(19) United States
(12) Patent Application Publication
(10) Pub. No.: US 2026/0118760 A1
(43) Pub. Date: Apr. 30, 2026

(54) RESIST COMPOSITION, LAMINATE, PATTERNING PROCESS, AND METHOD FOR MANUFACTURING THE RESIST COMPOSITION

(71) Applicant: SHIN-ETSU CHEMICAL CO., LTD., Tokyo (JP)

(72) Inventors: Shun KIKUCHI, Joetsu-shi (JP); Satoshi KUSAMA, Joetsu-shi (JP); Kousuke OHYAMA, Joetsu-shi (JP); Ryo NISHIKAWA, Joetsu-shi (JP); Masaki OHASHI, Joetsu-shi (JP)

(73) Assignee: SHIN-ETSU CHEMICAL CO., LTD., Tokyo (JP)

(21) Appl. No.: 19/364,350

(22) Filed: Oct. 21, 2025

(30) Foreign Application Priority Data
Oct. 24, 2024 (JP) 2024-187526

(51) Int. Cl. G03F 7/027; G03F 7/00

(52) U.S. Cl. CPC G03F 7/027; G03F 7/70033

(57) ABSTRACT

The present invention is a resist composition containing a hypervalent iodine compound, a carboxy-group-containing polymer, and a solvent, where the carboxy-group-containing polymer includes a repeating unit of a carboxylic acid derivative, represented by the following formula (1), and the polymer has a dispersity Mw/Mn of 1.30 or less, where Mw is a weight-average molecular weight and Mn is a number-average molecular weight measured by gel permeation chromatography. This can provide: a non-chemically amplified resist composition excellent in sensitivity and limiting resolution in photolithography using a high-energy beam; a laminate including the resist composition; a patterning process using the resist composition; and a method for manufacturing the resist composition.

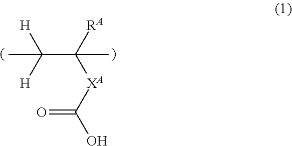

### TECHNICAL FIELD

The present invention relates to: a resist composition; a laminate; a patterning process using the resist composition; and a method for manufacturing the resist composition.

### BACKGROUND ART

While a higher integration density, higher operating speed and lower power consumption of LSIs are demanded to comply with the expanding IoT market, the effort to reduce the pattern rule is in rapid progress. In particular, logic devices drive forward the miniaturization technology. As the advanced miniaturization technology, devices of 10-nm node are manufactured in a mass scale by the double, triple or quadro-patterning version of the immersion ArF lithography. Furthermore, the experimental mass-scale manufacture of 7-nm node devices by the next-generation extreme ultraviolet ray (EUV) lithography of wavelength 13.5 nm has started.

As miniaturization advances, image blurs due to acid diffusion are regarded as a problem (Non Patent Document 1). In order to ensure resolution for fine patterns with a post-45 nm processed size, it is suggested that not only the enhancement of dissolution contrast, which has been proposed previously, but also the controlling of acid diffusion is important (Non Patent Document 2). In chemically amplified resist compositions, however, the sensitivity and the contrast are enhanced by acid diffusion. Accordingly, an attempt to minimize acid diffusion by lowering the temperature of post-exposure baking (PEB) and shortening the PEB time lowers the sensitivity and contrast markedly.

It is effective to control the acid diffusion by adding an acid generator that generates a bulky acid. Accordingly, it has been proposed to copolymerize a polymer with an acid generator in the form of an onium salt having polymerizable olefin. In post-16 nm processed size patterning of resist films, however, it is considered that patterning is impossible with chemically amplified resist compositions in view of the acid diffusion. Accordingly, development of a non-chemically amplified resist composition is desired.

Examples of materials for a non-chemically amplified resist composition include polymethyl methacrylate (PMMA). PMMA is a positive resist material whose solubility in an organic solvent developer increases due to decreased molecular weight caused by scission of the main chain by EUV irradiation.

Hydrogensilsesquioxane (HSQ) is a negative resist material which turns insoluble in an alkaline developer through crosslinking by condensation reaction of silanol generated by EUV irradiation. Calixarene substituted with chlorine also functions as a negative resist material. These negative resist materials have a small molecular size prior to crosslinking and are free from causing blurs due to acid diffusion, and therefore, exhibit smaller edge roughness and very high resolution. Accordingly, the materials have been used as a pattern transfer material to show the resolution limit of the exposure apparatus. These materials, however, are insufficient in sensitivity, and further improvement is required.

The number of photons in EUV exposure being small is a factor that causes difficulties in developing materials for EUV lithography. The energy of EUV is much higher than that of an ArF excimer laser beam, and the number of photons in EUV exposure is 1/14 of that of ArF exposure. Furthermore, the size of the pattern formed by EUV exposure is half of that in ArF exposure or less. Therefore, EUV exposure is easily affected by variation in the number of photons. The variation in the number of photons in a radiation light region of extremely short wavelengths is the physical phenomenon of shot noise, and it is impossible to eliminate the influence of the variation. Therefore, so-called probability theory (stochastics) is attracting attention. The influence of shot noise cannot be eliminated, but there is discussion of how to reduce this influence. Due to the influence of shot noise, not only are critical dimension uniformity (CDU) and line width roughness (LWR) increased, a phenomenon that a hole gets blocked at a probability of one to several millions is observed. If a hole gets blocked, conduction failure occurs and the transistor does not function, and the performance of the entire device is adversely affected. Considering sensitivity in practical terms, resist compositions that mainly contain PMMA or HSQ are greatly affected by stochastics, and cannot achieve the desired resolution performance.

The introduction of an element that greatly absorbs EUV light is attracting attention as a means for reducing the influence of shot noise on the side of the resist. Patent Document 1 proposes a chemically amplified resist composition containing iodine atoms, which greatly absorb EUV light. However, as stated above, a chemically amplified resist composition cannot realize excellent resolution performance in EUV lithography, in which the processed size is to be further miniaturized in the future. Especially in a line-and-space pattern, pattern collapse and the breaking of a line increase remarkably as the pattern size is reduced, and therefore, reducing these leads to the improvement of limiting resolution.

Patent Document 2 proposes a negative resist composition containing a tin compound. This composition mainly contains the element tin, which greatly absorbs EUV light, and therefore, stochastics is improved, and high sensitivity and high resolution can be realized. However, such a so-called metal resist has many problems such as insufficient solubility in a solvent for resists, storage stability, and defects due to residues after etching. Furthermore, a metal resist is a negative resist in which mainly the exposed portions form a metal oxide and become insoluble in a developer. Therefore, when the resist is applied to the patterning of contact holes, an additional reversal process step is necessary, and there are also concerns regarding costs.

### CITATION LIST

### Patent Literature

Patent Document 1: JP2018-5224A
Patent Document 2: JP2021-503482A

### Non Patent Literature

Non Patent Document 1: SPIE Vol. 5039 p1 (2003)
Non Patent Document 2: SPIE Vol. 6520 p65203L-1 (2007)

### SUMMARY OF INVENTION

### Technical Problem

The present invention has been made in view of the above-described circumstances, and an object thereof is to provide: a non-chemically amplified resist composition excellent in sensitivity and limiting resolution in photolithography using a high-energy beam, especially electron beam (EB) lithography and EUV lithography; a laminate including the resist composition; and a patterning process using the resist composition.

### Solution to Problem

To achieve the object, the present invention provides a resist composition comprising a hypervalent iodine compound, a carboxy-group-containing polymer, and a solvent,
wherein the carboxy-group-containing polymer includes a repeating unit of a carboxylic acid derivative, represented by the following formula (1), and the polymer has a dispersity Mw/Mn of 1.30 or less, where Mw is a weight-average molecular weight and Mn is a number-average molecular weight measured by gel permeation chromatography,

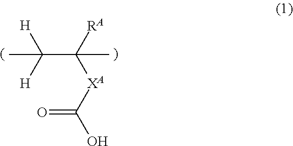

wherein R^{A} represents a hydrogen atom, a halogen atom, a methyl group, or a trifluoromethyl group; X^{A} represents a single bond, a phenylene group, a naphthylene group, or *—C(═O)—O—X^{A1}—; X^{A1} represents a saturated hydrocarbylene group having 1 to 10 carbon atoms, a phenylene group, or a naphthylene group, the saturated hydrocarbylene group optionally containing a hydroxy group, an ether bond, an ester bond, or a lactone ring; and “*” represents an attachment point to the carbon atom of the polymer main chain.

The inventive resist composition is a non-chemically amplified resist composition excellent in sensitivity and limiting resolution in photolithography using a high-energy beam, especially electron beam (EB) lithography and EUV lithography. In particular, by using a resist composition that contains a polymer having a narrow dispersity (molecular weight distribution), it is possible to achieve reduced roughness, uniform solubility, and reduced swelling of the polymer, and prevent pattern collapse of a line-and-space pattern and a phenomenon where the space between patterns in a contact hole pattern becomes blocked, which cause degradation in resolution.

In this case, the hypervalent iodine compound is preferably at least one compound selected from the group consisting of hypervalent iodine compounds represented by the following formulae (2) to (11),

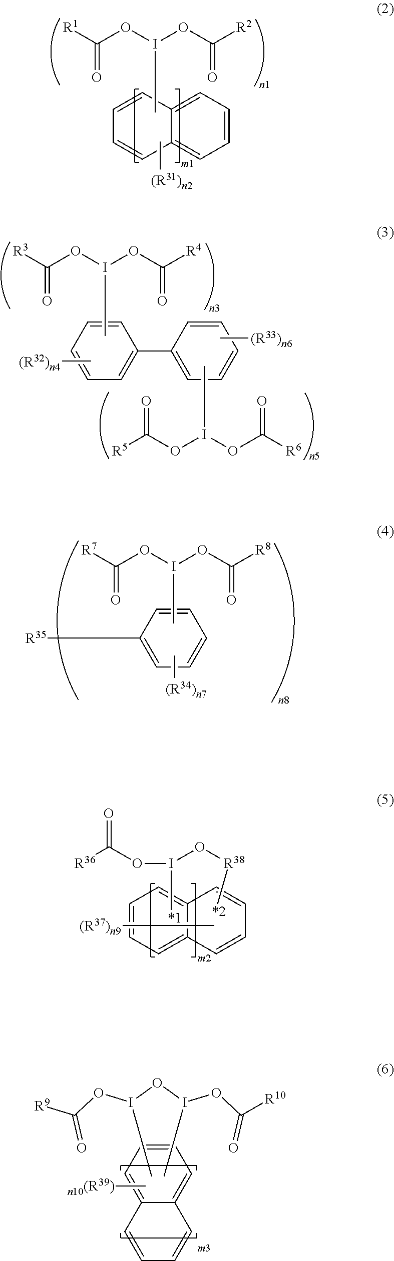

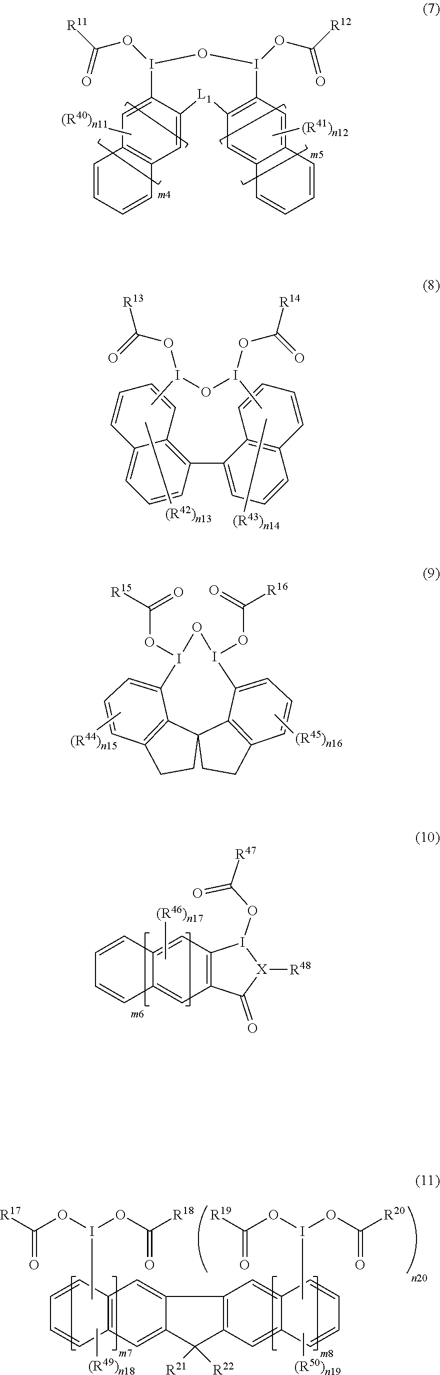

wherein “m1” represents 0, 1, or 2, when “m1” is 0, “n1” representing 1, 2, or 3, “n2” representing 0, 1, 2, 3, 4, or 5, and 1≤n1+n2≤6 being satisfied, when “m1” is 1, “n1” representing 1, 2, or 3, “n2” representing 0, 1, 2, 3, 4, 5, 6, or 7, and 1<n1+n2≤8 being satisfied, and when “m1” is 2, “n1” representing 1, 2, or 3, “n2” representing 0, 1, 2, 3, 4, 5, 6, 7, 8, or 9, and 1≤n1+n2≤10 being satisfied; “n3” represents 1 or 2, “n4” represents 0, 1, 2, 3, or 4, and 1<n3+n4≤5 is satisfied; “n5” represents 1 or 2, “n6” represents 0, 1, 2, 3, or 4, and 1≤n5+n6≤5 is satisfied; “n7” represents 0, 1, 2, 3, or 4; “n8” represents 1, 2, 3, or 4; “m2” represents 0, 1, or 2, when “m2” is 0, “n9” representing 0, 1, 2, 3, or 4, when “m2” is 1, “n9” representing 0, 1, 2, 3, 4, 5, or 6, and when “m2” is 2, “n9” representing 0, 1, 2, 3, 4, 5, 6, 7, or 8; “m3” represents 0, 1, or 2, when “m3” is 0, “n10” representing 0, 1, 2, 3, or 4, when “m3” is 1, “n10” representing 0, 1, 2, 3, 4, 5, or 6, and when “m3” is 2, “n10” representing 0, 1, 2, 3, 4, 5, 6, 7, or 8; “m4” represents 0 or 1, when “m4” is 0, “n11” representing 0, 1, 2, 3, or 4 and when “m4” is 1, “n11” representing 0, 1, 2, 3, 4, 5, or 6; “m5” represents 0 or 1, when “m5” is 0, “n12” representing 0, 1, 2, 3, or 4 and when “m5” is 1, “n12” representing 0, 1, 2, 3, 4, 5, or 6; “n13” and “n14” each represent 0, 1, 2, 3, 4, 5, or 6; “n15” and “n16” each represent 0, 1, 2, or 3; “m6” represents 0, 1, or 2, when “m6” is 0, “n17” representing 0, 1, 2, 3, or 4, when “m6” is 1, “n17” representing 0, 1, 2, 3, 4, 5, or 6, and when “m6” is 2, “n17” representing 0, 1, 2, 3, 4, 5, 6, 7, or 8; “m7” represents 0, 1, or 2, when “m7” is 0, “n18” representing 0, 1, 2, or 3, when “m7” is 1, “n18” representing 0, 1, 2, 3, 4, or 5, and when “m7” is 2, “n18” representing 0, 1, 2, 3, 4, 5, 6, or 7; “m8” represents 0, 1, or 2, when “m8” represents 0, “n19” representing 0, 1, 2, or 3 and “n20” representing 0 or 1, when “m8” is 1, “n19” representing 0, 1, 2, 3, 4, or 5 and “n20” representing 0 or 1, and when “m8” is 2, “n19” representing 0, 1, 2, 3, 4, 5, 6, or 7 and “n20” representing 0 or 1; R¹ to R²² each independently represent a halogen atom or a hydrocarbyl group having 1 to 10 carbon atoms and optionally containing a heteroatom, R¹ and R², R³ and R⁴, R⁵ and R⁶, R⁷ and R⁸, R⁹ and R¹⁰, R¹¹ and R¹², R¹³ and R¹⁴, R¹⁵ and R¹⁶, R¹⁷ and R¹⁸, or R¹⁹ and R²⁰ may be bonded to each other to form a ring together with the carbonyloxy groups bonded thereto and any atoms between the carbonyloxy groups, and R²¹ and R²² may be bonded to each other to form a ring together with the carbon atoms bonded thereto and any atoms between the carbon atoms; R³¹ to R³⁴, R³⁷, R³⁹ to R⁴⁶, R⁴⁹, and R⁵⁰ each independently represent a halogen atom or a hydrocarbyl group having 1 to 40 carbon atoms and optionally containing a heteroatom, when “n2” is 2 or more, the R³¹s are identical to or different from each other and the R³¹s may be bonded to each other to form a ring together with the carbon atoms of the aromatic ring bonded thereto, when “n4” is 2 or more, the R³'s are identical to or different from each other and the R³²s may be bonded to each other to form a ring together with the carbon atoms of the aromatic ring bonded thereto, when “n6” is 2 or more, the R³³s are identical to or different from each other and the R³³s may be bonded to each other to form a ring together with the carbon atoms of the aromatic ring bonded thereto, when “n7” is 2 or more, the R³⁴s are identical to or different from each other and the R³⁴s may be bonded to each other to form a ring together with the carbon atoms of the aromatic ring bonded thereto, when “n9” is 2 or more, the R³⁷s are identical to or different from each other and the R³⁷s may be bonded to each other to form a ring together with the carbon atoms of the aromatic ring bonded thereto, when “n10” is 2 or more, the R³⁹s are identical to or different from each other and the R³⁹s may be bonded to each other to form a ring together with the carbon atoms of the aromatic ring bonded thereto, when “n11” is 2 or more, the R⁴°s are identical to or different from each other and the R⁴⁰s may be bonded to each other to form a ring together with the carbon atoms of the aromatic ring bonded thereto, when “n12” is 2 or more, the R⁴¹s are identical to or different from each other and the R⁴¹s may be bonded to each other to form a ring together with the carbon atoms of the aromatic ring bonded thereto, when “n13” is 2 or more, the R⁴ªs are identical to or different from each other and the R⁴ªs may be bonded to each other to form a ring together with the carbon atoms of the aromatic ring bonded thereto, when “n14” is 2 or more, the R⁴³s are identical to or different from each other and the R⁴³s may be bonded to each other to form a ring together with the carbon atoms of the aromatic ring bonded thereto, when “n15” is 2 or more, the R⁴⁴s are identical to or different from each other and the R⁴⁴s may be bonded to each other to form a ring together with the carbon atoms of the aromatic ring bonded thereto, when “n16” is 2 or more, the R⁴⁵s are identical to or different from each other and the R⁴⁵s may be bonded to each other to form a ring together with the carbon atoms of the aromatic ring bonded thereto, when “n17” is 2 or more, the R⁴⁶s are identical to or different from each other and the R⁴⁶s may be bonded to each other to form a ring together with the carbon atoms of the aromatic ring bonded thereto, when “n18” is 2 or more, the R⁴⁹s are identical to or different from each other and the R⁴⁹s may be bonded to each other to form a ring together with the carbon atoms of the aromatic ring bonded thereto, and when “n19” is 2 or more, the R⁵⁰s are identical to or different from each other and the R⁵⁰s may be bonded to each other to form a ring together with the carbon atoms of the aromatic ring bonded thereto; R³⁵ represents an n8-valent hydrocarbon group having 1 to 40 carbon atoms or an n8-valent heterocyclic group having 2 to 40 carbon atoms, when “n8” is 2, the R³⁵ may be an ether bond, a carbonyl group, an azo group, a thioether bond, a carbonate bond, a carbamate bond, a sulfinyl group, a sulfonyl group, or a thioketone bond, wherein part or all of hydrogen atoms of the n8-valent hydrocarbon group or the n8-valent heterocyclic group may be substituted with a group containing a heteroatom, and part of —CH₂— of the n8-valent hydrocarbon group may be substituted with a group containing a heteroatom, and R³⁴ and R³⁵ may be bonded to each other to form a ring together with the carbon atoms bonded thereto and any atoms between the carbon atoms; R³⁶ represents a halogen atom or a hydrocarbyl group having 1 to 10 carbon atoms and optionally containing a heteroatom; R³⁸ represents a carbonyl group or a hydrocarbylene group having 1 to 10 carbon atoms and optionally containing a heteroatom; “*1” and “*2” each represent an attachment point to a carbon atom of the aromatic ring in the formula, provided that “*1” and “*2” are boned to adjacent carbon atoms of the aromatic ring; L₁ represents absence of a bond, a single bond, —O—, —S—, —NH—, or —CH₂—; R⁴⁷ represents a halogen atom or a hydrocarbyl group having 1 to 10 carbon atoms and optionally containing a heteroatom; and X represents nitrogen or sulfur, when X is nitrogen, X may have R⁴⁸, and R⁴⁸ represents a hydrogen atom, a halogen atom, or a hydrocarbyl group having 1 to 20 carbon atoms and optionally containing a heteroatom.

As the hypervalent iodine compound contained in the inventive resist composition, the tricoordinate hypervalent iodine compounds represented by the above formulae are preferable. When such a tricoordinate iodine (III) compound having an aryl group and a carboxylate ligand is mixed with a carboxy-group-containing compound, the exchange of the compound and the carboxylate ligand occurs easily as an equilibrium reaction. In this event, by removing the original carboxylate ligand from the reaction system, equilibrium shifts in a direction to generate a hypervalent iodine compound having a new ligand, and the ligand exchange progresses. Thus, a polymer in which a carboxy-group-containing compound is crosslinked with a hypervalent iodine compound is achieved.

The present invention also provides a laminate comprising: a substrate; and a resist film, which is a film body formed of the above-described resist composition, on the substrate.

In a laminate including a resist film obtained from the inventive resist composition, the resist film, which is a film body of the above-described resist composition, has high sensitivity, also exhibits excellent limiting resolution, is effective for precise fine processing, and in addition, can be applied to either positive or negative patterning. Therefore, the laminate has a wide range of uses, and is highly useful in resist process technology.

In this case, the laminate can further comprise a resist underlayer film between the substrate and the resist film. In addition, the resist film preferably contains a product made by a ligand exchange reaction of the hypervalent iodine compound and the carboxy-group-containing polymer.

The inventive laminate can be as described above in accordance with requirements.

The present invention also provides a patterning process comprising the steps of:
forming a resist film by using the above-described resist composition on a substrate or on a resist underlayer film of a substrate on which the resist underlayer film has been laminated;
exposing the resist film by using a high-energy beam; and
developing the exposed resist film by using a developer.

In the inventive patterning process, a resist composition that is excellent in sensitivity and resolution in photolithography using a high-energy beam, especially electron beam (EB) lithography and EUV lithography, is used, and therefore, the patterning process is useful for finer patterning.

In this case, the high-energy beam used is preferably an i-line, a KrF excimer laser beam, an ArF excimer laser beam, an electron beam, or an extreme ultraviolet ray.

In the inventive patterning process, using such a high-energy beam makes finer patterning possible.

The present invention also provides a method for manufacturing the above-described resist composition, comprising the step of
synthesizing the carboxy-group-containing polymer by living radical polymerization using a radical initiator and a reversible addition-fragmentation chain transfer agent represented by the following formula (R-1) or (R-2) and mixing the obtained carboxy-group-containing polymer with the hypervalent iodine compound and the solvent,

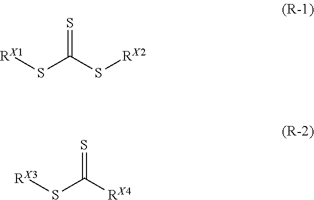

wherein R^{X1} and R^{X3} each independently represent a saturated hydrocarbylthio group having 3 to 20 carbon atoms, an aralkylthio group having 7 to 20 carbon atoms, a heterocyclyl group having 5 to 20 carbon atoms, —N(Z^{A})(Z^{B}), —COOZ^{A}, —OCOZ^{A}, —CON(Z^{A})(Z^{B}), —P(═O)(OZ^{A})₂, or —O—P(═O)(Z^{A})(Z^{B}); Z^{A} and Z^{B} each independently represent a saturated hydrocarbyl group having 1 to 20 carbon atoms, an aryl group having 6 to 20 carbon atoms, or an aralkyl group having 7 to 20 carbon atoms, wherein part or all of hydrogen atoms bonded to carbon atoms of Z^{A} and Z^{B} may be substituted with a cyano group or a carboxy group; and R^{X2} and R^{X4} each independently represent a saturated hydrocarbyl group having 2 to 20 carbon atoms and optionally containing a heteroatom, an aralkyl group having 7 to 20 carbon atoms, or an aryl group having 6 to 20 carbon atoms.

By synthesizing the carboxy-group-containing polymer in this manner, a narrowly dispersed polymer can be obtained, and the inventive resist composition, containing the polymer, can be manufactured with high productivity.

### Advantageous Effects of Invention

The inventive resist composition has high sensitivity and can also achieve both excellent roughness and excellent limiting resolution in lithography using a high-energy beam, especially an i-line, KrF excimer laser, ArF excimer laser, EB, and EUV, and is extremely useful on forming a fine pattern.

### DESCRIPTION OF EMBODIMENTS

To achieve the object, the present inventors have studied earnestly and found out that a resist composition mainly containing a hypervalent iodine compound and a predetermined carboxy-group-containing polymer can give a resist film that has high sensitivity, has low roughness, and exhibits excellent limiting resolution, and is extremely effective for precise fine processing. Thus, the present invention has been achieved.

That is, the present invention is a resist composition comprising a hypervalent iodine compound, a carboxy-group-containing polymer, and a solvent,
wherein the carboxy-group-containing polymer includes a repeating unit of a carboxylic acid derivative, represented by the following formula (1), and the polymer has a dispersity Mw/Mn of 1.30 or less, where Mw is a weight-average molecular weight and Mn is a number-average molecular weight measured by gel permeation chromatography (GPC),

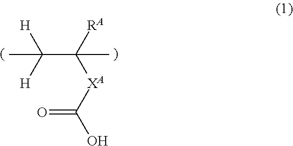

wherein R^{A} represents a hydrogen atom, a halogen atom, a methyl group, or a trifluoromethyl group; X^{A} represents a single bond, a phenylene group, a naphthylene group, or *—C(═O)—O—X^{A1}—; X^{A1} represents a saturated hydrocarbylene group having 1 to 10 carbon atoms, a phenylene group, or a naphthylene group, the saturated hydrocarbylene group optionally containing a hydroxy group, an ether bond, an ester bond, or a lactone ring; and “*” represents an attachment point to the carbon atom of the polymer main chain.

Hereinafter, the present invention will be described in detail, but the present invention is not limited thereto. Note that, in the present description, the recitations of numerical ranges by endpoints include all numbers subsumed within that range (e. g. “0 to 3” includes 0, 1, 2, and 3).

### [Resist Composition]

The inventive resist composition mainly contains a hypervalent iodine compound and a predetermined carboxy-group-containing polymer.

### [Hypervalent Iodine Compound]

The above-described hypervalent iodine compound is a tricoordinate hypervalent iodine compound represented by any of the following formulae (2) to (11).

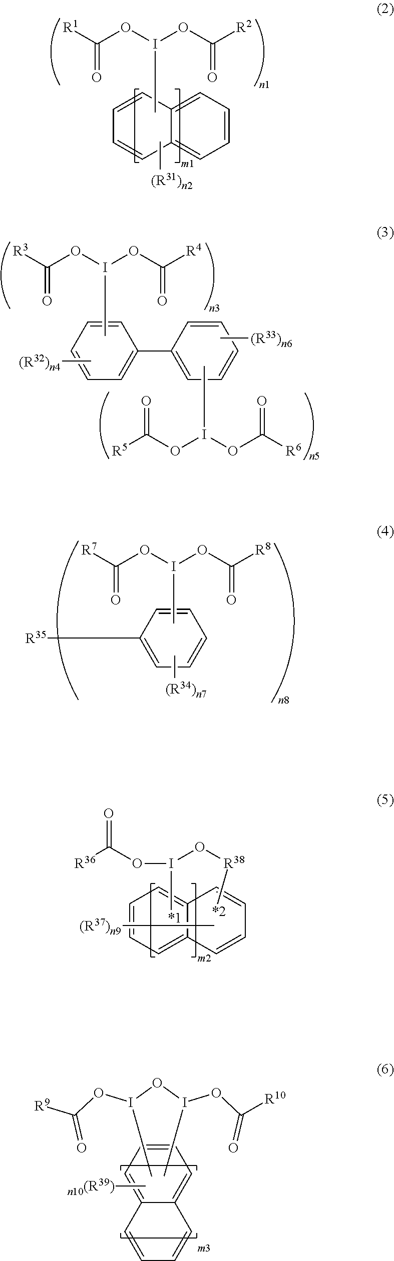

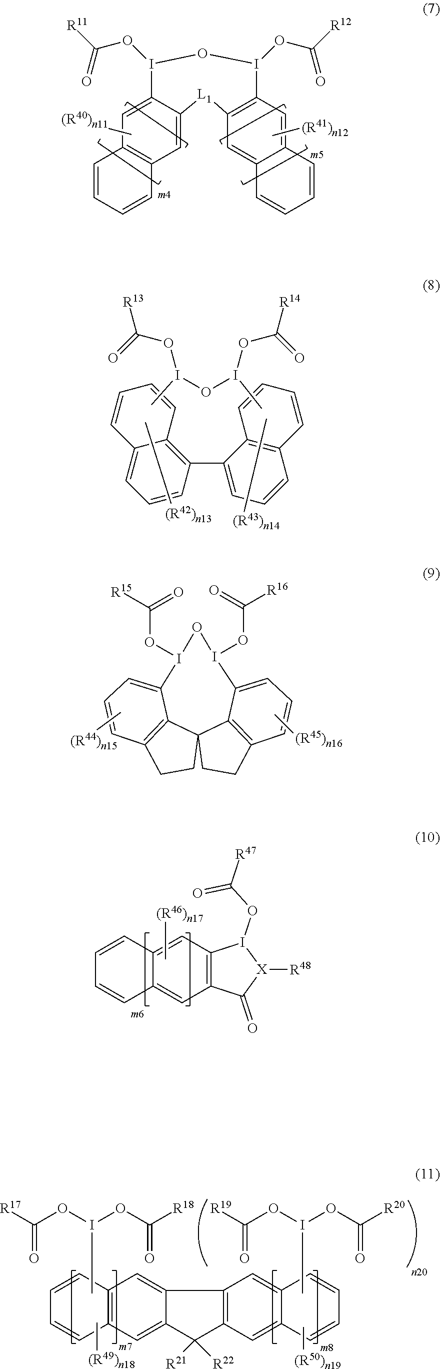

In the formulae, “m1” represents 0, 1, or 2, when “m1” is 0, “n1” representing 1, 2, or 3, “n2” representing 0, 1, 2, 3, 4, or 5, and 1<n1+n2≤6 being satisfied, when “m1” is 1, “n1” representing 1, 2, or 3, “n2” representing 0, 1, 2, 3, 4, 5, 6, or 7, and 1≤n1+n2≤8 being satisfied, and when “m1” is 2, “n1” representing 1, 2, or 3, “n2” representing 0, 1, 2, 3, 4, 5, 6, 7, 8, or 9, and 1≤n1+n2≤10 being satisfied; “n3” represents 1 or 2, “n4” represents 0, 1, 2, 3, or 4, and 1≤n3+n4≤5 is satisfied; “n5” represents 1 or 2, “n6” represents 0, 1, 2, 3, or 4, and 1<n5+n6≤5 is satisfied; “n7” represents 0, 1, 2, 3, or 4; “n8” represents 1, 2, 3, or 4; “m2” represents 0, 1, or 2, when “m2” is 0, “n9” representing 0, 1, 2, 3, or 4, when “m2” is 1, “n9” representing 0, 1, 2, 3, 4, 5, or 6, and when “m2” is 2, “n9” representing 0, 1, 2, 3, 4, 5, 6, 7, or 8; “m3” represents 0, 1, or 2, when “m3” is 0, “n10” representing 0, 1, 2, 3, or 4, when “m3” is 1, “n10” representing 0, 1, 2, 3, 4, 5, or 6, and when “m3” is 2, “n10” representing 0, 1, 2, 3, 4, 5, 6, 7, or 8; “m4” represents 0 or 1, when “m4” is 0, “n11” representing 0, 1, 2, 3, or 4 and when “m4” is 1, “n11” representing 0, 1, 2, 3, 4, 5, or 6; “m5” represents 0 or 1, when “m5” is 0, “n12” representing 0, 1, 2, 3, or 4 and when “m5” is 1, “n12” representing 0, 1, 2, 3, 4, 5, or 6; “n13” and “n14” each represent 0, 1, 2, 3, 4, 5, or 6; “n15” and “n16” each represent 0, 1, 2, or 3; “m6” represents 0, 1, or 2, when “m6” is 0, “n17” representing 0, 1, 2, 3, or 4, when “m” is 1, “n17” representing 0, 1, 2, 3, 4, 5, or 6, and when “m6” is 2, “n17” representing 0, 1, 2, 3, 4, 5, 6, 7, or 8; “m7” represents 0, 1, or 2, when “m7” is 0, “n18” representing 0, 1, 2, or 3, when “m7” is 1, “n18” representing 0, 1, 2, 3, 4, or 5, and when “m7” is 2, “n18” representing 0, 1, 2, 3, 4, 5, 6, or 7; “m8” represents 0, 1, or 2, when “m8” represents 0, “n19” representing 0, 1, 2, or 3 and “n20” representing 0 or 1, when “m8” is 1, “n19” representing 0, 1, 2, 3, 4, or 5 and “n20” representing 0 or 1, and when “m8” is 2, “n19” representing 0, 1, 2, 3, 4, 5, 6, or 7 and “n20” representing 0 or 1; R¹ to Re2 each independently represent a halogen atom or a hydrocarbyl group having 1 to 10 carbon atoms and optionally containing a heteroatom, R¹ and R², R³ and R⁴, R⁵ and R⁶, R⁷ and R⁸, R⁹ and R¹⁰, R¹¹ and R¹², R¹³ and R¹⁴, R¹⁵ and R¹⁶, R¹⁷ and R¹⁸, or R¹⁹ and R²⁰ may be bonded to each other to form a ring together with the carbonyloxy groups bonded thereto and any atoms between the carbonyloxy groups, and R²¹ and R²² may be bonded to each other to form a ring together with the carbon atoms bonded thereto and any atoms between the carbon atoms; R³¹ to R³⁴, R³⁷, R³⁹ to R⁴⁶, R⁴⁹, and R⁵⁰ each independently represent a halogen atom or a hydrocarbyl group having 1 to 40 carbon atoms and optionally containing a heteroatom, when “n2” is 2 or more, the R³¹s are identical to or different from each other and the R³¹s may be bonded to each other to form a ring together with the carbon atoms of the aromatic ring bonded thereto, when “n4” is 2 or more, the R³²s are identical to or different from each other and the R³²s may be bonded to each other to form a ring together with the carbon atoms of the aromatic ring bonded thereto, when “n6” is 2 or more, the R³³s are identical to or different from each other and the R³³s may be bonded to each other to form a ring together with the carbon atoms of the aromatic ring bonded thereto, when “n7” is 2 or more, the R³⁴s are identical to or different from each other and the R³⁴s may be bonded to each other to form a ring together with the carbon atoms of the aromatic ring bonded thereto, when “n9” is 2 or more, the R³⁷s are identical to or different from each other and the R³⁷s may be bonded to each other to form a ring together with when “n10” is 2 or more, the R³⁹s are identical to or different from each other and the R³'s may be bonded to each other to form a ring together with the carbon atoms of the aromatic ring bonded thereto, when “n11” is 2 or more, the R⁴⁰s are identical to or different from each other and the R⁴⁰s may be bonded to each other to form a ring together with the carbon atoms of the aromatic ring bonded thereto, when “n12” is 2 or more, the R⁴¹s are identical to or different from each other and the R⁴¹s may be bonded to each other to form a ring together with the carbon atoms of the aromatic ring bonded thereto, when “n13” is 2 or more, the R⁴ªs are identical to or different from each other and the R⁴ªs may be bonded to each other to form a ring together with the carbon atoms of the aromatic ring bonded thereto, when “n14” is 2 or more, the R⁴³s are identical to or different from each other and the R⁴³s may be bonded to each other to form a ring together with the carbon atoms of the aromatic ring bonded thereto, when “n15” is 2 or more, the R⁴⁴s are identical to or different from each other and the R⁴⁴s may be bonded to each other to form a ring together with the carbon atoms of the aromatic ring bonded thereto, when “n16” is 2 or more, the R⁴⁵s are identical to or different from each other and the R⁴⁵s may be bonded to each other to form a ring together with the carbon atoms of the aromatic ring bonded thereto, when “n17” is 2 or more, the R⁴⁶s are identical to or different from each other and the R⁴⁶s may be bonded to each other to form a ring together with the carbon atoms of the aromatic ring bonded thereto, when “n18” is 2 or more, the R⁴⁹s are identical to or different from each other and the R⁴⁹s may be bonded to each other to form a ring together with and when “n19” is 2 or more, the R⁵⁰s are identical to or different from each other and the R⁵⁰s may be bonded to each other to form a ring together with the carbon atoms of the aromatic ring bonded thereto; R³⁵ represents an n8-valent hydrocarbon group having 1 to 40 carbon atoms or an n8-valent heterocyclic group having 2 to 40 carbon atoms, when “n8” is 2, the R³⁵ may be an ether bond, a carbonyl group, an azo group, a thioether bond, a carbonate bond, a carbamate bond, a sulfinyl group, a sulfonyl group, or a thioketone bond, where part or all of hydrogen atoms of the n8-valent hydrocarbon group or the n8-valent heterocyclic group may be substituted with a group containing a heteroatom, and part of —CH₂— of the n8-valent hydrocarbon group may be substituted with a group containing a heteroatom, and R³⁴ and R³⁵ may be bonded to each other to form a ring together with the carbon atoms bonded thereto and any atoms between the carbon atoms; R³⁶ represents a halogen atom or a hydrocarbyl group having 1 to 10 carbon atoms and optionally containing a heteroatom; R³⁸ represents a carbonyl group or a hydrocarbylene group having 1 to 10 carbon atoms and optionally containing a heteroatom; “*1” and “*2” each represent an attachment point to a carbon atom of the aromatic ring in the formula, provided that “*1” and “*2” are boned to adjacent carbon atoms of the aromatic ring; L₁ represents absence of a bond, a single bond, —O—, —S—, —NH—, or —CH₂—; R⁴⁷ represents a halogen atom or a hydrocarbyl group having 1 to 10 carbon atoms and optionally containing a heteroatom; and X represents nitrogen or sulfur, when X is nitrogen, X may have R⁴⁸, and R⁴⁸ represents a hydrogen atom, a halogen atom, or a hydrocarbyl group having 1 to 20 carbon atoms and optionally containing a heteroatom.

In the formulae (2) to (11), “m1” represents 0, 1, or 2, when “m1” is 0, “n1” representing 1, 2, or 3, “n2” representing 0, 1, 2, 3, 4, or 5, and 1≤n1+n2≤6 being satisfied, when “m1” is 1, “n1” representing 1, 2, or 3, “n2” representing 0, 1, 2, 3, 4, 5, 6, or 7, and 1≤n1+n2≤8 being satisfied, and when “m1” is 2, “n1” representing 1, 2, or 3, “n2” representing 0, 1, 2, 3, 4, 5, 6, 7, 8, or 9, and 1≤n1+n2≤10 being satisfied; “n3” represents 1 or 2, “n4” represents 0, 1, 2, 3, or 4, and 1≤n3+n4≤5 is satisfied; “n5” represents 1 or 2, “n6” represents 0, 1, 2, 3, or 4, and 1≤n5+n6≤5 is satisfied; “n7” represents 0, 1, 2, 3, or 4; “n8” represents 1, 2, 3, or 4; “m2” represents 0, 1, or 2, when “m2” is 0, “n9” representing 0, 1, 2, 3, or 4, when “m2” is 1, “n9” representing 0, 1, 2, 3, 4, 5, or 6, and when “m2” is 2, “n9” representing 0, 1, 2, 3, 4, 5, 6, 7, or 8; “m3” represents 0, 1, or 2, when “m3” is 0, “n10” representing 0, 1, 2, 3, or 4, when “m3” is 1, “n10” representing 0, 1, 2, 3, 4, 5, or 6, and when “m3” is 2, “n10” representing 0, 1, 2, 3, 4, 5, 6, 7, or 8; “m4” represents 0 or 1, when “m4” is 0, “n11” representing 0, 1, 2, 3, or 4 and when “m4” is 1, “n11” representing 0, 1, 2, 3, 4, 5, or 6; “m5” represents 0 or 1, when “m5” is 0, “n12” representing 0, 1, 2, 3, or 4 and when “m5” is 1, “n12” representing 0, 1, 2, 3, 4, 5, or 6; “n13” and “n14” each represent 0, 1, 2, 3, 4, 5, or 6; “n15” and “n16” each represent 0, 1, 2, or 3; “m6” represents 0, 1, or 2, when “m6” is 0, “n17” representing 0, 1, 2, 3, or 4, when “m6” is 1, “n17” representing 0, 1, 2, 3, 4, 5, or 6, and when “m6” is 2, “n17” representing 0, 1, 2, 3, 4, 5, 6, 7, or 8; “m7” represents 0, 1, or 2, when “m7” is 0, “n18” representing 0, 1, 2, or 3, when “m7” is 1, “n18” representing 0, 1, 2, 3, 4, or 5, and when “m7” is 2, “n18” representing 0, 1, 2, 3, 4, 5, 6, or 7; “m8” represents 0, 1, or 2, when “m8” represents 0, “n19” representing 0, 1, 2, or 3 and “n20” representing 0 or 1, when “m8” is 1, “n19” representing 0, 1, 2, 3, 4, or 5 and “n20” representing 0 or 1, and when “m8” is 2, “n19” representing 0, 1, 2, 3, 4, 5, 6, or 7 and “n20” representing 0 or 1. Note that, when “m1”, “m2”, “m3”, “m4”, “m5”, “m”, “m7”, and “m8” are 0, the aromatic rings are benzene rings.

In the formulae (2) to (4), (6) to (9), and (11), R¹ to R²² each independently represent a halogen atom or a hydrocarbyl group having 1 to 10 carbon atoms and optionally containing a heteroatom, R¹ and R², R³ and R⁴, R⁵ and R⁶, R⁷ and R⁸, R⁹ and R¹⁰, R¹¹ and R¹², R¹³ and R¹⁴, R¹⁵ and R¹⁶, R¹⁷ and R¹⁸, or R¹⁹ and R²⁰ may be bonded to each other to form a ring together with the carbonyloxy groups bonded thereto and any atoms between the carbonyloxy groups, and R²¹ and R²² may be bonded to each other to form a ring together with the carbon atoms bonded thereto and any atoms between the carbon atoms.

Examples of the halogen atom represented by R¹ to R²² include a fluorine atom, a chlorine atom, a bromine atom, and an iodine atom. The hydrocarbyl group represented by R¹ to R²² having 1 to 10 carbon atoms may be saturated or unsaturated, and may be linear, branched, or cyclic. Specific examples thereof include: alkyl groups having 1 to 10 carbon atoms, such as a methyl group, an ethyl group, a propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}] decyl group, and an adamantyl group; alkenyl groups, such as a vinyl group and an allyl group; aryl groups having 6 to 10 carbon atoms, such as a phenyl group and a naphthyl group; and groups which are combinations of these groups. Furthermore, part or all of the hydrogen atoms of the hydrocarbyl group may be substituted with a group containing a heteroatom, such as an oxygen atom, a sulfur atom, a nitrogen atom, or a halogen atom, and part of the —CH₂— of the hydrocarbyl group may be substituted with a group containing a heteroatom such as an oxygen atom, a sulfur atom, or a nitrogen atom. The resulting hydrocarbyl group may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc. As R¹ to R²², a hydrocarbyl group having 1 to 4 carbon atoms is preferable.

In the formulae (2) to (11), R³¹ to R³⁴, R³⁷, R³⁹ to R⁴⁶, R⁴⁹, and R⁵⁰ each independently represent a halogen atom or a hydrocarbyl group having 1 to 40 carbon atoms and optionally containing a heteroatom, when “n2” is 2 or more, the R³¹s are identical to or different from each other and the R³¹s may be bonded to each other to form a ring together with the carbon atoms of the aromatic ring bonded thereto, when “n4” is 2 or more, the R³ªs are identical to or different from each other and the R³ªs may be bonded to each other to form a ring together with the carbon atoms of the aromatic ring bonded thereto, when “n6” is 2 or more, the R³³s are identical to or different from each other and the R³³s may be bonded to each other to form a ring together with the carbon atoms of the aromatic ring bonded thereto, when “n7” is 2 or more, the R³⁴s are identical to or different from each other and the R³⁴s may be bonded to each other to form a ring together with the carbon atoms of the aromatic ring bonded thereto, when “n9” is 2 or more, the R³⁷s are identical to or different from each other and the R³⁷s may be bonded to each other to form a ring together with the carbon atoms of the aromatic ring bonded thereto, when “n10” is 2 or more, the R³'s are identical to or different from each other and the R³'s may be bonded to each other to form a ring together with the carbon atoms of the aromatic ring bonded thereto, when “n11” is 2 or more, the R⁴⁰s are identical to or different from each other and the R⁴⁰s may be bonded to each other to form a ring together with the carbon atoms of the aromatic ring bonded thereto, when “n12” is 2 or more, the R⁴¹s are identical to or different from each other and the R⁴¹s may be bonded to each other to form a ring together with the carbon atoms of the aromatic ring bonded thereto, when “n13” is 2 or more, the R⁴²s are identical to or different from each other and the R⁴ªs may be bonded to each other to form a ring together with the carbon atoms of the aromatic ring bonded thereto, when “n14” is 2 or more, the R⁴³s are identical to or different from each other and the R⁴³s may be bonded to each other to form a ring together with the carbon atoms of the aromatic ring bonded thereto, when “n15” is 2 or more, the R⁴⁴s are identical to or different from each other and the R⁴⁴s may be bonded to each other to form a ring together with the carbon atoms of the aromatic ring bonded thereto, when “n16” is 2 or more, the R⁴⁵s are identical to or different from each other and the R⁴⁵s may be bonded to each other to form a ring together with the carbon atoms of the aromatic ring bonded thereto, when “n17” is 2 or more, the R⁴⁶s are identical to or different from each other and the R⁴⁶s may be bonded to each other to form a ring together with the carbon atoms of the aromatic ring bonded thereto, when “n18” is 2 or more, the R⁴⁹s are identical to or different from each other and the R⁴⁹s may be bonded to each other to form a ring together with the carbon atoms of the aromatic ring bonded thereto, and when “n19” is 2 or more, the R⁵⁰s are identical to or different from each other and the R⁵⁰s may be bonded to each other to form a ring together with the carbon atoms of the aromatic ring bonded thereto.

Examples of the halogen atom represented by R³¹ to R³⁴, R³⁷, R³⁹ to R⁴⁶, R⁴⁹, and R⁵⁰ include a fluorine atom, a chlorine atom, a bromine atom, and an iodine atom. The hydrocarbyl group represented by R³¹ to R³⁴, R³⁷, R³⁹ to R⁴⁶, R⁴⁹, and R⁵⁰ having 1 to 40 carbon atoms may be saturated or unsaturated, and may be linear, branched, or cyclic. Specific examples thereof include: alkyl groups having 1 to 40 carbon atoms, such as a methyl group, an ethyl group, a propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, an adamantyl group, and an adamantylmethyl group; and aryl groups having 6 to 40 carbon atoms, such as a phenyl group, a naphthyl group, and an anthracenyl group. Furthermore, part or all of the hydrogen atoms of the hydrocarbyl group may be substituted with a group containing a heteroatom, such as an oxygen atom, a sulfur atom, a nitrogen atom, or a halogen atom, and part of the —CH₂— of the hydrocarbyl group may be substituted with a group containing a heteroatom such as an oxygen atom, a sulfur atom, or a nitrogen atom. The resulting hydrocarbyl group may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc.

In the formula (4), R³⁵ represents an n8-valent hydrocarbon group having 1 to 40 carbon atoms or an n8-valent heterocyclic group having 2 to 40 carbon atoms, when “n8” is 2, the R³⁵ may be an ether bond, a carbonyl group, an azo group, a thioether bond, a carbonate bond, a carbamate bond, a sulfinyl group, a sulfonyl group, or a thioketone bond, where part or all of hydrogen atoms of the n8-valent hydrocarbon group or the n8-valent heterocyclic group may be substituted with a group containing a heteroatom, and part of —CH₂— of the n8-valent hydrocarbon group may be substituted with a group containing a heteroatom, and R³⁴ and R³⁵ may be bonded to each other to form a ring together with the carbon atoms bonded thereto and any atoms between the carbon atoms.

The n8-valent hydrocarbon group represented by R³⁵ may be saturated or unsaturated, and may be linear, branched, or cyclic. The n8-valent hydrocarbon group is a hydrocarbon group from which “n8” hydrogen atoms are removed. Examples of the hydrocarbon include alkanes having 1 to 40 carbon atoms, alkenes having 2 to 40 carbon atoms, alkynes having 2 to 40 carbon atoms, cyclic saturated hydrocarbons having 3 to 40 carbon atoms, cyclic unsaturated hydrocarbons having 3 to 40 carbon atoms, and aromatic hydrocarbons having 6 to 40 carbon atoms.

Specific examples of the alkanes having 1 to 40 carbon atoms include methane, ethane, propane, butane, pentane, hexane, heptane, octane, nonane, decane, and structural isomers thereof.

Specific examples of the alkenes having 2 to 40 carbon atoms include ethylene, propylene, butene, pentene, hexene, heptene, octene, nonene, decene, and structural isomers thereof.

Specific examples of the alkynes having 2 to 40 carbon atoms include acetylene, propyne, butyne, pentyne, hexyne, heptyne, octyne, nonyne, decyne, and structural isomers thereof.

Specific examples of the cyclic saturated hydrocarbons having 3 to 40 carbon atoms include cyclopropane, cyclobutane, cyclohexane, cycloheptane, cyclooctane, adamantane, and norbornane.

Specific examples of the cyclic unsaturated hydrocarbons having 3 to 40 carbon atoms include cyclopropene, cyclobutene, cyclopentene, cyclohexene, cycloheptene, cyclooctene, and norbornene.

Specific examples of the aromatic hydrocarbons having 6 to 40 carbon atoms include benzene, naphthalene, and biphenyl.

The n8-valent heterocyclic group represented by R³⁵ is a group which is obtained by removing of “n8” hydrogen atoms from a heterocyclic compound. Examples of the heterocyclic compound include furan, pyridine, pyrazole, and thiazolidine.

Part or all of the hydrogen atoms of the n8-valent hydrocarbon group or the n8-valent heterocyclic group represented by R³⁵ may be substituted with a group containing a heteroatom such as an oxygen atom, a sulfur atom, a nitrogen atom, or a halogen atom. The resulting n8-valent hydrocarbon group or n8-valent heterocyclic group may contain a hydroxy group, a cyano group, a fluorine atom, a chlorine atom, a bromine atom, an iodine atom, etc. Furthermore, part of the —CH₂-constituting the n8-valent hydrocarbon group may be substituted with a group containing a heteroatom such as an oxygen atom, a sulfur atom, or a nitrogen atom. The resulting n8-valent hydrocarbon group may contain a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc.

In the formula (5), R³⁶ represents a halogen atom or a hydrocarbyl group having 1 to 10 carbon atoms and optionally containing a heteroatom. Specific examples of the halogen atom and hydrocarbyl group represented by R³⁶ respectively include those given as examples of the halogen atom and hydrocarbyl group represented by R¹ to R²².

In the formula (5), R³⁸ represents a carbonyl group or a hydrocarbylene group having 1 to 10 carbon atoms and optionally containing a heteroatom. The hydrocarbylene group having 1 to 10 carbon atoms may be saturated or unsaturated, and may be linear, branched, or cyclic. Specific examples thereof include: alkylene groups having 1 to 10 carbon atoms, such as a methanediyl group, an ethane-1,1-diyl group, an ethane-1,2-diyl group, a propane-1,1-diyl group, a propane-1,2-diyl group, a propane-1,3-diyl group, a propane-2,2-diyl group, a butane-2,3-diyl group, a butane-1,4-diyl group, a 2-methylpropane-1,2-diyl group, a pentane-1,5-diyl group, a hexane-1,6-diyl group, a heptane-1,7-diyl group, an octane-1,8-diyl group, a nonane-1,9-diyl group, and a decane-1,10-diyl group; cyclic saturated hydrocarbylene groups having 3 to 10 carbon atoms, such as a cyclopentanediyl group, a cyclohexanediyl group, a norbornanediyl group, an adamantanediyl group, and a tricyclo[5.2.1.0^{2,6}]decanediyl group; alkenylene groups having 2 to 10 carbon atoms, such as a vinylene group and a propynylene group; arylene groups having 6 to 10 carbon atoms, such as a phenylene group, a methylphenylene group, an ethylphenylene group, an n-propylphenylene group, an isopropylphenylene group, an n-butylphenylene group, and a naphthylene group; and groups which are combinations of these groups. Furthermore, part or all of the hydrogen atoms of the hydrocarbylene group may be substituted with a group containing a heteroatom, such as an oxygen atom, a sulfur atom, a nitrogen atom, or a halogen atom, and part of the —CH₂— of the hydrocarbylene group may be substituted with a group containing a heteroatom such as an oxygen atom, a sulfur atom, or a nitrogen atom. The resulting hydrocarbylene group may contain a hydroxy group, a cyano group, a halogenated alkyl group, a halogen atom, a carbonyl group, an ether bond, a thioether bond, an ester bond, a sulfonic acid ester bond, a carbonate bond, a carbamate bond, a lactone ring, a sultone ring, a carboxylic anhydride (—C(═O)—O—C(═O)—), etc. As R³⁸, a carbonyl group, a hydrocarbylene group having 1 to 4 carbon atoms, or a fluorinated hydrocarbylene group having 1 to 4 carbon atoms is preferable.

In the formula (5), “*1” and “*2” each represent an attachment point to a carbon atom of the aromatic ring in the formula, provided that “*1” and “*2” are boned to adjacent carbon atoms of the aromatic ring. As combinations of such “*1”, “2”, and “m2”, the seven cases shown below are possible.

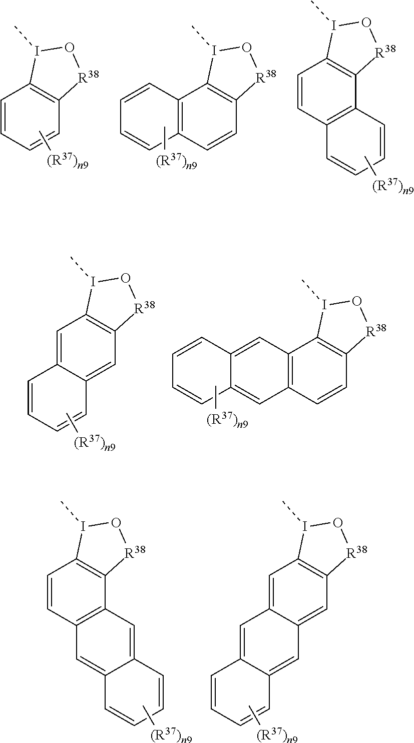

In the formulae, “n9”, R³⁷, and R³⁸ are as defined above. A broken line represents an attachment point to R³⁶—C(═O)—O—.

L₁ represents absence of a bond (in this case, the carbon atoms of the aromatic rings are each substituted with a hydrogen atom), a single bond, —O—, —S—, —NH—, or —CH₂—.

In the formula (10), R⁴⁷ represents a halogen atom or a hydrocarbyl group having 1 to 10 carbon atoms and optionally containing a heteroatom. Specific examples of the halogen atom and hydrocarbyl group represented by R⁴⁷ respectively include those given as examples of the halogen atom and hydrocarbyl group represented by R¹ to R²².

In the formula (10), X represents nitrogen or sulfur, when X is nitrogen, X may have R⁴⁸, and R⁴⁸ represents a hydrogen atom, a halogen atom, or a hydrocarbyl group having 1 to 20 carbon atoms and optionally containing a heteroatom. Specific examples of the halogen atom and hydrocarbyl group represented by R⁴⁸ respectively include those given as examples of the halogen atom and hydrocarbyl group represented by R¹ to R²².

Note that R³¹ to R³⁴, R³⁷ to R⁴⁶, R⁴⁹, and R⁵⁰ can substitute any position in the aromatic rings in the above formulae.

Specific examples of the hypervalent iodine compound represented by the formula (2) include the following, but are not limited thereto.

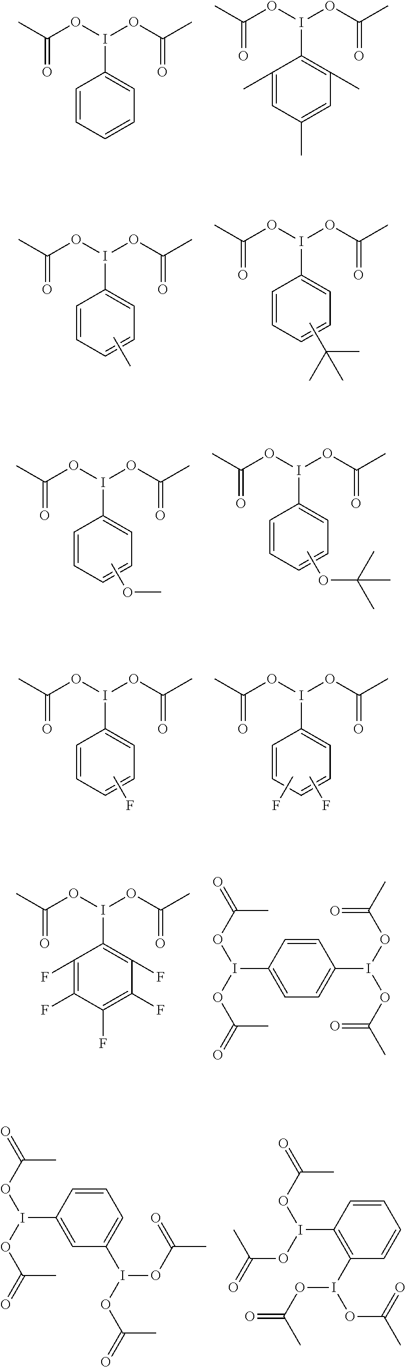

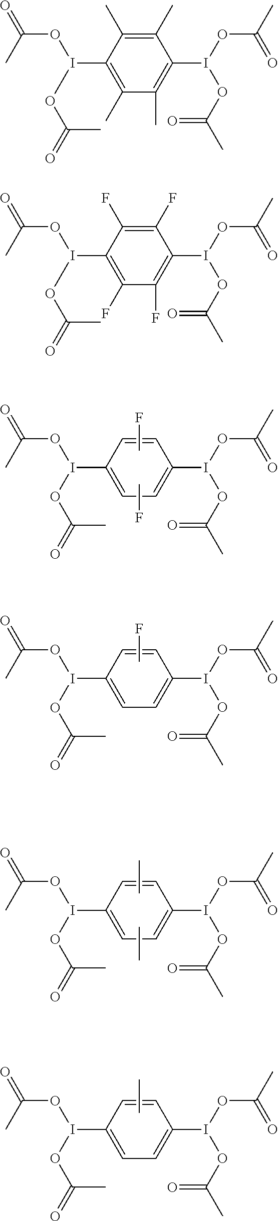

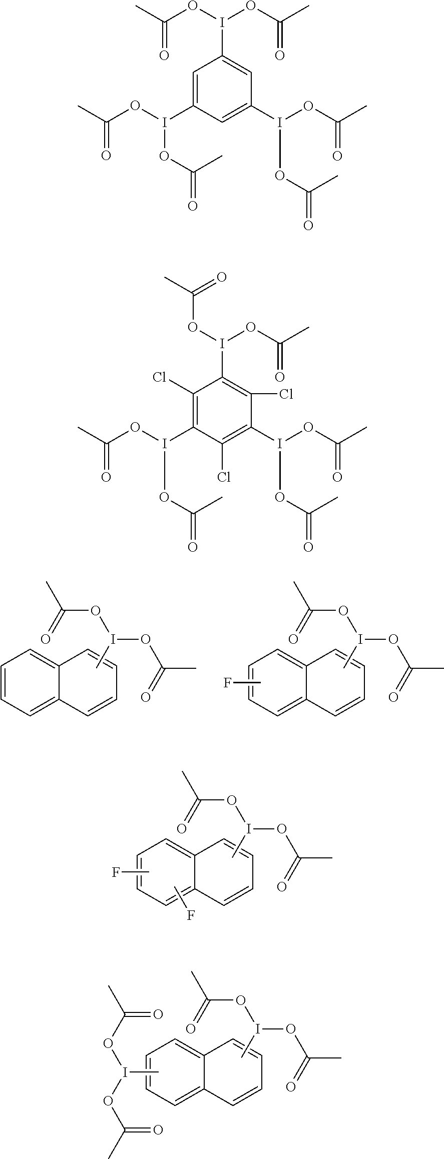

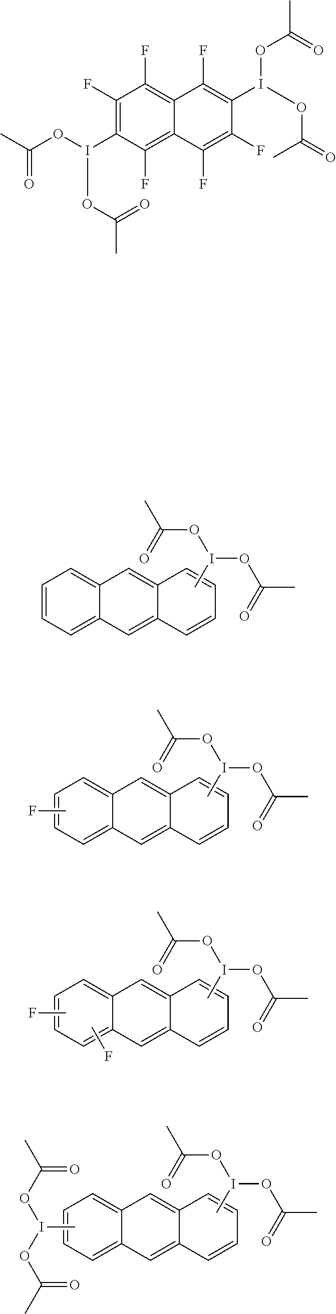

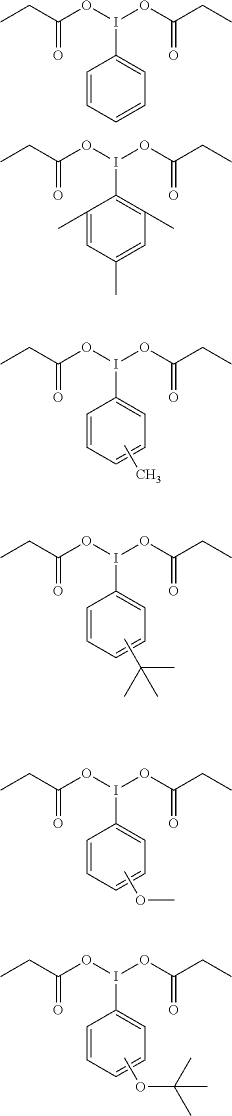

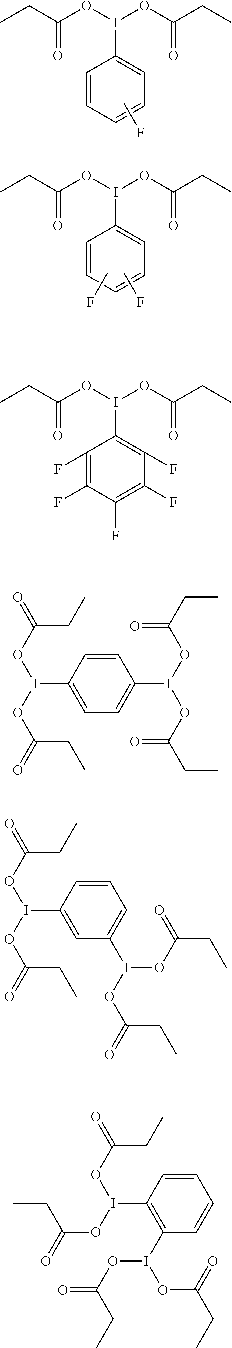

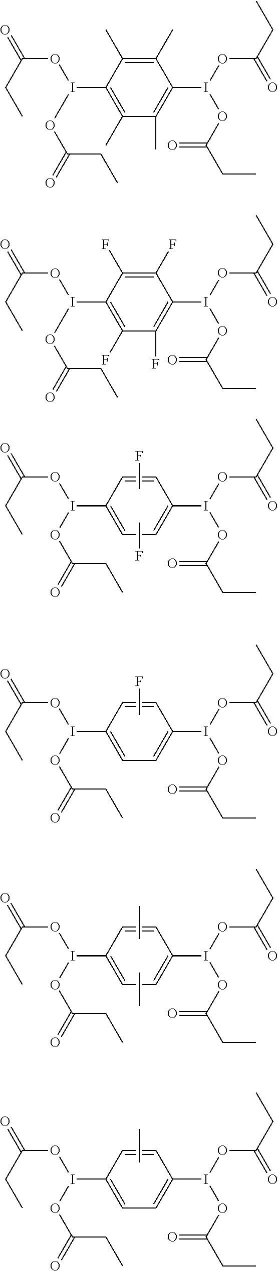

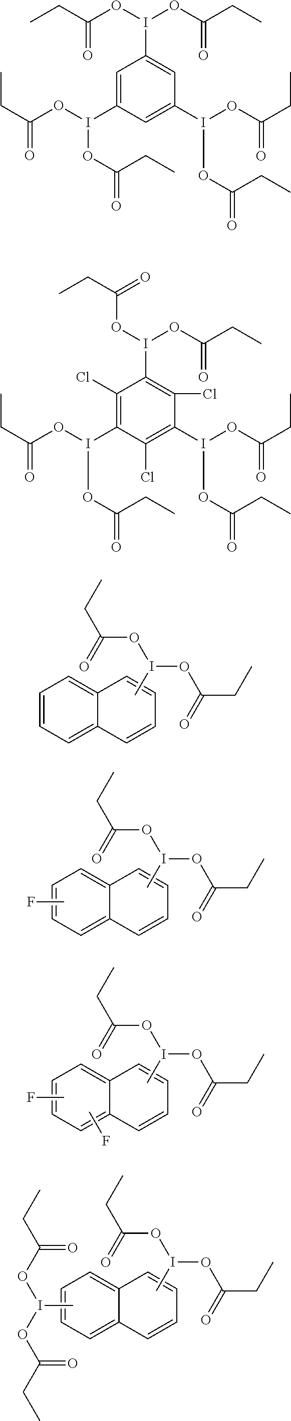

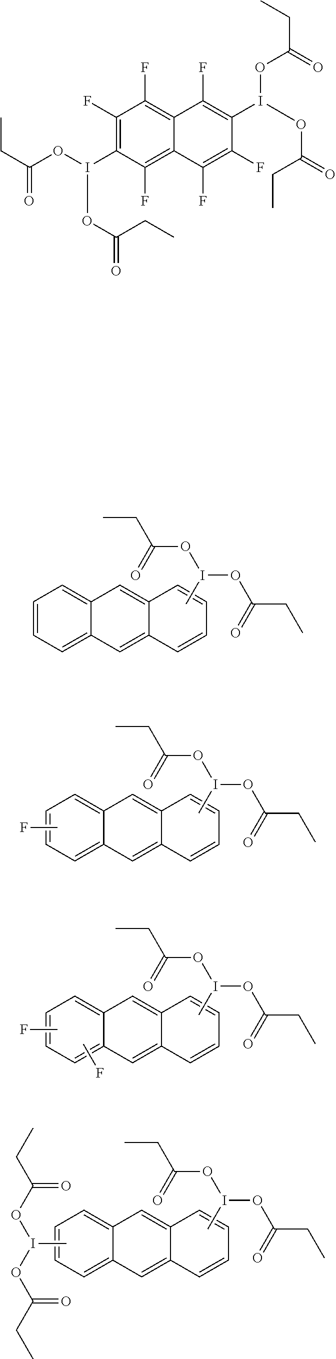

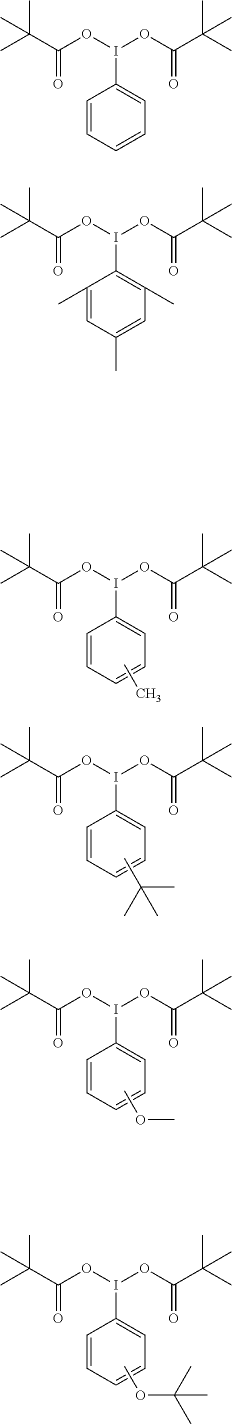

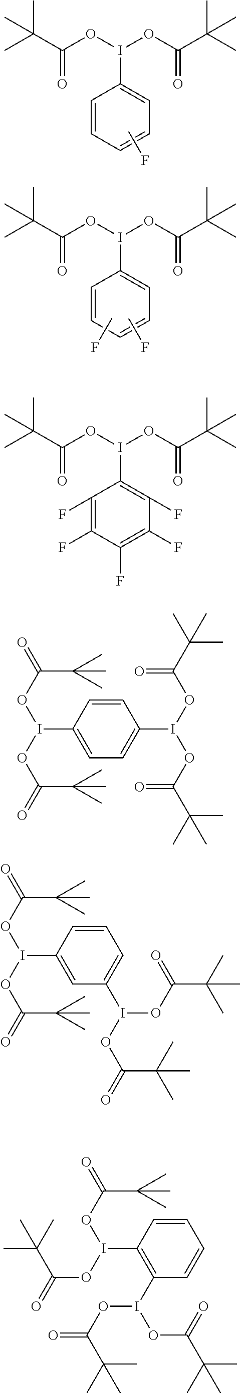

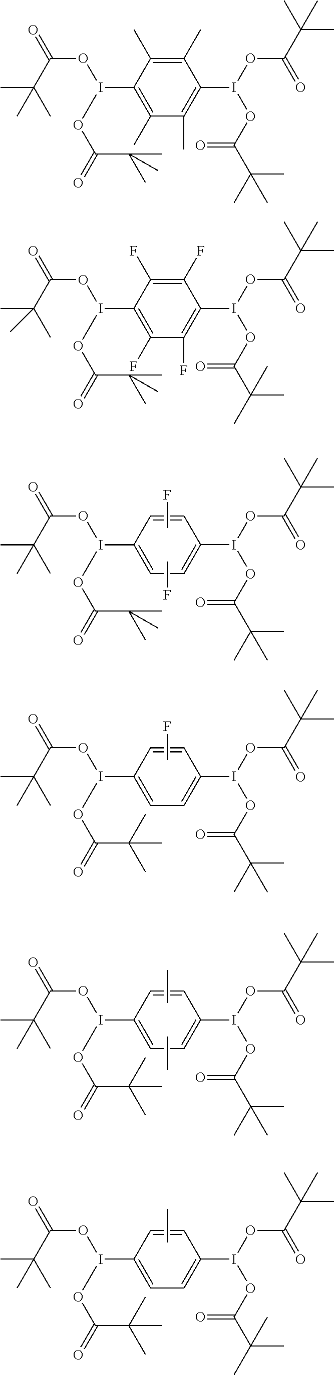

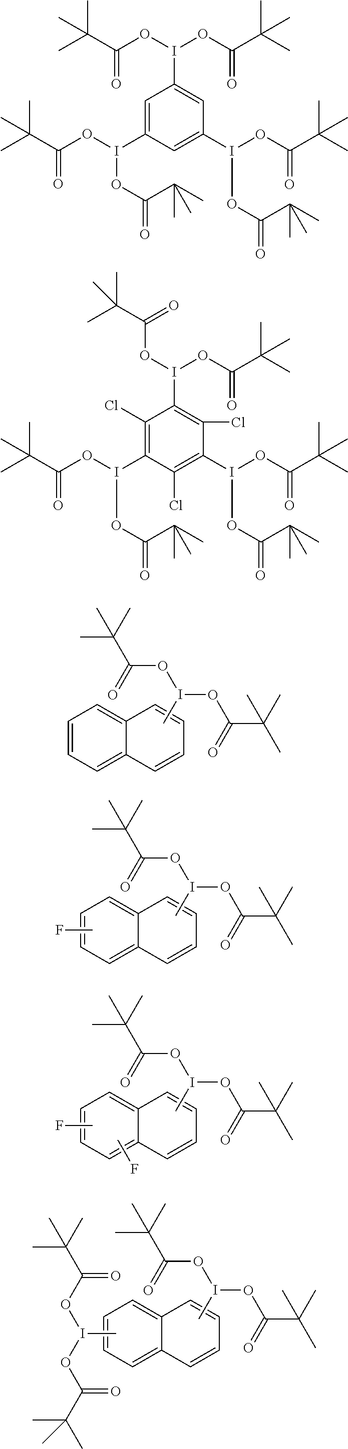

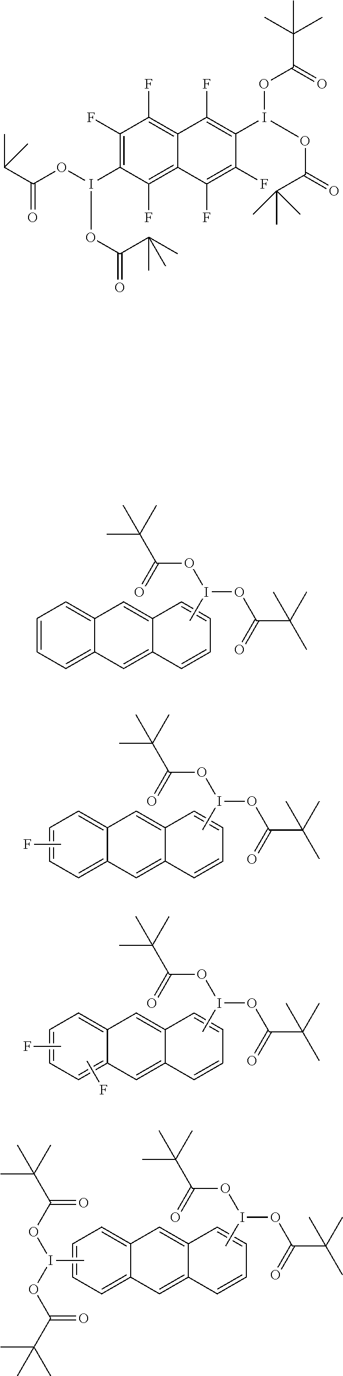

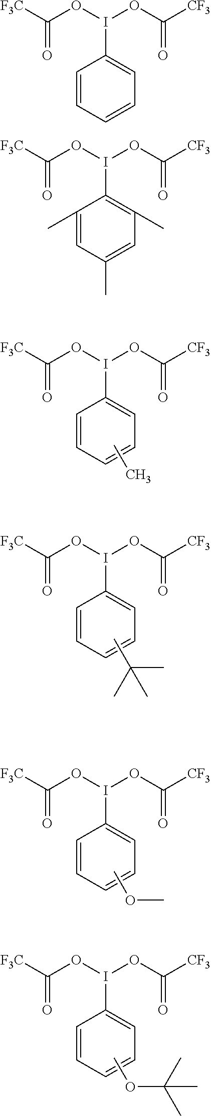

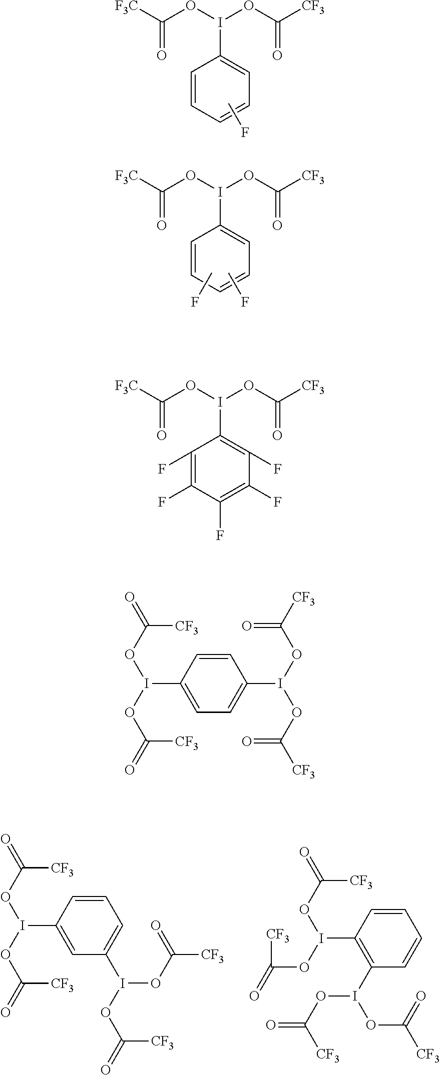

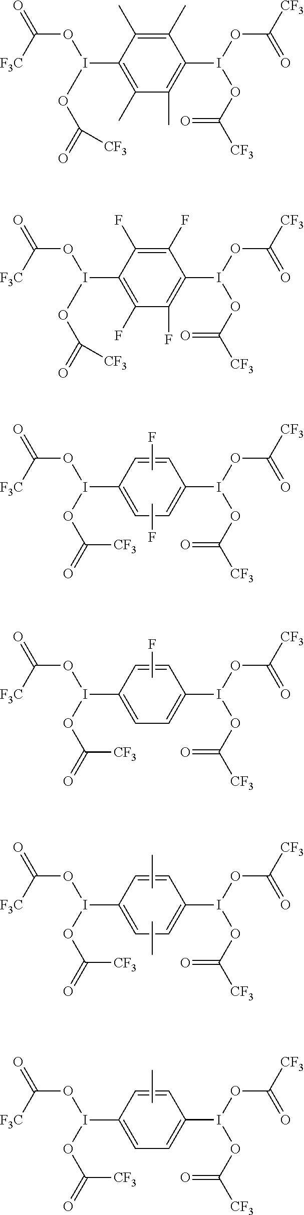

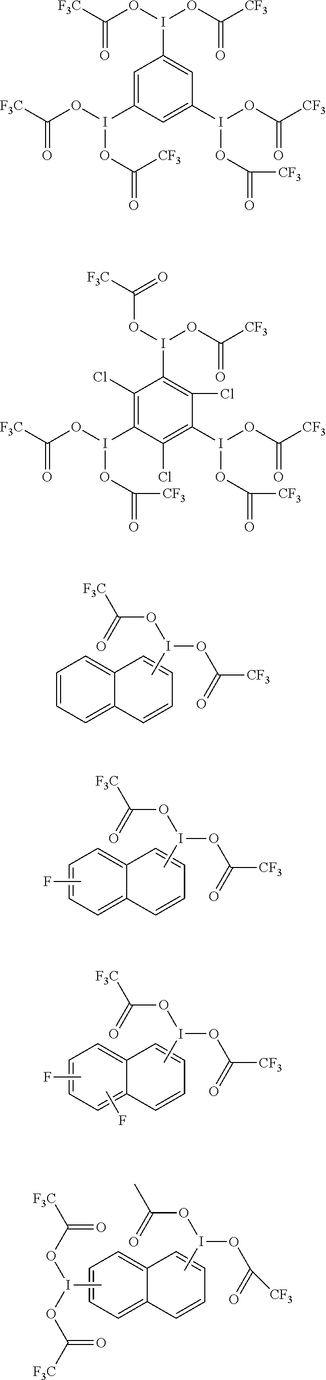

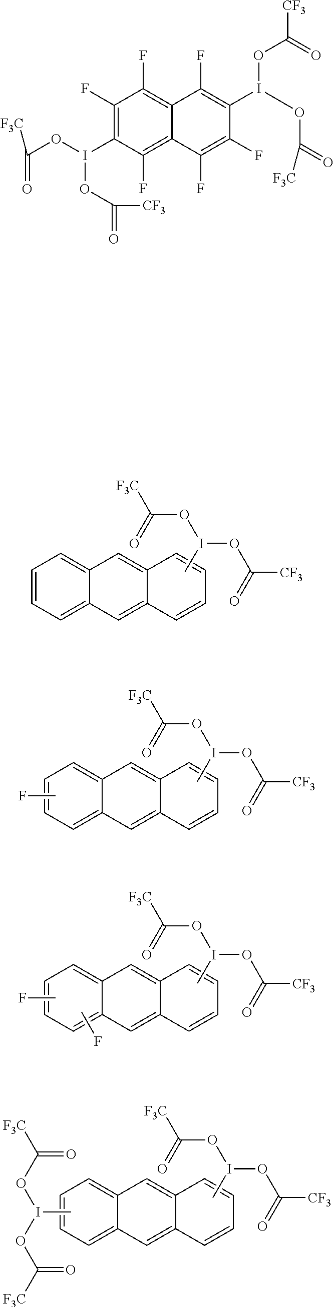

Specific examples of the hypervalent iodine compound represented by the formula (3) include the following, but are not limited thereto.

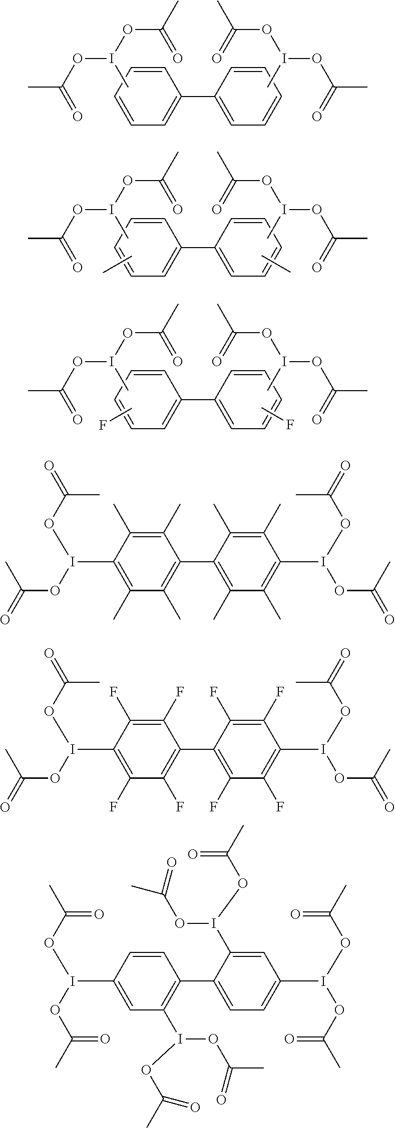

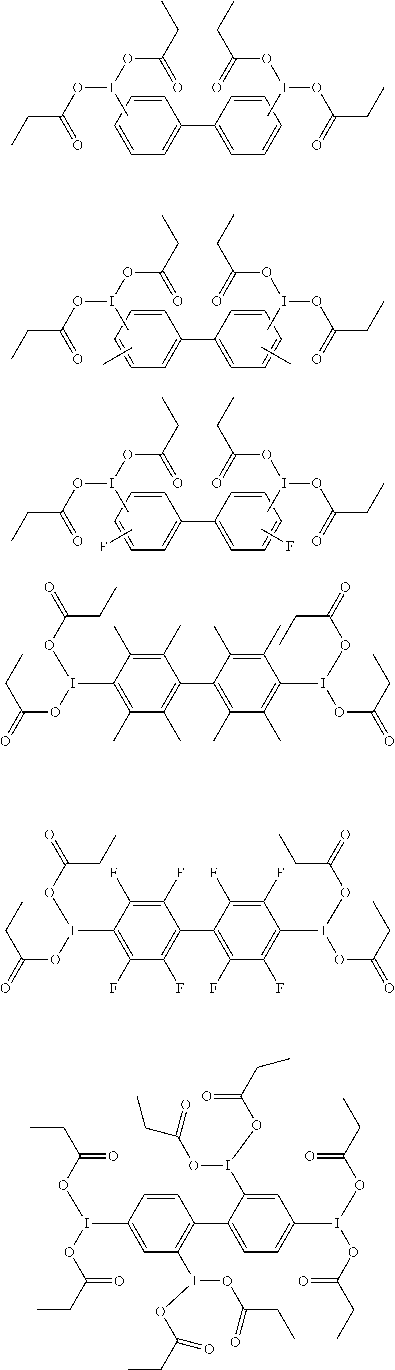

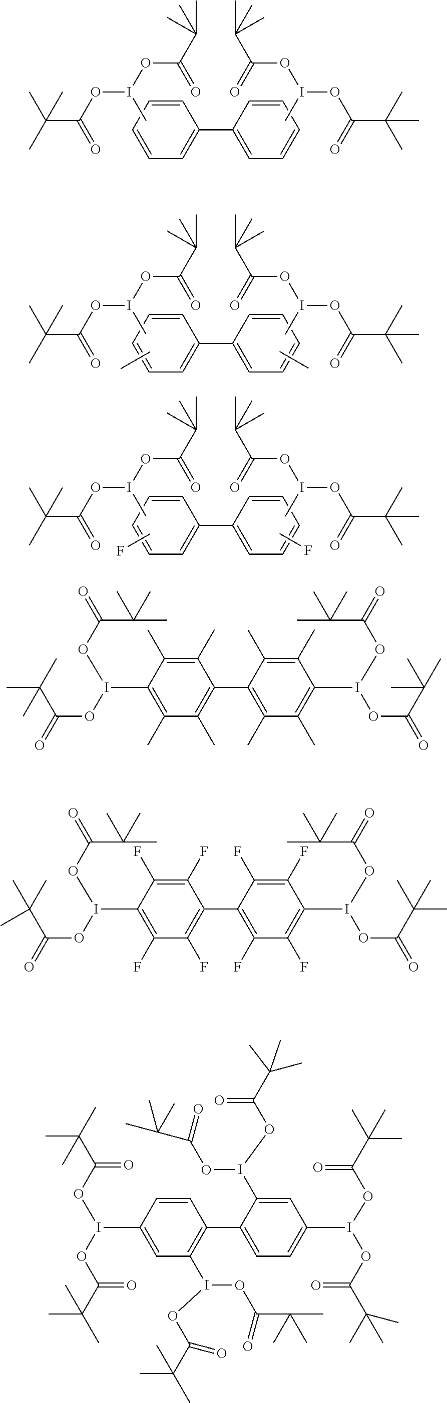

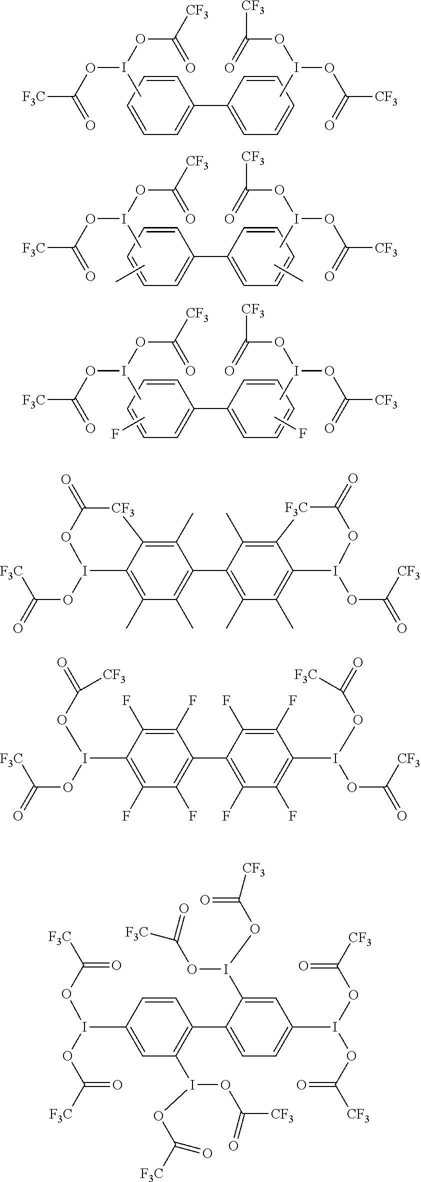

Specific examples of the hypervalent iodine compound represented by the formula (4) include the following, but are not limited thereto.

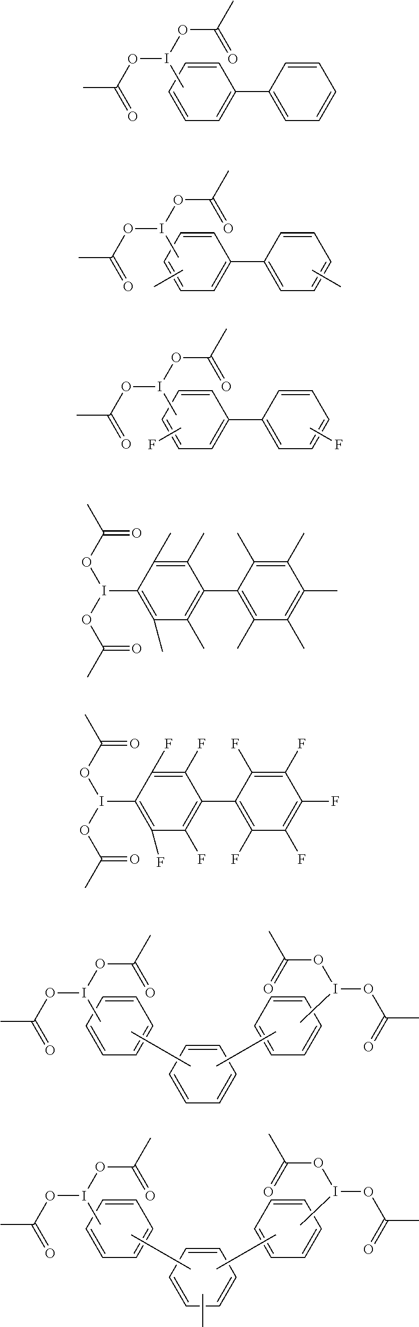

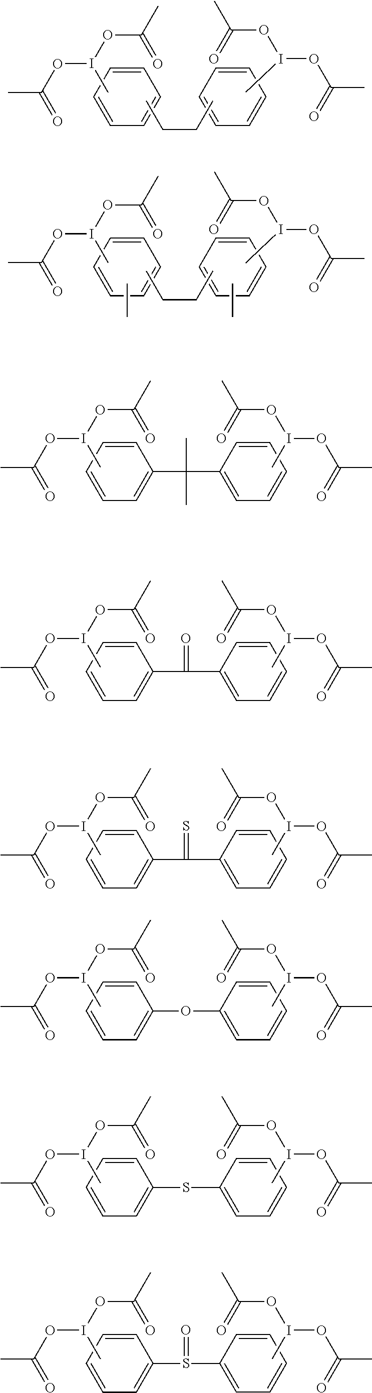

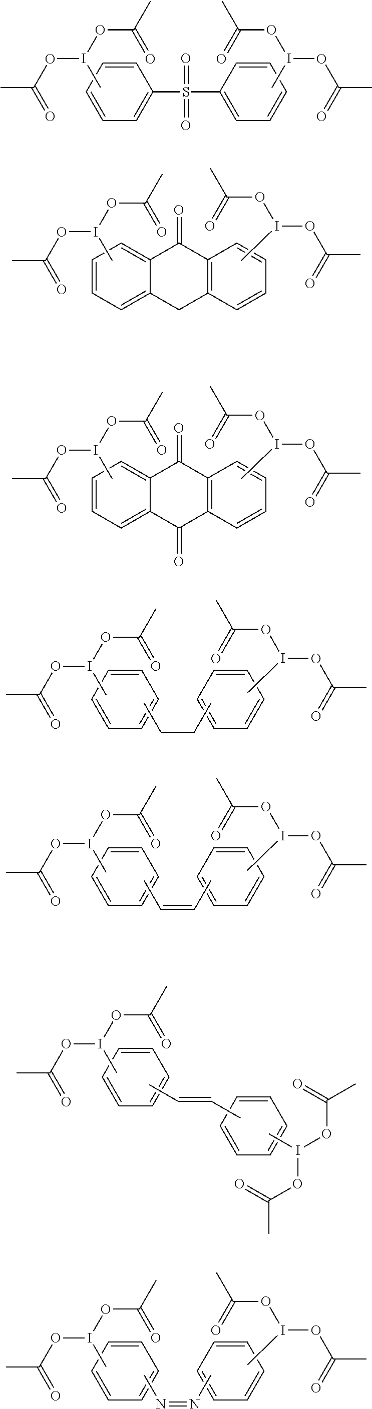

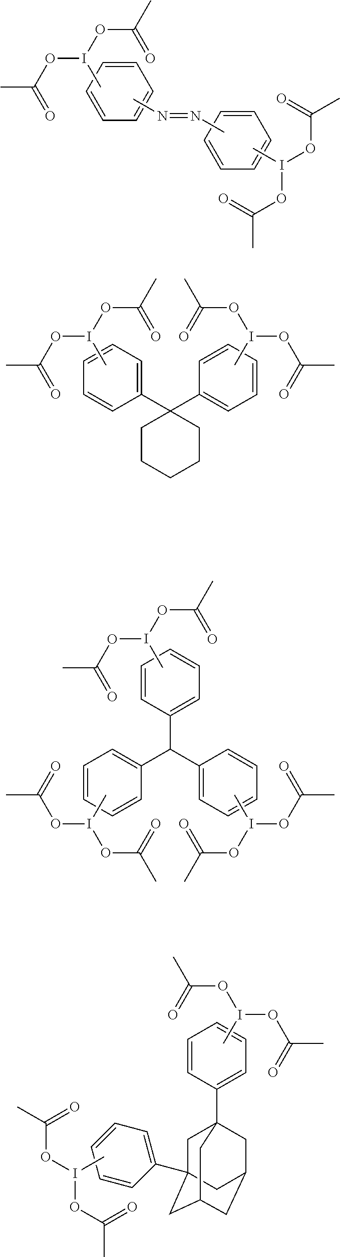

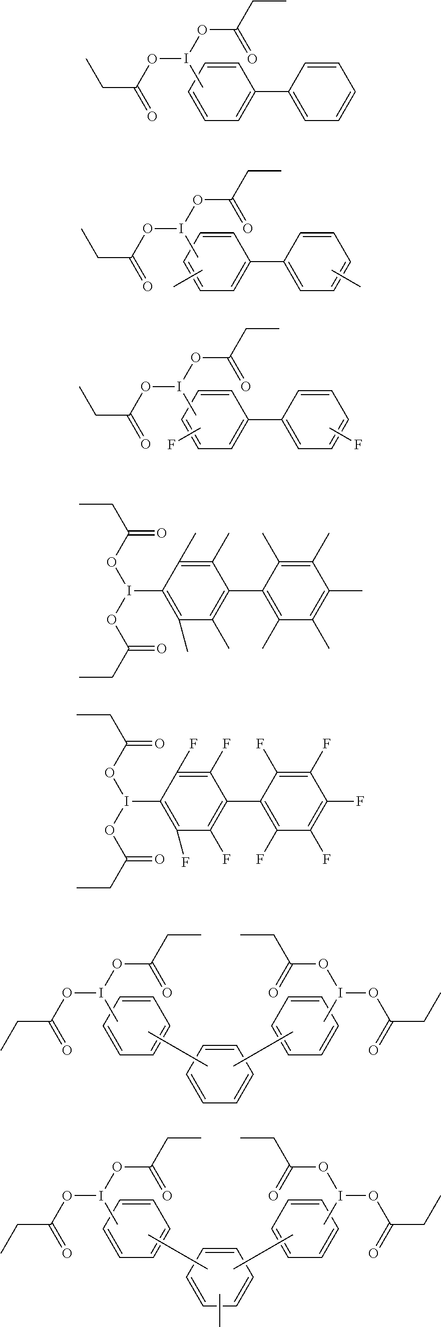

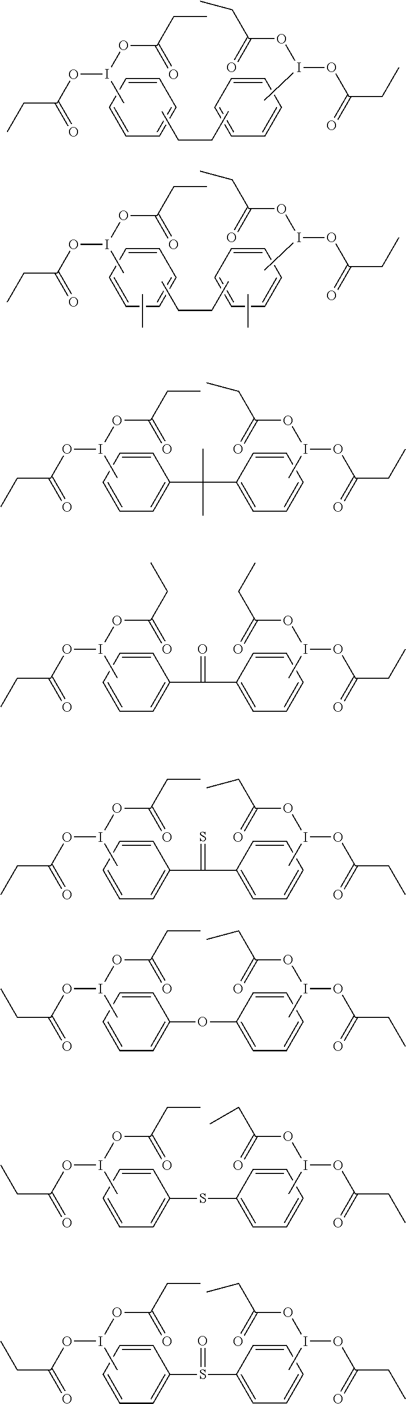

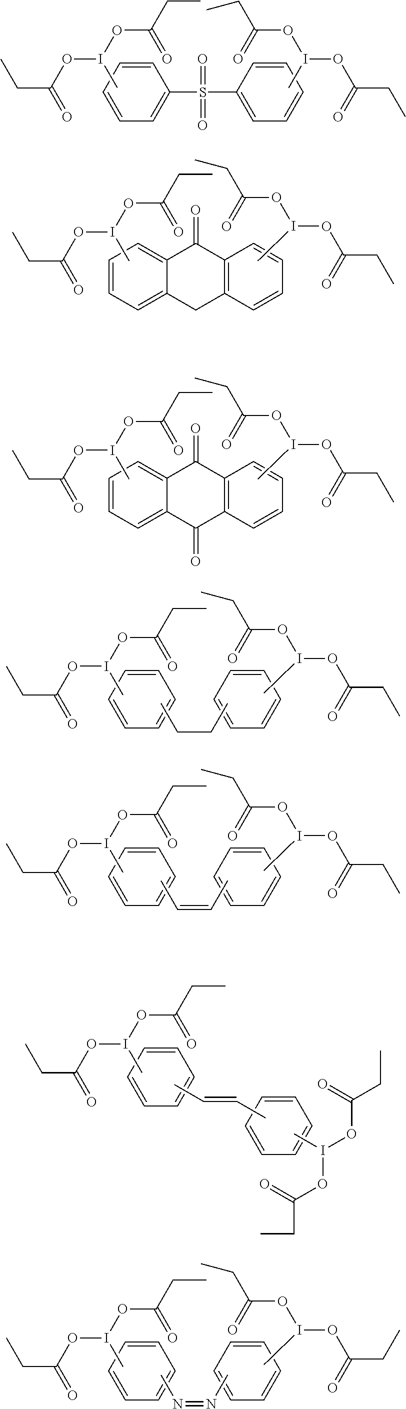

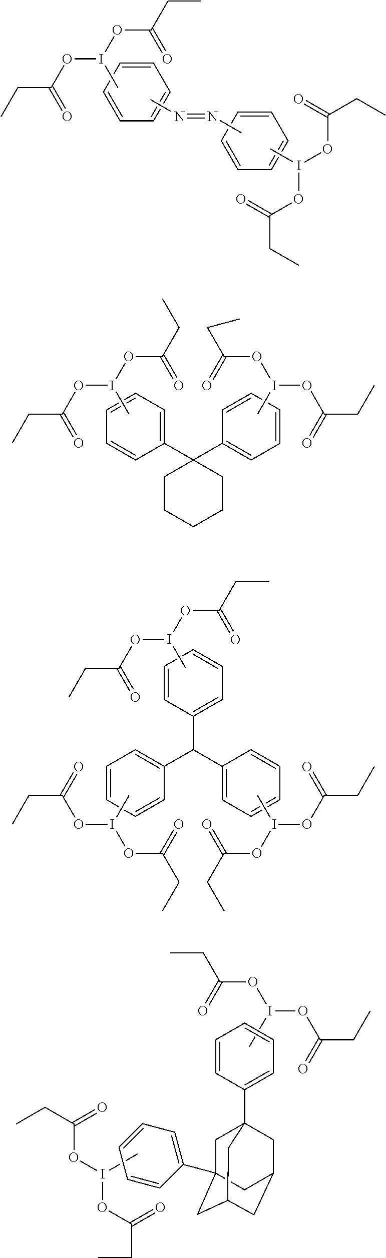

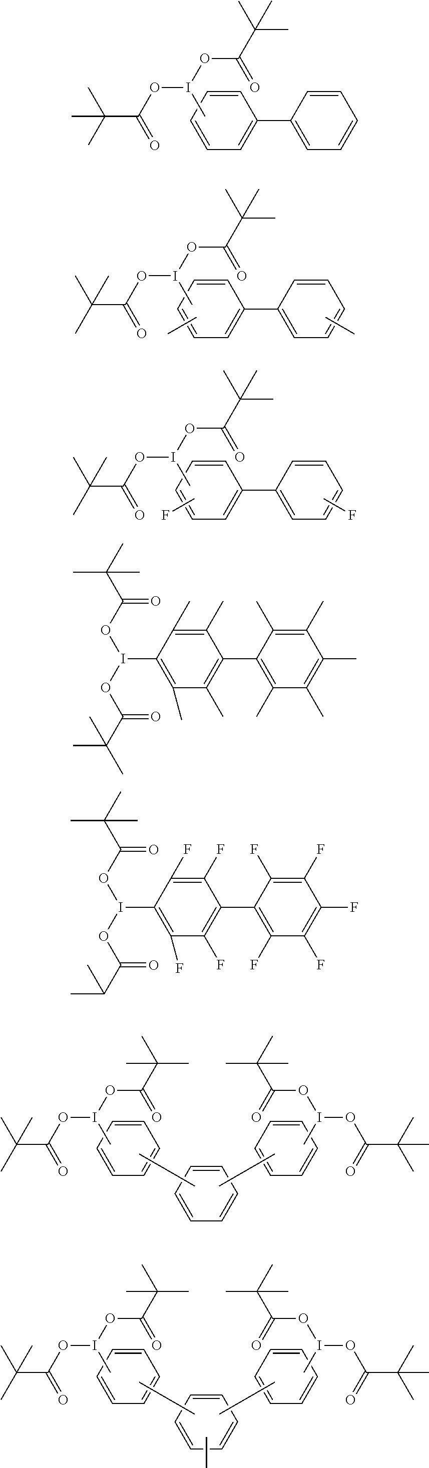

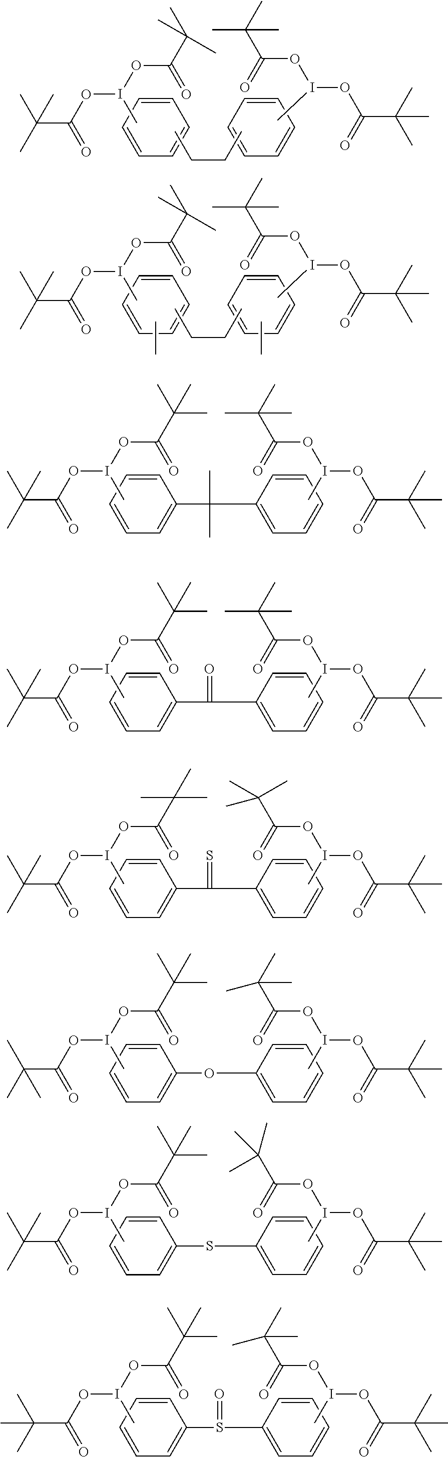

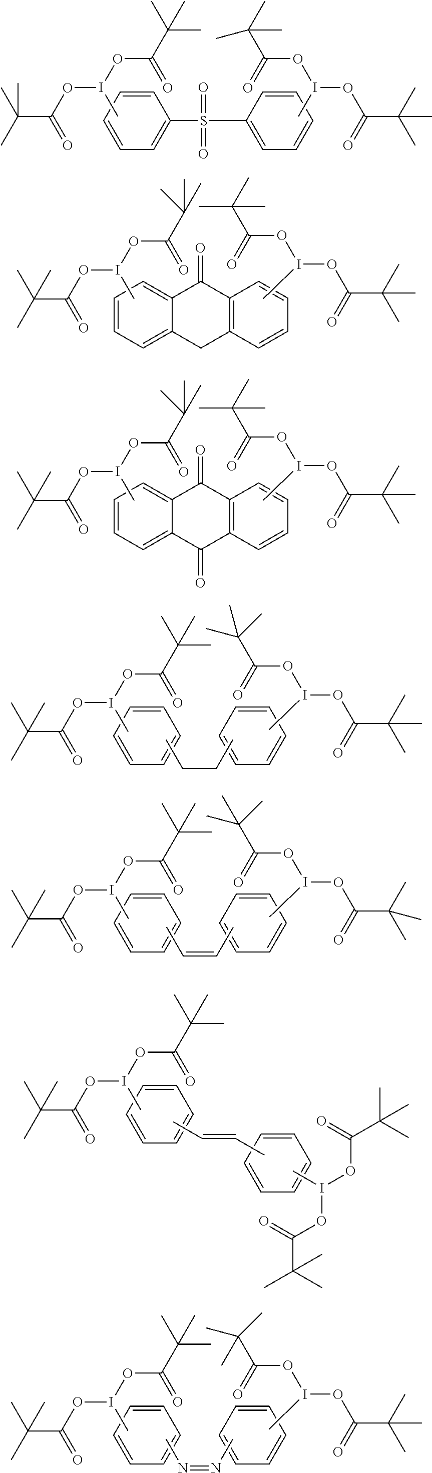

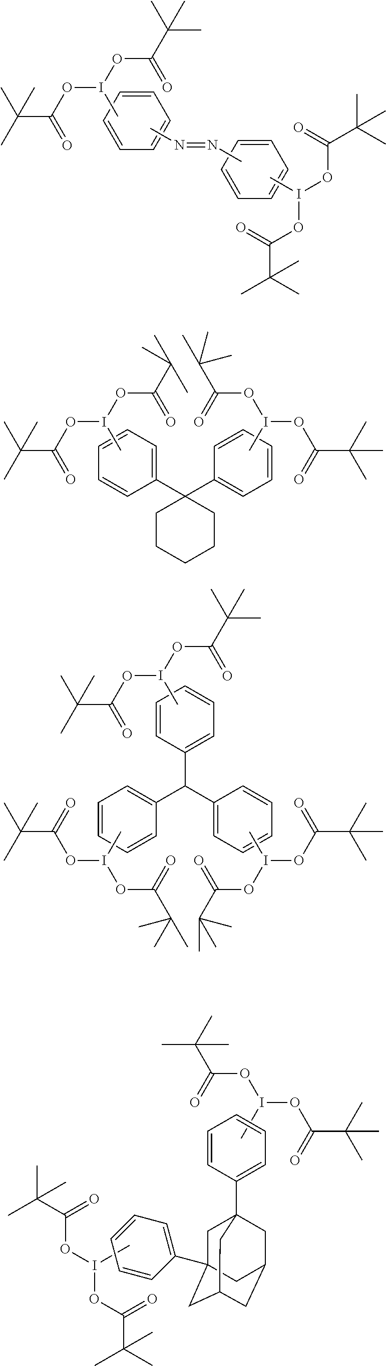

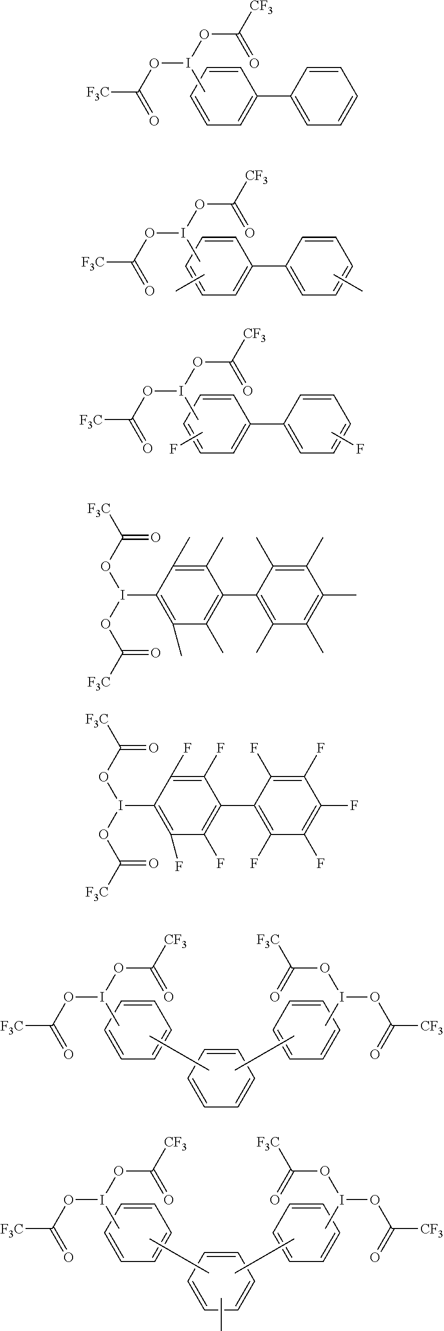

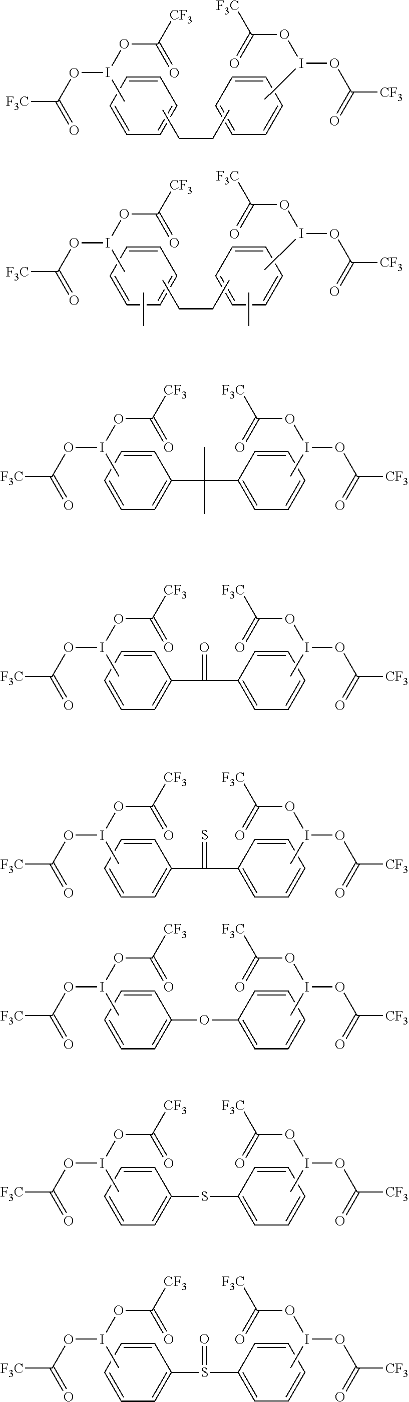

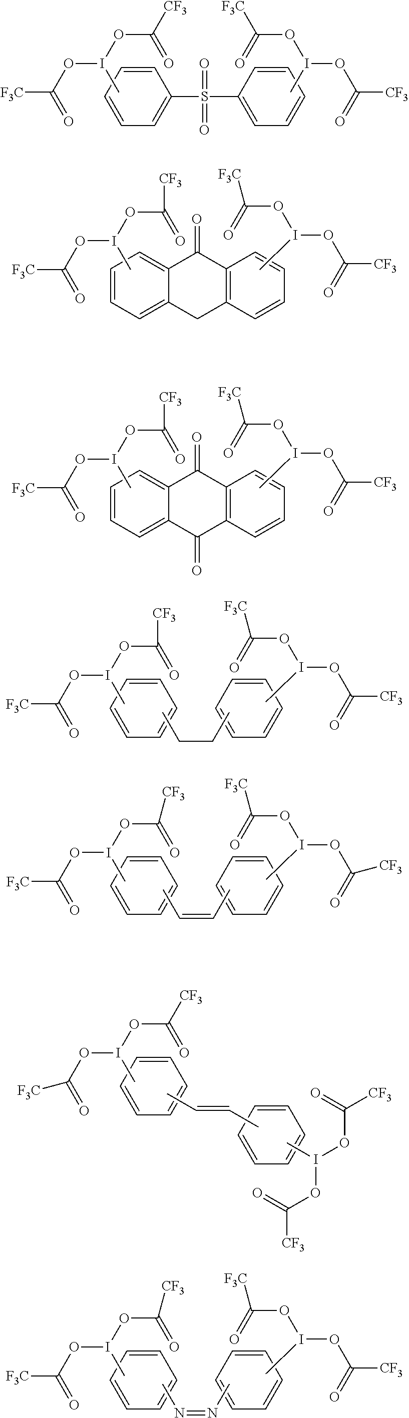

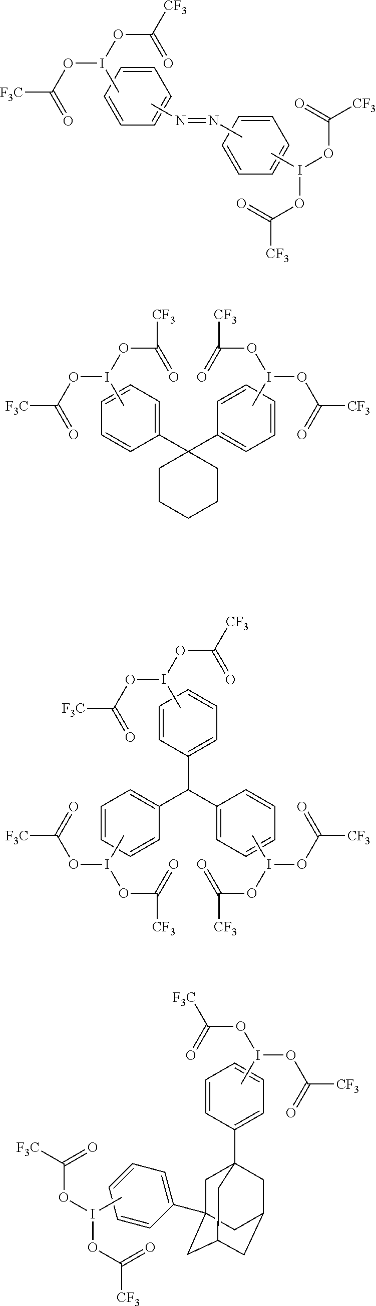

Specific examples of the hypervalent iodine compound represented by the formula (5) include the following, but are not limited thereto. Note that, in the following formulae, Me represents a methyl group.

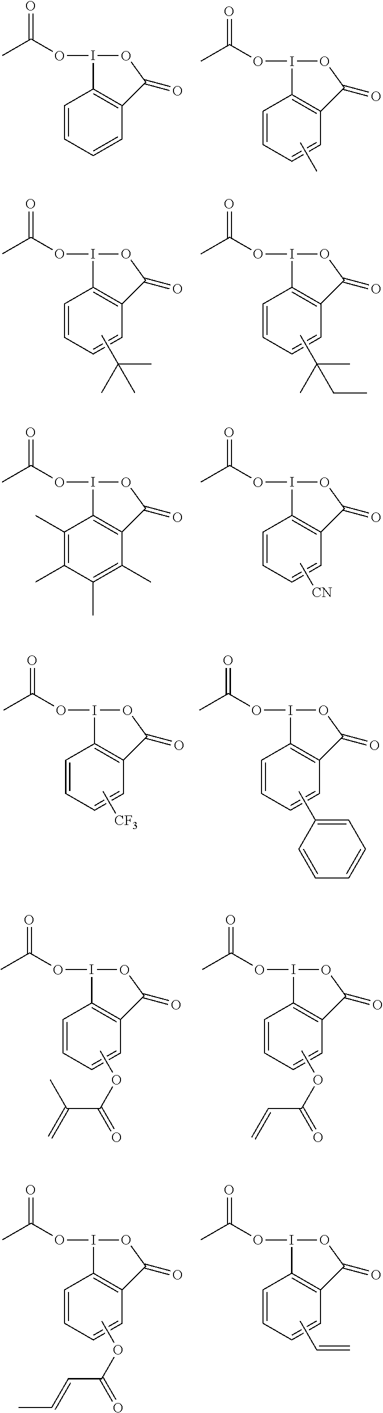

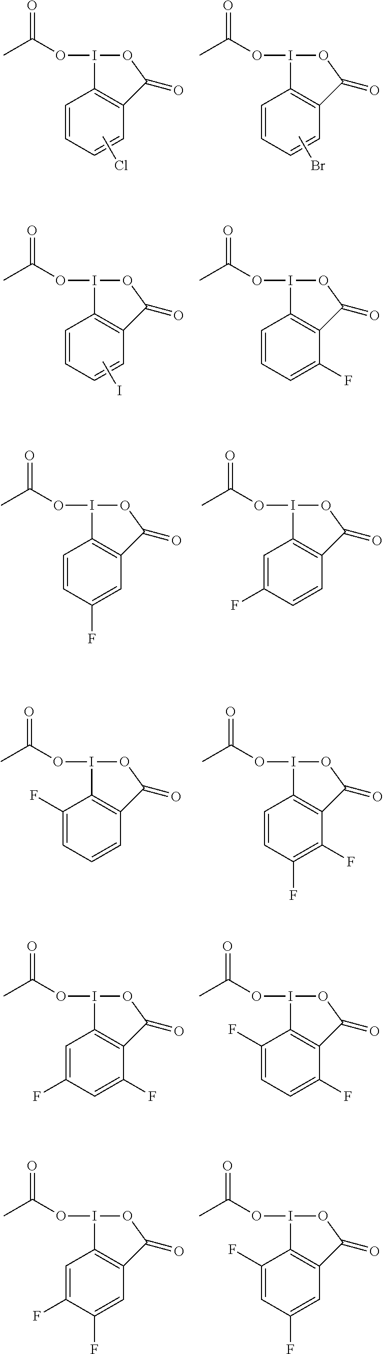

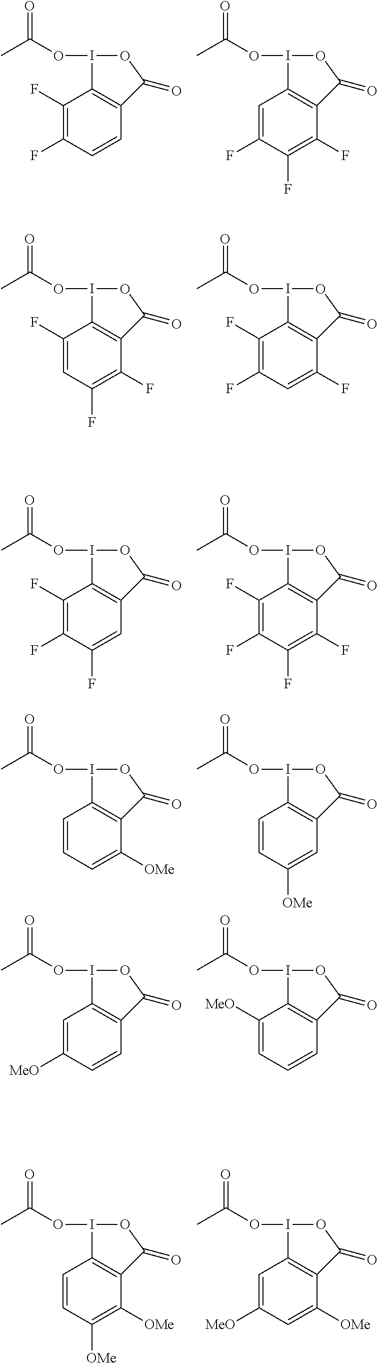

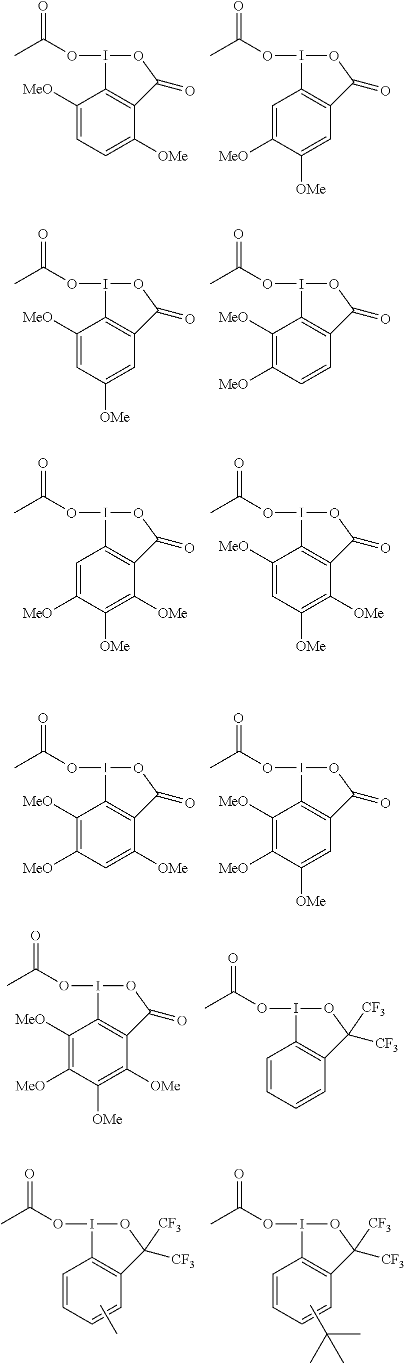

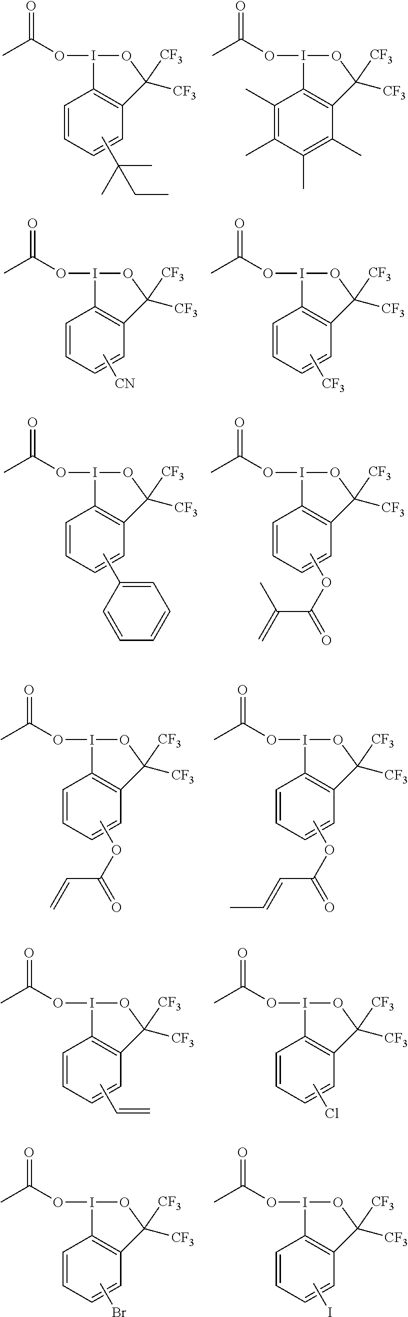

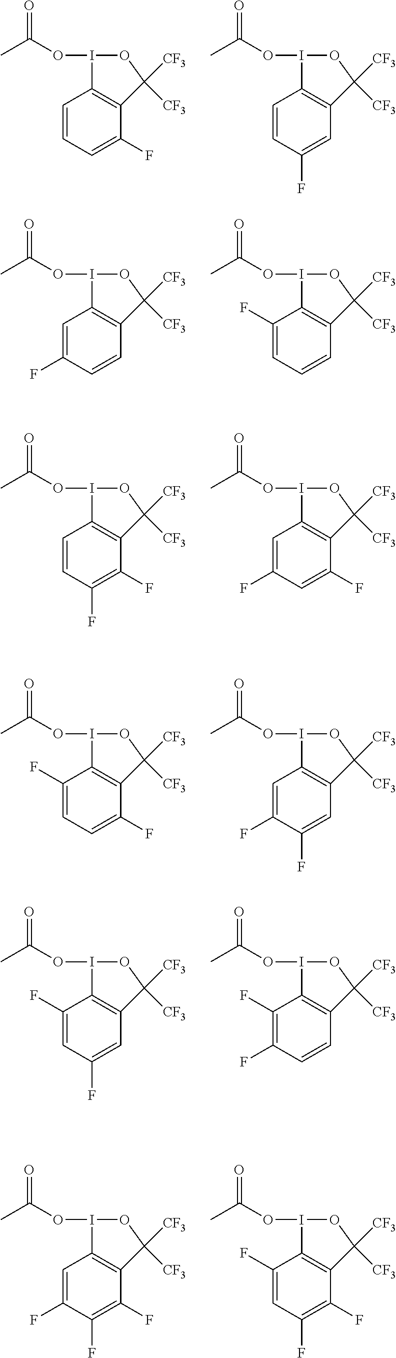

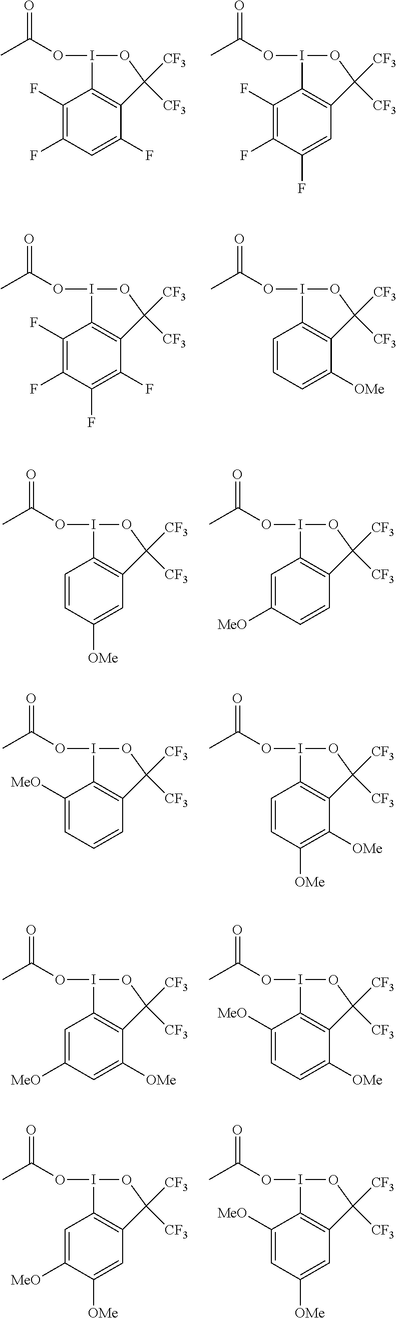

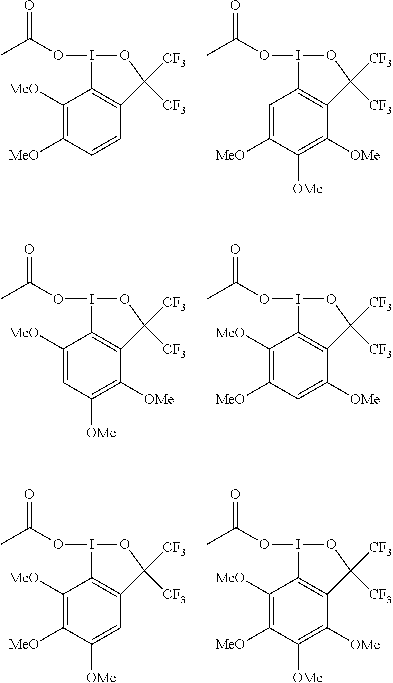

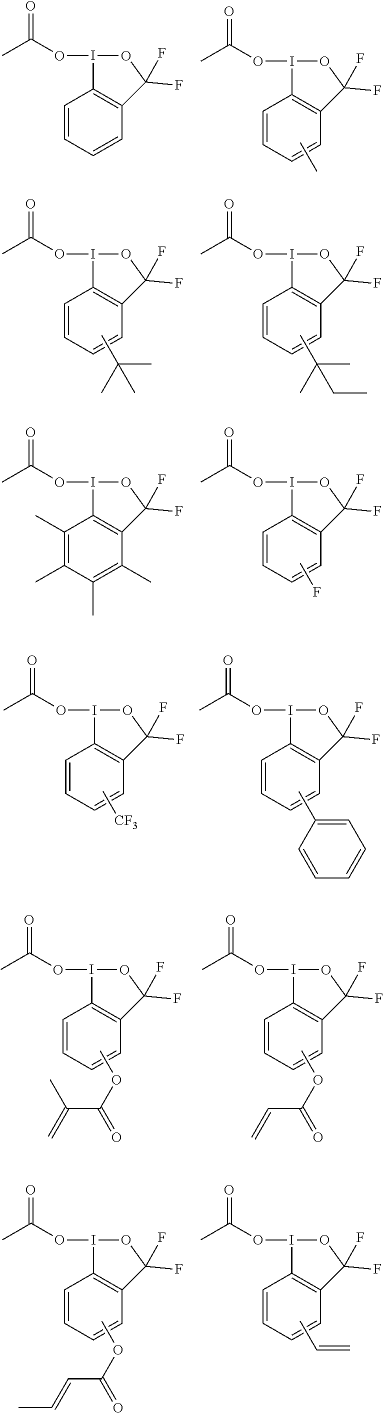

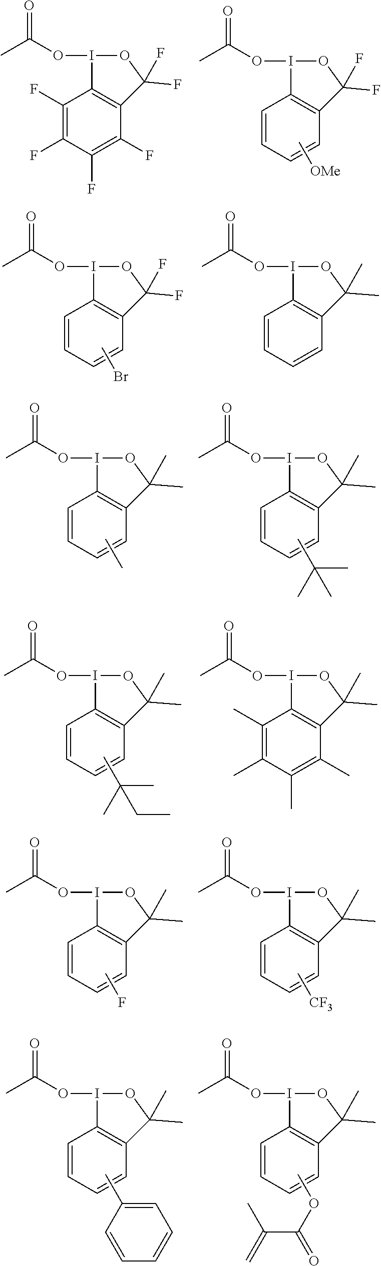

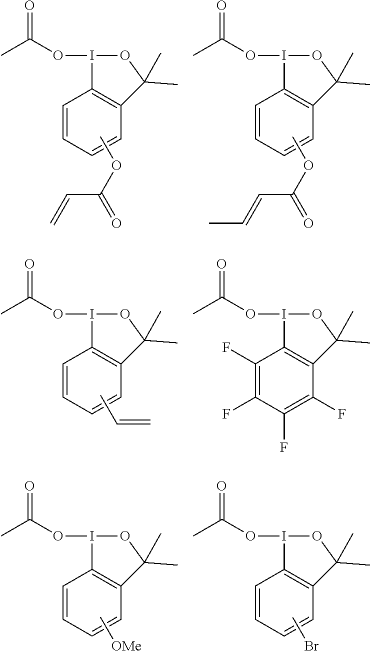

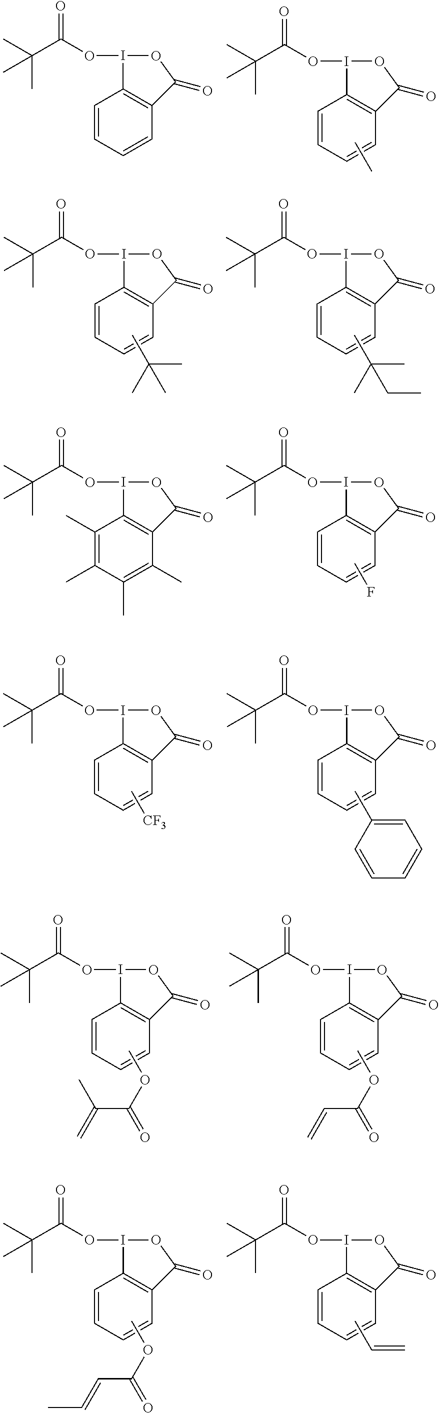

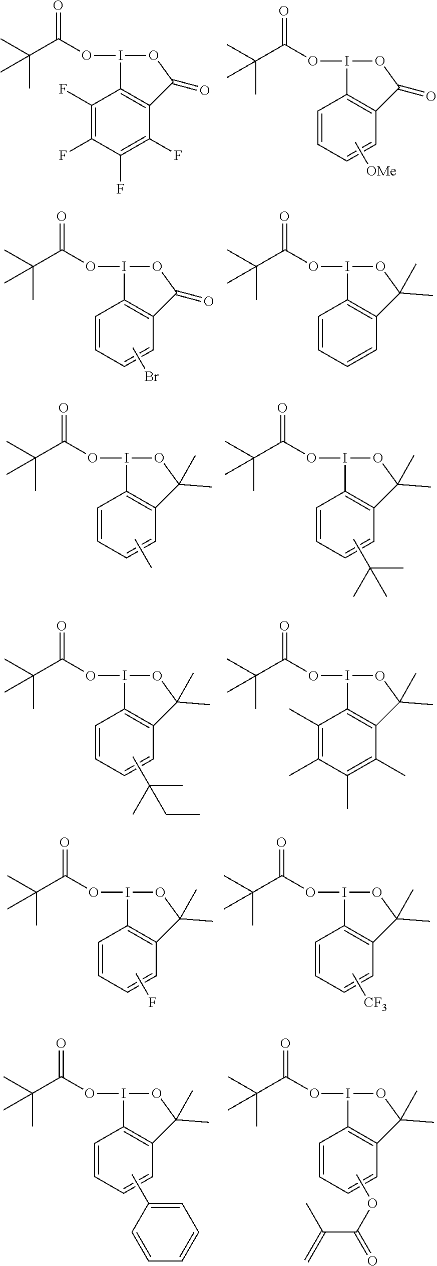

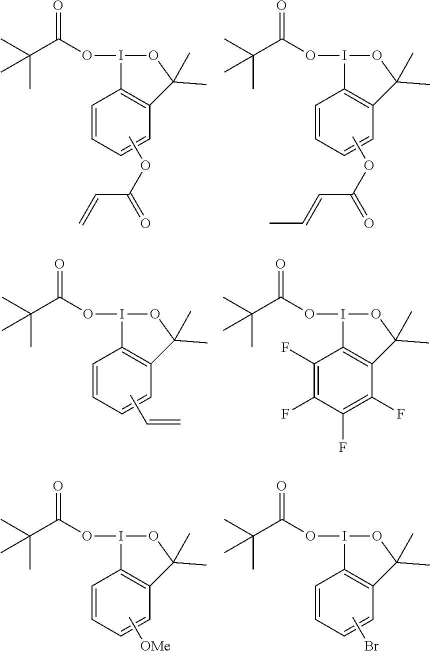

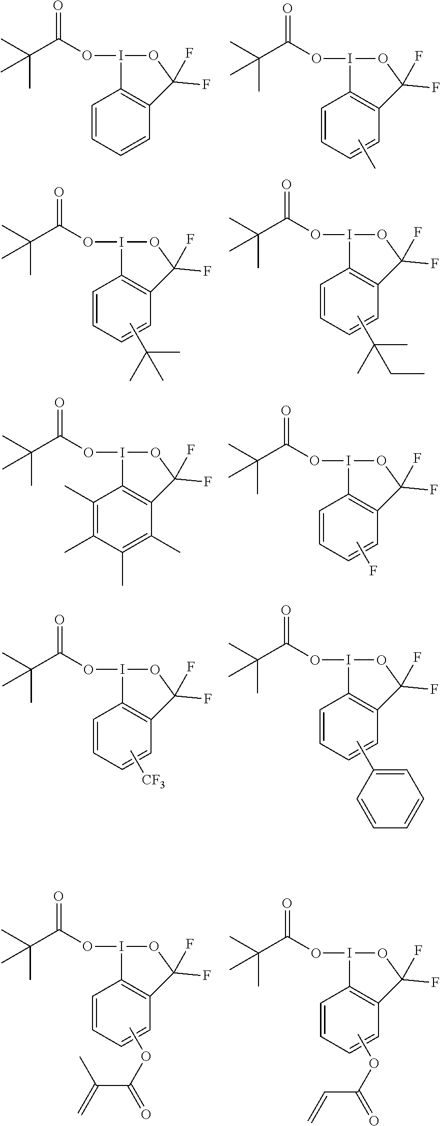

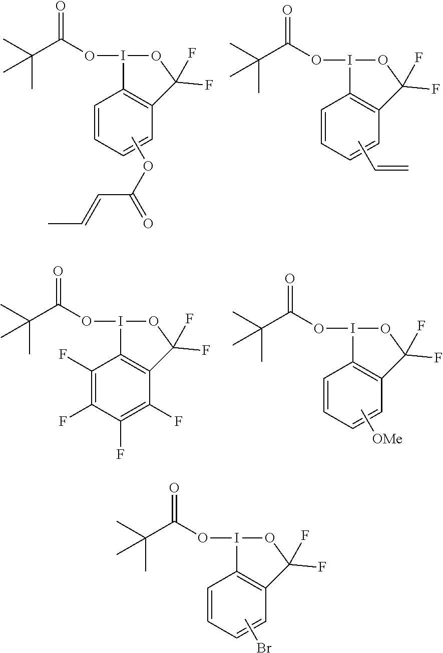

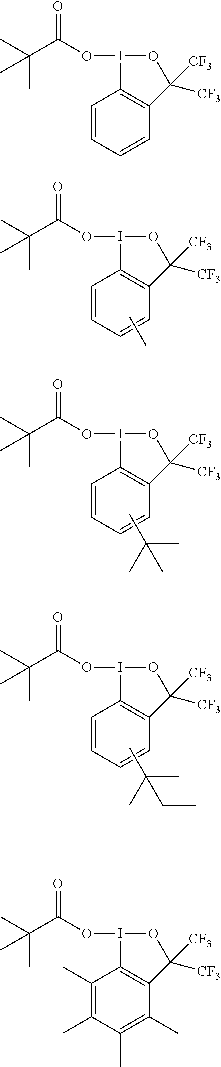

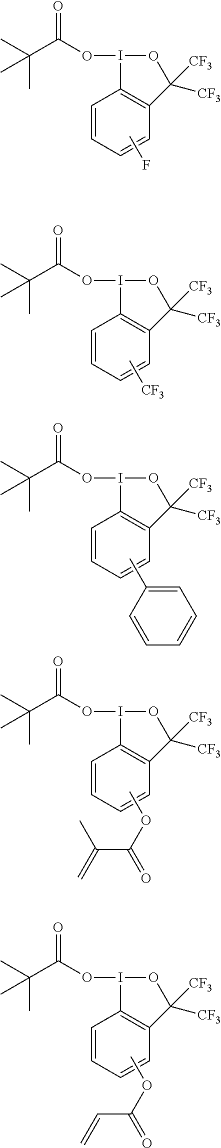

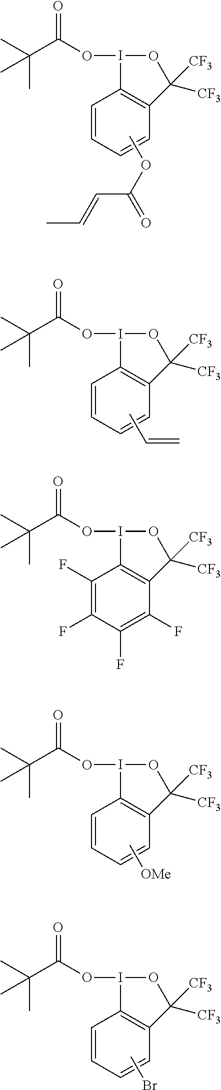

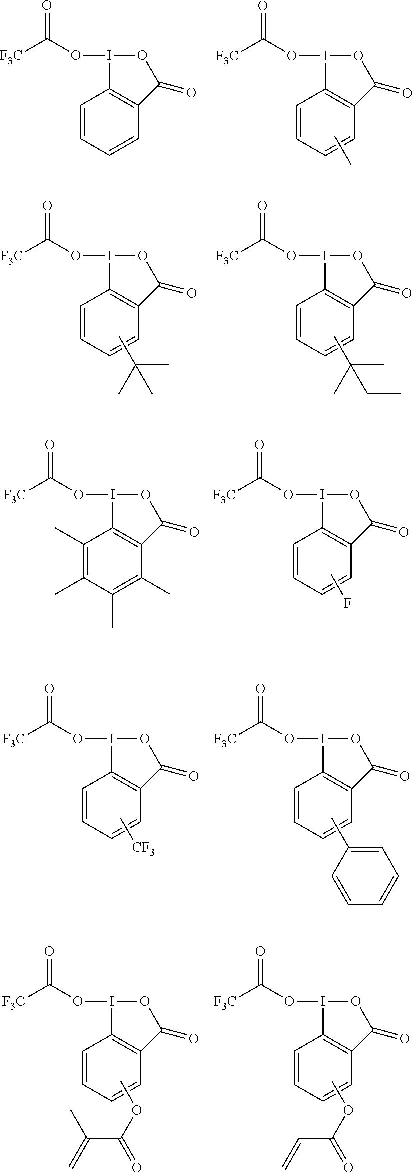

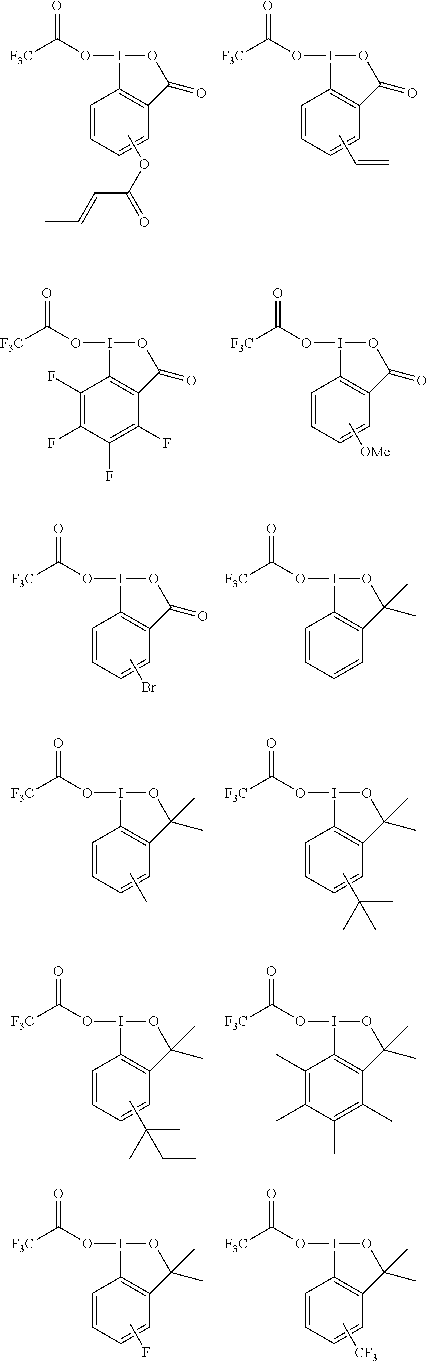

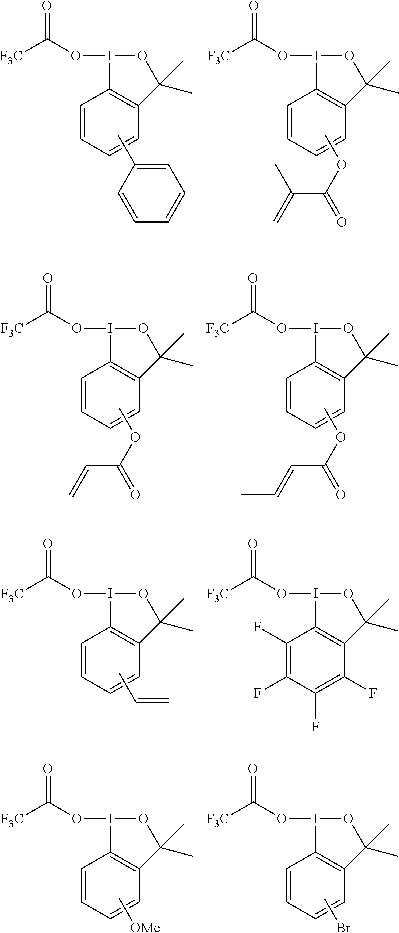

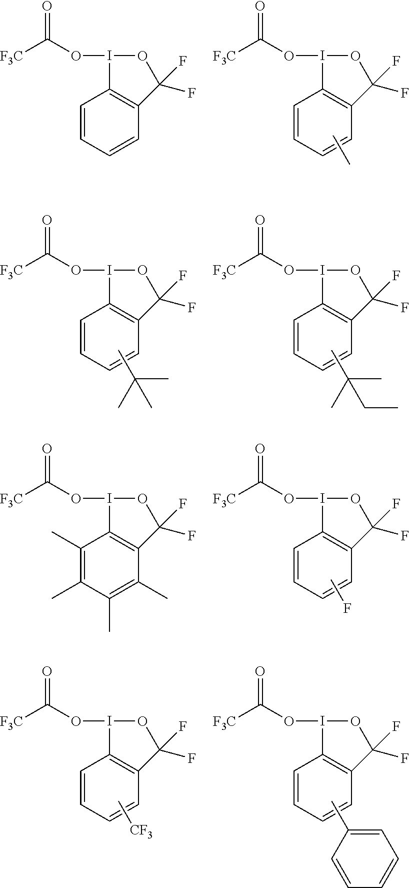

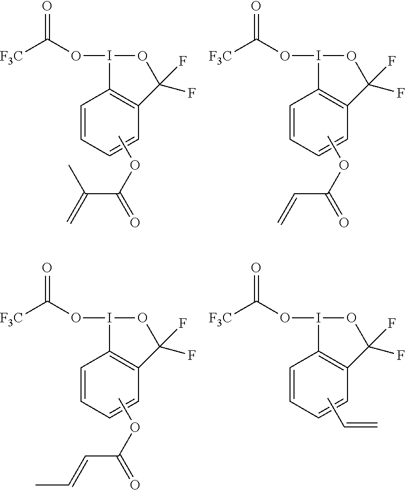

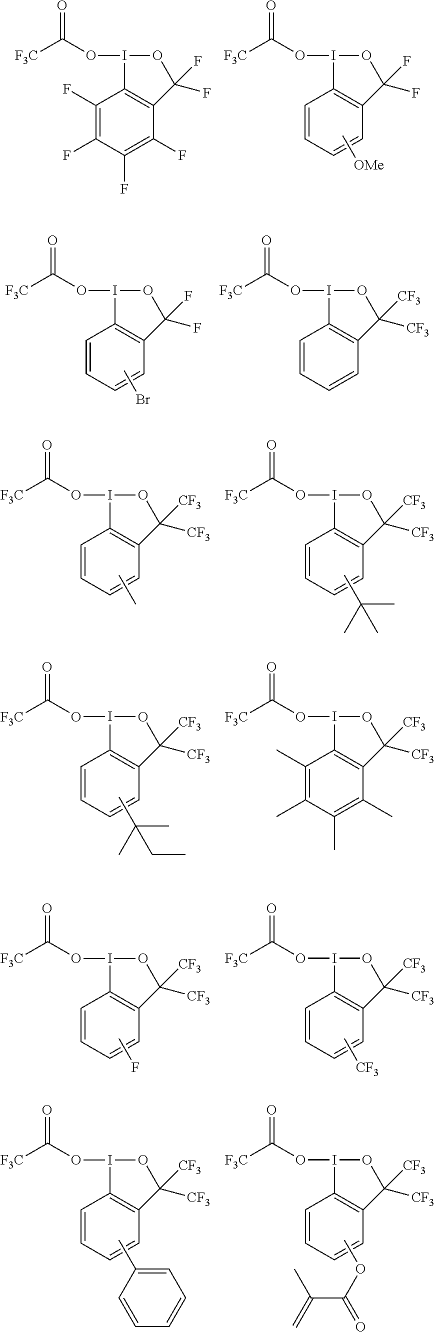

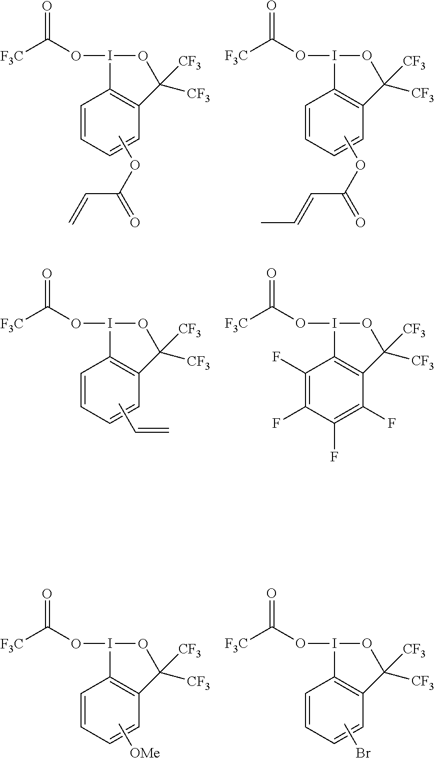

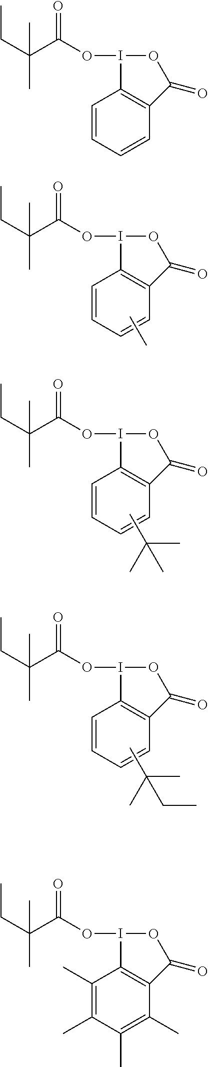

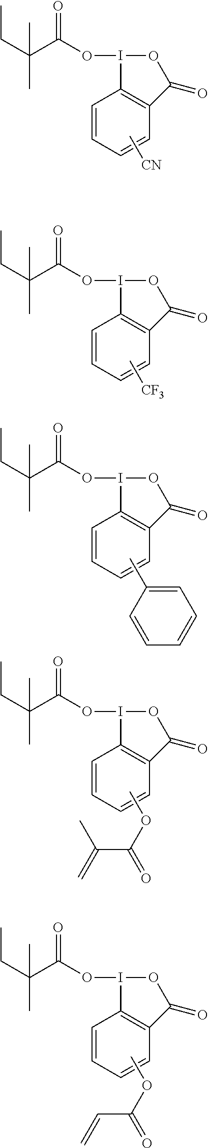

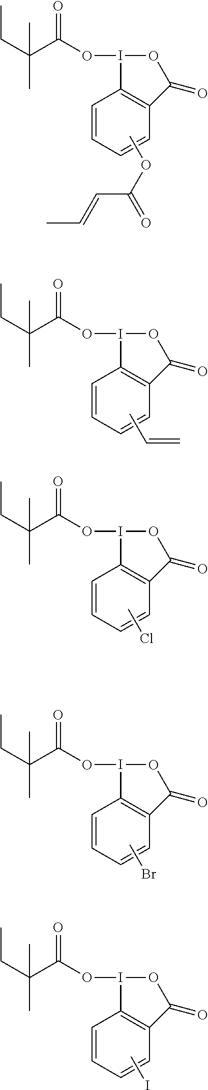

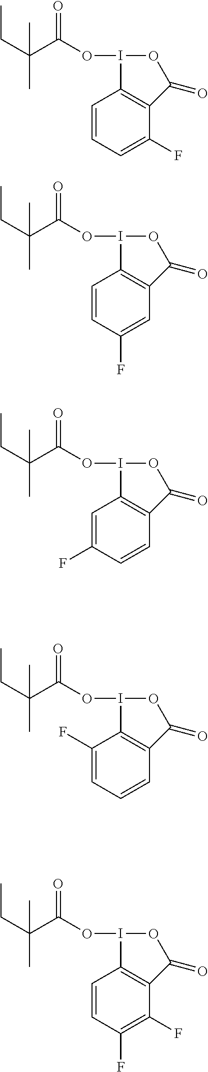 [SMILES: CCC(C)(C)C(=O)OI1OC(=O)c2c(F)cccc21 ; CCC(C)(C)C(=O)OI1OC(=O)c2cc(F)ccc21 ; CCC(C)(C)C(=O)OI1OC(=O)c2ccc(F)cc21 ; CCC(C)(C)C(=O)OI1OC(=O)c2cccc(F)c21 ; CCC(C)(C)C(=O)OI1OC(=O)c2c1ccc(F)c2F]

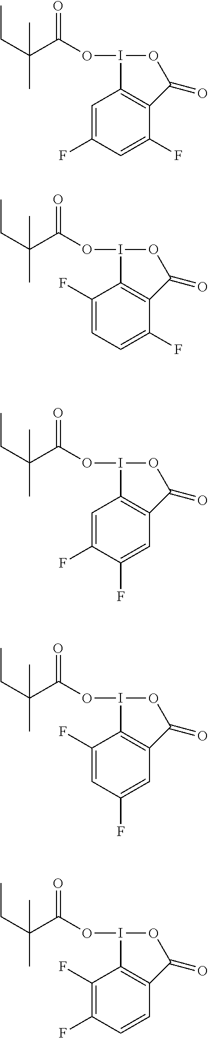

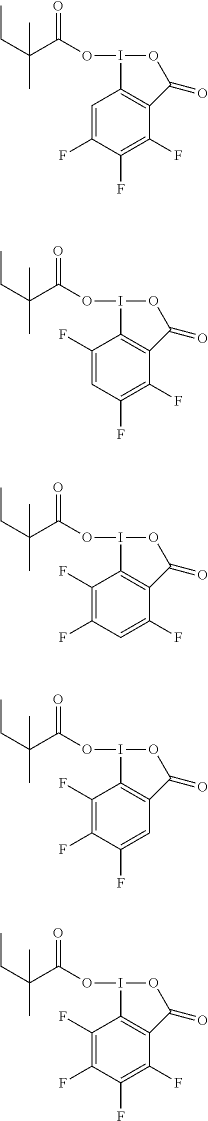 [SMILES: CCC(C)(C)C(=O)OI1OC(=O)c2c1cc(F)c(F)c2F ; CCC(C)(C)C(=O)OI1OC(=O)c2c(F)c(F)cc(F)c21 ; CCC(C)(C)C(=O)OI1OC(=O)c2c(F)cc(F)c(F)c21 ; CCC(C)(C)C(=O)OI1OC(=O)c2cc(F)c(F)c(F)c21 ; CCC(C)(C)C(=O)OI1OC(=O)c2c(F)c(F)c(F)c(F)c21]

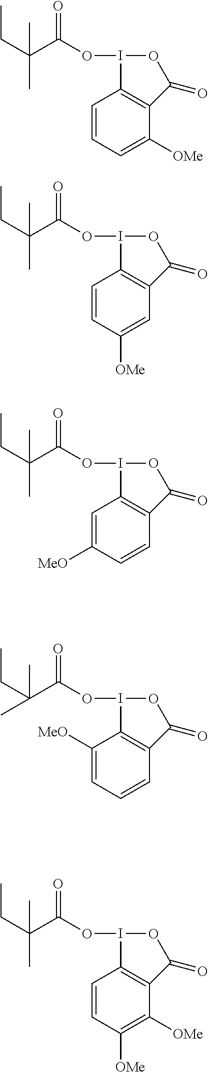 [SMILES: CCC(C)(C)C(=O)OI1OC(=O)c2c(OC)cccc21 ; CCC(C)(C)C(=O)OI1OC(=O)c2cc(OC)ccc21 ; CCC(C)(C)C(=O)OI1OC(=O)c2ccc(OC)cc21 ; CCC(C)(C)C(=O)OI1OC(=O)c2cccc(OC)c21 ; CCC(C)(C)C(=O)OI1OC(=O)c2c1ccc(OC)c2OC]

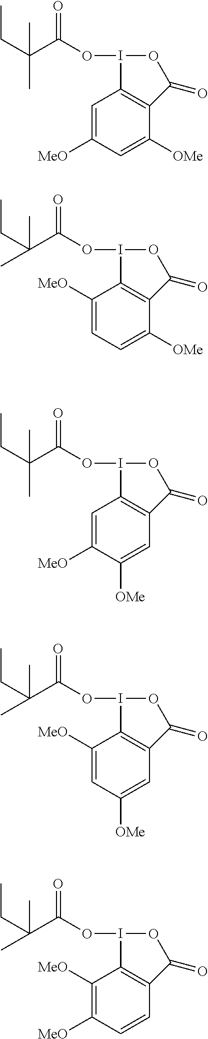

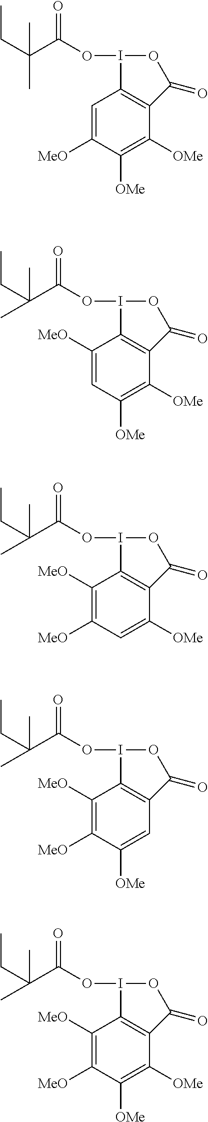 [SMILES: CCC(C)(C)C(=O)OI1OC(=O)c2c1cc(OC)c(OC)c2OC ; CCC(C)(C)C(=O)OI1OC(=O)c2c(OC)c(OC)cc(OC)c21 ; CCC(C)(C)C(=O)OI1OC(=O)c2c(OC)cc(OC)c(OC)c21 ; CCC(C)(C)C(=O)OI1OC(=O)c2cc(OC)c(OC)c(OC)c21 ; CCC(C)(C)C(=O)OI1OC(=O)c2c(OC)c(OC)c(OC)c(OC)c21]

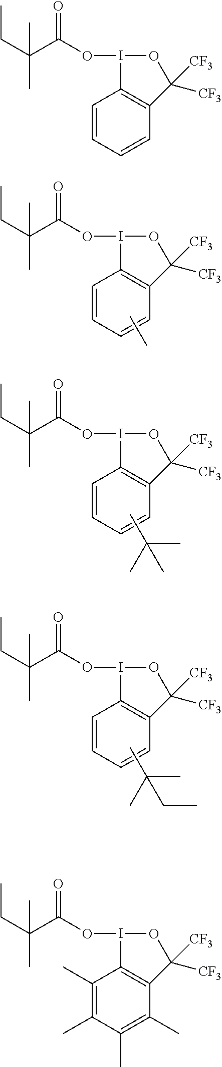

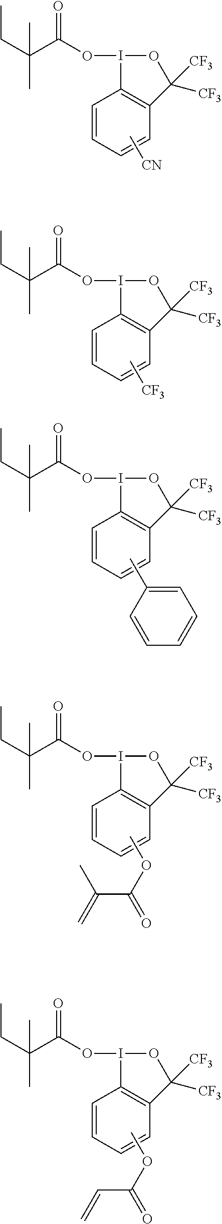

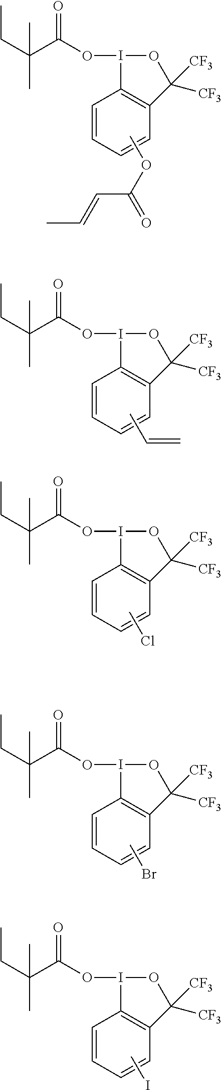

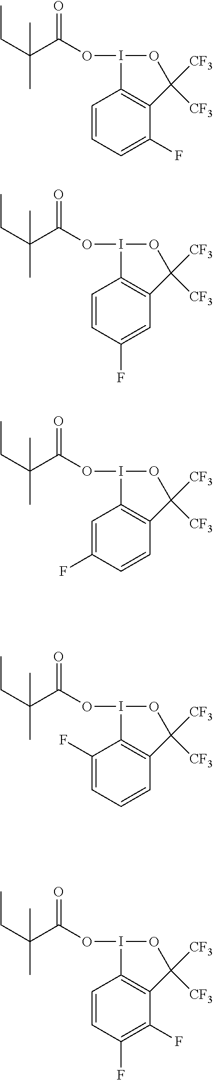 [SMILES: CCC(C)(C)C(=O)OI1OC(C(F)(F)F)(C(F)(F)F)c2c(F)cccc21 ; CCC(C)(C)C(=O)OI1OC(C(F)(F)F)(C(F)(F)F)c2cc(F)ccc21 ; CCC(C)(C)C(=O)OI1OC(C(F)(F)F)(C(F)(F)F)c2ccc(F)cc21 ; CCC(C)(C)C(=O)OI1OC(C(F)(F)F)(C(F)(F)F)c2cccc(F)c21 ; CCC(C)(C)C(=O)OI1OC(C(F)(F)F)(C(F)(F)F)c2c1ccc(F)c2F]

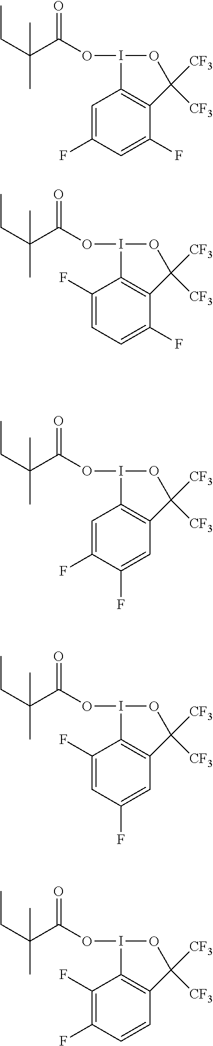

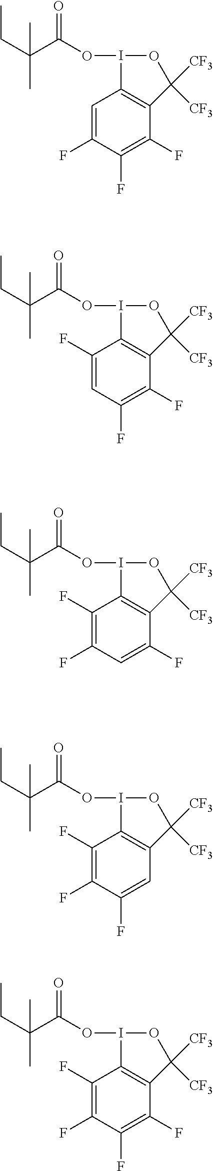 [SMILES: CCC(C)(C)C(=O)OI1OC(C(F)(F)F)(C(F)(F)F)c2c1cc(F)c(F)c2F ; CCC(C)(C)C(=O)OI1OC(C(F)(F)F)(C(F)(F)F)c2c(F)c(F)cc(F)c21 ; CCC(C)(C)C(=O)OI1OC(C(F)(F)F)(C(F)(F)F)c2c(F)cc(F)c(F)c21 ; CCC(C)(C)C(=O)OI1OC(C(F)(F)F)(C(F)(F)F)c2cc(F)c(F)c(F)c21 ; CCC(C)(C)C(=O)OI1OC(C(F)(F)F)(C(F)(F)F)c2c(F)c(F)c(F)c(F)c21]

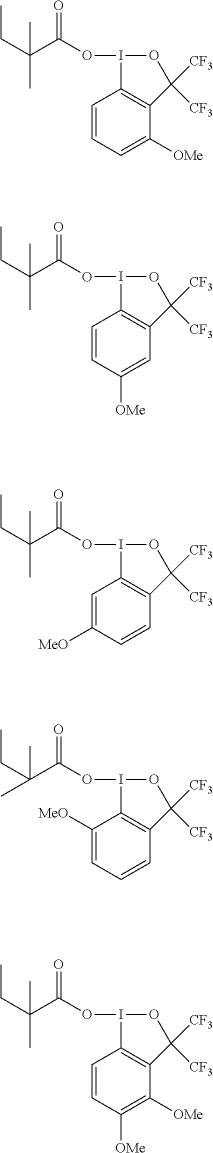 [SMILES: CCC(C)(C)C(=O)OI1OC(C(F)(F)F)(C(F)(F)F)c2c(OC)cccc21 ; CCC(C)(C)C(=O)OI1OC(C(F)(F)F)(C(F)(F)F)c2cc(OC)ccc21 ; CCC(C)(C)C(=O)OI1OC(C(F)(F)F)(C(F)(F)F)c2ccc(OC)cc21 ; CCC(C)(C)C(=O)OI1OC(C(F)(F)F)(C(F)(F)F)c2cccc(OC)c21 ; CCC(C)(C)C(=O)OI1OC(C(F)(F)F)(C(F)(F)F)c2c1ccc(OC)c2OC]

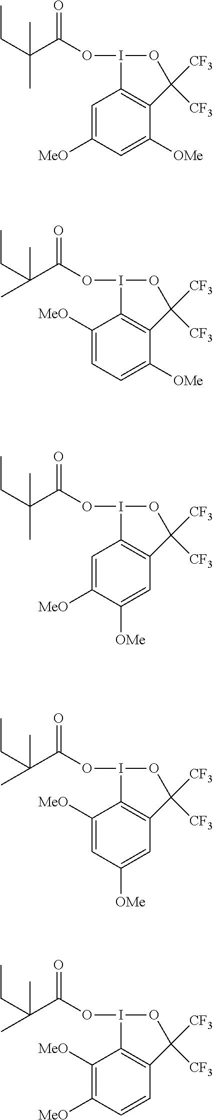 [SMILES: CCC(C)(C)C(=O)OI1OC(C(F)(F)F)(C(F)(F)F)c2c(OC)cc(OC)cc21 ; CCC(C)(C)C(=O)OI1OC(C(F)(F)F)(C(F)(F)F)c2c(OC)ccc(OC)c21 ; CCC(C)(C)C(=O)OI1OC(C(F)(F)F)(C(F)(F)F)c2cc(OC)c(OC)cc21 ; CCC(C)(C)C(=O)OI1OC(C(F)(F)F)(C(F)(F)F)c2cc(OC)cc(OC)c21 ; CCC(C)(C)C(=O)OI1OC(C(F)(F)F)(C(F)(F)F)c2ccc(OC)c(OC)c21]

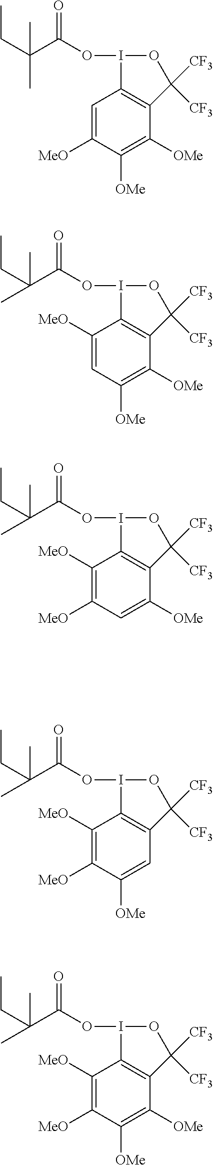 [SMILES: CCC(C)(C)C(=O)OI1OC(C(F)(F)F)(C(F)(F)F)c2c1cc(OC)c(OC)c2OC ; CCC(C)(C)C(=O)OI1OC(C(F)(F)F)(C(F)(F)F)c2c(OC)c(OC)cc(OC)c21 ; CCC(C)(C)C(=O)OI1OC(C(F)(F)F)(C(F)(F)F)c2c(OC)cc(OC)c(OC)c21 ; CCC(C)(C)C(=O)OI1OC(C(F)(F)F)(C(F)(F)F)c2cc(OC)c(OC)c(OC)c21 ; CCC(C)(C)C(=O)OI1OC(C(F)(F)F)(C(F)(F)F)c2c(OC)c(OC)c(OC)c(OC)c21]

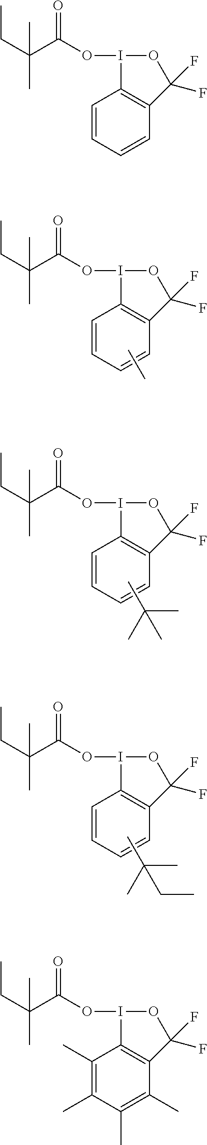

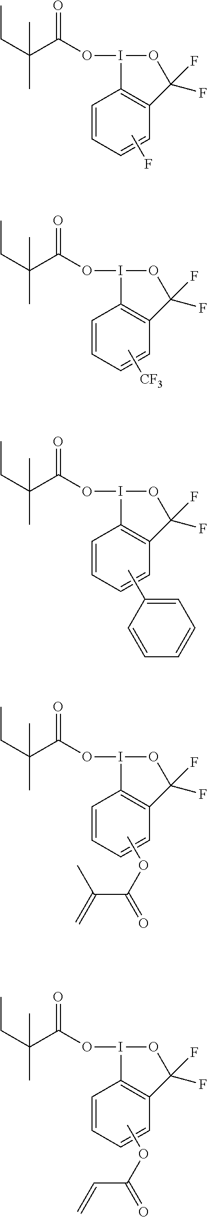

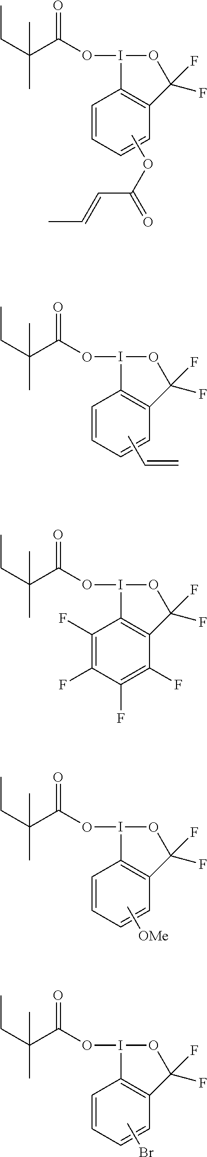

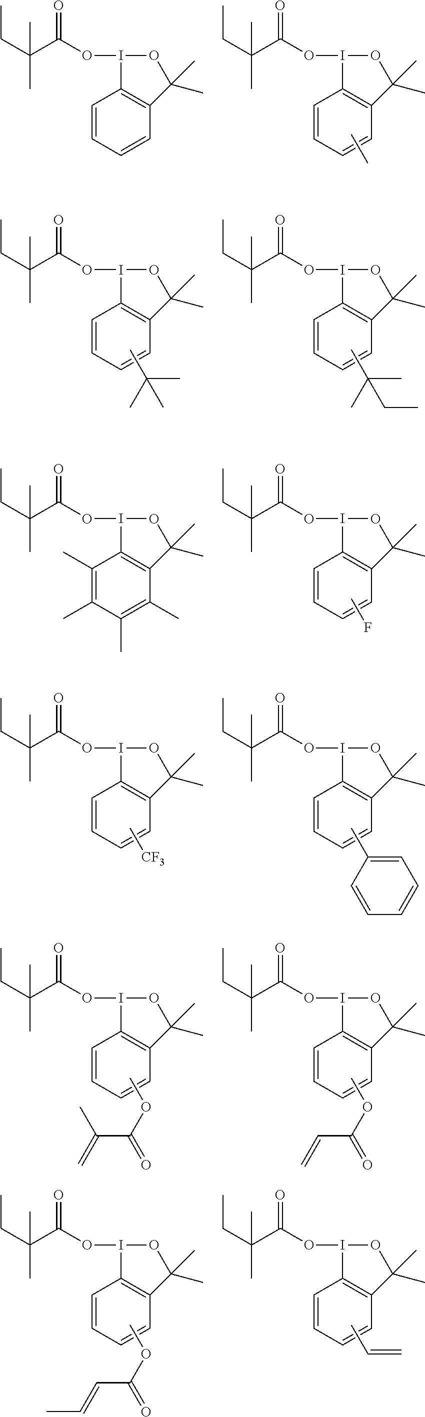

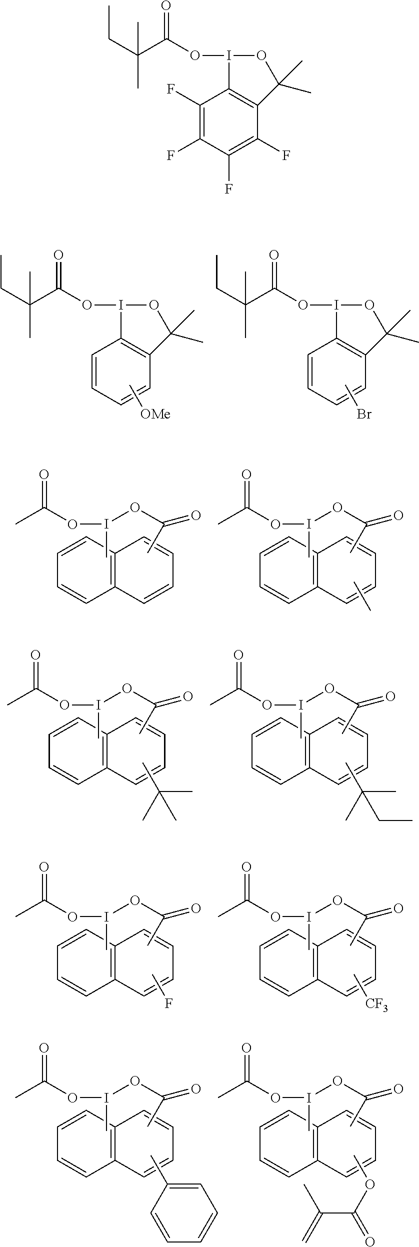

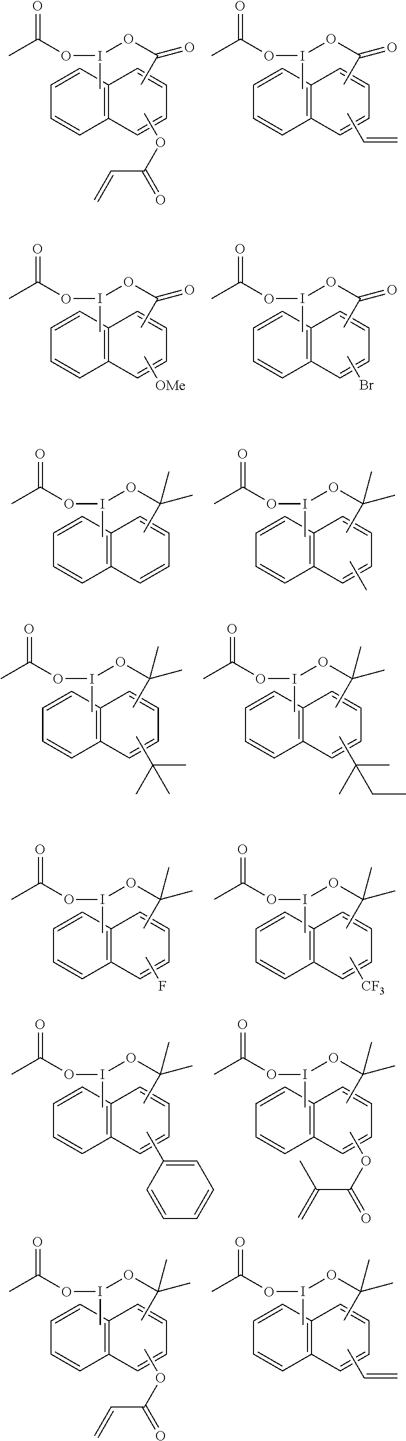

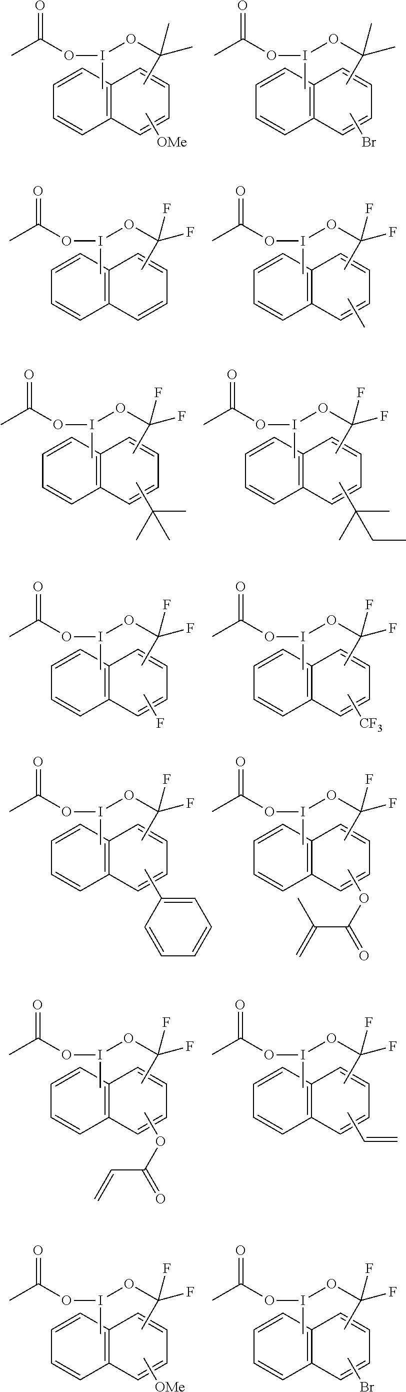

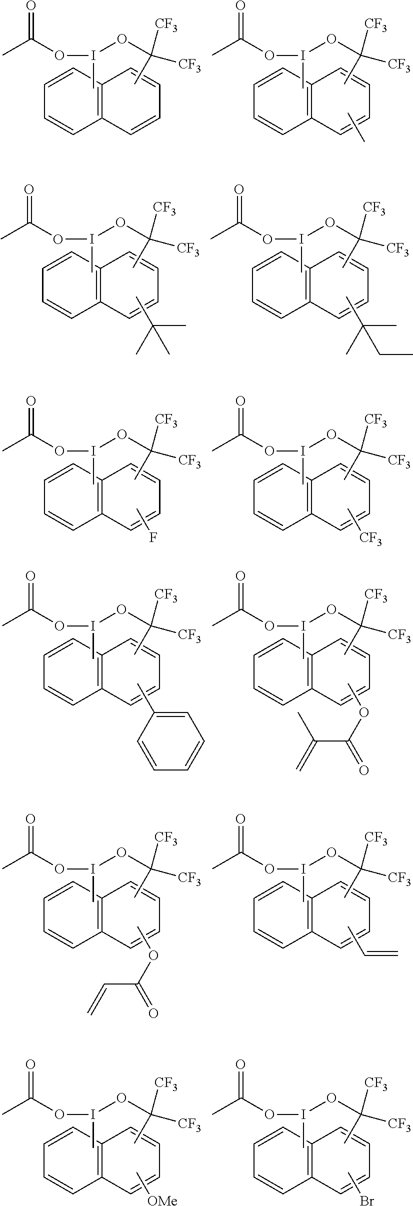

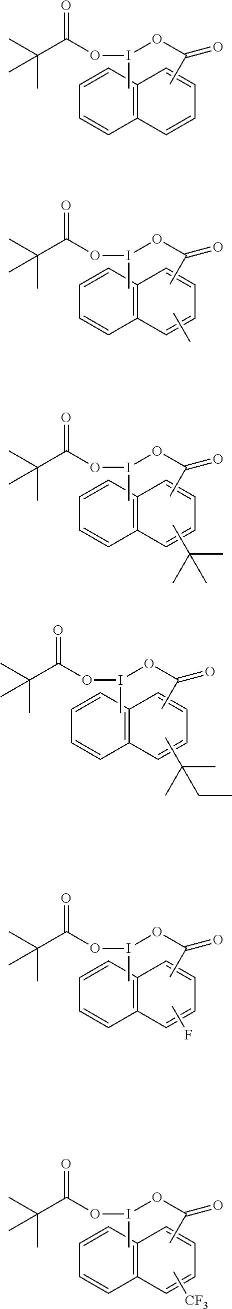

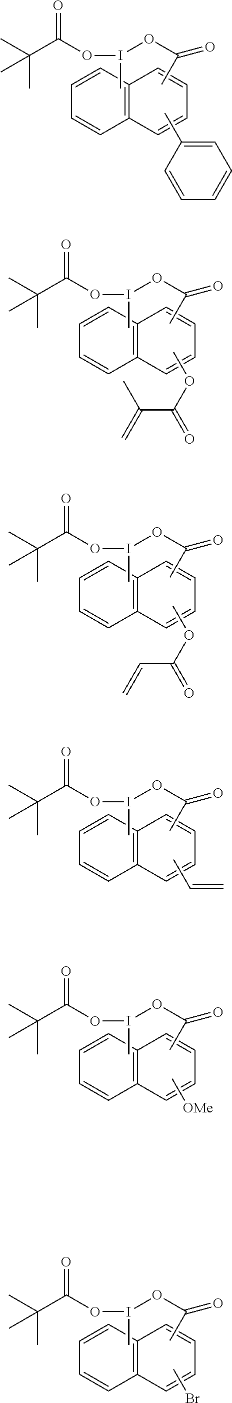

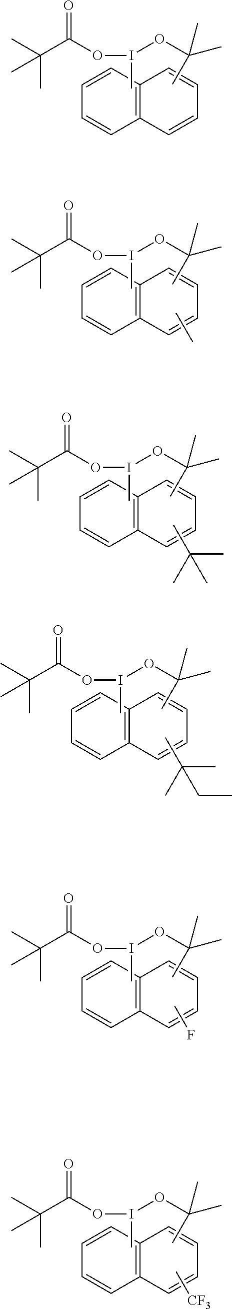

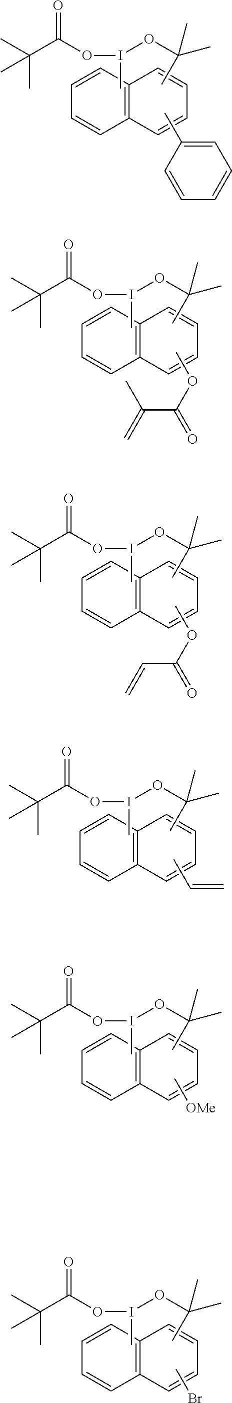

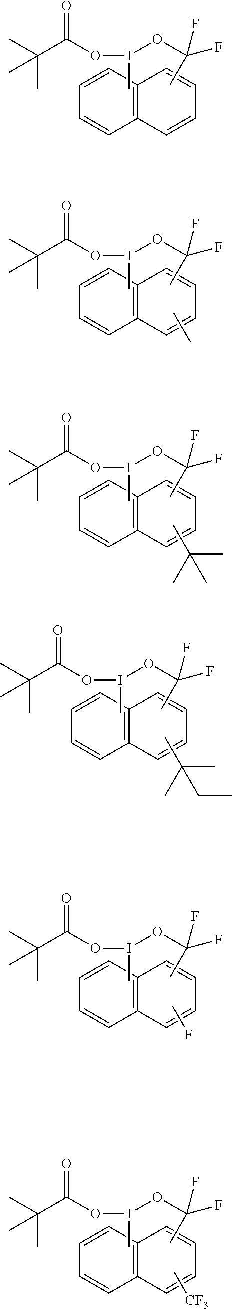

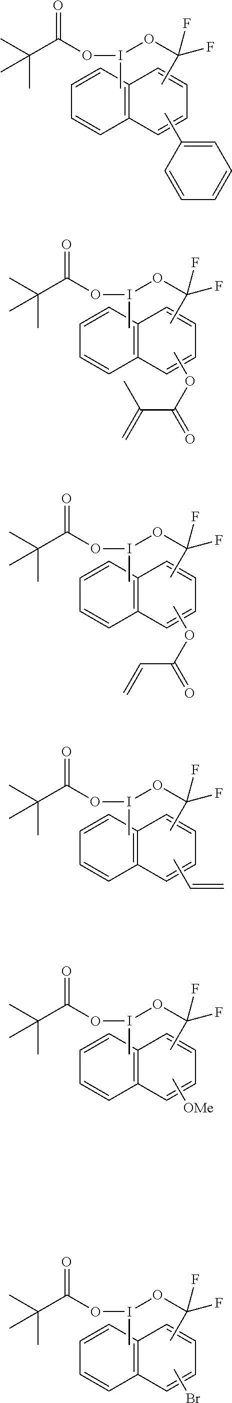

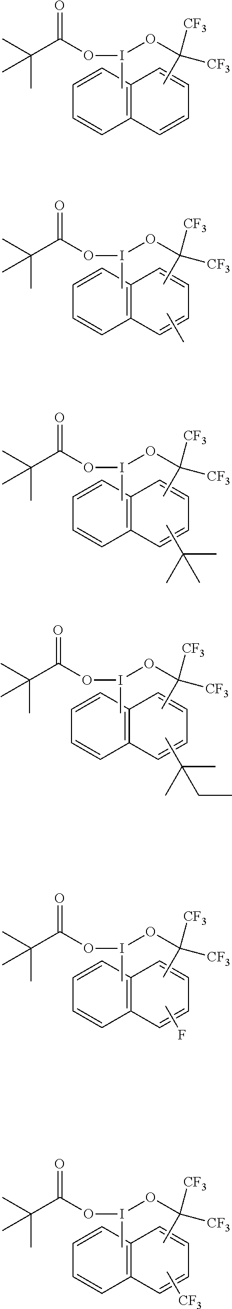

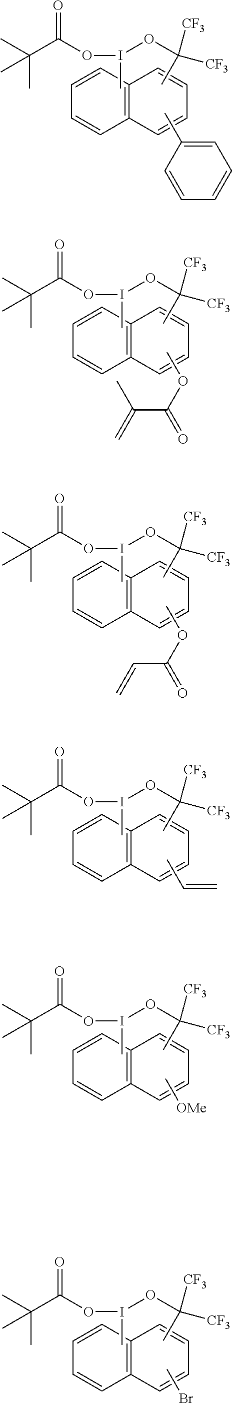

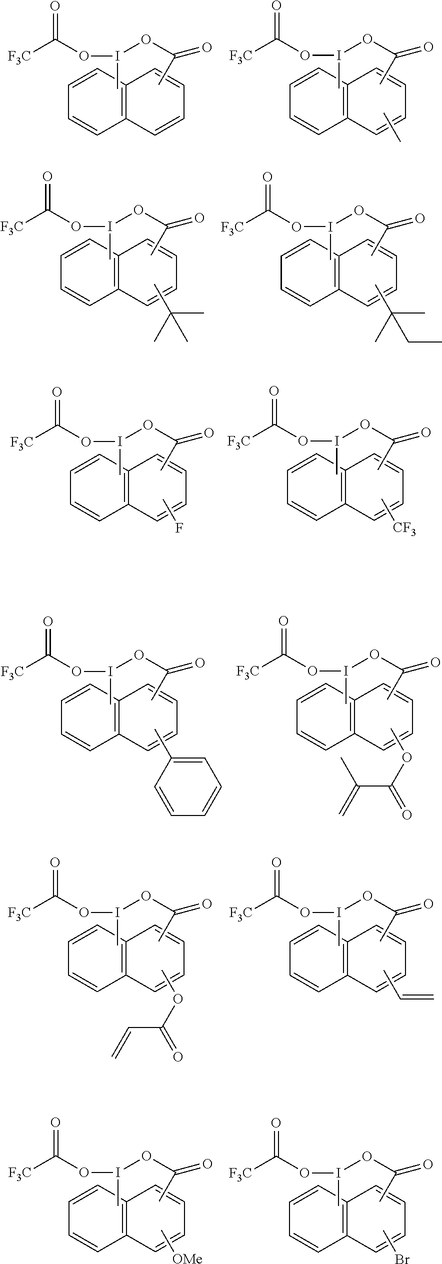

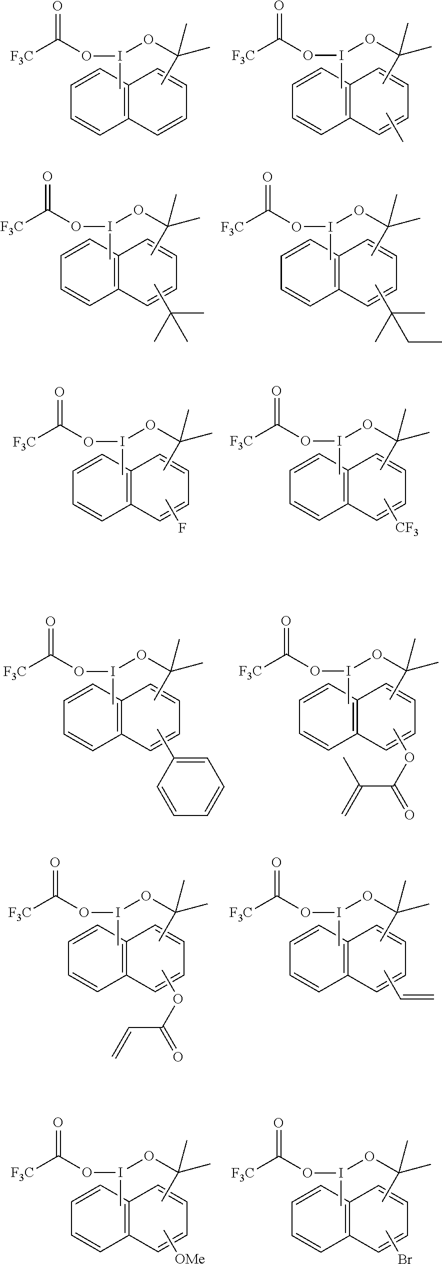

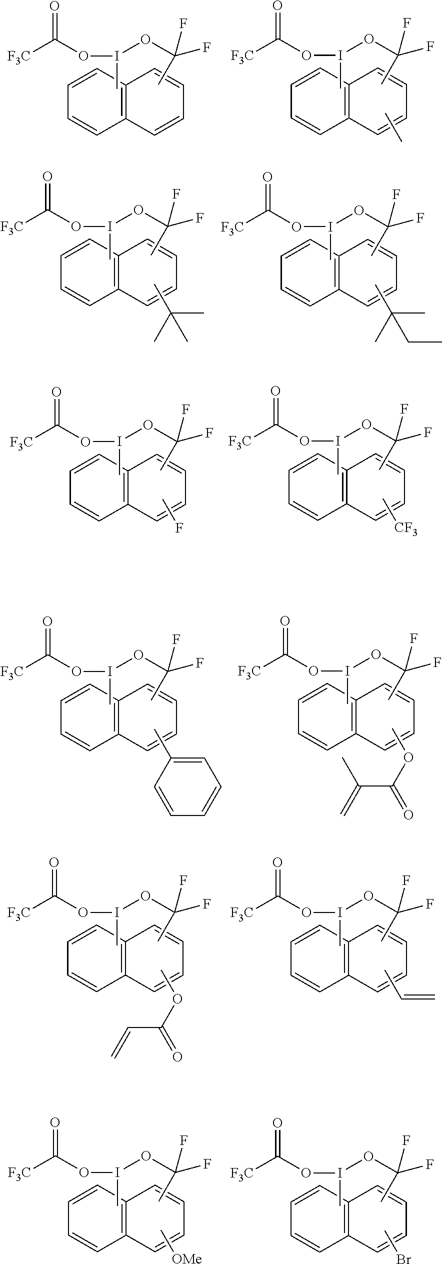

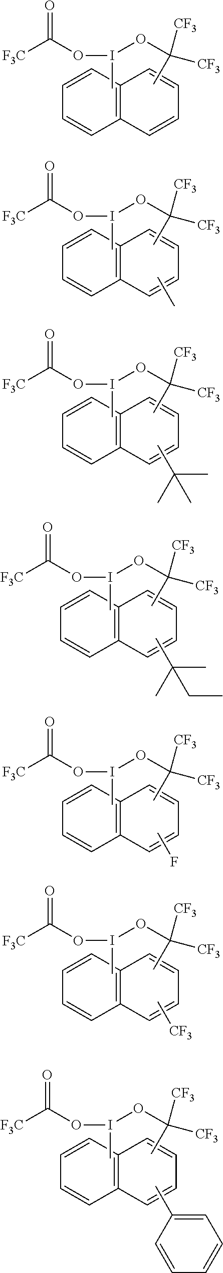

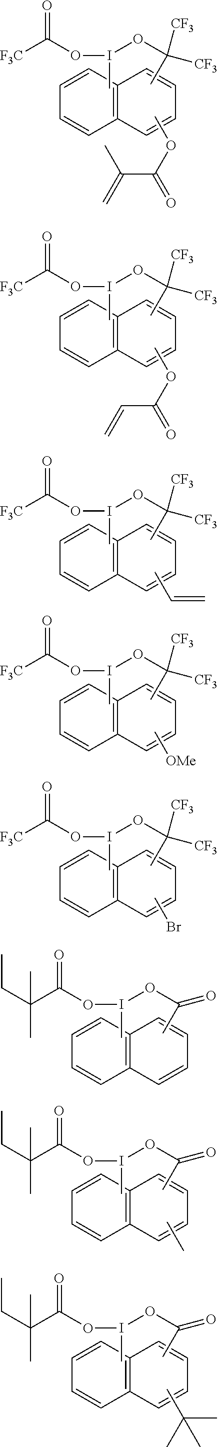

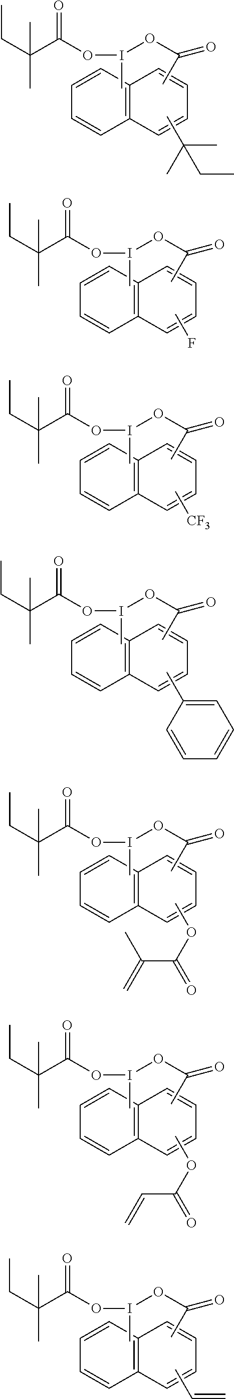

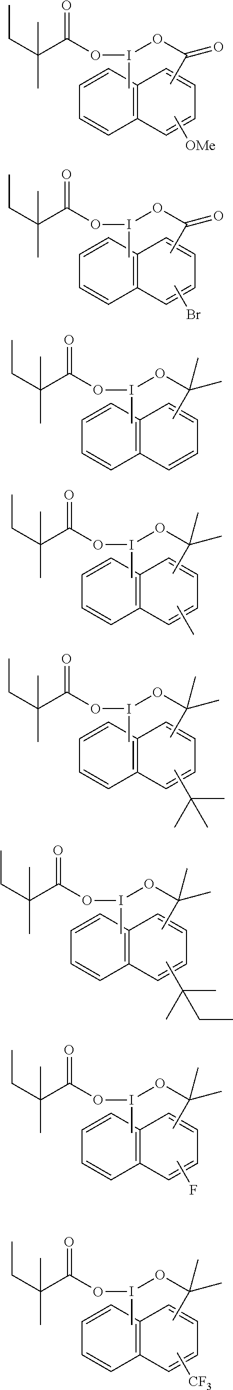

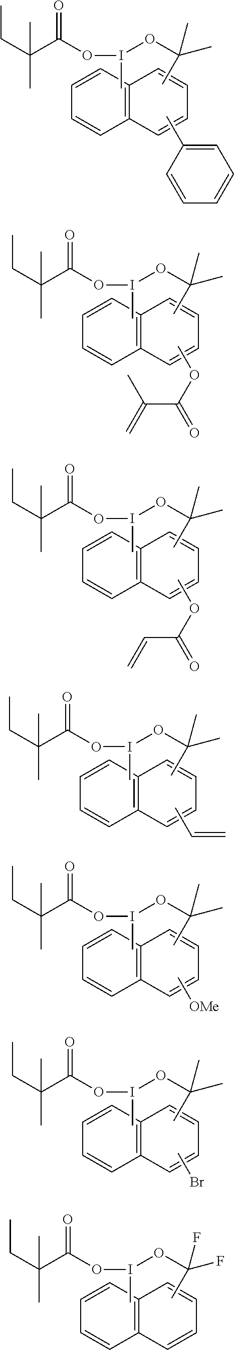

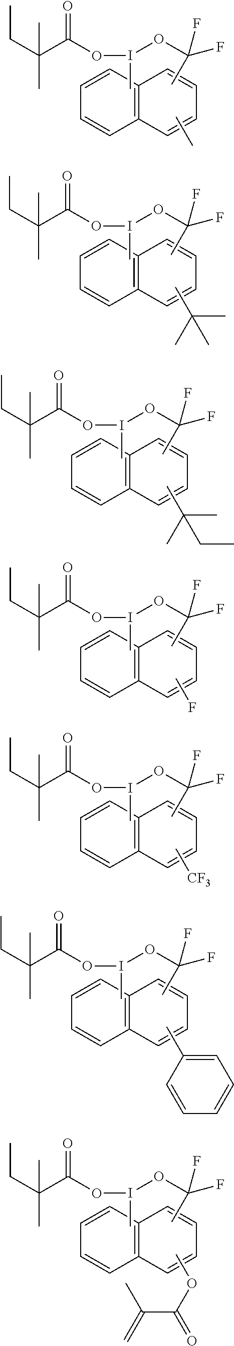

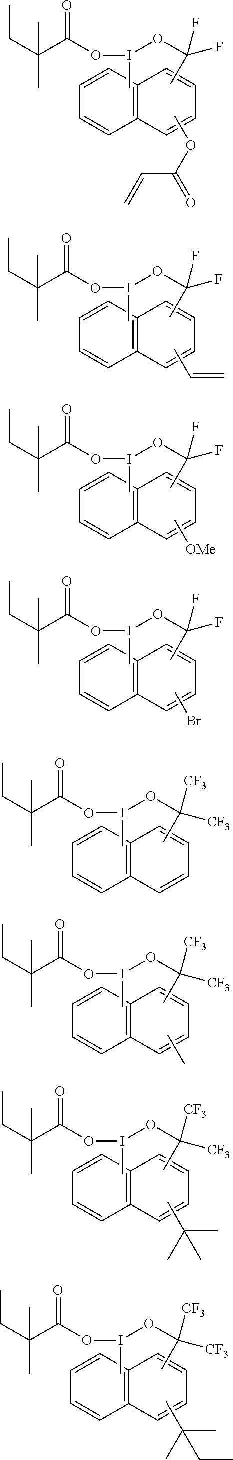

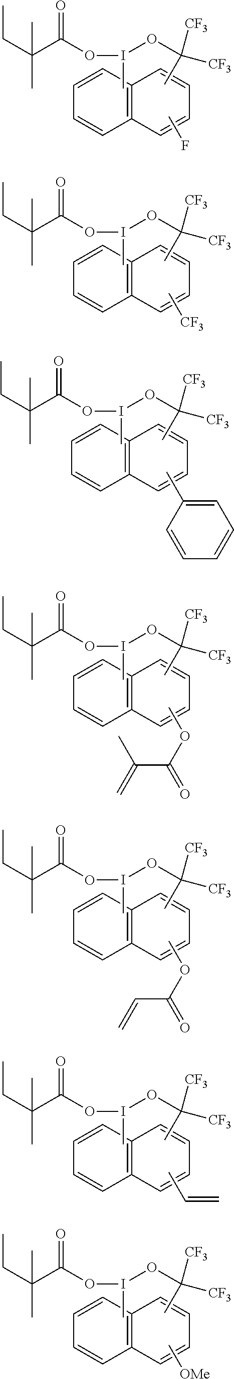

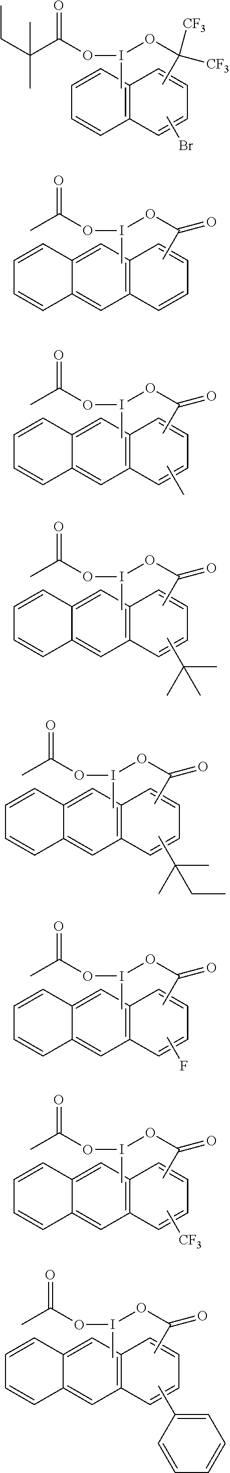

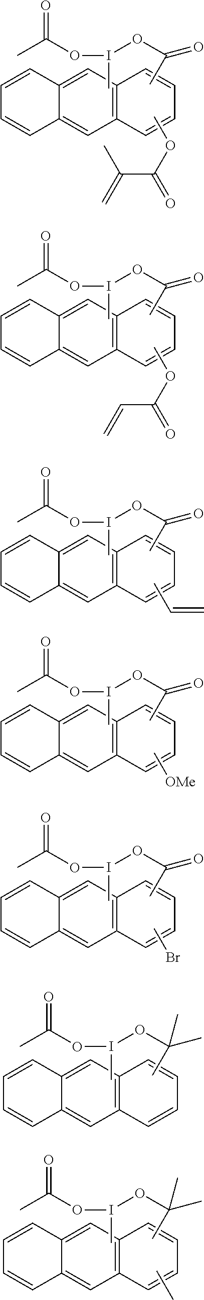

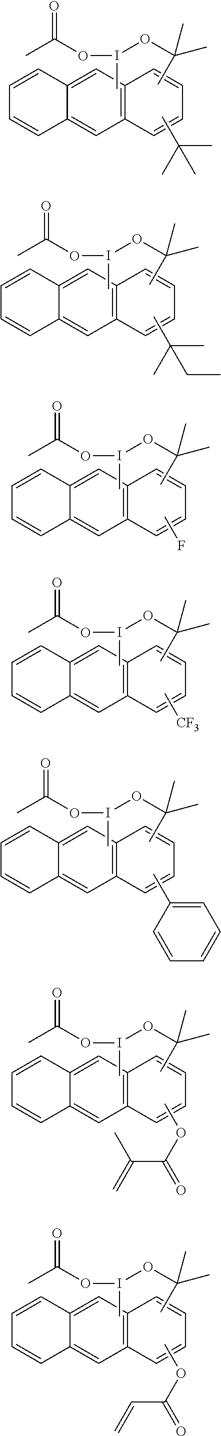

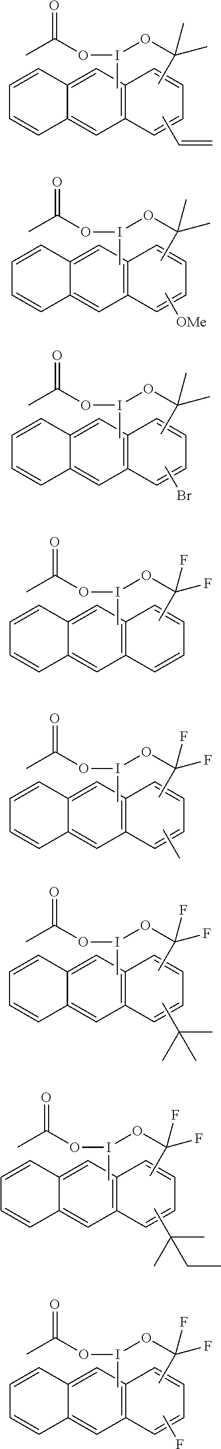

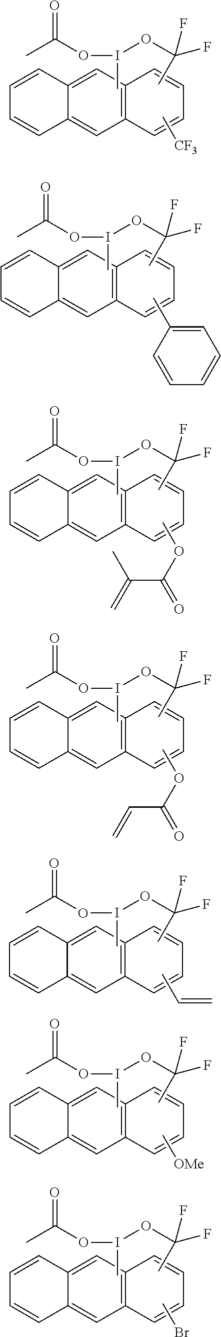

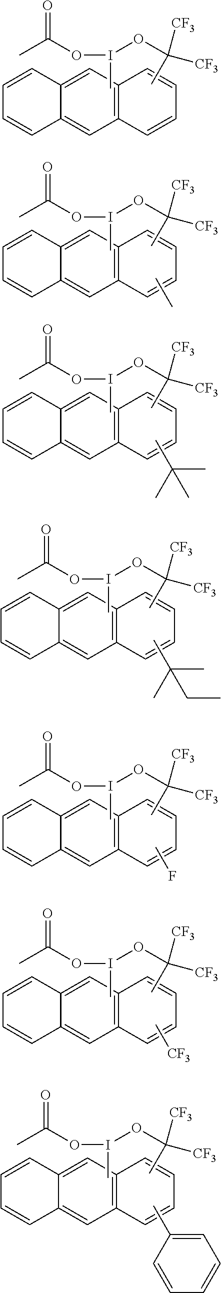

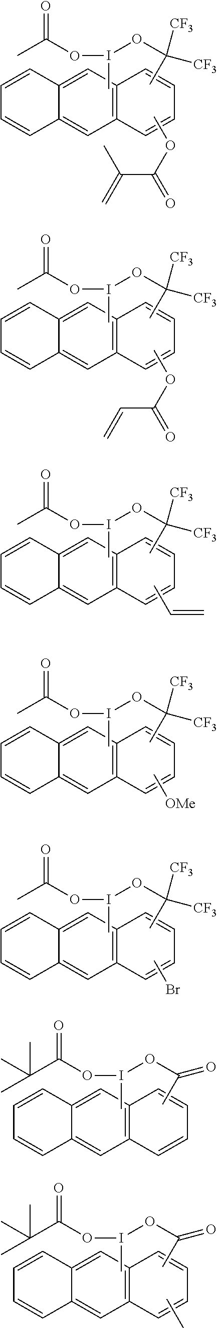

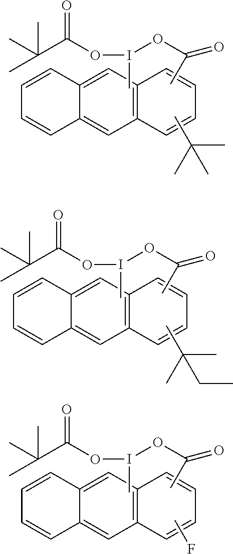

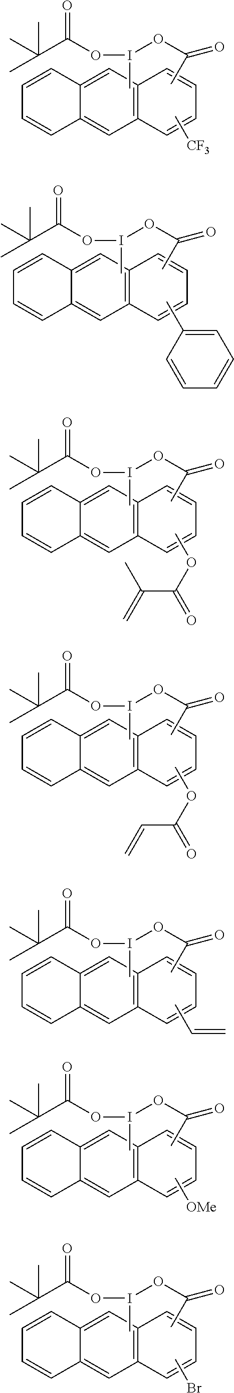

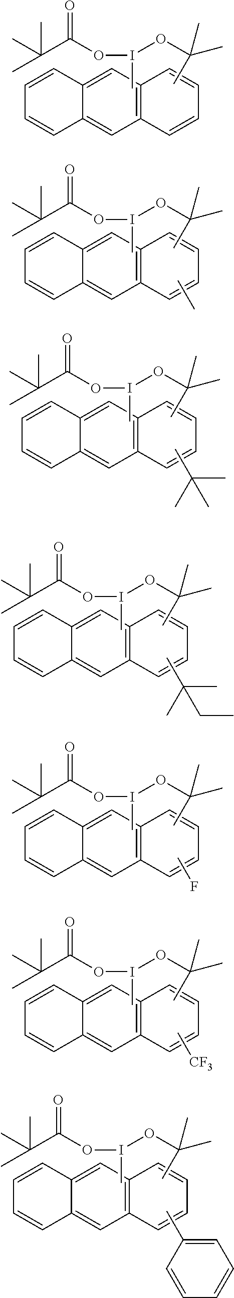

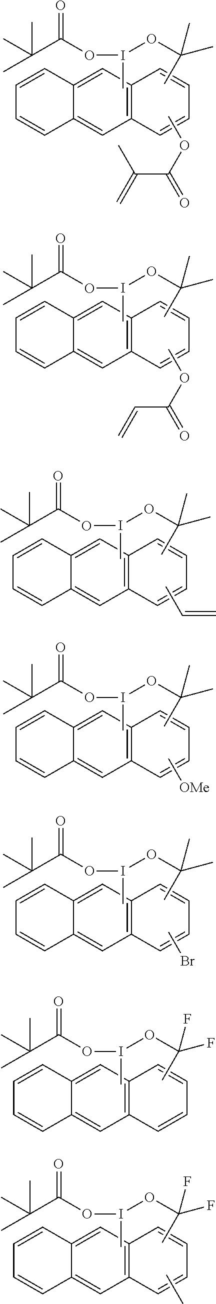

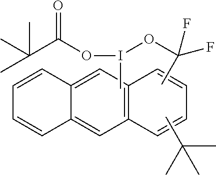

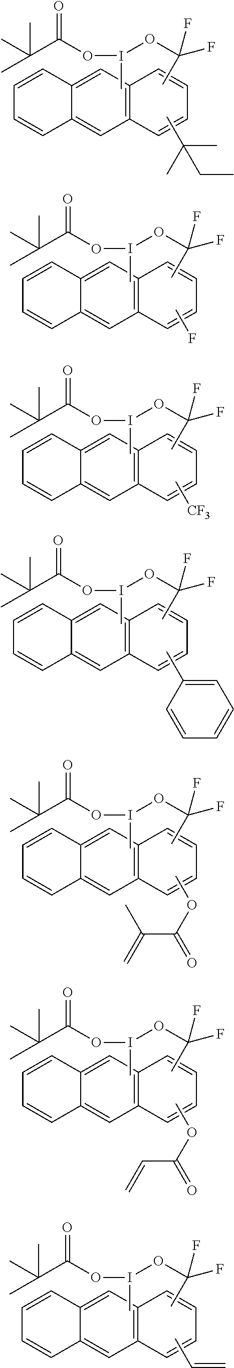

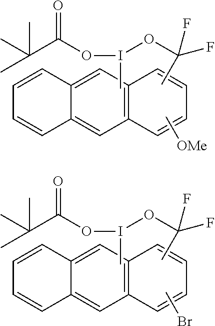

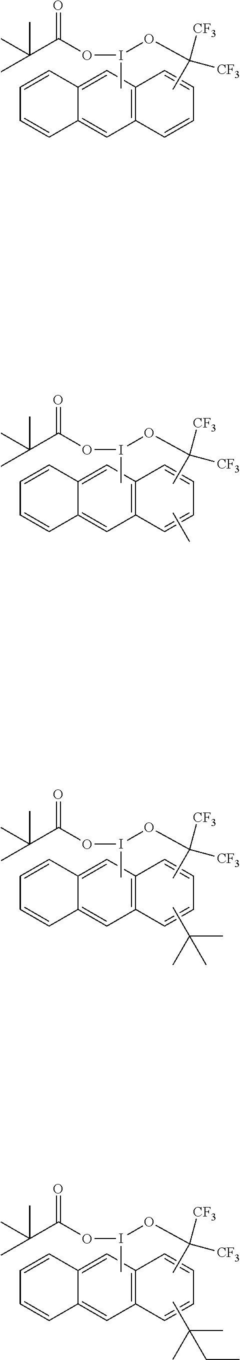

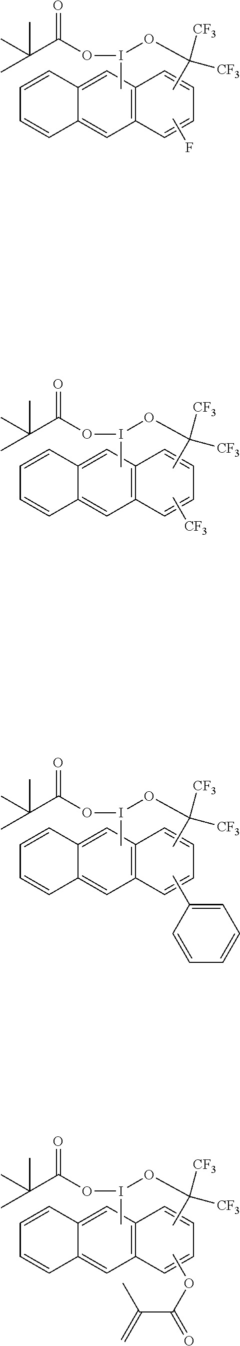

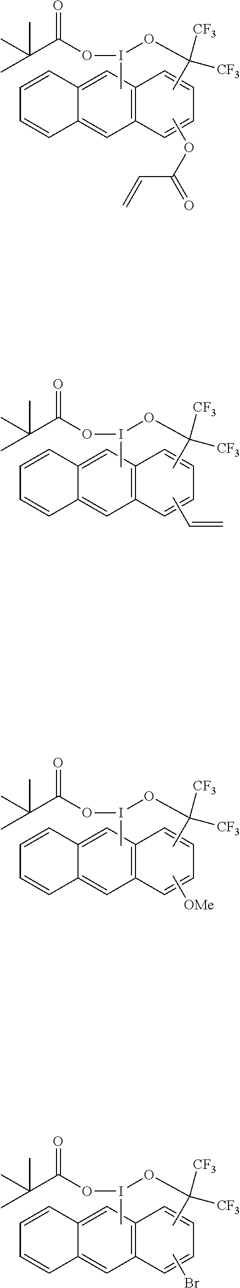

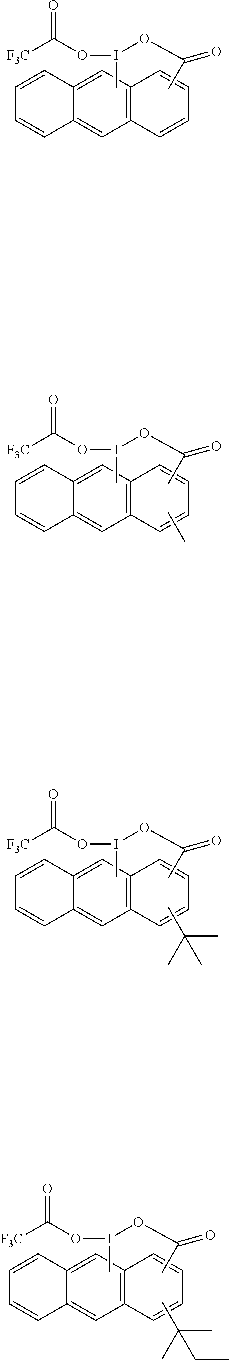

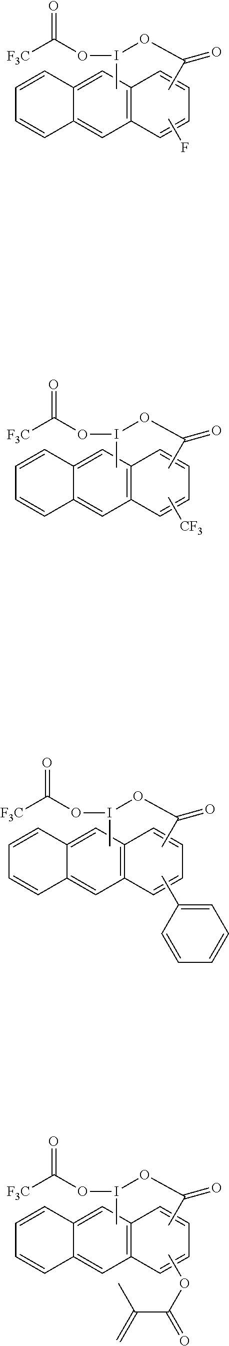

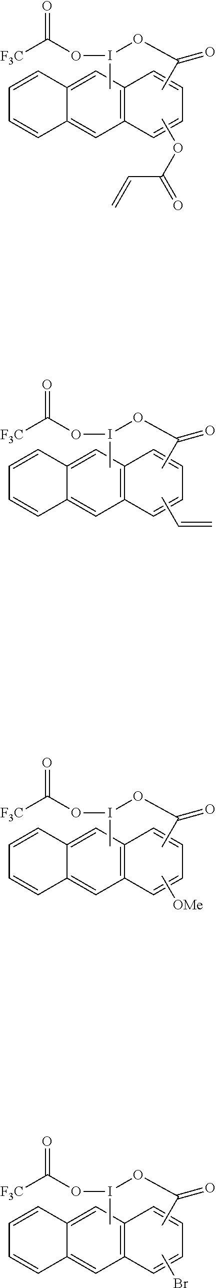

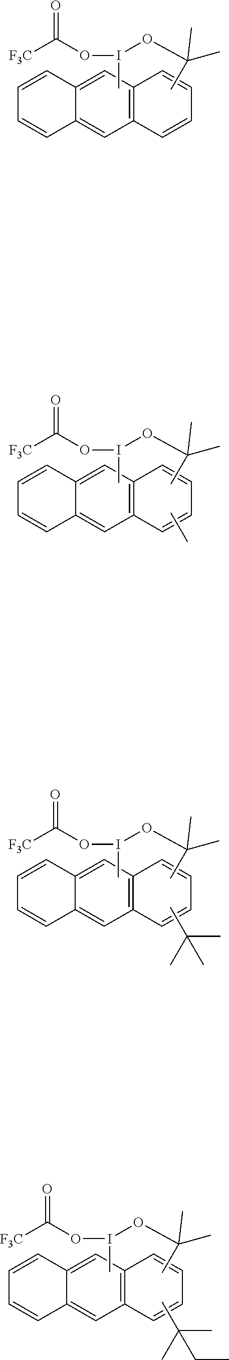

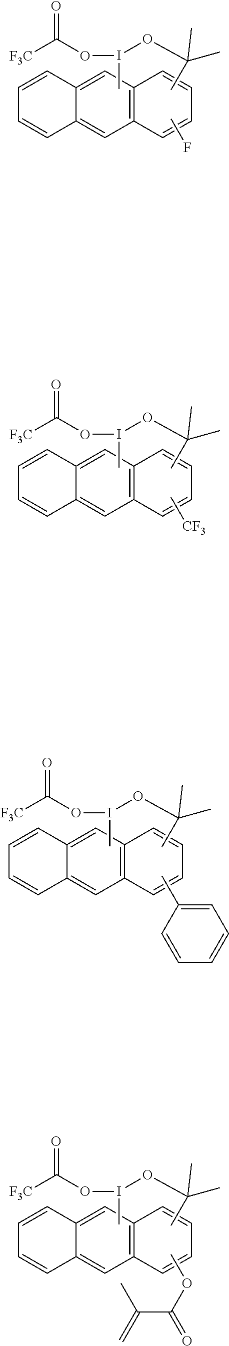

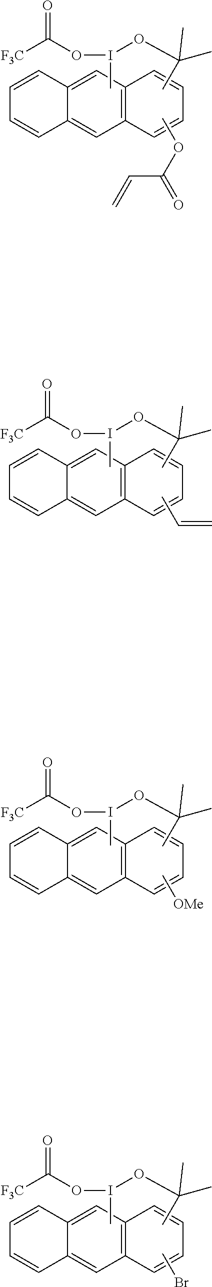

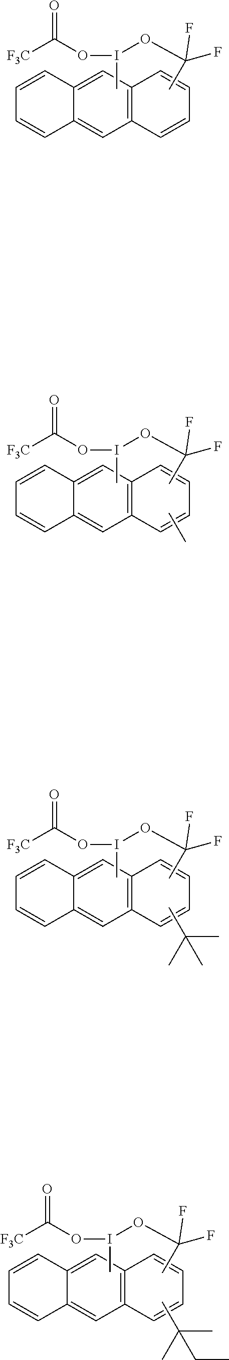

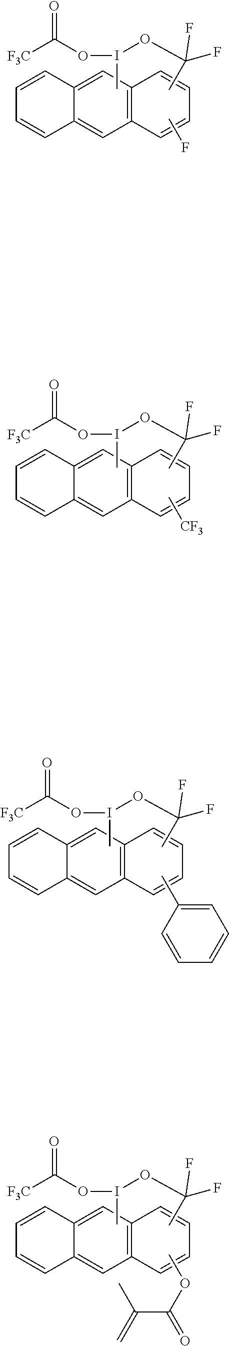

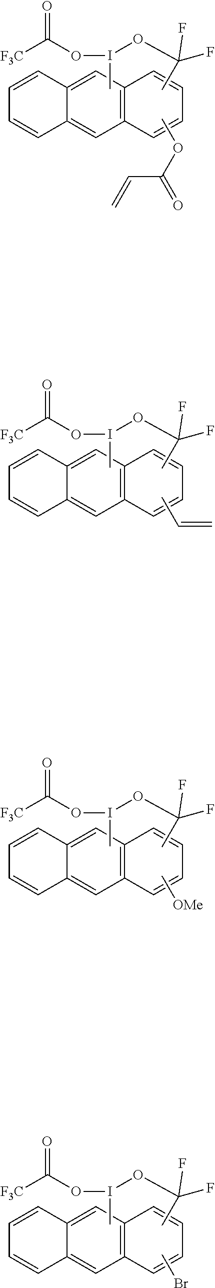

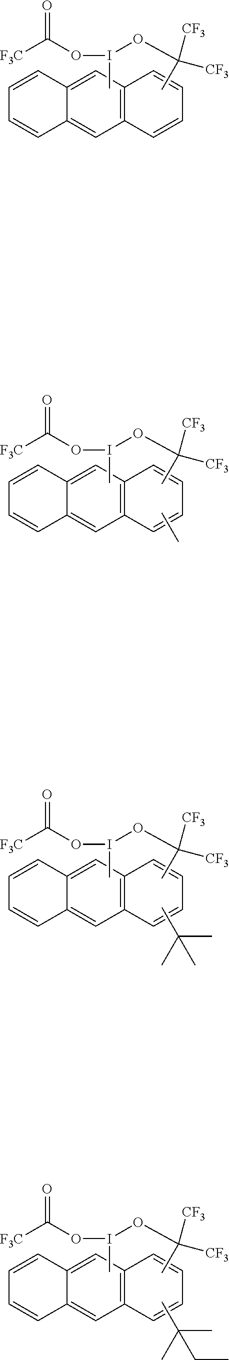

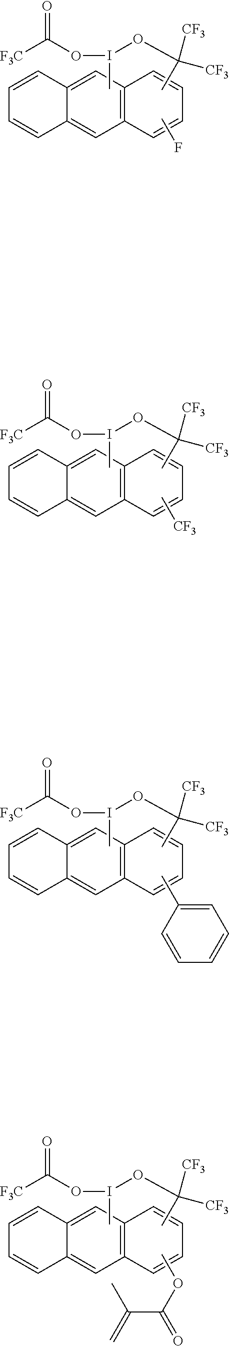

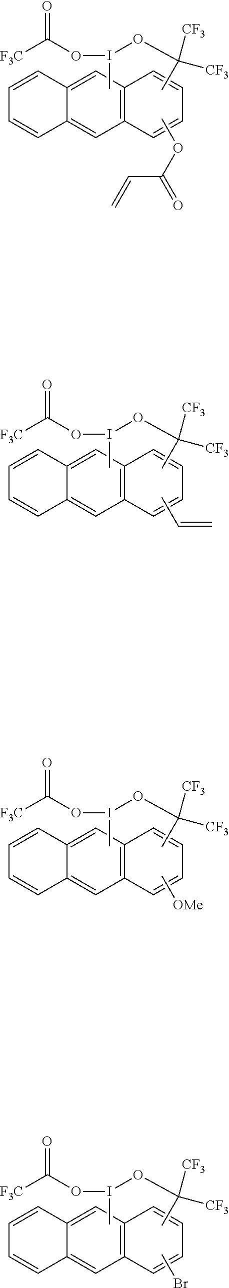

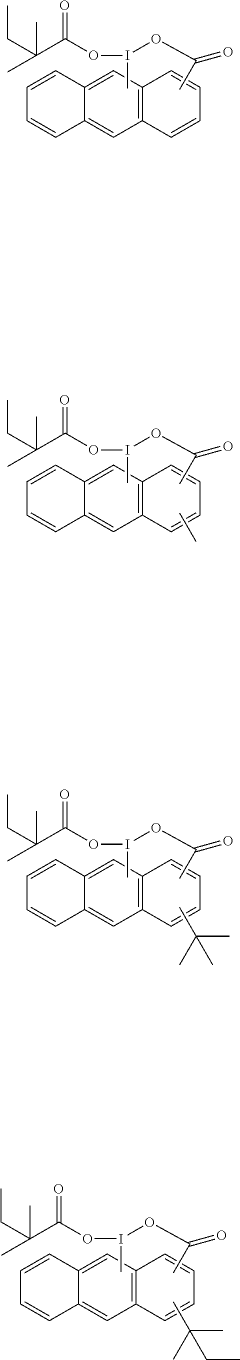

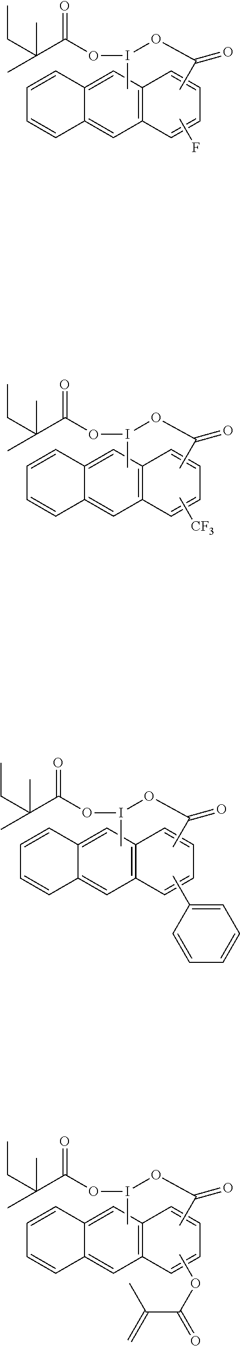

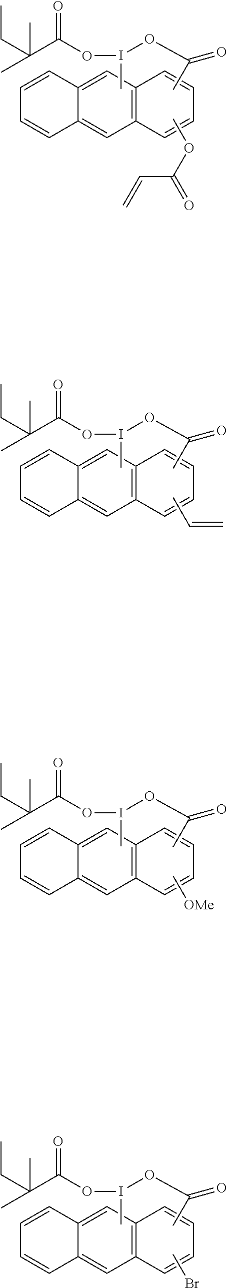

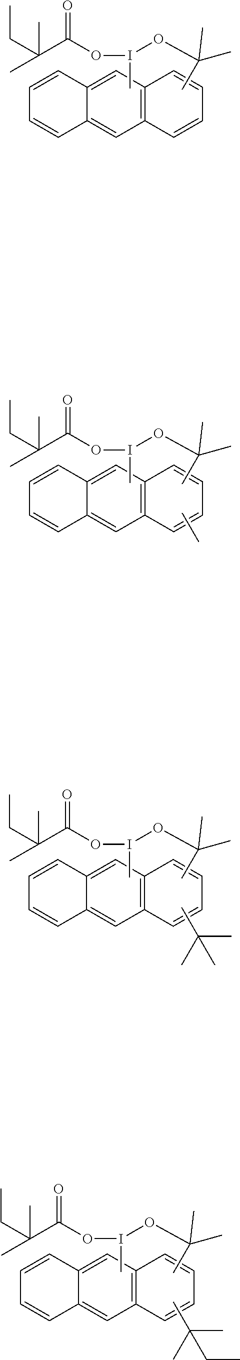

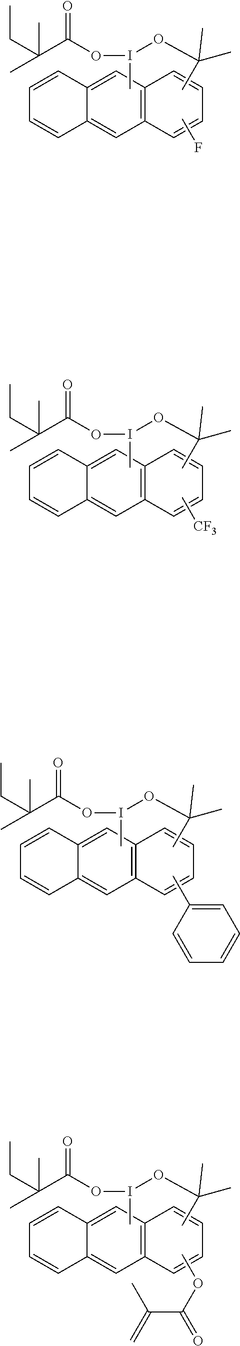

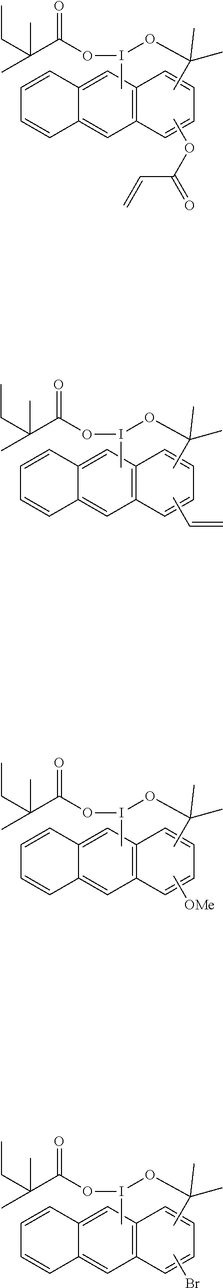

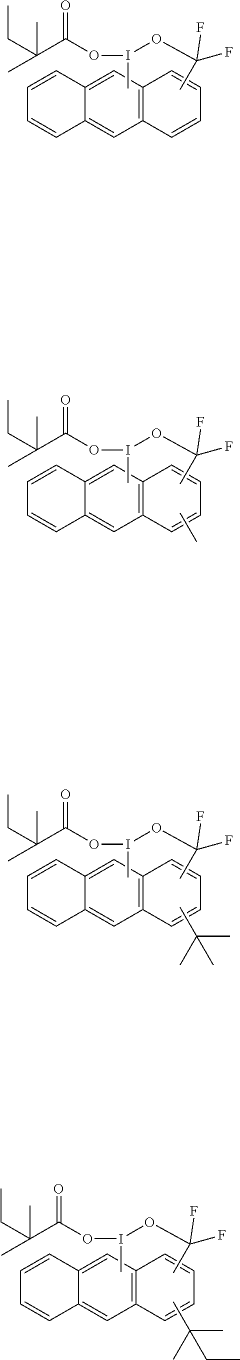

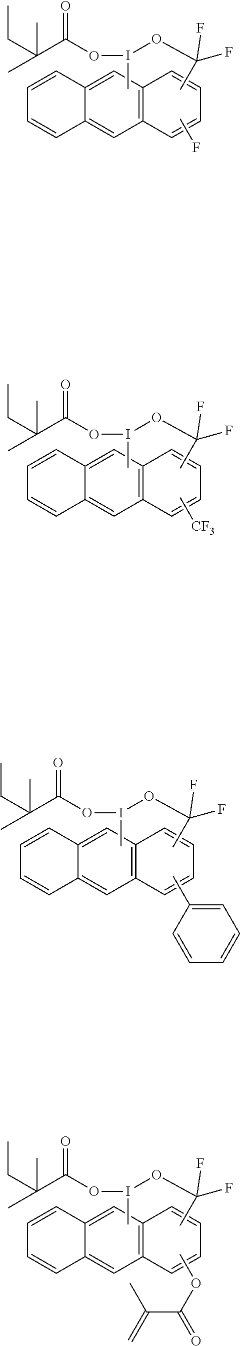

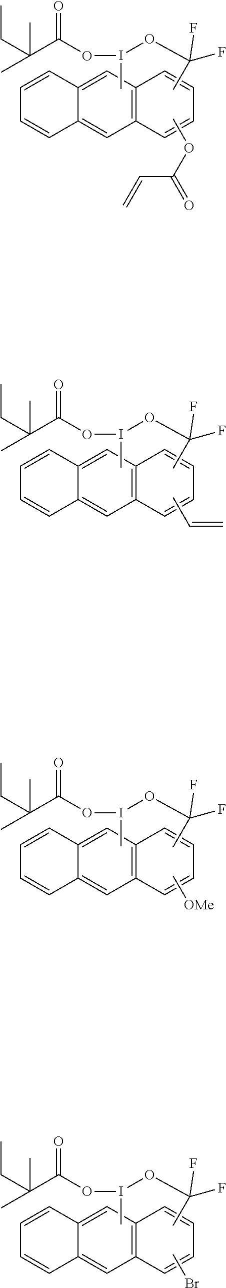

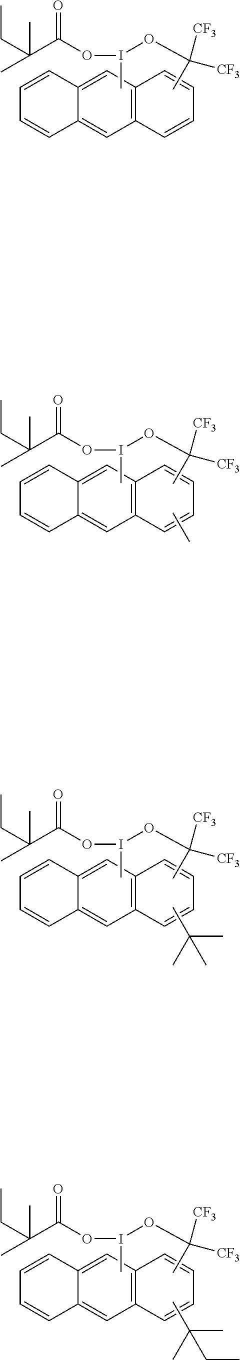

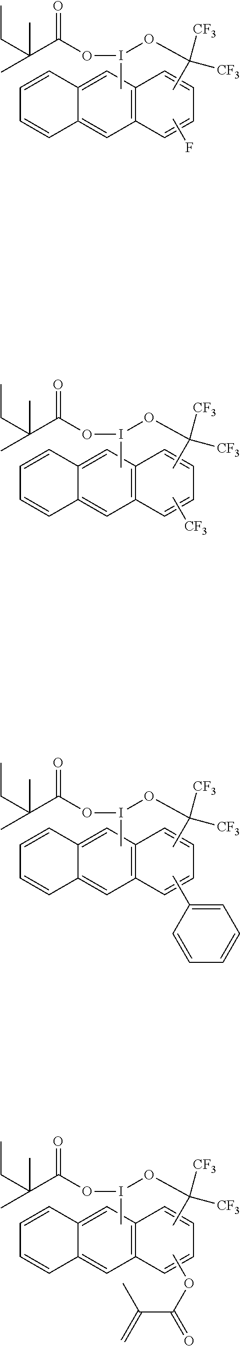

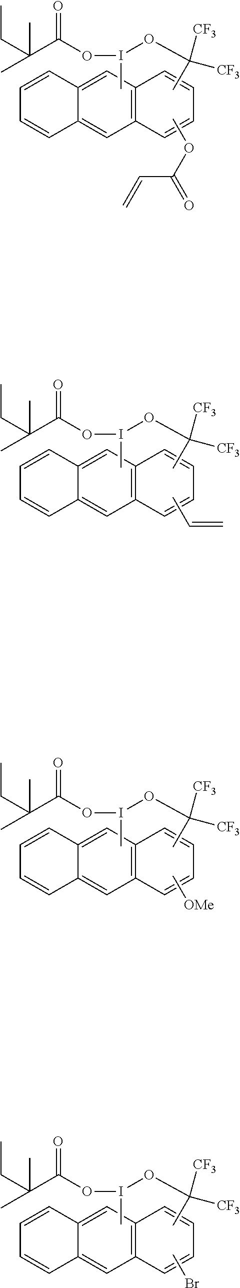

Specific examples of the hypervalent iodine compound represented by the formula (6) include the following, but are not limited thereto.

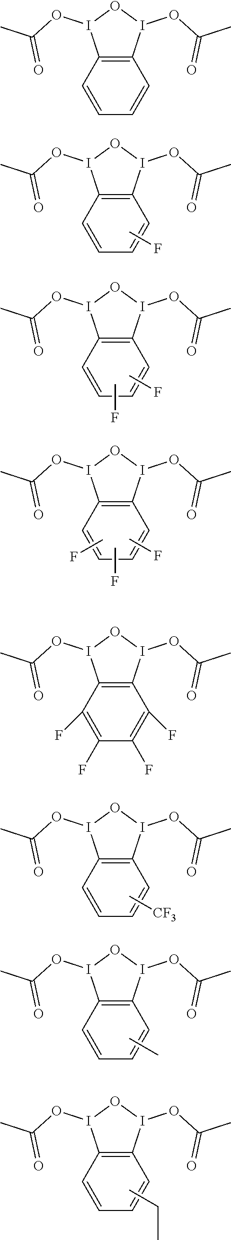

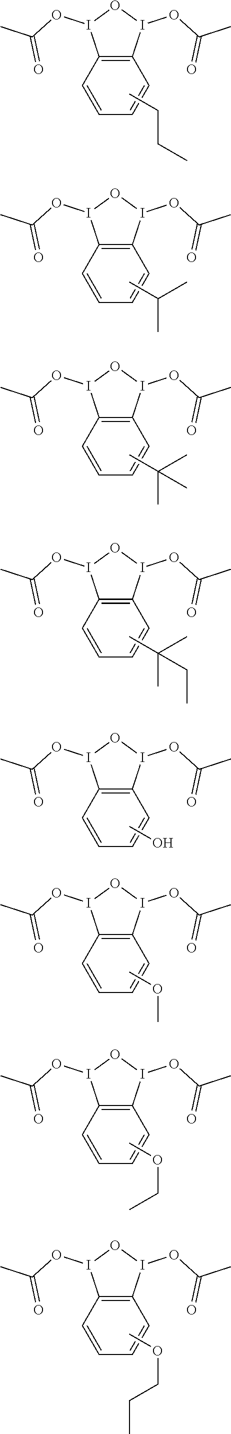

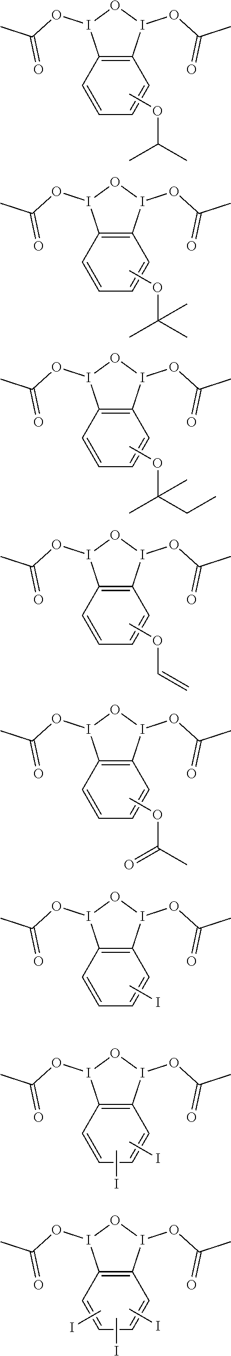

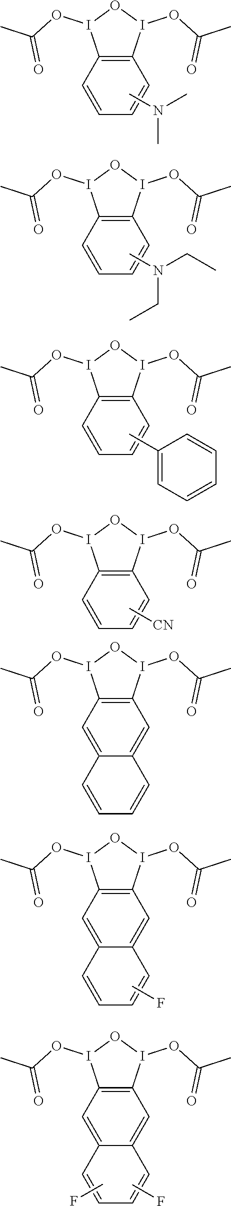

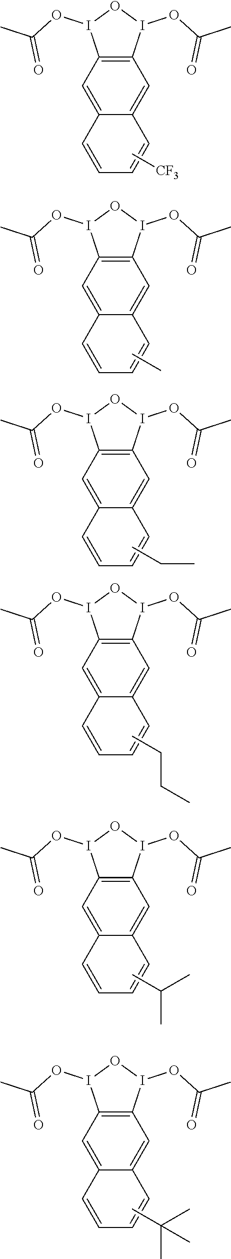

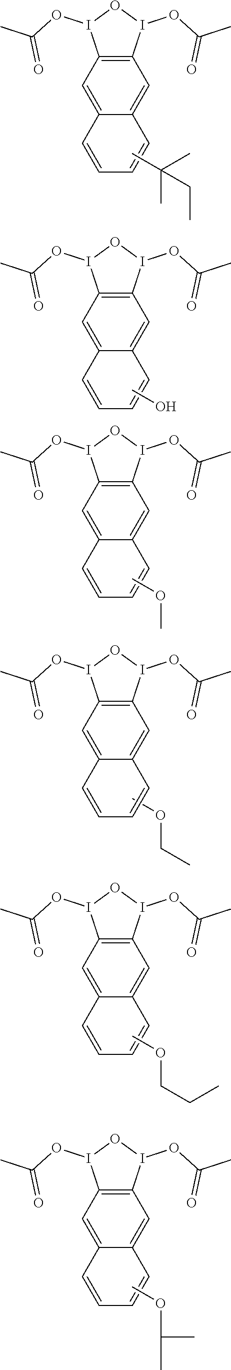

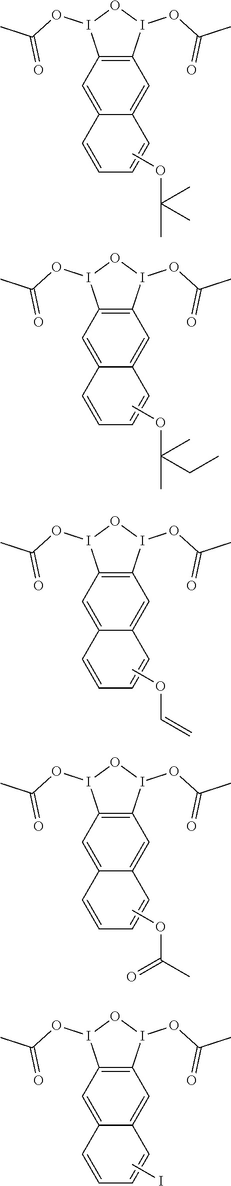

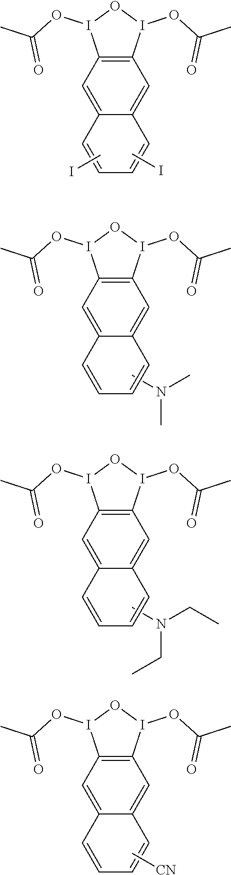

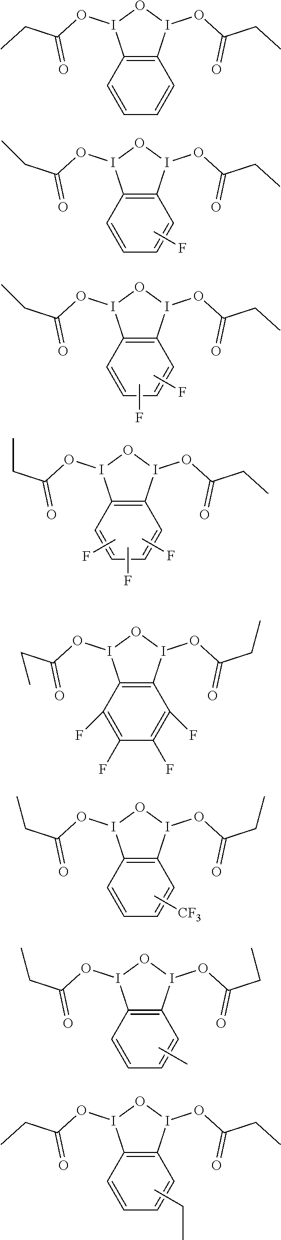

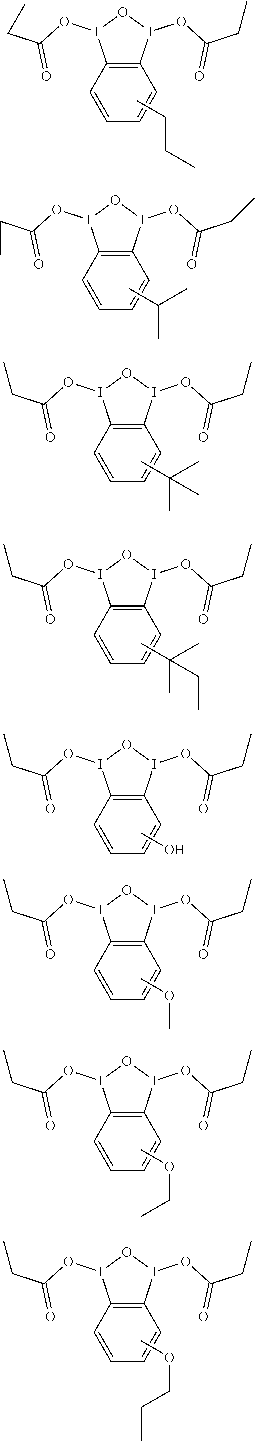

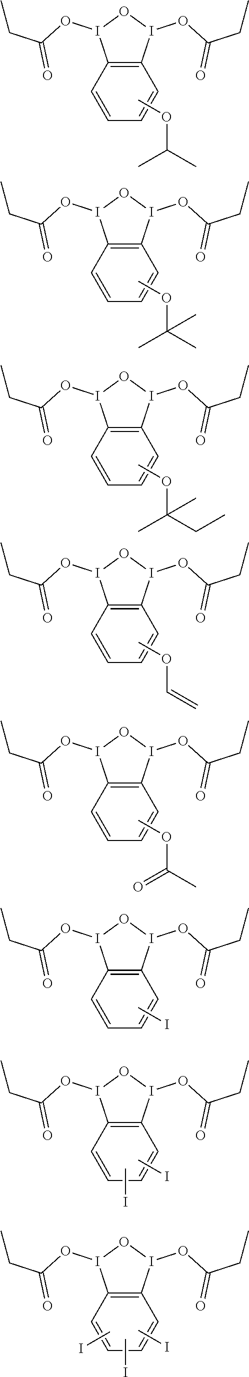

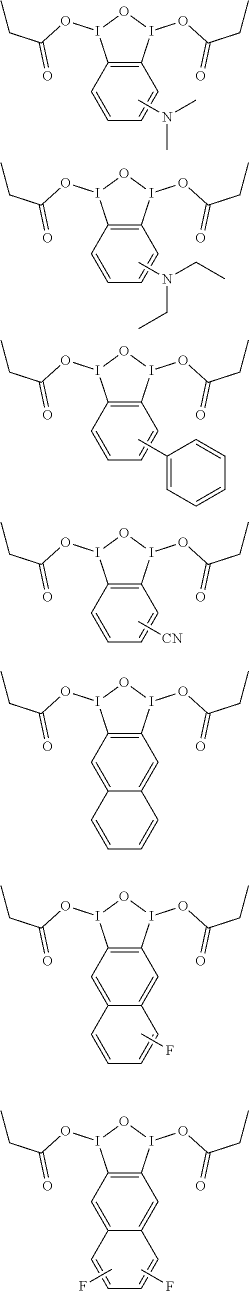

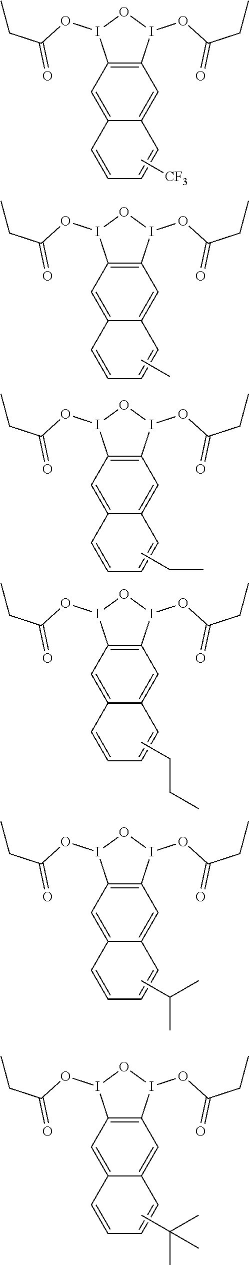

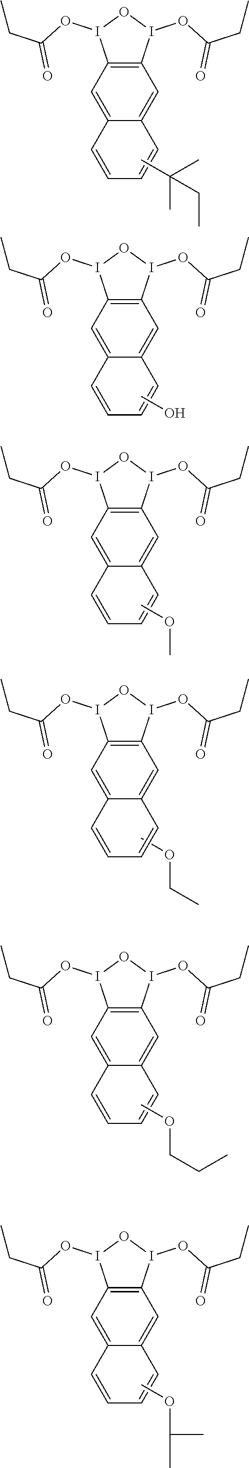

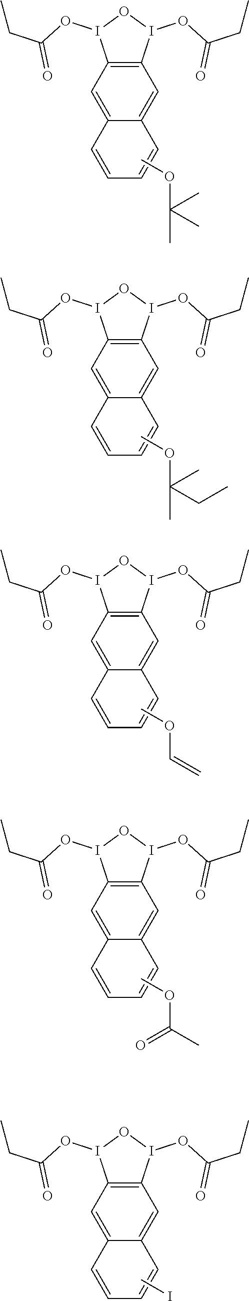

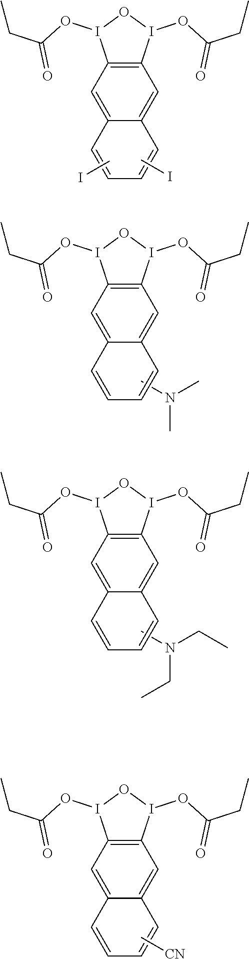

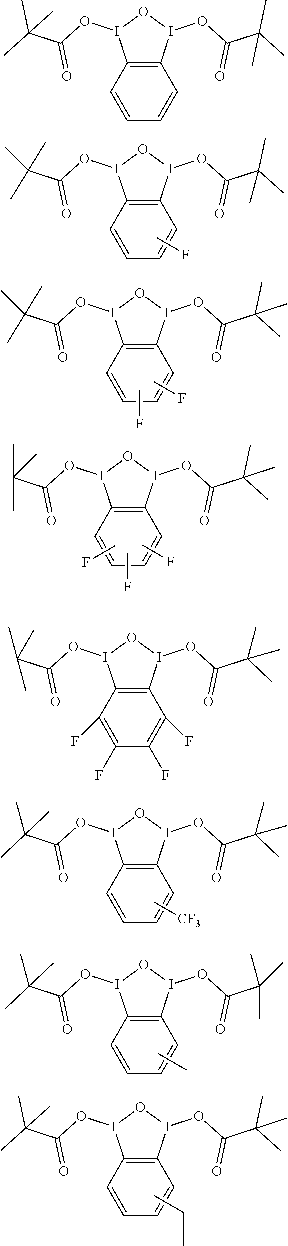

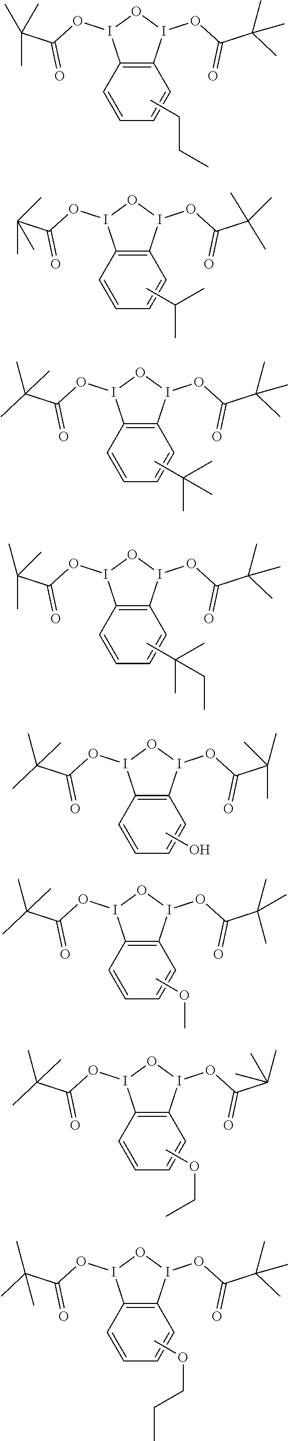

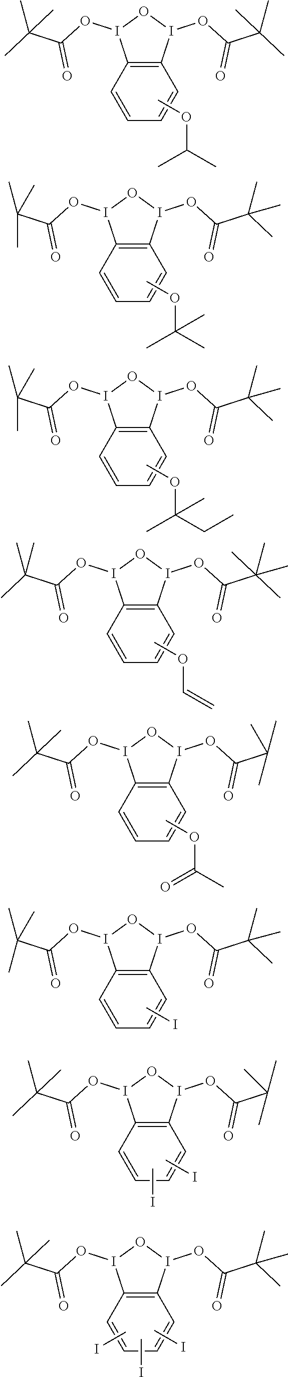

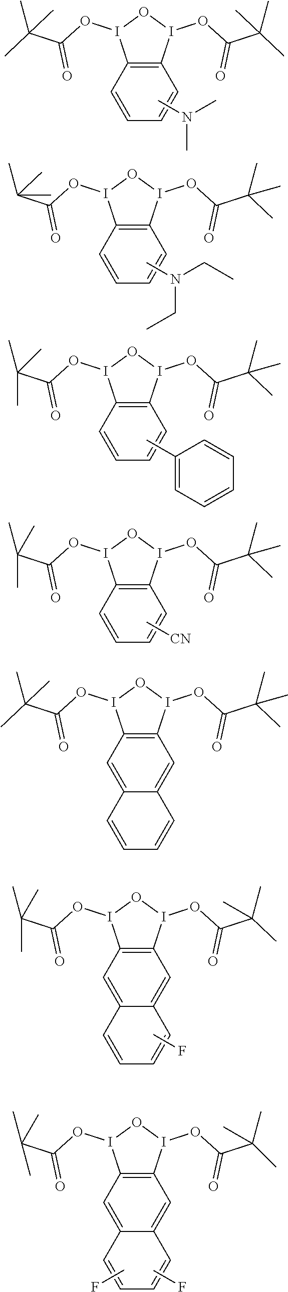

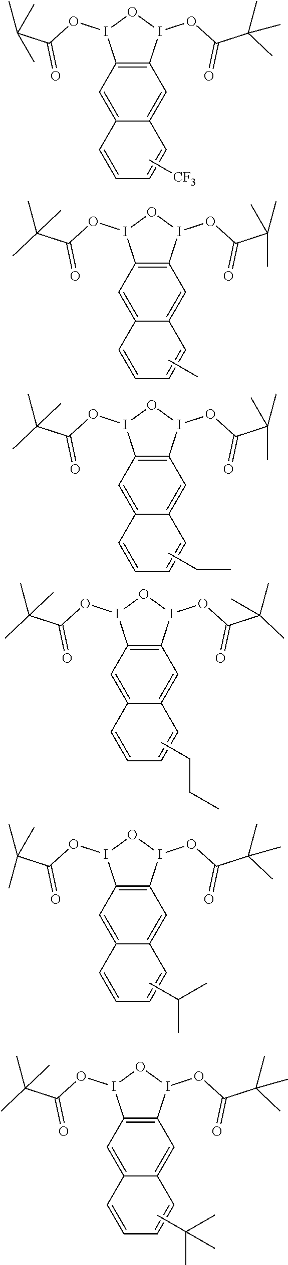

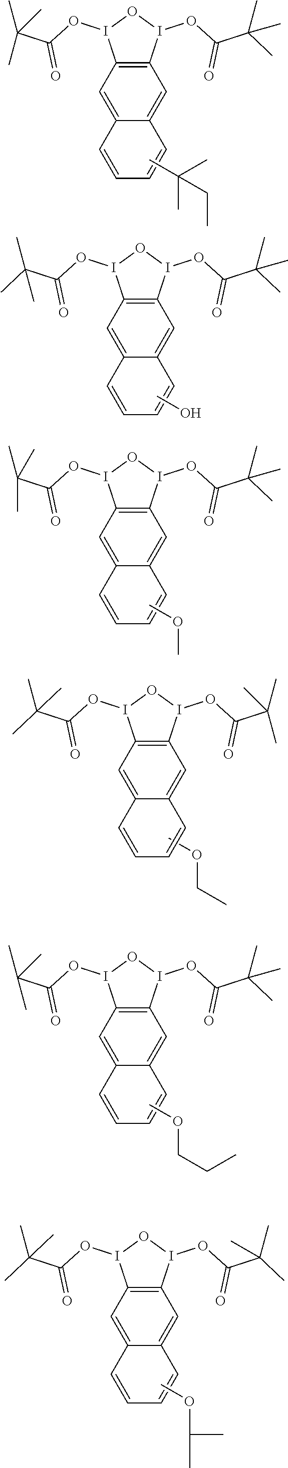

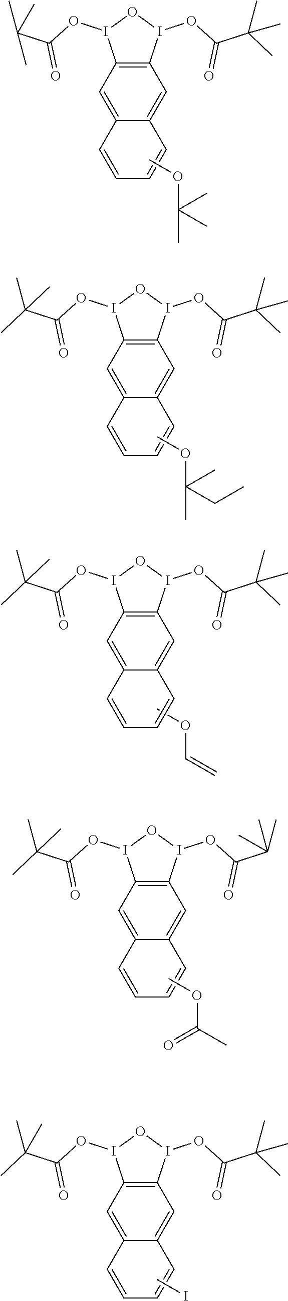

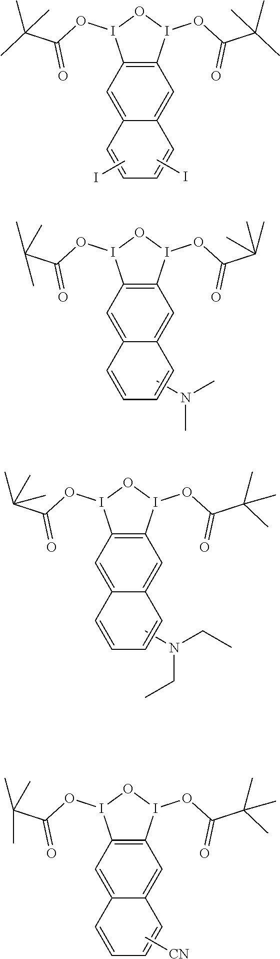

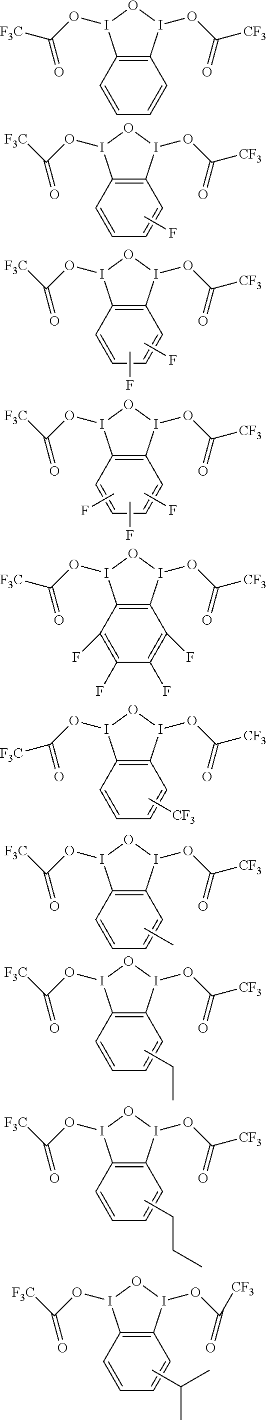

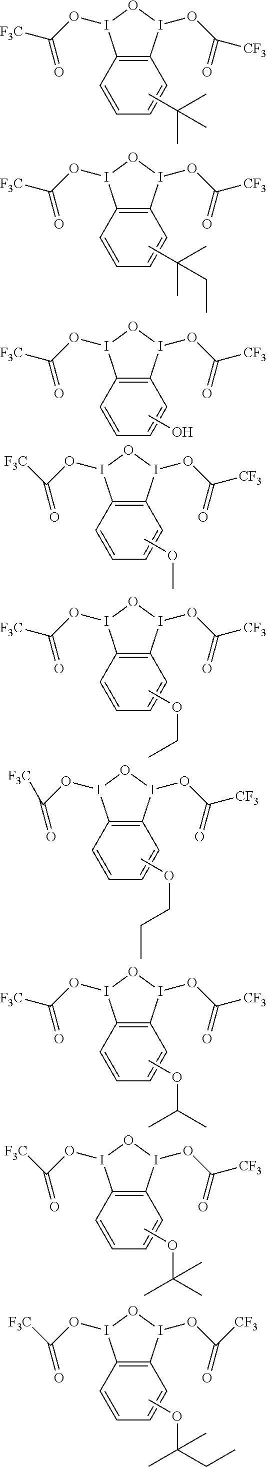

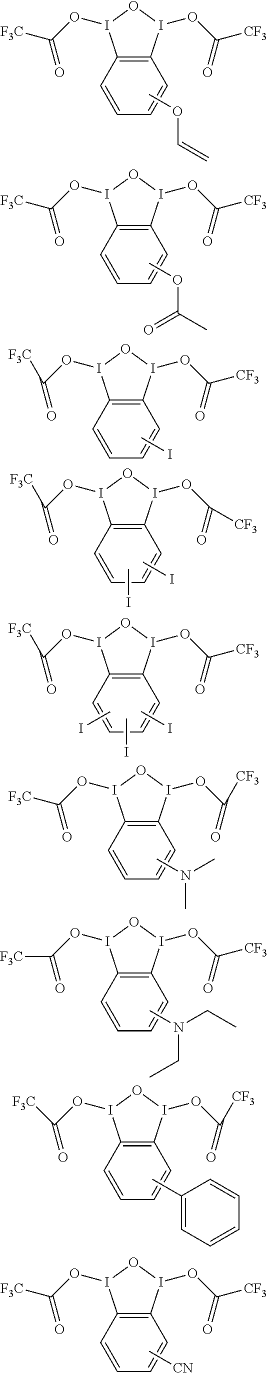

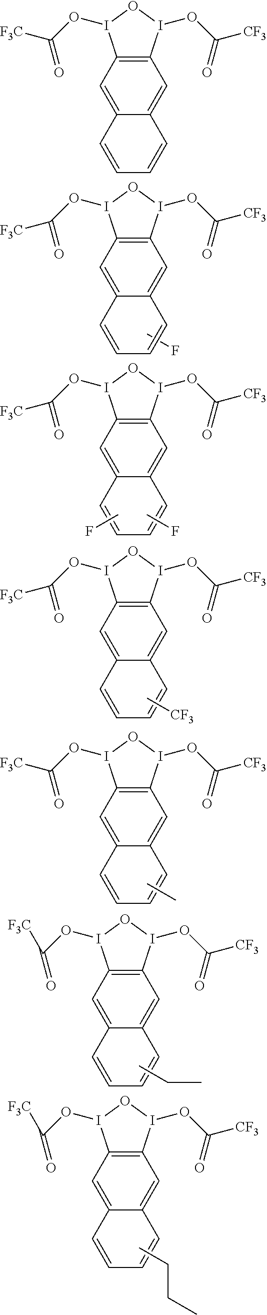

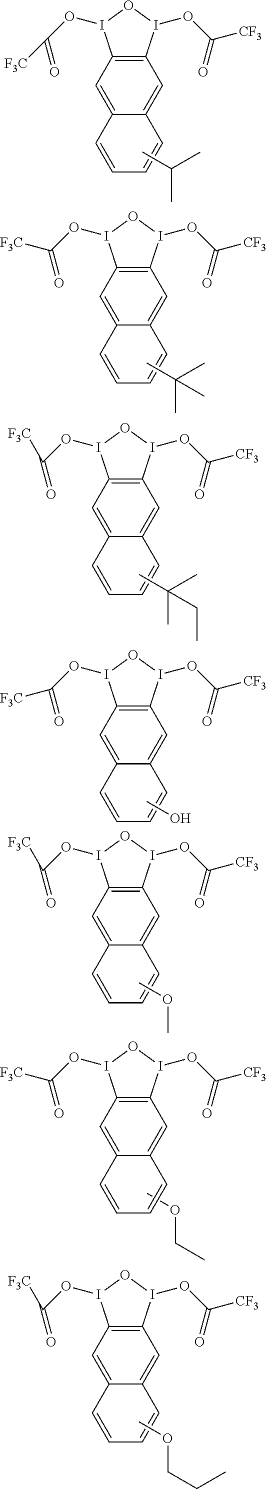

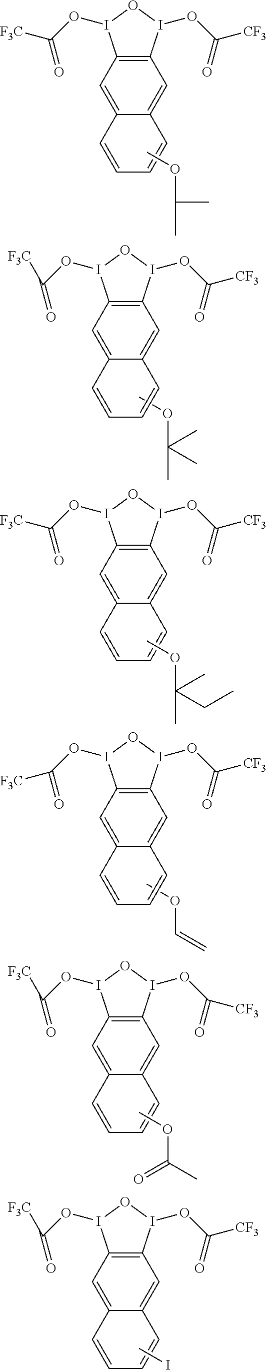

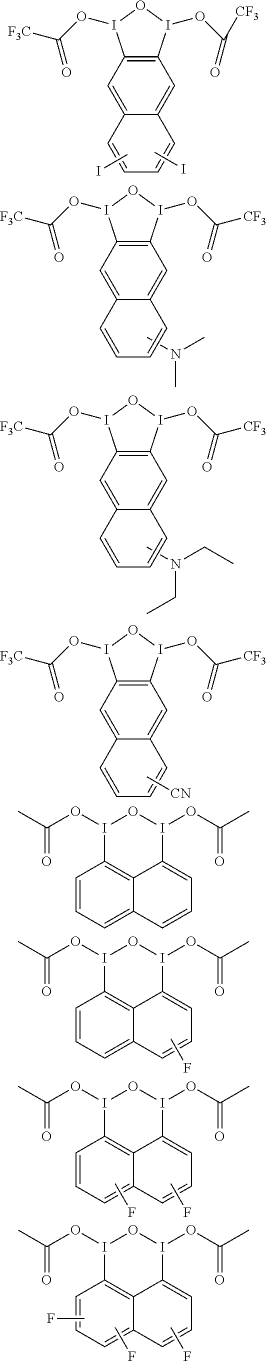

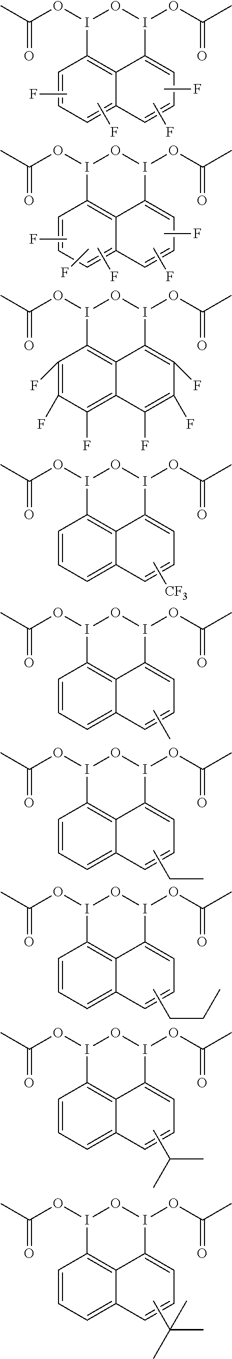

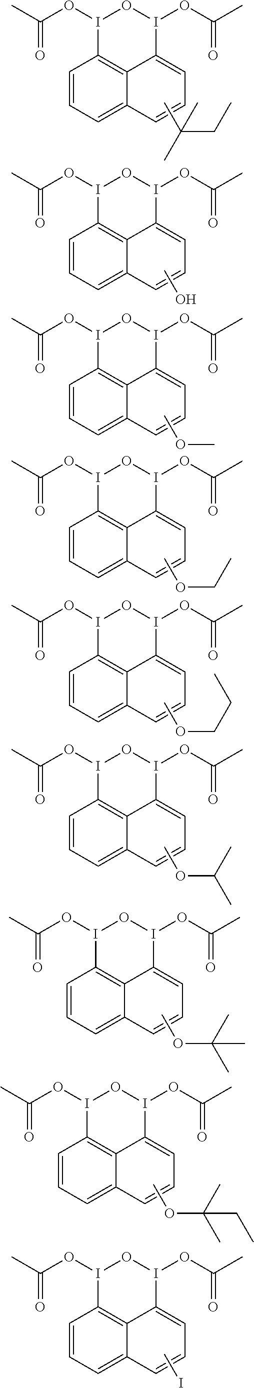

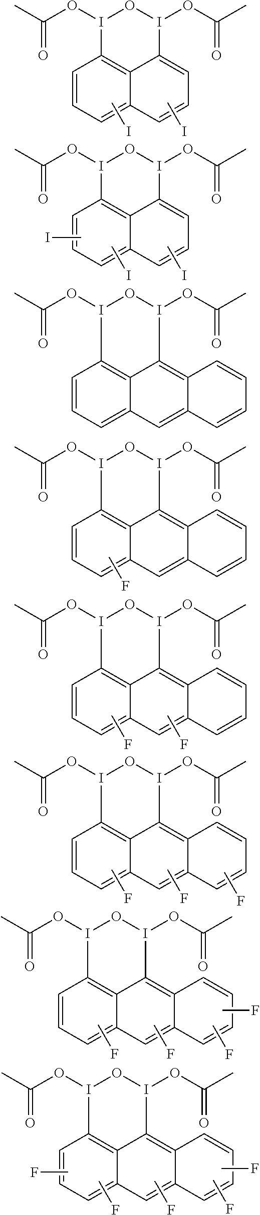

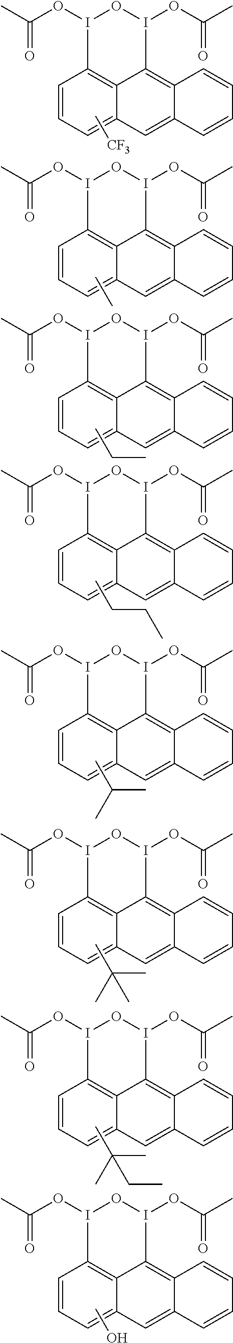

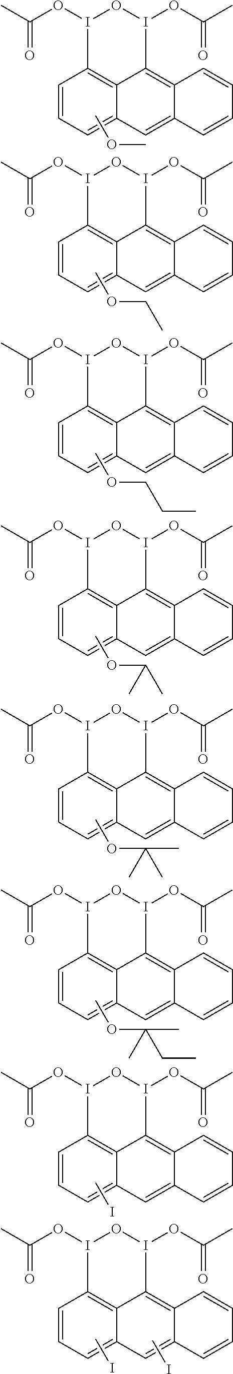

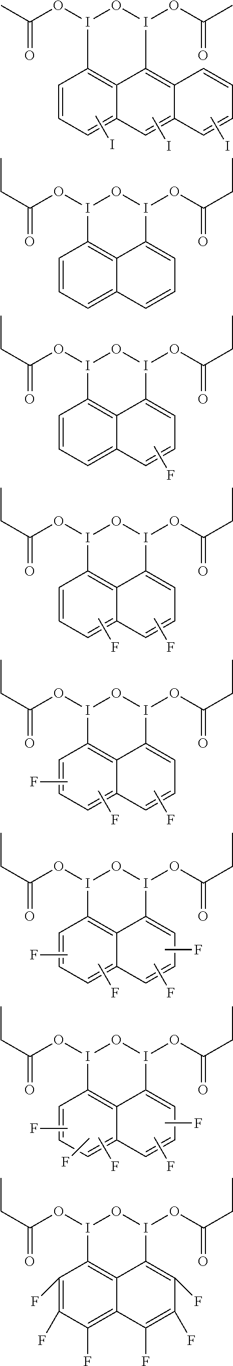

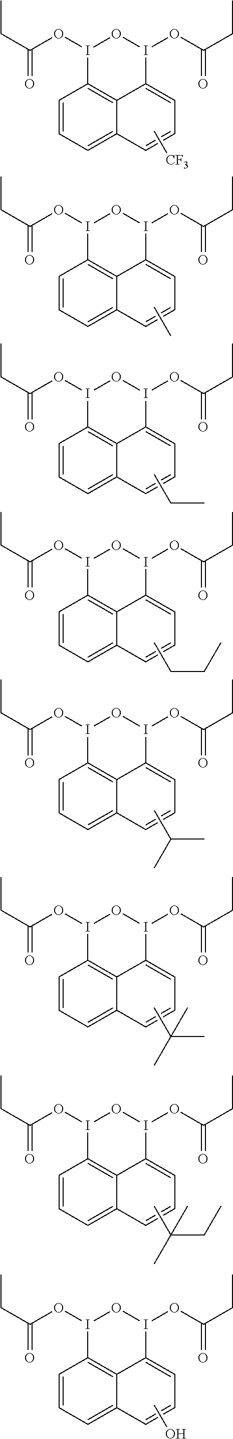

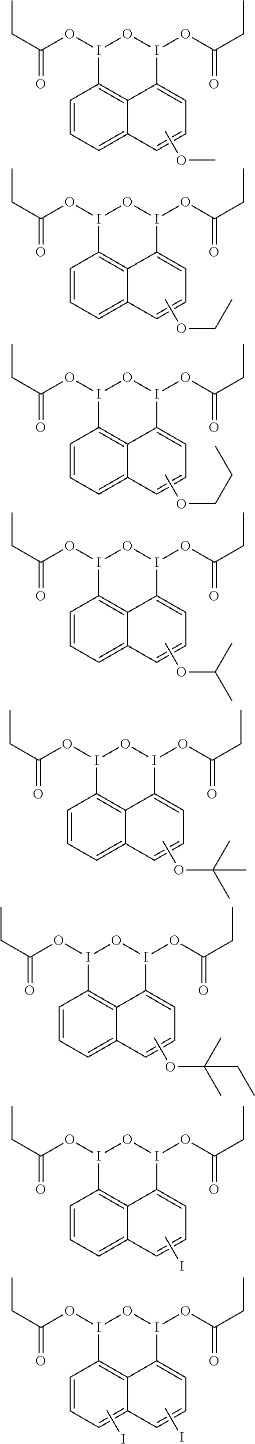

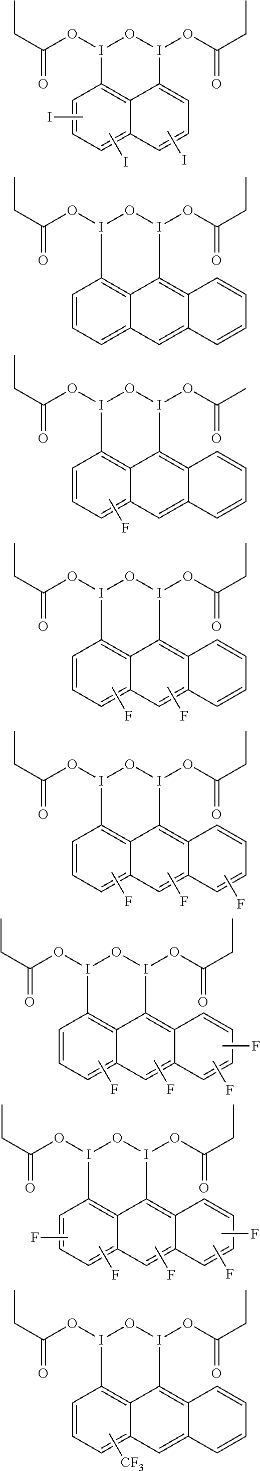

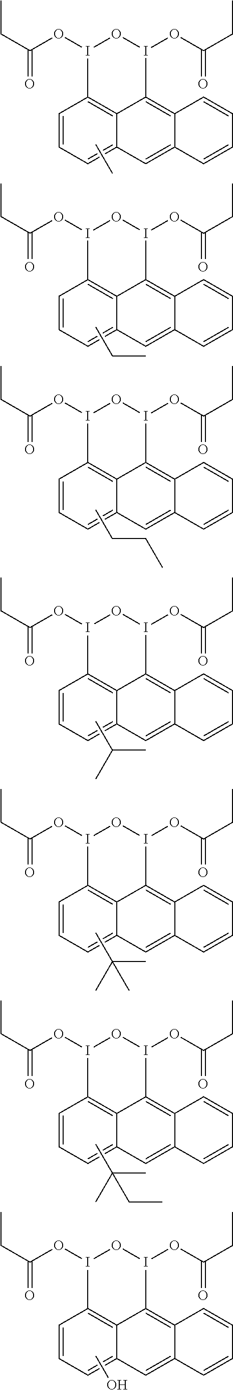

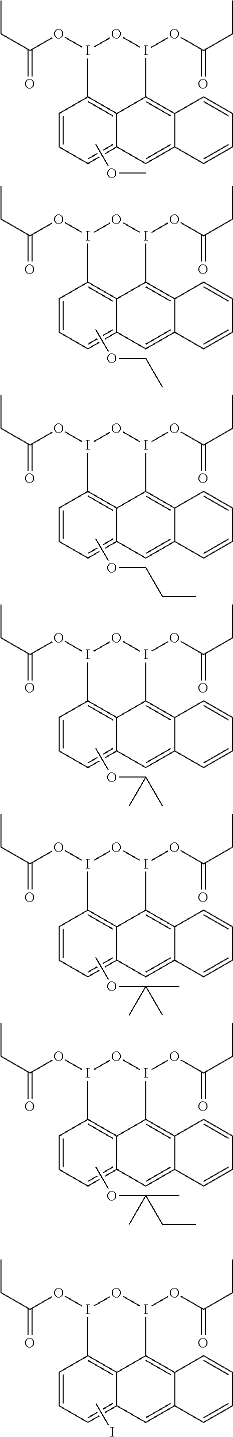

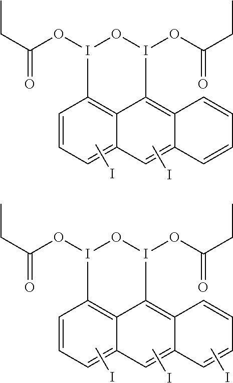

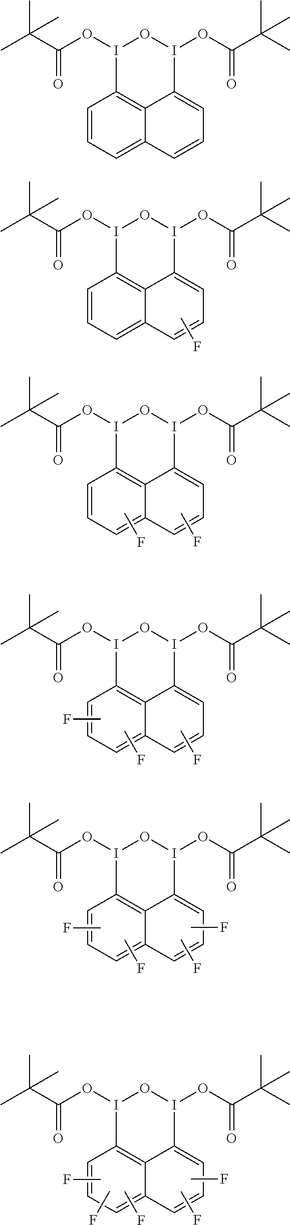

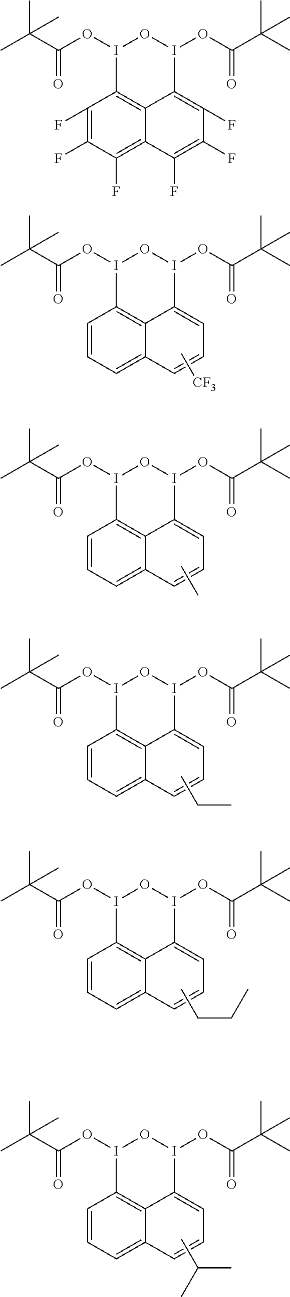

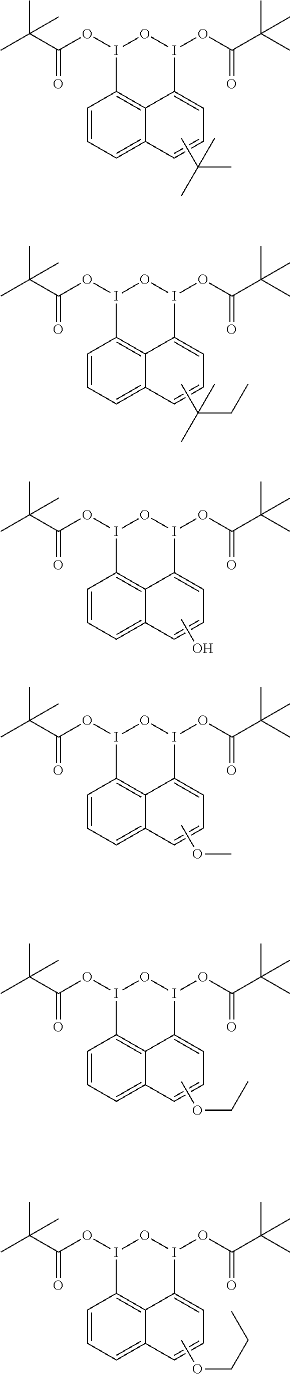

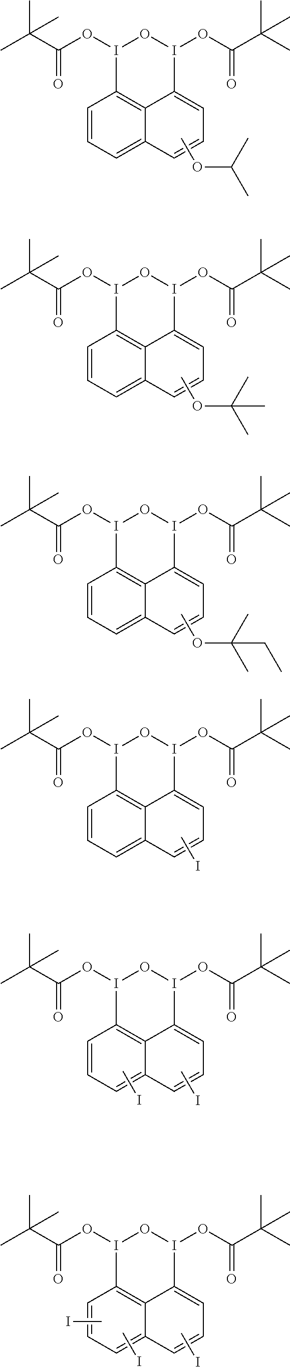

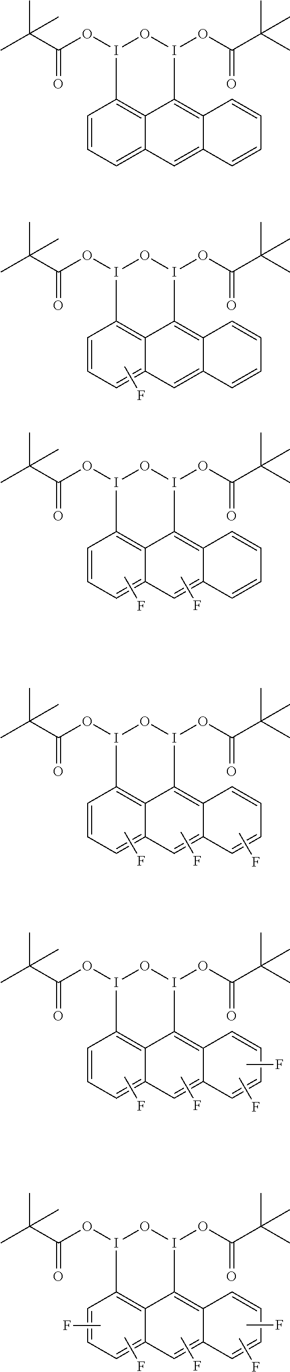

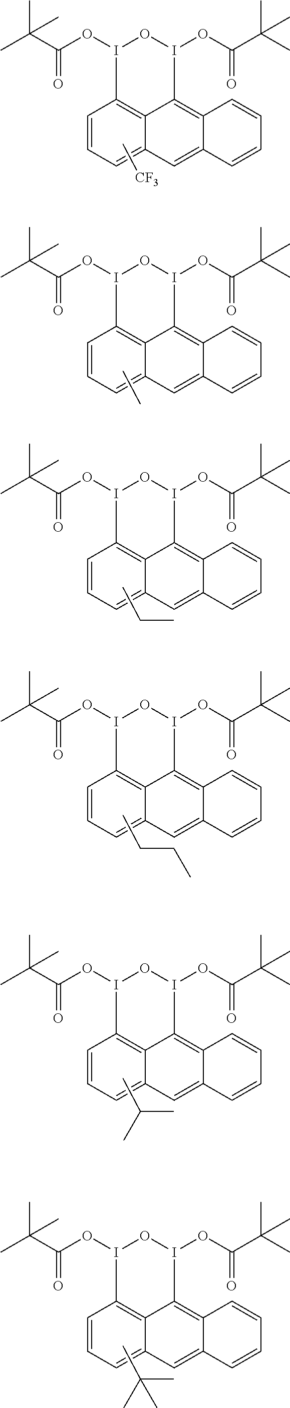

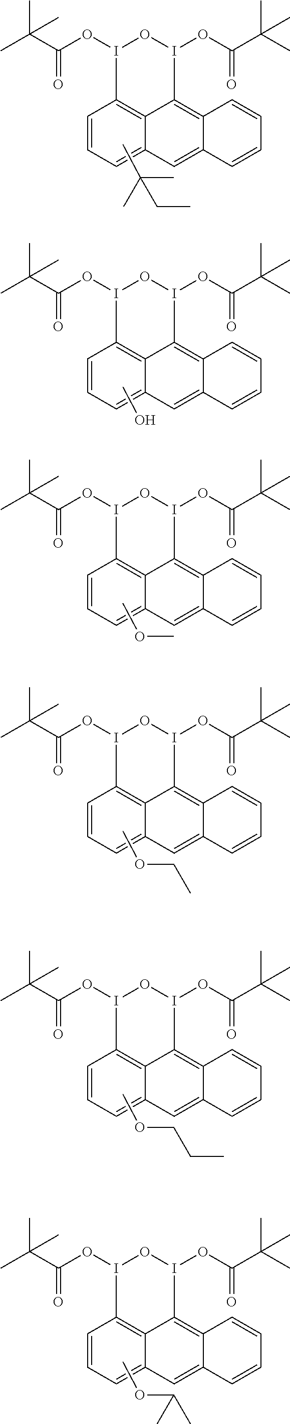

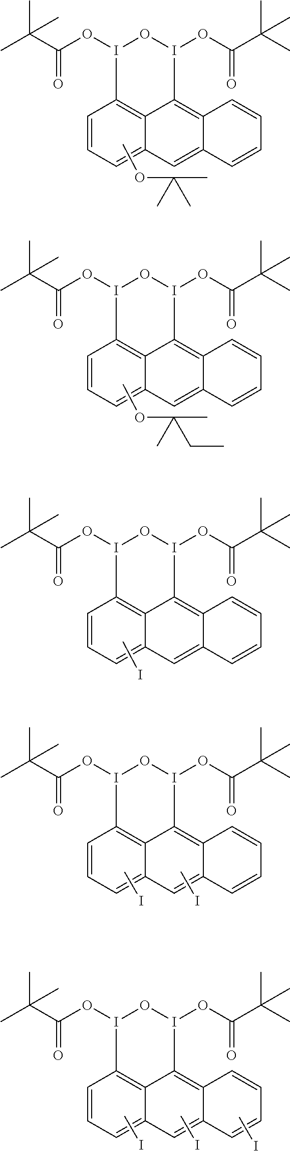

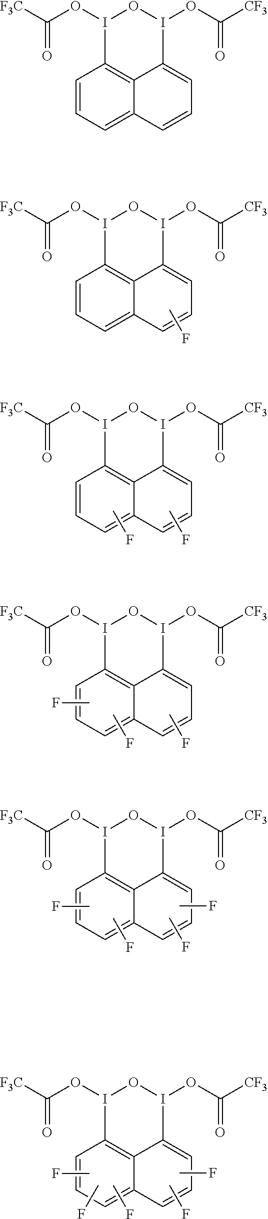

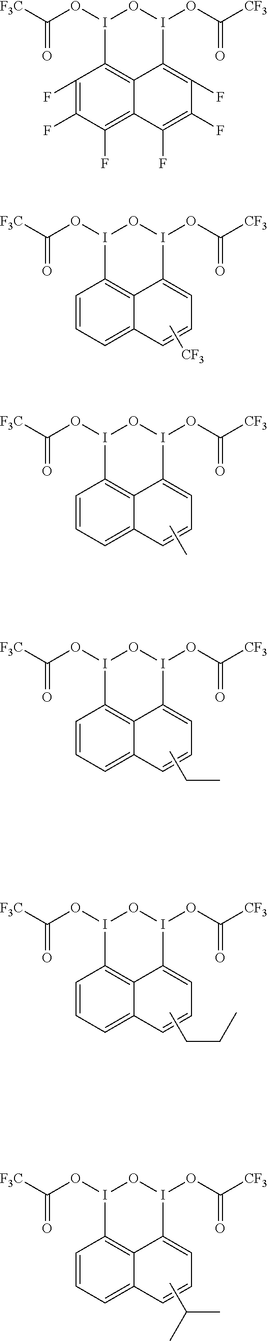

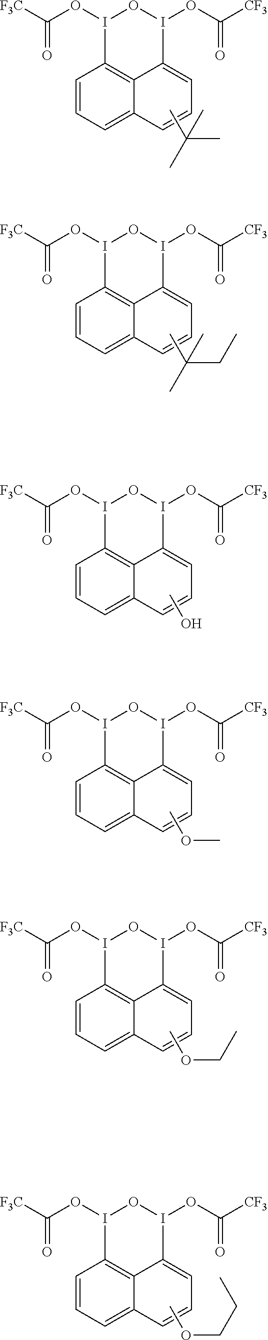

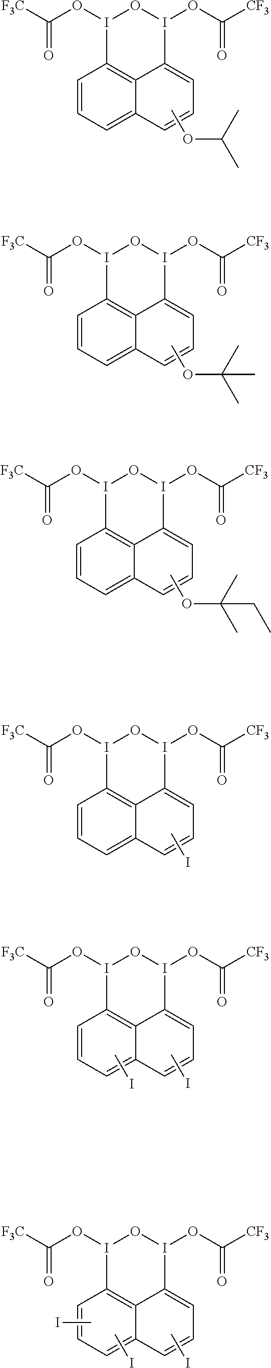

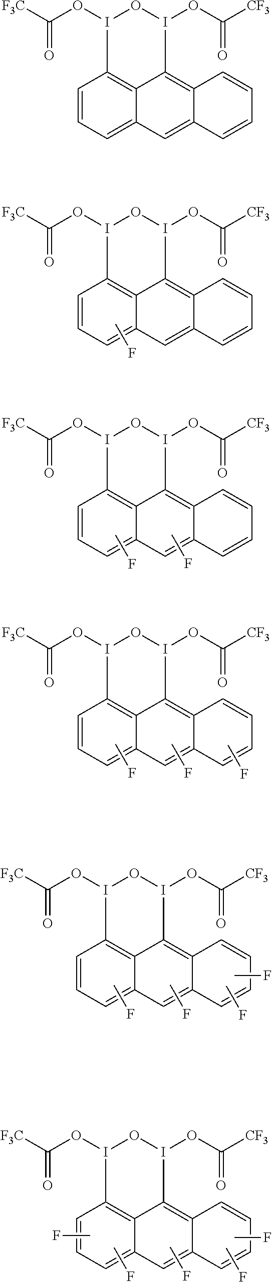

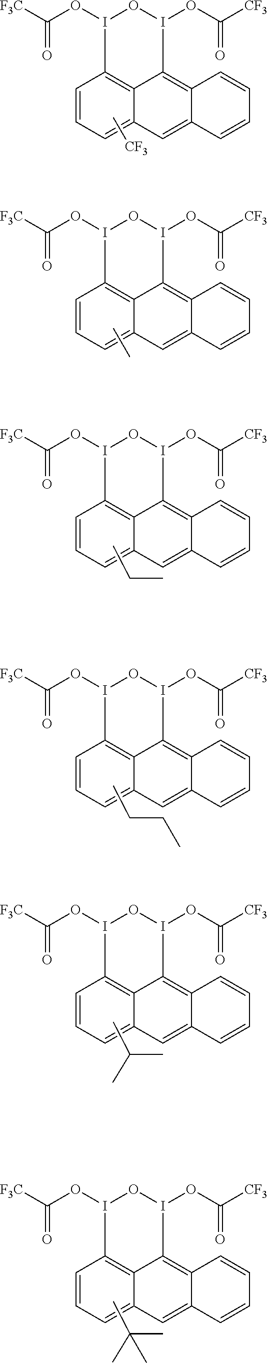

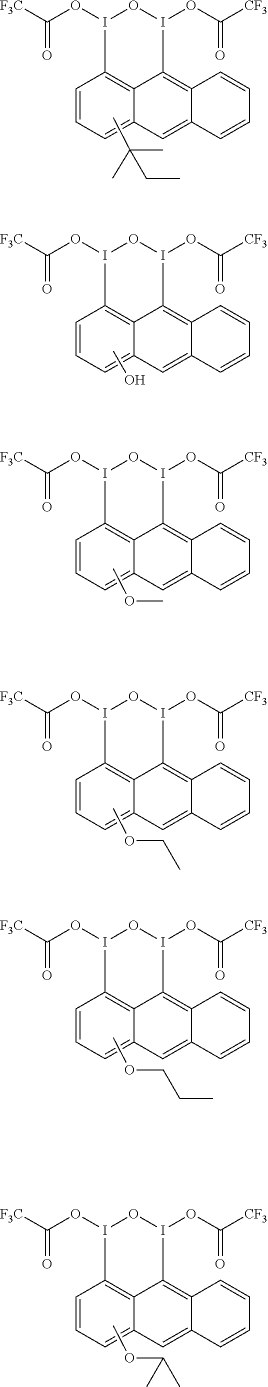

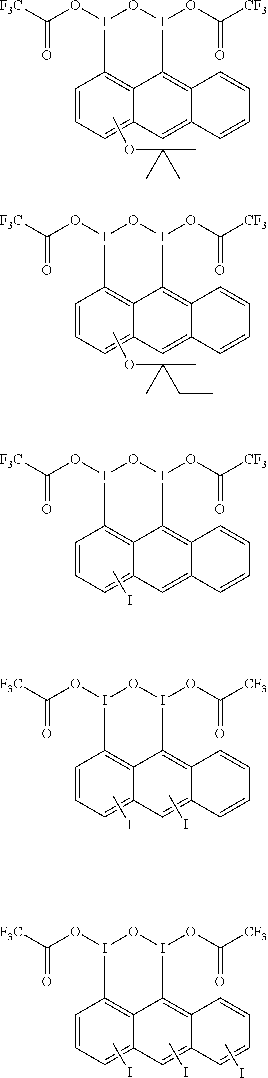

Specific examples of the hypervalent iodine compound represented by the formula (7) include the following, but are not limited thereto. Note that, in the following formulae, L₁ is as defined above.

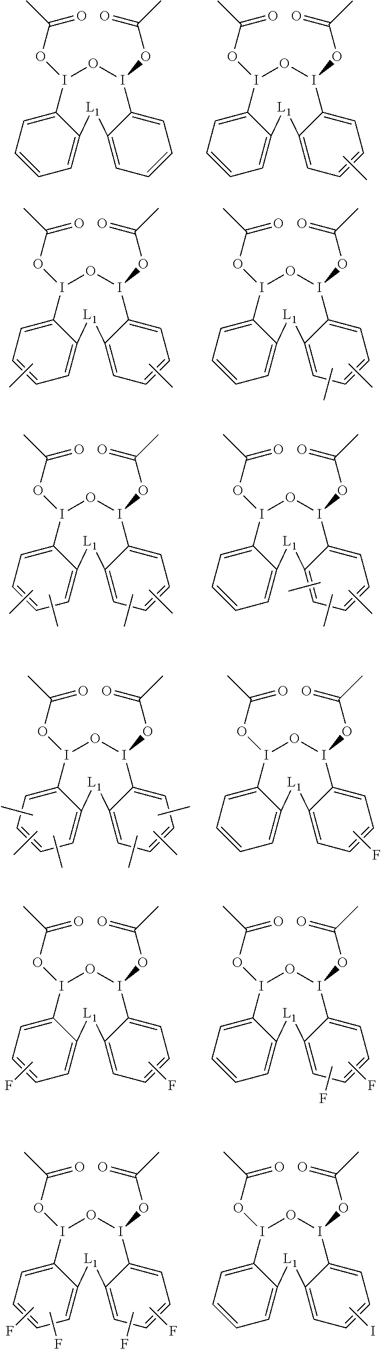

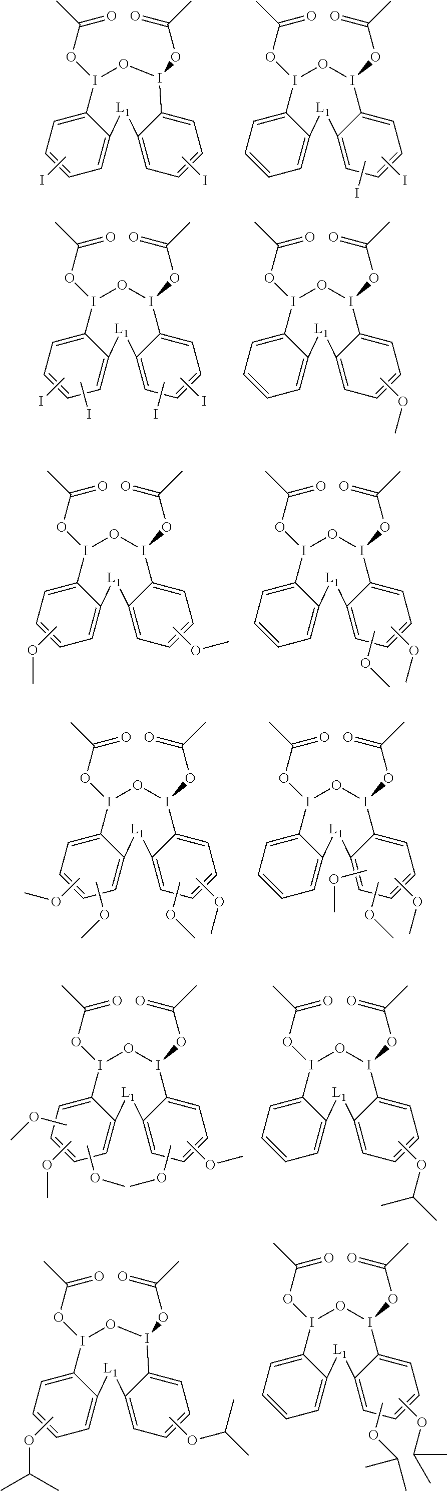

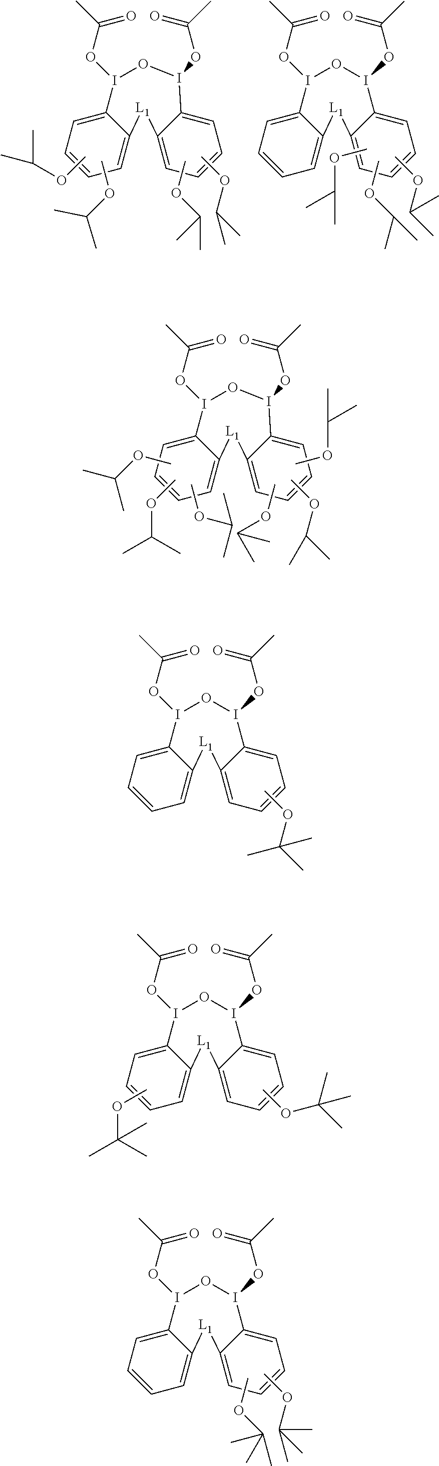

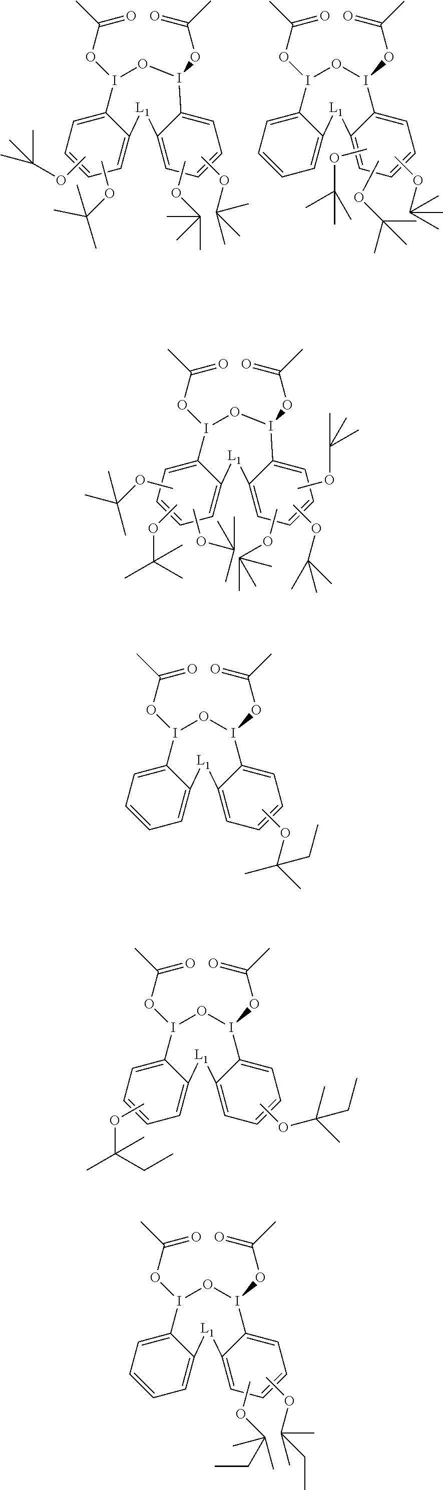

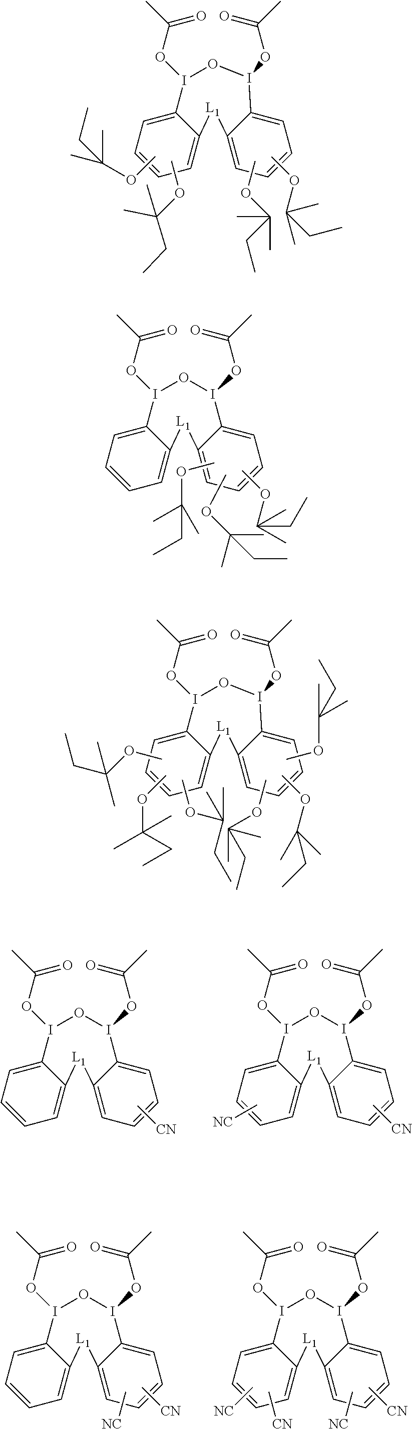

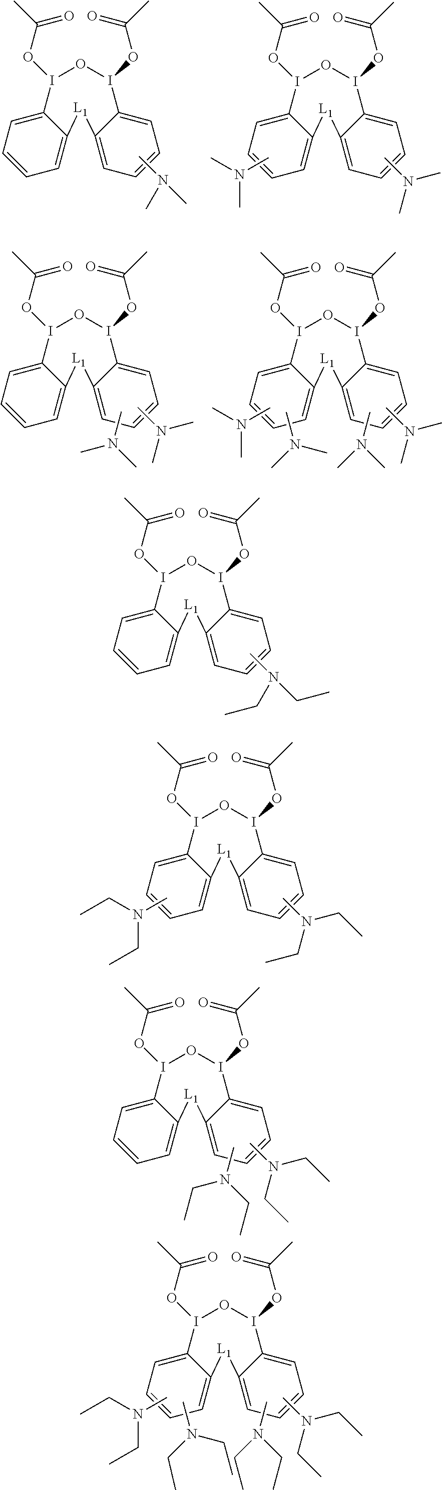

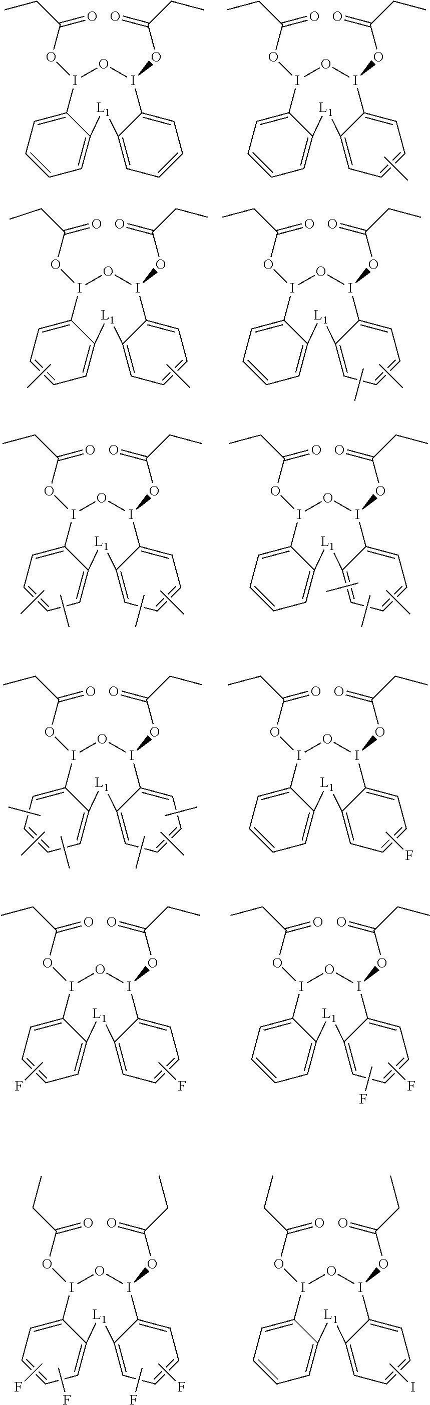

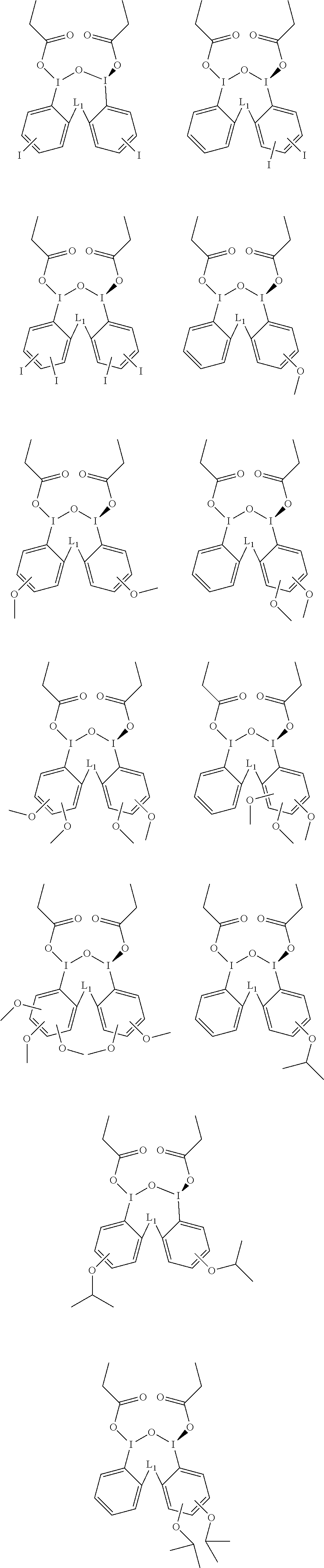

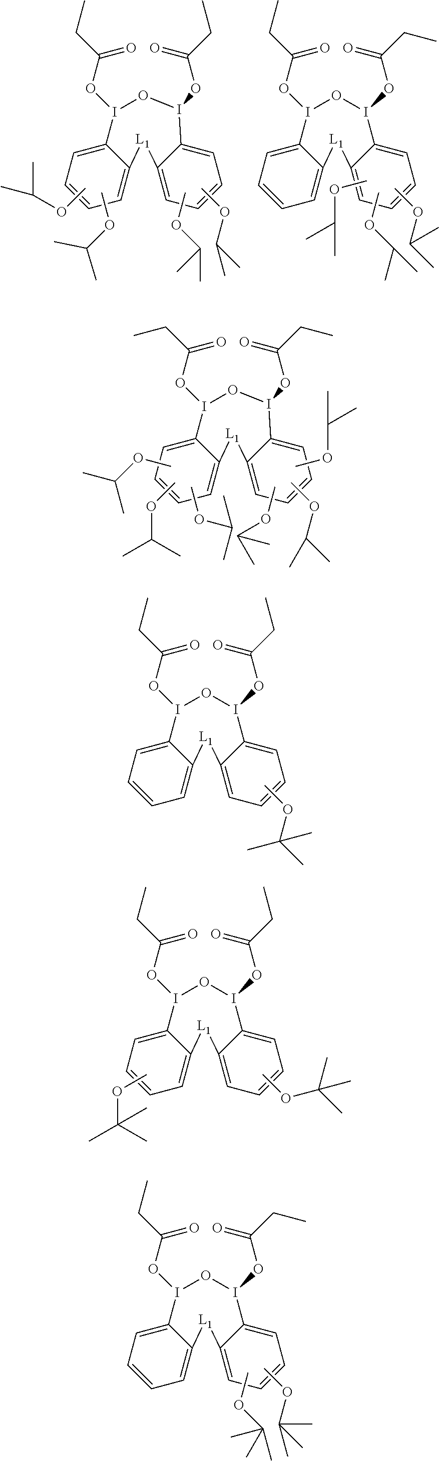

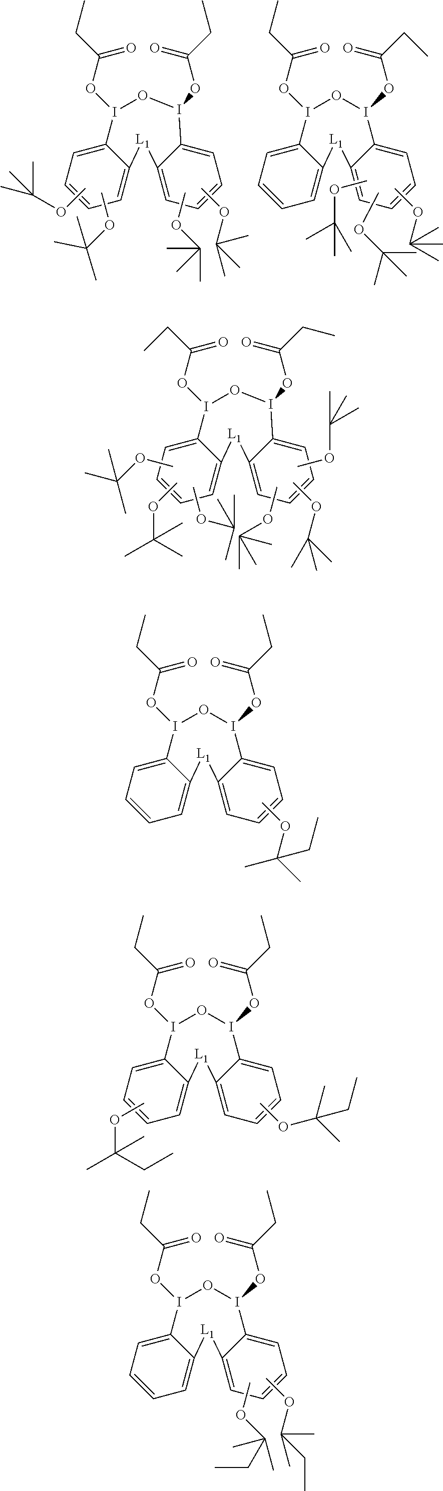

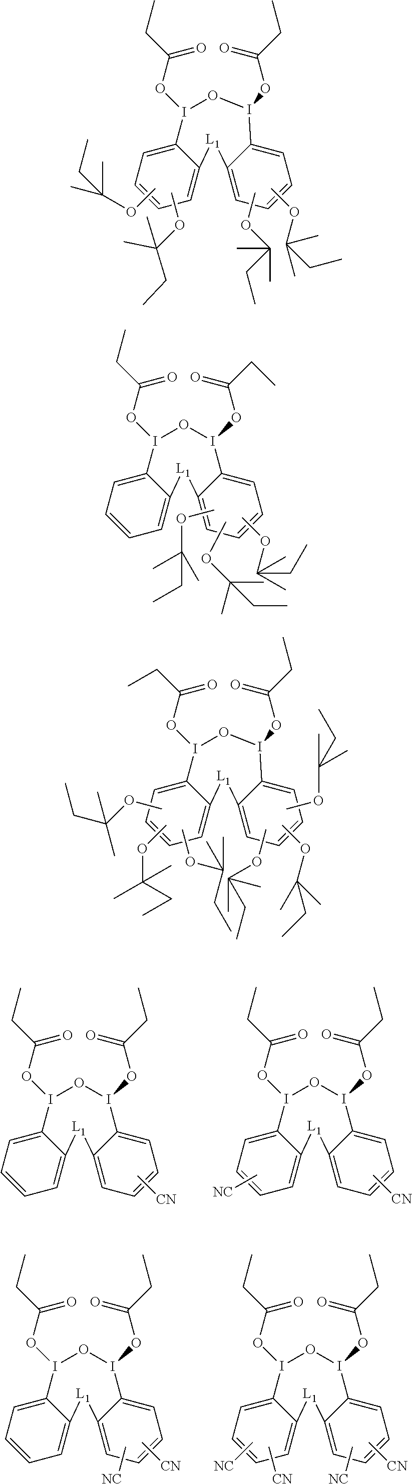

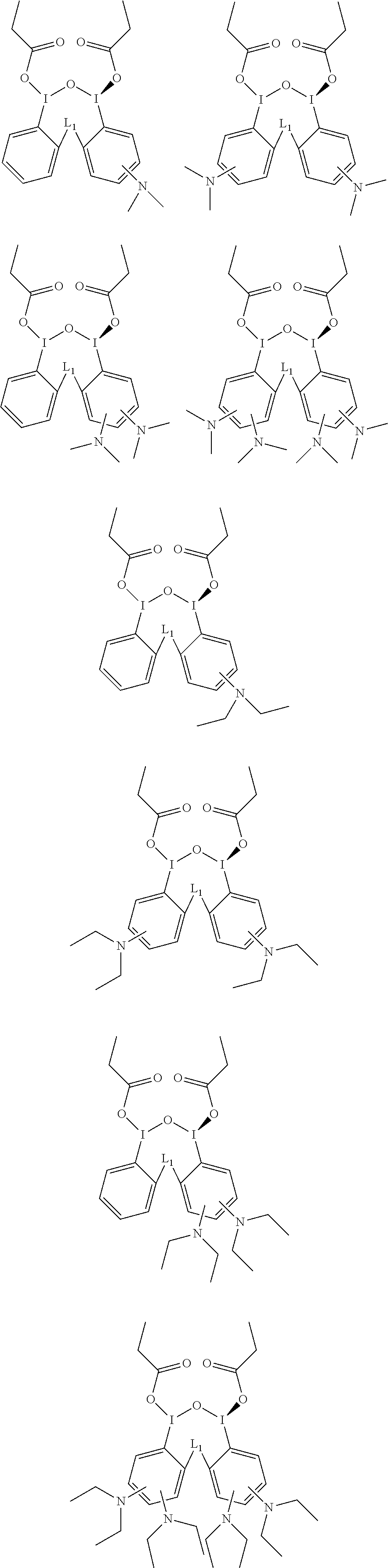

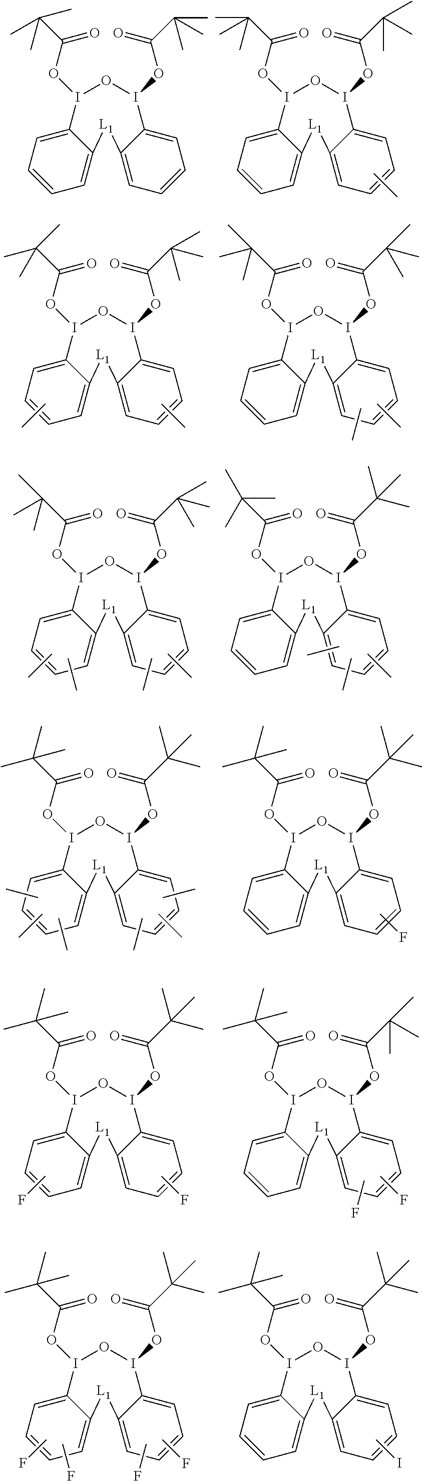

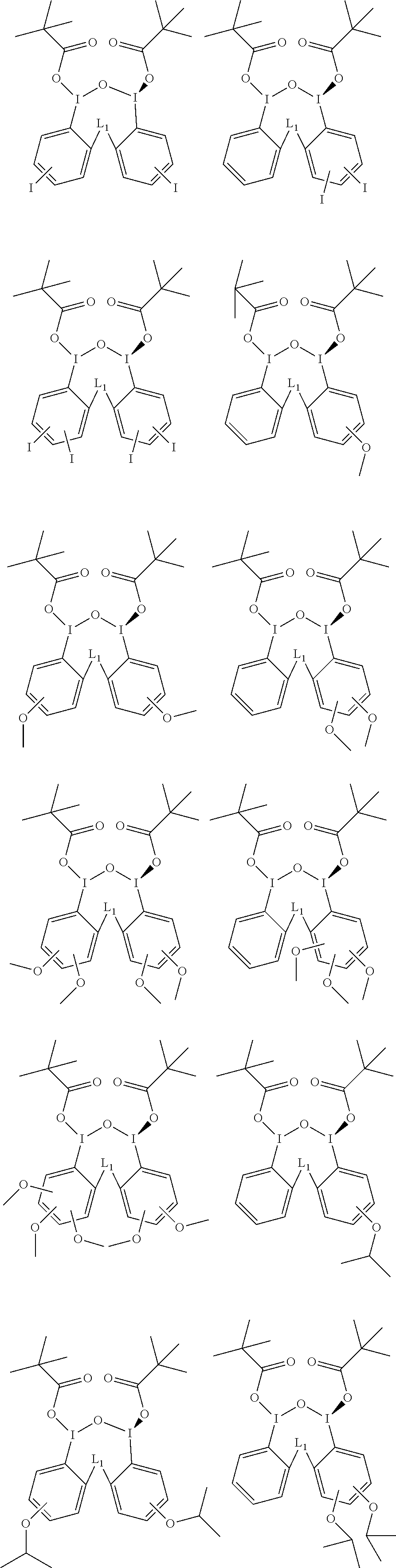

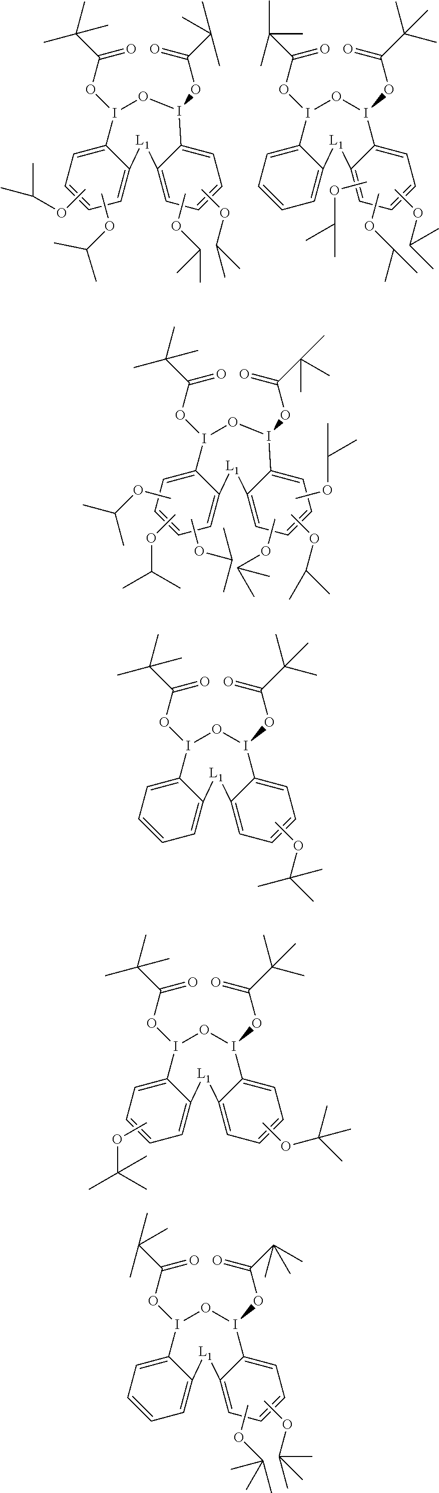

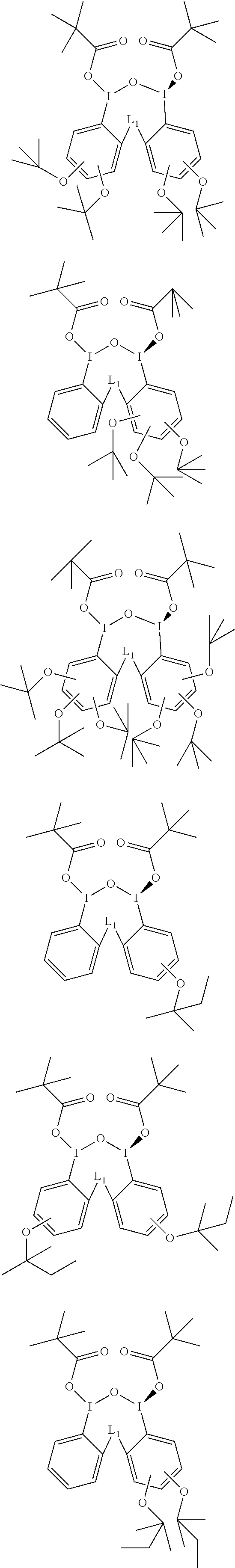

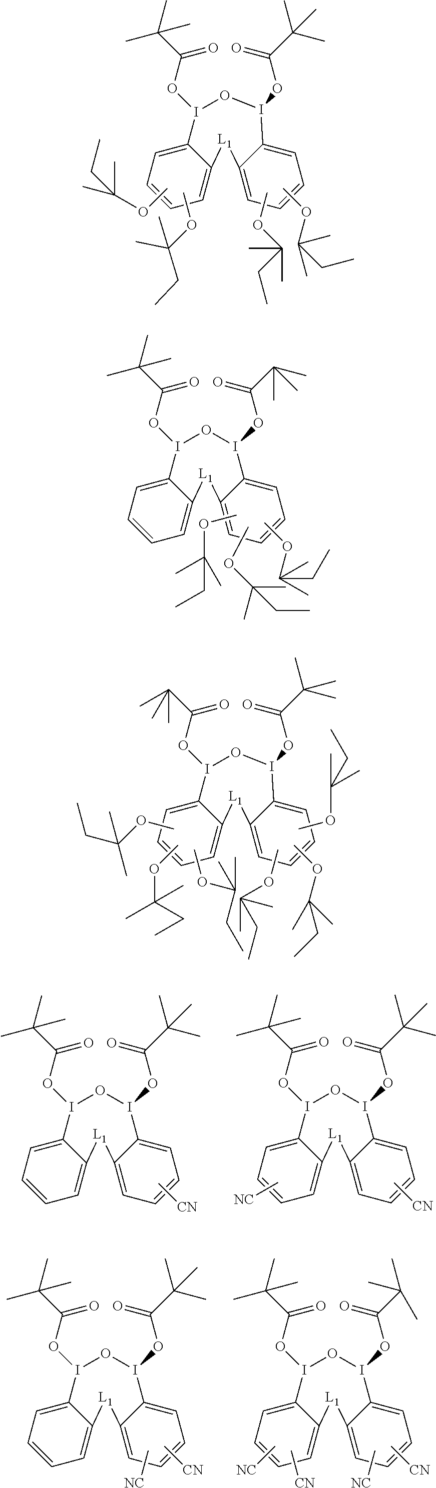

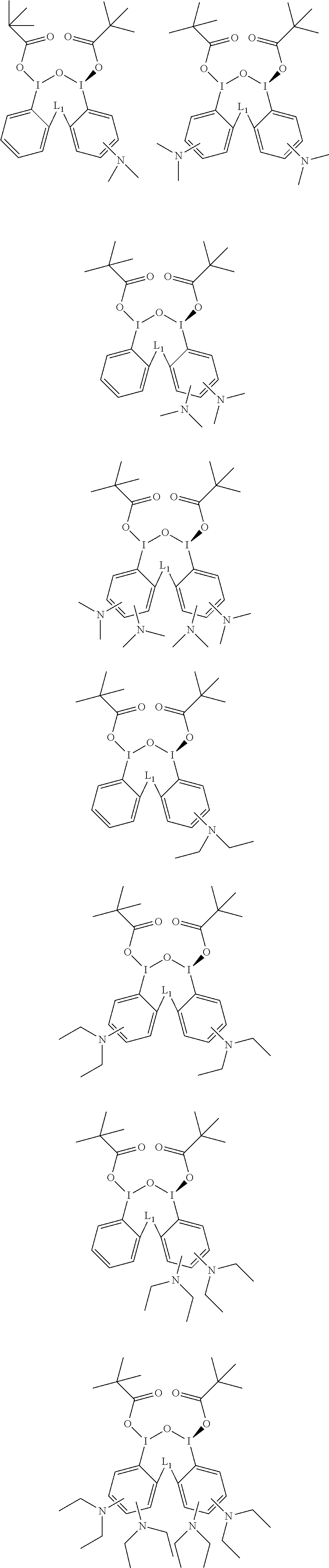

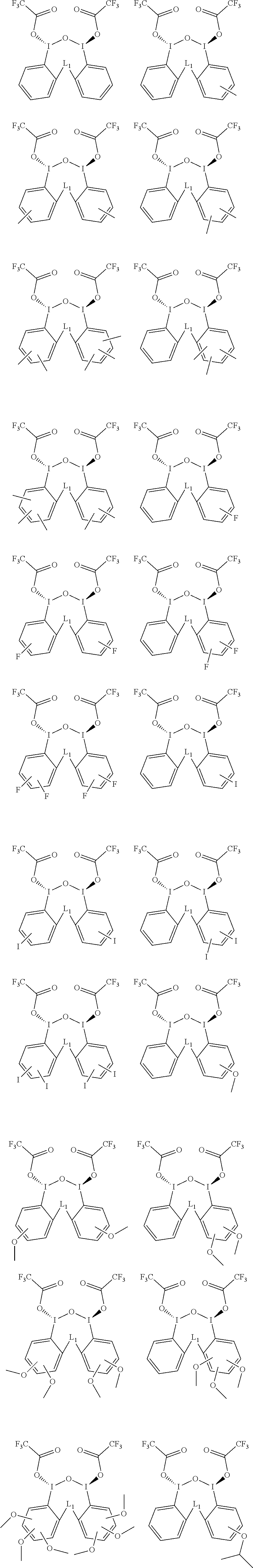

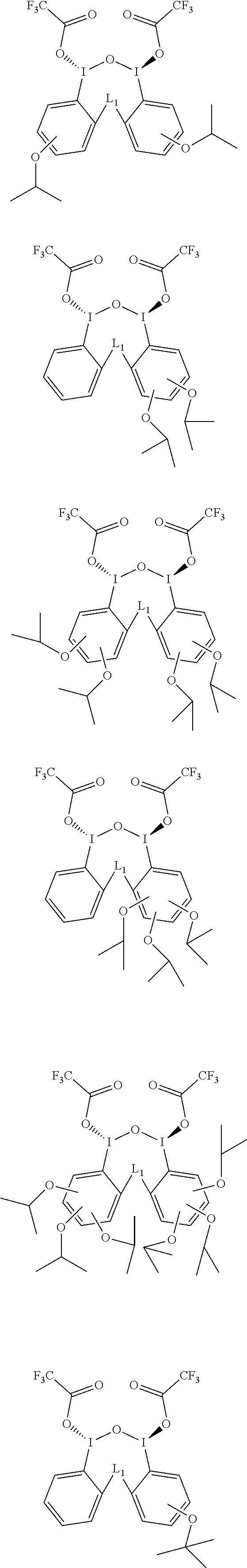

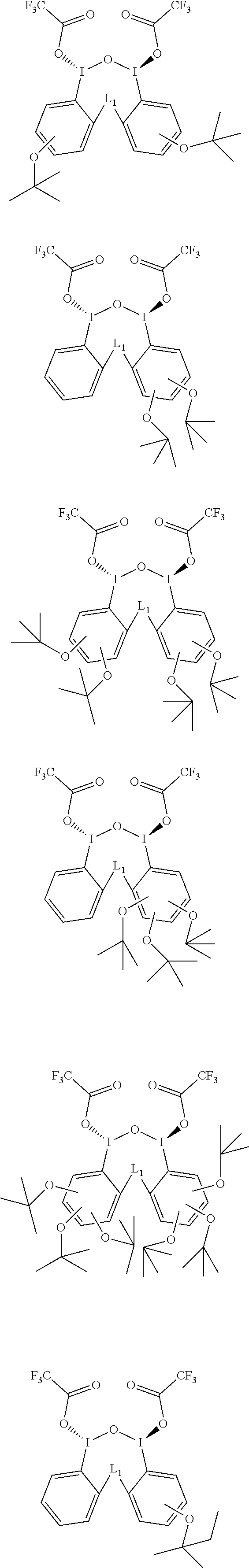

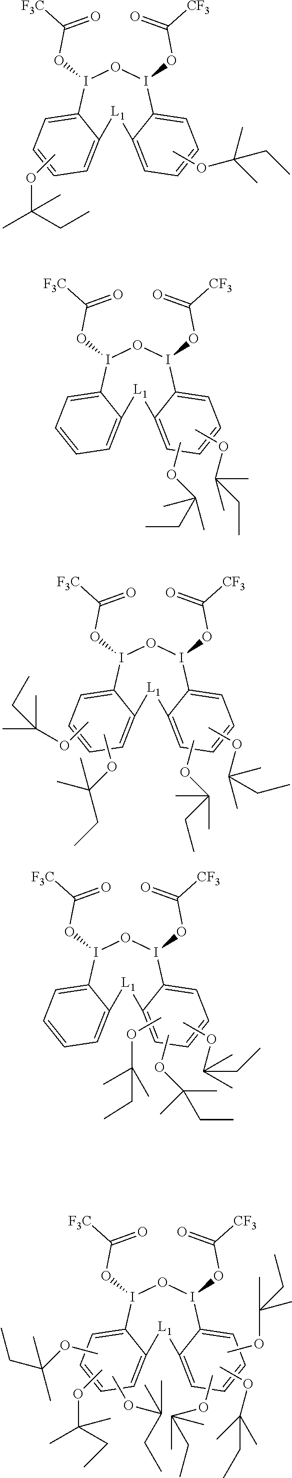

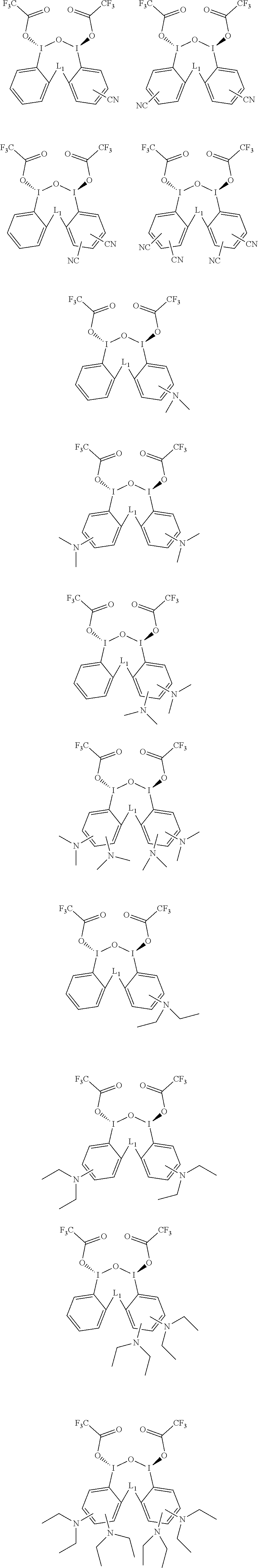

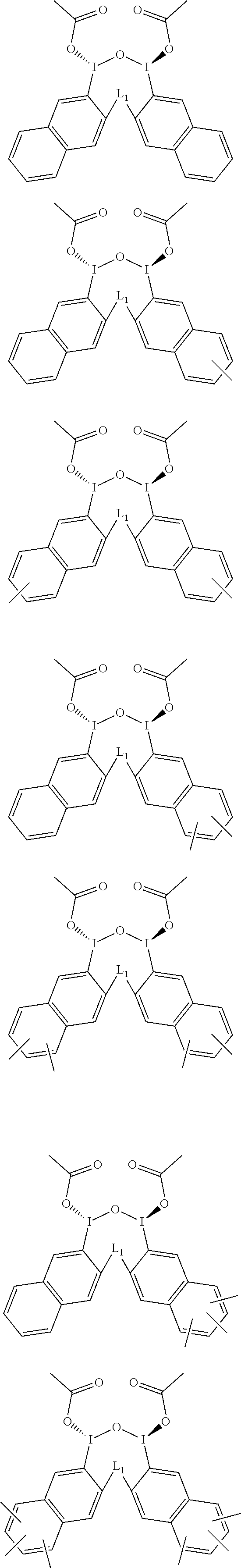

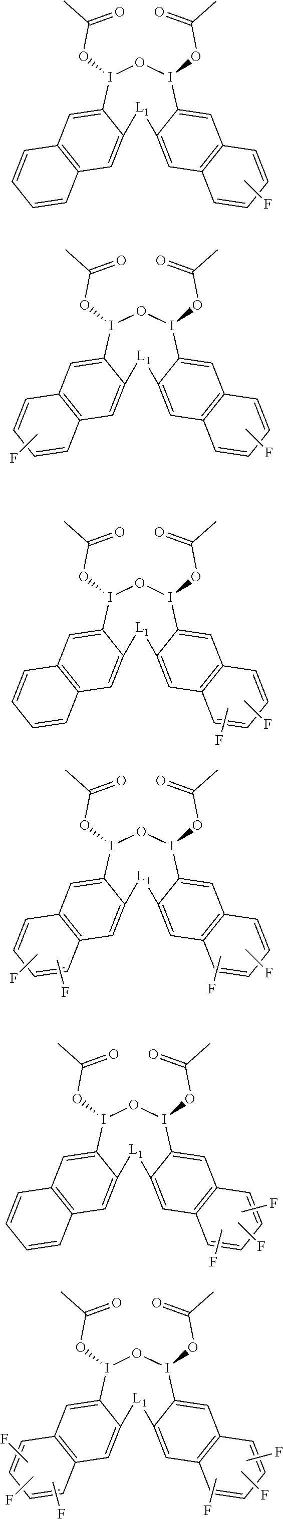

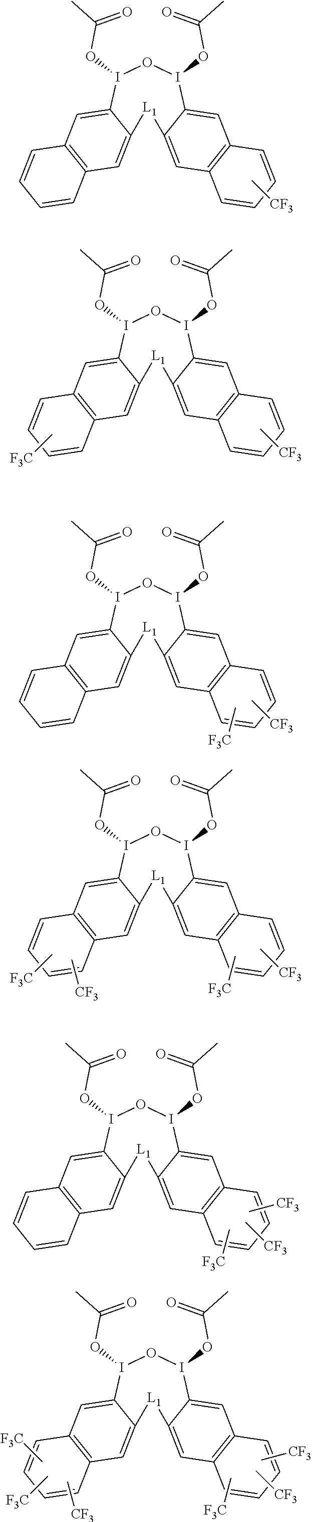

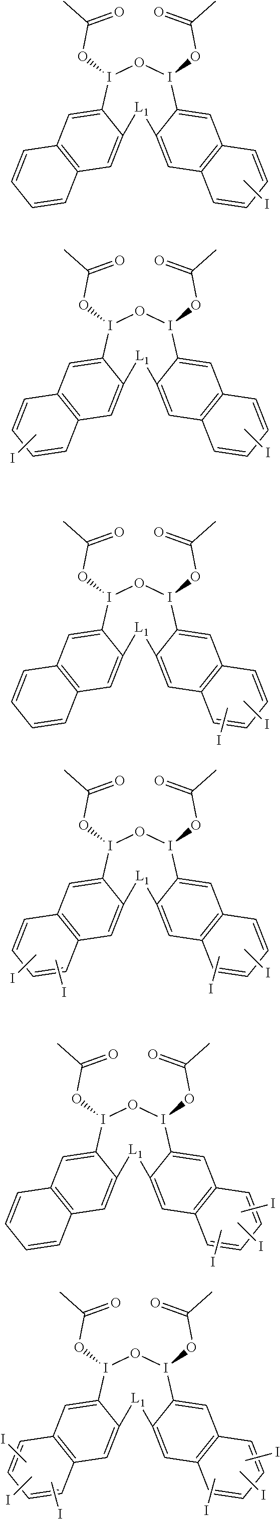

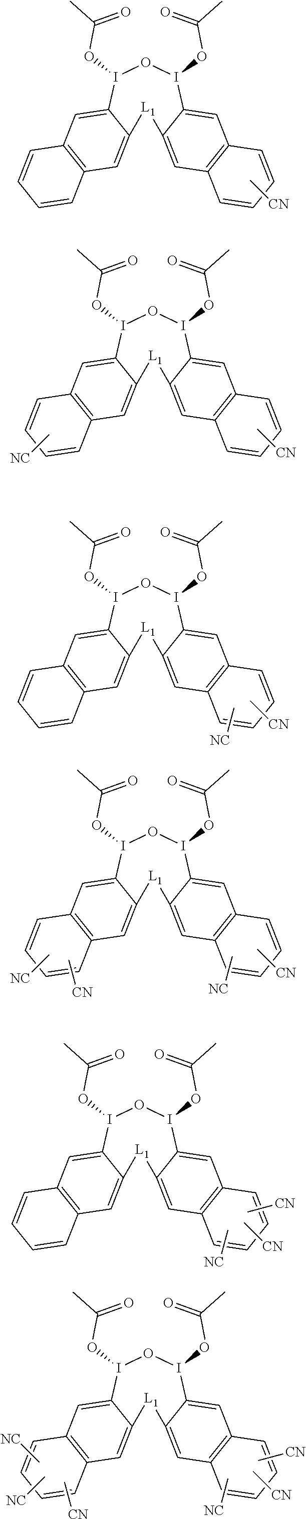

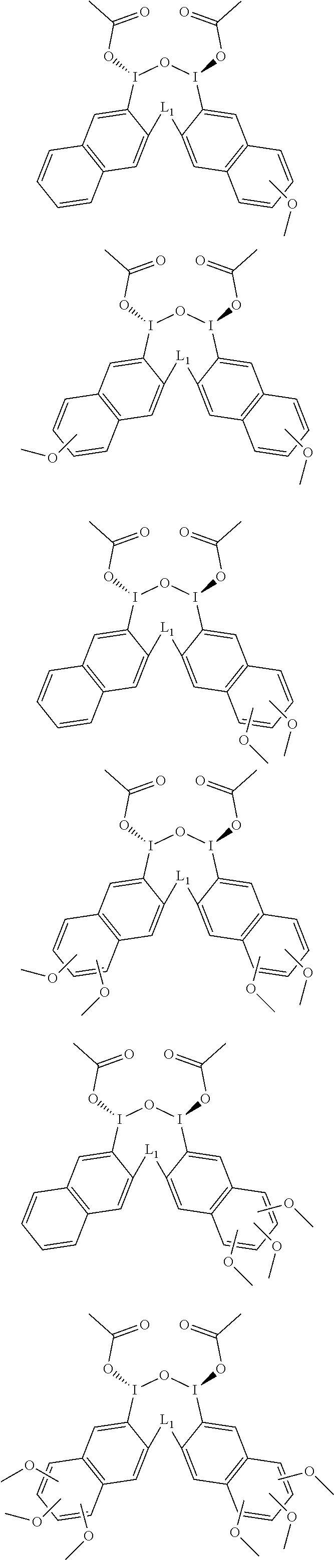

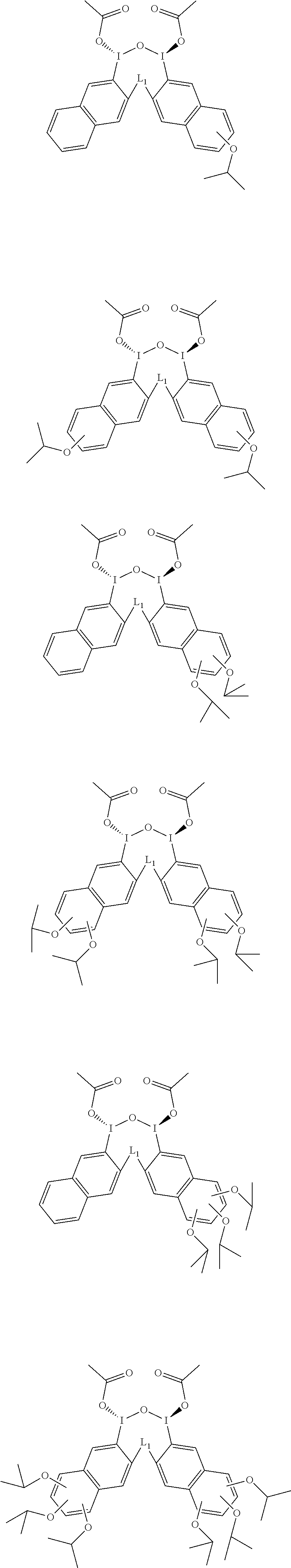

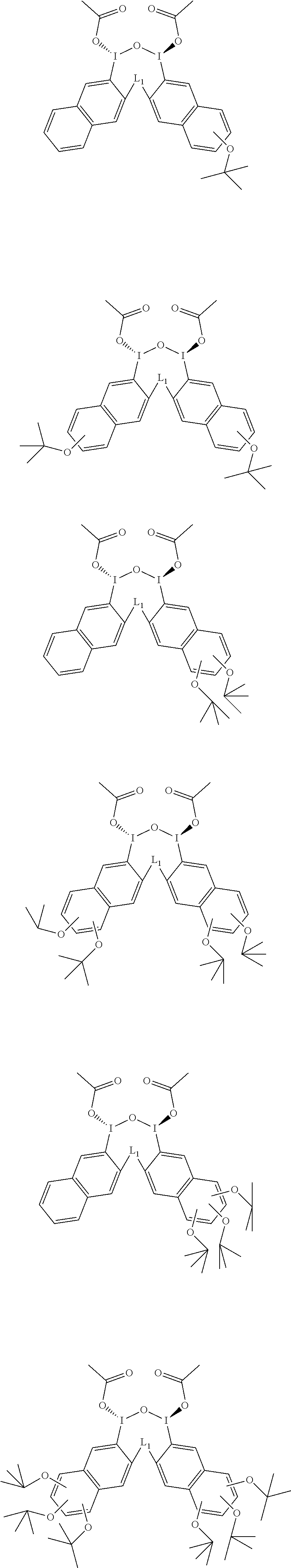

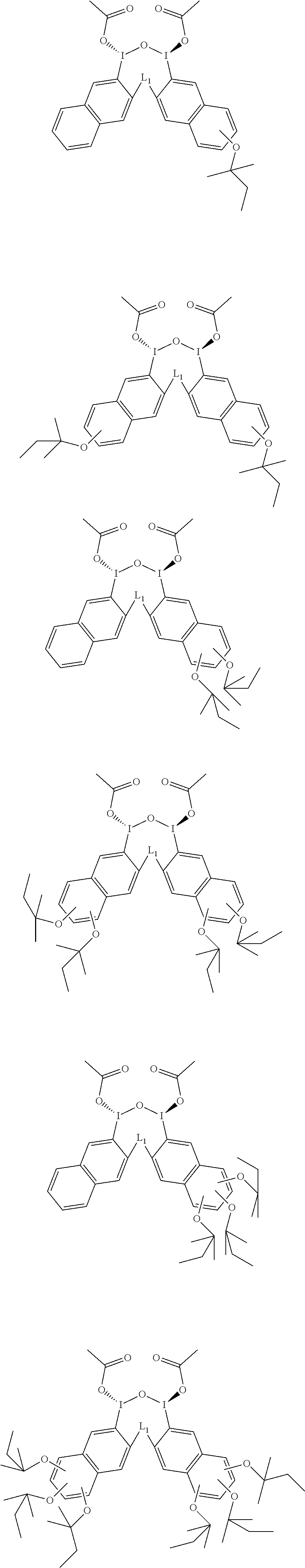

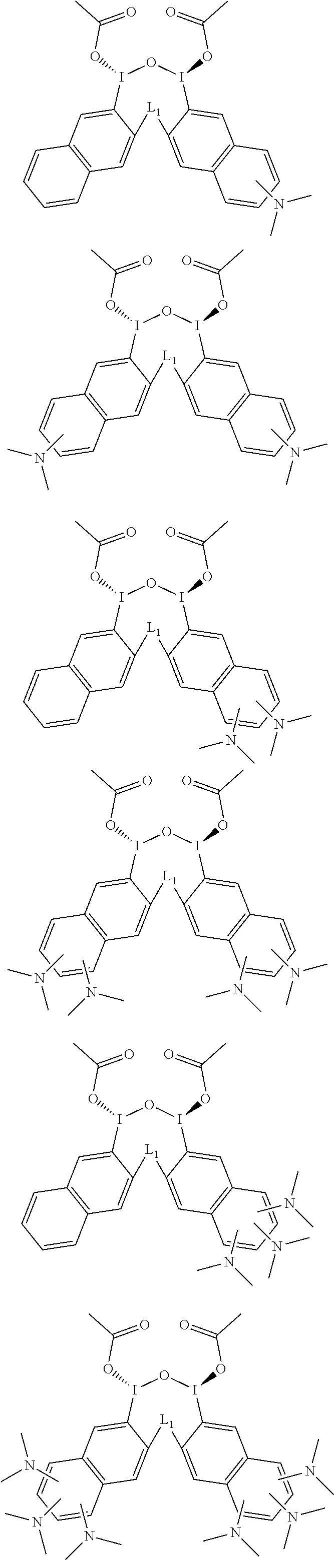

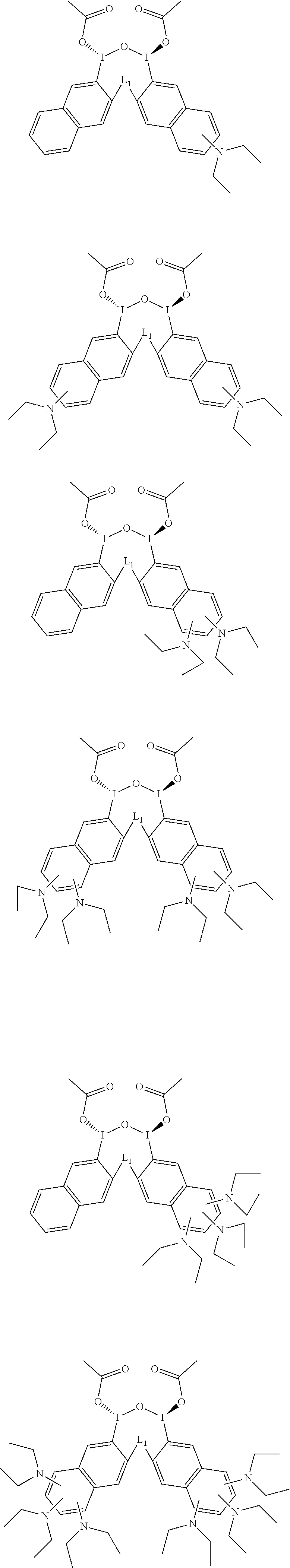

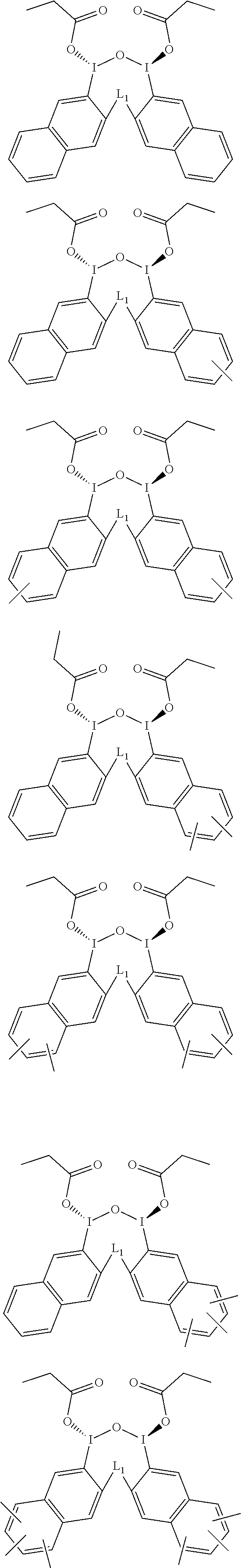

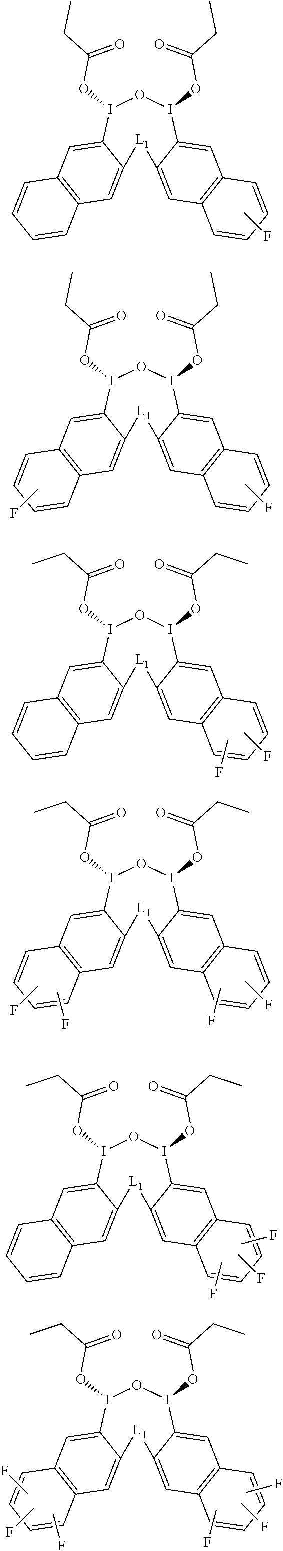

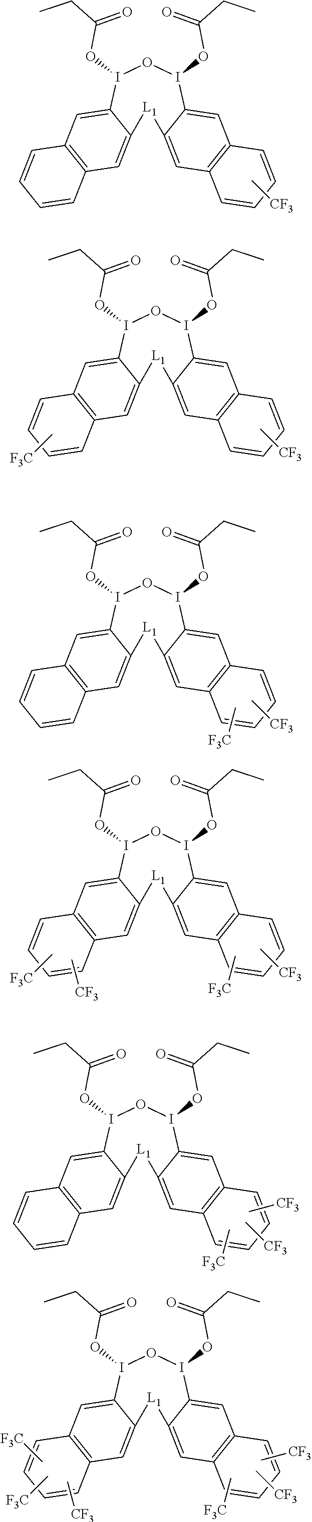

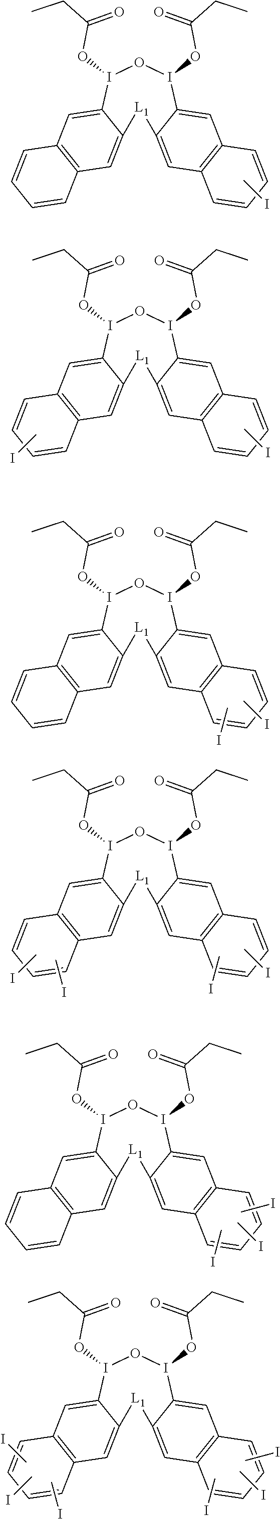

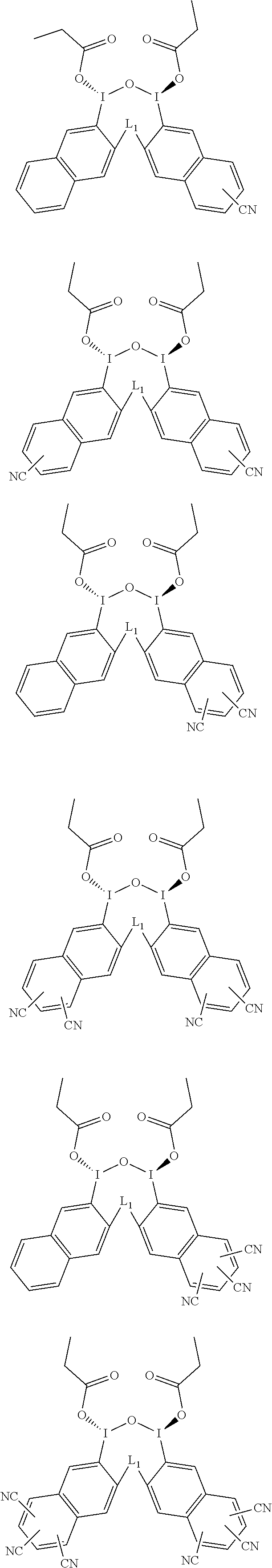

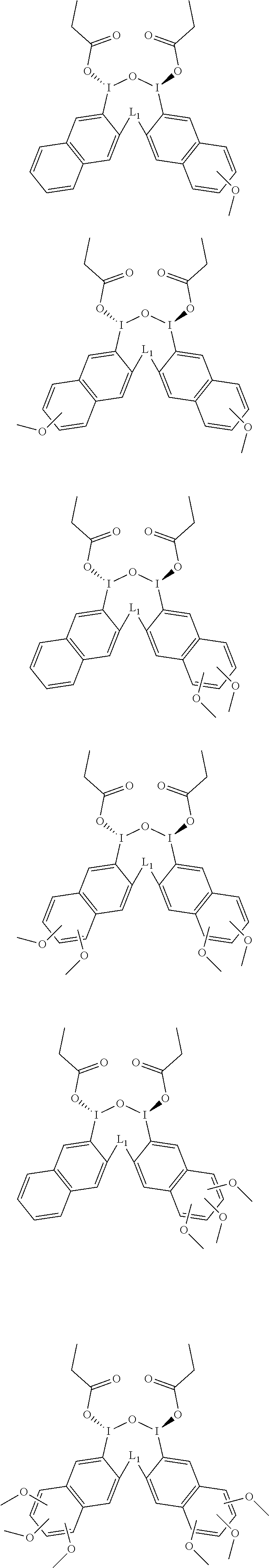

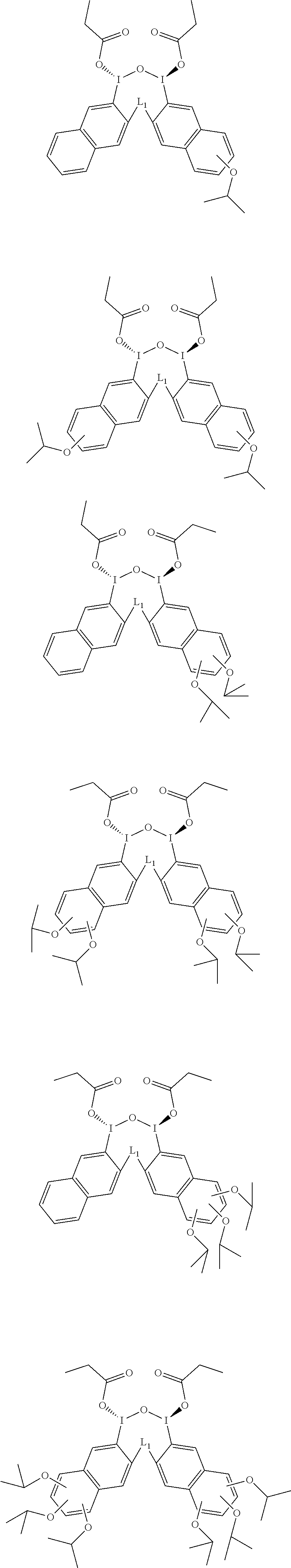

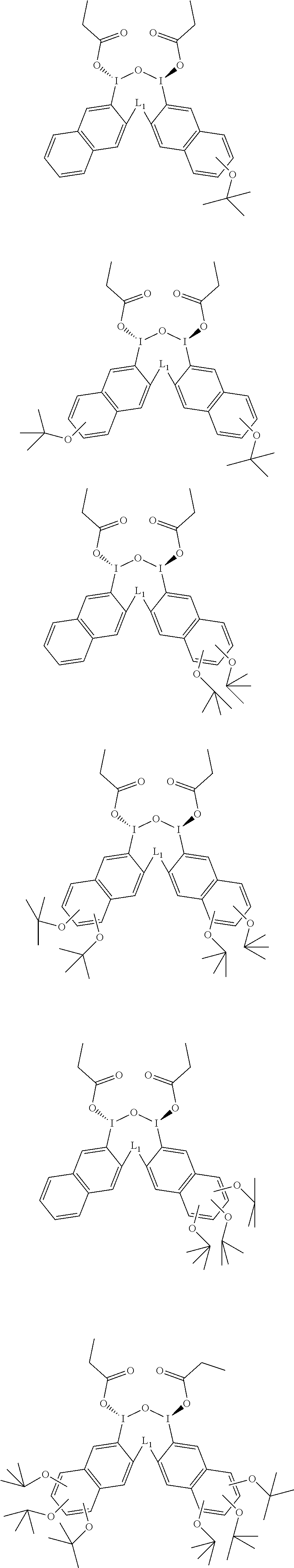

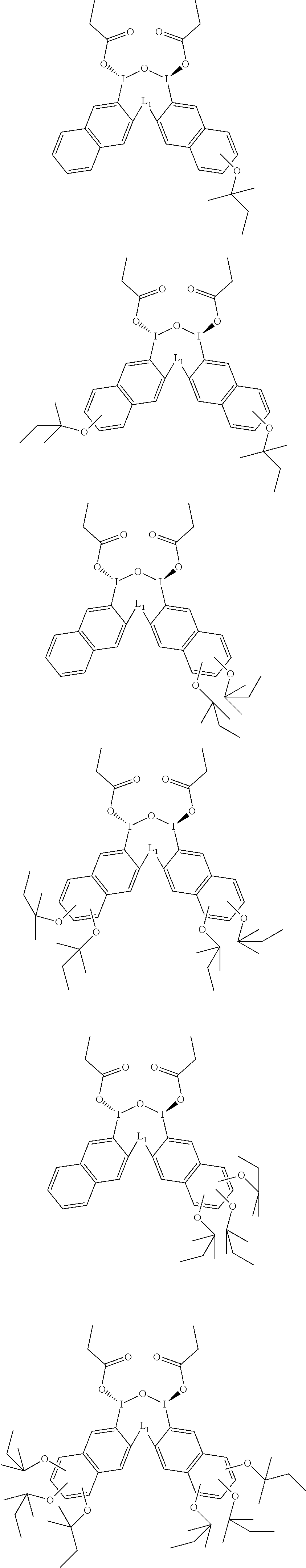

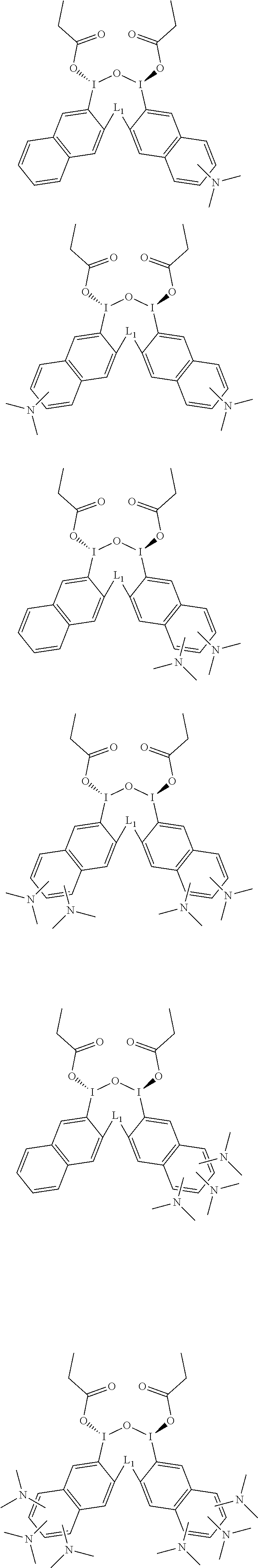

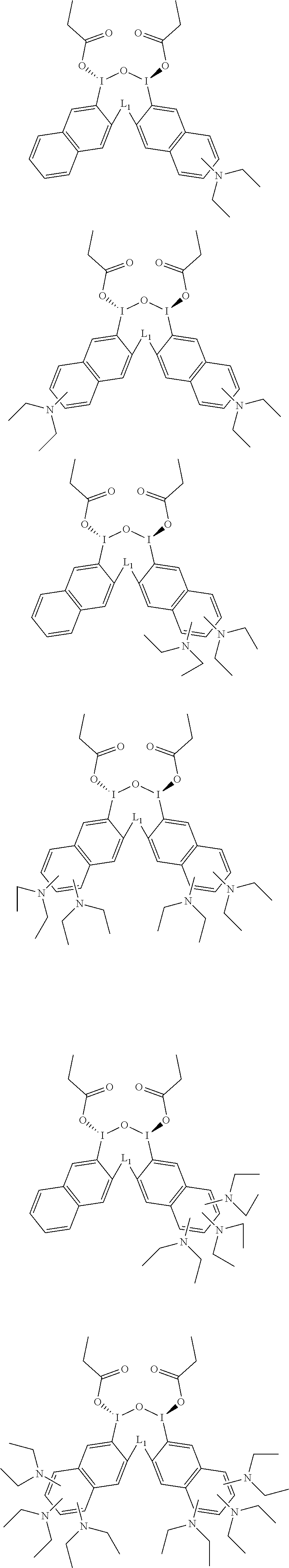

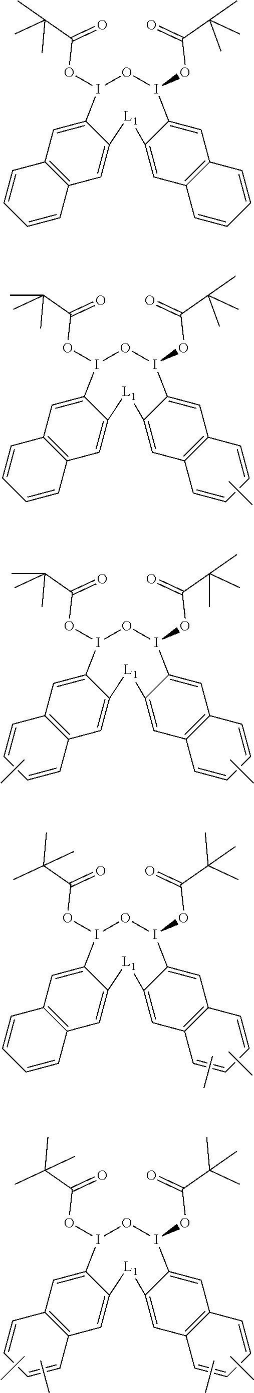

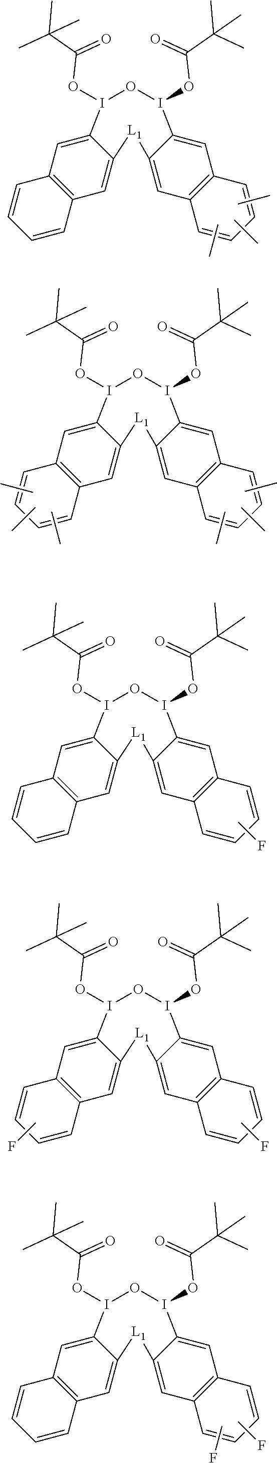

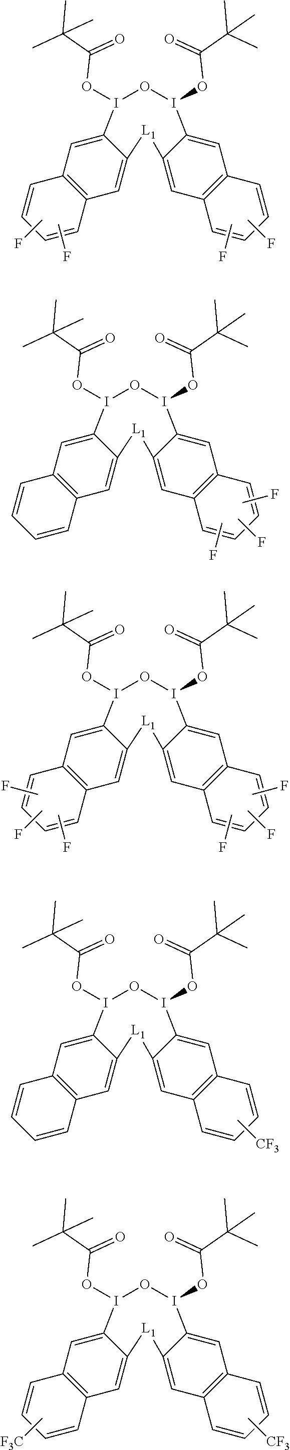

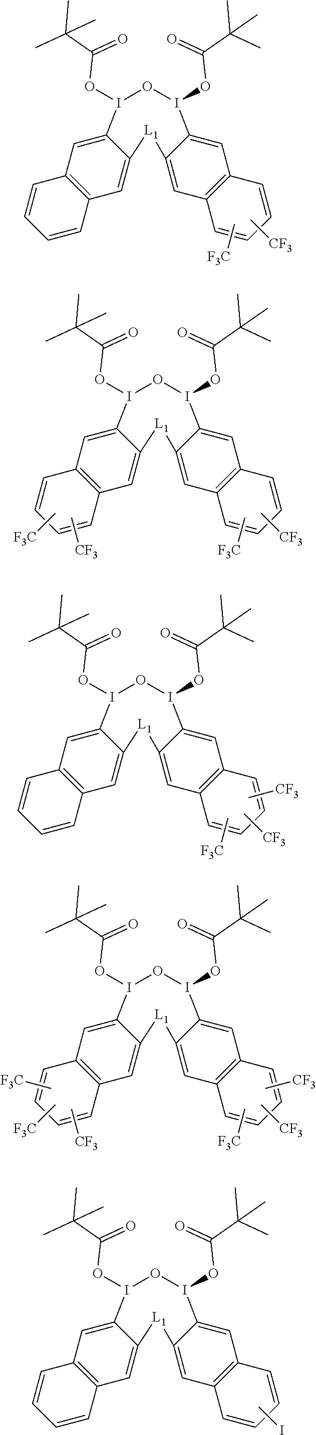

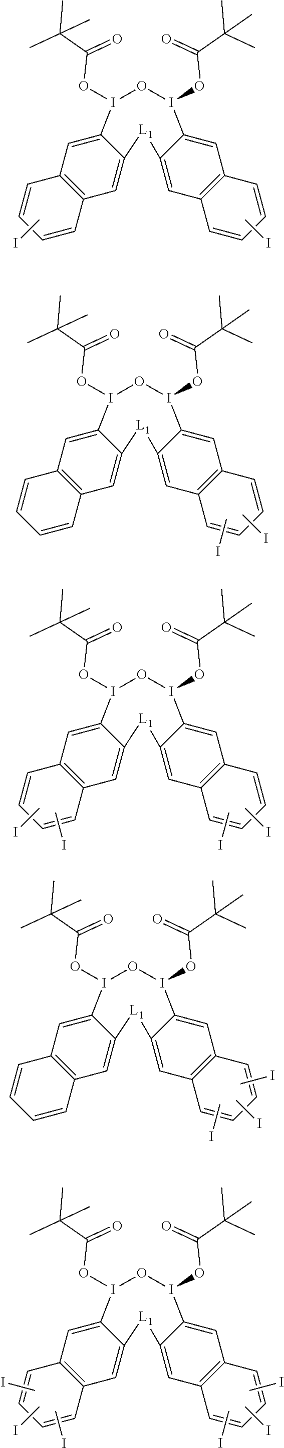

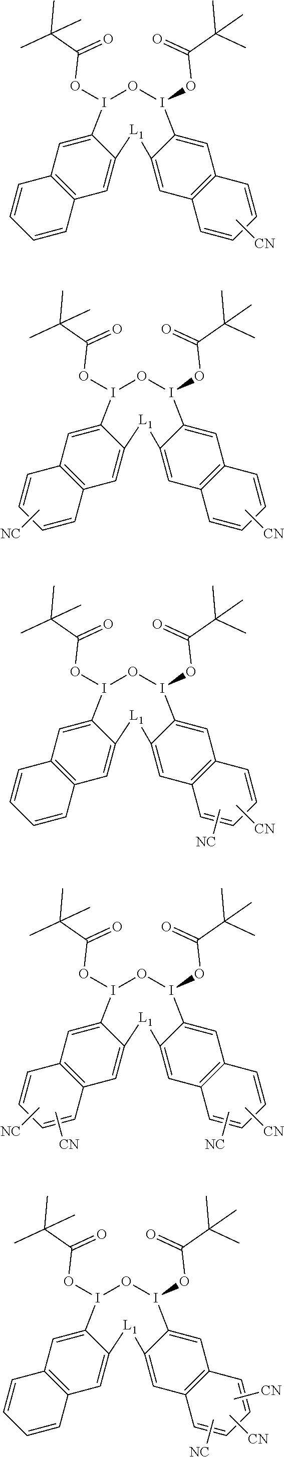

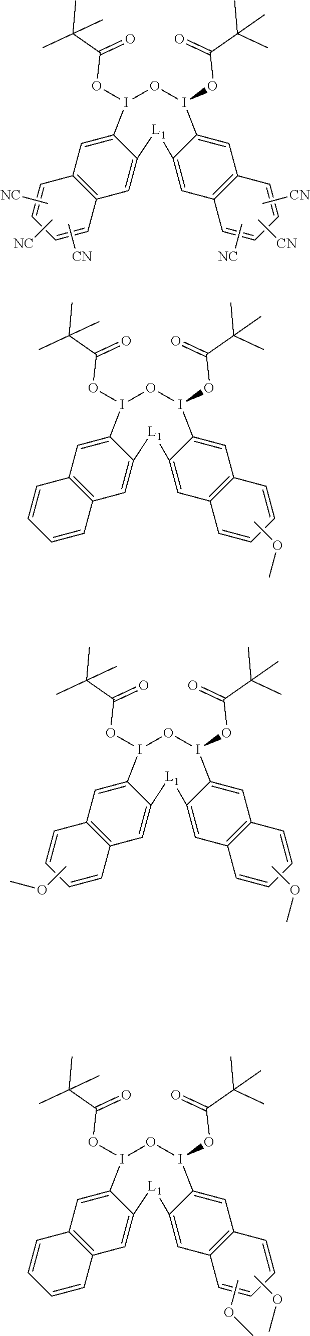

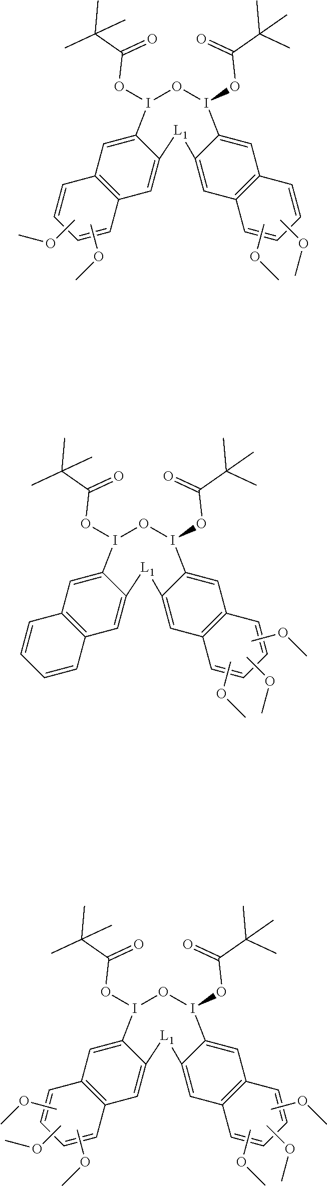

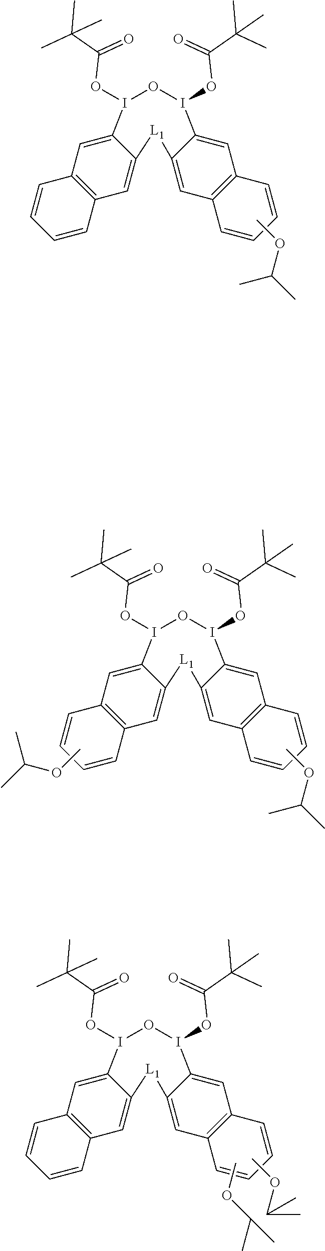

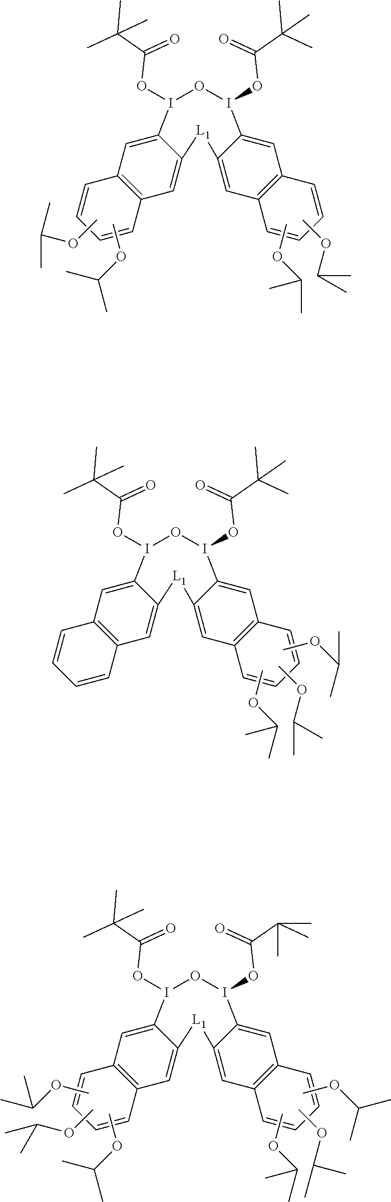

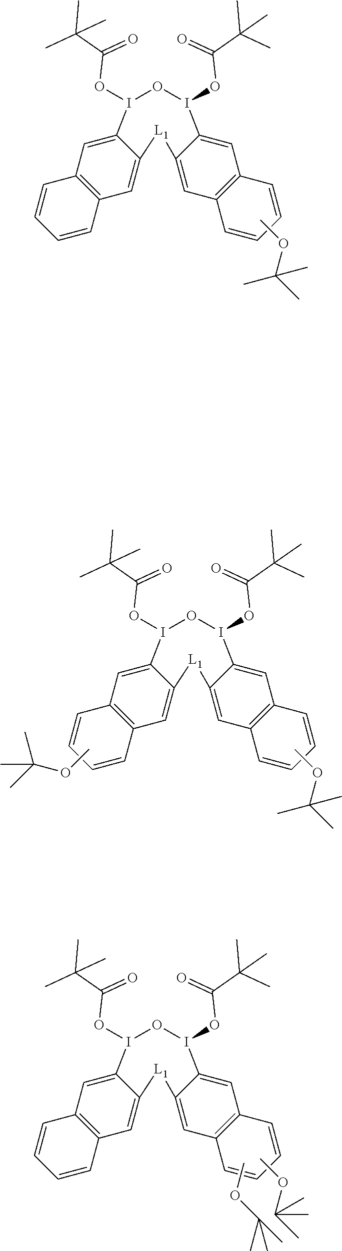

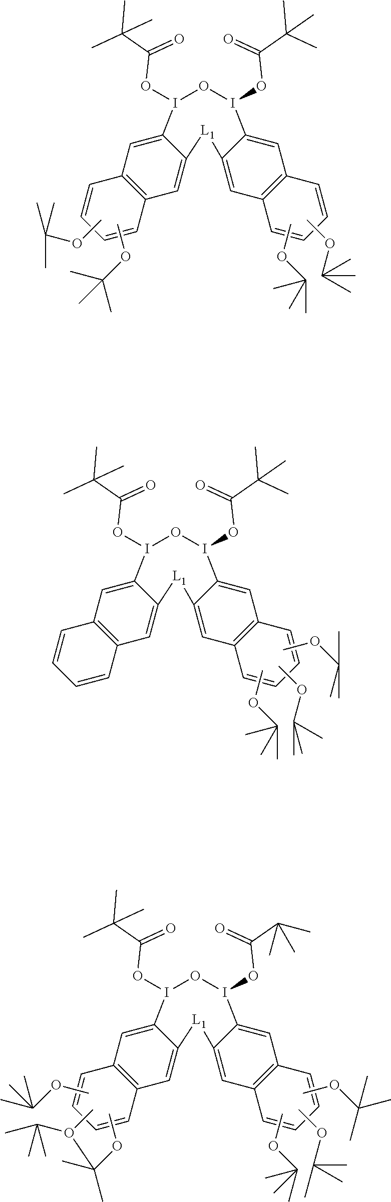

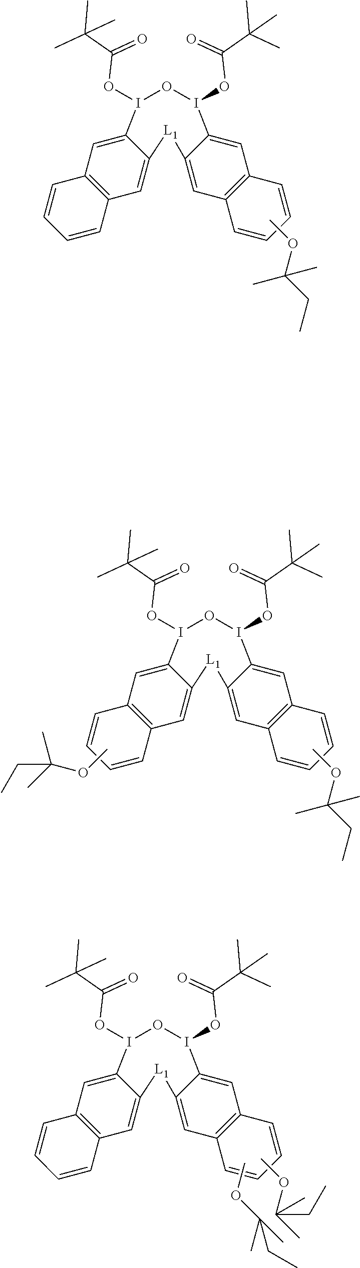

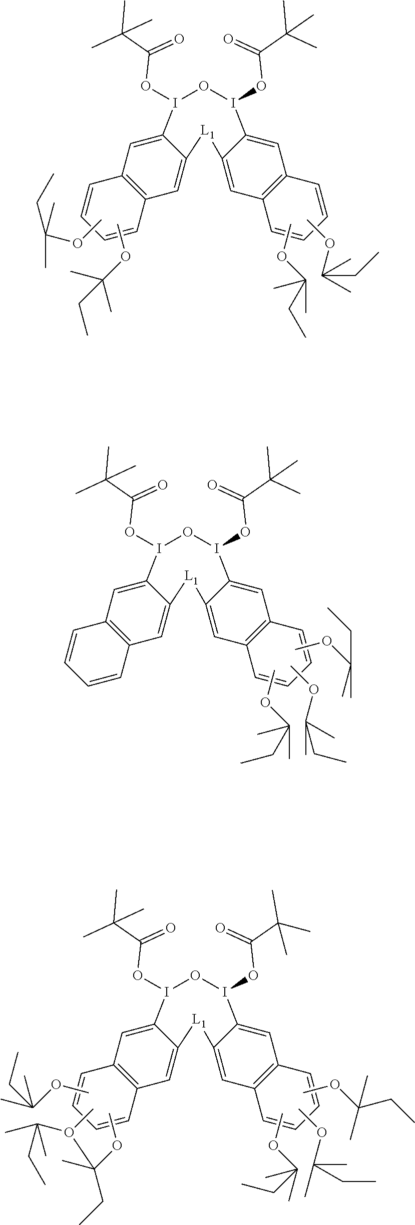

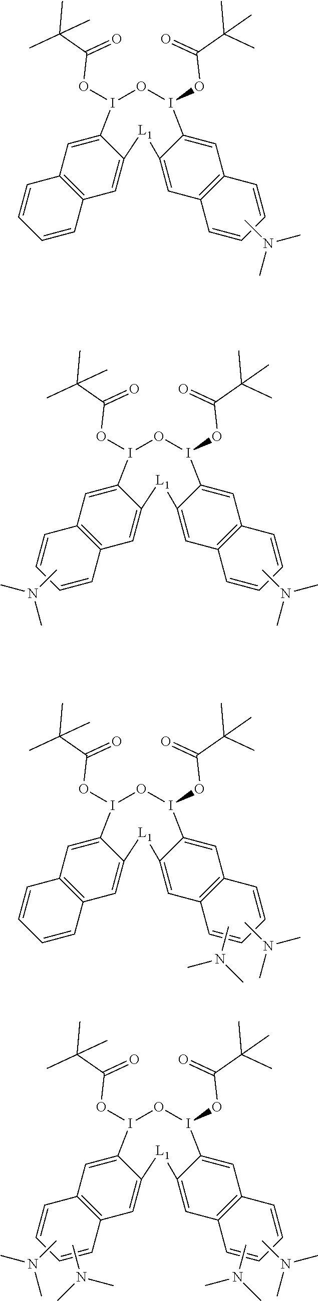

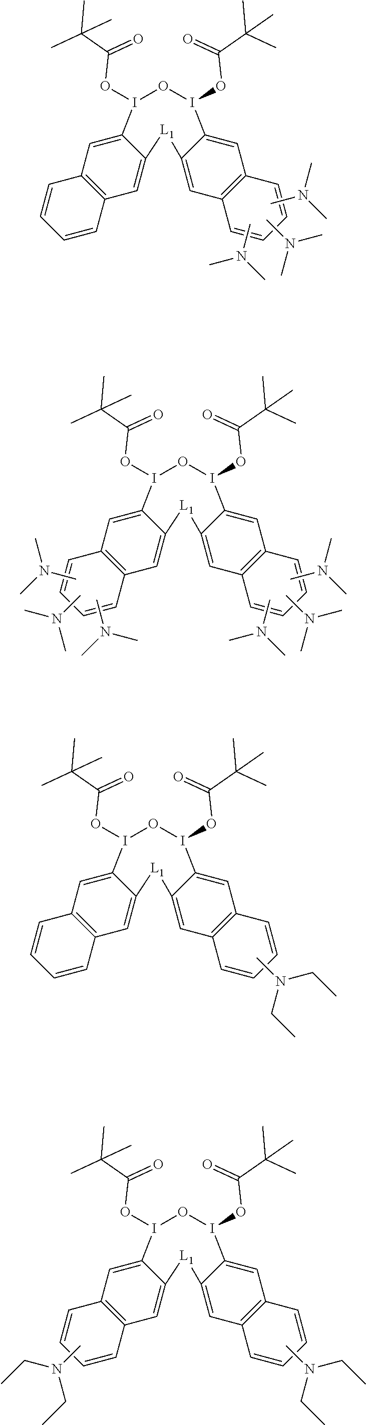

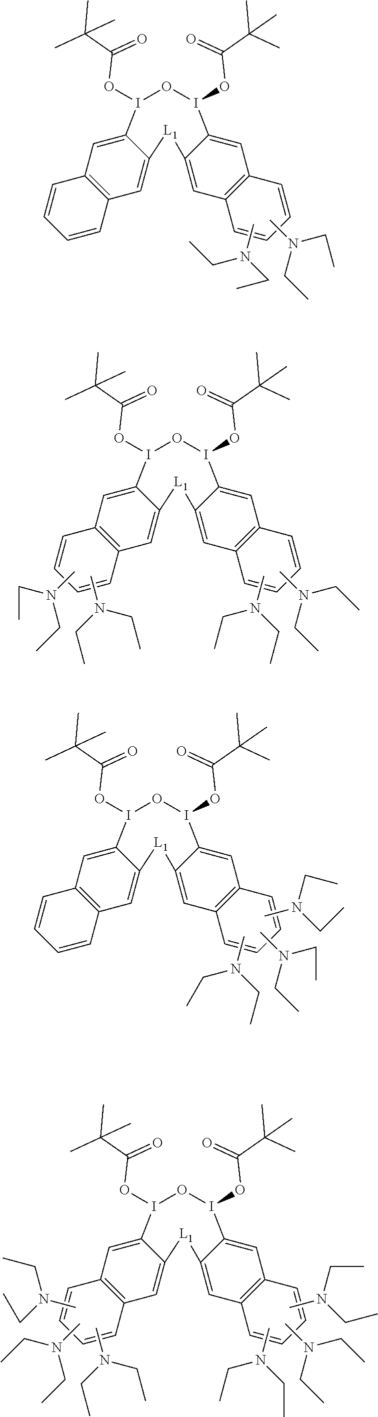

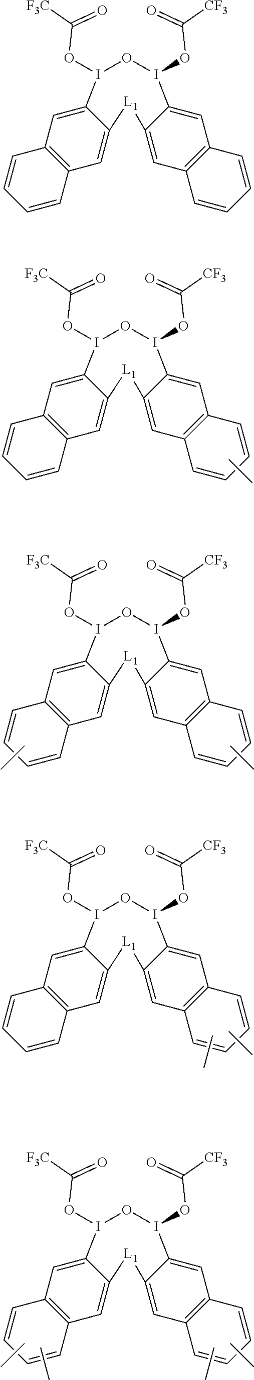

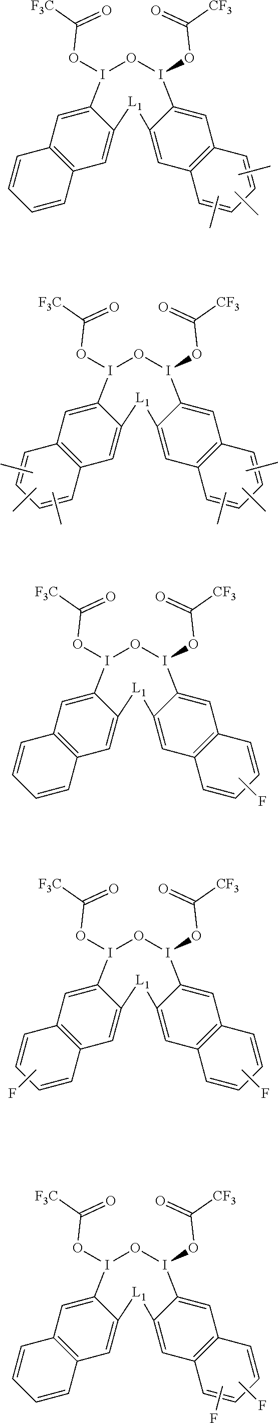

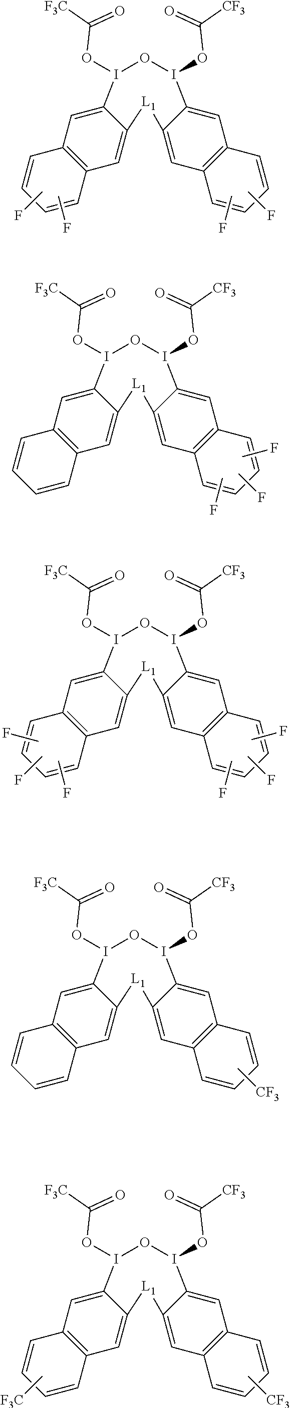

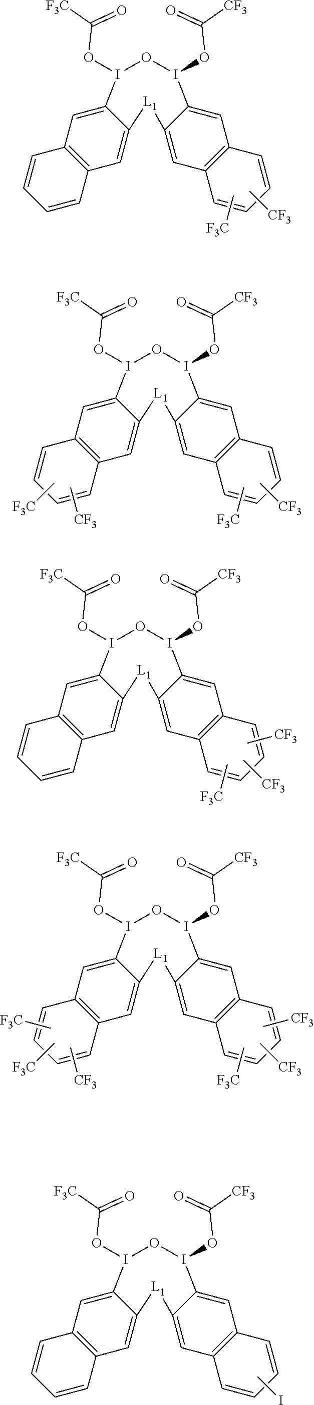

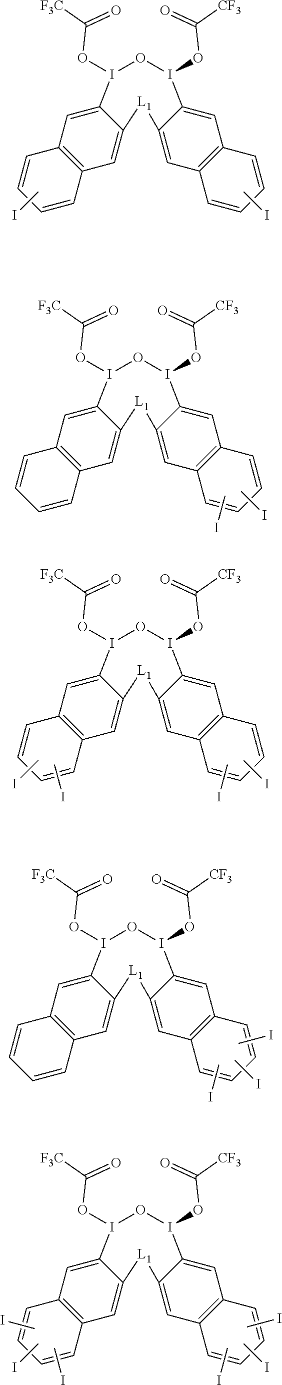

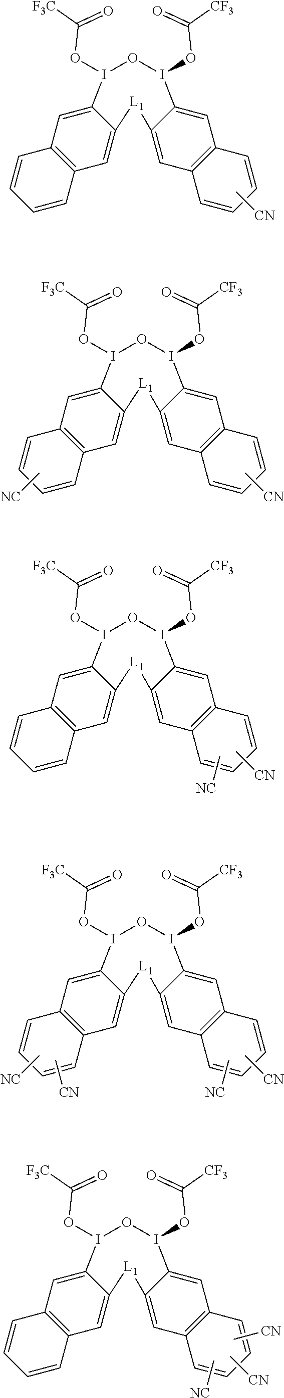

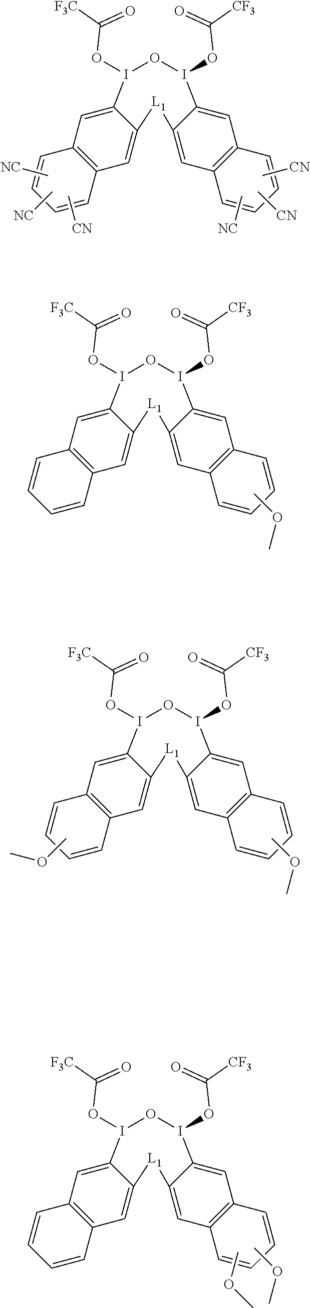

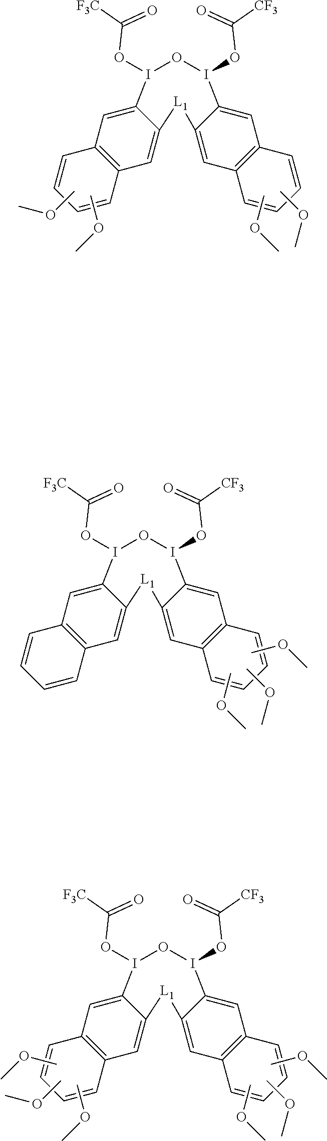

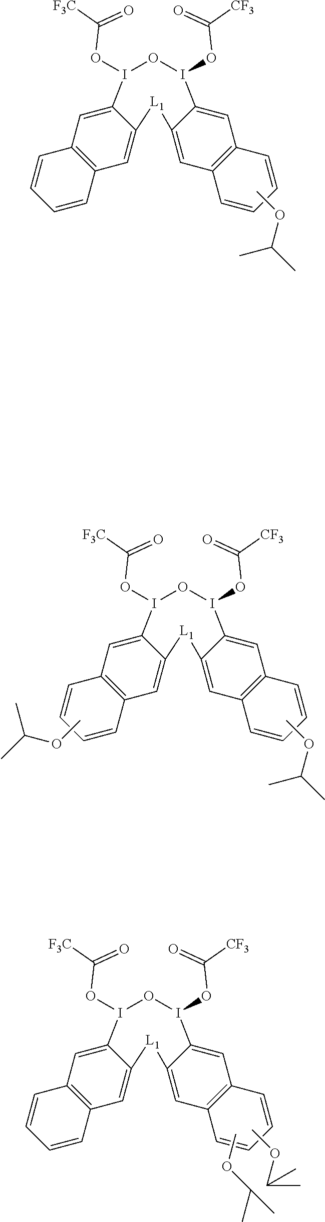

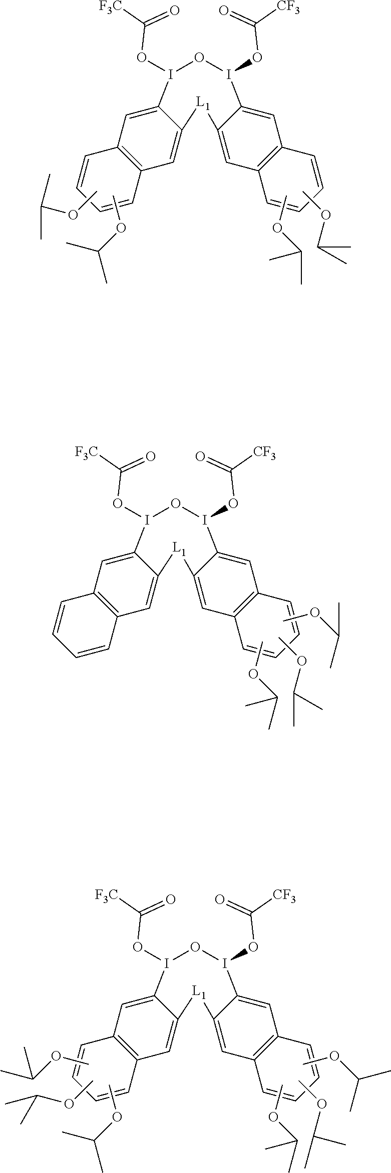

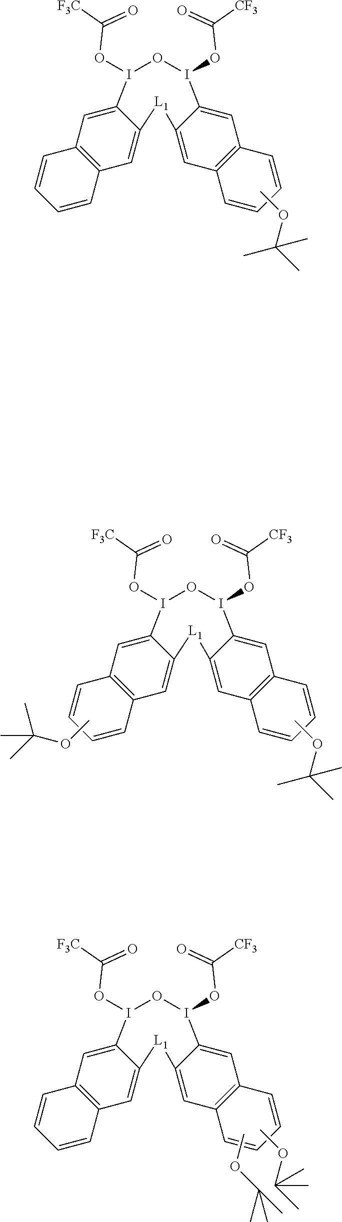

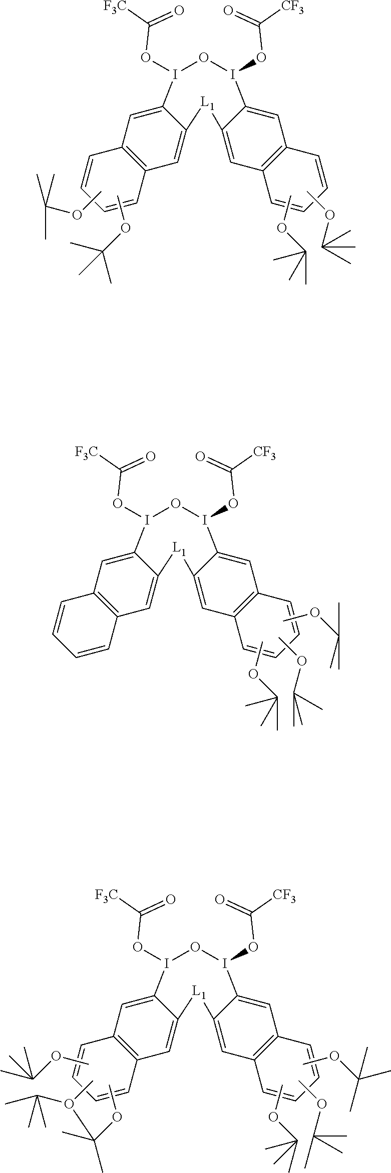

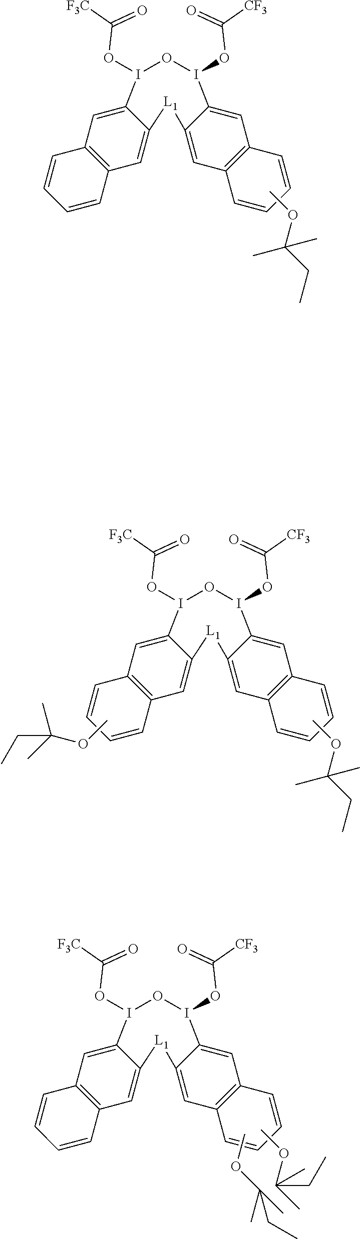

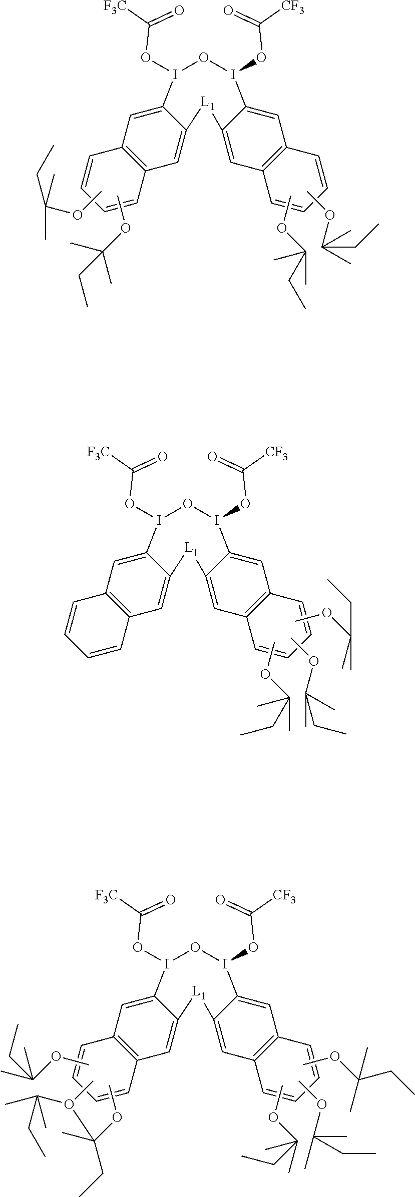

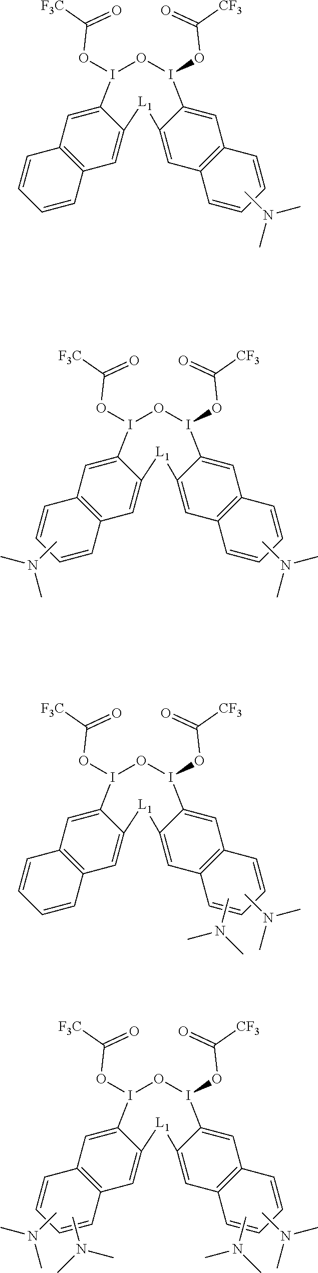

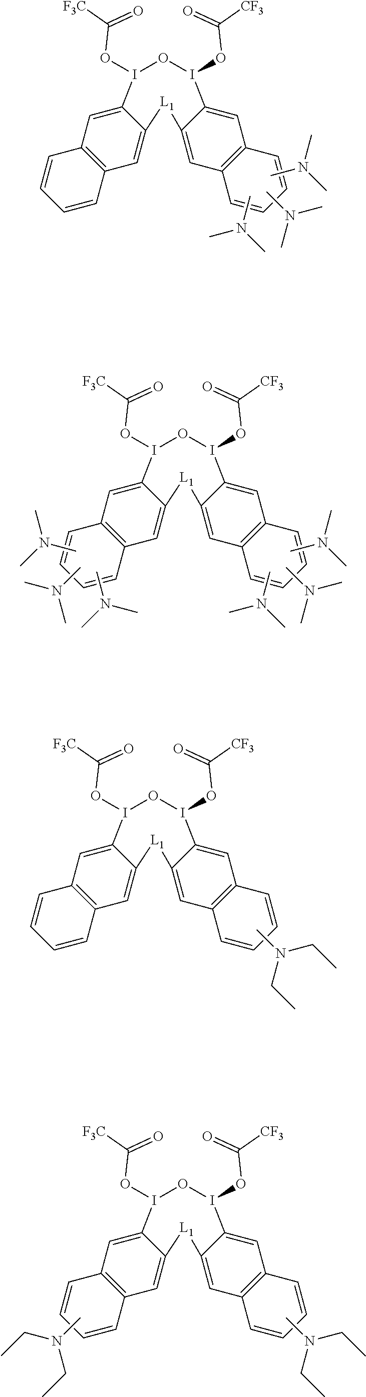

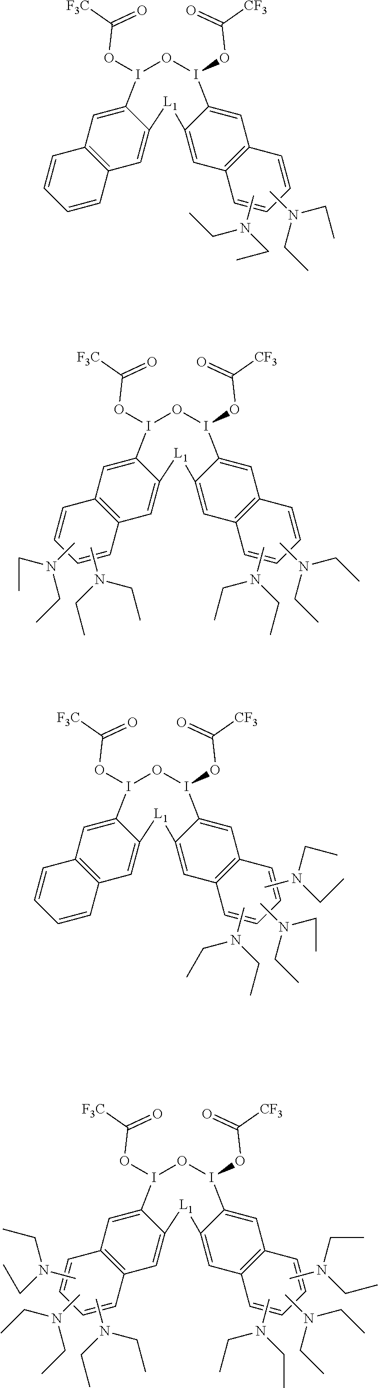

Specific examples of the hypervalent iodine compound represented by the formula (8) include the following, but are not limited thereto.

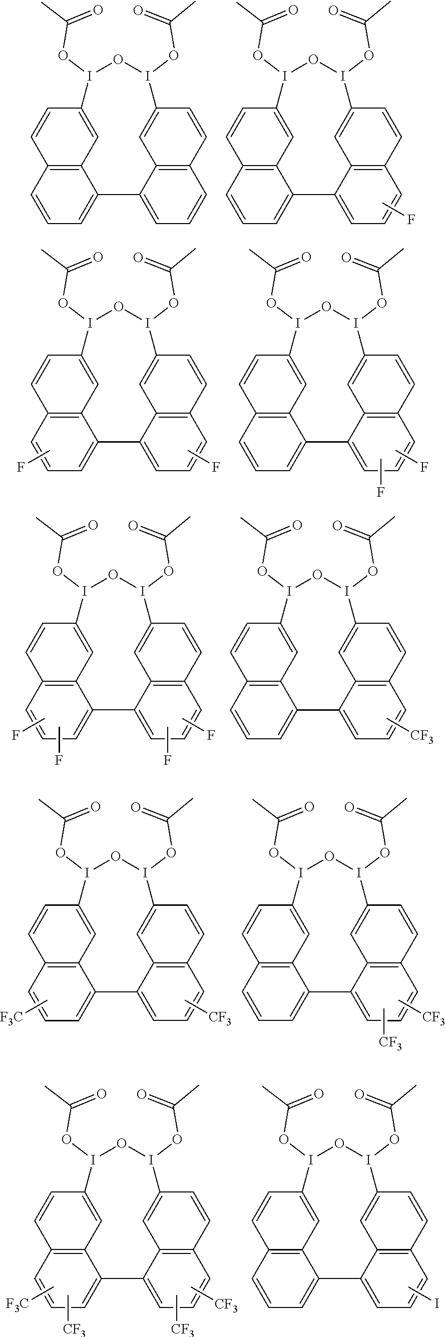

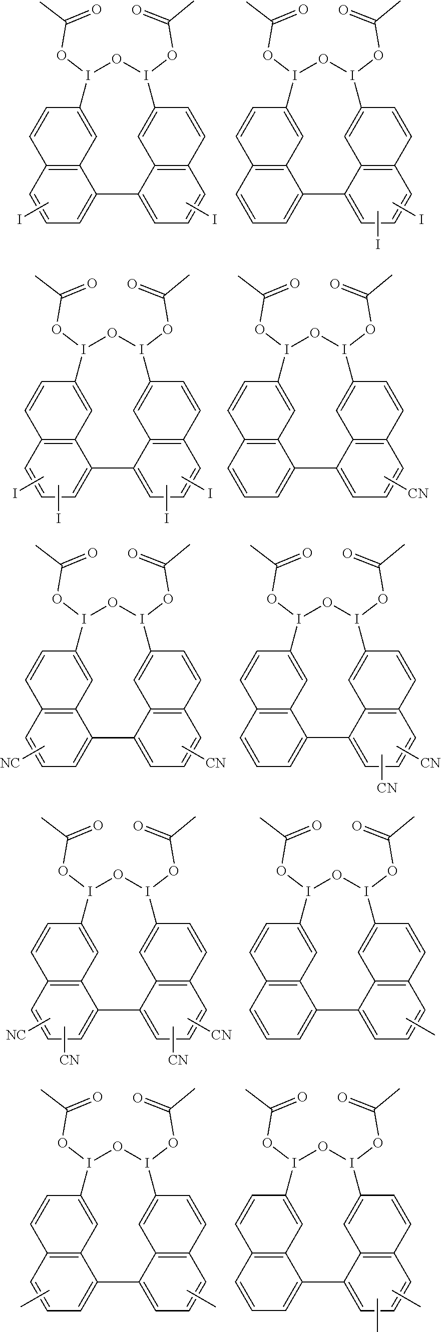

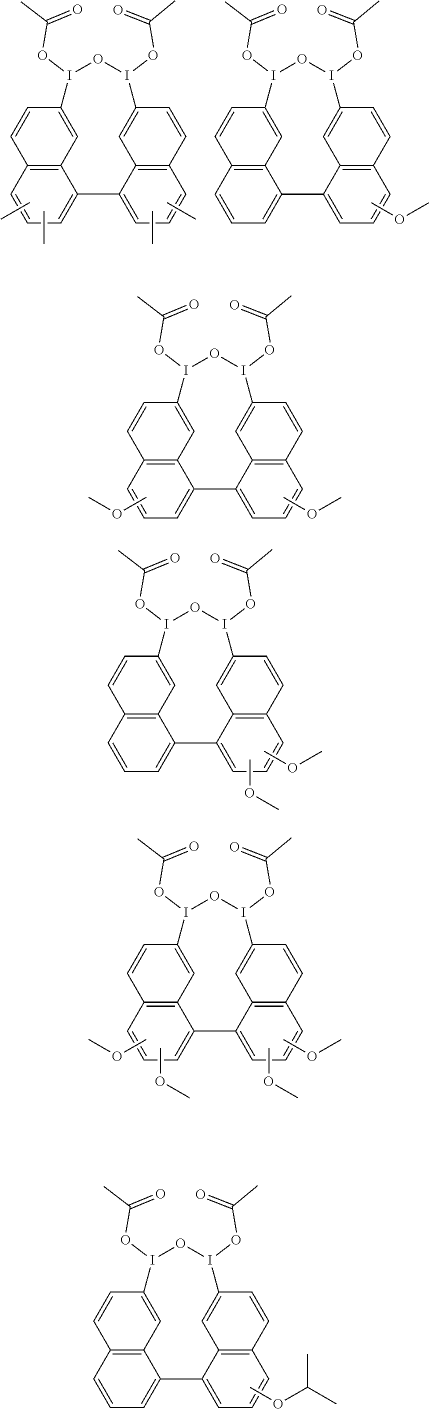

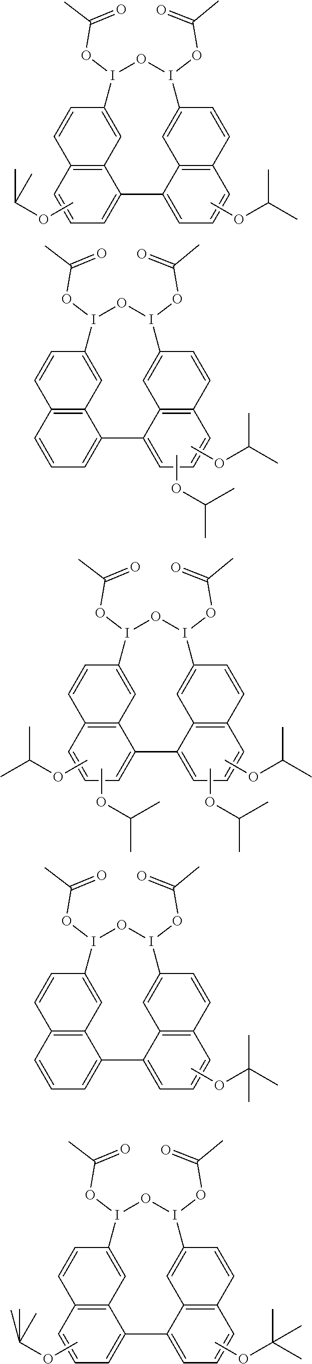

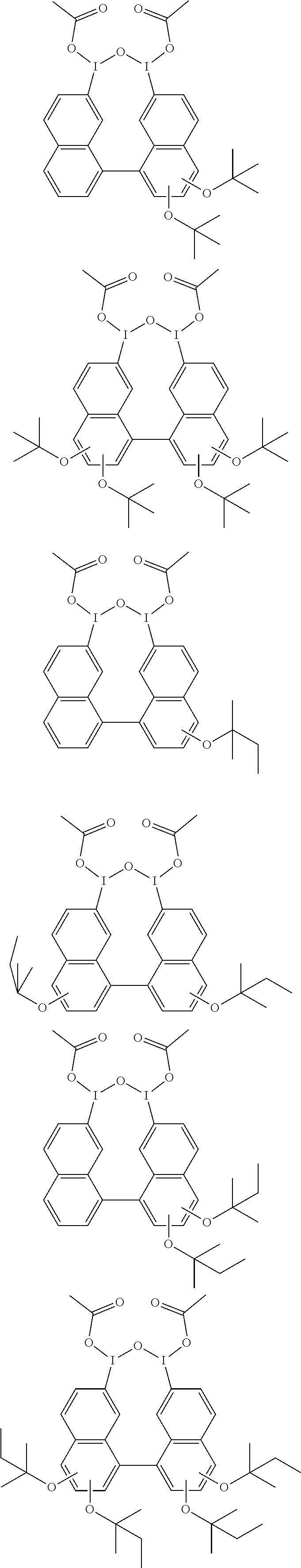

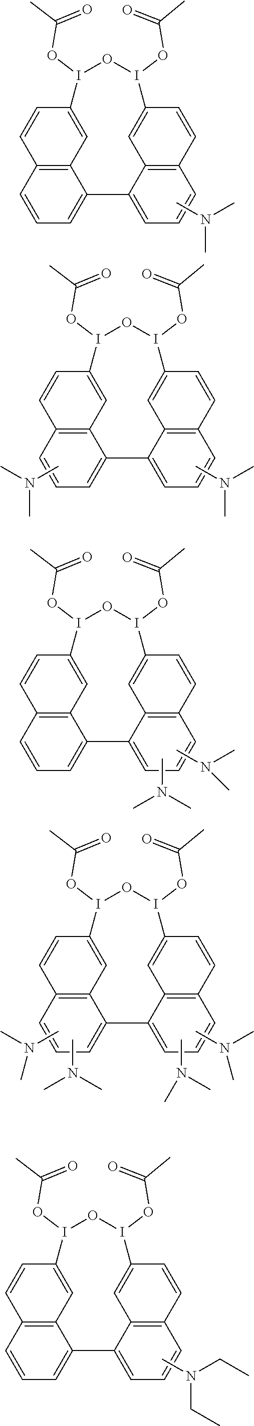

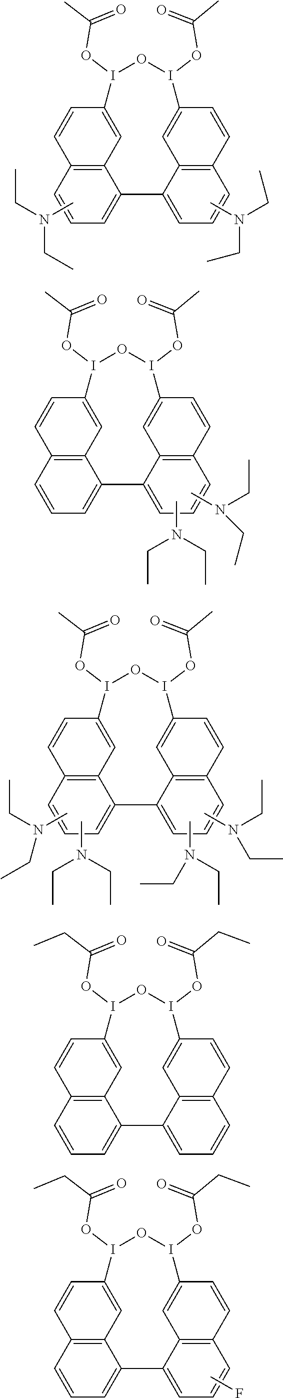

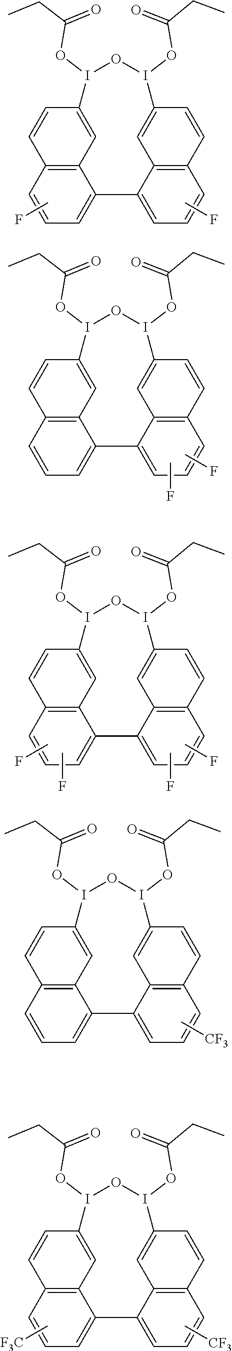

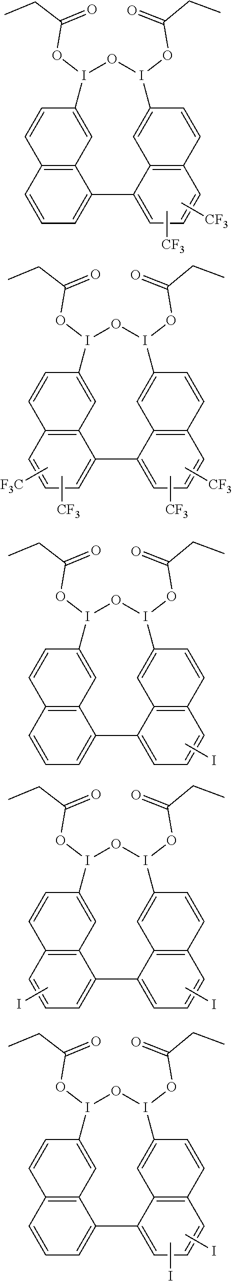

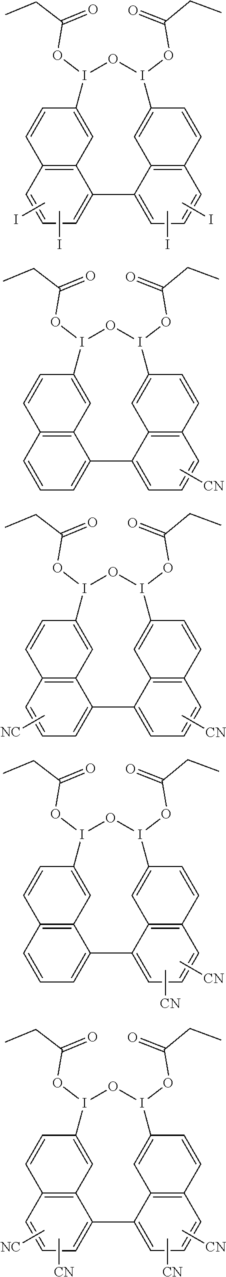

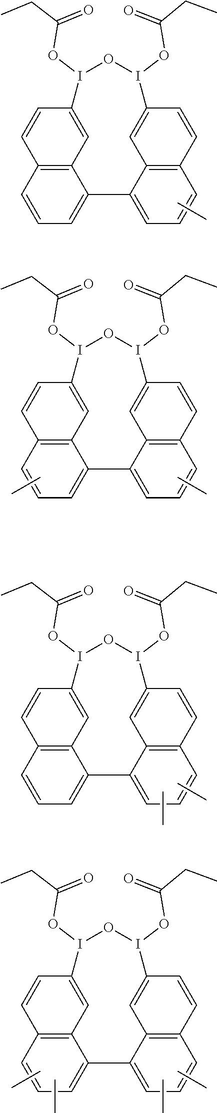

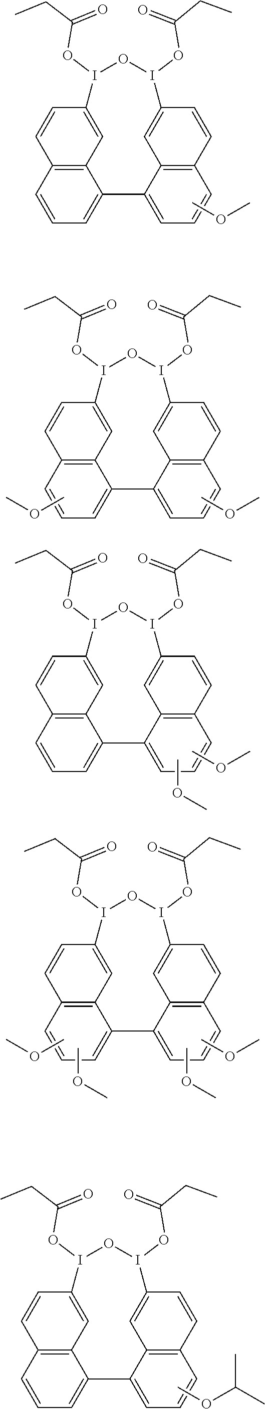

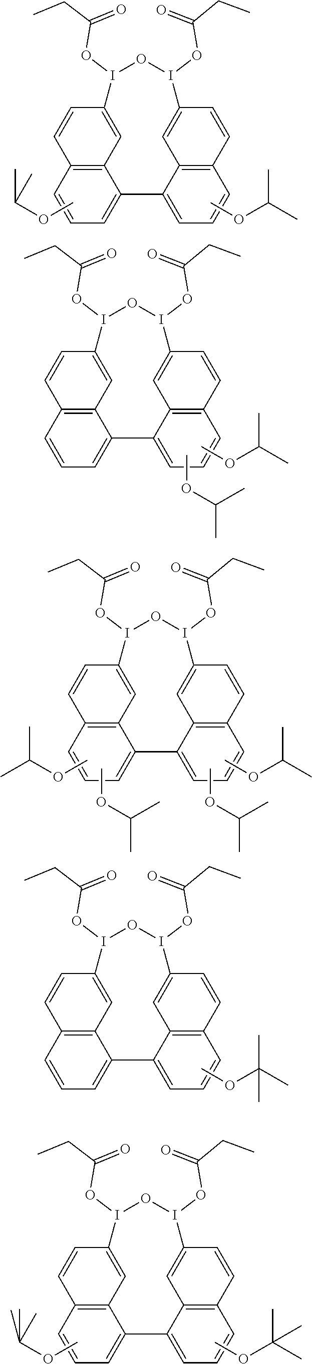

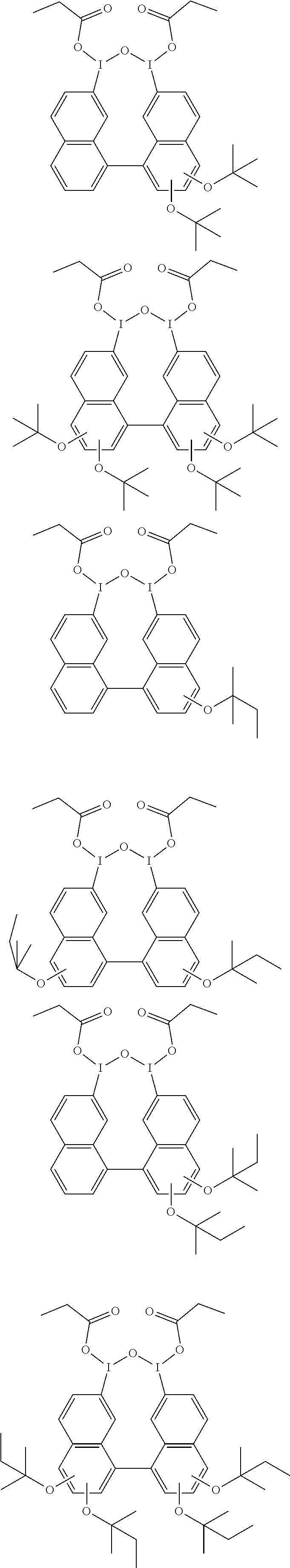

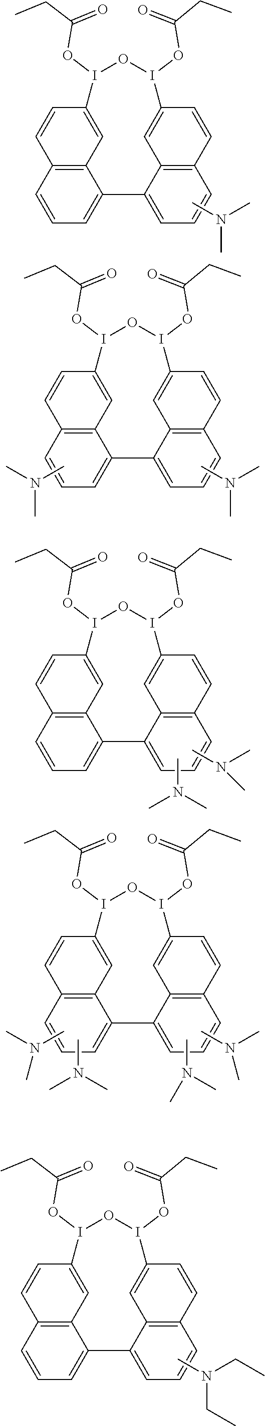

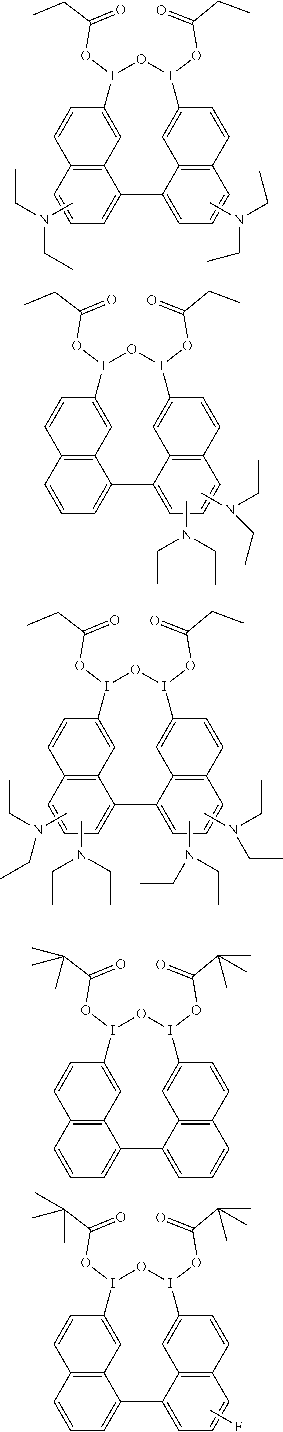

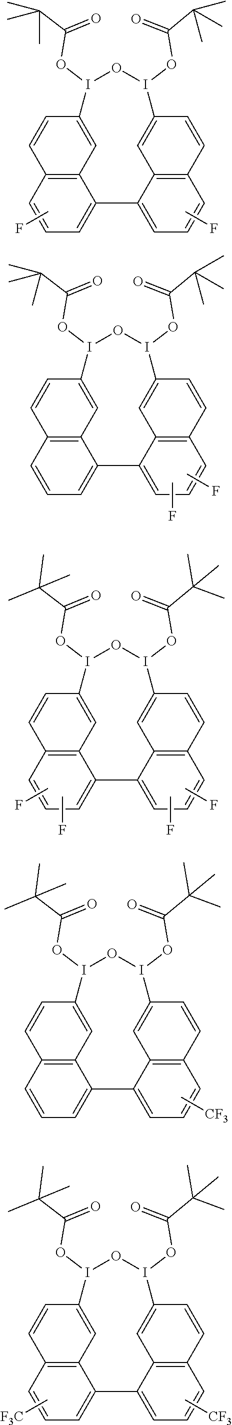

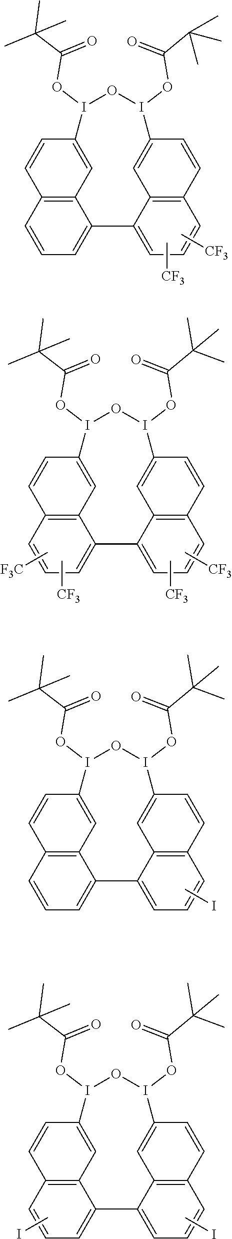

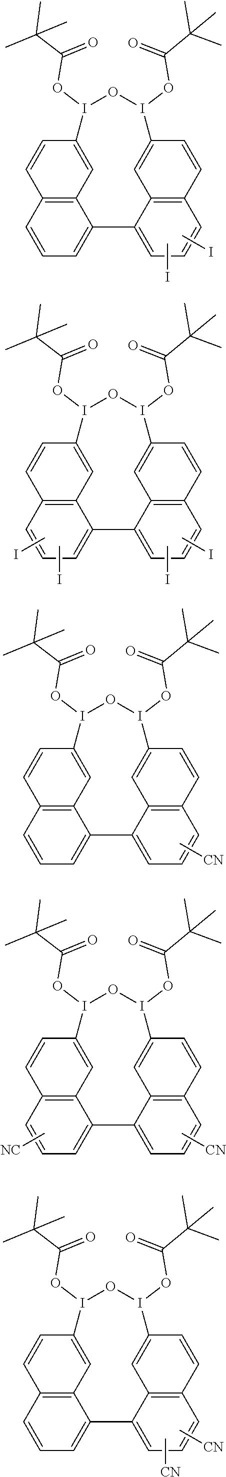

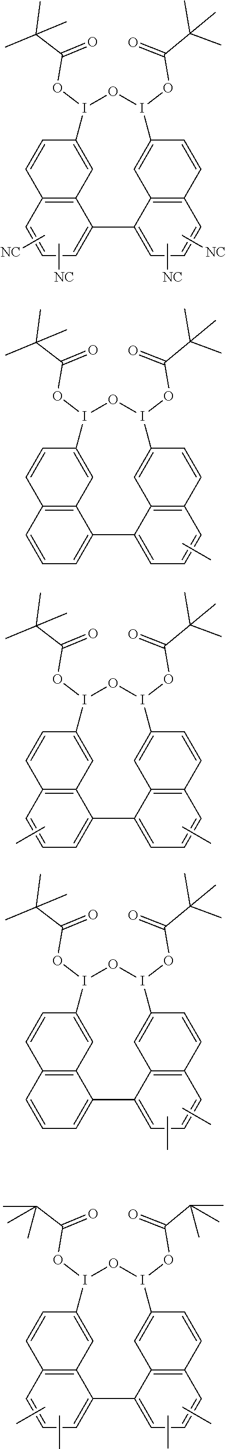

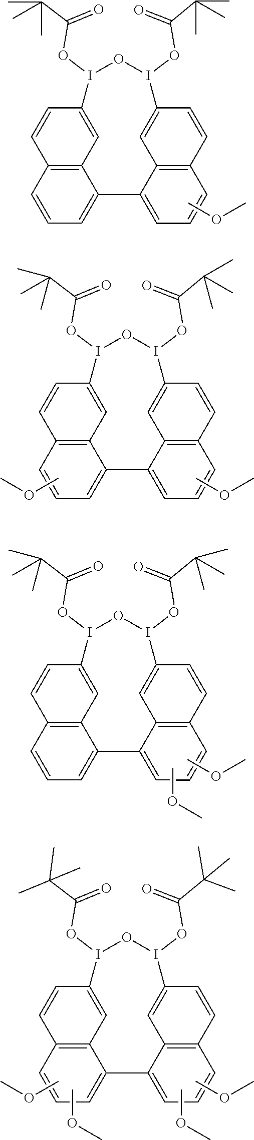

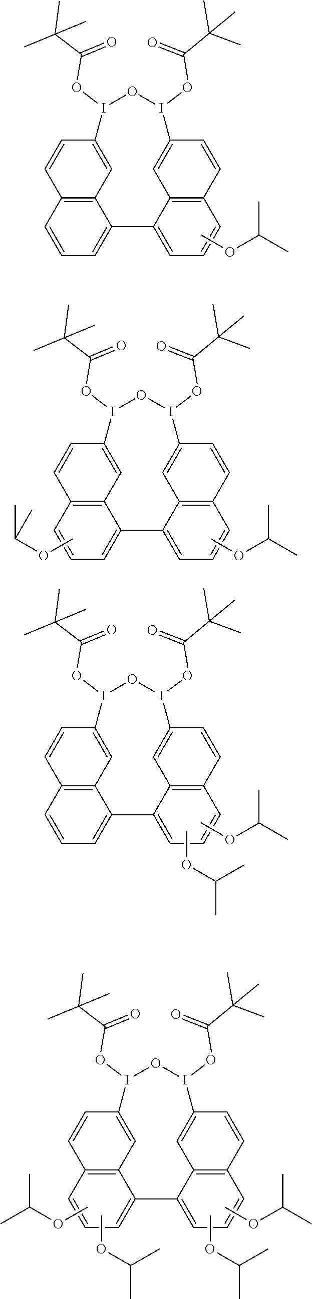

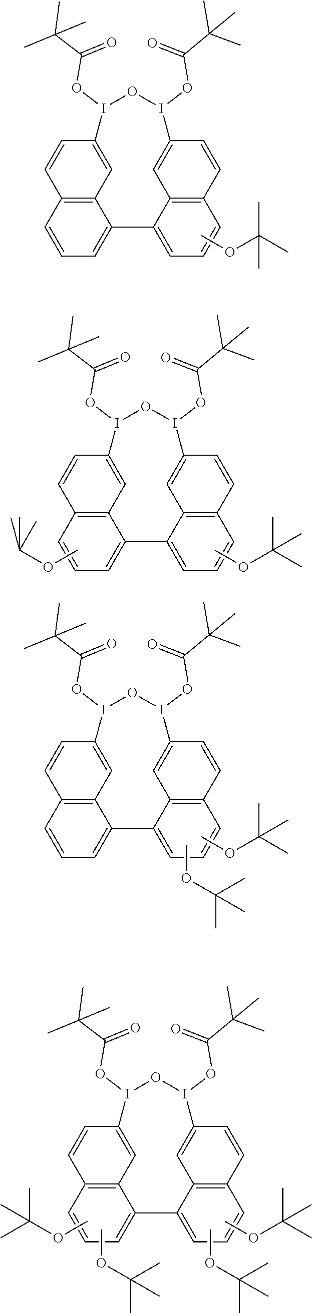

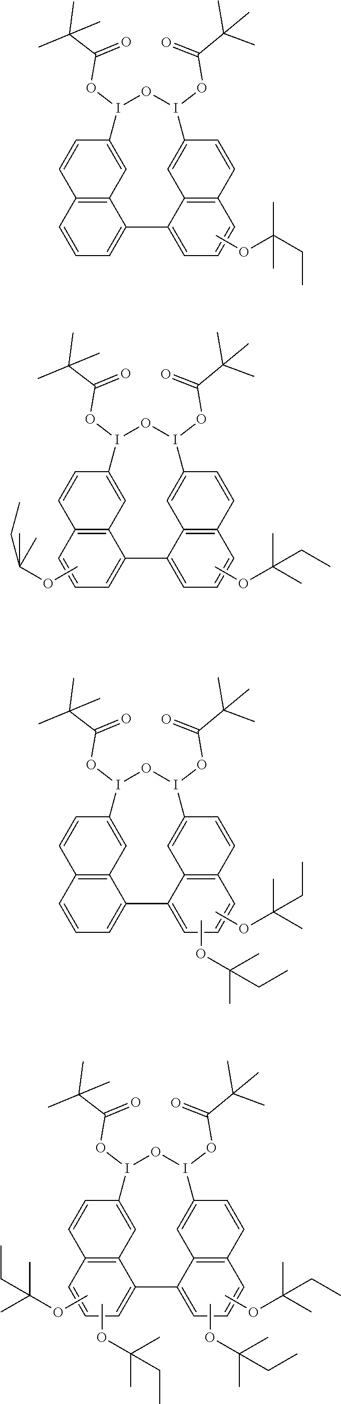

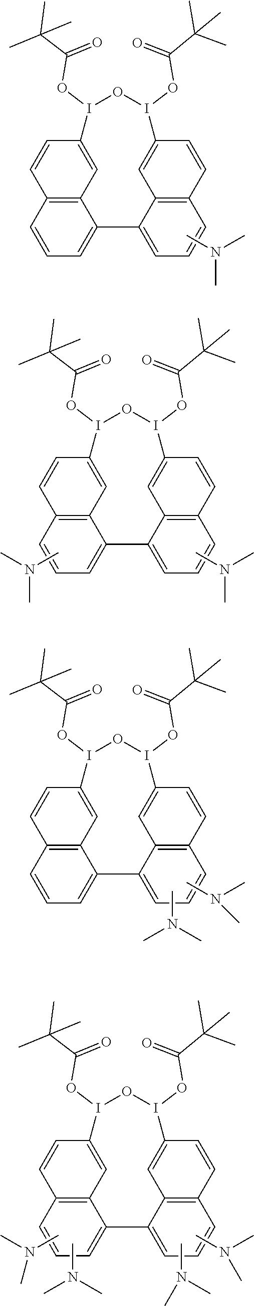

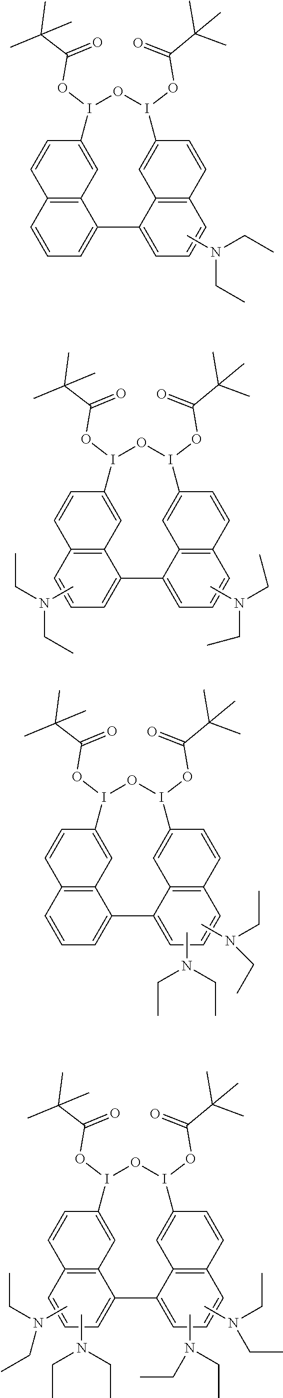

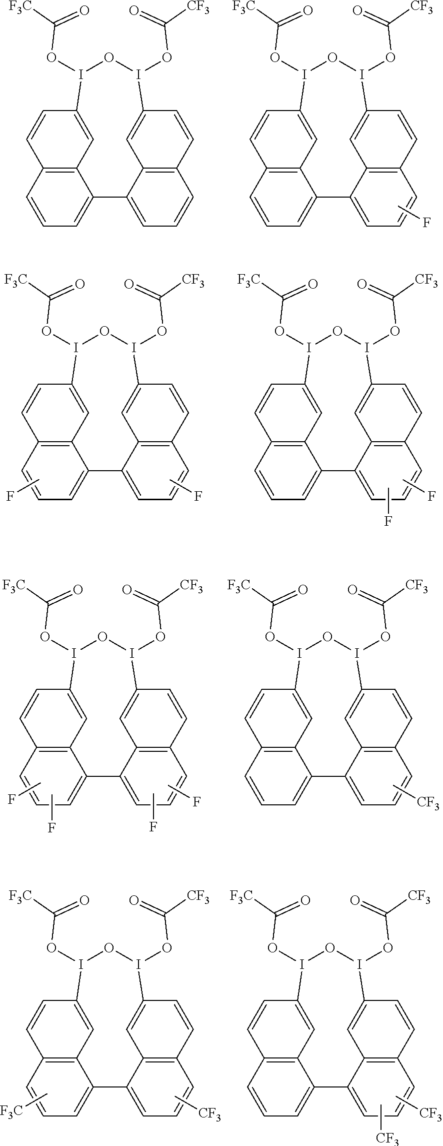

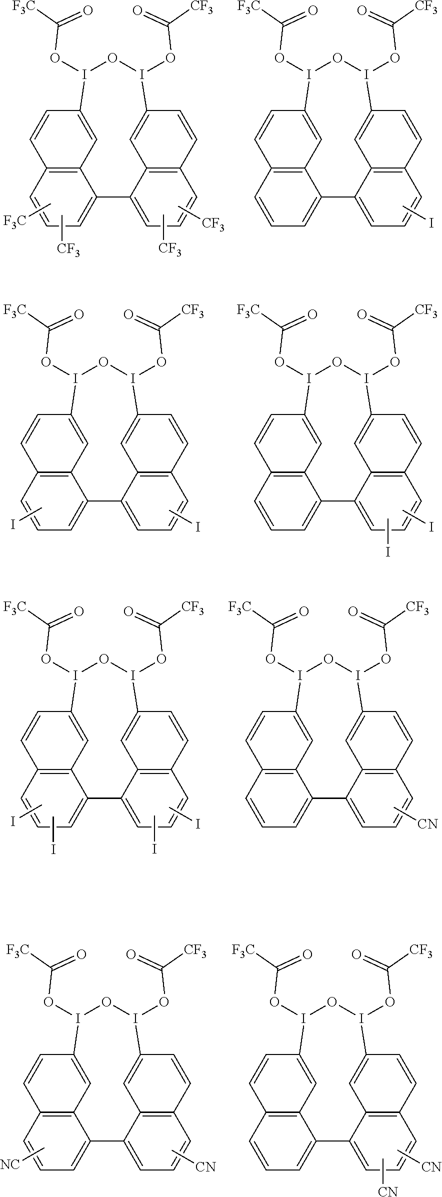

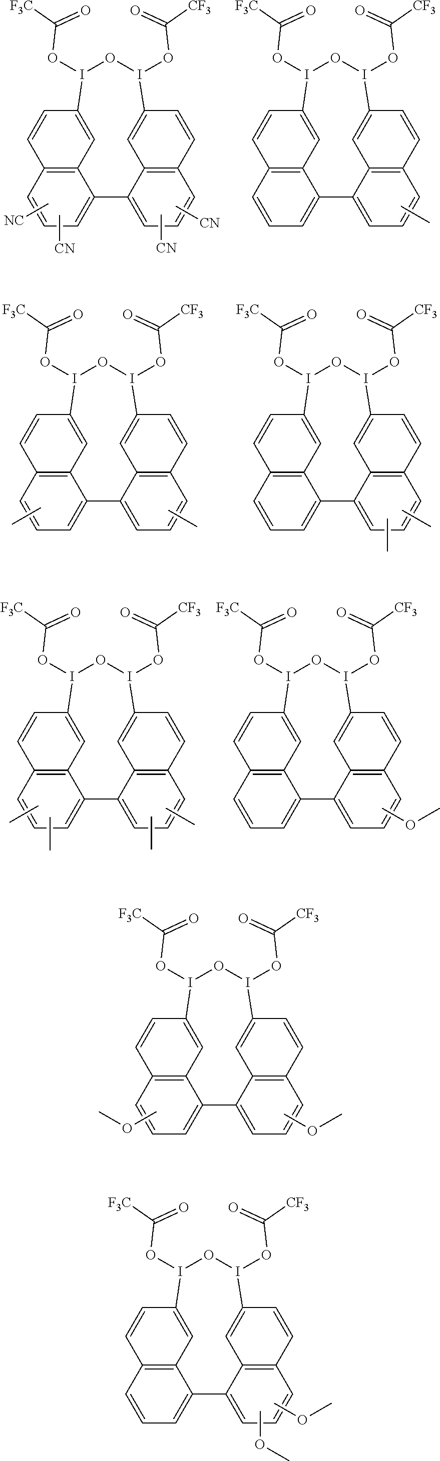

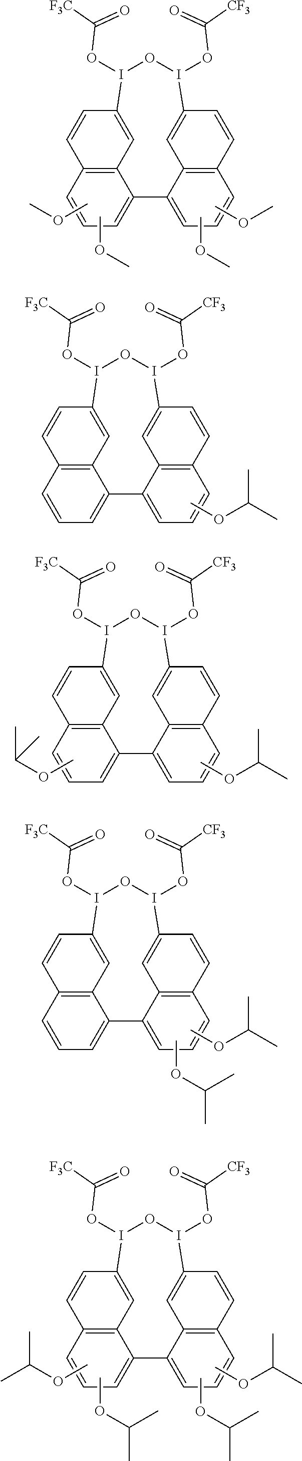

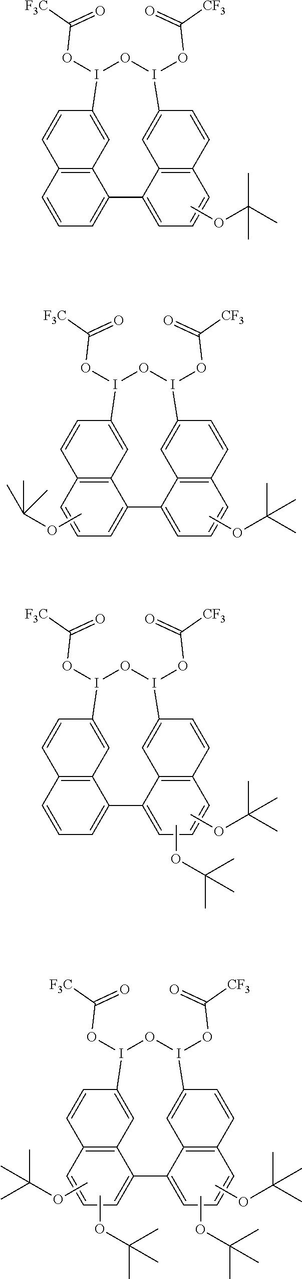

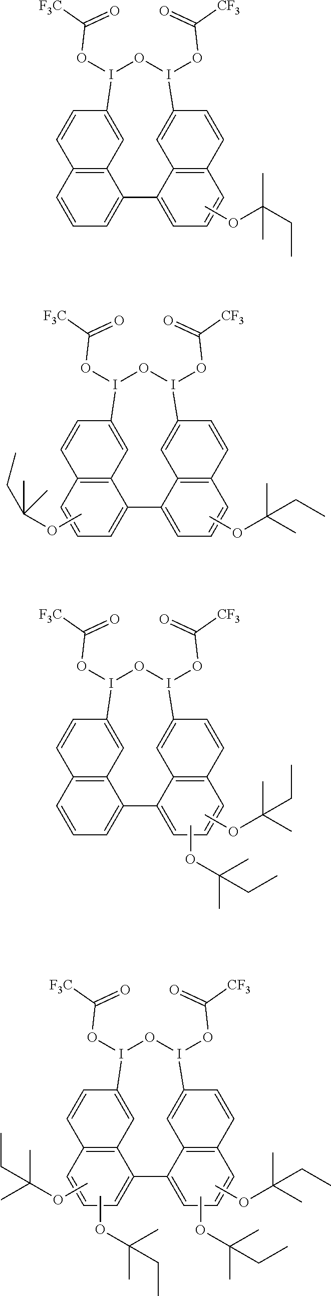

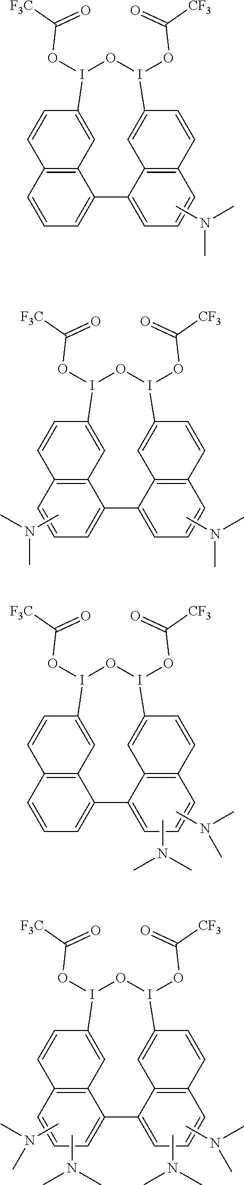

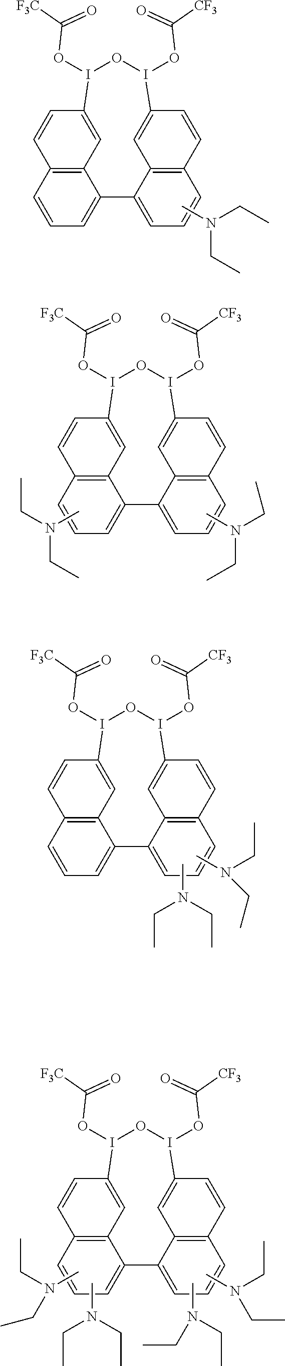

Specific examples of the hypervalent iodine compound represented by the formula (9) include the following, but are not limited thereto.

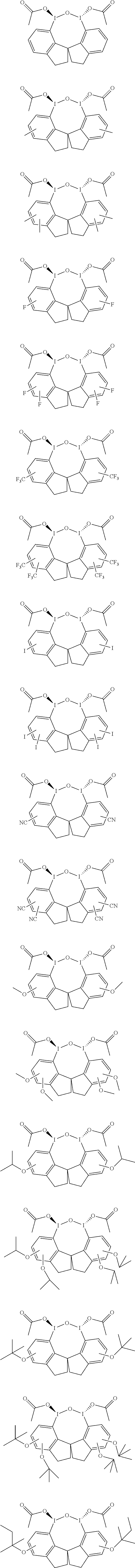

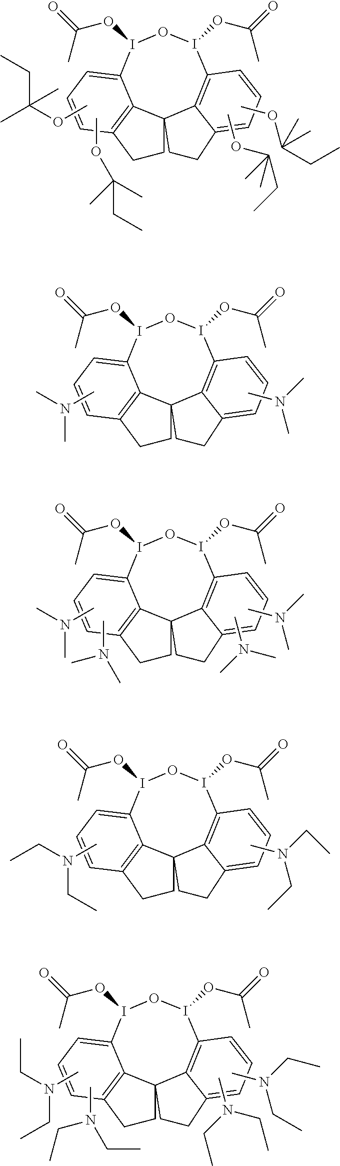

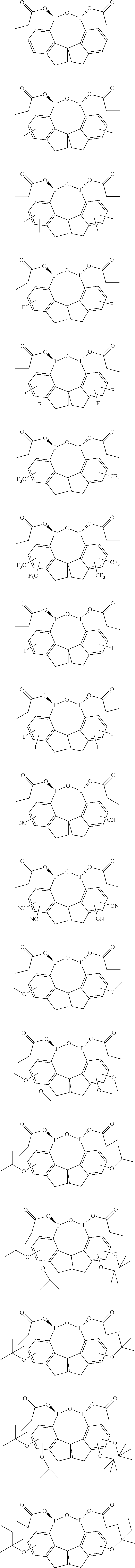

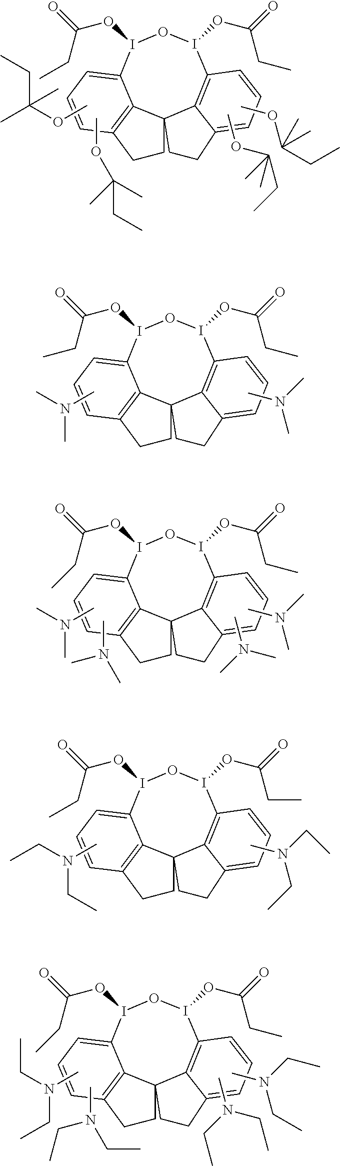

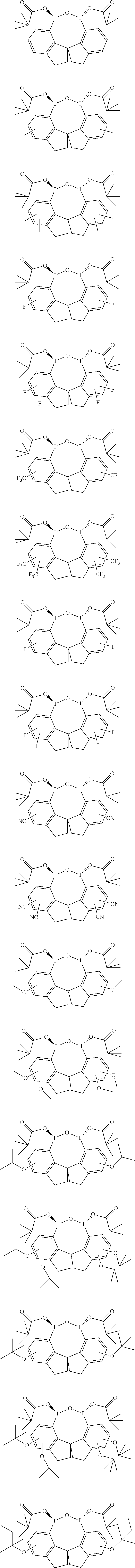

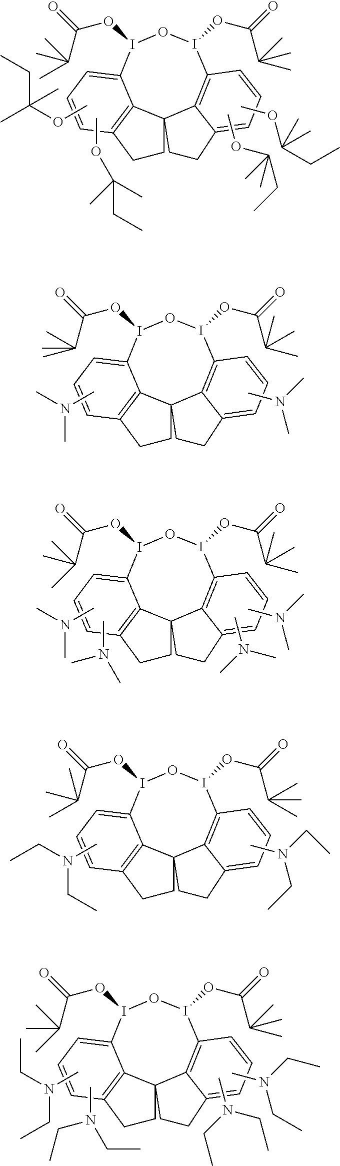

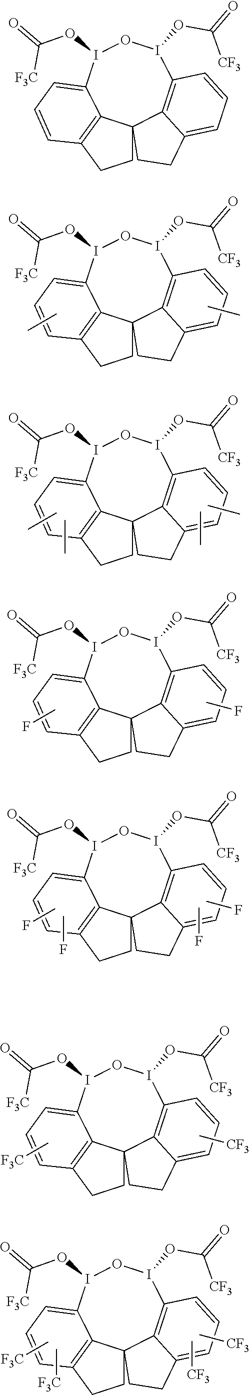

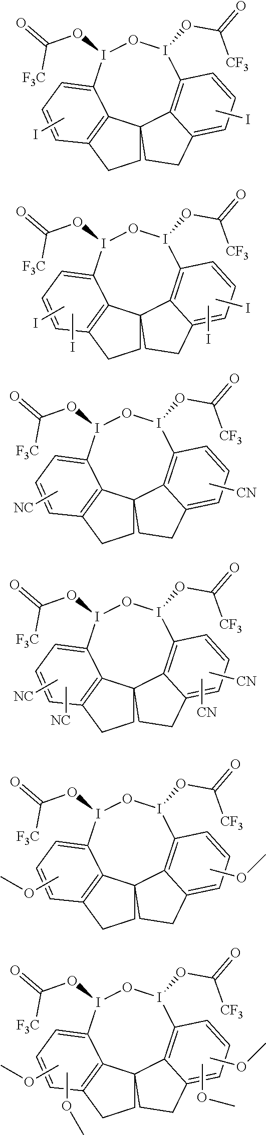

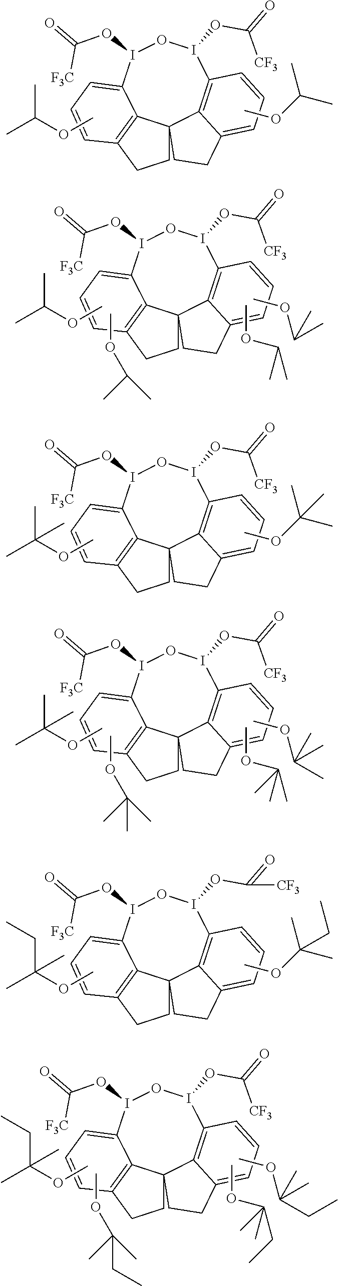

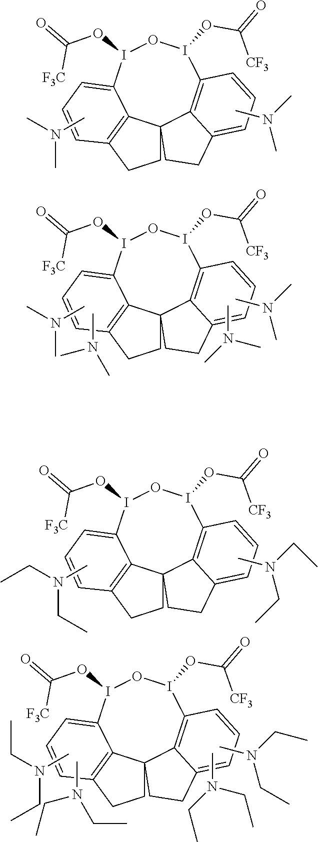

Specific examples of the hypervalent iodine compound represented by the formula (10) include the following, but are not limited thereto.

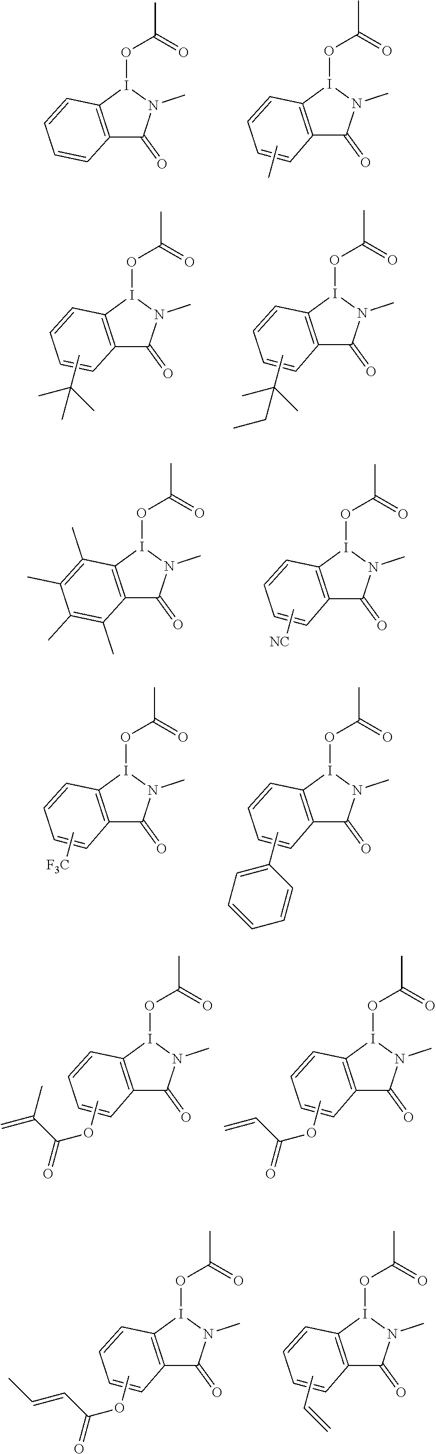

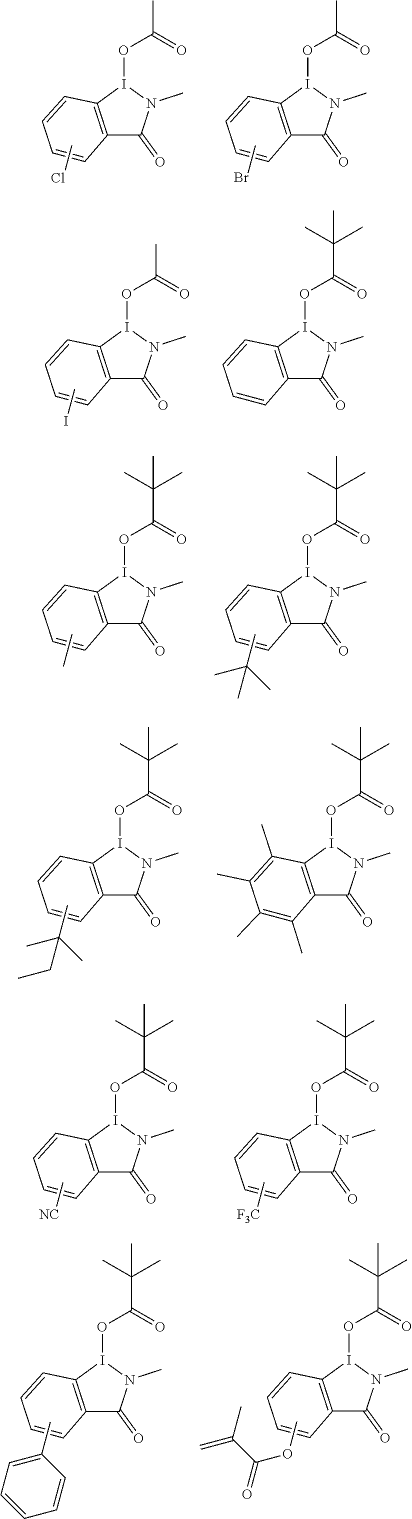

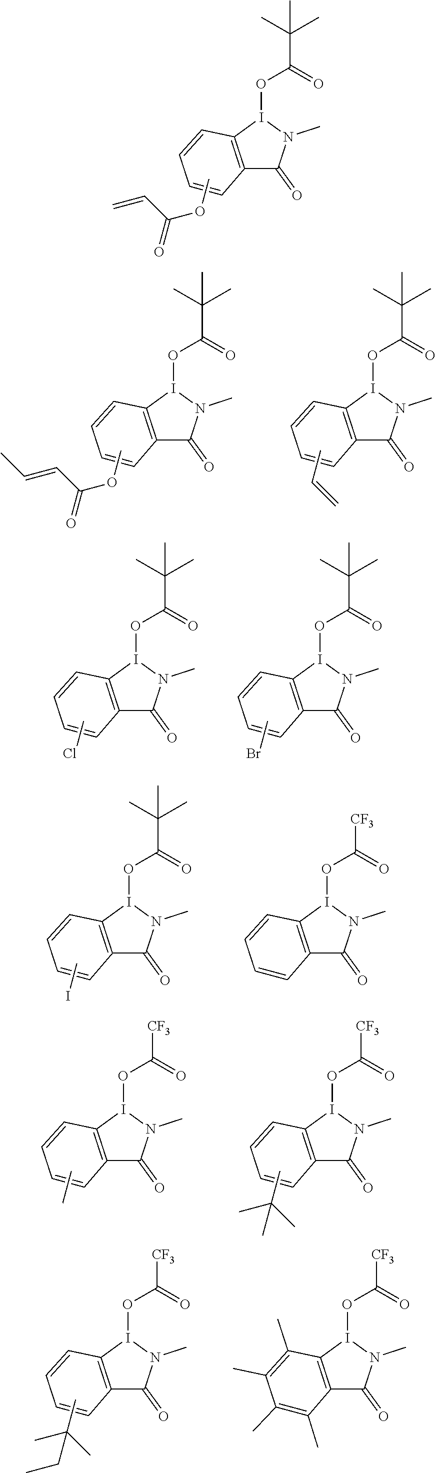

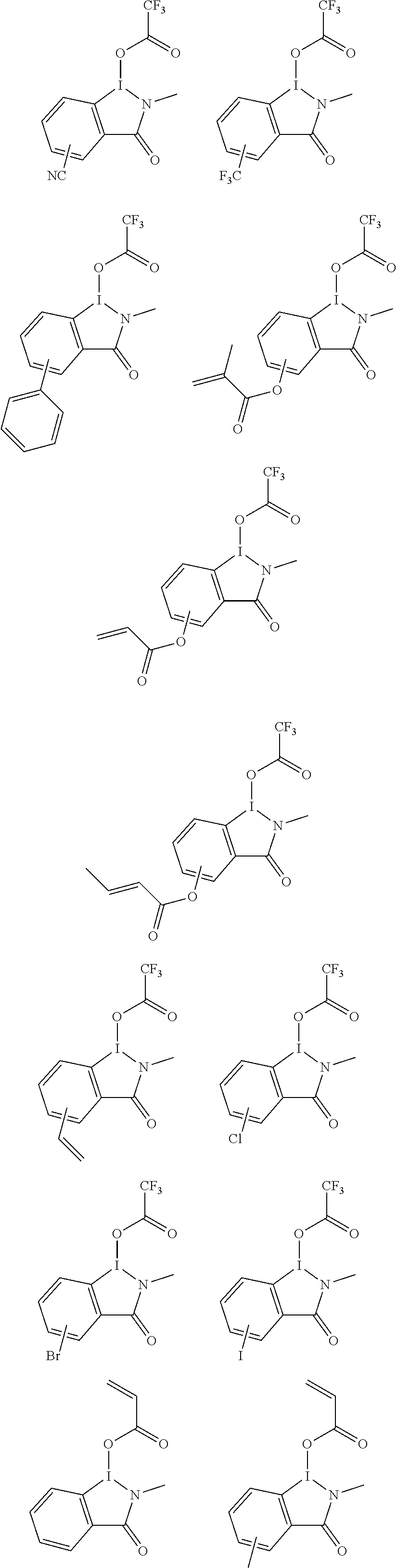

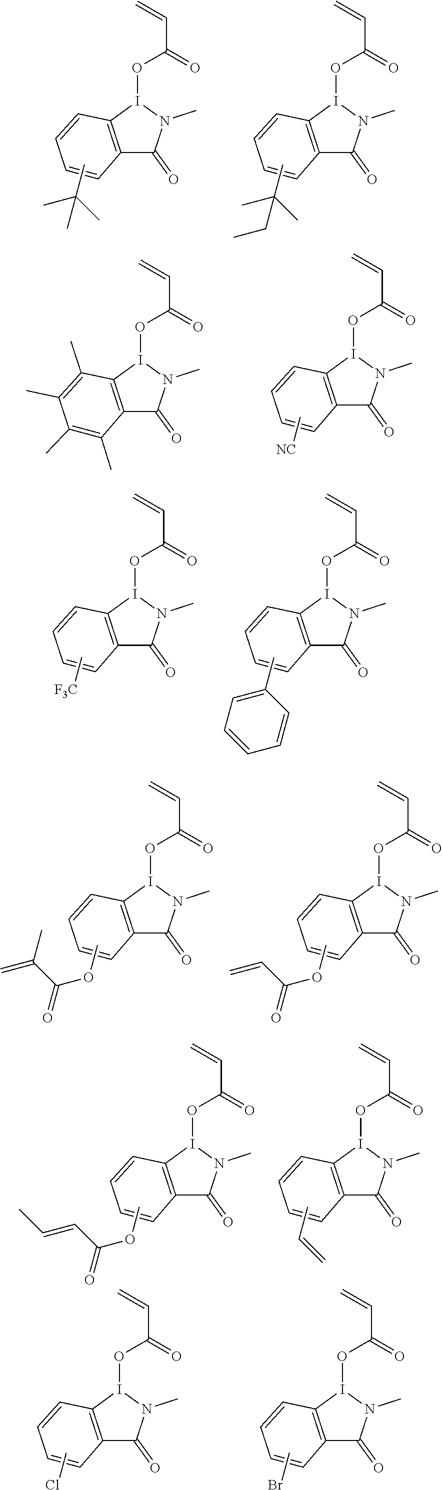

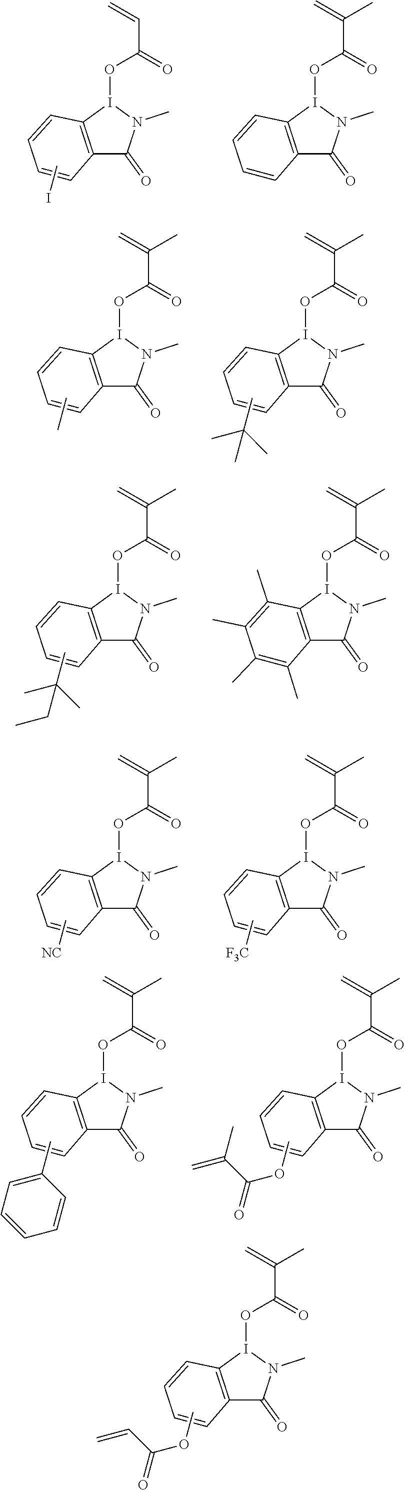

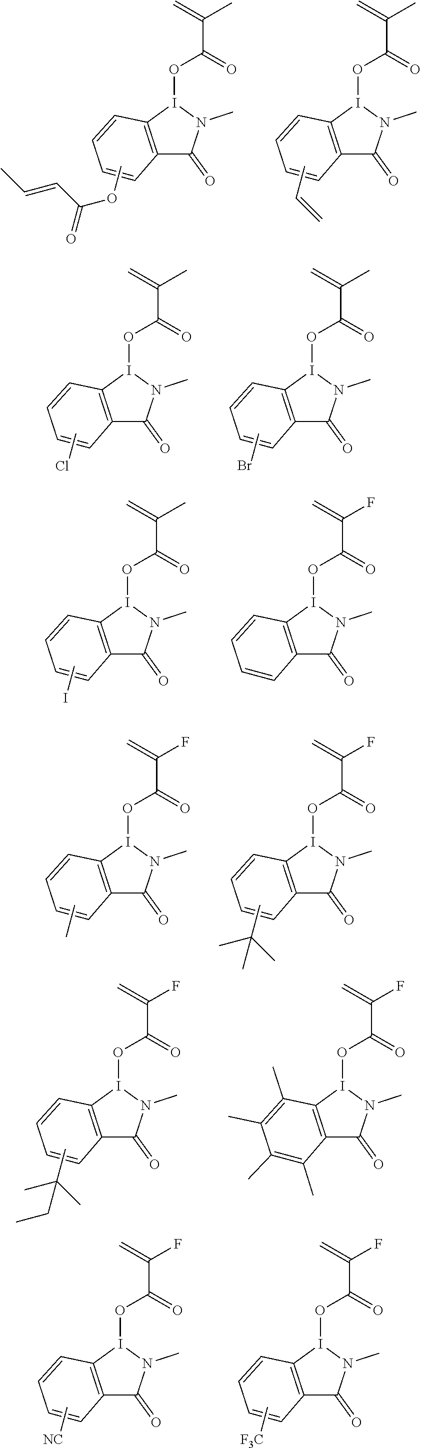

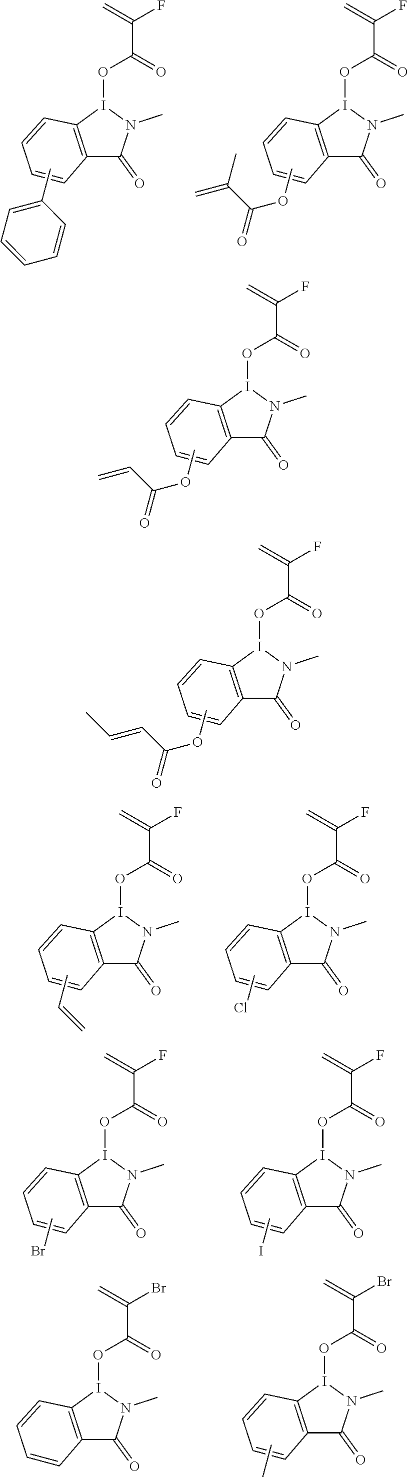

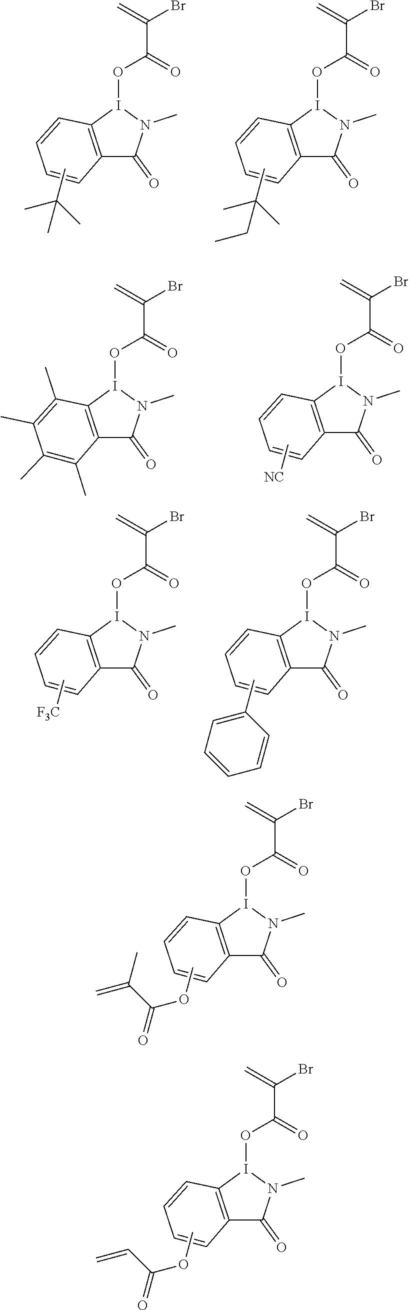

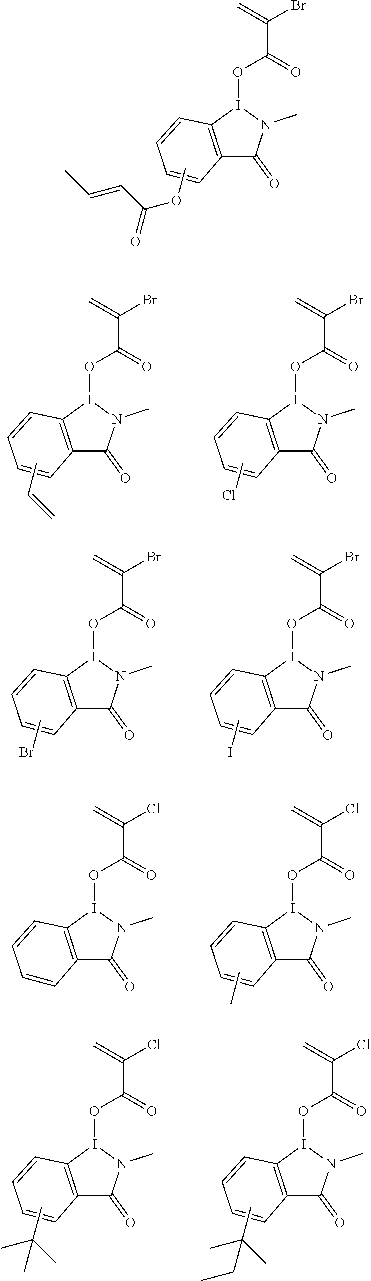

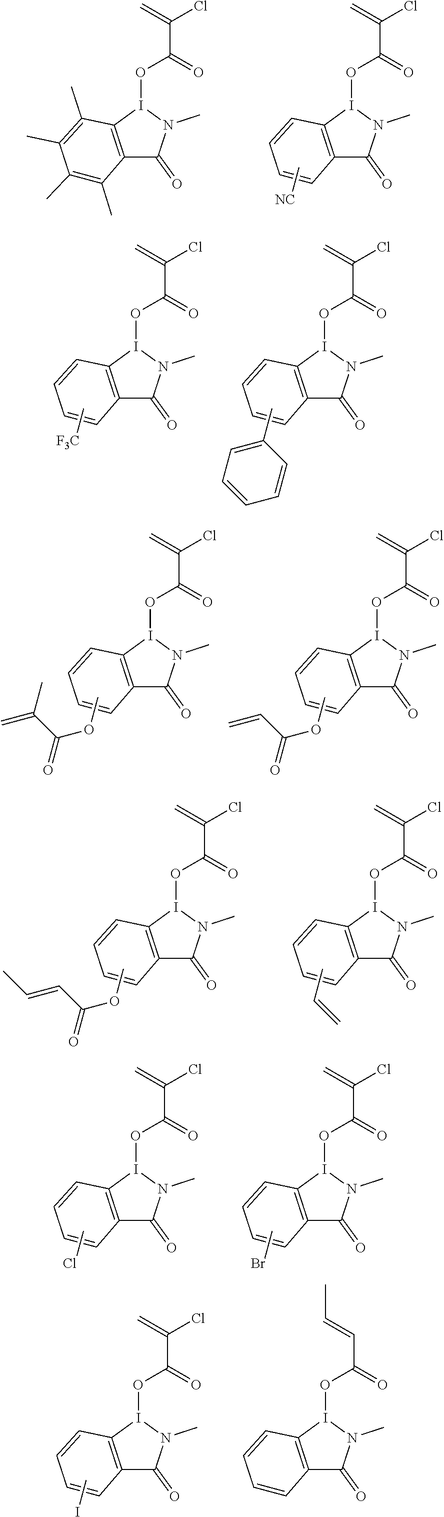

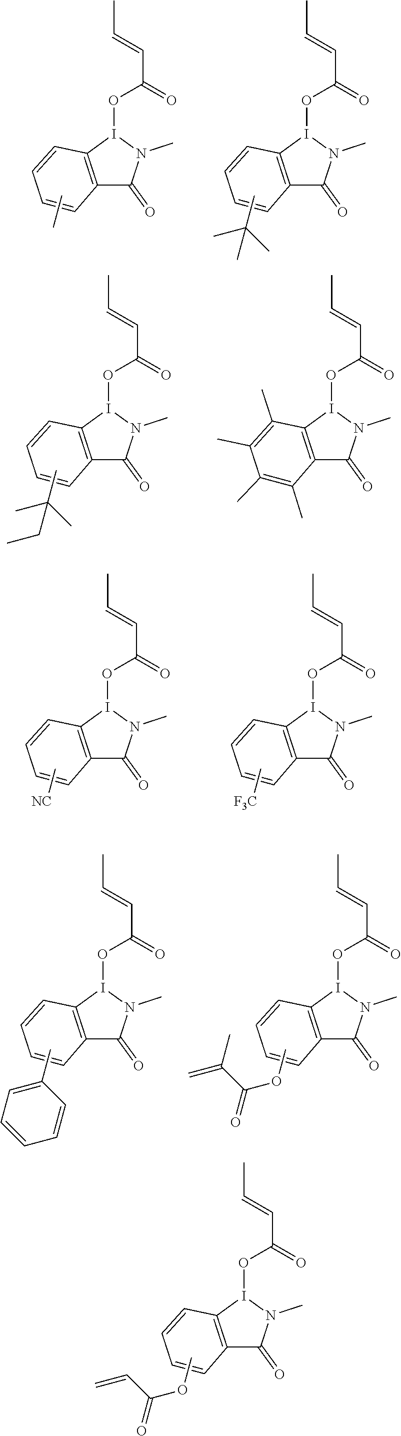

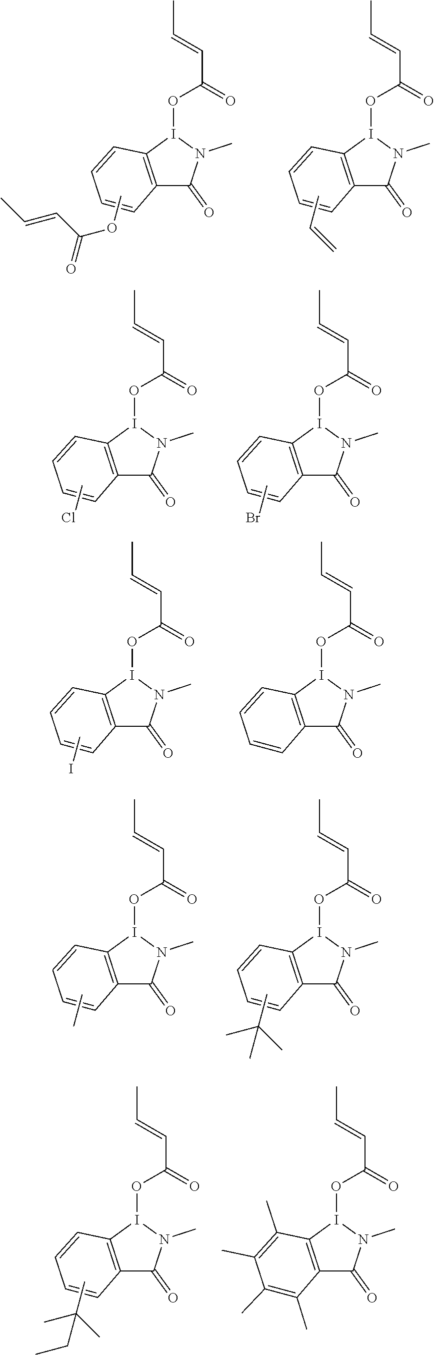

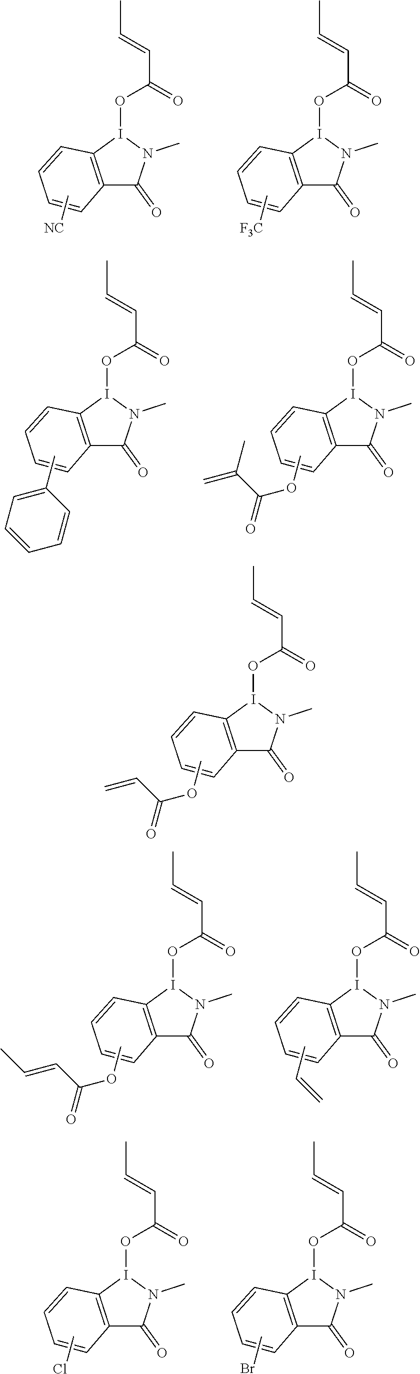

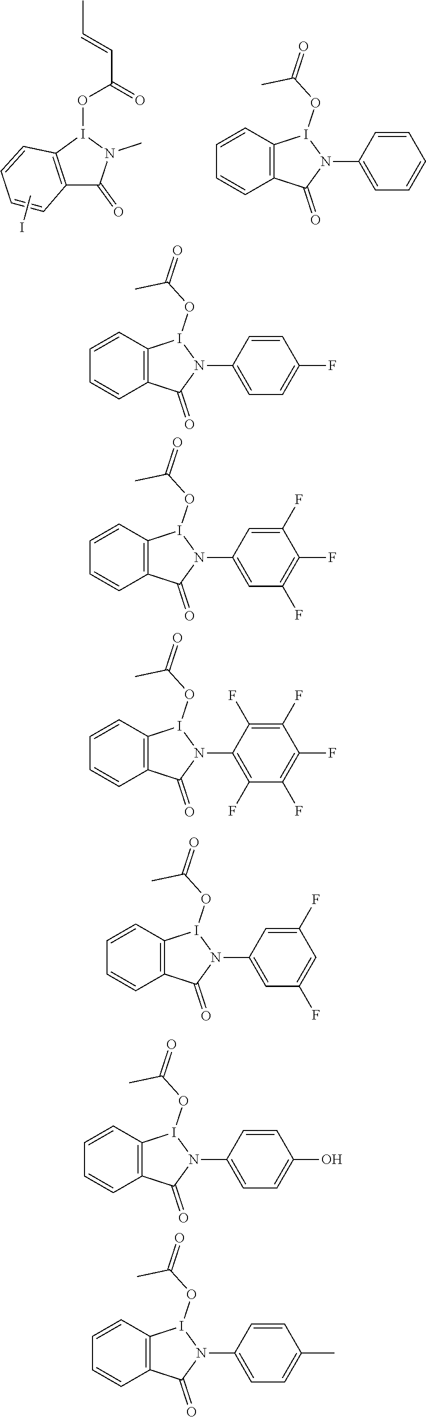

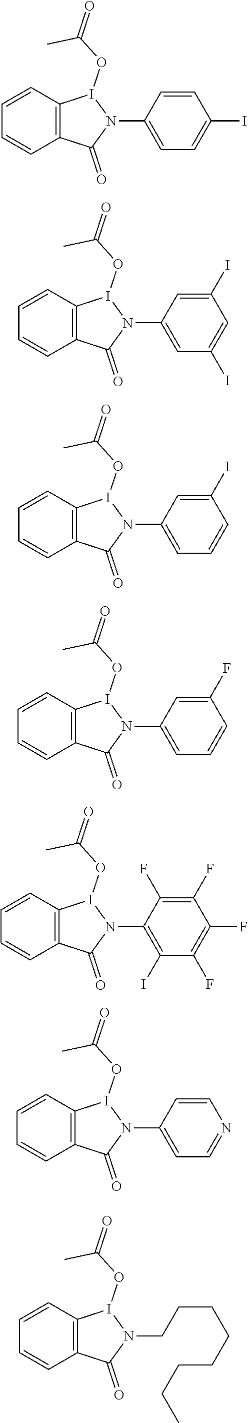

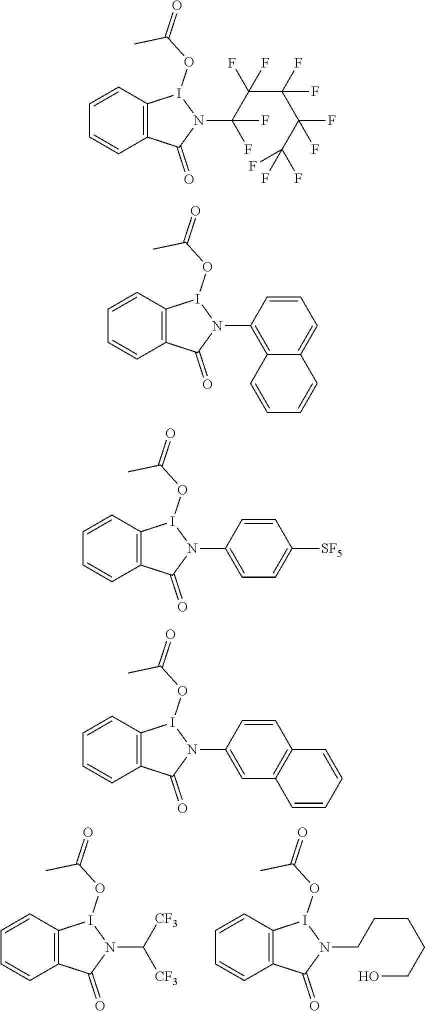

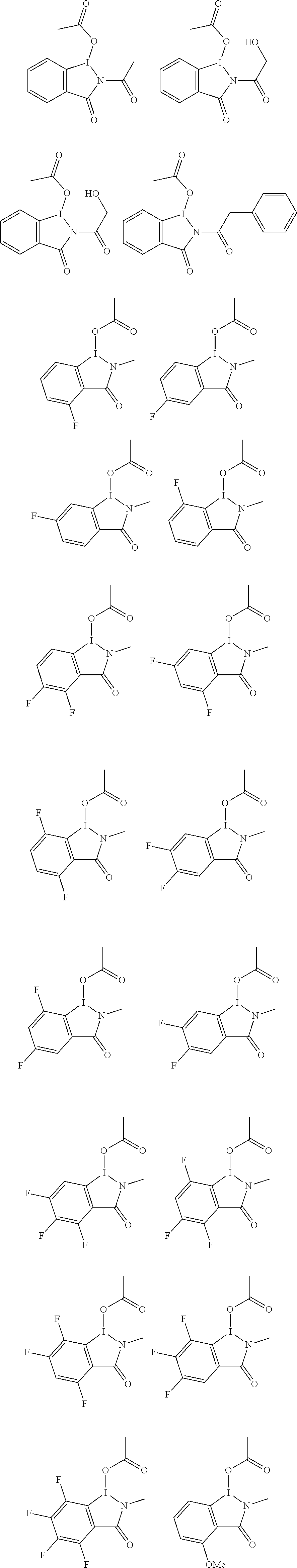

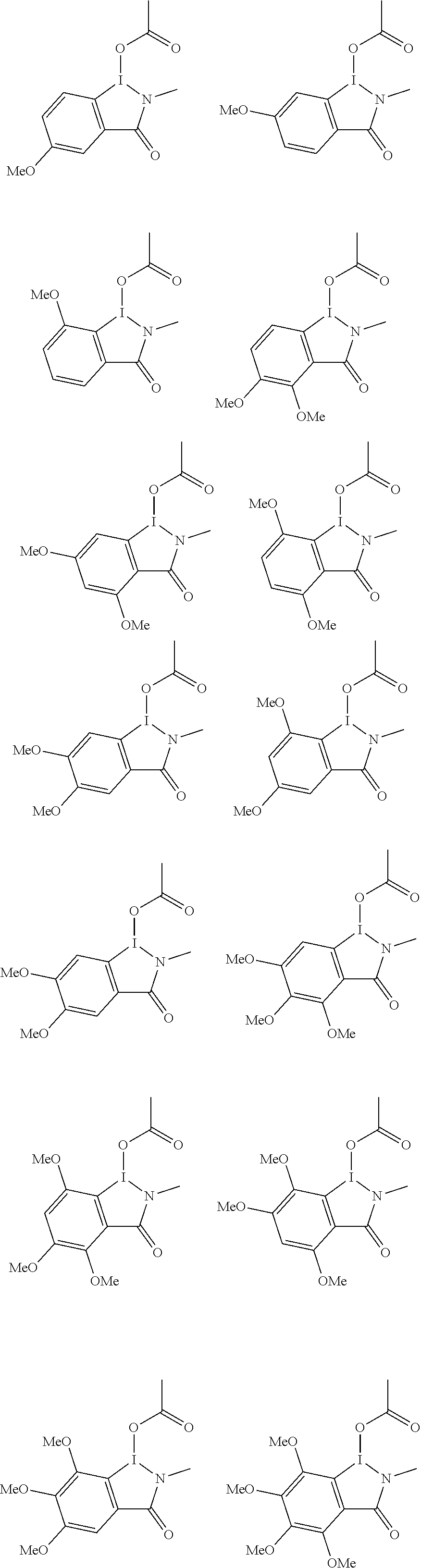

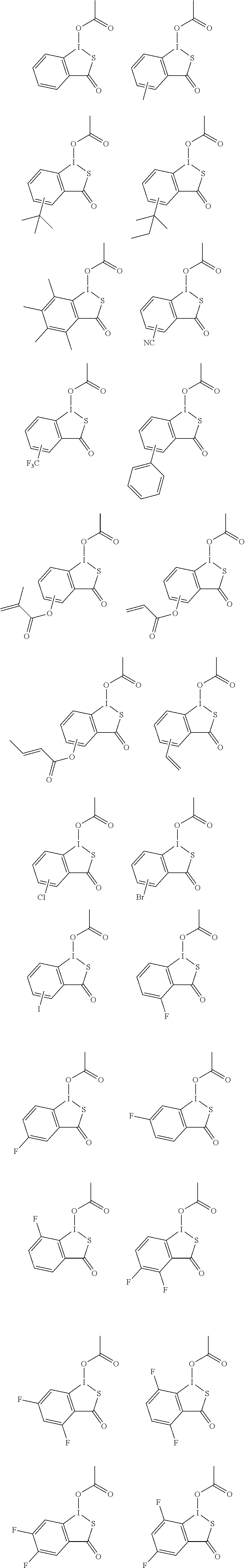

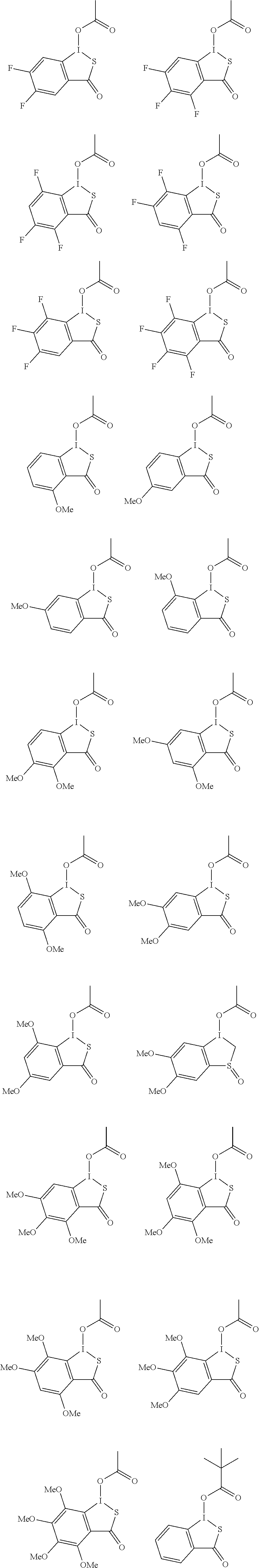

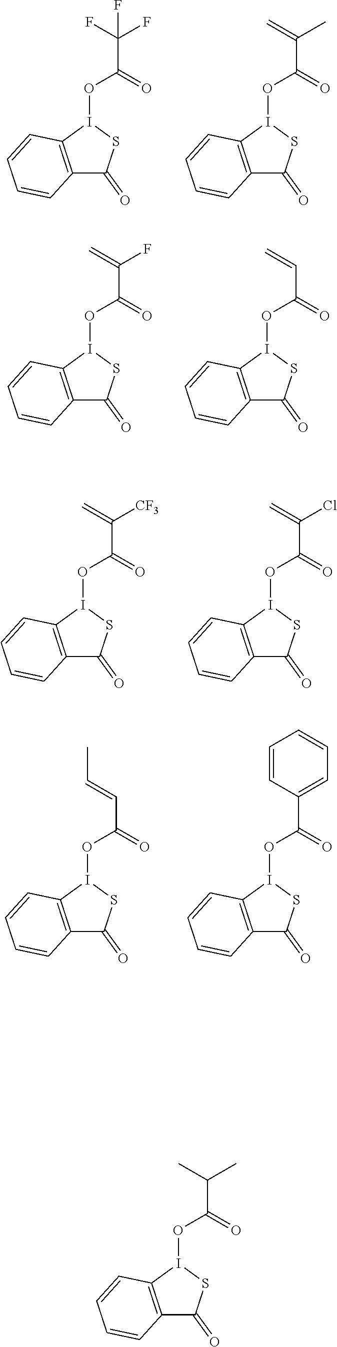

Specific examples of the hypervalent iodine compound represented by the formula (11) include the following, but are not limited thereto.

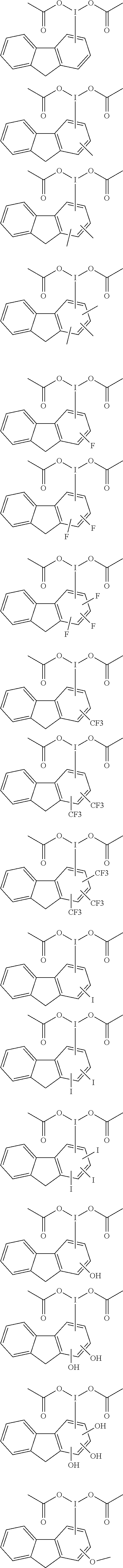

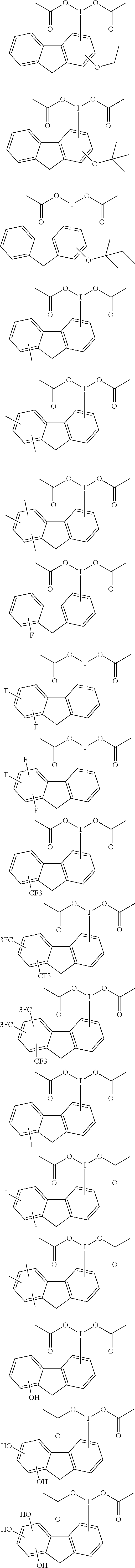

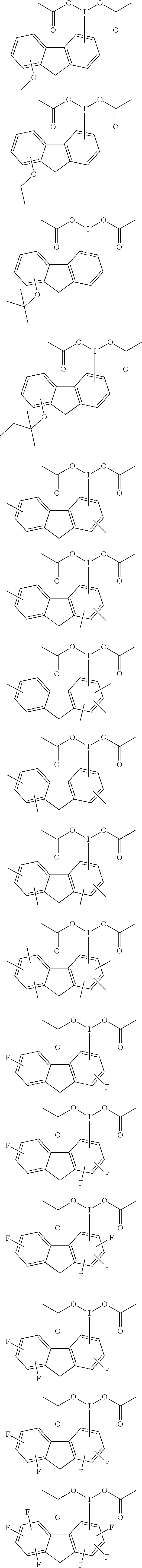

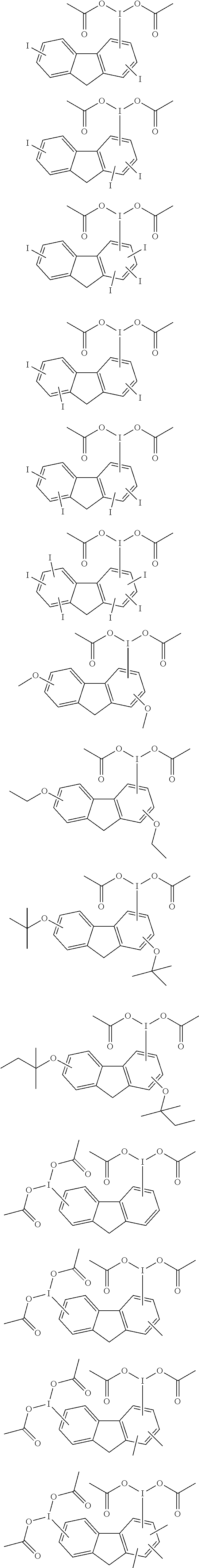

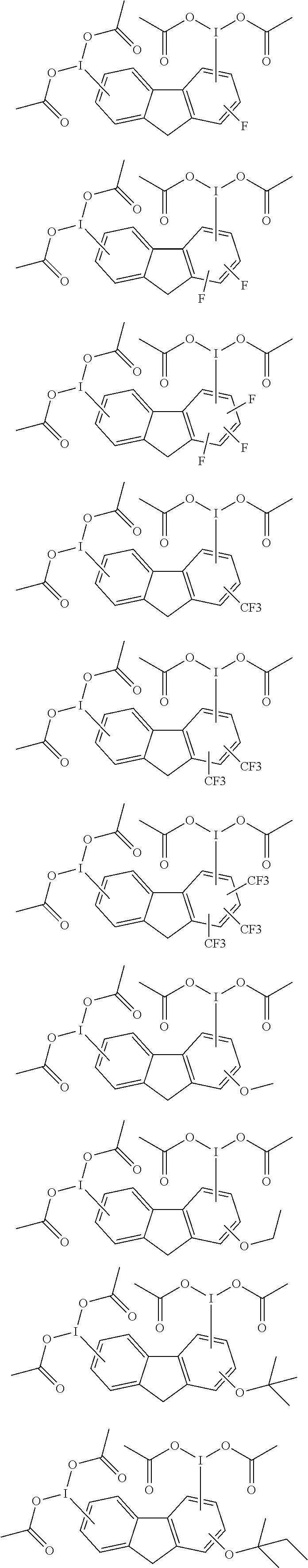

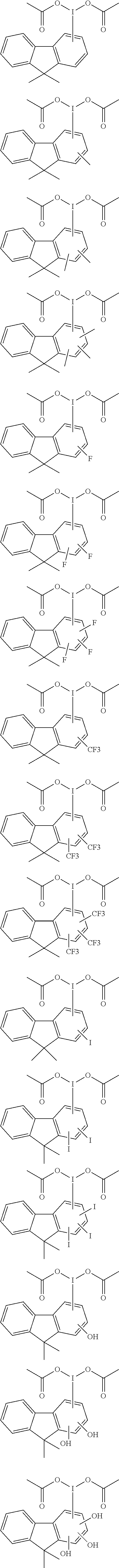

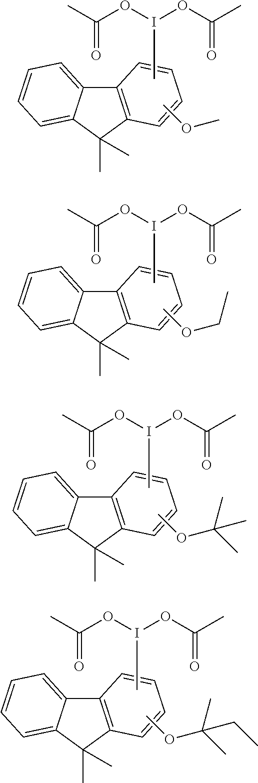

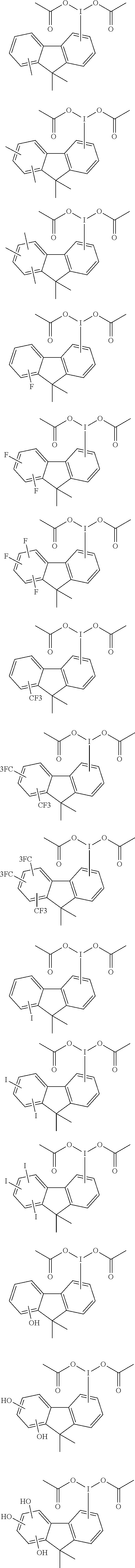

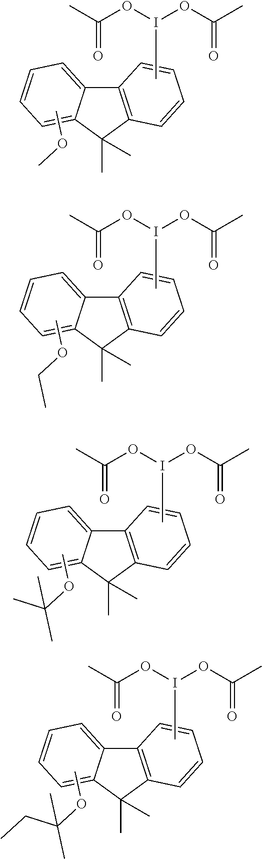

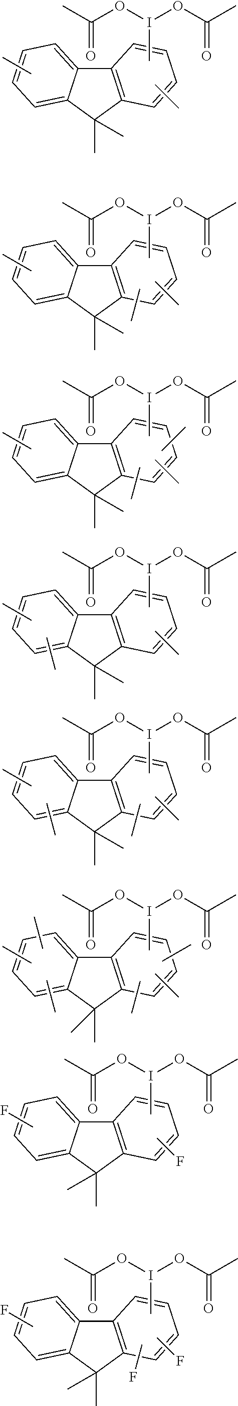

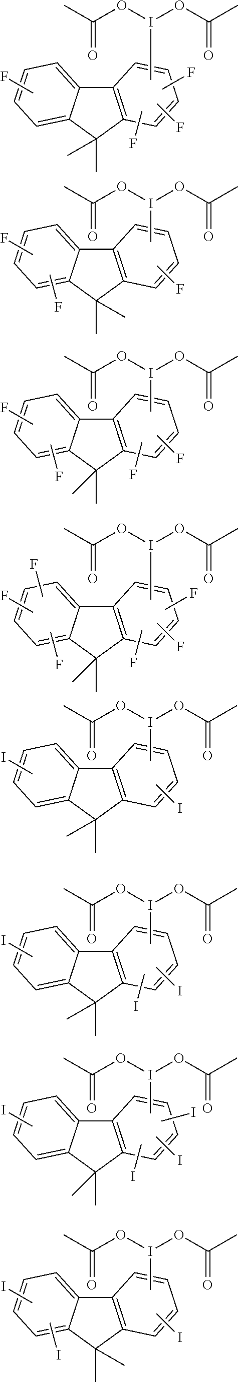

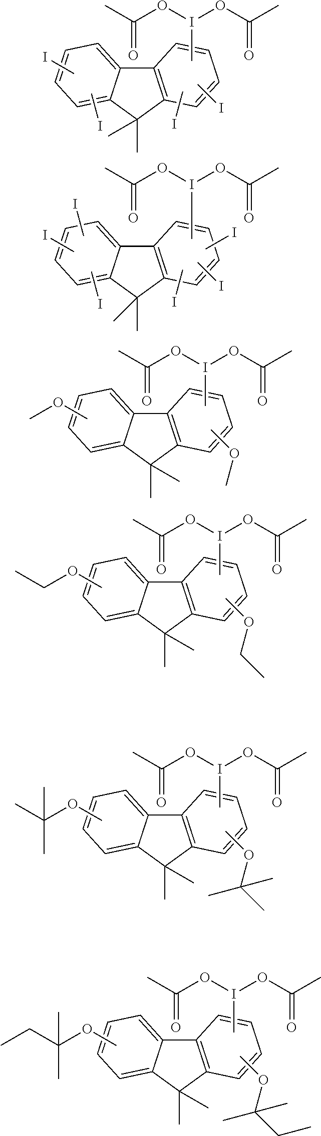

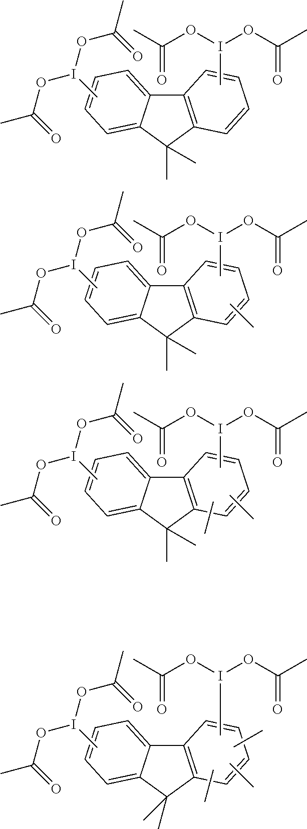

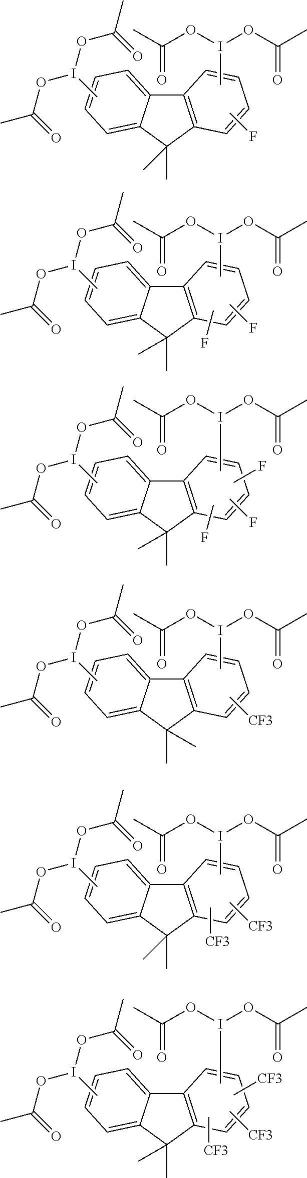

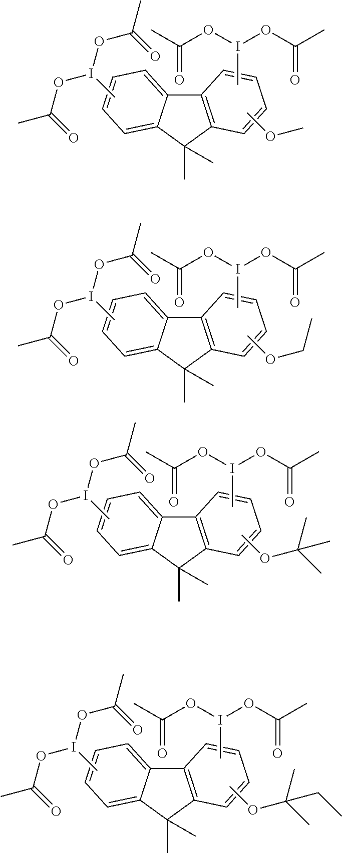

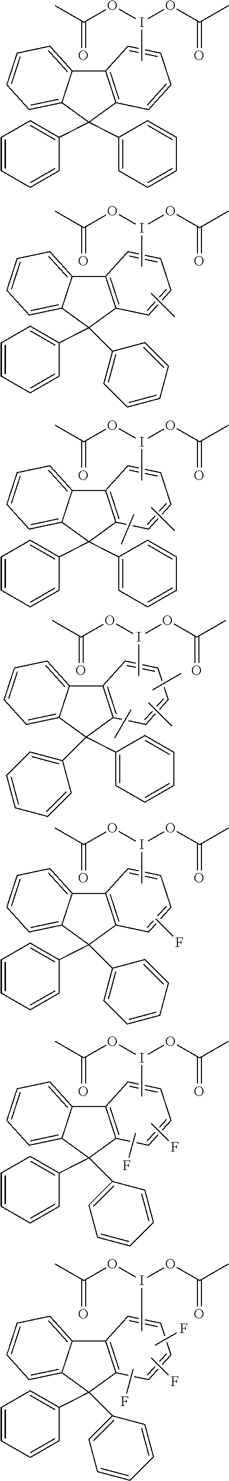

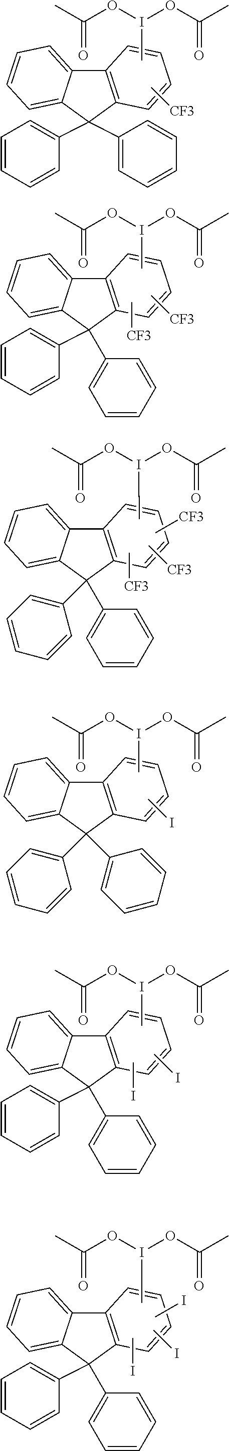

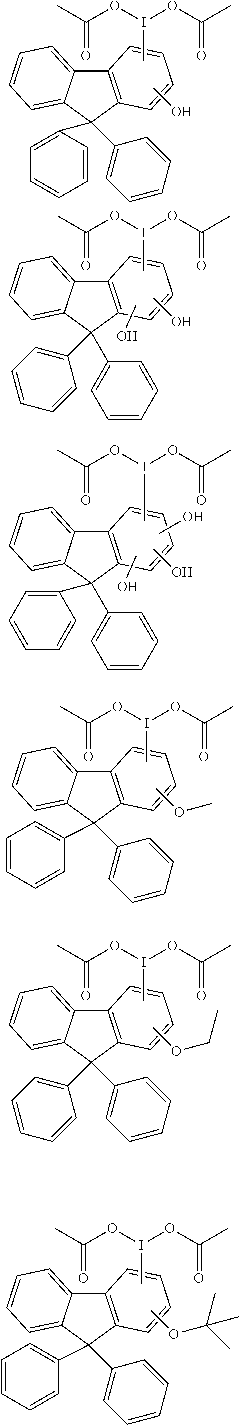

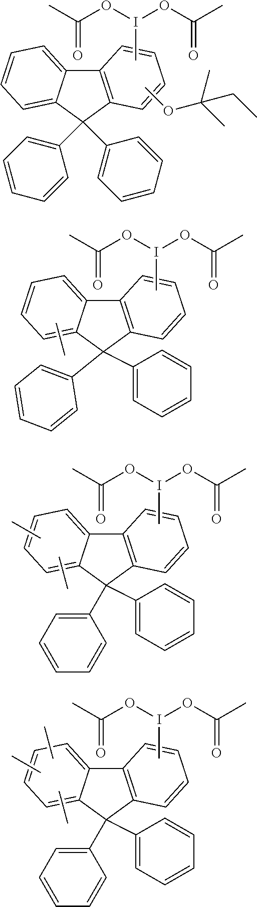

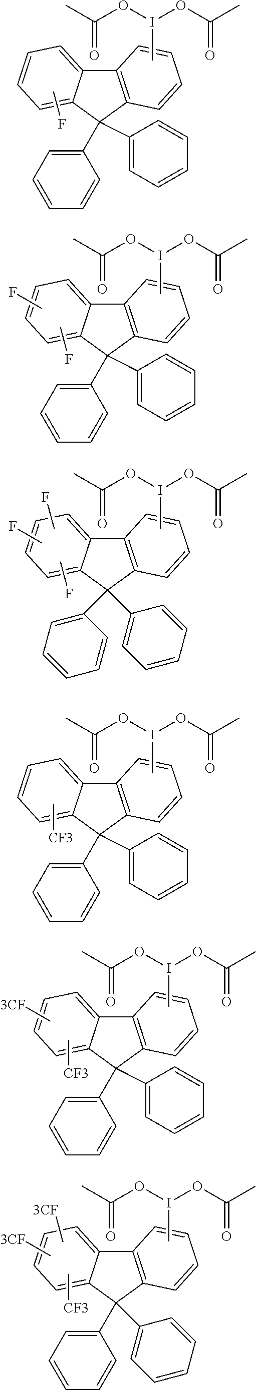

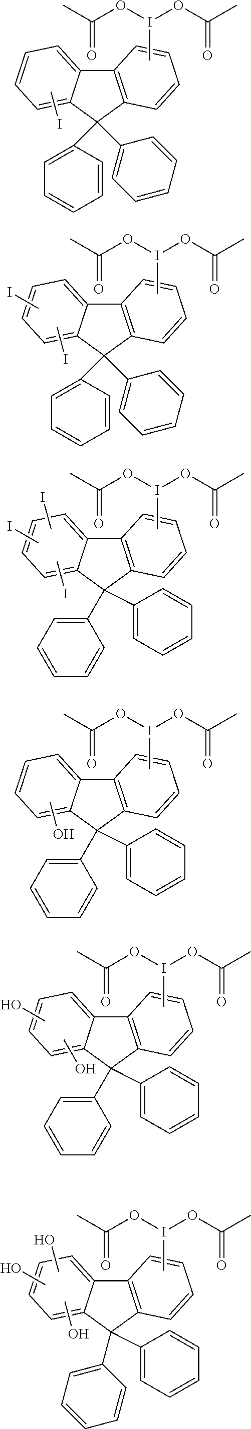

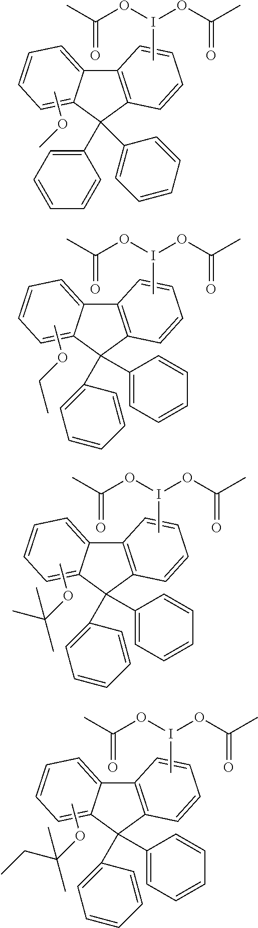

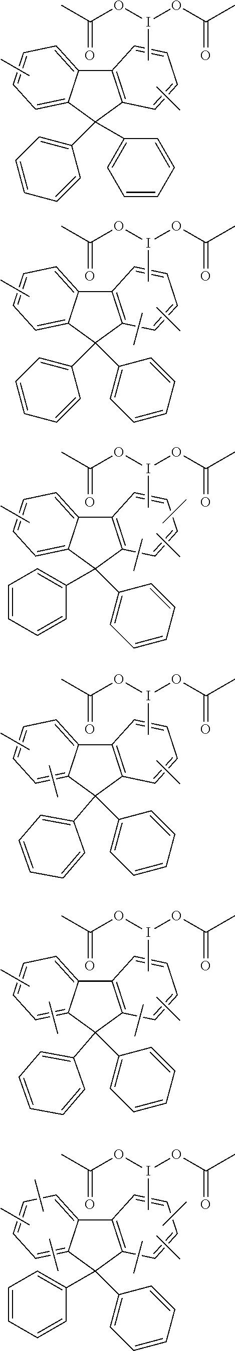

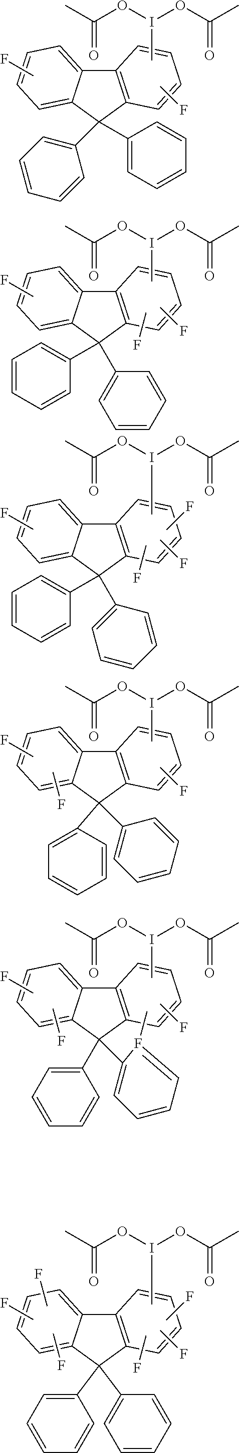

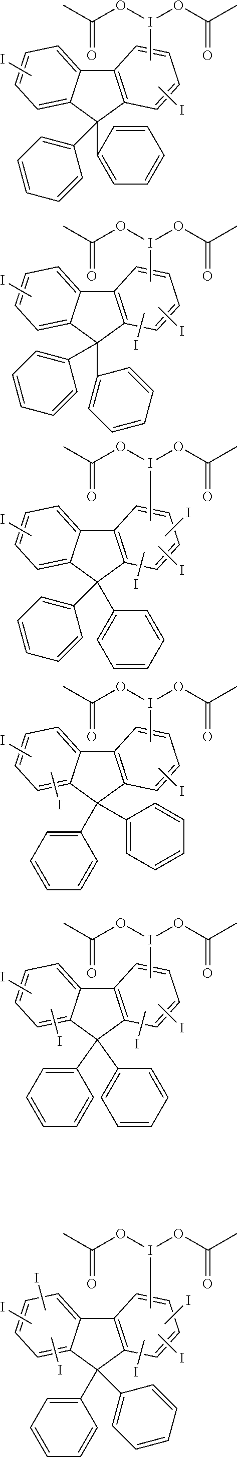

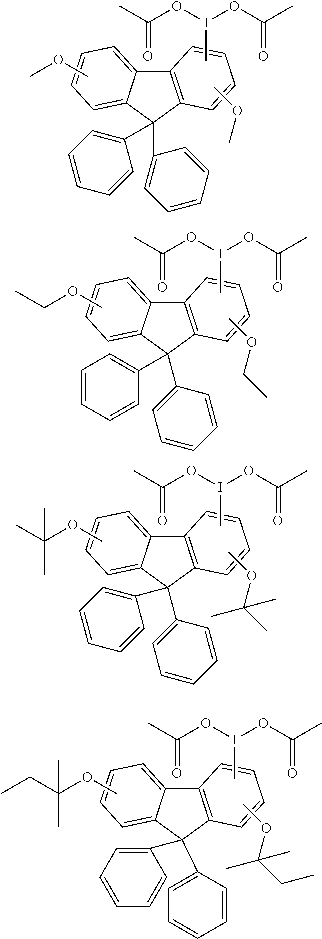

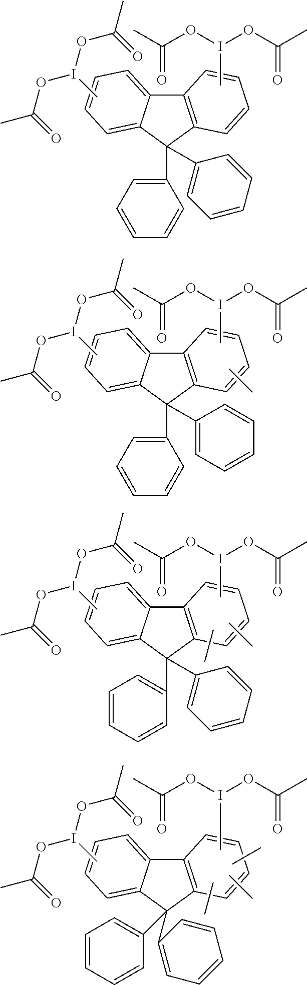

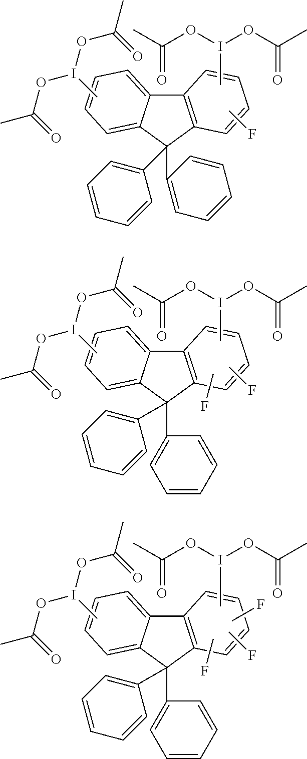

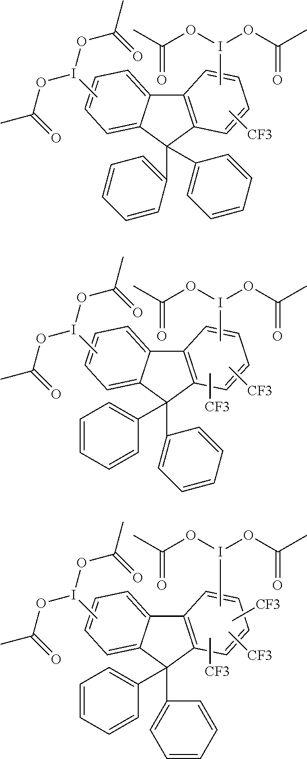

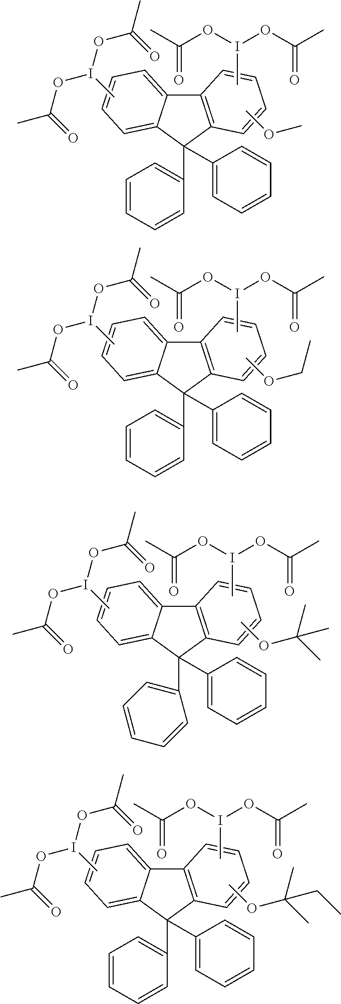

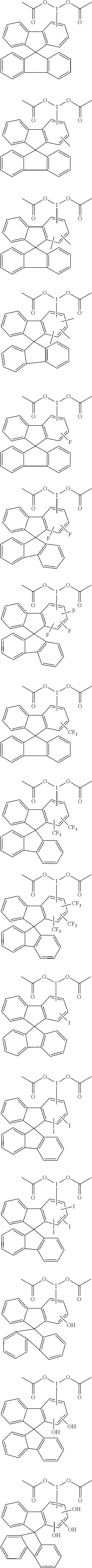

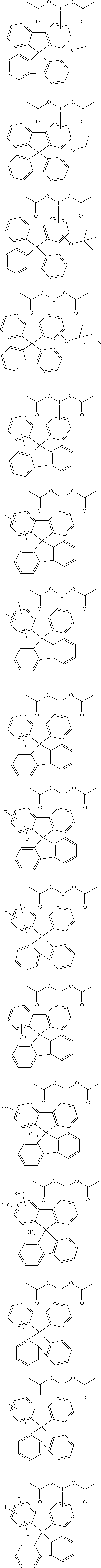

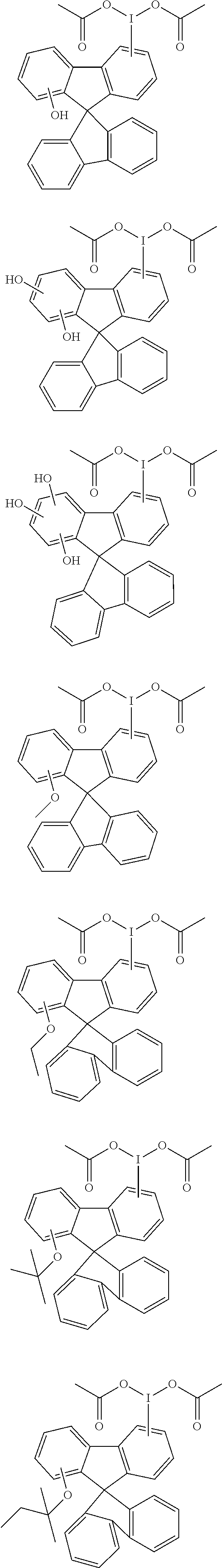

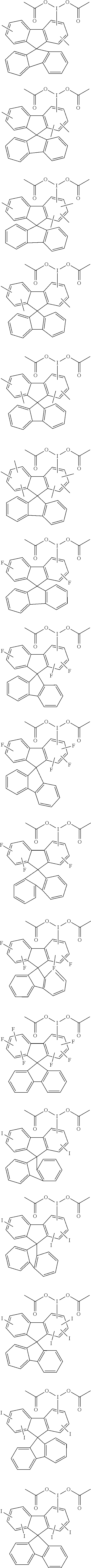

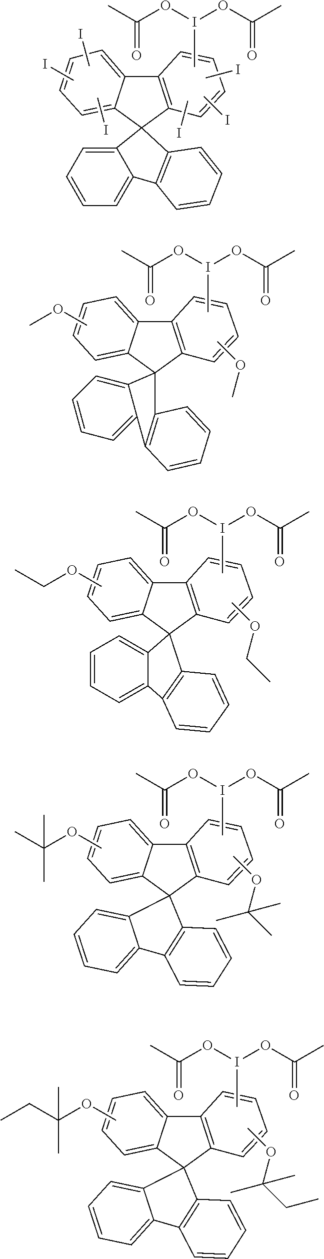

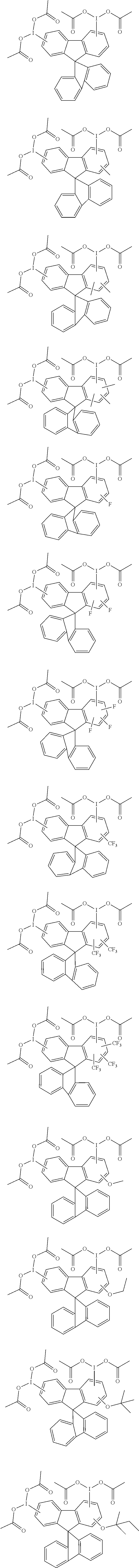

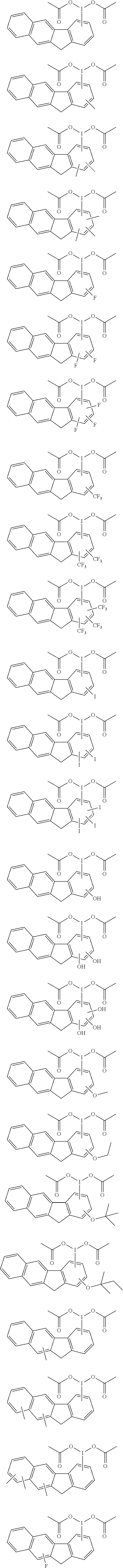

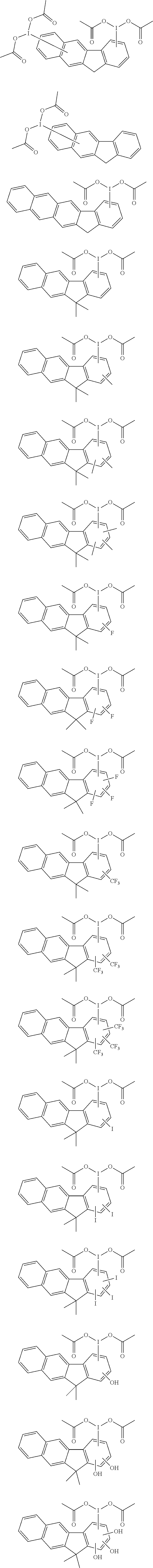

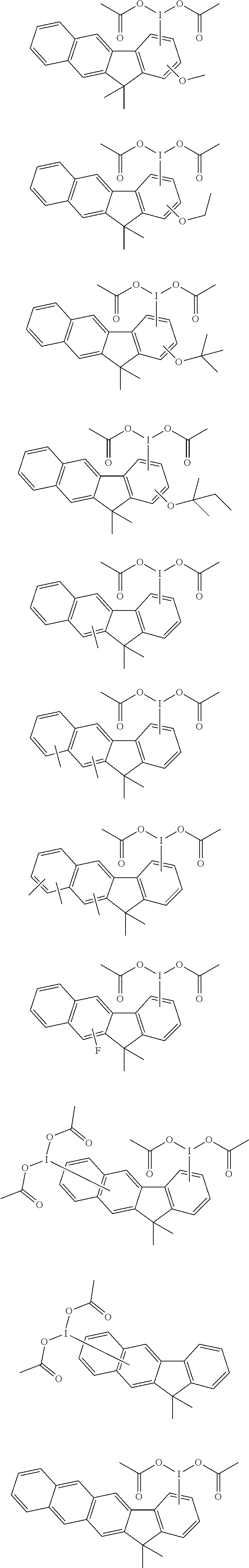

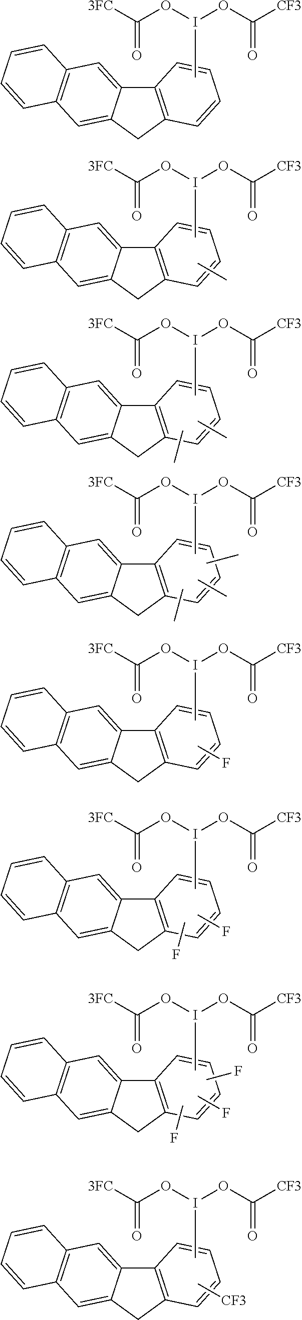

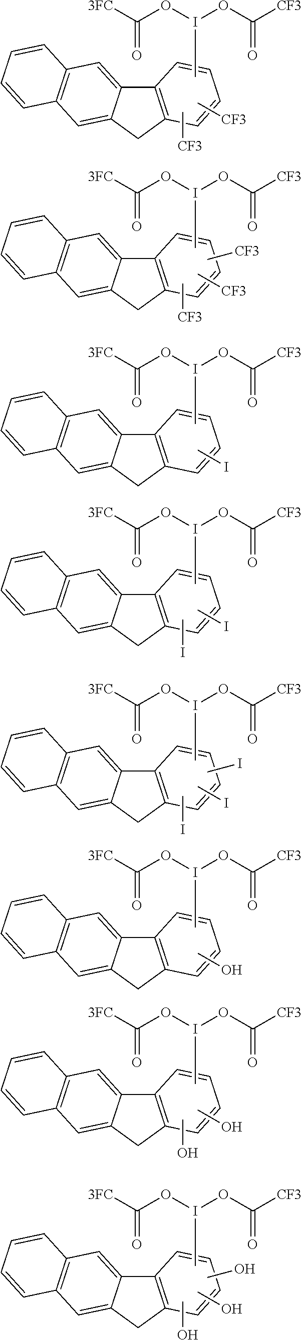

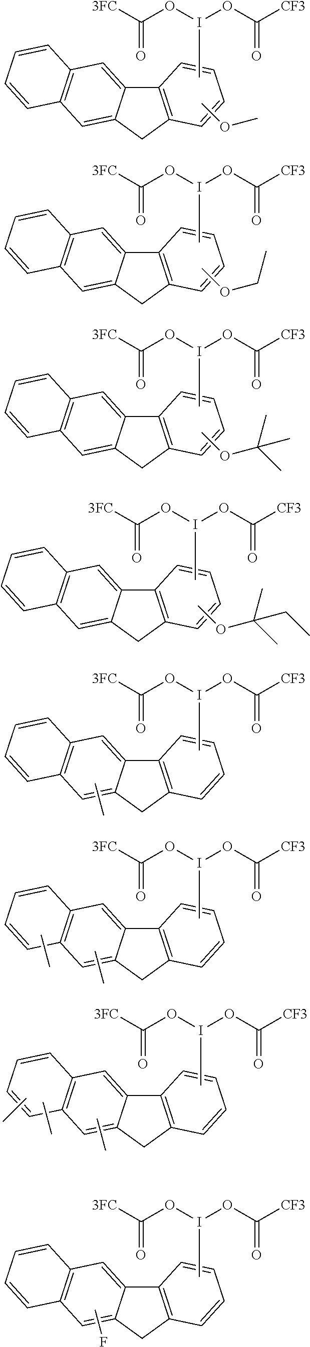

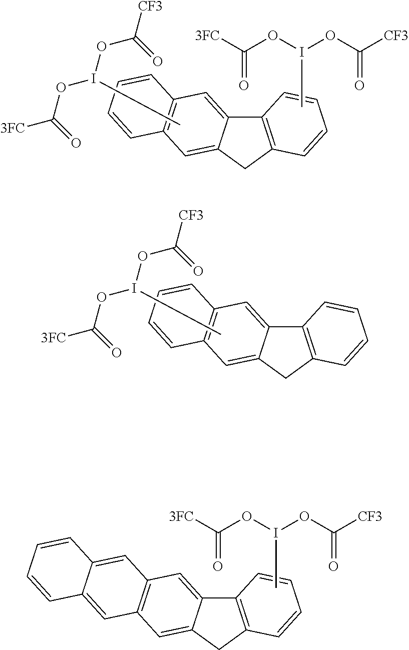

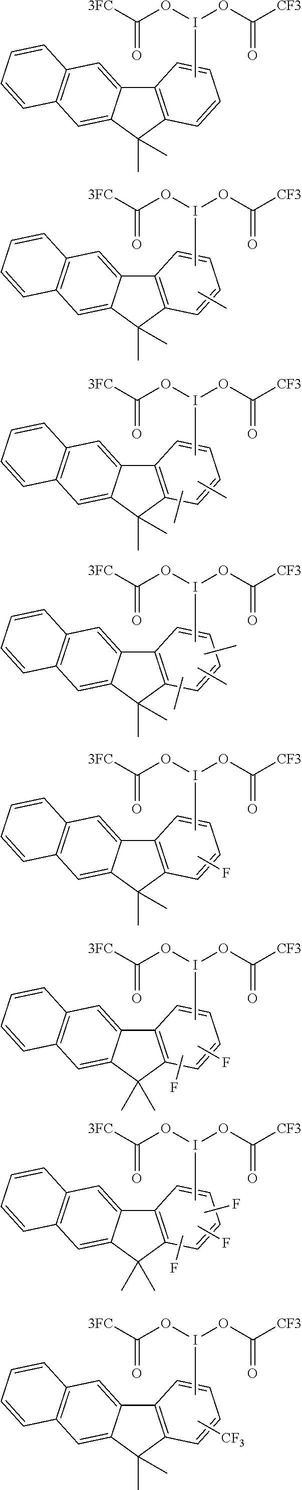

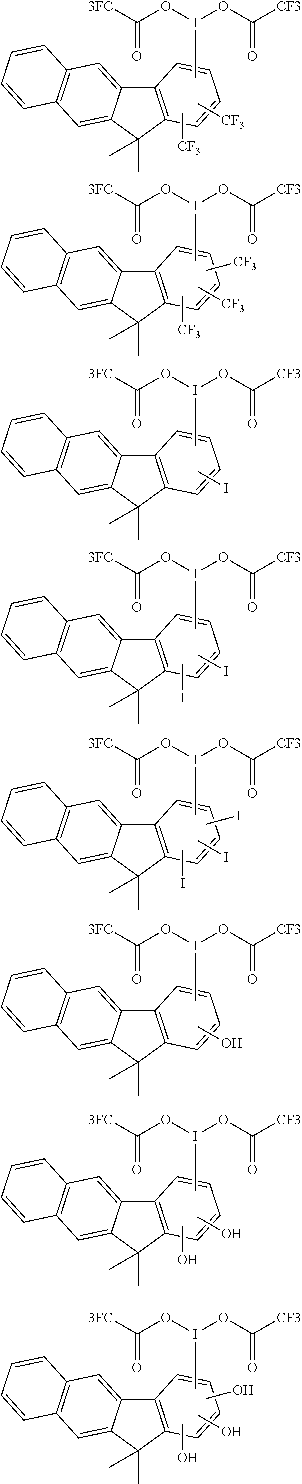

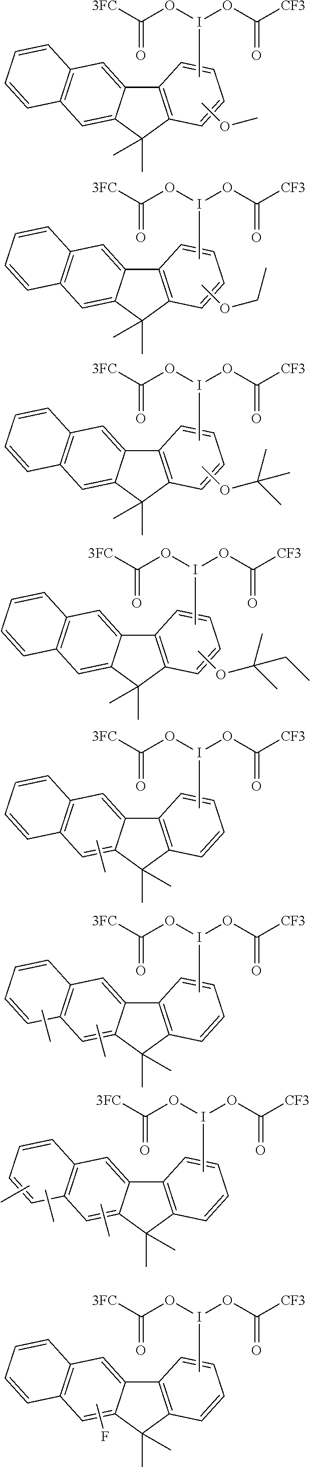

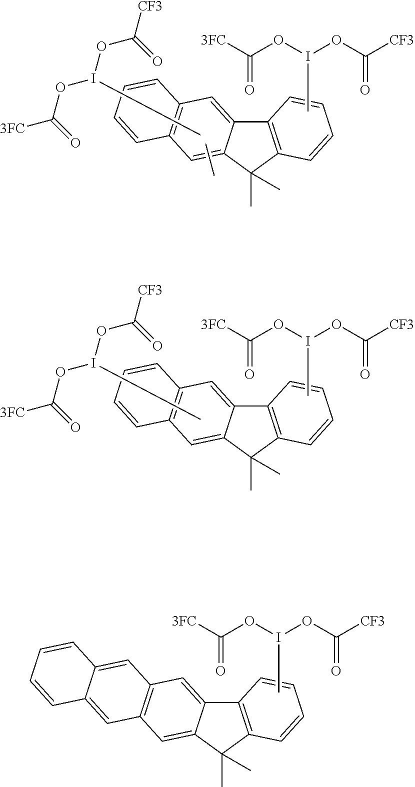

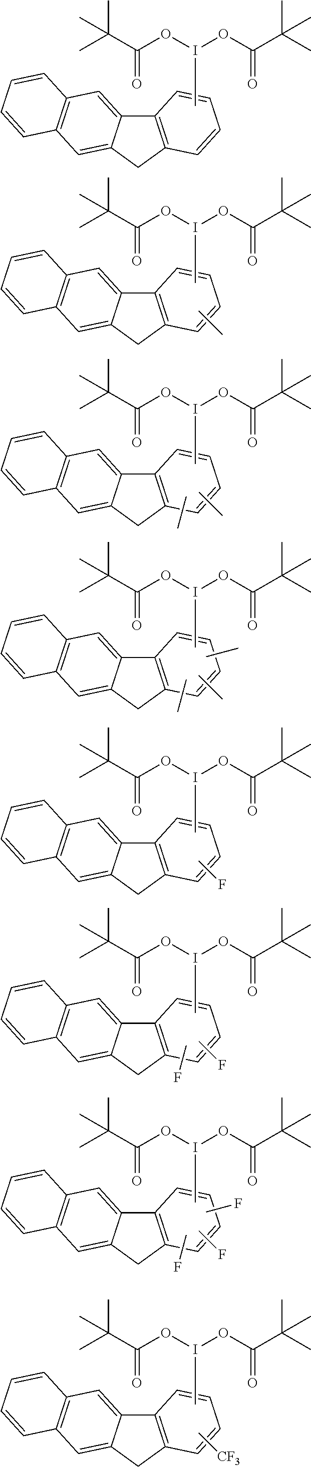

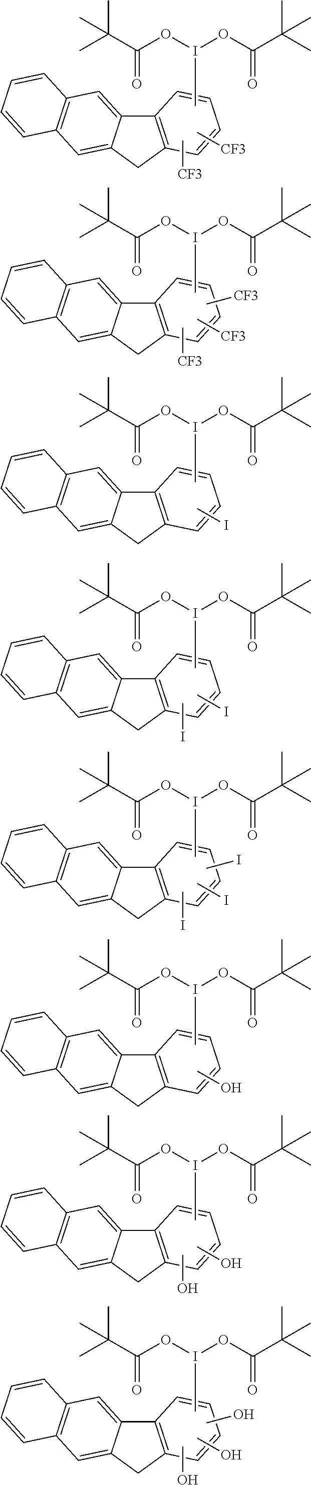

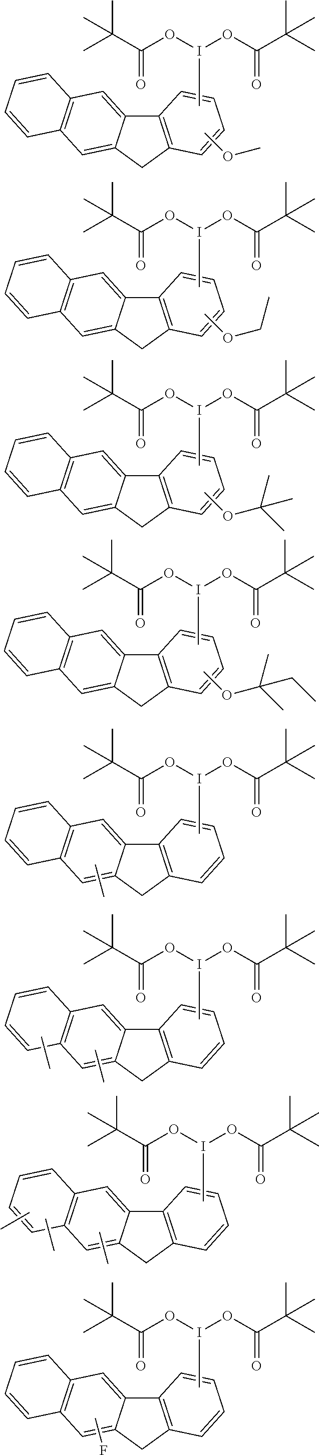

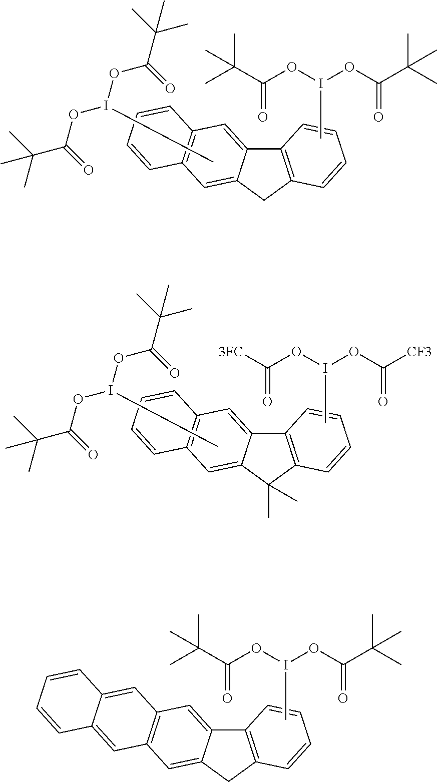

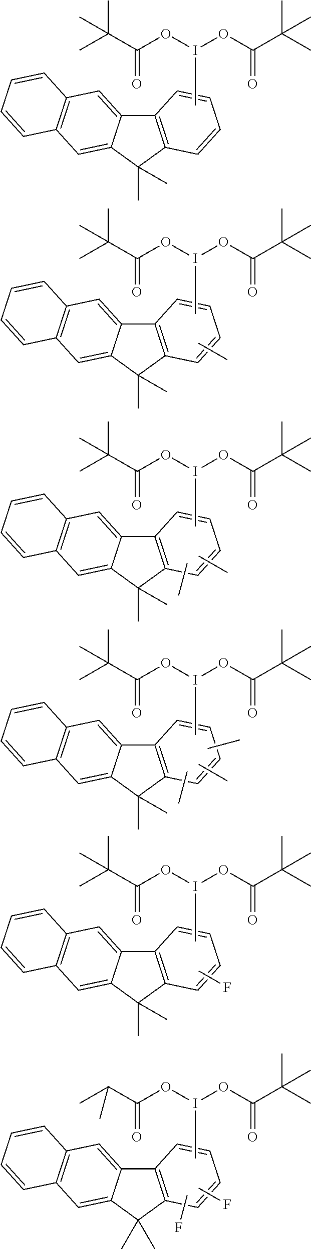

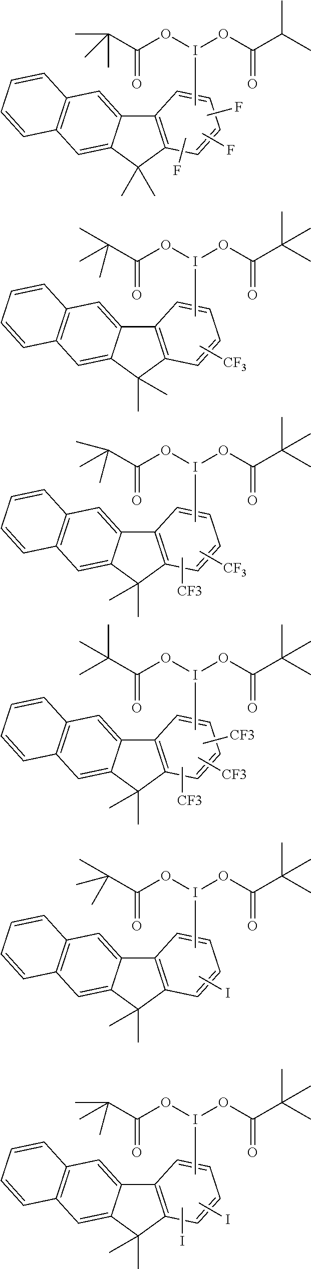

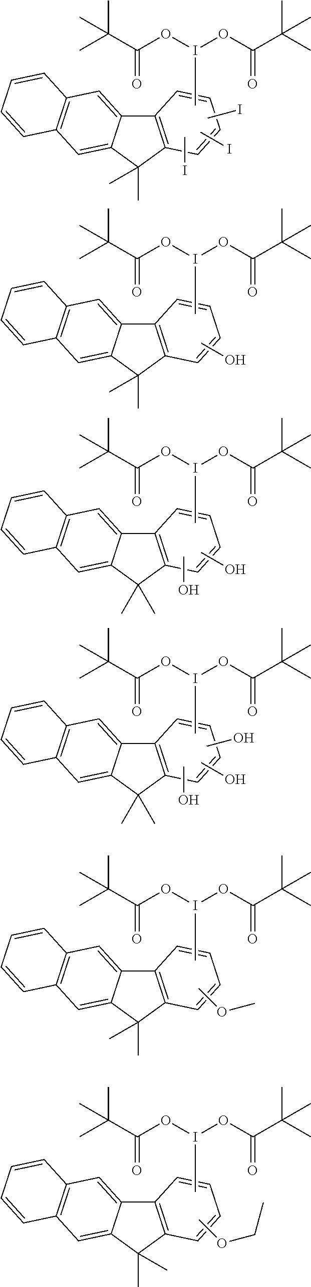

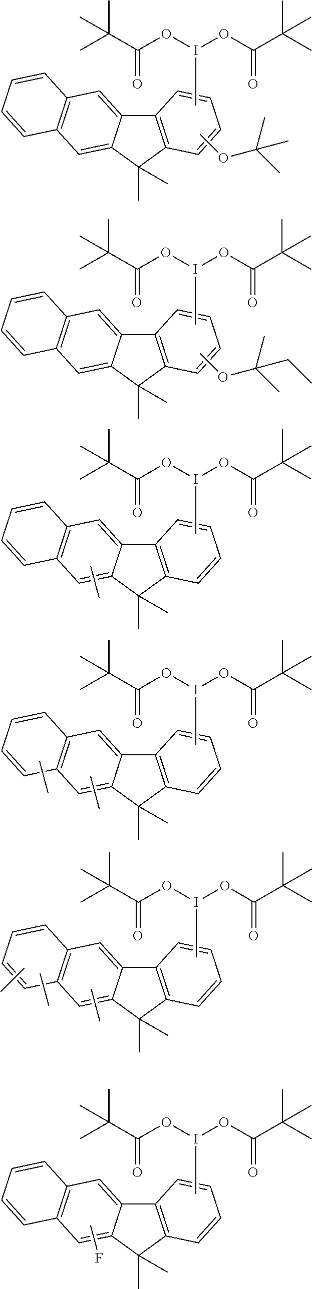

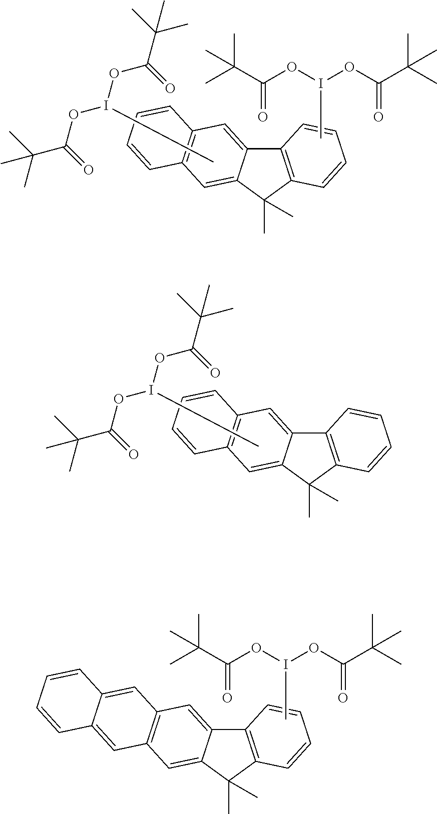

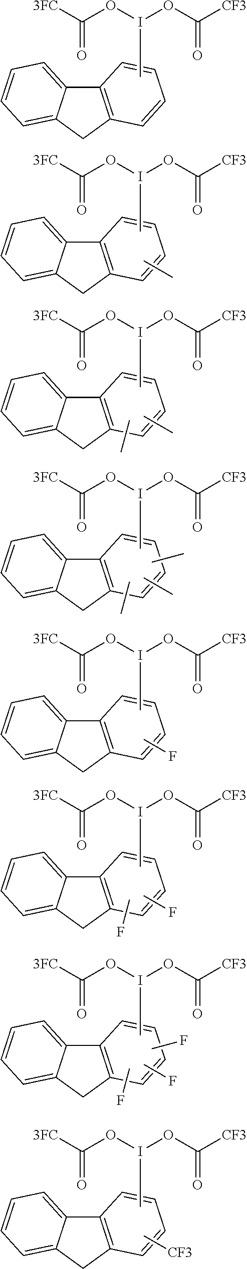

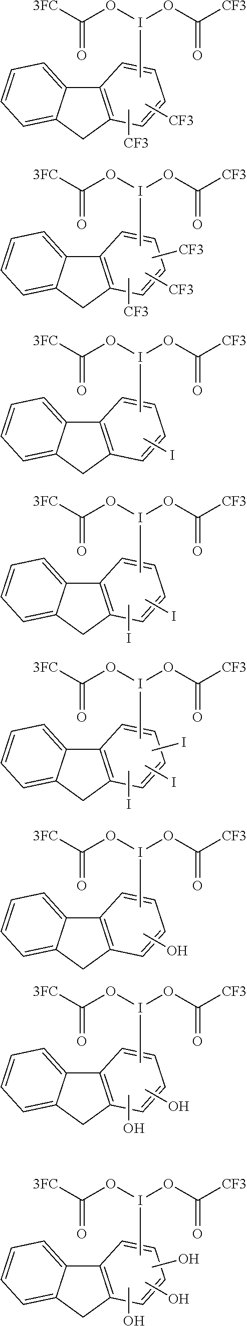

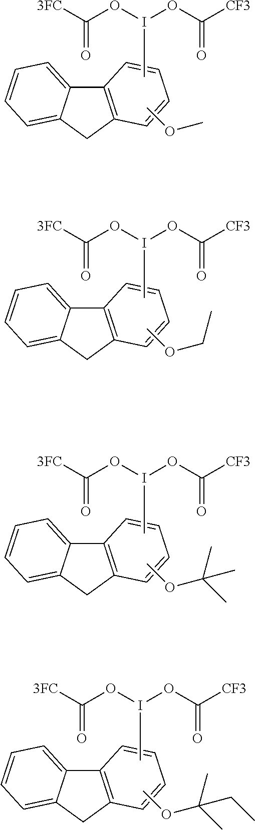

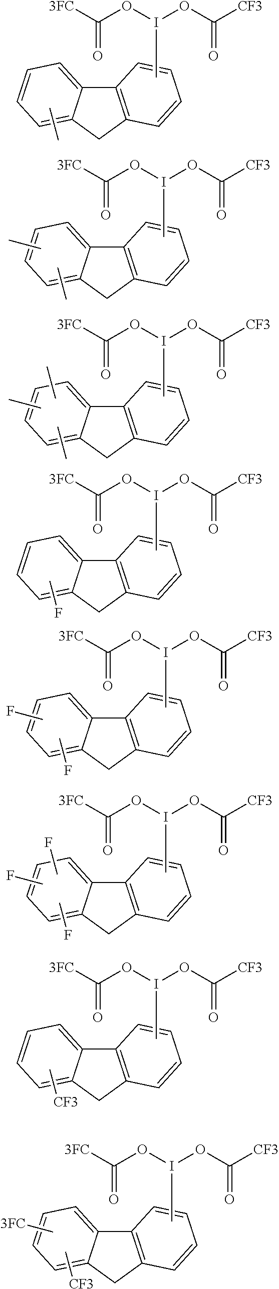

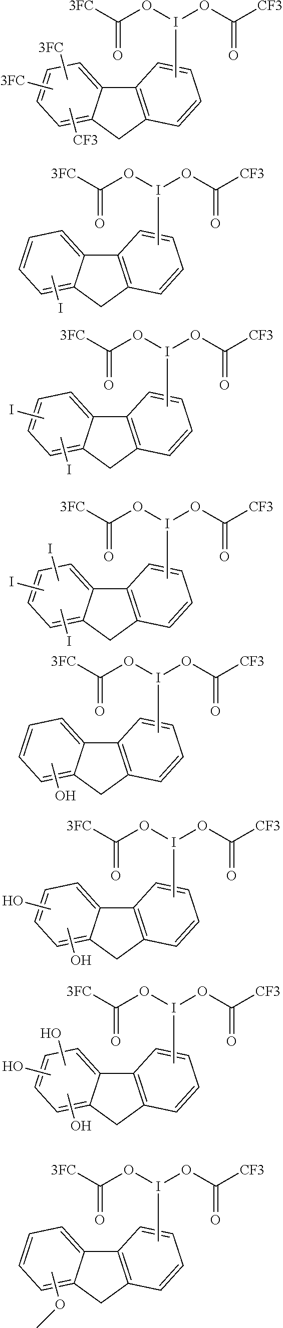

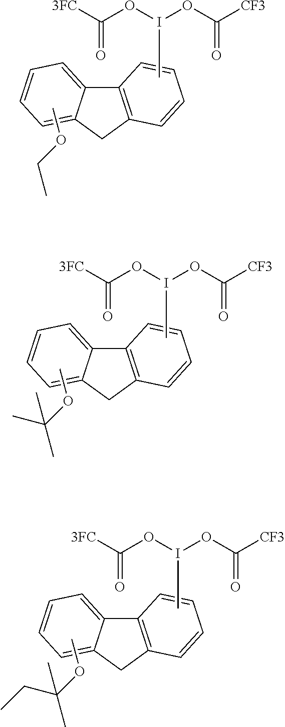

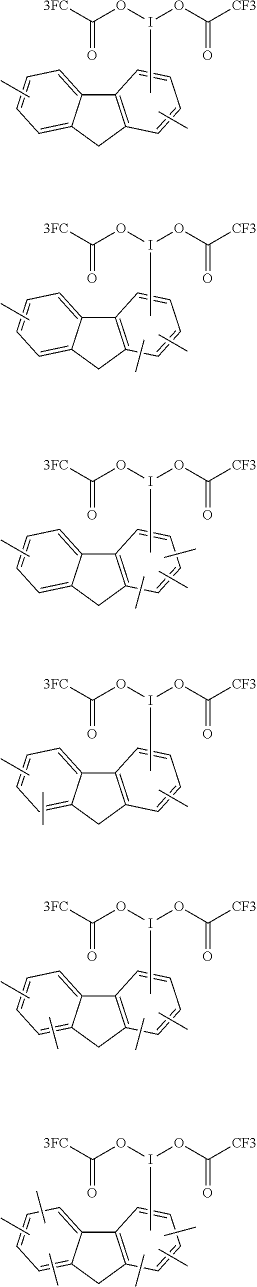

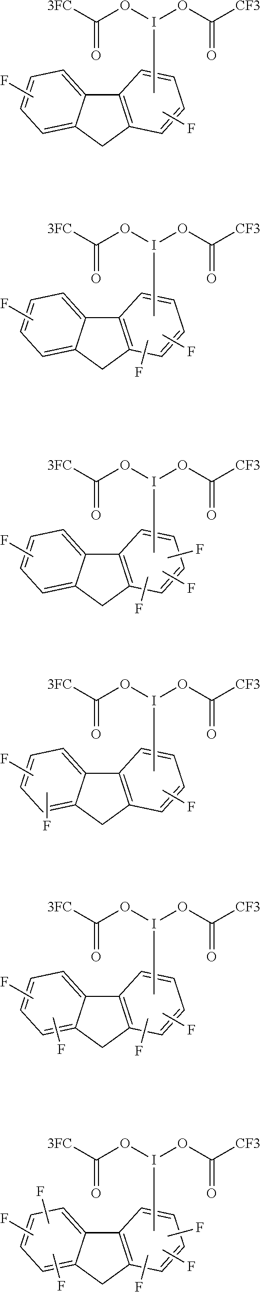

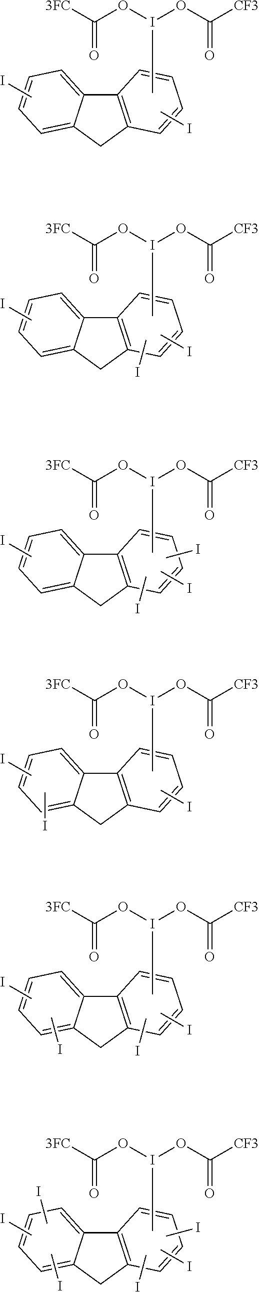

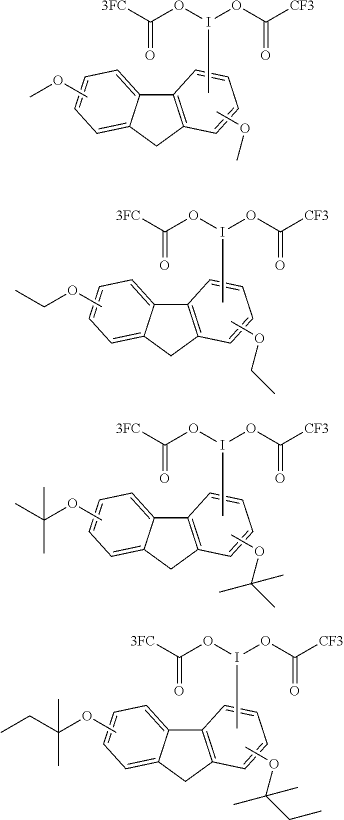

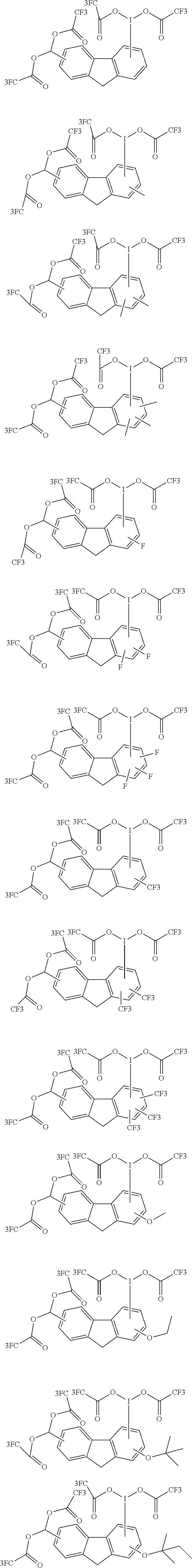

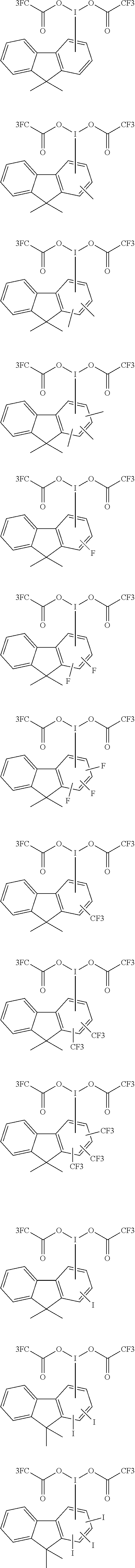

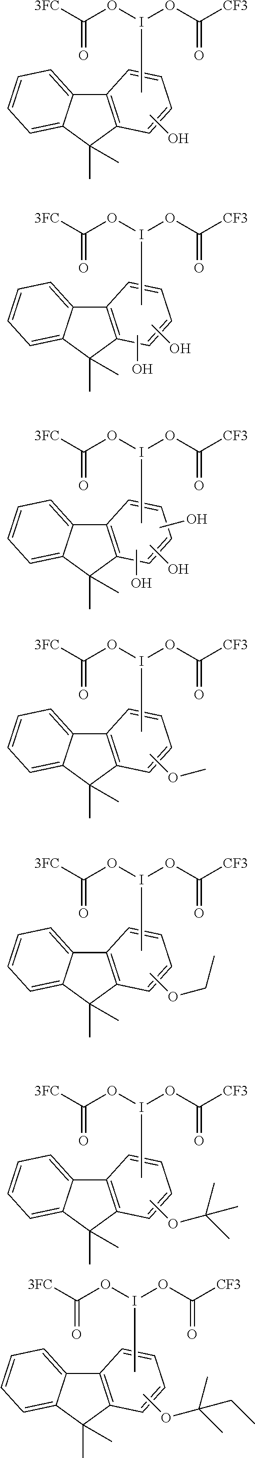

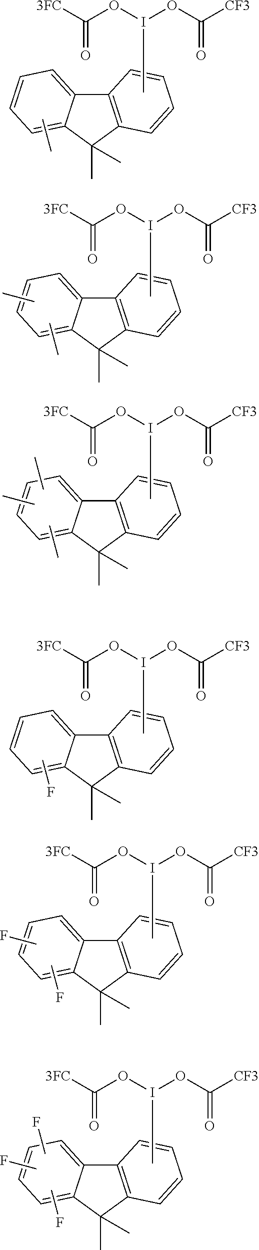

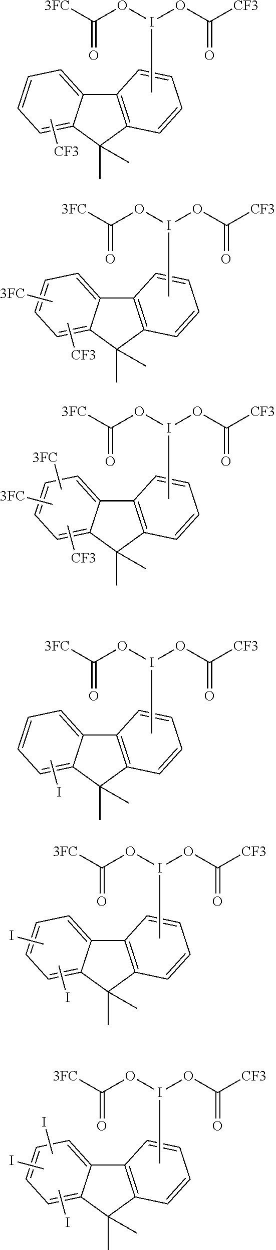

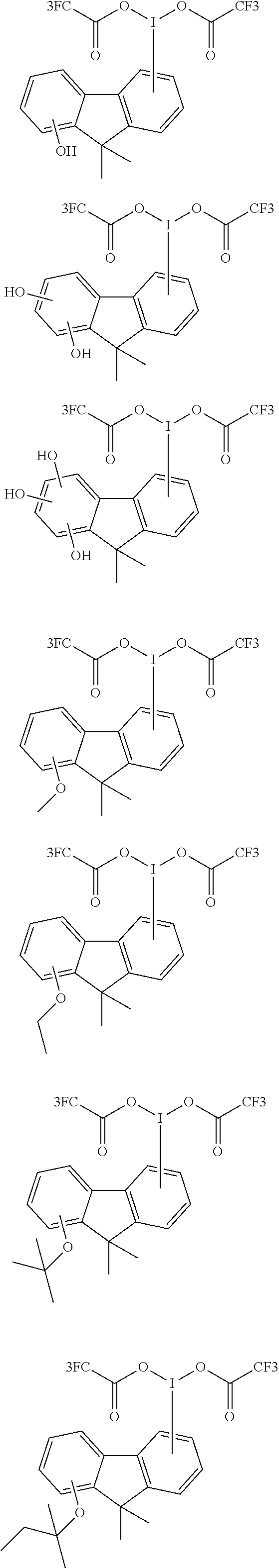

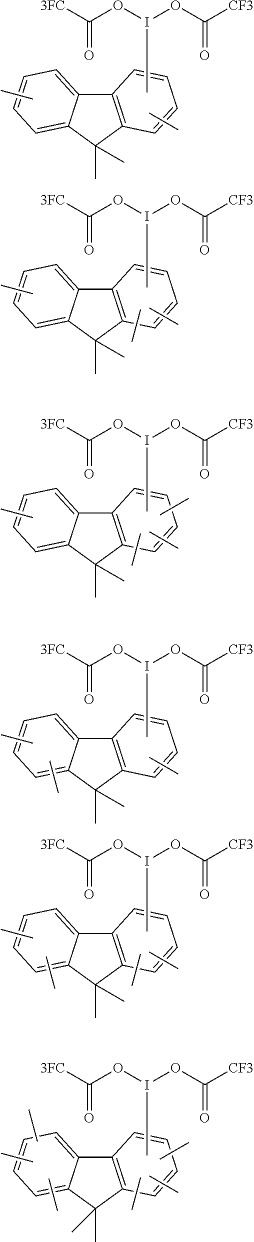

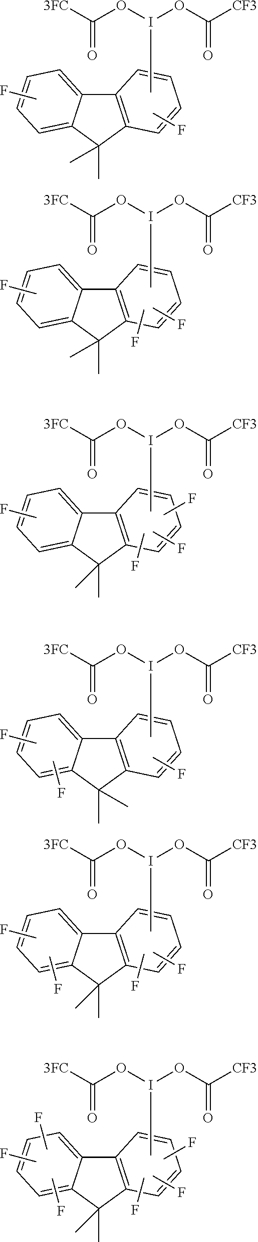

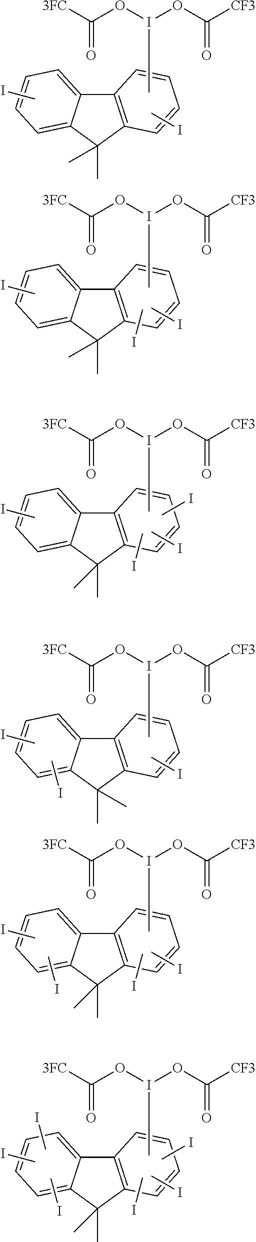

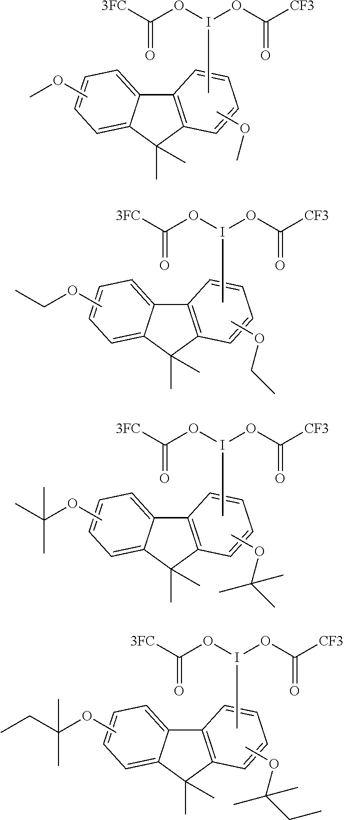

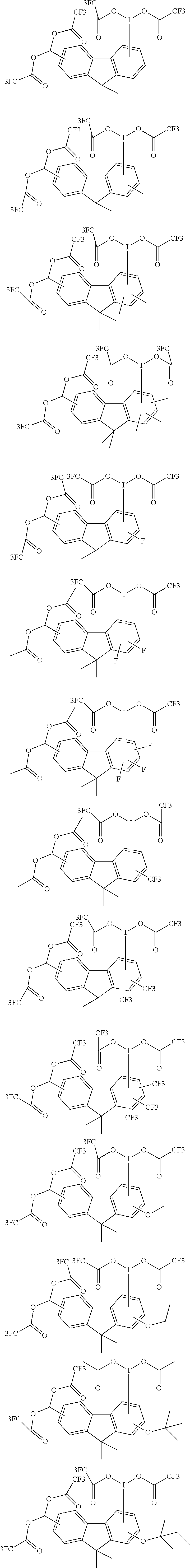

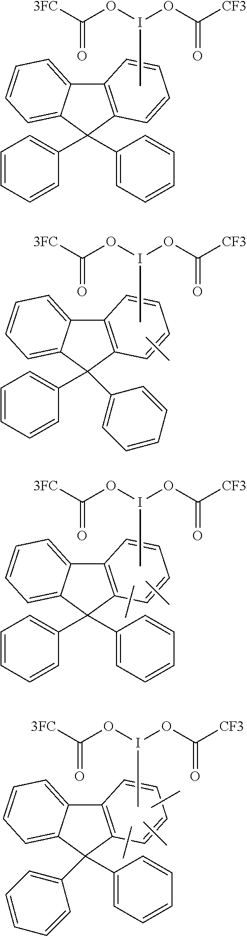

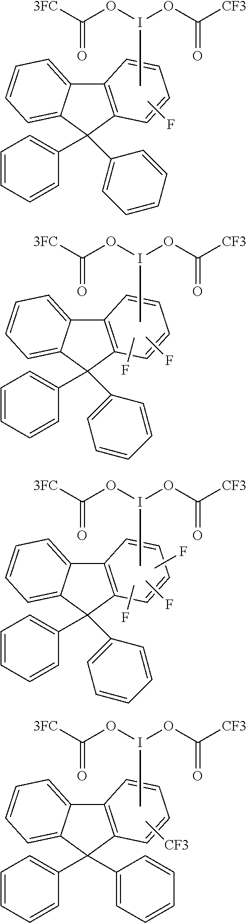

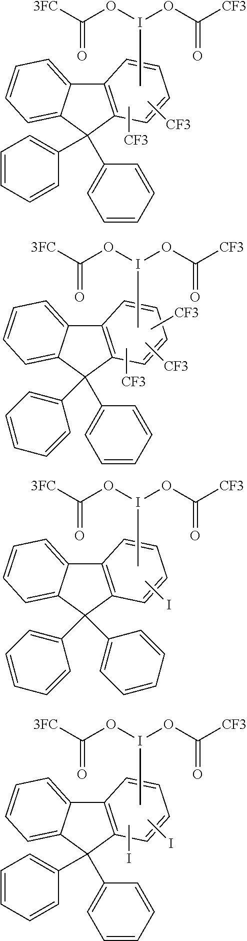

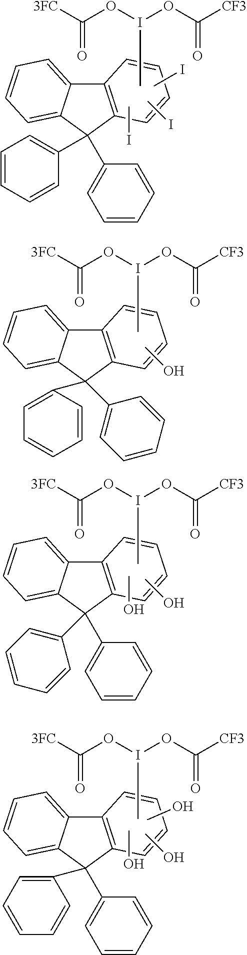

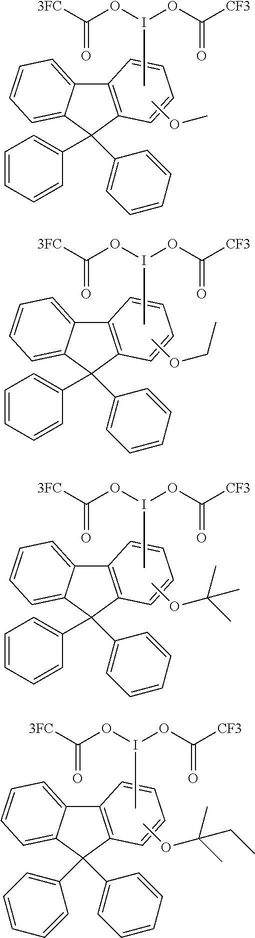

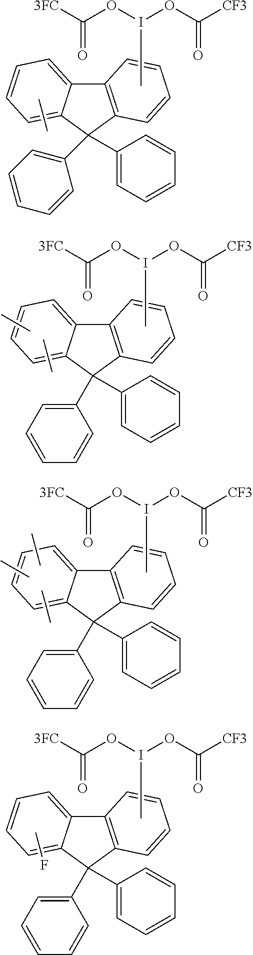

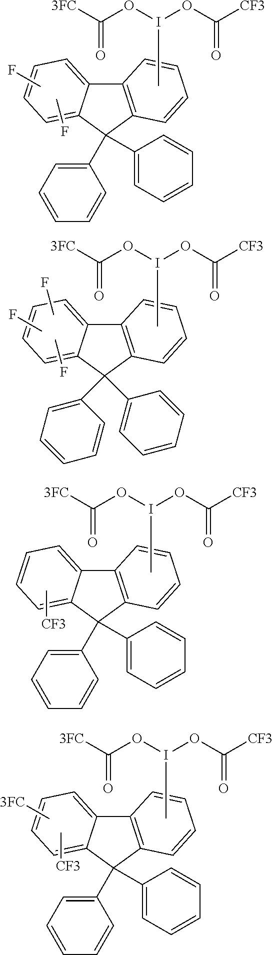

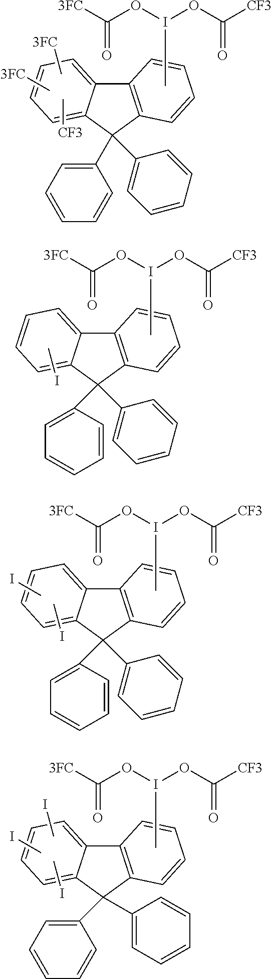

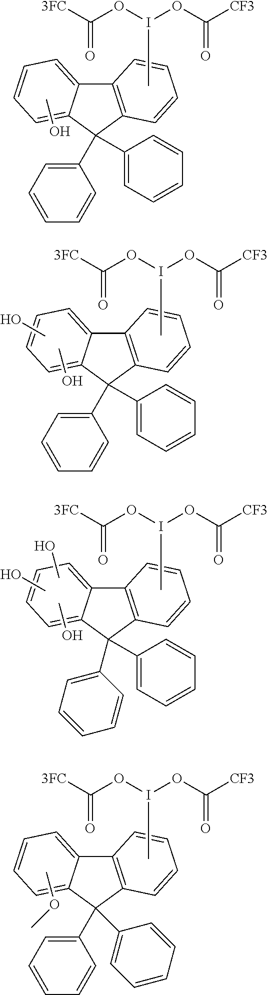

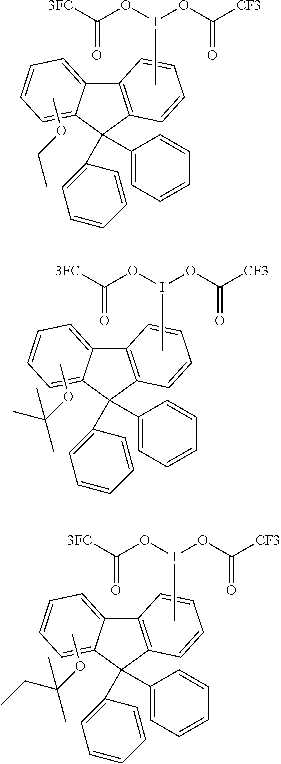

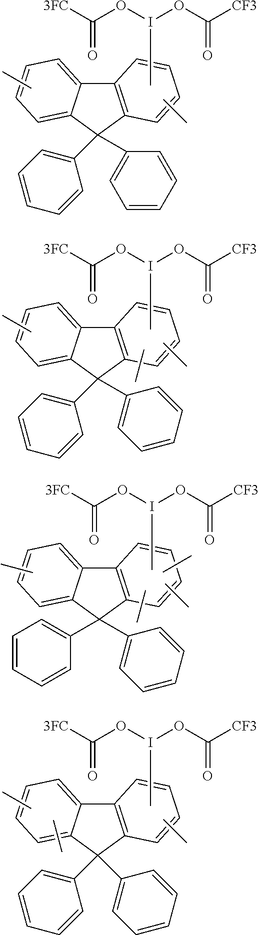

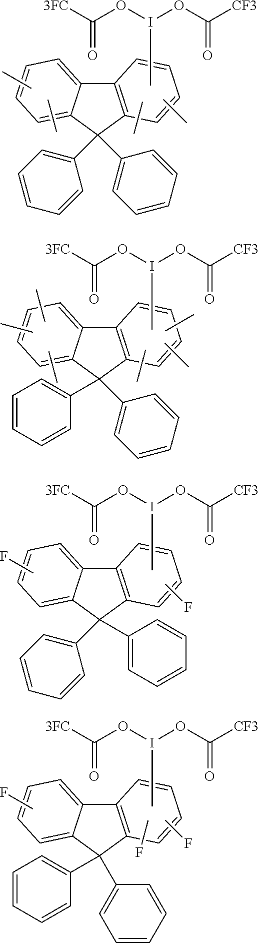

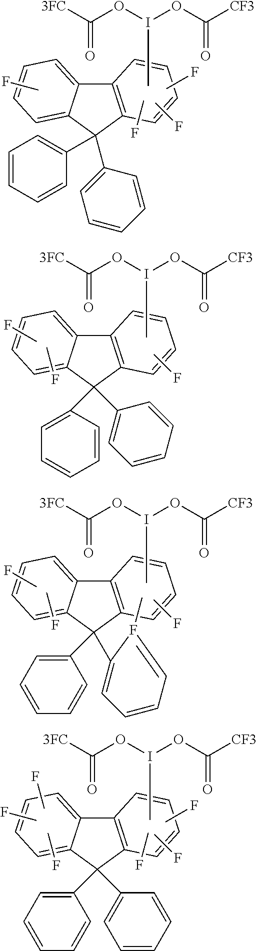

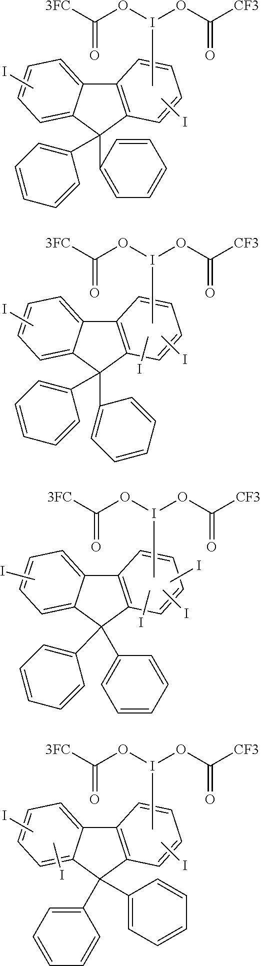

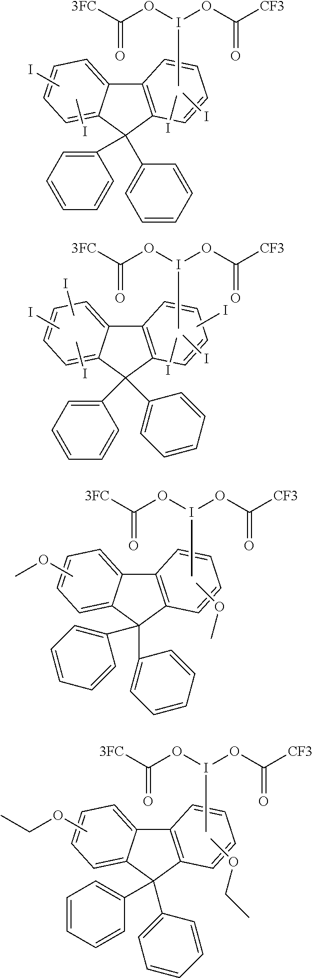

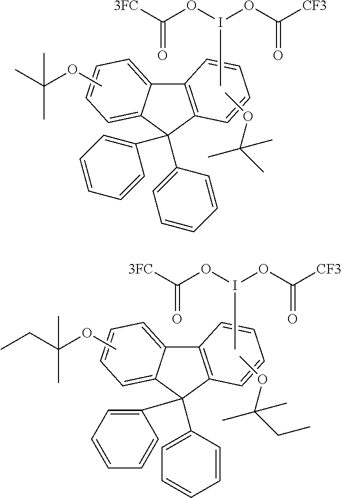

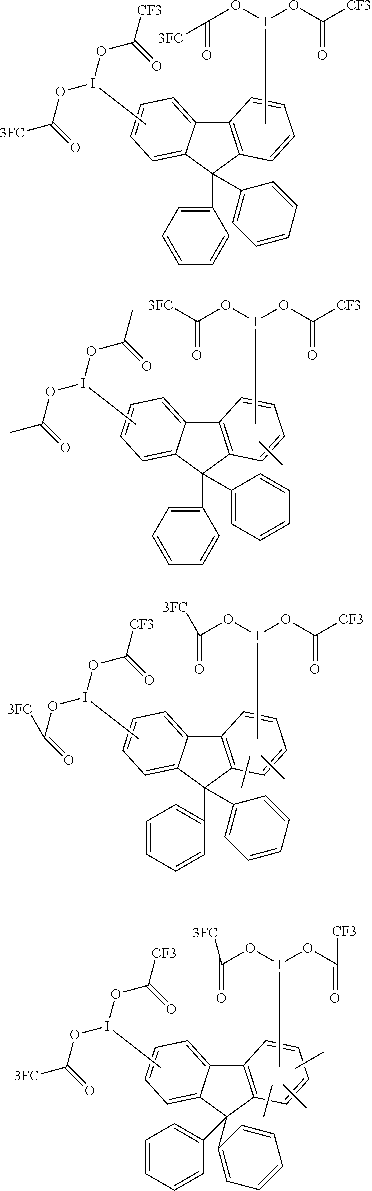

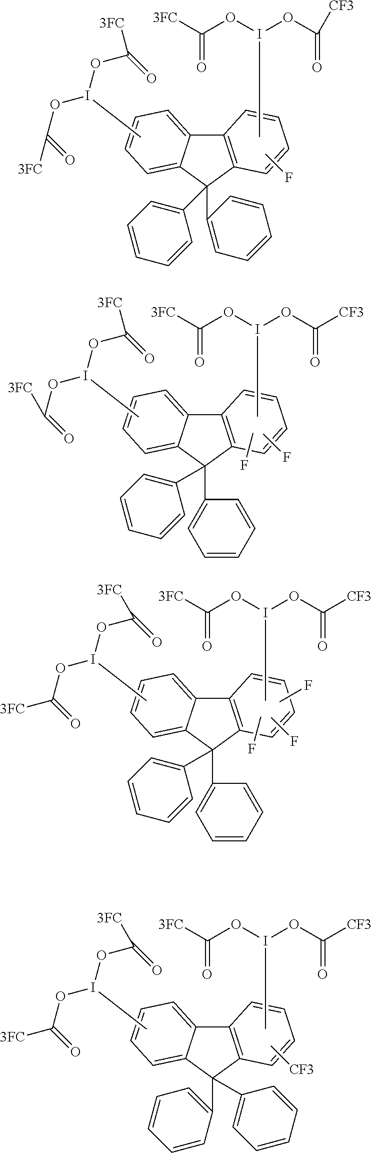

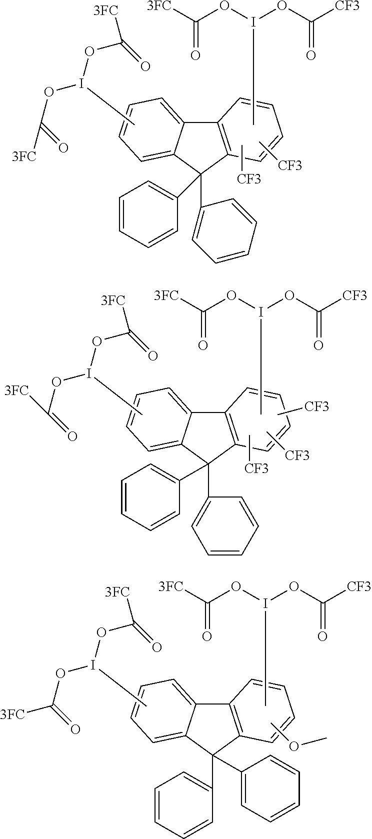

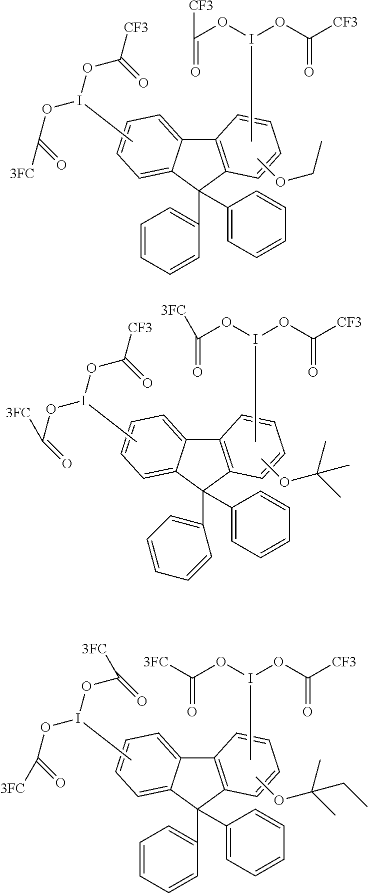

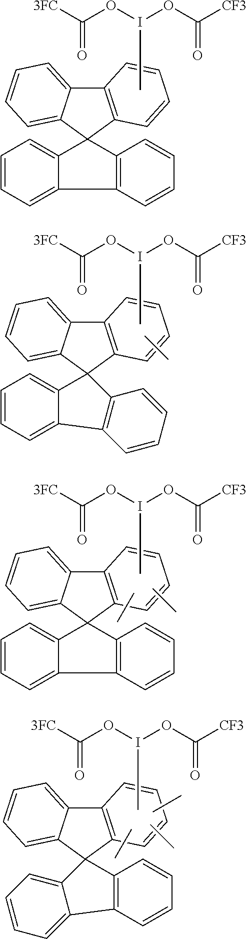

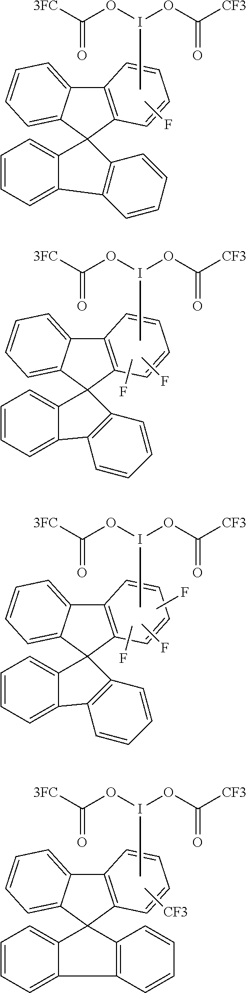

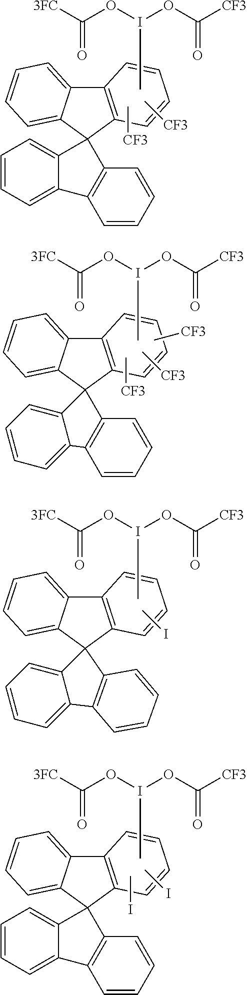

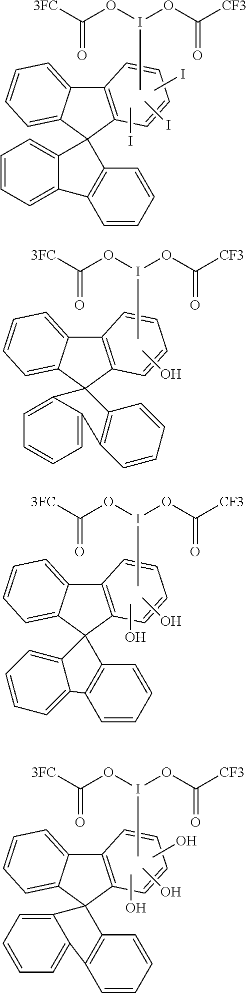

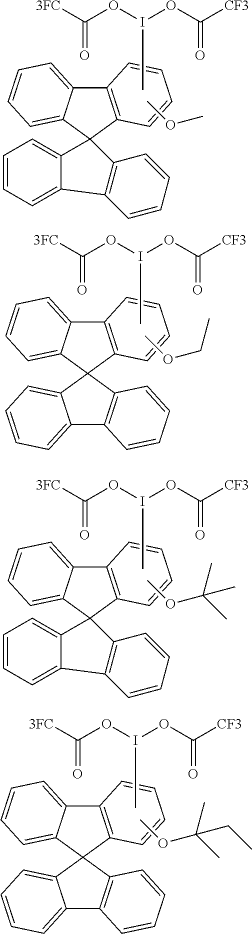

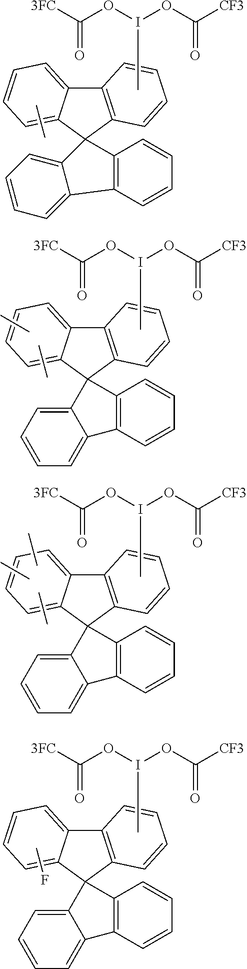

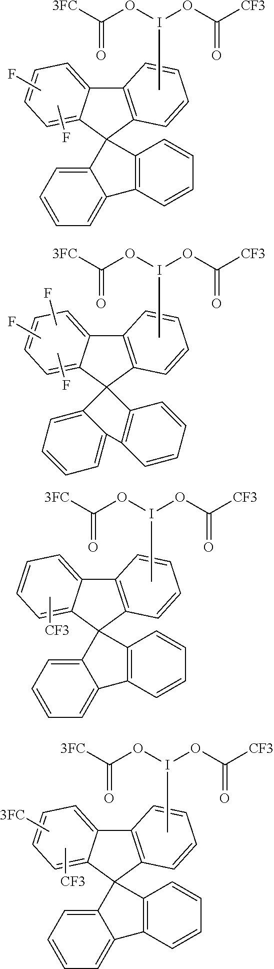

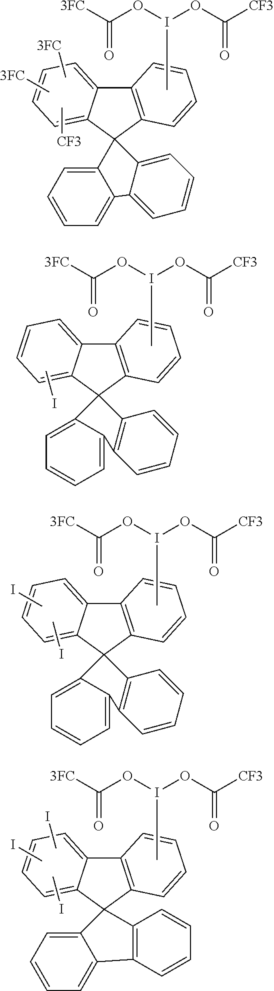

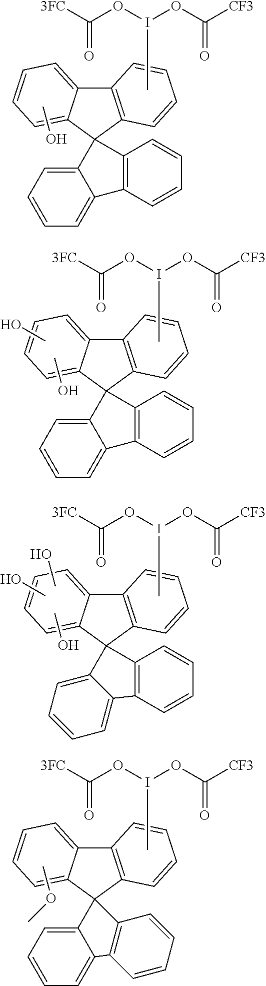

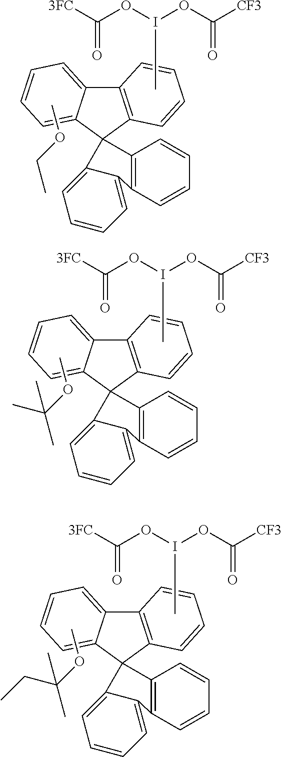

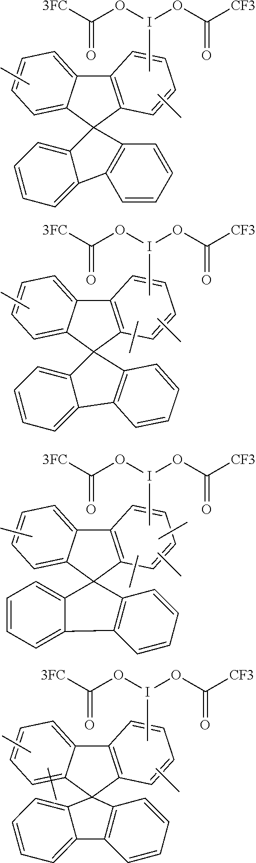

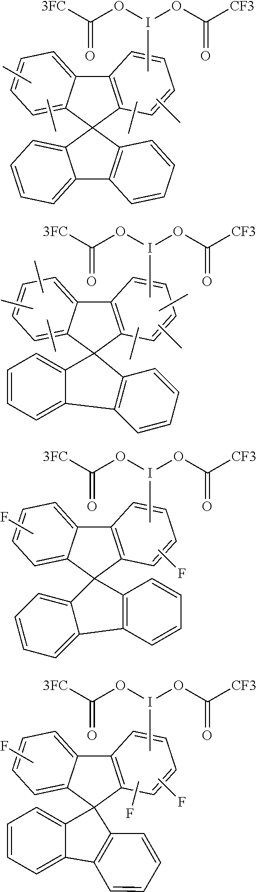

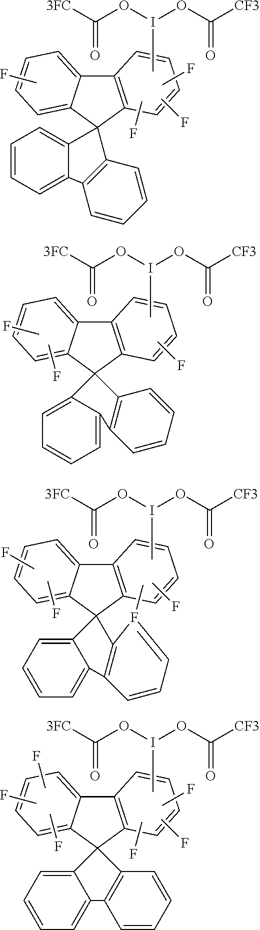

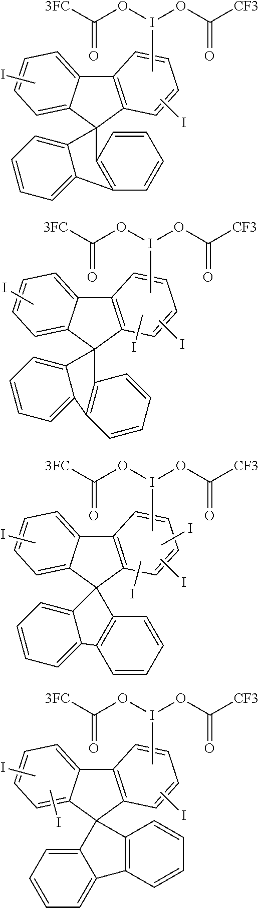

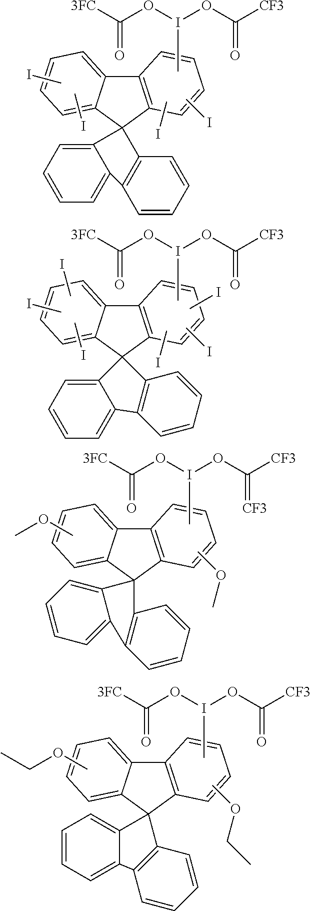

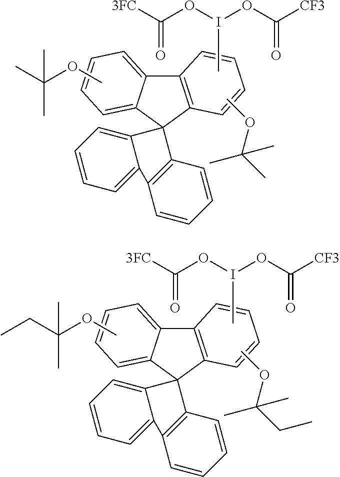

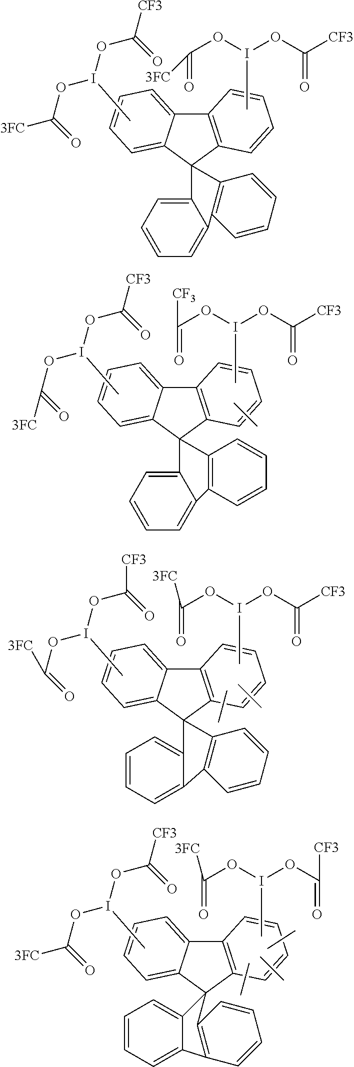

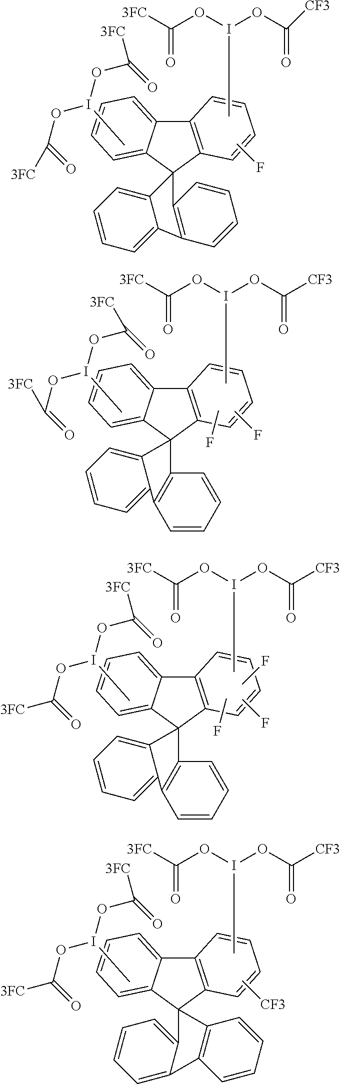

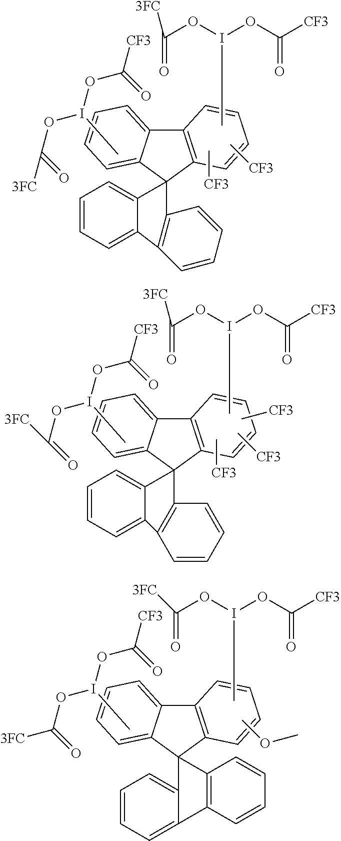

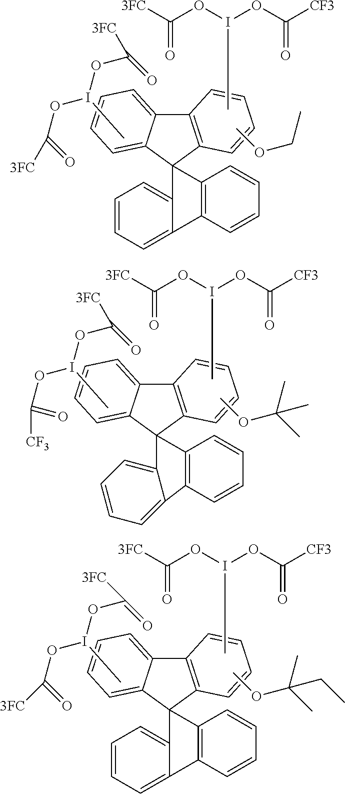

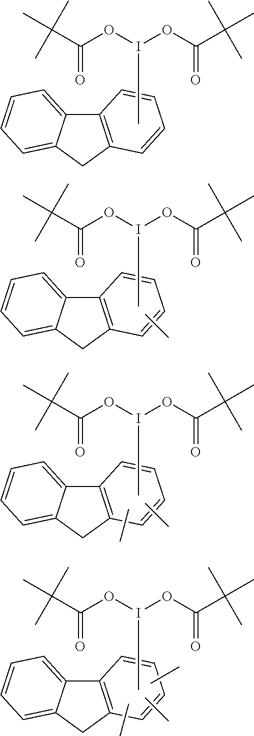

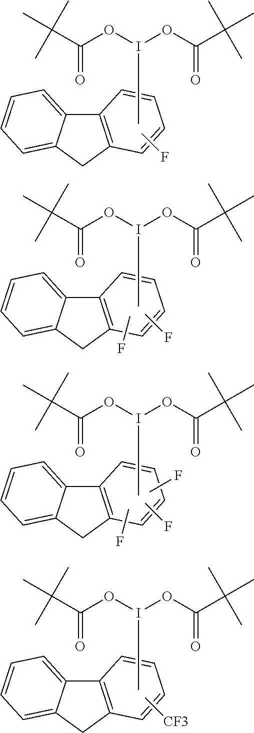

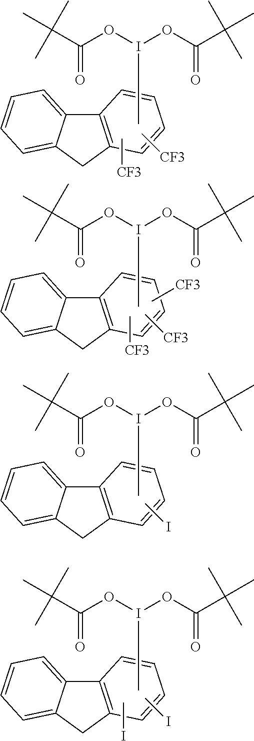

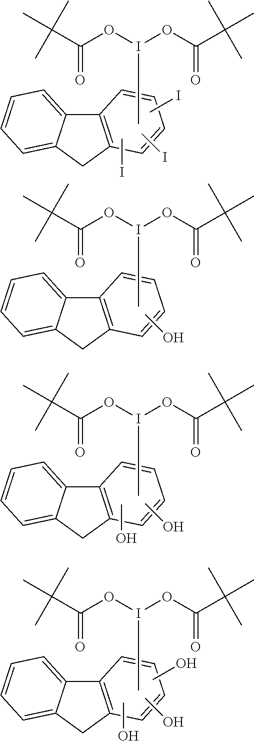

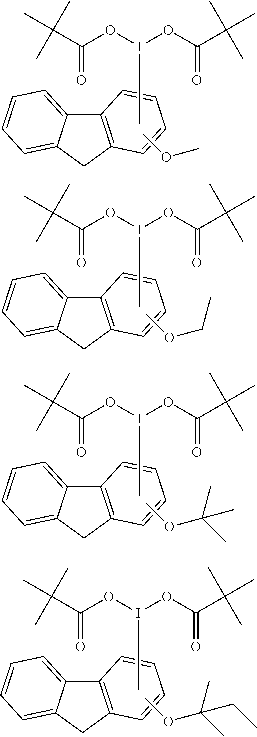

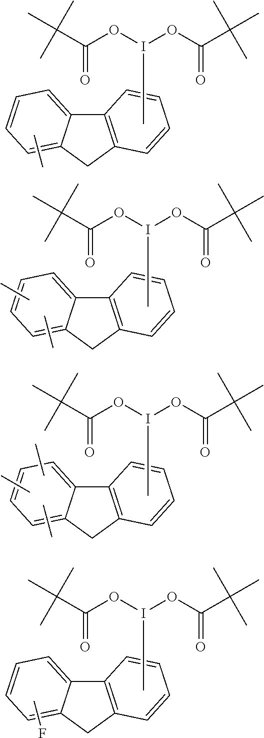

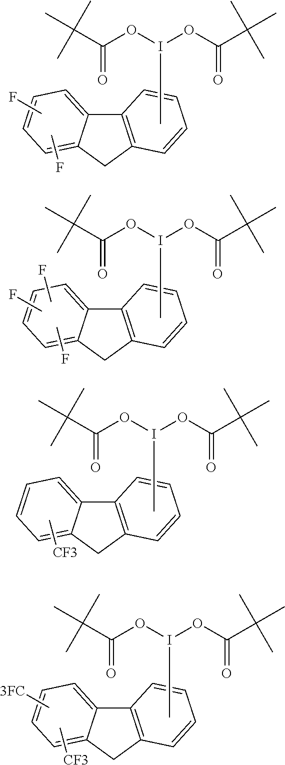

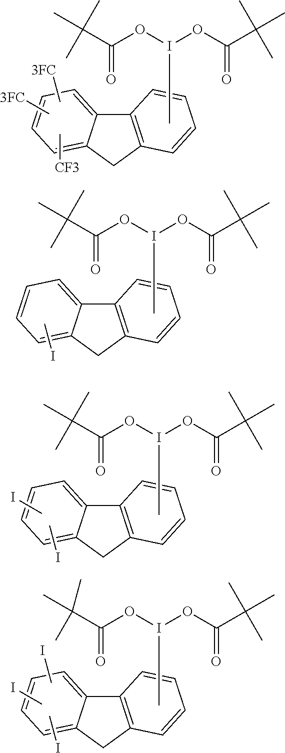

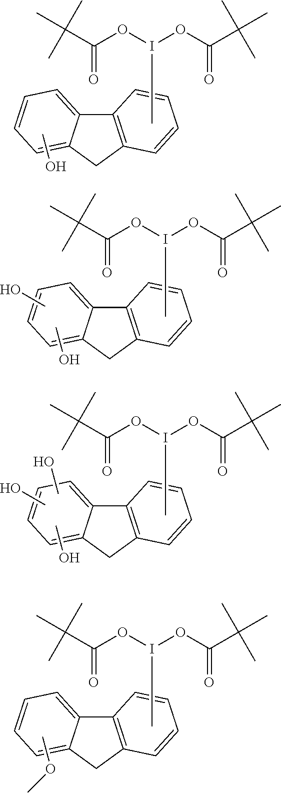

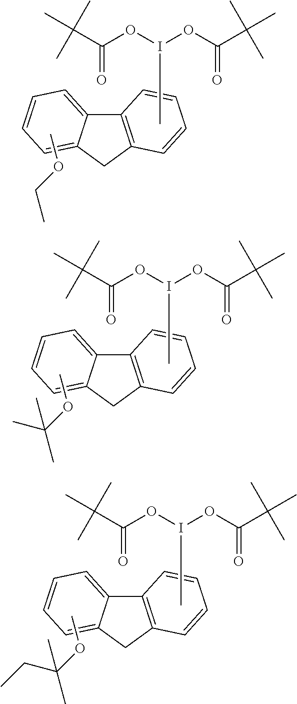

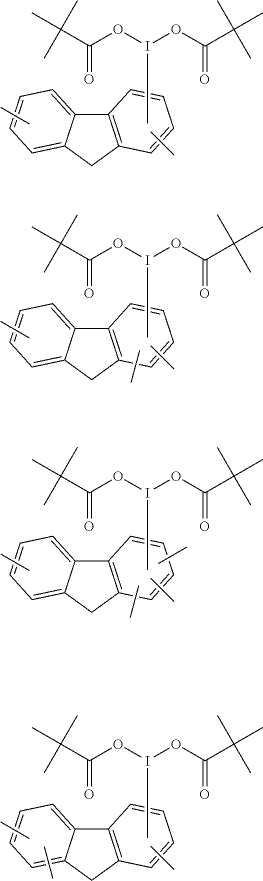

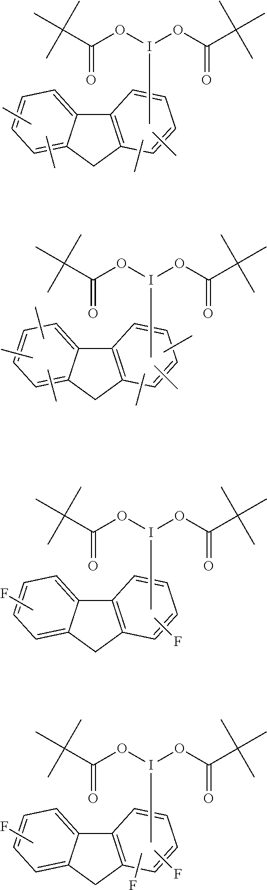

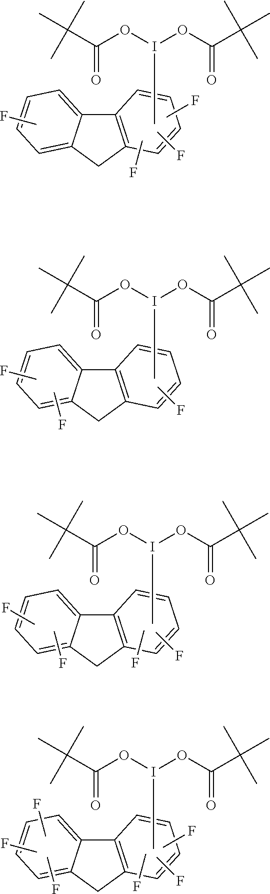

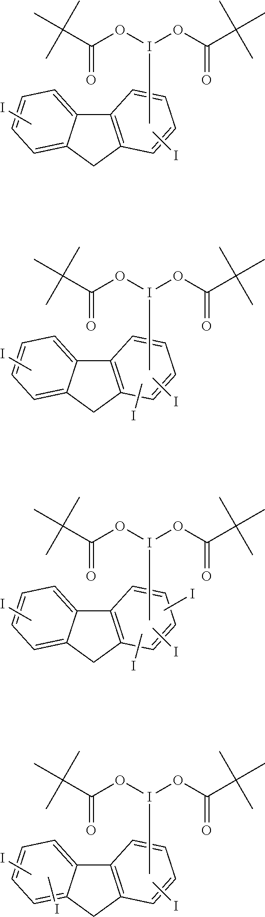

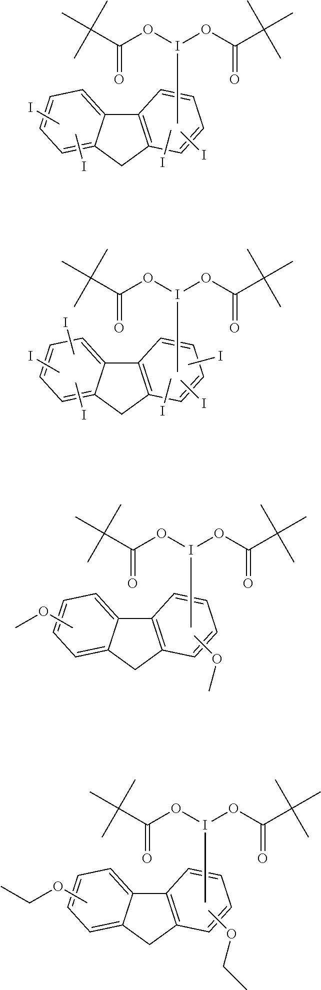

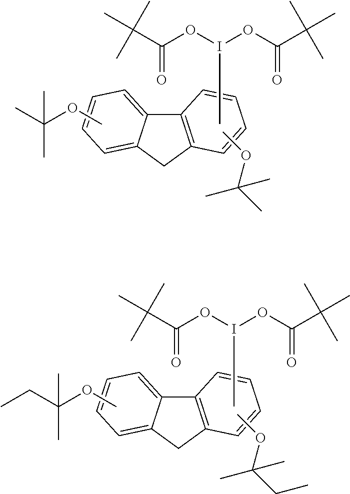

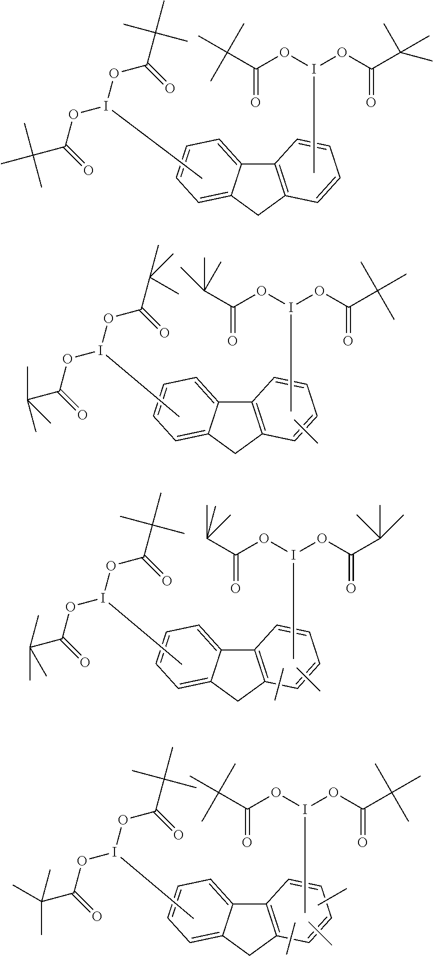

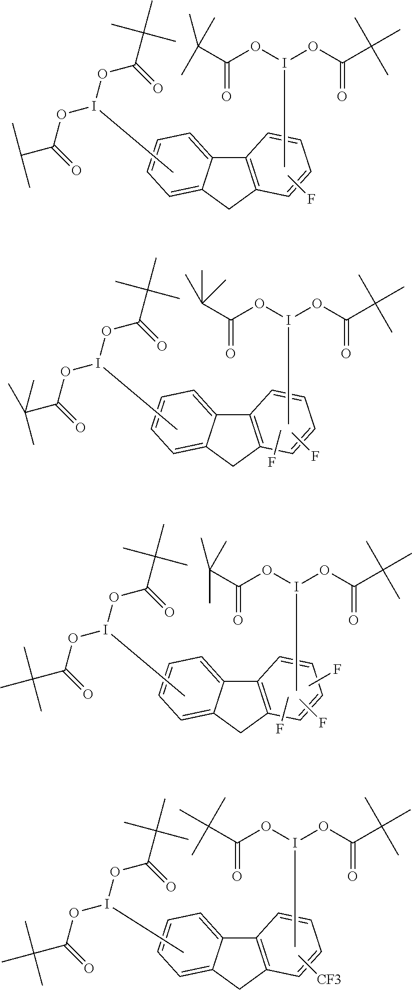

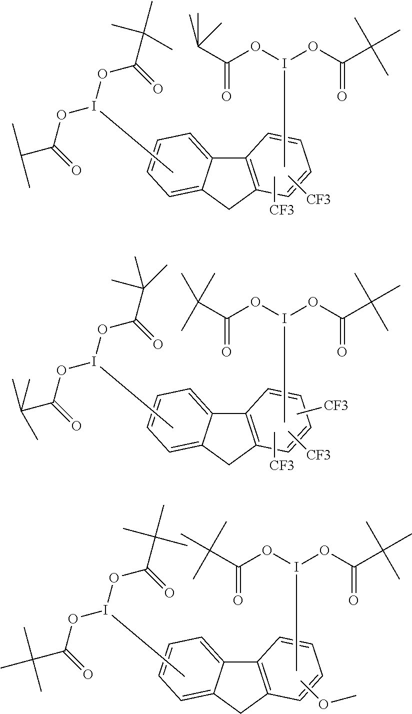

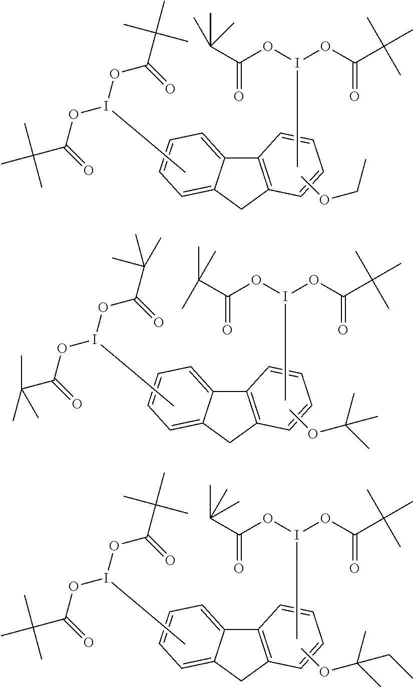

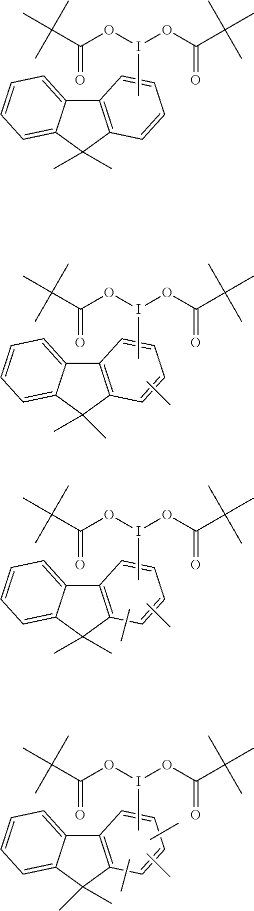

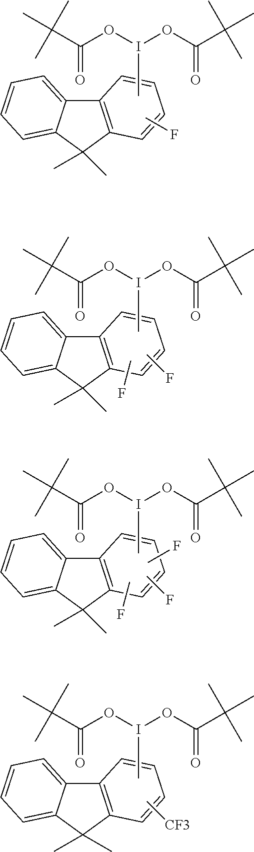

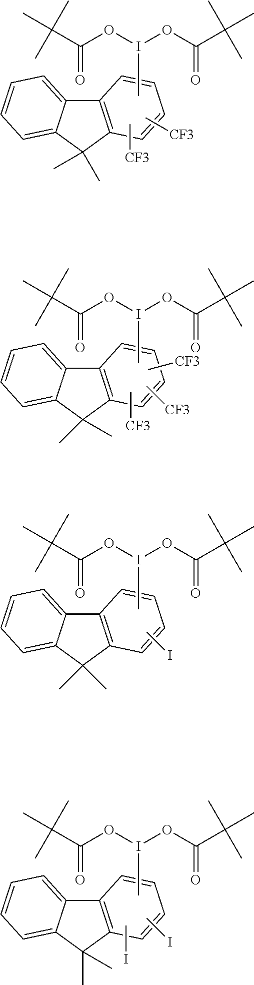

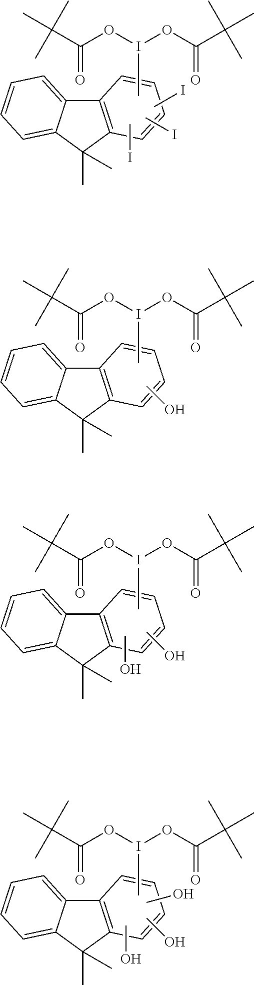

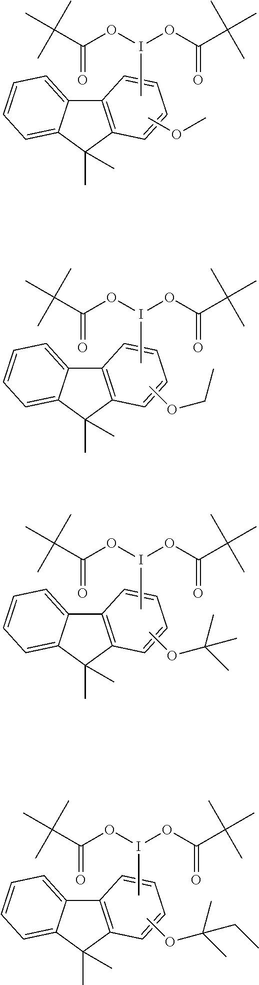

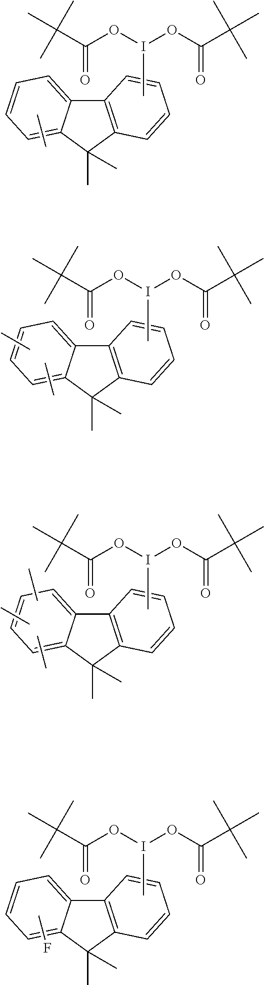

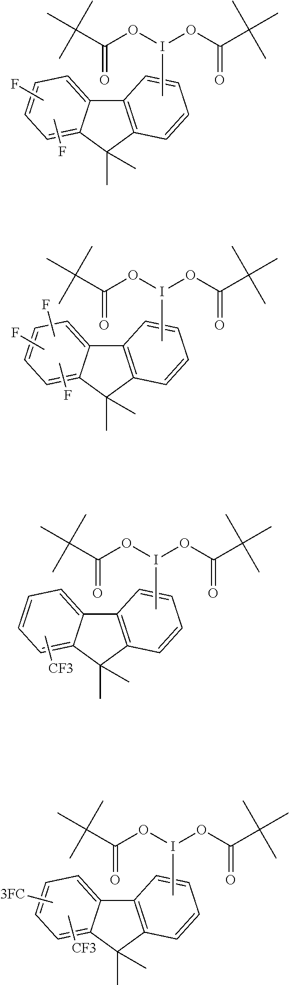

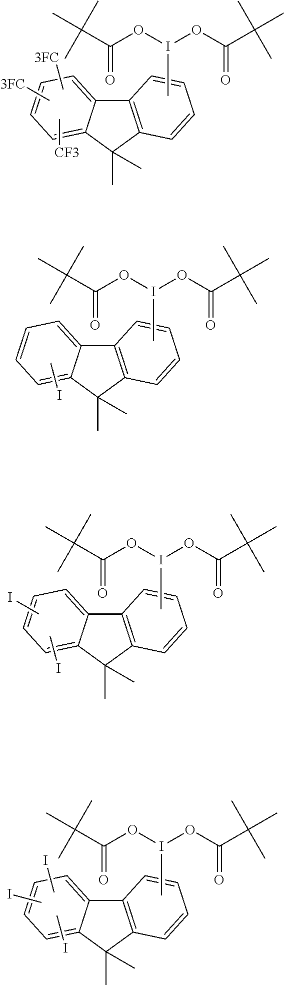

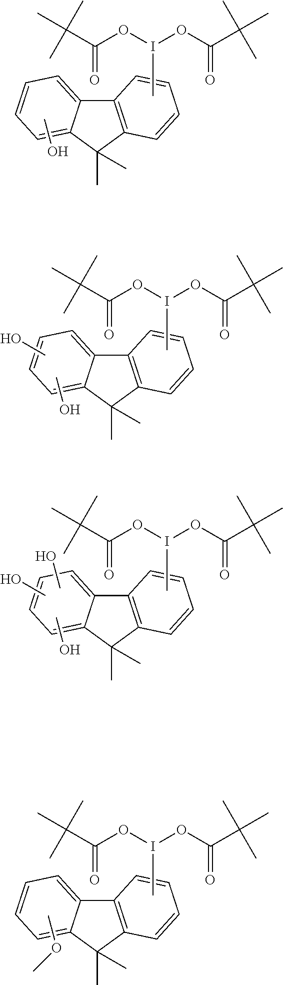

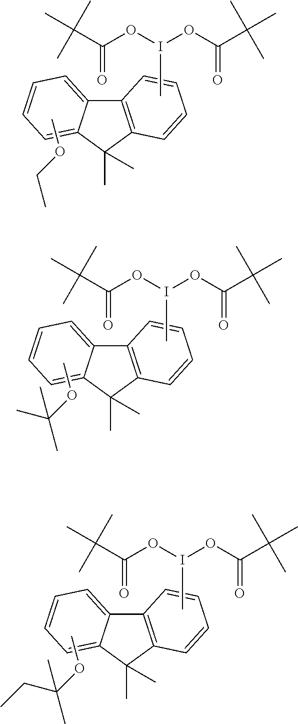

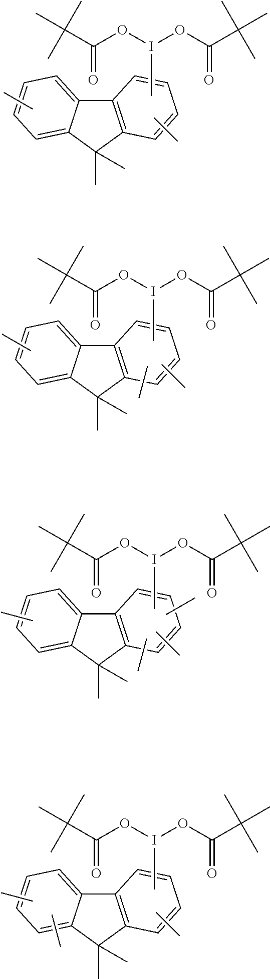

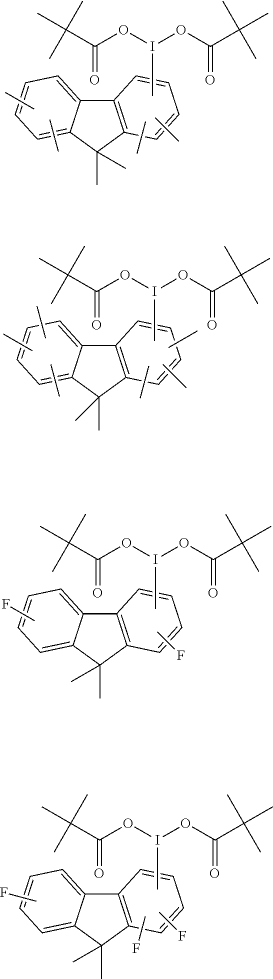

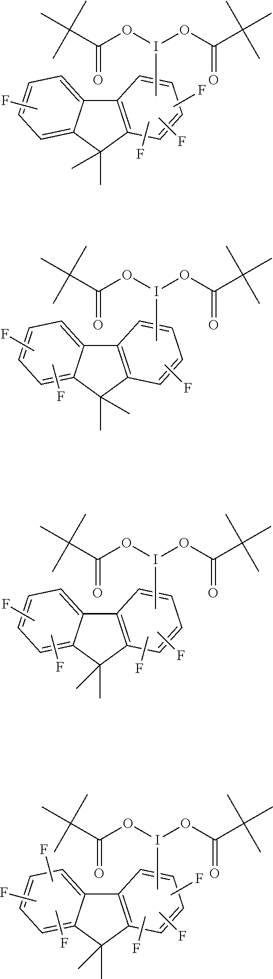

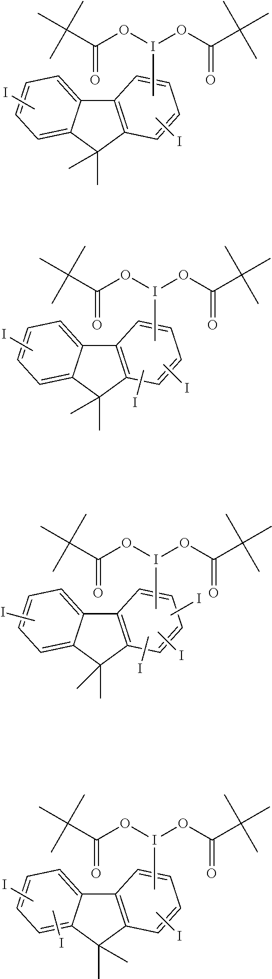

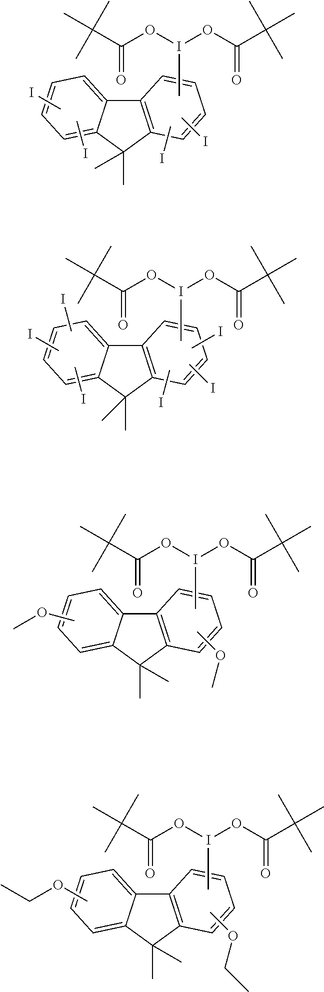

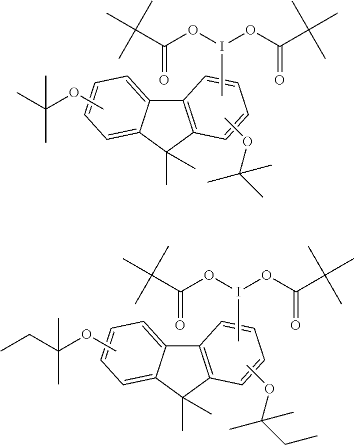

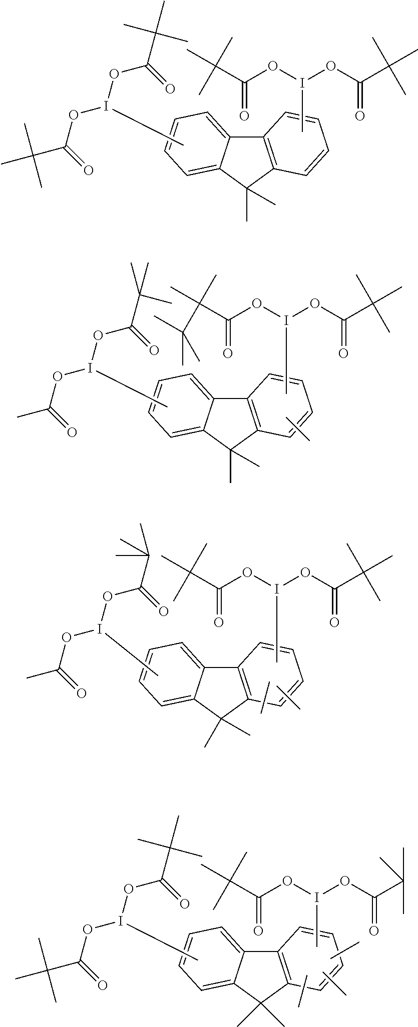

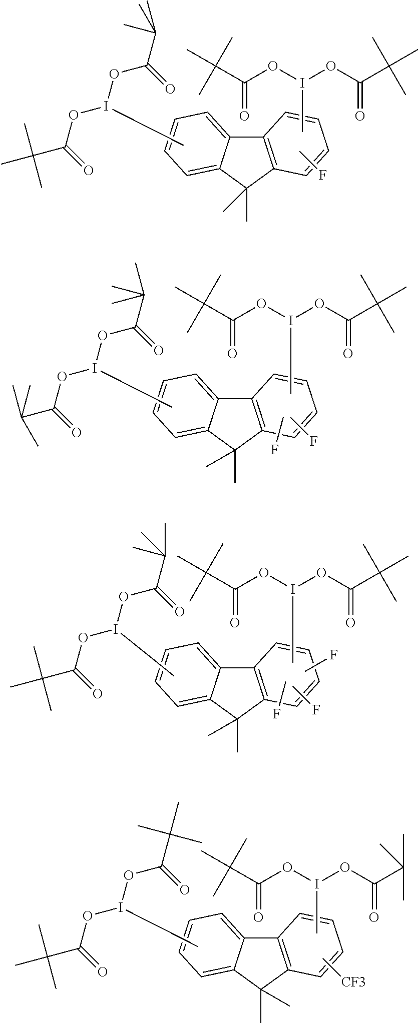

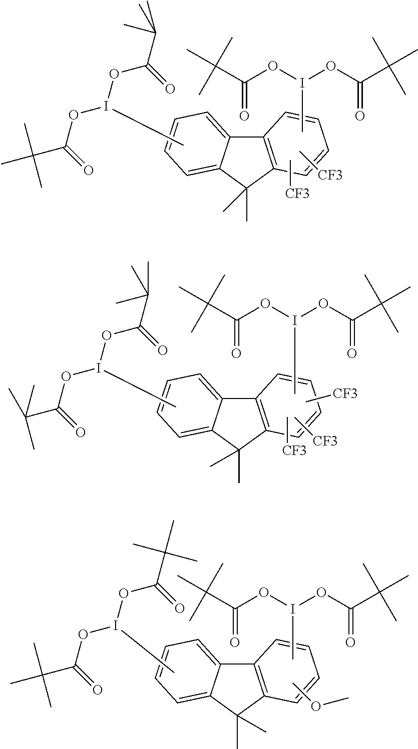

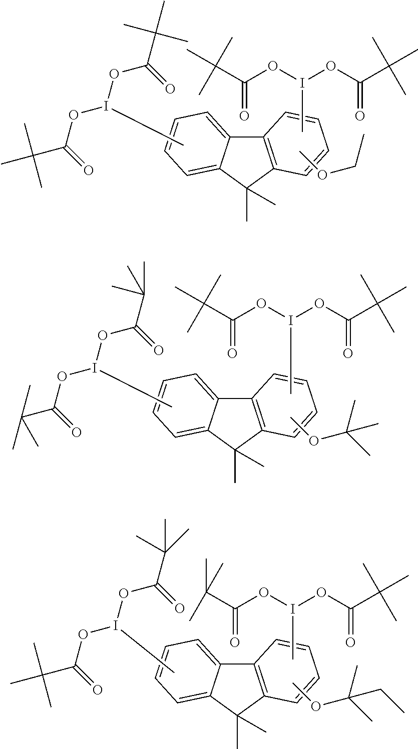

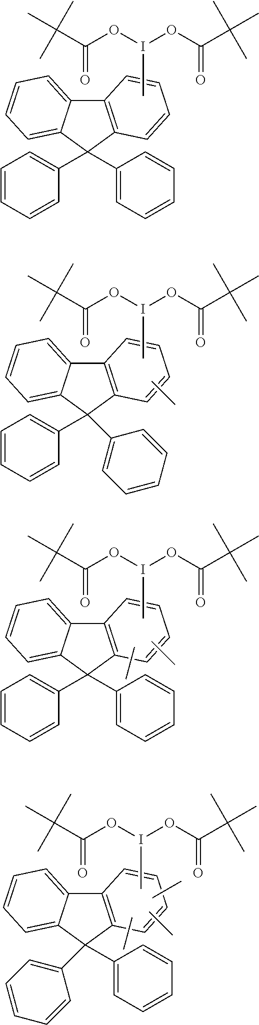

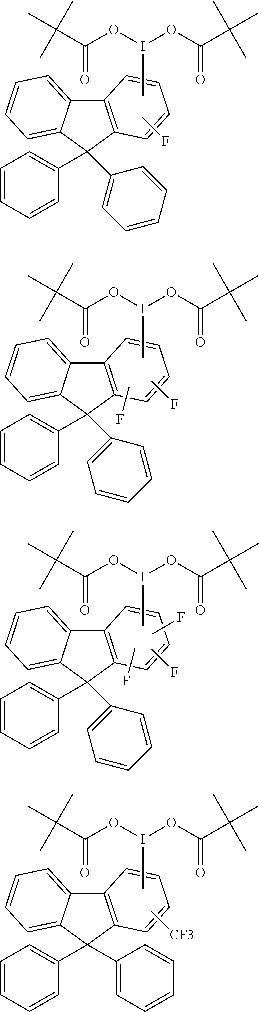

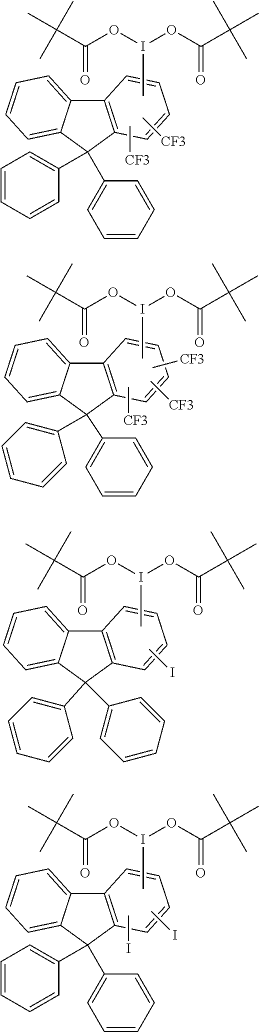

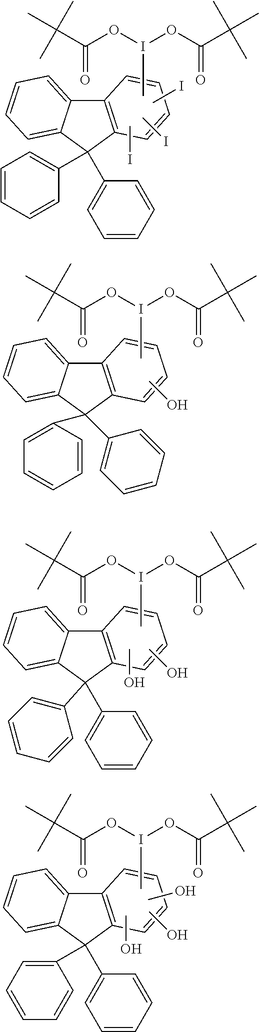

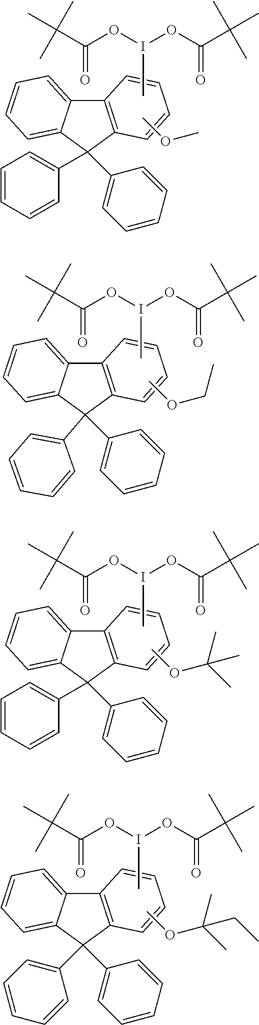

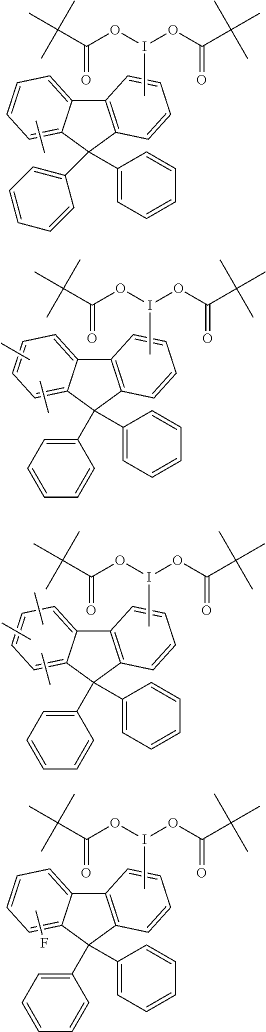

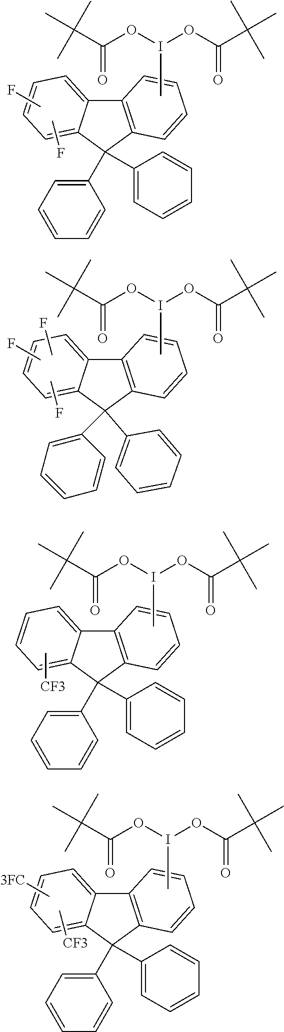

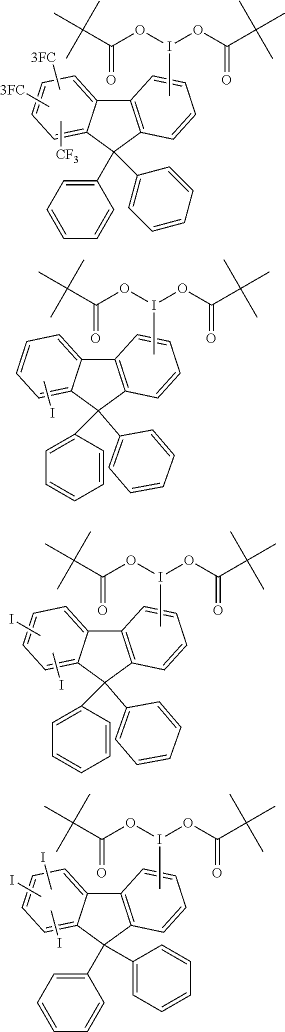

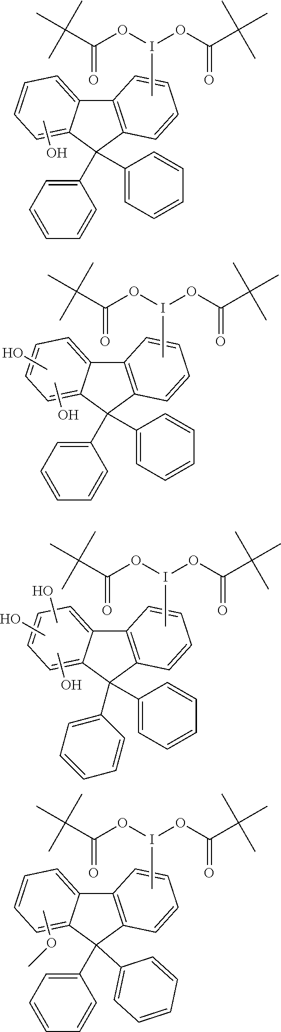

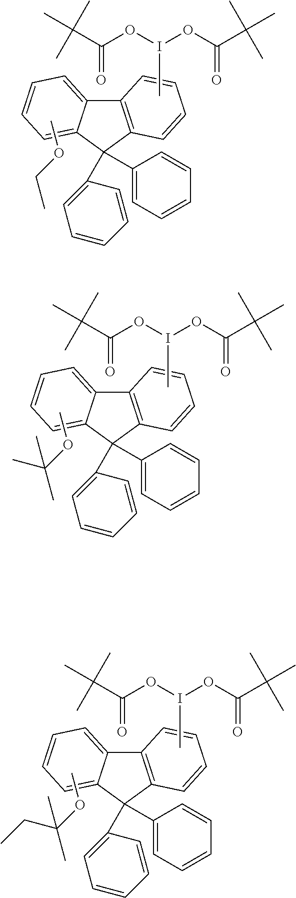

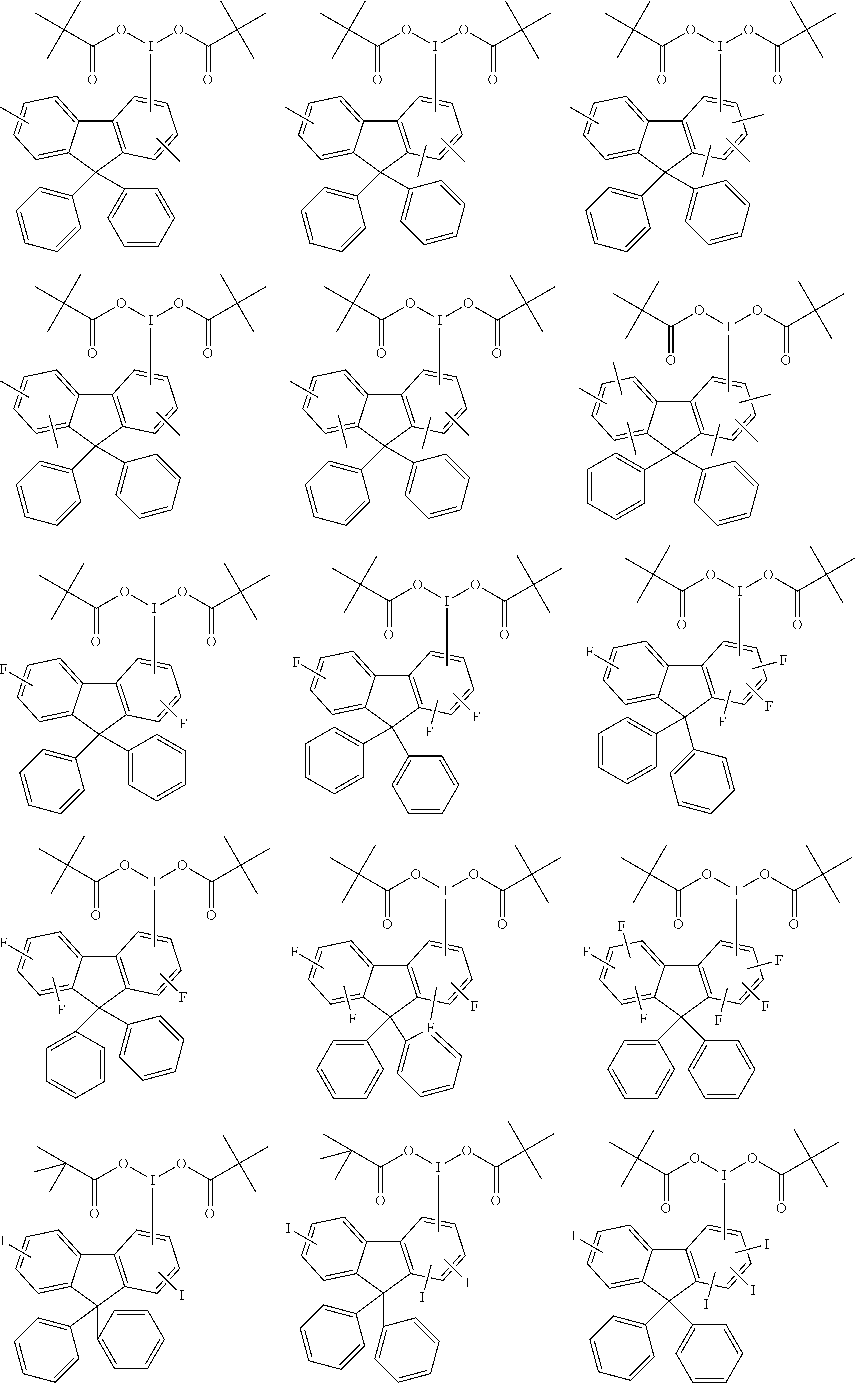

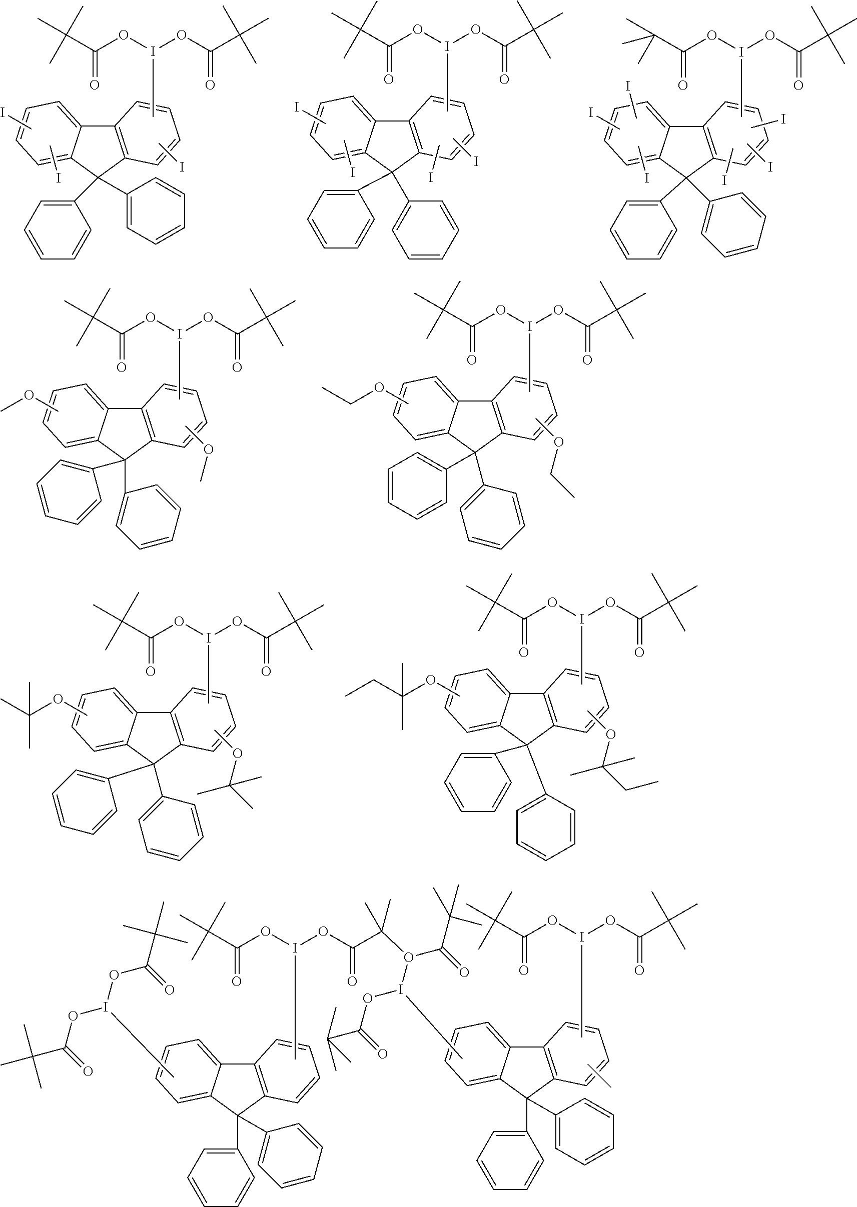

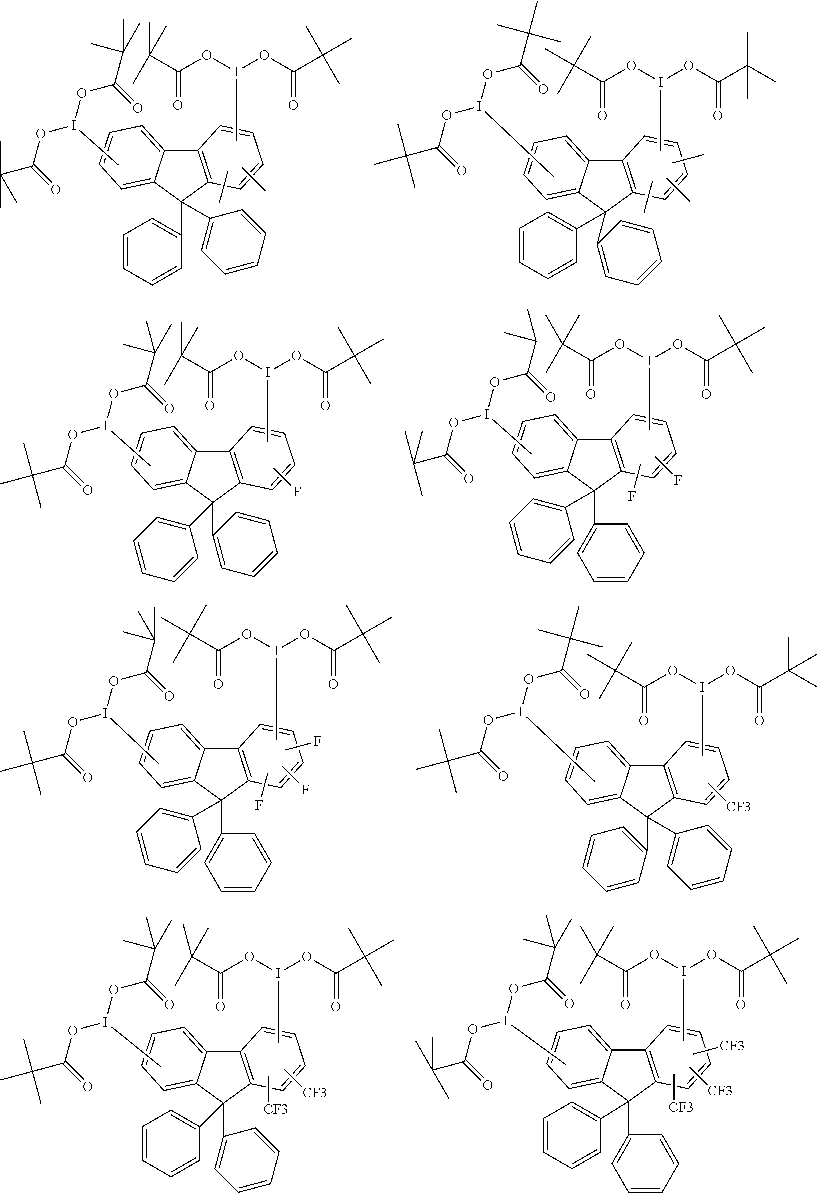

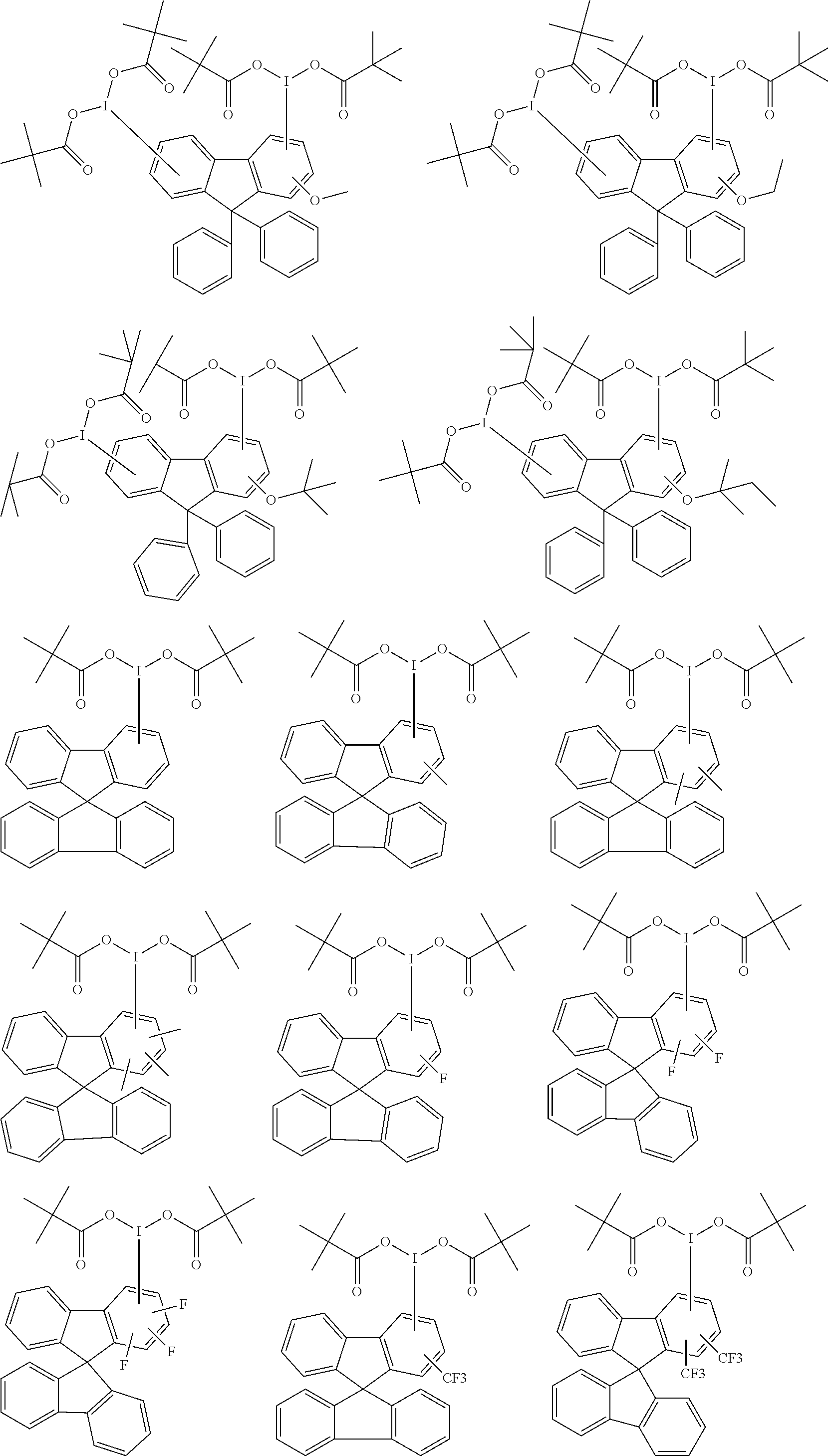

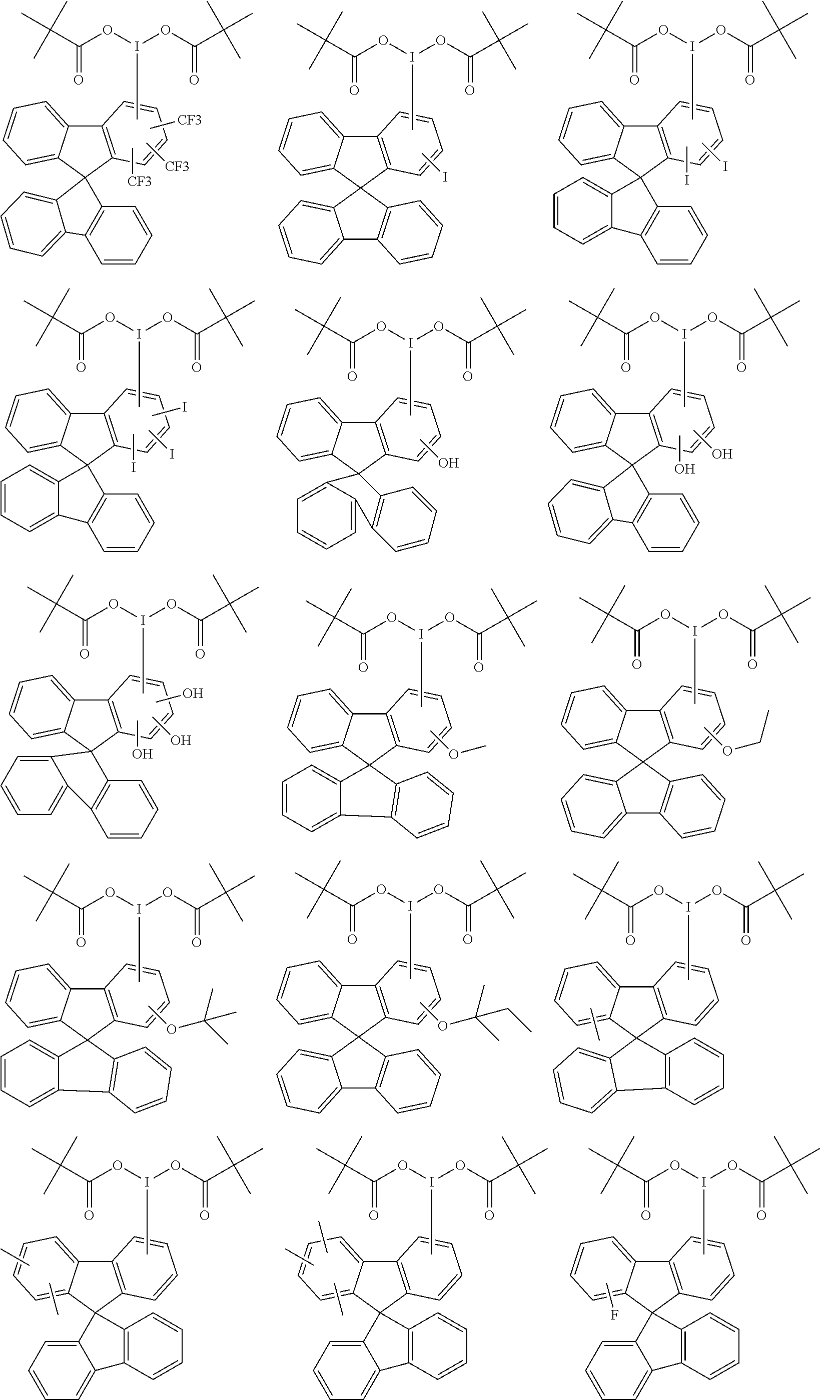

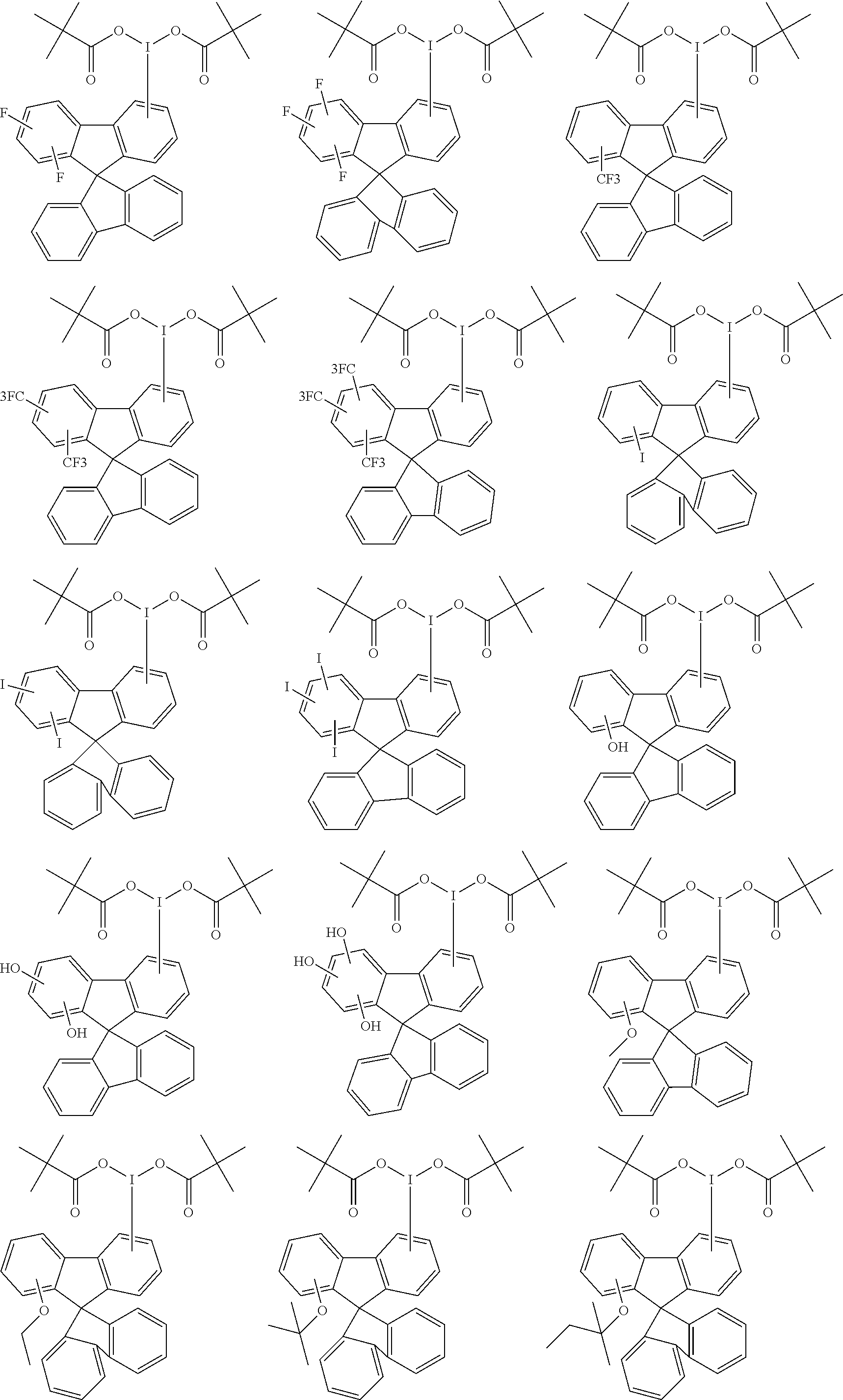

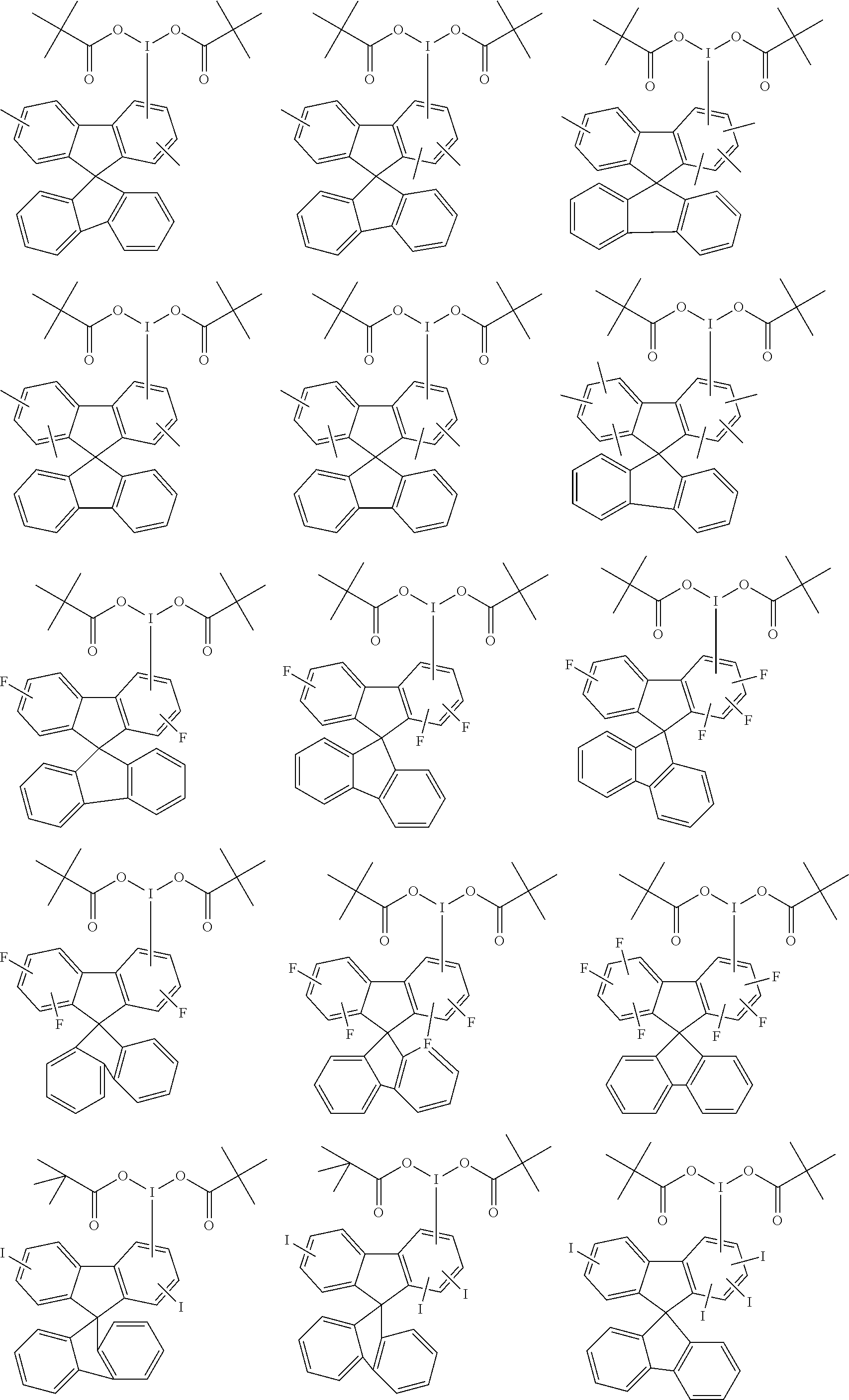

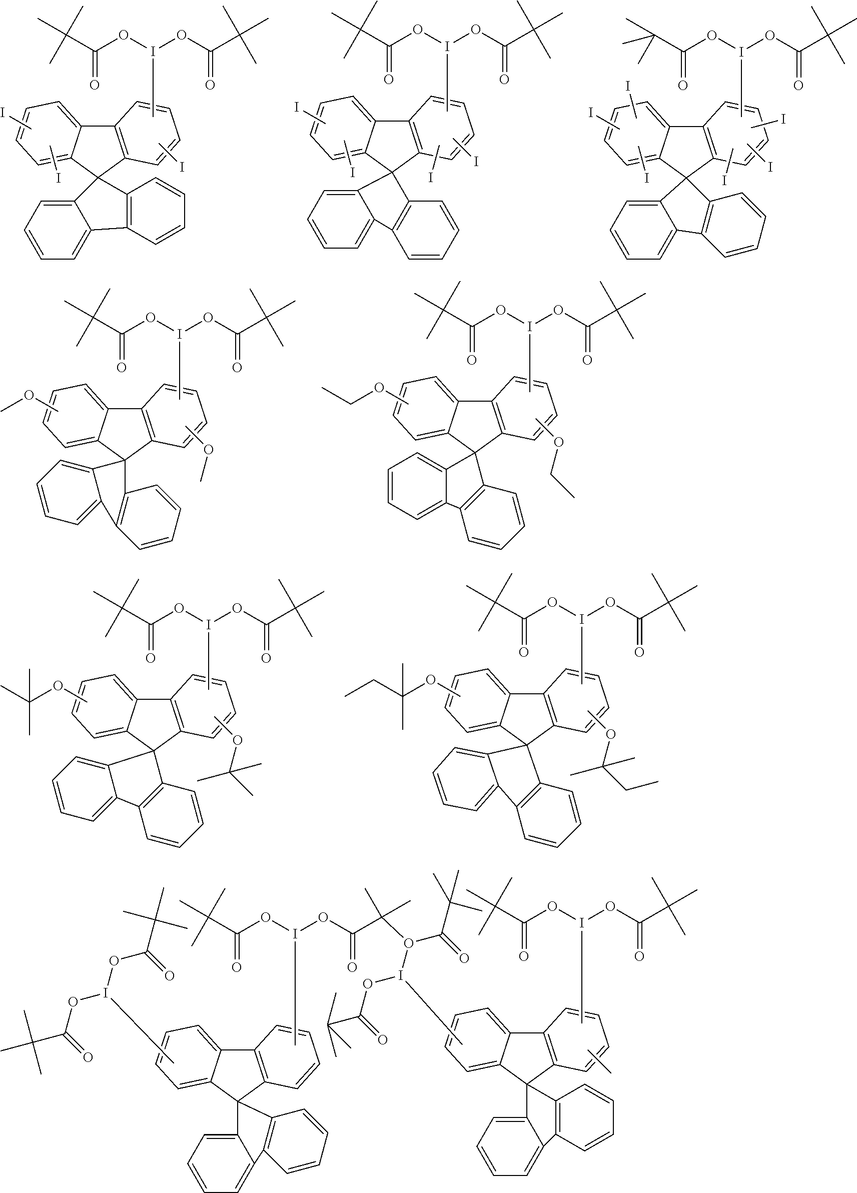

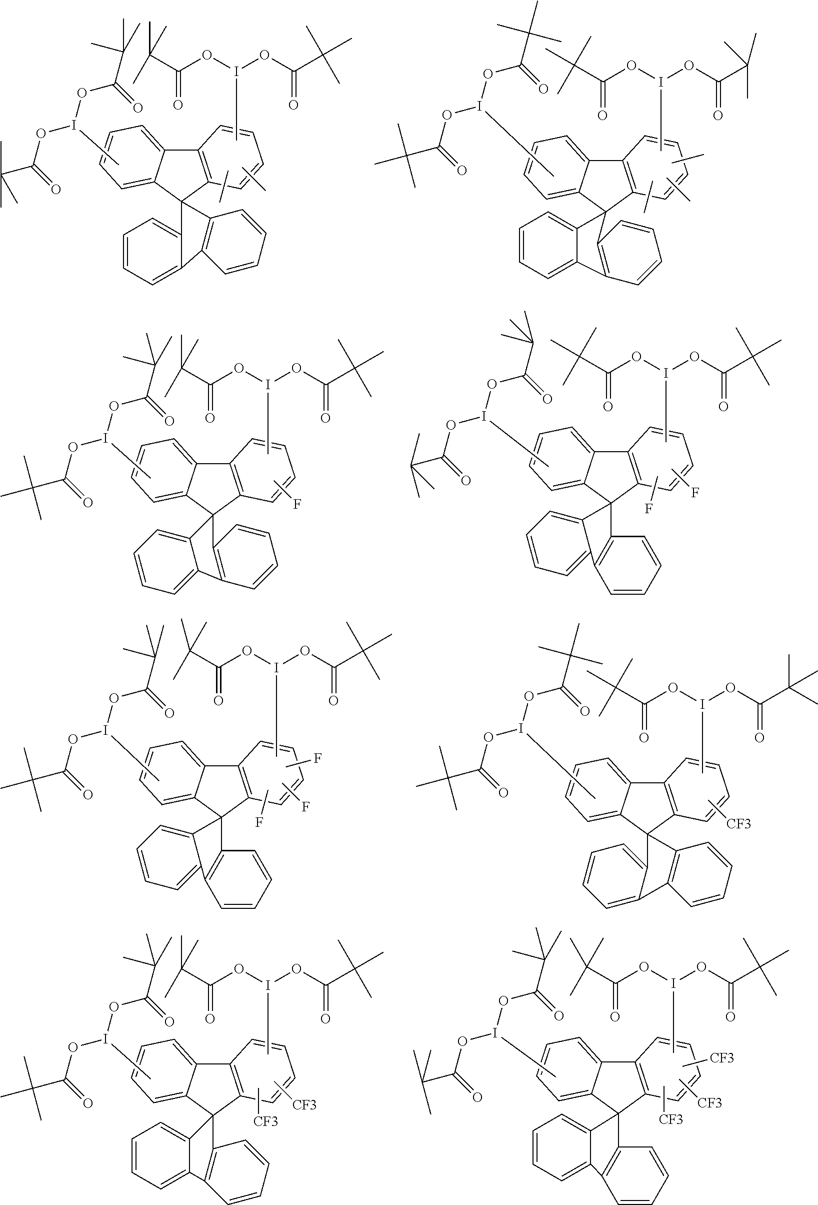

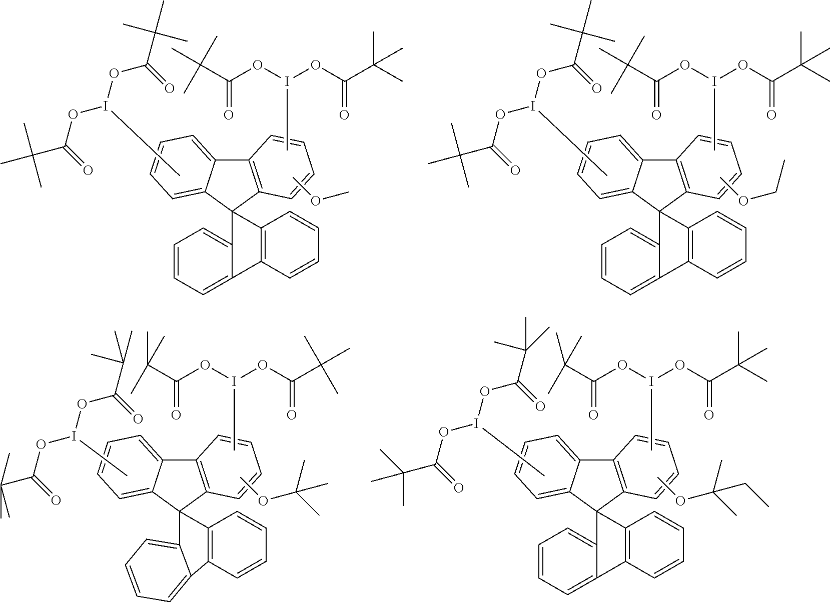

### [Carboxy-Group-Containing Polymer]

The carboxy-group-containing polymer of the present invention includes a repeating unit of a carboxylic acid derivative, represented by the following formula (1), and the polymer has a dispersity Mw/Mn of 1.30 or less, where Mw is a weight-average molecular weight and Mn is a number-average molecular weight measured by GPC. The theoretical lower limit of the dispersity is 1, and the closer the dispersity is to 1, the more monodisperse.

In the present invention, to obtain a non-chemically amplified resist composition excellent in sensitivity and limiting resolution, it is important that the dispersity Mw/Mn be narrow and 1.30 or less. If the dispersity exceeds 1.30, the molecular weight distribution of the polymer is widened, and if the polymer is used for a resist, roughness is increased and solubility becomes ununiform due to the broad molecular weight. Therefore, the polymer swells easily, and there are risks that pattern collapse of a line-and-space pattern, blocking of the space between patterns in a contact hole pattern, etc. may occur. The dispersity Mw/Mn is preferably 1.0 to 1.30, more preferably 1.0 to 1.1.

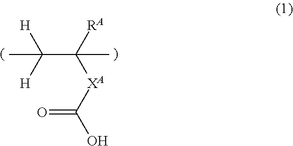

R^{A} represents a hydrogen atom, a halogen atom, a methyl group, or a trifluoromethyl group; X^{A} represents a single bond, a phenylene group, a naphthylene group, or *—C(═O)—O—X^{A1}—; X^{A1} represents a saturated hydrocarbylene group having 1 to 10 carbon atoms, a phenylene group, or a naphthylene group, the saturated hydrocarbylene group optionally containing a hydroxy group, an ether bond, an ester bond, or a lactone ring; and “*” represents an attachment point to the carbon atom of the polymer main chain.

Note that, in the present invention, Mw and Mn are values measured in terms of standard polystyrene by gel permeation chromatography (GPC) using tetrahydrofuran (THF) as an eluent. A person skilled in the art knows that GPC (also called Size Exclusion Chromatography (SEC)) can be used in measuring the molecular weight distribution (dispersity) of a polymer, and knows a method for calibrating GPC and what column, detector, temperature setting, etc. should be applied to measure Mw and Mn in a highly reliable manner for suitable for the carboxy-group-containing polymer in the present invention. Thus, the dispersity of the polymer can be calculated with excellent reproducibility within the range of normal error.

Specific examples of the carboxy-group-containing repeating unit represented by the formula (1) include the following, but are not limited thereto. Note that, in the following formulae, R^{A} is as defined above.

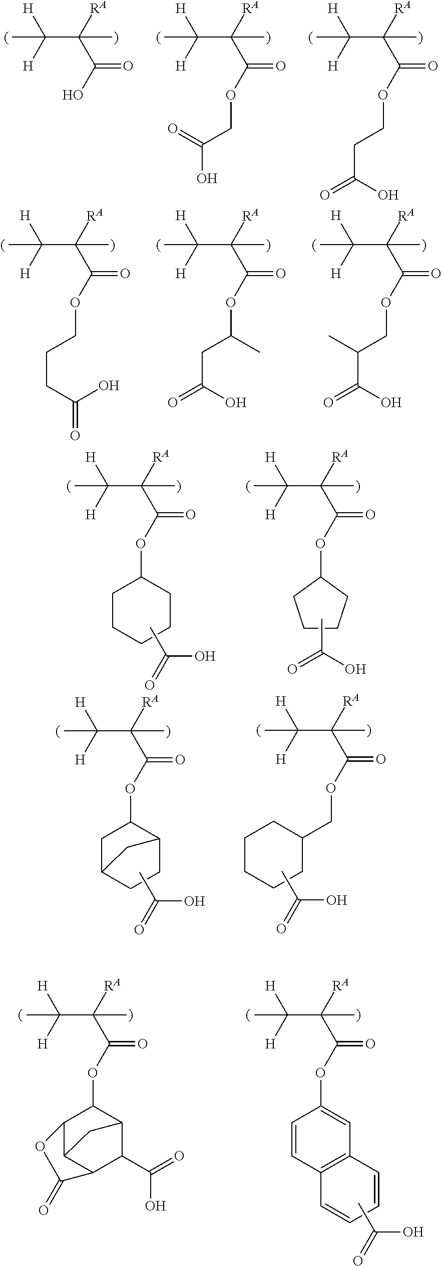

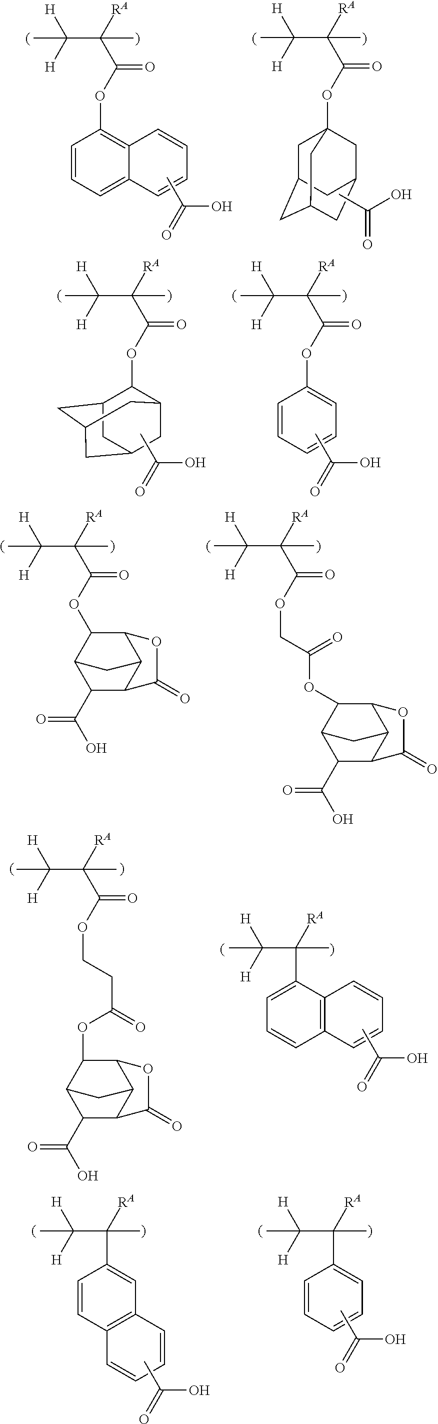

The carboxy-group-containing polymer including the repeating unit represented by the formula (1) may further include repeating units (hereinafter, also referred to as other repeating units) other than the repeating unit represented by the formula (1). The other repeating units are not particularly limited, but preferable are those that may enhance the solubility of the polymer in a solvent, because the polymer being hardly soluble when having only a repeating unit having a carboxy group. As the other repeating units, repeating units having a cyclic structure and repeating units including a styrene skeleton, which having a rigid skeleton and expected to have high etching resistance, are preferable.

Specific examples of the other repeating units include the following, but are not limited thereto. Note that, in the following formulae, R^{A} is as defined above and each X^{B} independently represents —CH₂— or —O—.

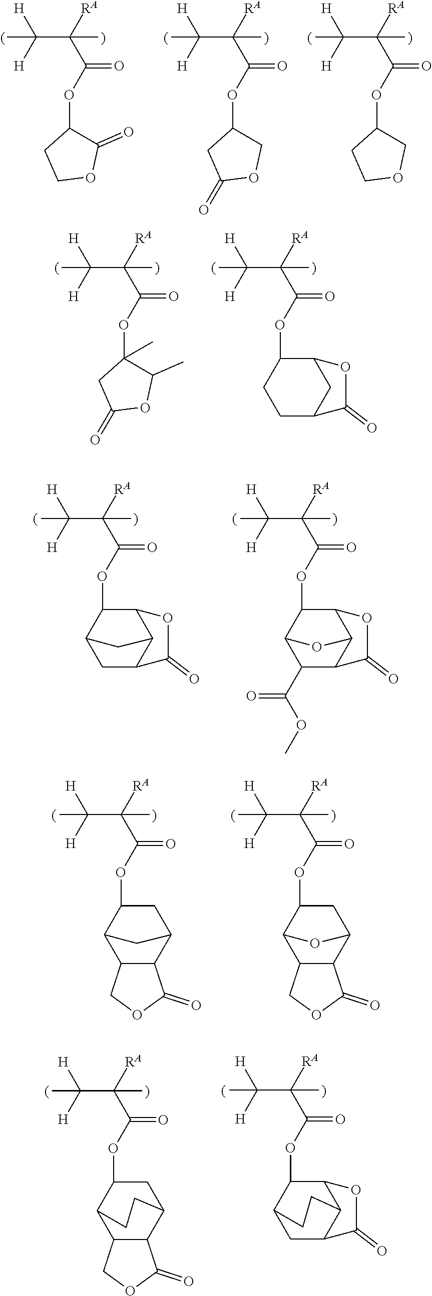

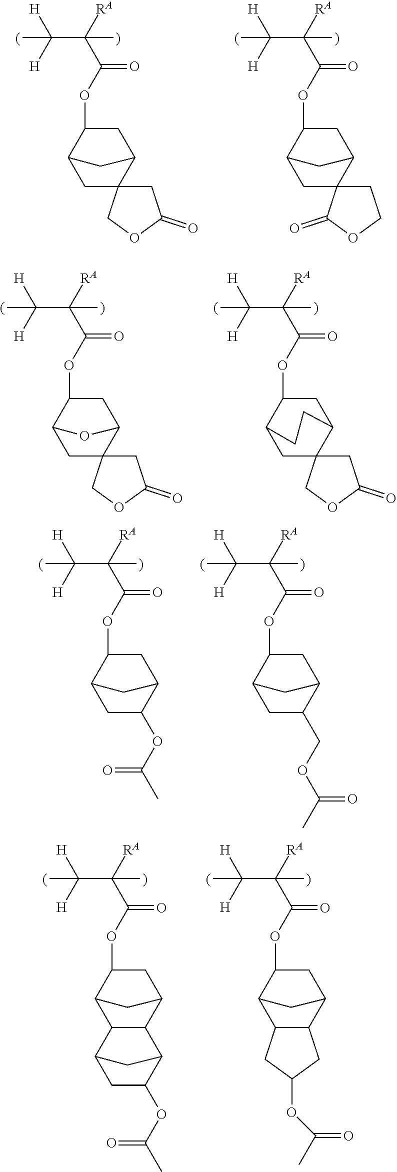

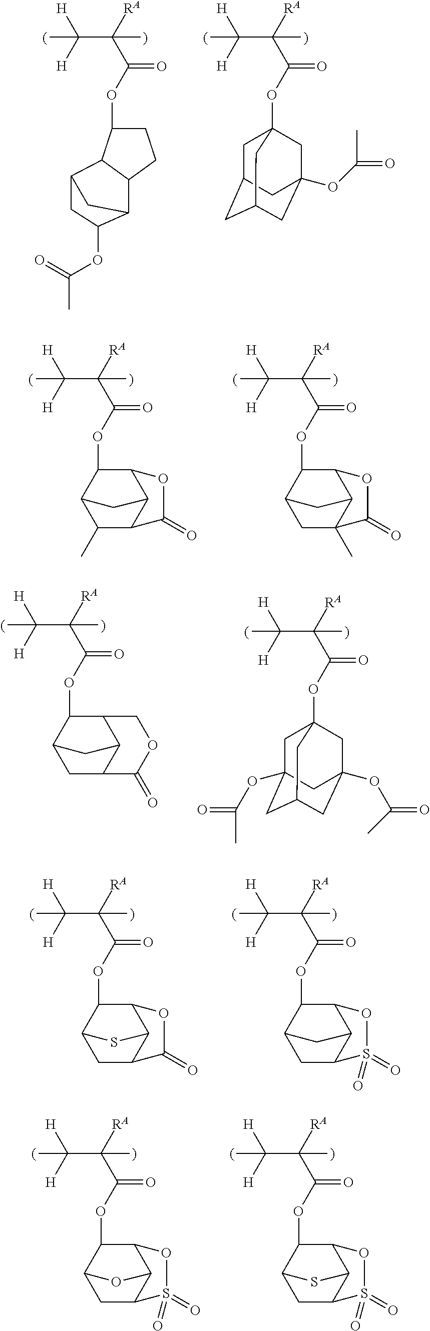

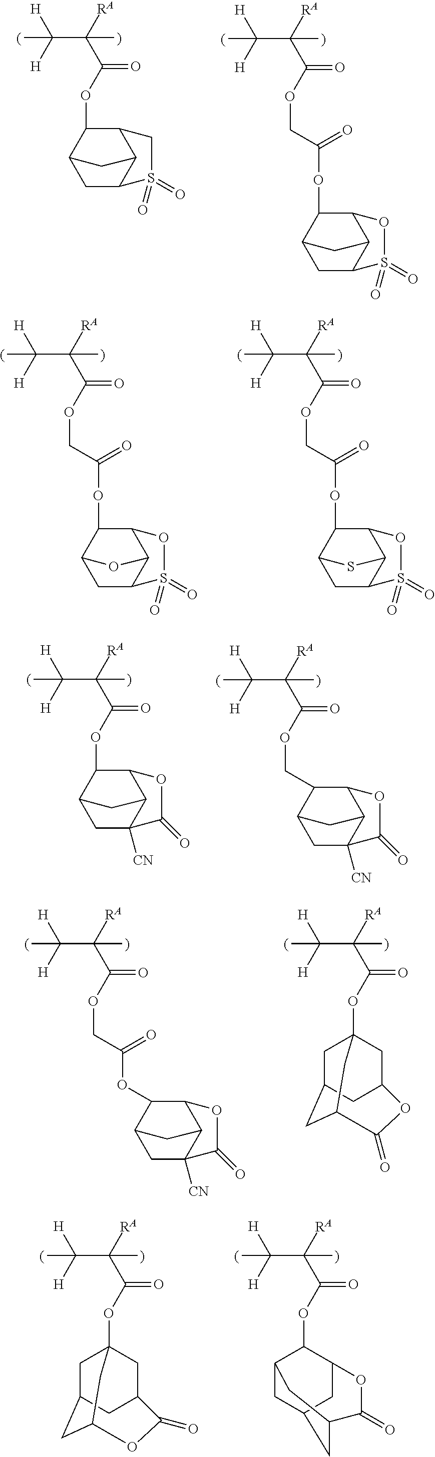

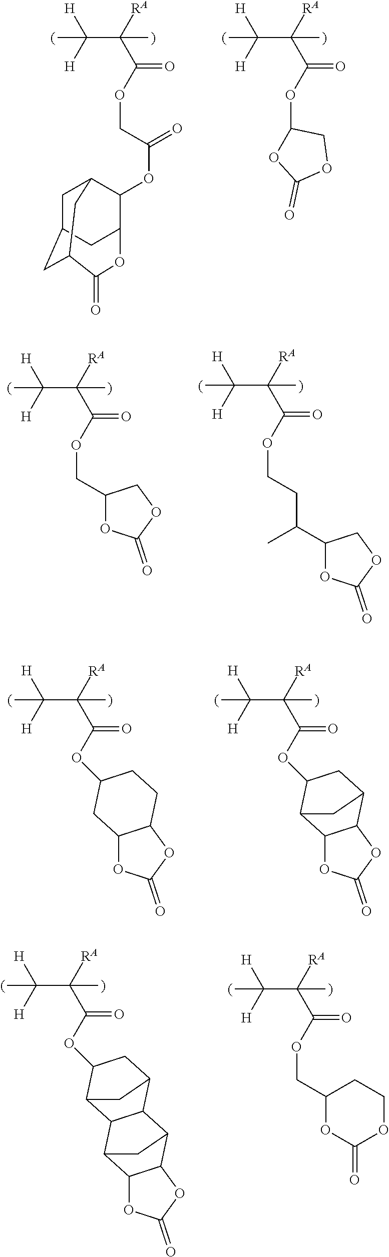

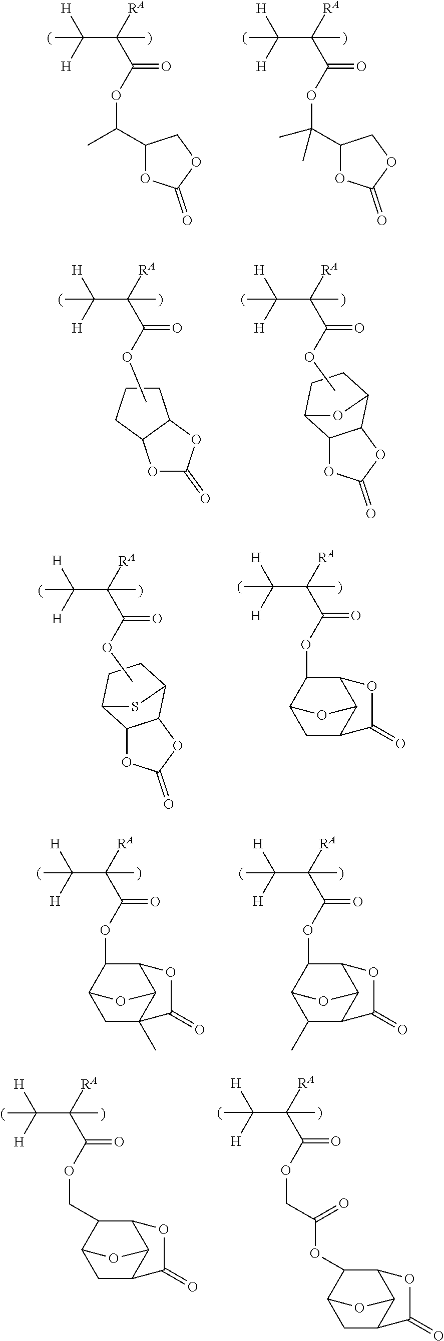

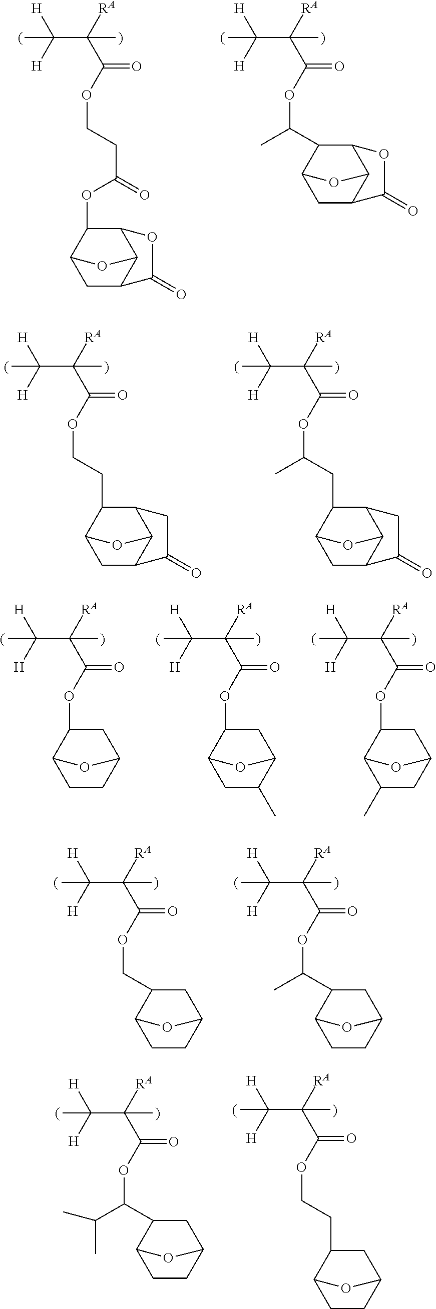

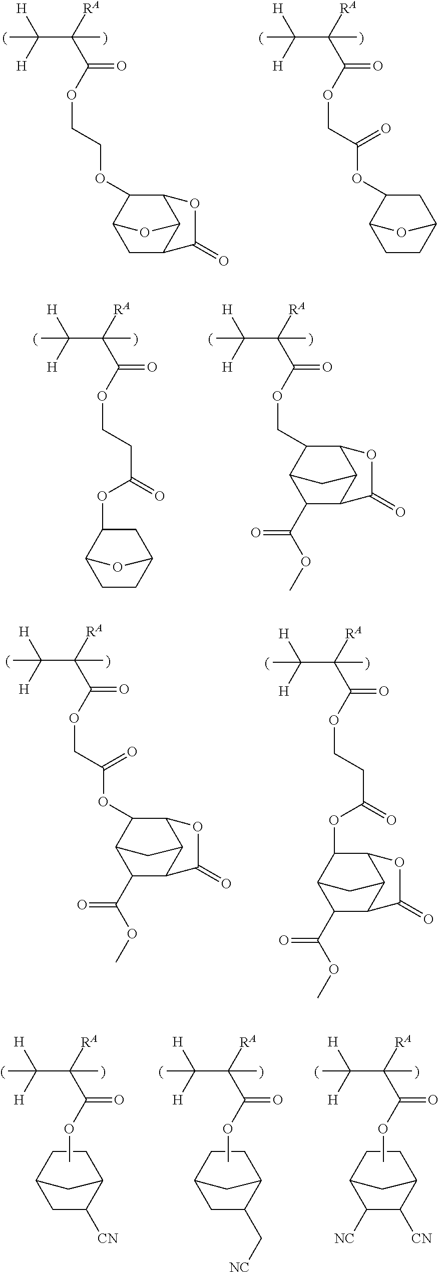

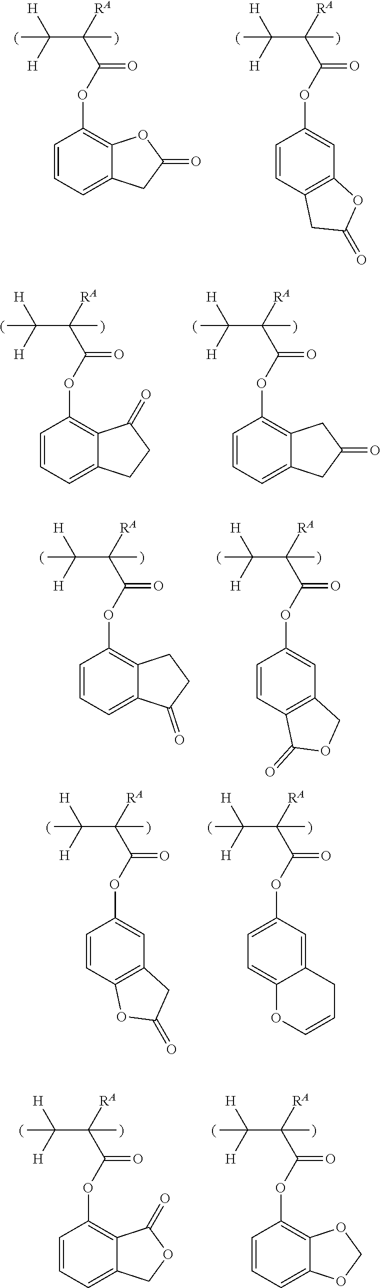

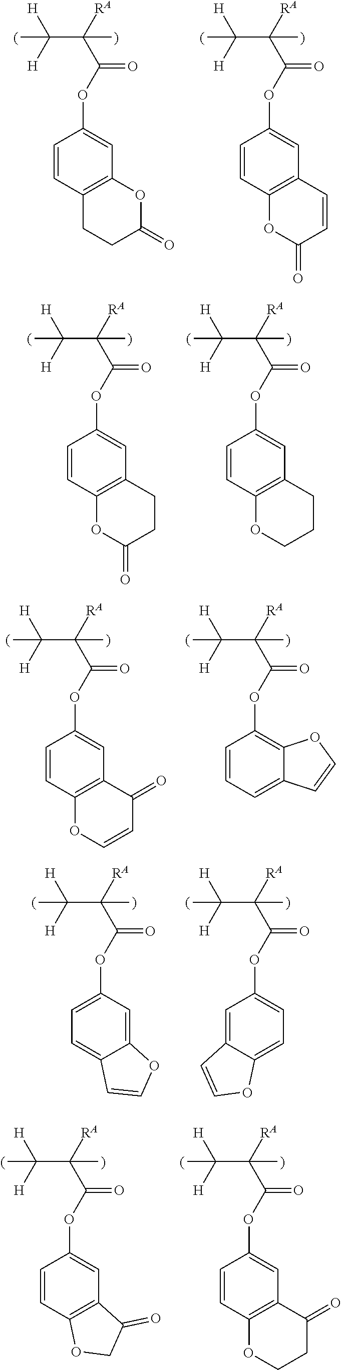

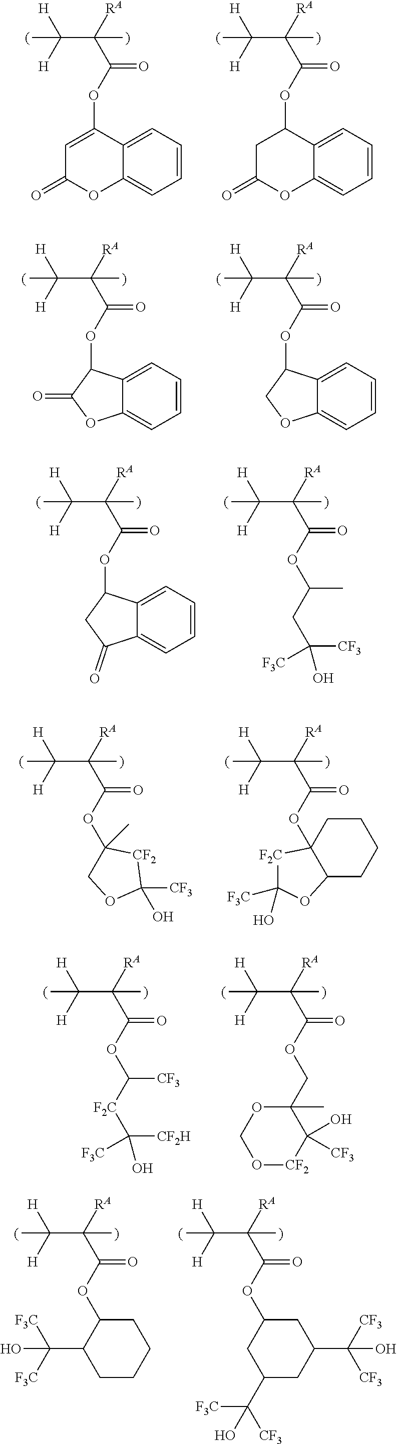

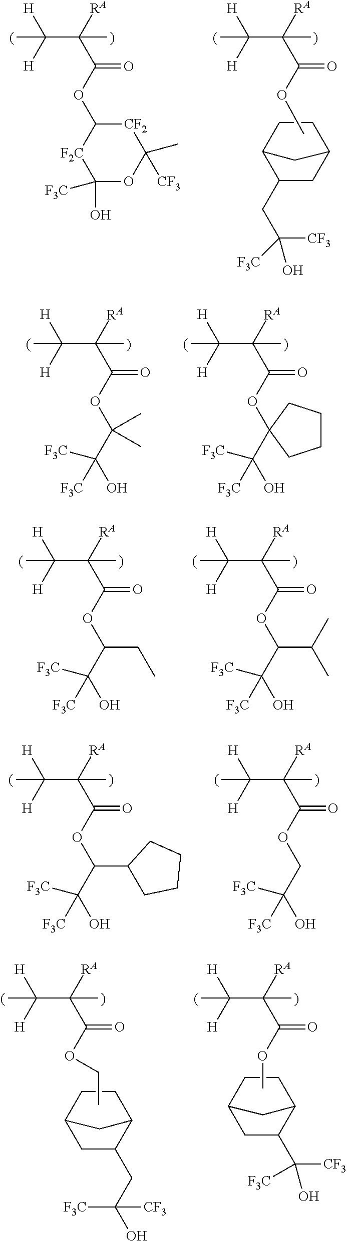

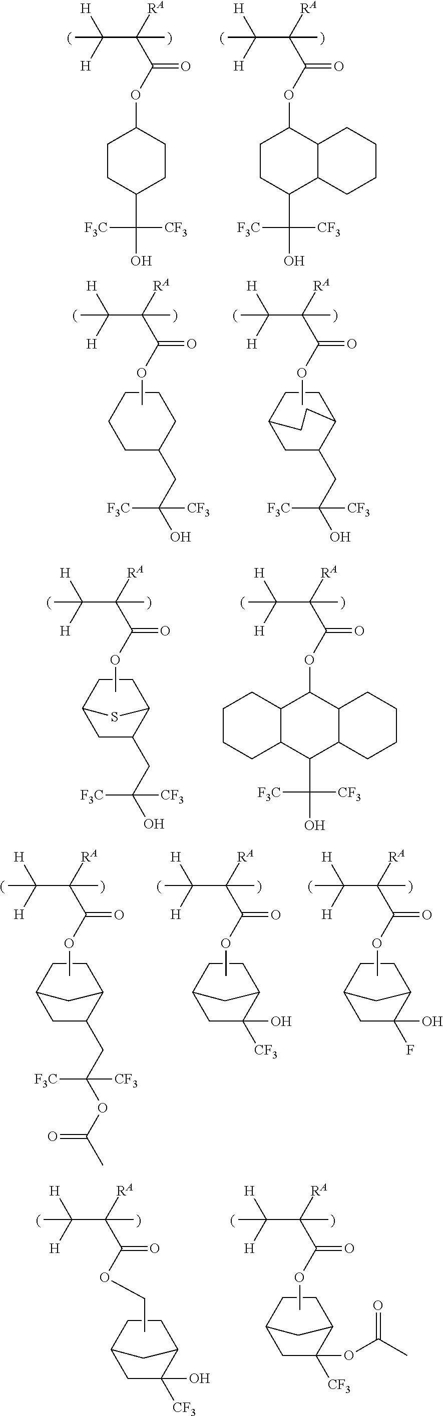

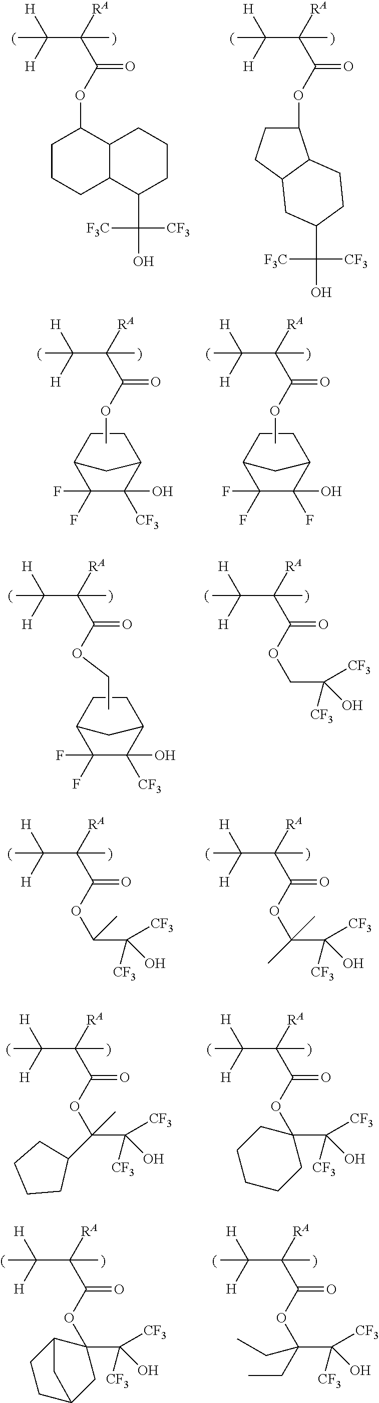

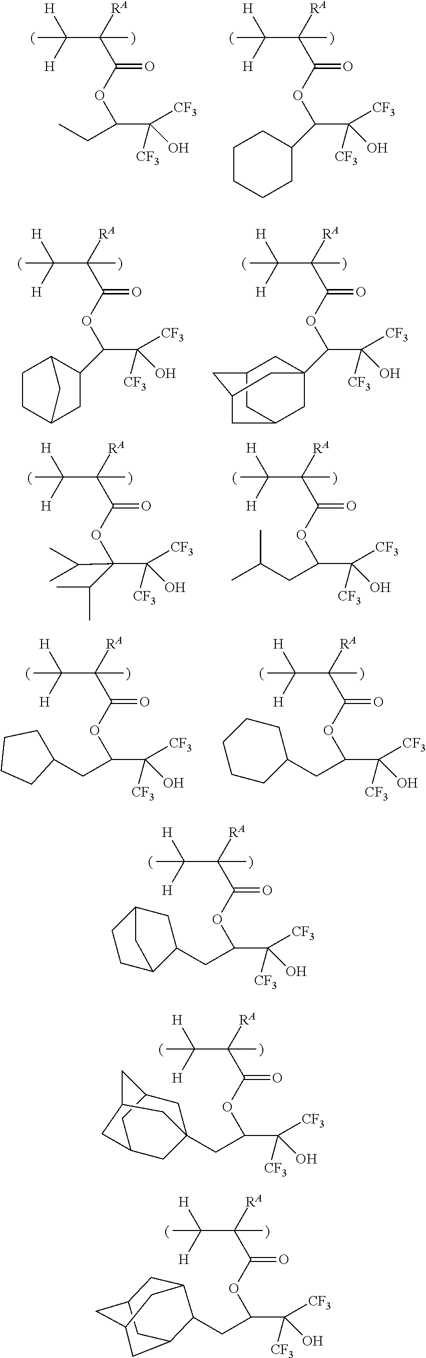

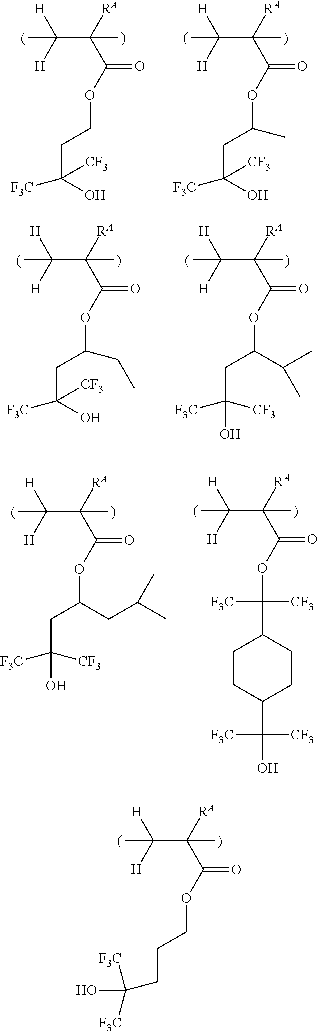

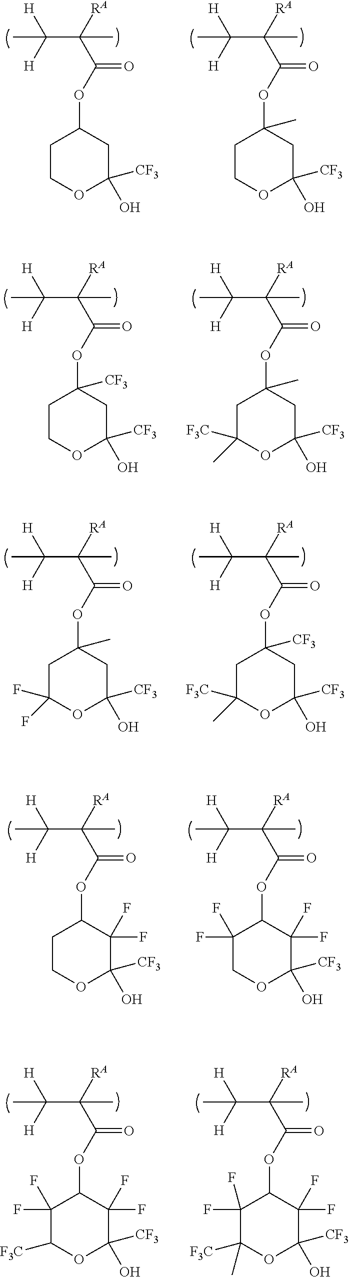

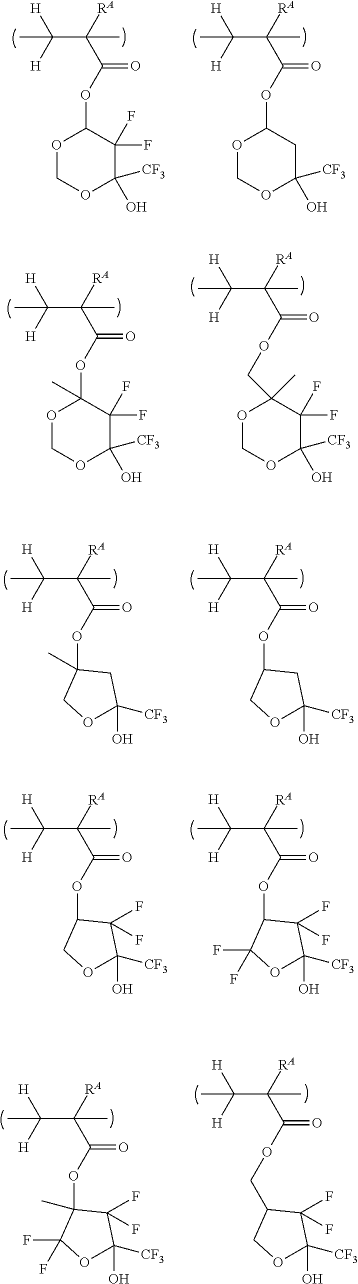

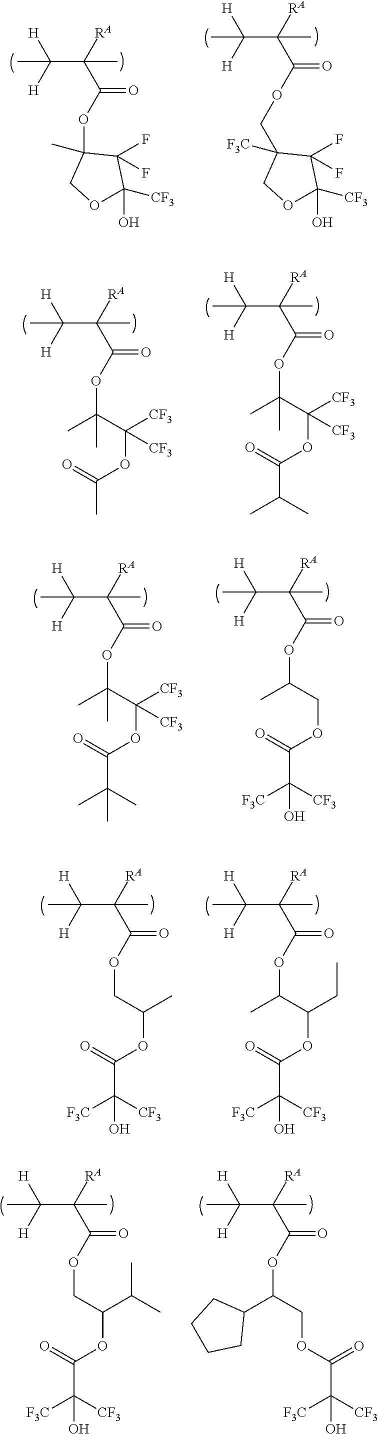

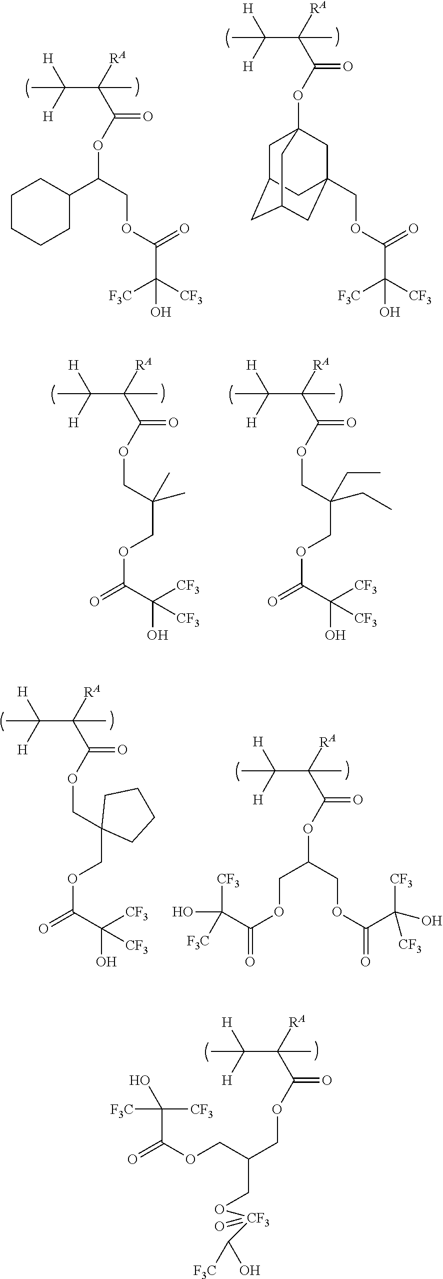

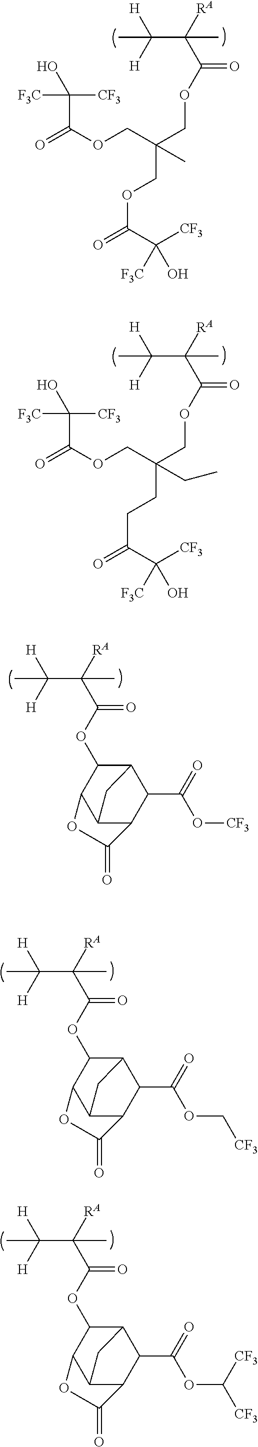

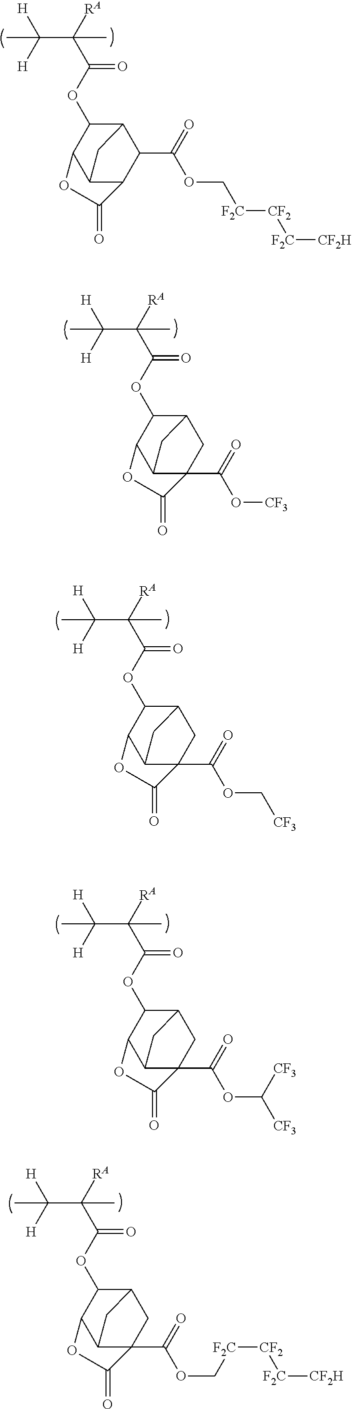

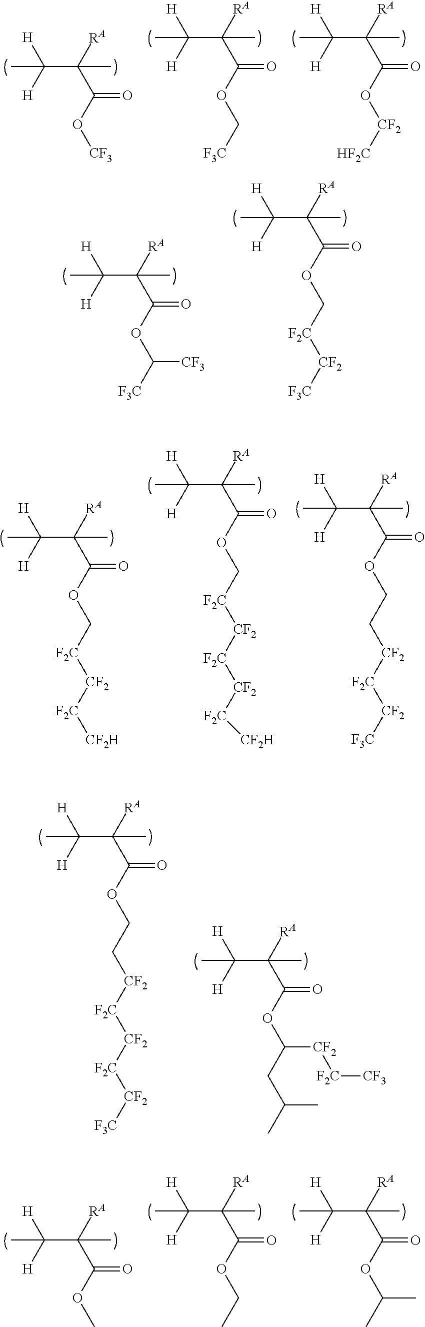

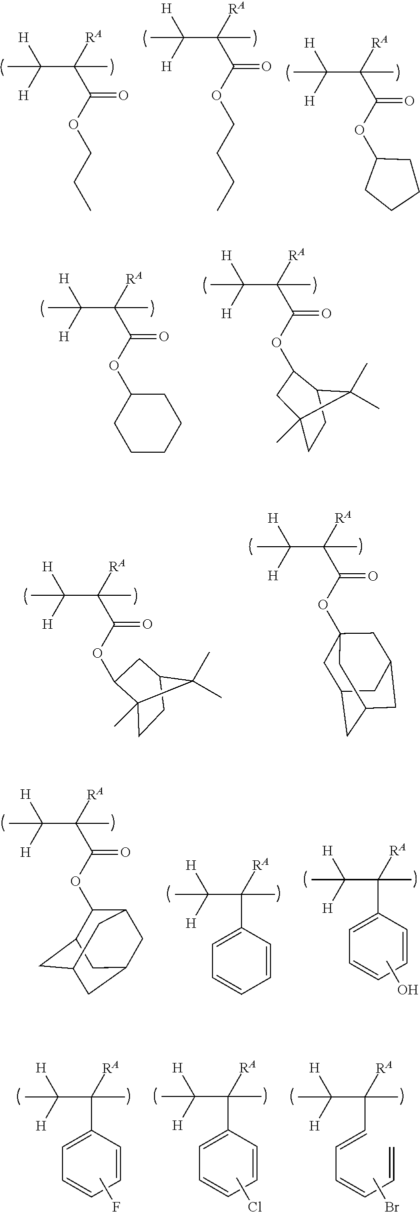

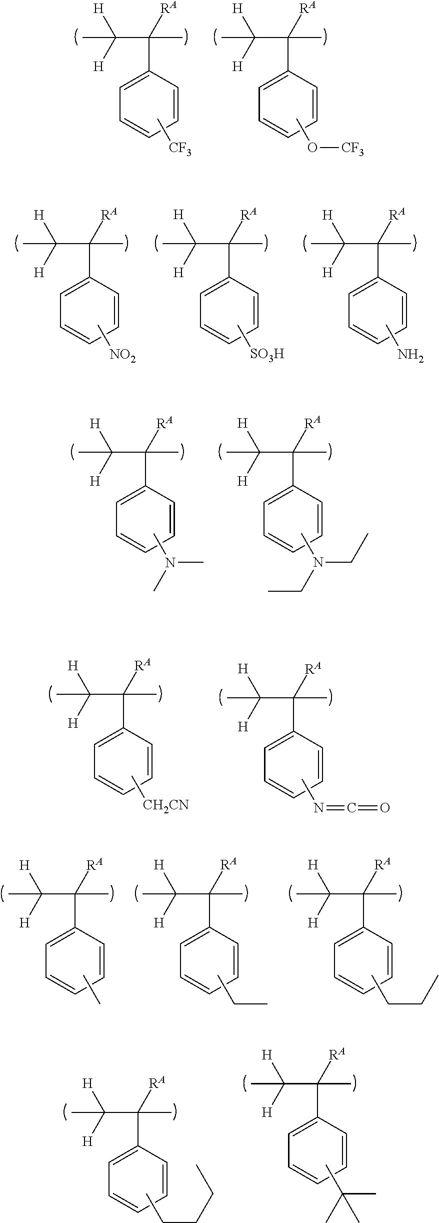

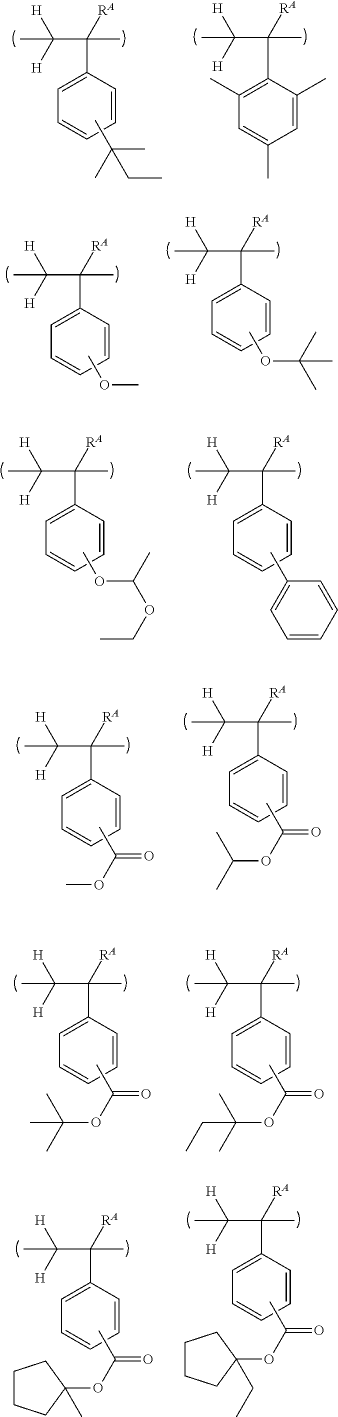

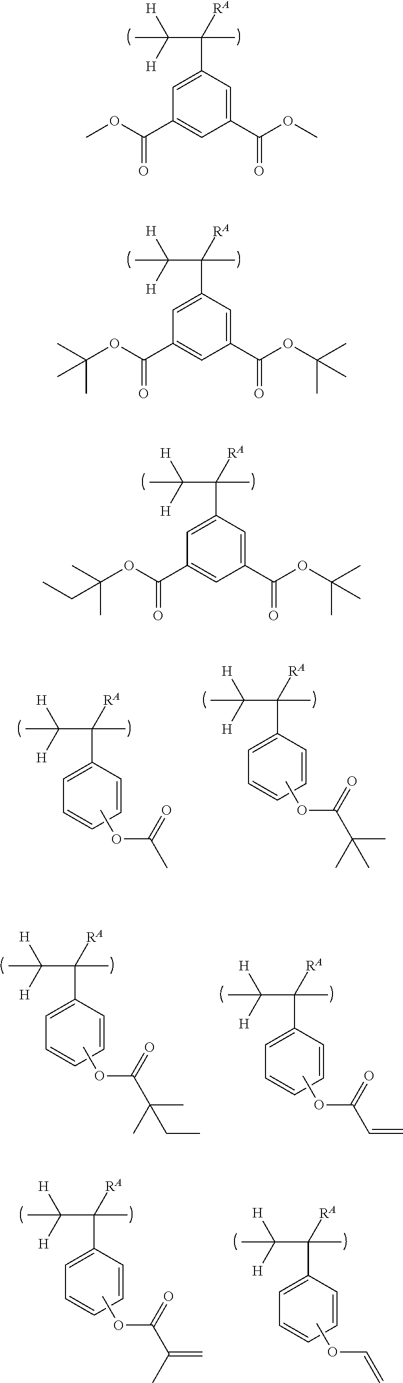

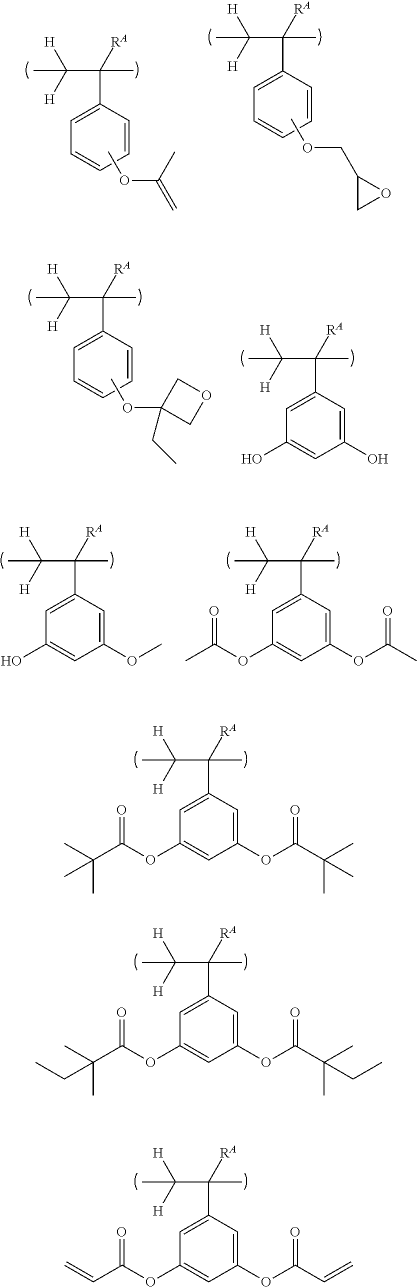

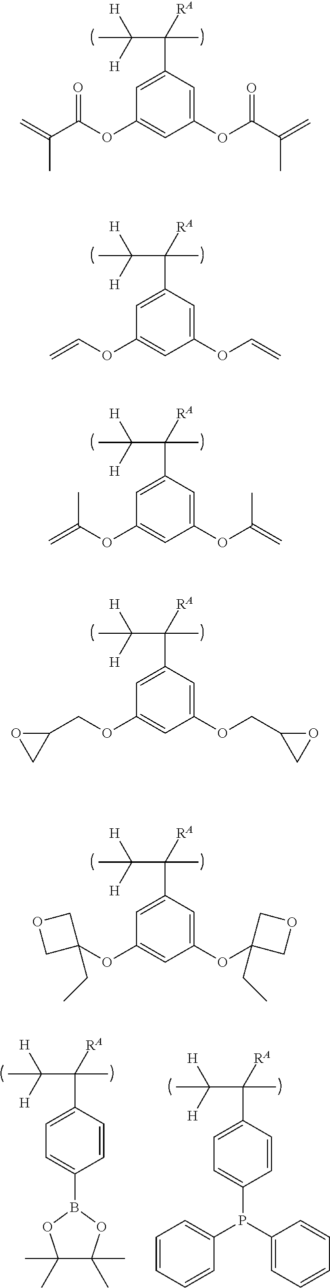

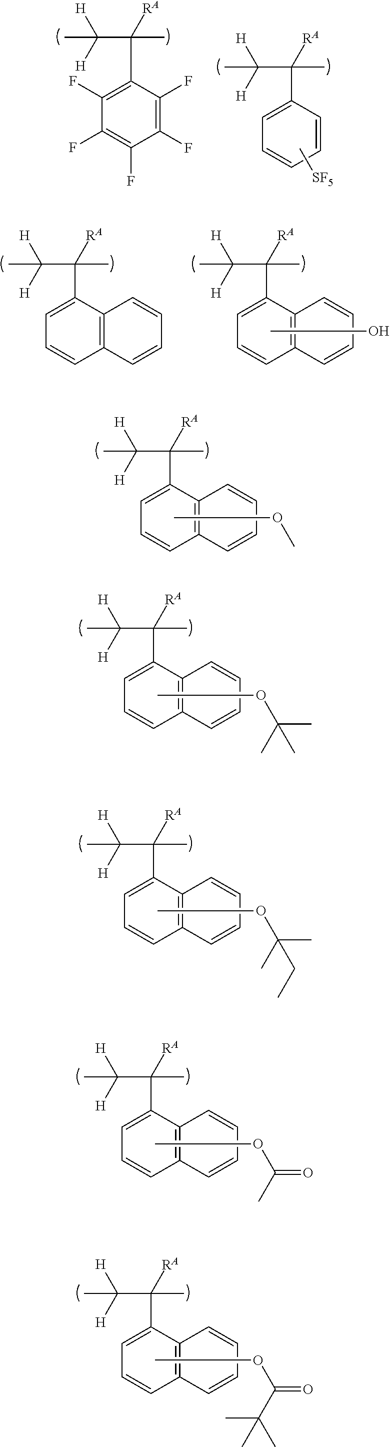

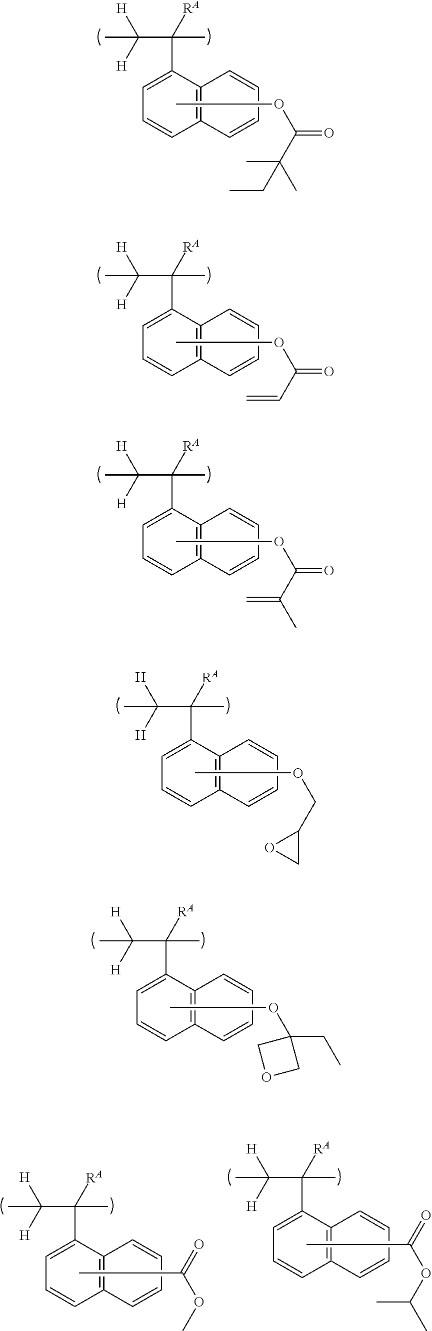

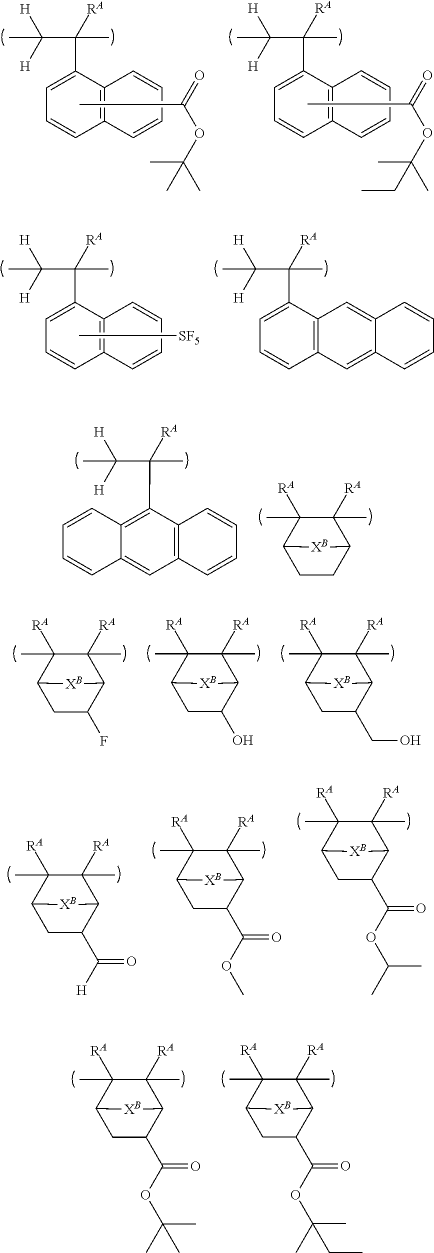

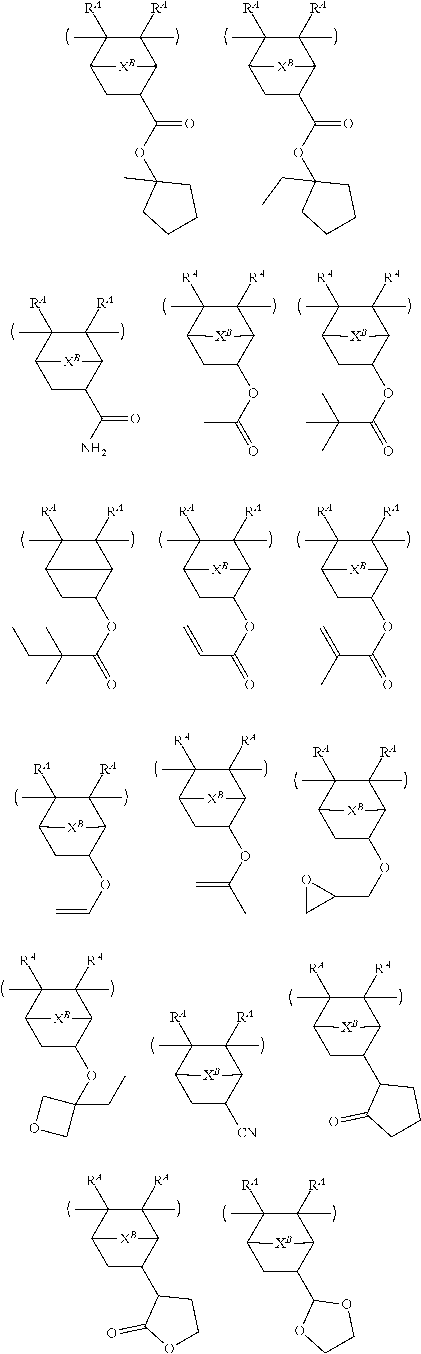

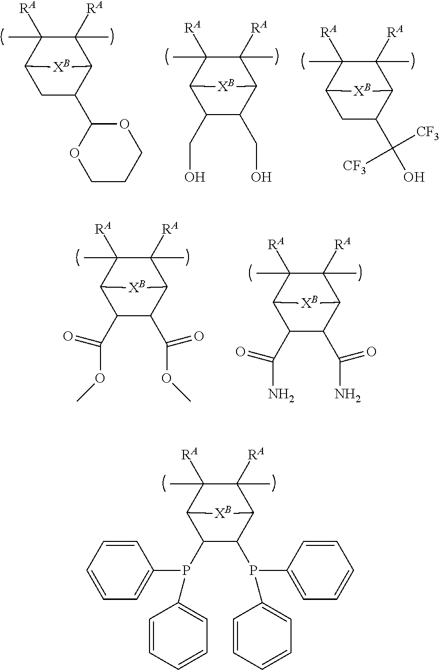

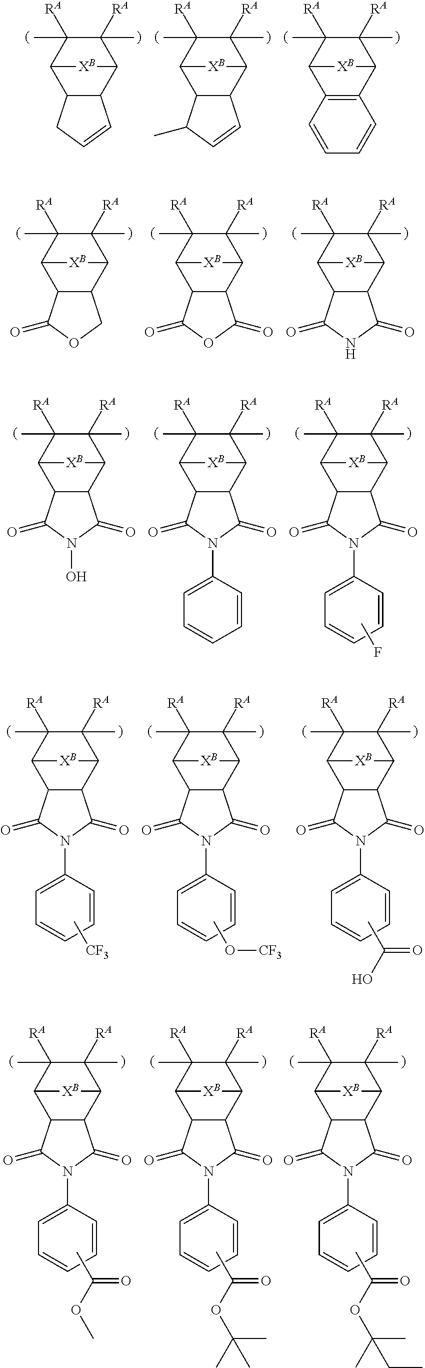

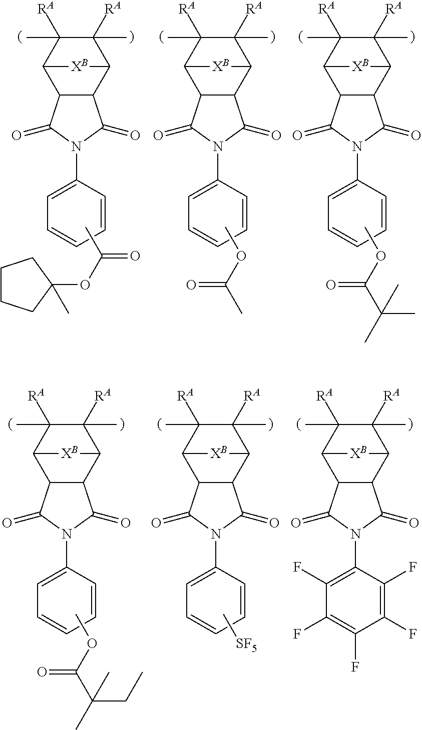

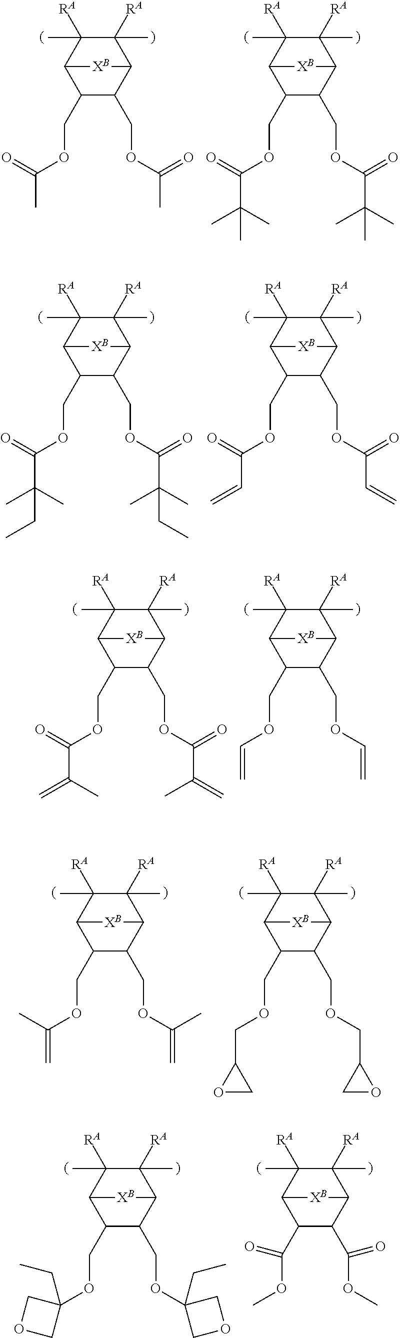

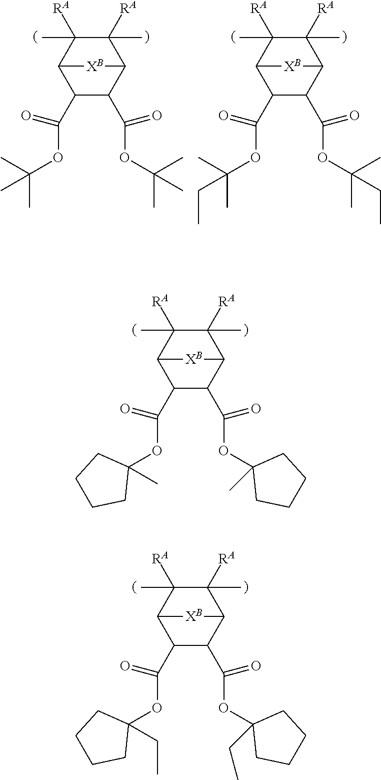

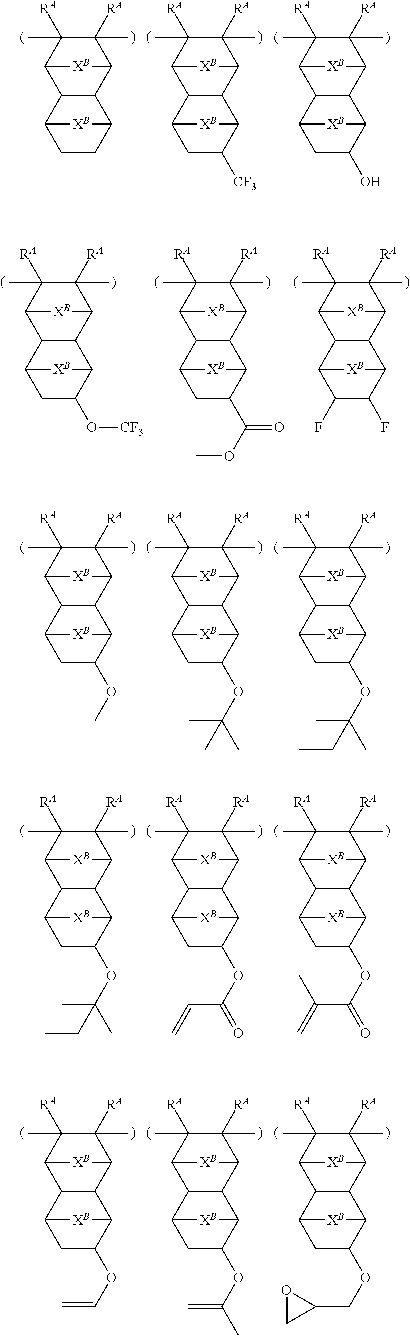

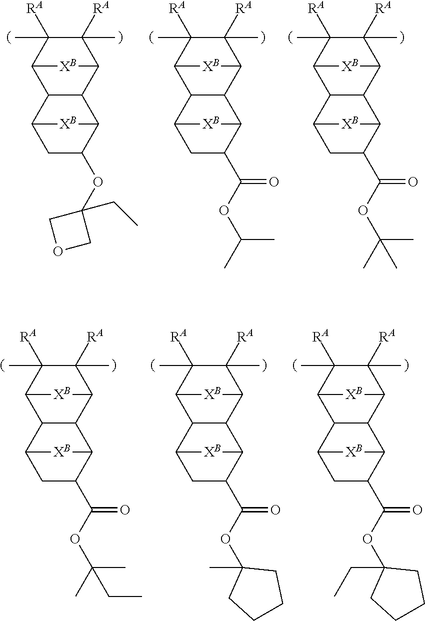

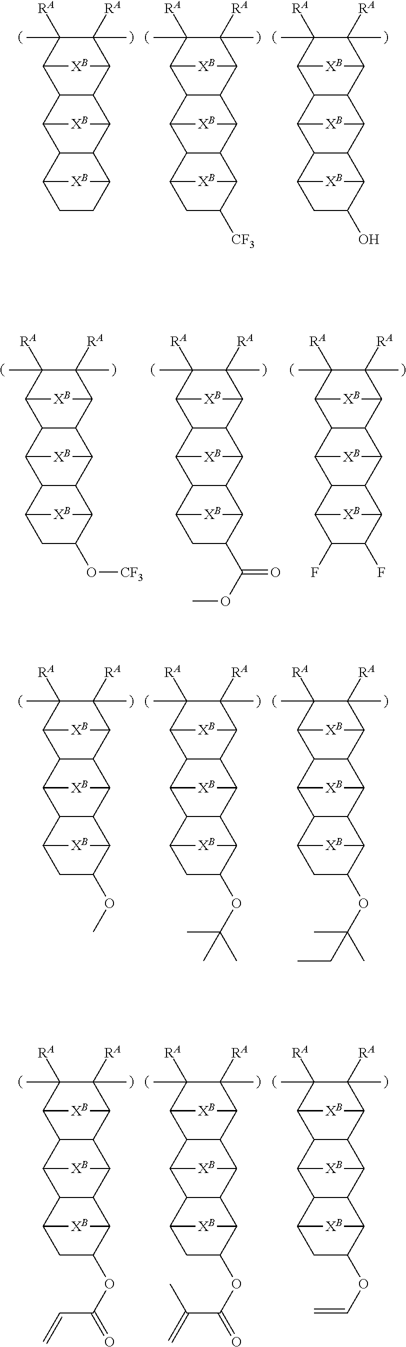

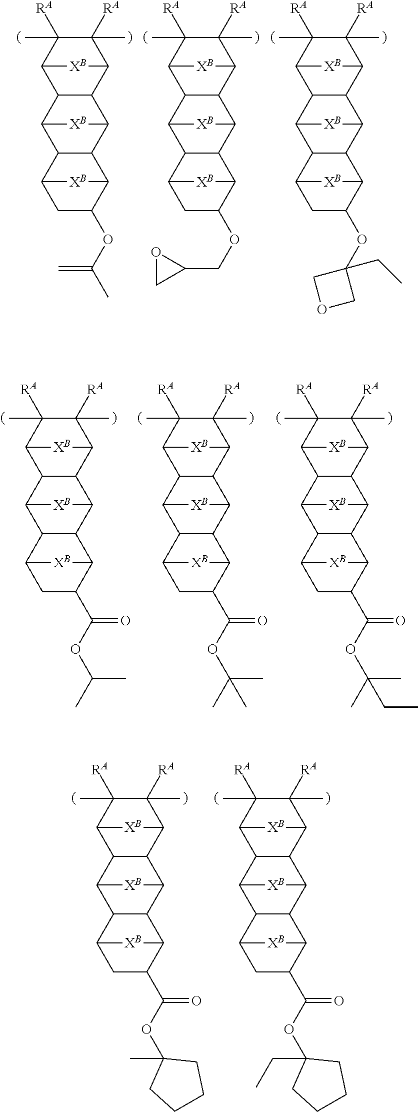

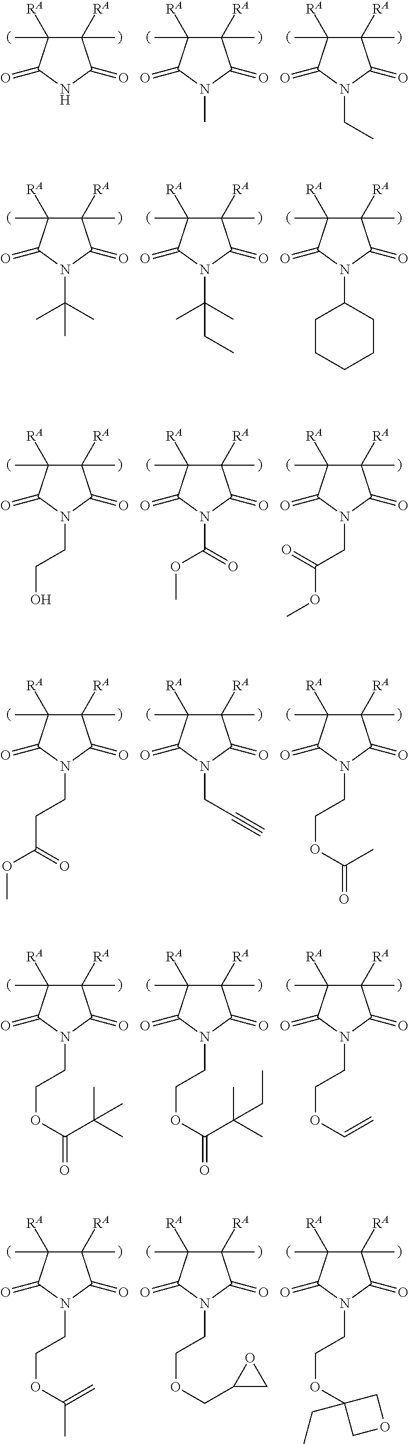

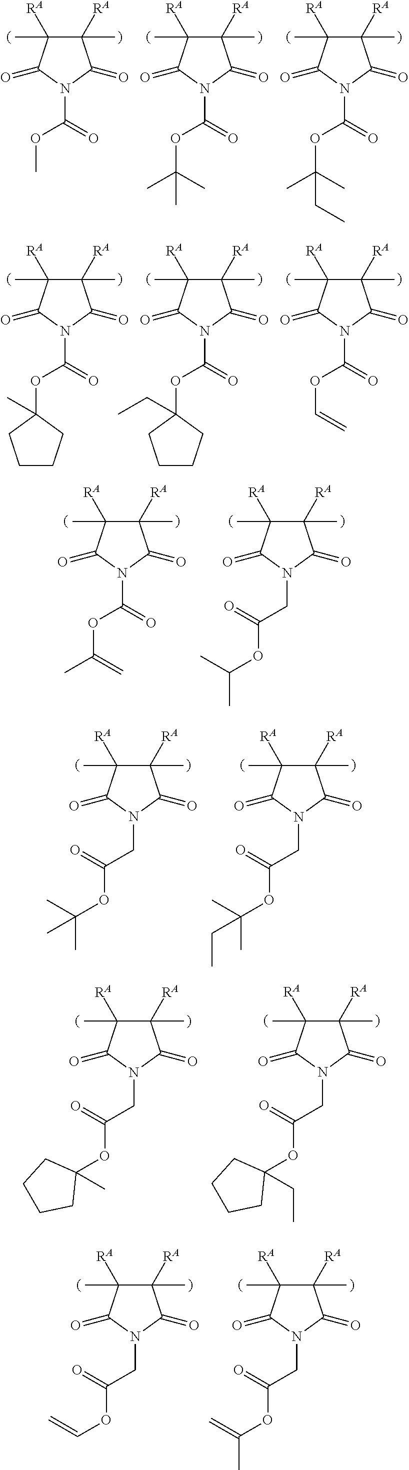

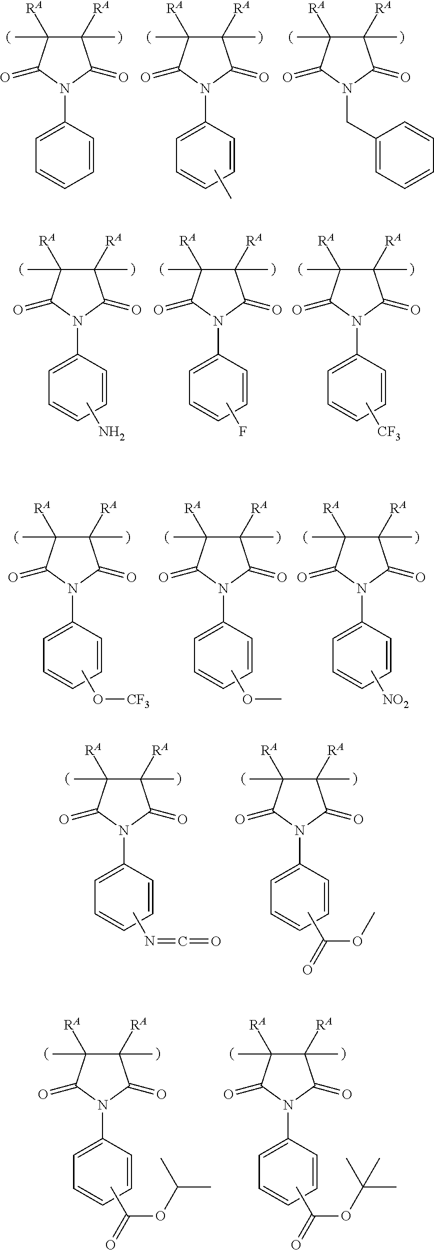

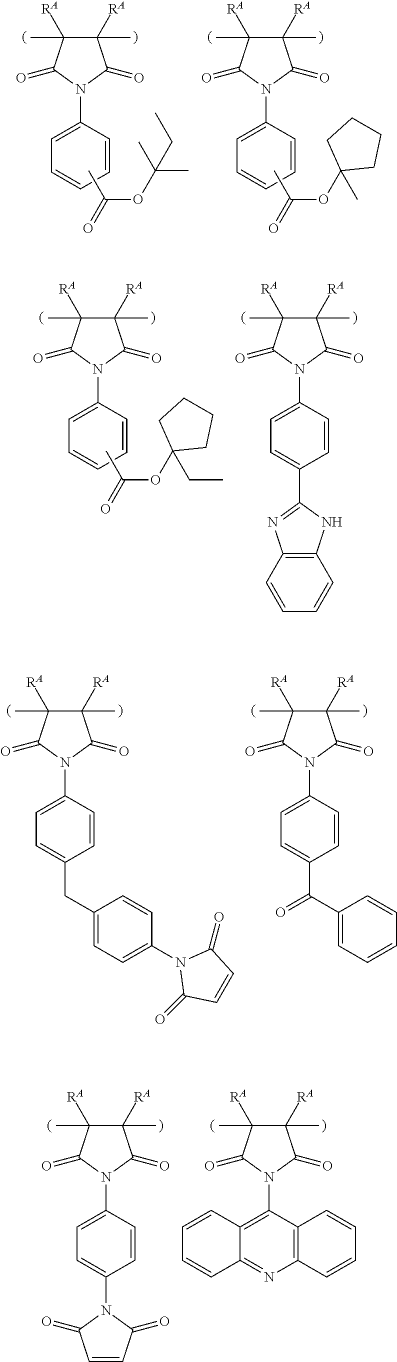

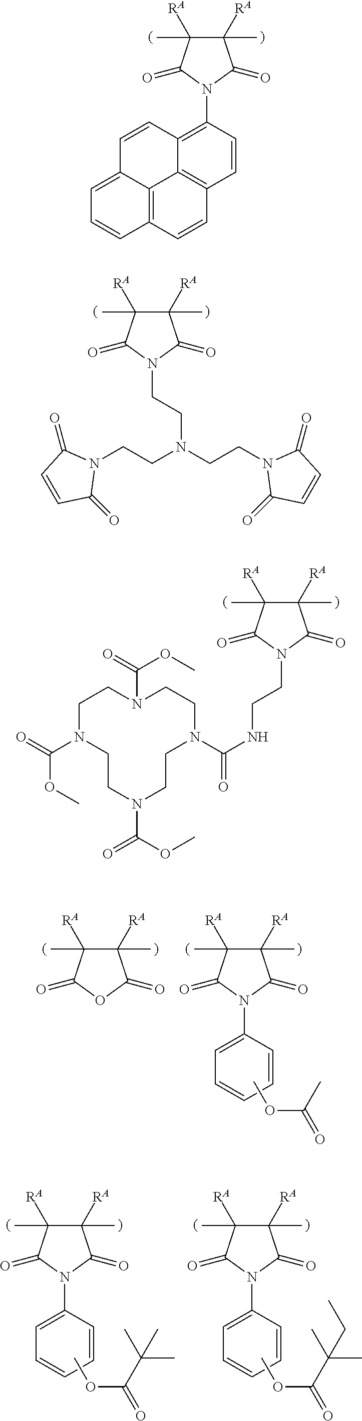

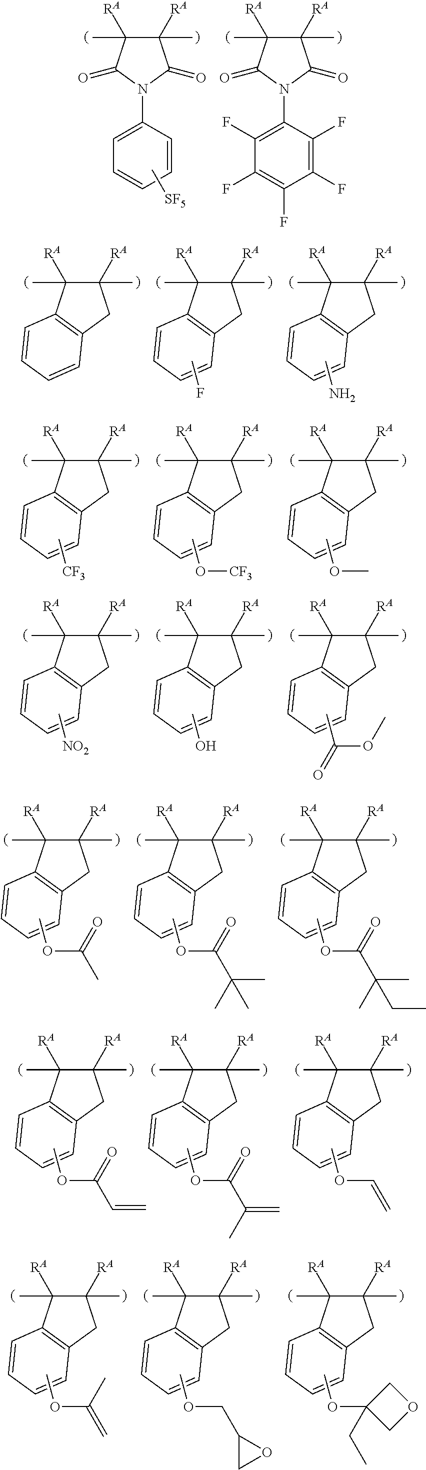

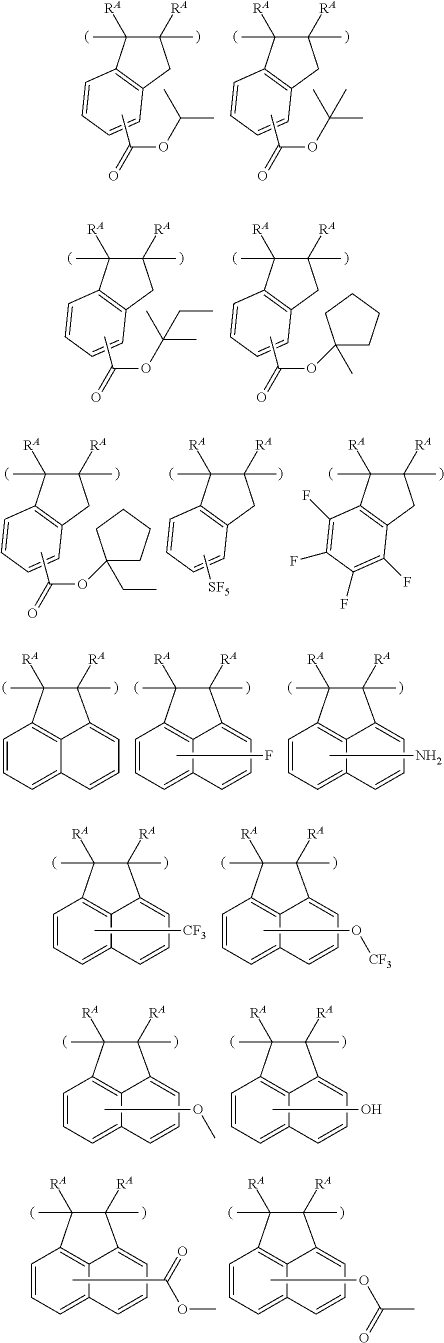

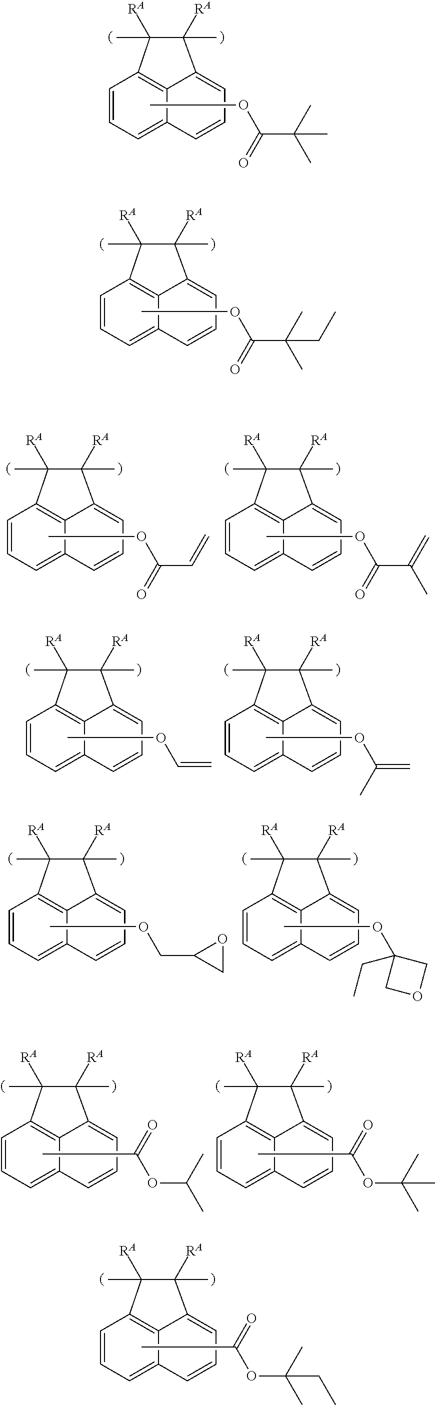

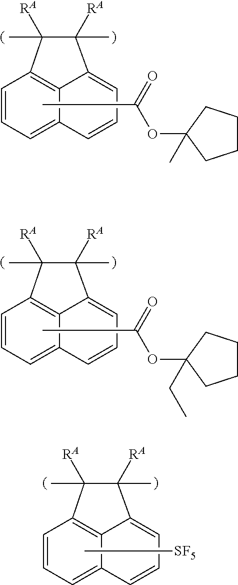

Methods for synthesizing the carboxy-group-containing polymer are not particularly limited as long as a polymer that satisfies the above-described dispersity can be obtained, but the polymer is preferably synthesized by living radical polymerization using a radical initiator and a reversible addition-fragmentation chain transfer agent (RAFT agent). That is, the present invention also provides a method for manufacturing the above-described resist composition, including the step of synthesizing the carboxy-group-containing polymer by living radical polymerization using a radical initiator and a reversible addition-fragmentation chain transfer agent (RAFT agent) represented by the formula (R-1) or (R-2) described later and mixing the obtained carboxy-group-containing polymer with the hypervalent iodine compound and the solvent. Hereinafter, living radical polymerization that uses a RAFT agent is also referred to as “RAFT polymerization”.

Living polymerization is a polymerization method effective for synthesizing a polymer whose structure has been controlled precisely, and is known as a method that gives a polymer having a narrow dispersity. Various kinds of living polymerization having different reaction mechanisms, such as anion, cation, radical, coordination, and ring-opening (metathesis), are being used.

The carboxy-group-containing polymer in the present invention can be obtained by (co) polymerizing monomers including a monomer that corresponds to the carboxy-group-containing repeating unit represented by the formula (1) and, as necessary, monomers corresponding to the other repeating units described above, and as a polymerization to give the carboxy-group-containing polymer of the present invention, having a dispersity Mw/Mn of 1.30 or less as measured by GPC, living radical polymerization is preferable, and RAFT polymerization is more preferable.

RAFT polymerization itself is a known technique, as disclosed in JP2007-520587A, JP2006-002096A, JP2007-246588A, etc. However, in conventional living radical polymerization systems, it is known that, since a RAFT reagent residue having an unsaturated bond in the structure has strong absorption in the ultraviolet region, a RAFT reagent may be effective for controlling polymerization but is insufficient for enhancing the performance of a resist resin in many cases (see paragraph of JP2006-002096A), and it has been thought that it is extremely difficult to obtain a resist composition having sensitivity and limiting resolution that exceed those of conventional compositions in photolithography using a high-energy beam such as EUV. Despite these circumstances, surprisingly, in the present invention, a resist composition containing a hypervalent iodine compound, a particular carboxy-group-containing polymer, and a solvent can give a non-chemically amplified resist composition excellent in sensitivity and limiting resolution in EUV lithography and so forth without the above-described problem occurring.

In the following, the RAFT polymerization in the present invention will be described.

### [RAFT Agent]

As the RAFT agent, a reversible addition-fragmentation chain transfer agent (RAFT agent) represented by the following formula (R-1) or (R-2) is preferable.

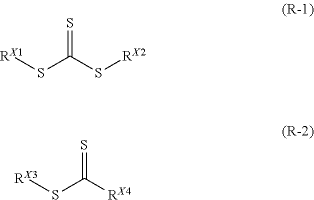

In the formulae, R^{X1} and R^{X3} each independently represent a saturated hydrocarbylthio group having 3 to 20 carbon atoms, an aralkylthio group having 7 to 20 carbon atoms, a heterocyclyl group having 5 to 20 carbon atoms, —N(Z^{A})(Z^{B}), —COOZ^{A}, —OCOZ^{A}, —CON(Z^{A})(Z^{B}), —P(═O)(OZ^{A})₂, or —O—P(═O)(Z^{A})(Z^{B}); Z^{A} and Z^{B} each independently represent a saturated hydrocarbyl group having 1 to 20 carbon atoms, an aryl group having 6 to 20 carbon atoms, or an aralkyl group having 7 to 20 carbon atoms, where part or all of hydrogen atoms bonded to carbon atoms of Z^{A} and Z^{B} may be substituted with a cyano group or a carboxy group.

R^{X2} and R^{X4} each independently represent a saturated hydrocarbyl group having 2 to 20 carbon atoms and optionally containing a heteroatom, an aralkyl group having 7 to 20 carbon atoms, or an aryl group having 6 to 20 carbon atoms.

The RAFT agents are respectively a trithiocarbonate compound and a dithioester compound. Specific examples of the trithiocarbonate compound include 2-cyano-2-propyl dodecyl trithiocarbonate, 4-cyano-4-[(dodecylsulfanylthiocarbonyl) sulfanyl]pentanoic acid, cyanomethyl dodecyl trithiocarbonate, and 2-(dodecylthiocarbonothioylthio)-2-methylpropionic acid. Specific examples of the dithioester compound include 1-ethoxycarbonyl-1-phenylmethyl benzodithioate, 2-phenyl-2-propyl benzodithioate, 4-cyano-4-(phenylthiocarbonylthio) pentanoic acid, and 2-cyano-2-propyl benzodithioate.

Among the RAFT agents, from the viewpoint of availability, it is preferable to use 2-cyano-2-propyl dodecyl trithiocarbonate among the trithiocarbonate compounds and 1-ethoxycarbonyl-1-phenylmethyl benzodithioate among the dithioester compounds respectively.

The amount of the RAFT agent to be used is preferably 0.05 parts by mass or more, more preferably 0.1 parts by mass or more based on a total of 100 parts by mass of the monomers. Meanwhile, the upper limit of the amount used is preferably 20 parts by mass or less, more preferably 10 parts by mass or less based on a total of 100 parts by mass of the monomers. One kind of the RAFT agent may be used, or two or more kinds thereof may be used in combination.

In the above-described resist composition, the content ratio of the hypervalent iodine compound to the carboxy-group-containing compound (when the carboxy-group-containing compound is a carboxy-group-containing polymer, the content ratio of the hypervalent iodine compound to the carboxylic-acid-containing repeating unit in the polymer) is preferably “hypervalent iodine compound”: “carboxy-group-containing compound”=10:90 to 90:10, more preferably 20:80 to 80:20, and further preferably 30:70 to 70:30 in molar ratio. One kind of the hypervalent iodine compound may be used, or two or more kinds thereof having different composition ratios, Mw, and/or Mw/Mn may be used in combination. One kind of the carboxy-group-containing polymer may be used, or two or more kinds thereof having different composition ratios, Mw, and/or Mw/Mn may be used in combination.

In the carboxy-group-containing polymer, the content ratio (molar ratio) of the carboxy-group-containing repeating unit to the other repeating units is preferably “carboxy-group-containing repeating unit”: “other repeating units”=10:90 to 90:10, more preferably 15:85 to 85:15, and further preferably 20:80 to 80:20.

The carboxy-group-containing polymer preferably has a weight-average molecular weight (Mw) of 1000 to 500000, more preferably 3000 to 100000. Note that, in the present invention, Mw is a value measured in terms of standard polystyrene by gel permeation chromatography (GPC) using tetrahydrofuran (THF) as an eluent.

The living radical polymerization reaction can be performed by any method selected appropriately from:
(1) a method of adding all of the monomers, the polymerization initiator, and the RAFT agent to a solvent at once in a reaction vessel and dissolving the materials, and then heating the reaction vessel to initiate the reaction;
(2) a method of supplying, to a reaction vessel into which part of the solvent has been charged and which has been heated beforehand, a solution in which the monomers, the polymerization initiator, and the RAFT agent have been dissolved in a solvent, thereby initiating the reaction; and
(3) a method of supplying, to a reaction vessel into which the RAFT agent and part of the solvent have been charged and which has been heated beforehand, a solution in which the monomers and the polymerization initiator have been dissolved in a solvent, thereby initiating the reaction. In the cases of the methods of (2) and (3), regarding the preparation of the solution of the monomers, the initiator, and the RAFT agent, a solution of each may be prepared independently and supplied to the reaction vessel. There is a possibility that the polymerization reaction may progress due to radicals generated from the initiator during waiting time and an ultra-high molecular weight polymer may be generated, and therefore, from the viewpoint of quality control, it is preferable to prepare at least the monomer solution and the initiator solution each independently and add the solutions dropwise.

In the living radical polymerization reaction, the reaction temperature is preferably 50 to 150° C., more preferably 60 to 100° C. The reaction time is preferably 2 to 24 hours, and from the viewpoint of production efficiency, more preferably 2 to 12 hours.

After the living radical polymerization reaction process, a purification process of adding the reaction solution to a poor solvent and performing reprecipitation and so forth may be included as necessary. The poor solvent used in this event can be appropriately selected depending on the kind of the polymer, and typical examples include: hydrocarbons, such as toluene, xylene, hexane, and heptane; ethers, such as diethyl ether, tetrahydrofuran, and dibutyl ether; ketones, such as acetone and 2-butanone; esters, such as ether acetate and butyl acetate; and water. However, the poor solvent is not limited thereto. One kind of these solvents may be used, or two or more kinds thereof may be used in mixture.

By adding a radical generator and a thiol compound to the solution containing the polymer obtained after the polymerization and heating the mixture, the above-described terminal structure can be removed from the main chain of the polymer. By this operation, the terminal structure that the polymer has is substituted with a hydrogen atom. Note that, out of the radical generator used in the radical polymerization process, some undecomposed radical generator may be present, but to substitute the terminal structure with a hydrogen atom in a short time with high efficiency, it is preferable to add a radical generator additionally simultaneously when adding the thiol compound.

As the radical generator to be added after the polymerization, a radical generator can be selected appropriately from those given as examples in the polymerization and can be used. The amount of the radical initiator to be used is preferably 0.5 to 10 mol, more preferably 0.5 to 2 mol based on 1 mol of the RAFT agent used in the polymerization.

In the present invention, as the thiol compound to be used after the polymerization, a compound represented by the following formula (SH-1) or (SH-2) is preferable.

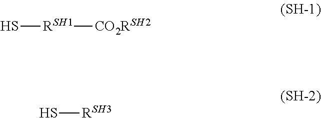

In the formula (SH-1), R^{SH1} represents a hydrocarbylene group having 1 to 3 carbon atoms. Specific examples of the hydrocarbylene group include a methanediyl group, an ethane-1,1-diyl group, an ethane-1,2-diyl group, a propane-1,1-diyl group, a propane-1,2-diyl group, a propane-1,3-diyl group, and a propane-2,2-diyl group.

In the formula (SH-1), R^{SH2} represents an aliphatic hydrocarbyl group having 4 to 8 carbon atoms, an aralkyl group having 7 to 18 carbon atoms, or an aryl group having 6 to 18 carbon atoms, and may contain a heteroatom. Examples of the heteroatom include an oxygen atom, a nitrogen atom, a sulfur atom, or a halogen atom.

The aliphatic hydrocarbyl group represented by R^{SH2} may be saturated or unsaturated, and may be linear, branched, or cyclic. Specific examples thereof include: linear or branched aliphatic hydrocarbyl groups, such as an n-butyl group, an isobutyl group, a sec-butyl group, a tert-butyl group, an n-pentyl group, an isopentyl group, a sec-pentyl group, a 3-pentyl group, a tert-pentyl group, a neopentyl group, an n-hexyl group, a 3-methylpentan-3-yl group, a 2,3-dimethylbutan-2-yl group, an n-heptyl group, a 2,3,4-trimethylpentan-3-yl group, an n-octyl group, a tetradecyl group, a hexadecyl group, and an octadecyl group; and cyclic aliphatic hydrocarbyl groups such as a cyclopentyl group, a 1-methylcyclopentyl group, a 1-ethylcyclopentyl group, a 1-vinylcyclopentyl group, a cyclohexyl group, a 1-methylcyclohexyl group, a 1-ethylcyclohexyl group, a 1-vinylcyclohexyl group, a norbornyl group, a 1-methylnorbornyl group, a cyclooctyl group, a cyclodecyl group, a cyclododecyl group, a 1-adamantyl group, a 2-adamantyl group, a 1-methyladamantyl group, and a 1-ethyladamantyl group.

Specific examples of the aralkyl group represented by R^{SH2} having 7 to 18 carbon atoms include a benzyl group, a phenethyl group, a 4-methoxybenzyl group, and a 9-anthracenylmethyl group. Specific examples of the aryl group represented by R^{SH2} having 6 to 18 carbon atoms include a phenyl group, a naphthyl group, a 4-methoxyphenyl group, a 2-anthracenyl group, and a 9-anthracenyl group.

In the formula (SH-2), R^{SH3} represents a saturated hydrocarbyl group having 6 to 20 carbon atoms, an aralkyl group having 7 to 18 carbon atoms, or an aryl group having 6 to 18 carbon atoms, and may contain a heteroatom.

The saturated hydrocarbyl group represented by R^{SH3} may be linear, branched, or cyclic, and specific examples thereof include an n-hexyl group, a 3-methylpentyl group, an n-heptyl group, an n-octyl group, a 1-ethylhexyl group, an n-nonyl group, an n-decyl group, an n-undecyl group, an n-dodecyl group, a 2,2,4,6,6-pentamethylheptan-4-yl group, an n-tetradecyl group, an n-hexadecyl group, an n-octadecyl group, an n-eicosanyl group, and a 2,3,3,4,4,5-hexamethylhexan-2-yl group.

Specific examples of the aralkyl group represented by R^{SH3} having 7 to 18 carbon atoms include a benzyl group, a phenethyl group, a 4-methoxybenzyl group, and a 9-anthracenylmethyl group. Specific examples of the aryl group represented by R^{SH3} having 6 to 18 carbon atoms include a phenyl group, a naphthyl group, a 4-methoxyphenyl group, a 2-anthracenyl group, and a 9-anthracenyl group.

As the compound represented by the formula (SH-1), the following are preferable.

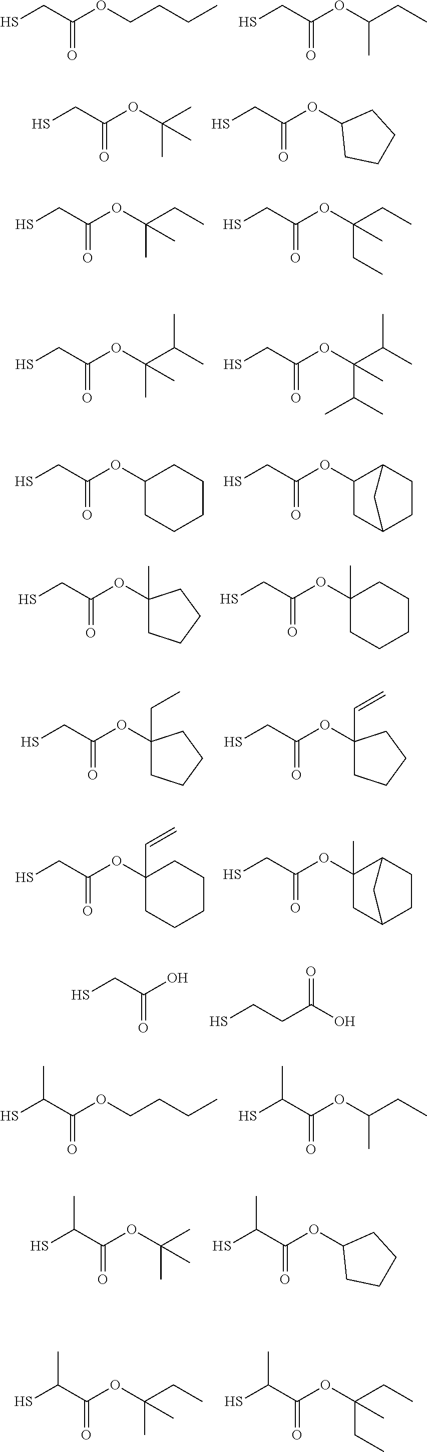

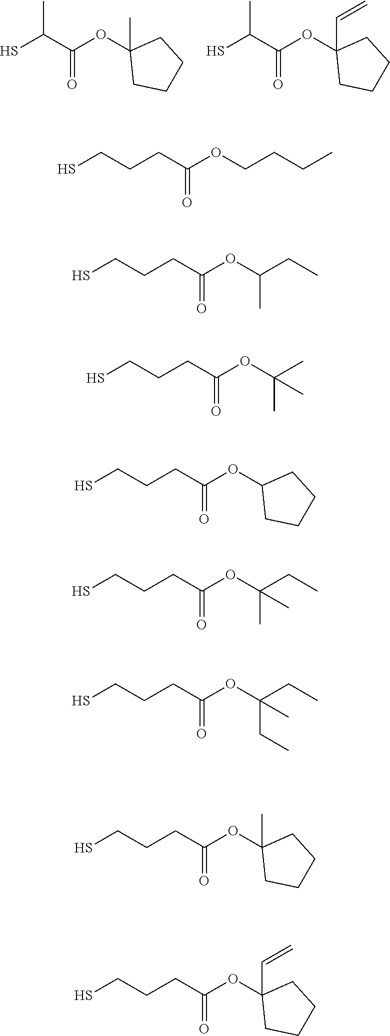

As the compound represented by the formula (SH-2), the following are preferable.

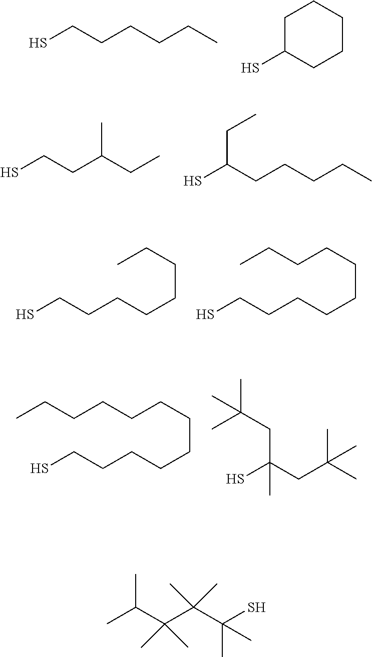

The amount of the thiol compound to be used after the polymerization is preferably 1 to 20 mol, more preferably 1 to 4 mol based on 1 mol of the RAFT agent used in the polymerization. The radical initiator and the thiol compound to be added after the polymerization may each be added independently to the solution containing the polymer, or the two may be mixed together and added simultaneously to the solution containing the polymer. From the viewpoint of the efficiency of the operation, it is preferable to add to the solution containing the polymer, a solution obtained by mixing and dissolving the initiator and the thiol compound in a solvent simultaneously, and it is more preferable to add to a reaction solution obtained by performing living radical polymerization in a solvent, a mixed solution of the initiator and the thiol sequentially.

The reaction temperature after the polymerization is preferably 50 to 150° C., more preferably 60 to 100° C. In addition, the reaction time after the polymerization is preferably 2 to 24 hours, and from the viewpoint of production efficiency, more preferably 2 to 5 hours.

Specific examples of the organic solvent to be used in the polymerization reaction include toluene, benzene, THF, diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and Y-butyrolactone (GBL). Specific examples of the polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The amount of the polymerization initiator to be added is preferably 0.01 to 25 mol % of the total amount of the monomers to be polymerized.

A polymer synthesized by living radical polymerization has a narrow dispersity, and therefore, when used for a resist, roughness can be reduced and uniform solubility can be achieved. Therefore, such a polymer hardly swells, and is effective for preventing pattern collapse of a line-and-space pattern and a phenomenon where the space between patterns in a contact hole pattern becomes blocked.

Note that the amount of each monomer in the monomer solution can be, for example, set appropriately to achieve the preferable content ratios of the above-described repeating units.

### [Solvent]

The inventive resist composition contains a solvent. The solvent is not particularly limited as long as the solvent dissolves the hypervalent iodine compound, the carboxy-group-containing compound, and other components described later and allows film formation. As such a solvent, organic solvents are preferable, and specific examples thereof include: ketones, such as cyclohexanone, methyl-2-n-pentyl ketone, and methyl isoamyl ketone; alcohols, such as 3-methoxybutanol, 3-methyl-3-methoxybutanol, 1-methoxy-2-propanol, 1-ethoxy-2-propanol, diacetone alcohol, 4-methyl-2-pentanol, and methyl 2-hydroxyisobutyrate; ethers, such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters, such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; carboxylic acids, such as formic acid, acetic acid, and propionic acid; lactones, such as γ-butyrolactone; and mixed solvents thereof.

In the inventive resist composition, the amount of the solvent contained is preferably such an amount that the concentration of the solid contents in the resist composition is 0.1 to 20 mass %, more preferably 0.1 to 15 mass %, and further preferably 0.1 to 10 mass %. Note that, in the present invention, solid contents is a general term for the components other than the solvent out of all the components of the resist composition. One kind of the solvent may be used, or two or more kinds thereof may be used in mixture.

### [Other Components]

The resist composition may further contain a surfactant. As the surfactant, a fluorine-based and/or silicone-based surfactant is preferable. Examples of such a surfactant include surfactants disclosed in paragraph [0276] of US2008/0248425A1. Furthermore, it is also possible to use a surfactant disclosed in paragraph [0280] of US2008/0248425A1, other than the fluorine-based and/or silicone-based surfactants.

When the resist composition contains the surfactant, the contained amount is preferably 0.0001 to 2 mass % of all the solid contents. One kind of the surfactant may be used, or two or more kinds thereof may be used in combination.

The resist composition may further contain a radical scavenger. When a radical scavenger is contained, the photoreaction during photolithography can be controlled, and sensitivity can be adjusted.

Examples of the radical scavenger include hindered phenols, quinones, hindered amines, and thiol compounds. Specifically, examples of the hindered phenols include dibutylhydroxytoluene (BHT) and 2,2′-methylenebis(4-methyl-6-tert-butylphenol). Examples of the quinones include 4-methoxyphenol (methoquinone) and hydroquinone. Examples of the hindered amines include 2,2,6,6-tetramethylpiperidine and 2,2,6,6-tetramethylpiperidine-N-oxy radical. Examples of the thiols include dodecanethiol and hexadecanethiol.

When the resist composition contains the radical scavenger, the contained amount is preferably 0.01 to 10 mass % of all the solid contents. One kind of the radical scavenger may be used, or two or more kinds thereof may be used in combination.

The resist composition may further contain a crosslinking agent. When a crosslinking agent is contained, the crosslinking reaction during photolithography can be promoted, the glass transition temperature of the pattern can be increased, and a pattern that is excellent in the resolution of a thin line can be obtained.

Examples of the crosslinking agent include compounds having a carbon-carbon unsaturated bond as a functional group, such as a vinyl group, a (meth)acrylate group, an allyl group, an alkynyl group, and an aromatic ring. Specifically, examples of compounds having a vinyl group include chain alkenes, branched alkenes, and cyclic alkenes, each optionally having a substituent. Examples of compounds having a (meth)acrylate group include acrylic acid, methacrylic acid, acrylic acid ester, and methacrylic acid ester, each optionally having a substituent. Examples of compounds having an allyl group include allyl alcohol, allyl ether, allyl ester, allyl amide, allylamine, and allyl-group-containing isocyanurates, each optionally having a substituent. Examples of compounds having an alkynyl group include chain alkynes, branched alkynes, cyclic alkynes, alkynyl alcohols, alkynyl ethers, alkynyl esters, alkynyl amides, alkynyl amines, and alkynyl-group-containing isocyanurates, each optionally having a substituent. Examples of compounds having an aromatic ring include arenes, heteroarenes, styrene, stilbene, phenylacetylene, acenaphthylene, and chalcone, each optionally having a substituent. The crosslinking agent may have only one of the functional groups, or may have a plurality of the groups. The number of the functional groups contained in the crosslinking agent is preferably 1 or more and 10 or less, more preferably 2 or more and 8 or less.

When the resist composition contains the crosslinking agent, the contained amount is preferably 0.01 to 50 mass % of all the solid contents. One kind of the crosslinking agent may be used, or two or more kinds thereof may be used in combination.

When the resist composition contains the crosslinking agent, a photo-polymerization initiator may further be contained. The photo-polymerization initiator generates radicals when irradiated with a high-energy beam, and can promote the crosslinking of the crosslinking agent.

Specific examples of the photo-polymerization initiator include: benzophenone derivatives, such as benzophenone, methyl O-benzoylbenzoate, 4-benzoyl-4′-methyldiphenyl ketone, dibenzyl ketone, and fluorenone; acetophenone derivatives, such as 2,2′-diethoxyacetophenone, 2-hydroxy-2-methylpropiophenone, 2,2-dimethoxy-1,2-diphenylethan-1-one, 1-hydroxycyclohexyl phenyl ketone, 2-methyl-1-[4-(methylthio)phenyl]-2-morpholinopropan-1-one, 2-hydroxy-1-{4-[4-(2-hydroxy-2-methylpropionyl)-benzyl]-phenyl}-2-methylpropan-1-one, and methyl phenylglyoxylate; thioxanthone derivatives, such as thioxanthone, 2-methylthioxanthone, 2-isopropylthioxanthone, 4-isopropylthioxanthone, 2-chlorothioxanthone, and diethylthioxanthone; benzyl derivatives, such as benzyl, benzyldimethyl ketal, and benzyl-β-methoxyethyl acetal; benzoin derivatives, such as benzoin, benzoin methyl ether, and 2-hydroxy-2-methyl-1-phenylpropan-1-one; oxime compounds, such as 1-phenyl-1,2-butanedione-2-(O-methoxycarbonyl) oxime, 1-phenyl-1,2-propanedione-2-(0-methoxycarbonyl) oxime, 1-phenyl-1,2-propanedione-2-(0-ethoxycarbonyl) oxime, 1-phenyl-1,2-propanedione-2-(0-benzoyl) oxime, 1,3-diphenylpropanetrione-2-(O-ethoxycarbonyl) oxime, 1-phenyl-3-ethoxypropantrione-2-(O-benzoyl) oxime, 1,2-octanedione-1-[4-(phenylthio)-2-(0-benzoyloxime), ethenone-1-[9-ethyl-6-(2-methylbenzoyl)-9H-carbazol-3-yl]-1-(0-acetyloxime); α-hydroxyketone compounds, such as 2-hydroxy-2-methyl-1-phenylpropan-1-one, 1-[4-(2-hydroxyethoxy)phenyl]-2-hydroxy-2-methyl-1-propan-1-one, and 2-hydroxy-1-{4-[4-(2-hydroxy-2-methylpropiony])-benzyl]phenyl}-2-methylpropane; α-aminoalkylphenone compounds, such as 2-benzyl-2-dimethylamino-1-(4-morpholinophenyl)-butanone-1 and 2-dimethylamino-2-(4-methylbenzyl)-1-(4-morpholin-4-yl-phenyl) butan-1-one; phosphine oxide compounds, such as bis(2,4,6-trimethylbenzoyl)-phenylphosphine oxide, bis(2,6-dimethoxybenzoyl)-2,4,4-trimethyl-pentylphosphine oxide, and 2,4,6-trimethylbenzoyldiphenylphosphine oxide; and titanocene compounds, such as bis(η5-2,4-cyclopentadien-1-yl)-bis(2,6-difluoro-3-(1H-pyrrol-1-yl)phenyl) titanium.

When the resist composition contains the photo-polymerization initiator, the contained amount is preferably 0.1 to 10 mass %, more preferably 0.1 to 5 mass %, and most preferably 0.1 to 1 mass % of all the solid contents. When the amount is 0.1 mass % or more, a blending effect can be achieved sufficiently.

The resist composition mainly contains a hypervalent iodine compound and a carboxy-group-containing compound as described above, and polymers containing acid-labile groups and photo-acid generators, which are contained in conventional chemically amplified resist compositions, are not essential. However, the inventive resist composition makes it possible to form a positive pattern, where exposed portions become soluble in a developer, or a negative pattern, where exposed portions become insoluble in a developer, especially by exposure to EB or EUV. The mechanism is not completely clear, but the following conjecture can be made, for example.

A hypervalent iodine compound preferred in the present invention is a compound having a tricoordinate hypervalent iodine having an aryl group and a carboxylate ligand. It can be assumed that when such a tricoordinate iodine compound is mixed with a carboxy-group-containing compound, exchange with the carboxylate ligand occurs as an equilibrium reaction. In this event, if the original carboxylate ligand can be removed by some method, a hypervalent iodine compound having a new ligand is generated. For example, when 1-iodonaphthylene diacetate, which is a hypervalent iodine compound, and a carboxy-group-containing compound are mixed together and the generated acetic acid, having a low boiling point, is removed, ligand exchange is completed. Here, a polymer in which the carboxy-group-containing compound is crosslinked with the hypervalent iodine compound is obtained.

The polymer crosslinked with the hypervalent iodine compound is generated at the time of film formation. This is because such a crosslinked polymer is insoluble in most organic solvents, and therefore, a solution cannot be prepared even if the polymer is synthesized beforehand. This is conjectured to be because the hypervalent iodine compound, originally having low solvent solubility due to high polarization, contains the carboxy-group-containing compound as a ligand, and thus, solubility is even more degraded. Accordingly, in this step, it is desirable to remove the original low-molecular-weight carboxylic acid component at the time of film formation and in the subsequent baking process, thus completing the ligand exchange reaction and also forming a resist film.

The resist film obtained from the inventive resist composition changes in polarity by the hypervalent iodine compound, being the main component of the resist film, being decomposed by light, and a pattern is formed by a development process. The mechanism is not completely clear, but the following conjecture can be made, for example.

The inventive resist composition can be either a positive type or a negative type depending on the choice of components. In the case of a positive type, a polymer in which a hypervalent iodine compound is bonded is contained at the time of film formation. By the polymer being decomposed due to light, a monovalent iodine compound is formed, and at the same time, the bond between the carboxy-group-containing compound and the hypervalent iodine compound is removed, and the molecular weight is reduced. It is conjectured that, as a result, a positive pattern, where exposed portions are removed with an organic solvent, is formed.

On the other hand, in the case of a negative type, a polymer generated at the time of film formation, crosslinked with a hypervalent iodine compound, is contained. By the polymer being decomposed due to light, exchange of cross links or bonds occurs, and increase in molecular weight and polarity conversion occurs. It is conjectured that, as a result, a negative pattern, where unexposed portions are removed with an aqueous alkaline solution, is formed.

From the above-described conjecture, it can be said that the inventive resist composition is a non-chemically amplified resist composition. The inventive resist composition does not require an acid-labile group-containing polymer or a photo-acid generator, unlike conventional chemically amplified resist compositions. Therefore, adverse effects (e. g. image blurs) due to acid diffusion do not occur, and resolution of a fine pattern is possible.

The inventive resist composition is extremely effective, especially in EUV lithography. This results from iodine atoms, which are capable of greatly absorbing EUV light, being contained. That is, shot noise can be reduced, and higher resolution and lower LWR can be achieved.

As an EUV resist composition with which a fine pattern can be formed, reported is a metal resist that mainly contains a compound of tin, which is a metal having a high absorbance of EUV light in the same manner as iodine atoms (e. g. Patent Document 2). However, as described above, such a metal resist has many issues such as insufficient solubility in a solvent, storage stability, and defects due to residues after etching caused by a metal element being contained. On the other hand, the inventive resist composition has an advantage over metal resists regarding defects, since a metal element is not used, and there are no problems regarding solubility in a solvent either. Moreover, the inventive resist composition is applicable in the case of either a positive type or a negative type, and therefore, has a wide range of uses. For example, in a contact hole formation process, a reversal process step is necessary after forming a pillar pattern in the case of a metal resist performed with negative development, but such a step is unnecessary in the case of a positive resist. Therefore, it can be said that the inventive resist composition is more useful than metal resists from the viewpoint of the simplicity and convenience of the process as well.

The resist film preferably has a film thickness of 10 to 70 nm, more preferably 20 to 50 nm.

The resist composition may contain a photo-acid generator. By a photo-acid generator being contained in the inventive resist composition, a positive pattern can be formed with higher sensitivity compared to a resist composition containing no photo-acid generator. The mechanism is not completely clear, but the following conjecture can be made, for example.

In the inventive resist composition, by a photo-acid generator being contained, the acid generated from the photo-acid generator in the process of exposing the resist is exchanged with the ligand of the hypervalent iodine compound to form a new ligand, and thus, the bond between the carboxy-group-containing polymer and the hypervalent iodine compound is removed. It is conjectured that, therefore, in addition to scission of the I-O bond caused by light, polarity conversion caused by exchange with a new ligand caused by the acid generated from the photo-acid generator occurs, or decrease in the molecular weight occurs, and a positive pattern can be formed with high sensitivity by development with an organic solvent.

From the above conjecture, the inventive resist composition is a non-chemically amplified resist composition containing a photo-acid generator, and does not require an acid-labile group-containing polymer, unlike conventional chemically amplified resist compositions. Therefore, the acid generated from the photo-acid generator reacts with the ligand of the hypervalent iodine compound in exposed portions to form a new ligand of the hypervalent iodine. That is, unlike chemically amplified resist compositions, the composition does not have an amplification mechanism, where a reaction with an acid-labile-group occurs and an acid is regenerated, and therefore, adverse effects (e. g. image blurs) due to acid diffusion do not occur and a fine pattern can be resolved.

Specific examples of the photo-acid generator include the following onium salt compounds.

### [Onium Salt Compound]

The onium salt compounds contain, as a cation, a sulfonium cation represented by the following formula (5-1) or an iodonium cation represented by the following formula (5-2).

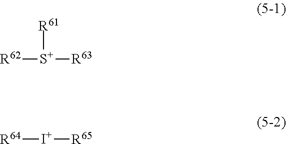

In the formulae (5-1) and (5-2), R⁶¹ to R⁶⁵ each independently represent a halogen atom or a hydrocarbyl group having 1 to 30 carbon atoms and optionally containing a heteroatom.

Specific examples of the halogen atom represented by R⁶¹ to R⁶⁵ include a fluorine atom, a chlorine atom, a bromine atom, and an iodine atom.

The hydrocarbyl group represented by R⁶¹ to R⁶⁵ may be saturated or unsaturated, and may be linear, branched, or cyclic. Specific examples thereof include: alkyl groups having 1 to 30 carbon atoms, such as a methyl group, an ethyl group, an n-propyl group, an isopropyl group, an n-butyl group, an isobutyl group, a sec-butyl group, and a tert-butyl group; cyclic saturated hydrocarbyl groups having 3 to 30 carbon atoms, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups having 2 to 30 carbon atoms, such as a vinyl group, an allyl group, a propenyl group, a butenyl group, and a hexenyl group; cyclic unsaturated hydrocarbyl groups having 3 to 30 carbon atoms, such as a cyclohexenyl group; aryl groups having 6 to 30 carbon atoms, such as a phenyl group, a naphthyl group, and a thienyl group; aralkyl groups having 7 to 30 carbon atoms, such as a benzyl group, a 1-phenylethyl group, and a 2-phenylethyl group; groups which are combinations of these groups; etc. Aryl groups are preferable. Furthermore, part or all of the hydrogen atoms of the hydrocarbyl group may be substituted with a group containing a heteroatom, such as an oxygen atom, a sulfur atom, a nitrogen atom, or a halogen atom, and part of the —CH₂— of the hydrocarbyl group may be substituted with a group containing a heteroatom such as an oxygen atom, a sulfur atom, or a nitrogen atom. The resulting hydrocarbyl group may contain a hydroxy group, a fluorine atom, a chlorine atom, a bromine atom, an iodine atom, a cyano group, a nitro group, a carbonyl group, an ether bond, an ester bond, a sulfonic acid ester bond, a carbonate bond, a lactone ring, a sultone ring, a carboxylic anhydride (—C(═O)—O—C(═O)—), a haloalkyl group, etc.

Furthermore, R⁶¹ and R⁶² may be bonded to each other to form a ring together with the sulfur atom bonded thereto. In this case, specific examples of the structure of the ring include those represented by the following formulae.

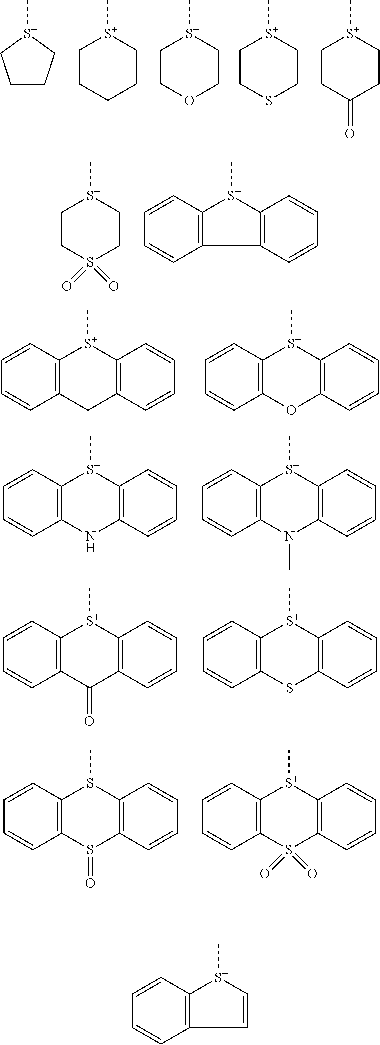

In the formulae, a broken line represents an attachment point to R⁶³.

Specific examples of the sulfonium cation represented by the formula (5-1) include the following, but are not limited thereto.

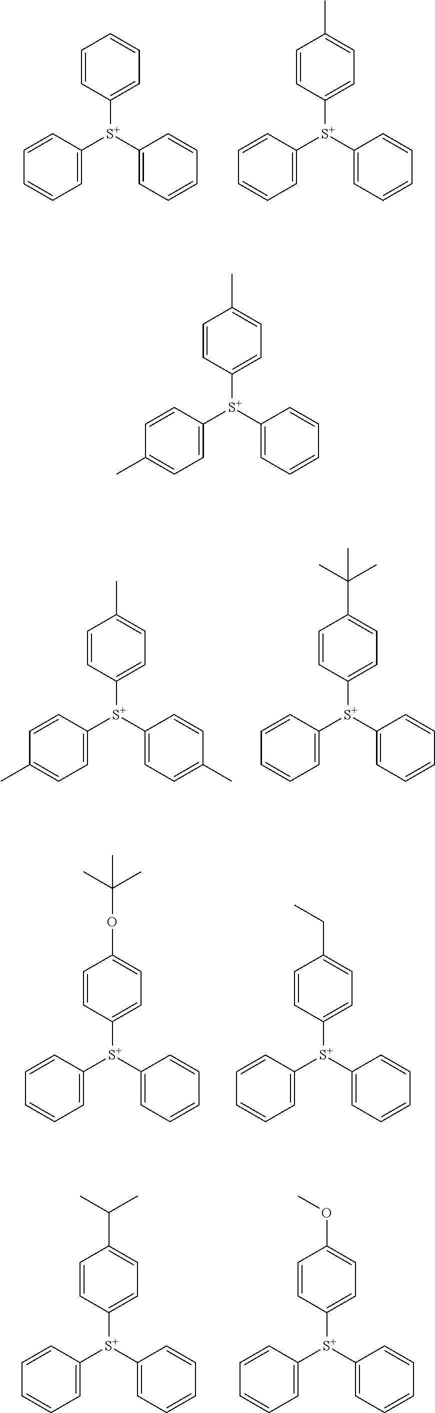

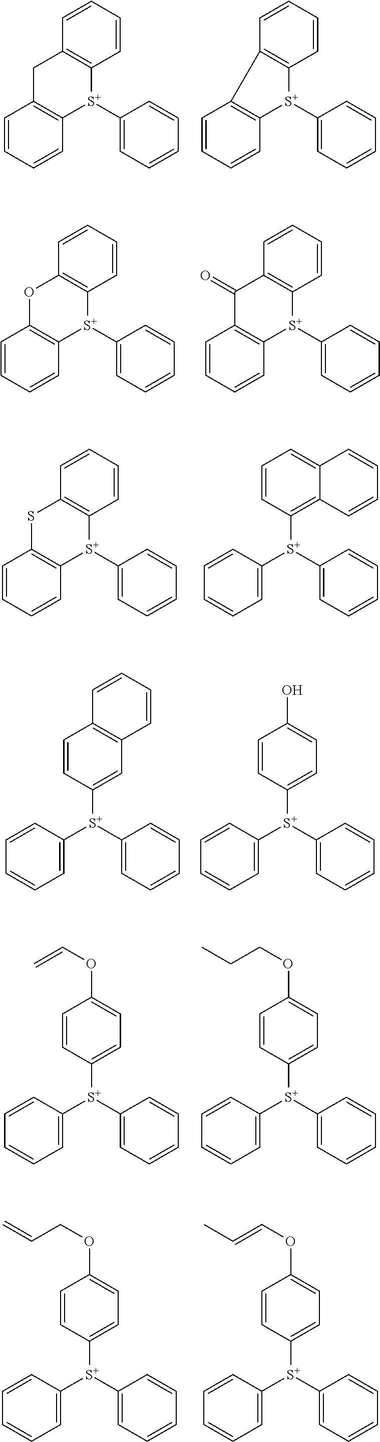

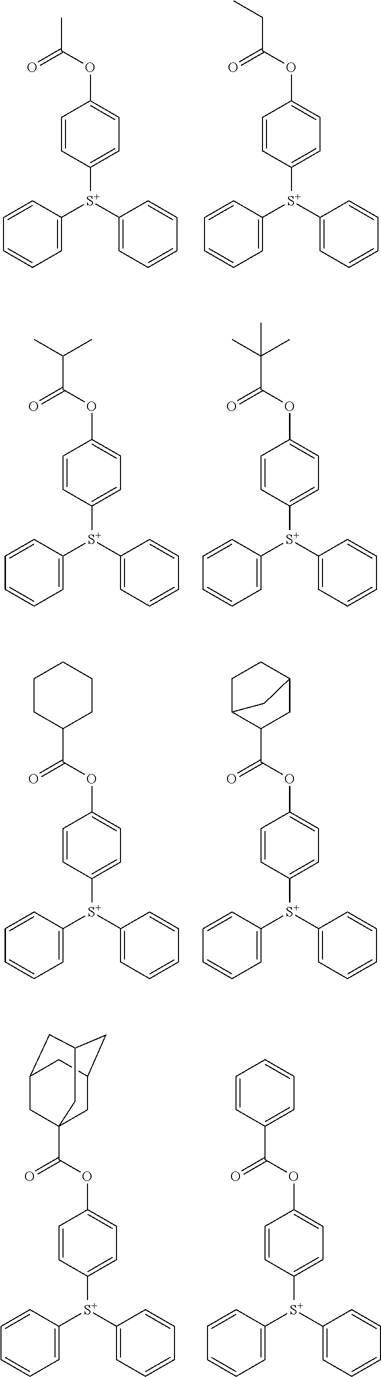

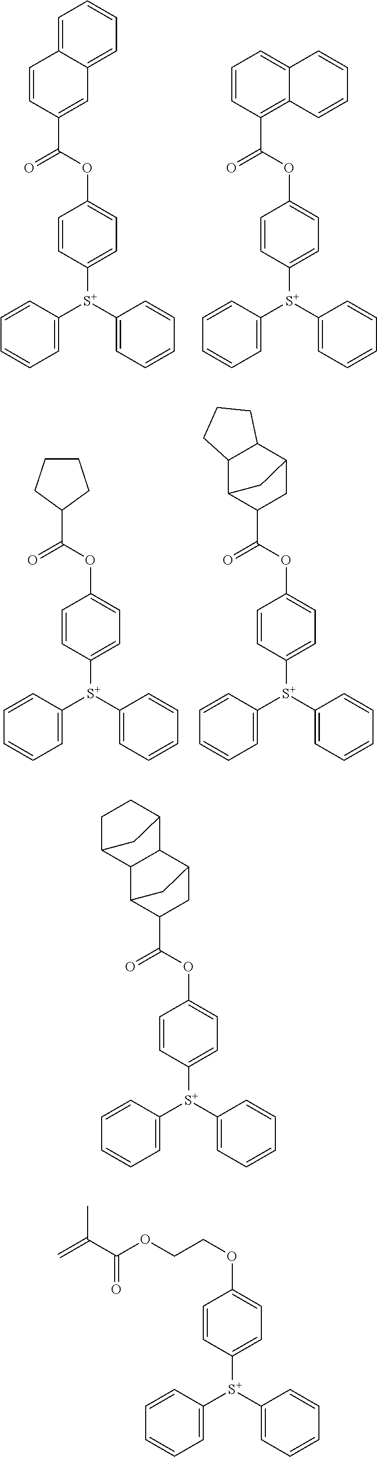 [SMILES: O=C(Oc1ccc([S+](c2ccccc2)c2ccccc2)cc1)c1ccc2ccccc2c1 ; O=C(Oc1ccc([S+](c2ccccc2)c2ccccc2)cc1)c1cccc2ccccc12 ; O=C(Oc1ccc([S+](c2ccccc2)c2ccccc2)cc1)C1CCCC1 ; O=C(Oc1ccc([S+](c2ccccc2)c2ccccc2)cc1)C1CC2CC1C1CCCC21 ; O=C(Oc1ccc([S+](c2ccccc2)c2ccccc2)cc1)C1CC2CC1C1C3CCC(C3)C21 ; C=C(C)C(=O)OCCOc1ccc([S+](c2ccccc2)c2ccccc2)cc1]

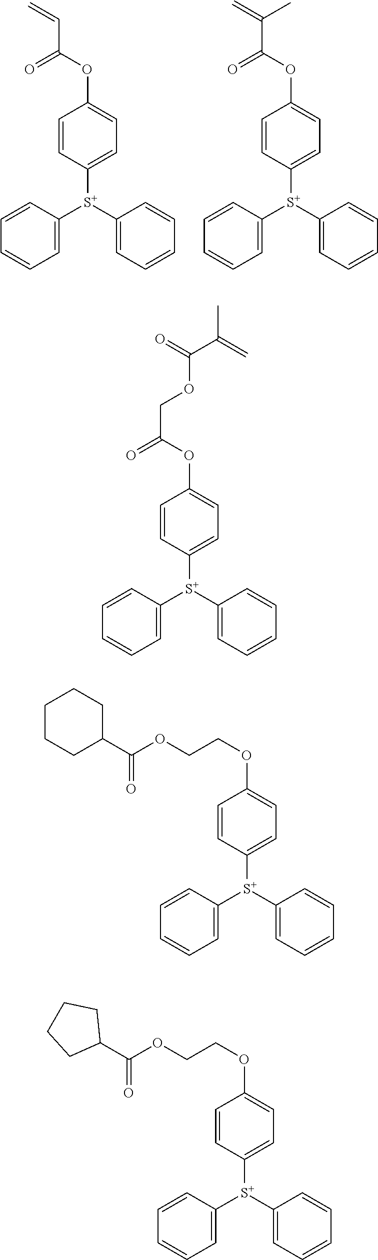 [SMILES: C=CC(=O)Oc1ccc([S+](c2ccccc2)c2ccccc2)cc1 ; C=C(C)C(=O)Oc1ccc([S+](c2ccccc2)c2ccccc2)cc1 ; C=C(C)C(=O)OCC(=O)Oc1ccc([S+](c2ccccc2)c2ccccc2)cc1 ; O=C(OCCOc1ccc([S+](c2ccccc2)c2ccccc2)cc1)C1CCCCC1 ; O=C(OCCOc1ccc([S+](c2ccccc2)c2ccccc2)cc1)C1CCCC1]

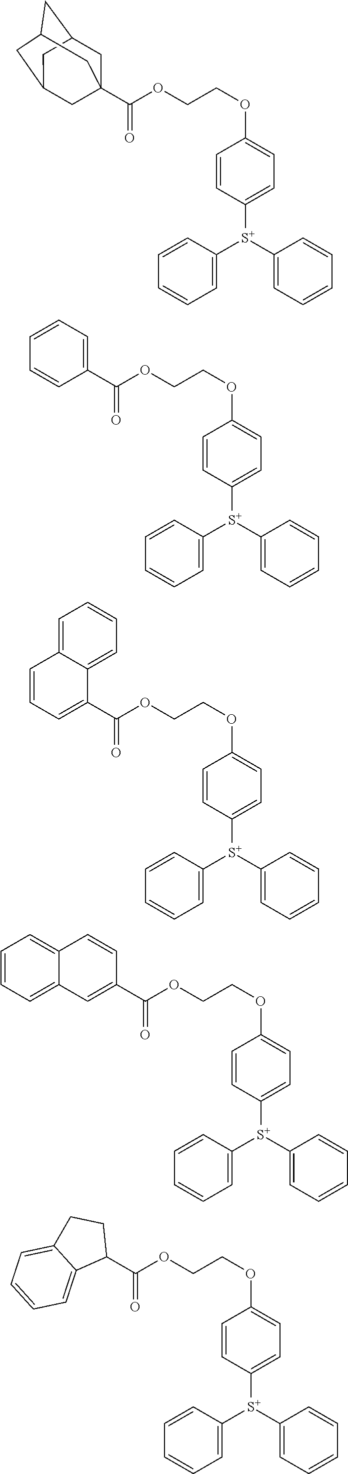 [SMILES: O=C(OCCOc1ccc([S+](c2ccccc2)c2ccccc2)cc1)C12CC3CC(CC(C3)C1)C2 ; O=C(OCCOc1ccc([S+](c2ccccc2)c2ccccc2)cc1)c1ccccc1 ; O=C(OCCOc1ccc([S+](c2ccccc2)c2ccccc2)cc1)c1cccc2ccccc12 ; O=C(OCCOc1ccc([S+](c2ccccc2)c2ccccc2)cc1)c1ccc2ccccc2c1 ; O=C(OCCOc1ccc([S+](c2ccccc2)c2ccccc2)cc1)C1CCc2ccccc21]

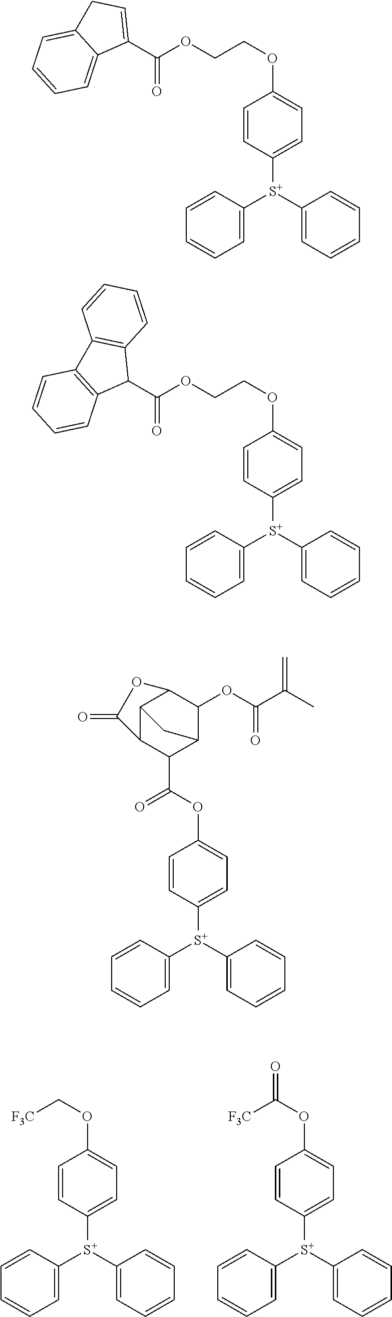 [SMILES: O=C(OCCOc1ccc([S+](c2ccccc2)c2ccccc2)cc1)C1=CCc2ccccc21 ; O=C(OCCOc1ccc([S+](c2ccccc2)c2ccccc2)cc1)C1c2ccccc2-c2ccccc21 ; C=C(C)C(=O)OC1C2CC3C1OC(=O)C3C2C(=O)Oc1ccc([S+](c2ccccc2)c2ccccc2)cc1 ; FC(F)(F)COc1ccc([S+](c2ccccc2)c2ccccc2)cc1 ; O=C(Oc1ccc([S+](c2ccccc2)c2ccccc2)cc1)C(F)(F)F]

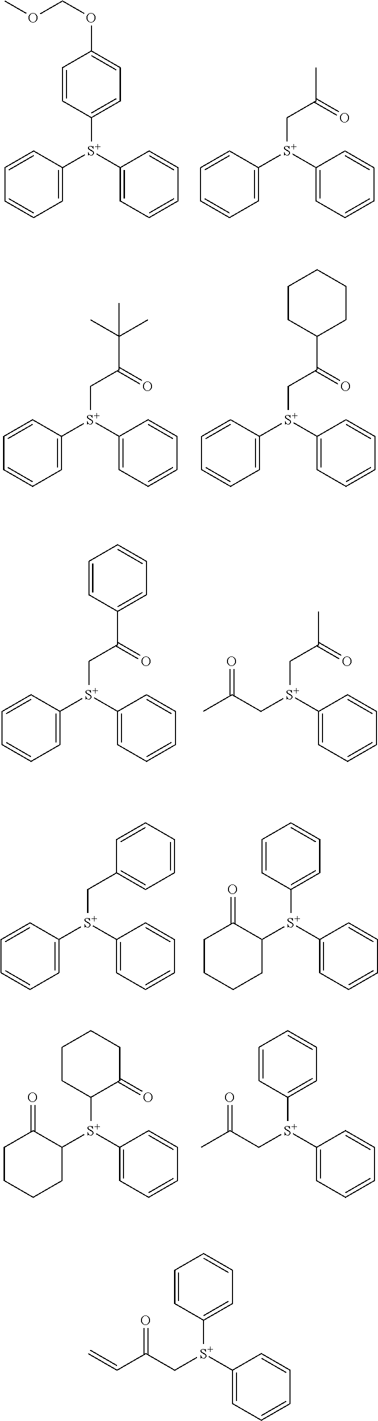

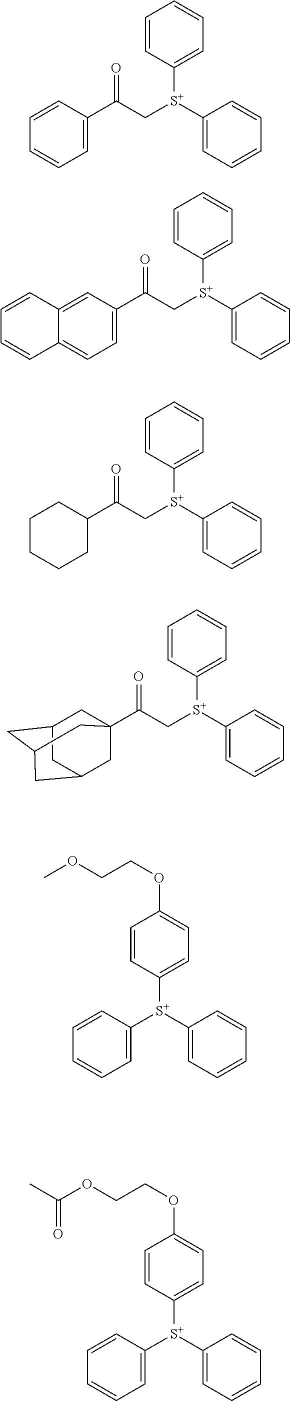 [SMILES: O=C(C[S+](c1ccccc1)c1ccccc1)c1ccccc1 ; O=C(C[S+](c1ccccc1)c1ccccc1)c1ccc2ccccc2c1 ; O=C(C[S+](c1ccccc1)c1ccccc1)C1CCCCC1 ; O=C(C[S+](c1ccccc1)c1ccccc1)C12CC3CC(CC(C3)C1)C2 ; COCCOc1ccc([S+](c2ccccc2)c2ccccc2)cc1 ; CC(=O)OCCOc1ccc([S+](c2ccccc2)c2ccccc2)cc1]

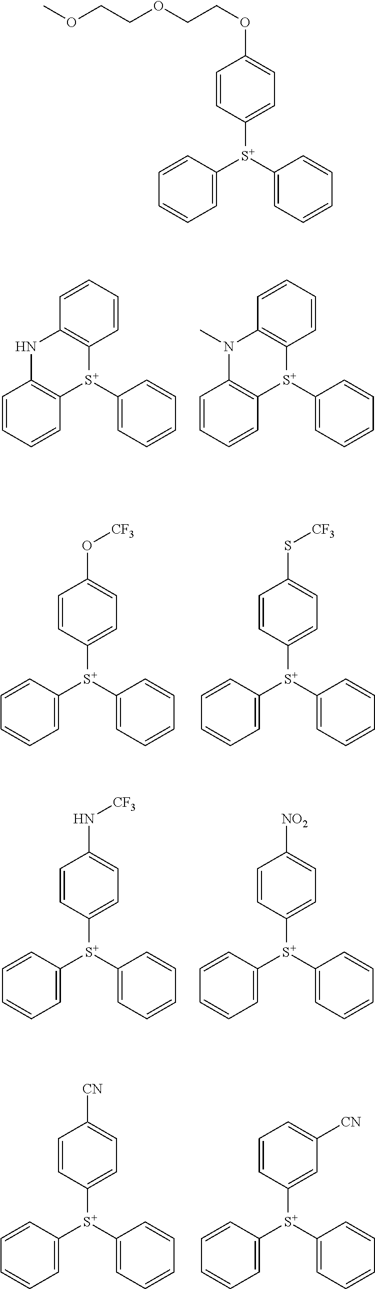

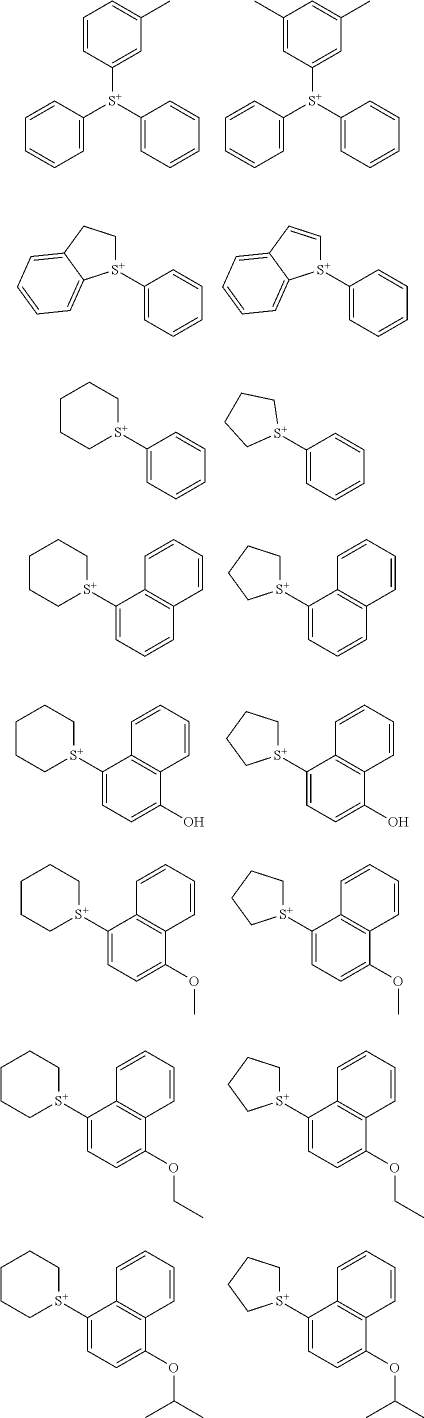

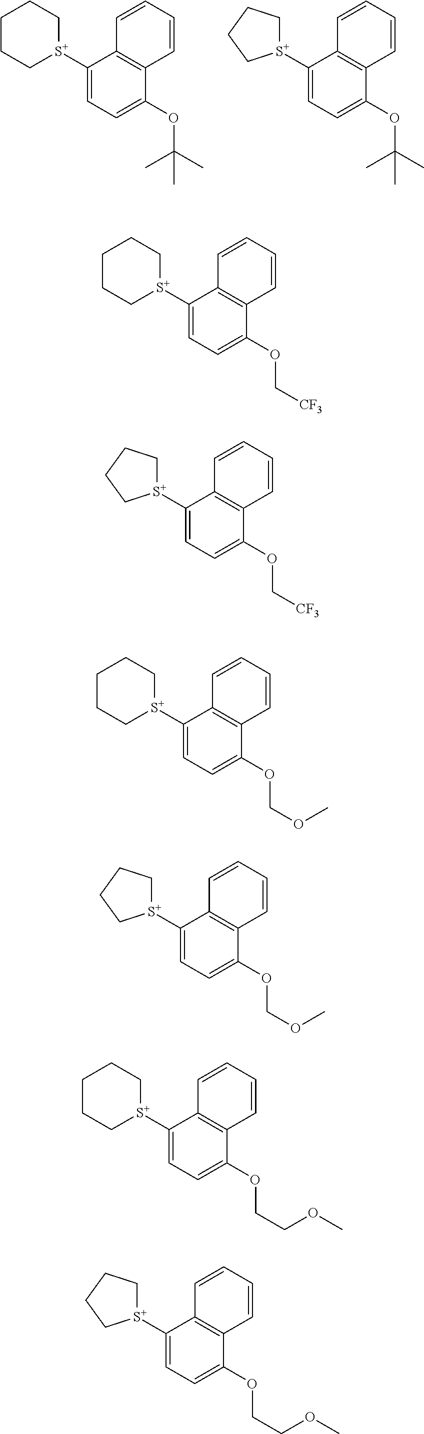

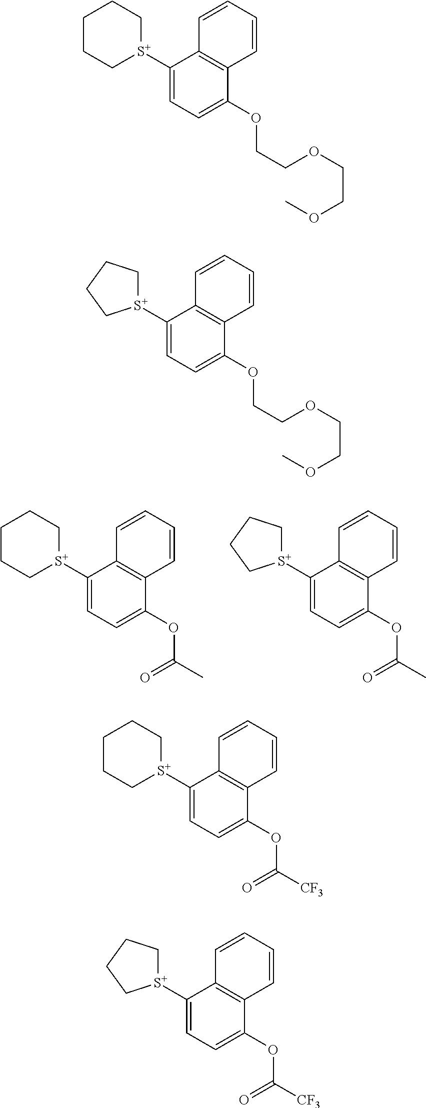 [SMILES: COCCOCCOc1ccc([S+]2CCCCC2)c2ccccc12 ; COCCOCCOc1ccc([S+]2CCCC2)c2ccccc12 ; CC(=O)Oc1ccc([S+]2CCCCC2)c2ccccc12 ; CC(=O)Oc1ccc([S+]2CCCC2)c2ccccc12 ; O=C(Oc1ccc([S+]2CCCCC2)c2ccccc12)C(F)(F)F ; O=C(Oc1ccc([S+]2CCCC2)c2ccccc12)C(F)(F)F]

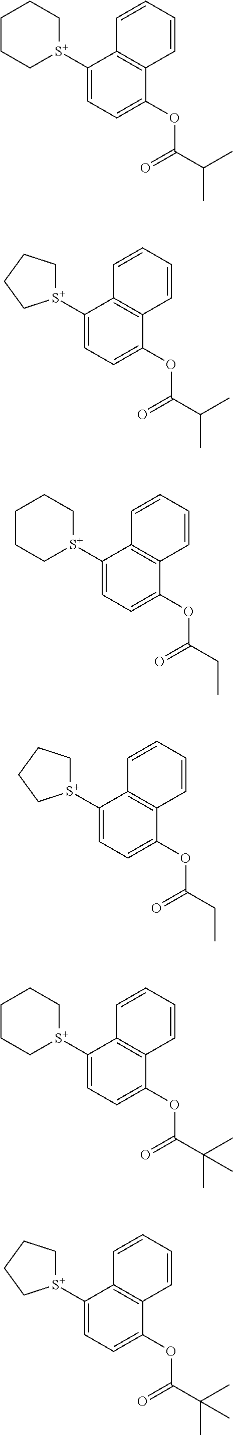 [SMILES: CC(C)C(=O)Oc1ccc([S+]2CCCCC2)c2ccccc12 ; CC(C)C(=O)Oc1ccc([S+]2CCCC2)c2ccccc12 ; CCC(=O)Oc1ccc([S+]2CCCCC2)c2ccccc12 ; CCC(=O)Oc1ccc([S+]2CCCC2)c2ccccc12 ; CC(C)(C)C(=O)Oc1ccc([S+]2CCCCC2)c2ccccc12 ; CC(C)(C)C(=O)Oc1ccc([S+]2CCCC2)c2ccccc12]

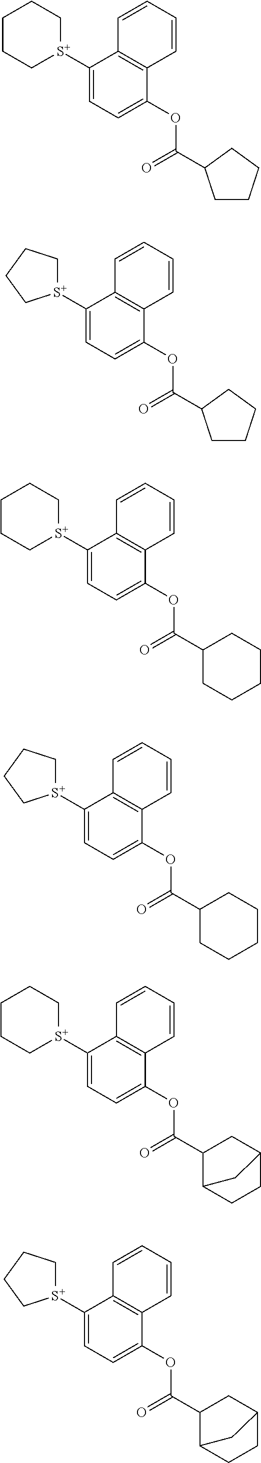 [SMILES: O=C(Oc1ccc([S+]2CCCCC2)c2ccccc12)C1CCCC1 ; O=C(Oc1ccc([S+]2CCCC2)c2ccccc12)C1CCCC1 ; O=C(Oc1ccc([S+]2CCCCC2)c2ccccc12)C1CCCCC1 ; O=C(Oc1ccc([S+]2CCCC2)c2ccccc12)C1CCCCC1 ; O=C(Oc1ccc([S+]2CCCCC2)c2ccccc12)C1CC2CCC1C2 ; O=C(Oc1ccc([S+]2CCCC2)c2ccccc12)C1CC2CCC1C2]

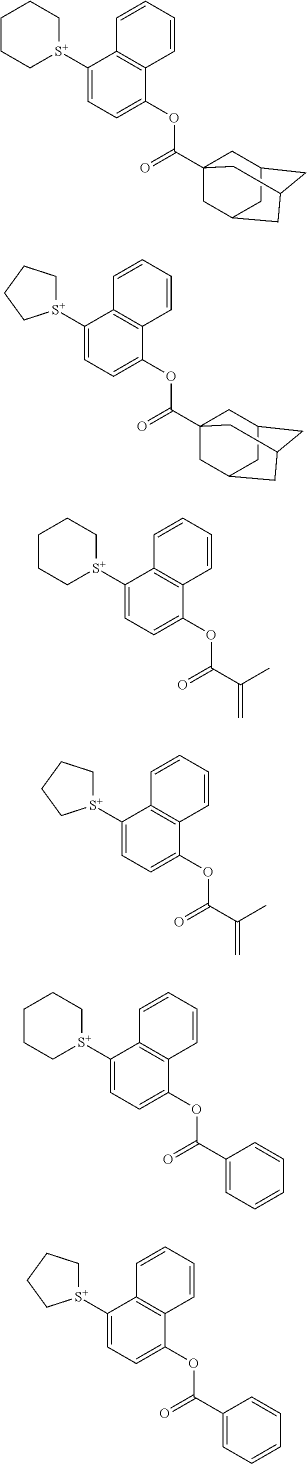 [SMILES: O=C(Oc1ccc([S+]2CCCCC2)c2ccccc12)C12CC3CC(CC(C3)C1)C2 ; O=C(Oc1ccc([S+]2CCCC2)c2ccccc12)C12CC3CC(CC(C3)C1)C2 ; C=C(C)C(=O)Oc1ccc([S+]2CCCCC2)c2ccccc12 ; C=C(C)C(=O)Oc1ccc([S+]2CCCC2)c2ccccc12 ; O=C(Oc1ccc([S+]2CCCCC2)c2ccccc12)c1ccccc1 ; O=C(Oc1ccc([S+]2CCCC2)c2ccccc12)c1ccccc1]

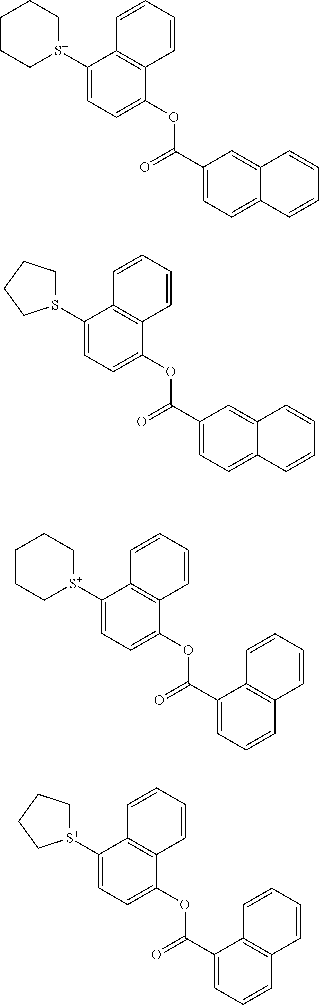 [SMILES: O=C(Oc1ccc([S+]2CCCCC2)c2ccccc12)c1ccc2ccccc2c1 ; O=C(Oc1ccc([S+]2CCCC2)c2ccccc12)c1ccc2ccccc2c1 ; O=C(Oc1ccc([S+]2CCCCC2)c2ccccc12)c1cccc2ccccc12 ; O=C(Oc1ccc([S+]2CCCC2)c2ccccc12)c1cccc2ccccc12]

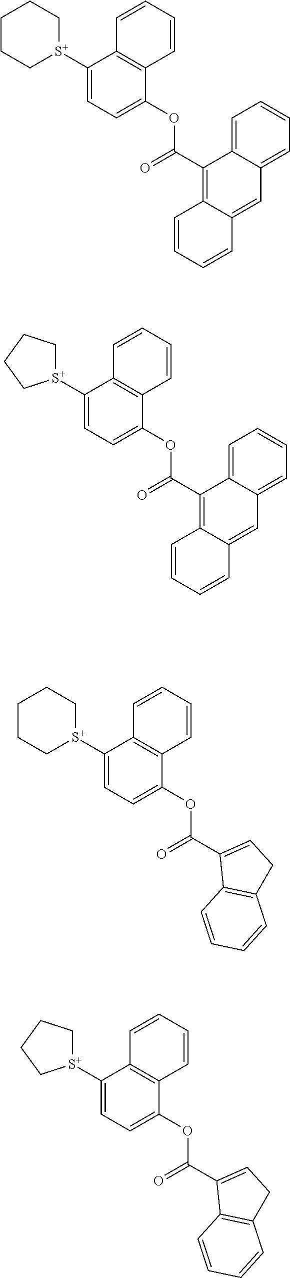 [SMILES: O=C(Oc1ccc([S+]2CCCCC2)c2ccccc12)c1c2ccccc2cc2ccccc12 ; O=C(Oc1ccc([S+]2CCCC2)c2ccccc12)c1c2ccccc2cc2ccccc12 ; O=C(Oc1ccc([S+]2CCCCC2)c2ccccc12)C1=CCc2ccccc21 ; O=C(Oc1ccc([S+]2CCCC2)c2ccccc12)C1=CCc2ccccc21]

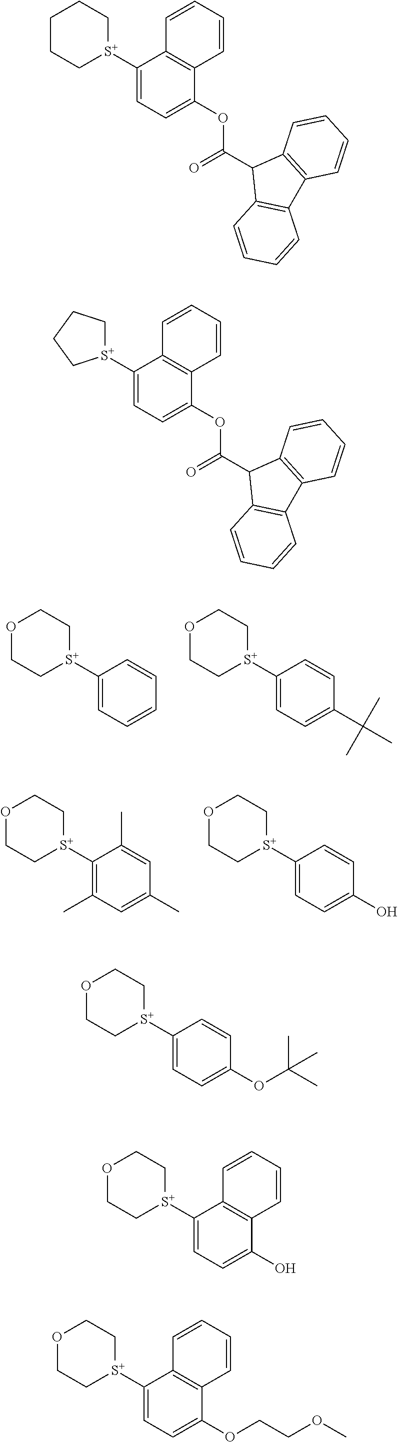

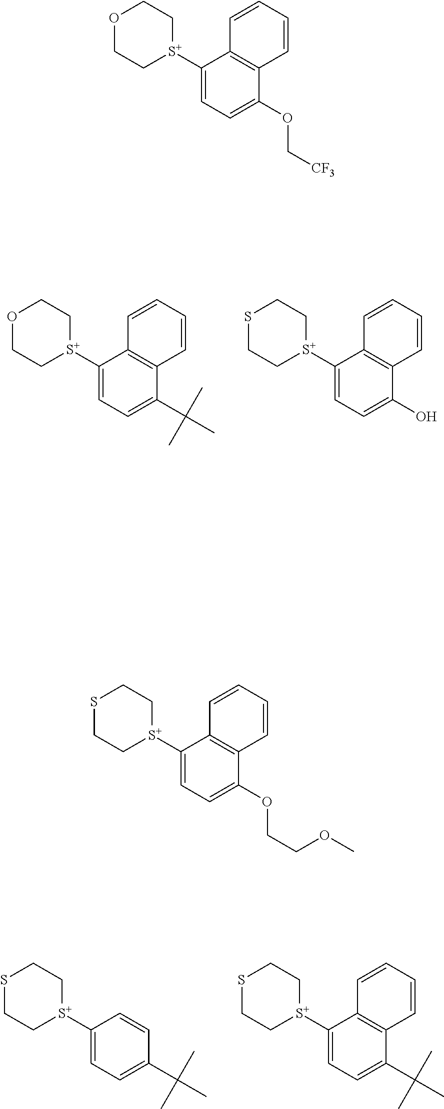 [SMILES: FC(F)(F)COc1ccc([S+]2CCOCC2)c2ccccc12 ; CC(C)(C)c1ccc([S+]2CCOCC2)c2ccccc12 ; Oc1ccc([S+]2CCSCC2)c2ccccc12 ; COCCOc1ccc([S+]2CCSCC2)c2ccccc12 ; CC(C)(C)c1ccc([S+]2CCSCC2)cc1 ; CC(C)(C)c1ccc([S+]2CCSCC2)c2ccccc12]

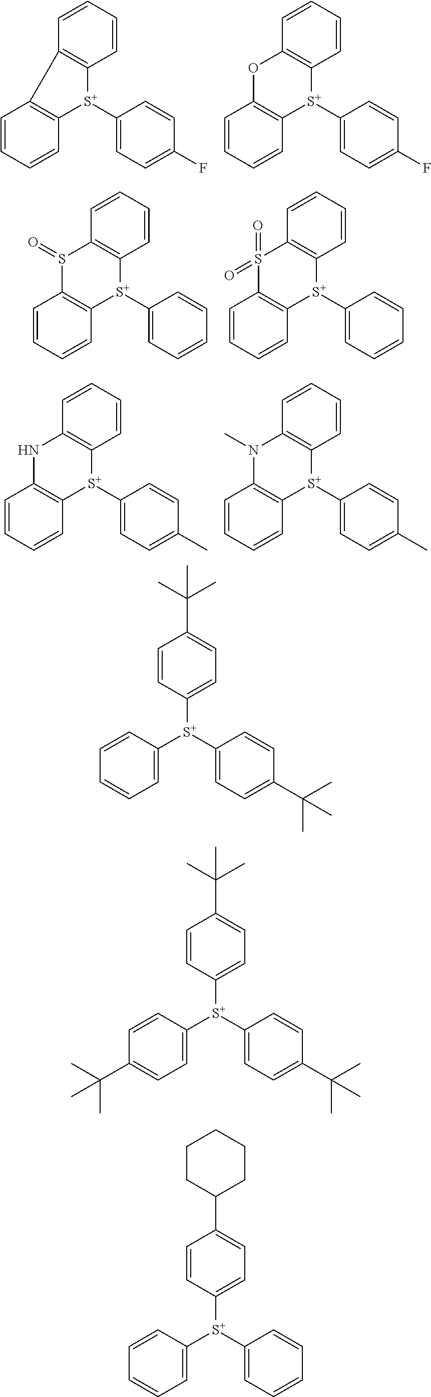

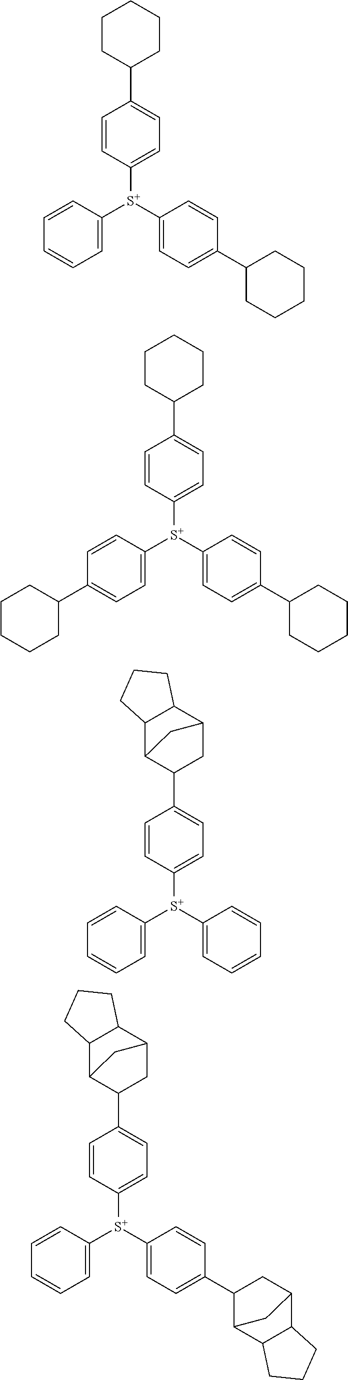 [SMILES: c1ccc([S+](c2ccc(C3CCCCC3)cc2)c2ccc(C3CCCCC3)cc2)cc1 ; c1cc([S+](c2ccc(C3CCCCC3)cc2)c2ccc(C3CCCCC3)cc2)ccc1C1CCCCC1 ; c1ccc([S+](c2ccccc2)c2ccc(C3CC4CC3C3CCCC43)cc2)cc1 ; c1ccc([S+](c2ccc(C3CC4CC3C3CCCC43)cc2)c2ccc(C3CC4CC3C3CCCC43)cc2)cc1]

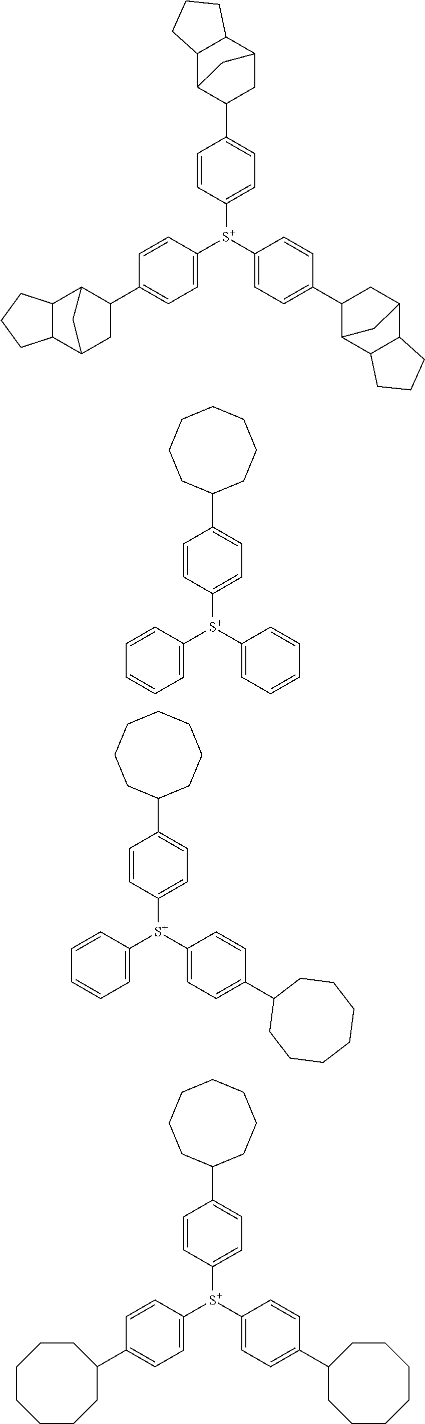 [SMILES: c1cc([S+](c2ccc(C3CC4CC3C3CCCC43)cc2)c2ccc(C3CC4CC3C3CCCC43)cc2)ccc1C1CC2CC1C1CCCC21 ; c1ccc([S+](c2ccccc2)c2ccc(C3CCCCCCC3)cc2)cc1 ; c1ccc([S+](c2ccc(C3CCCCCCC3)cc2)c2ccc(C3CCCCCCC3)cc2)cc1 ; c1cc([S+](c2ccc(C3CCCCCCC3)cc2)c2ccc(C3CCCCCCC3)cc2)ccc1C1CCCCCCC1]

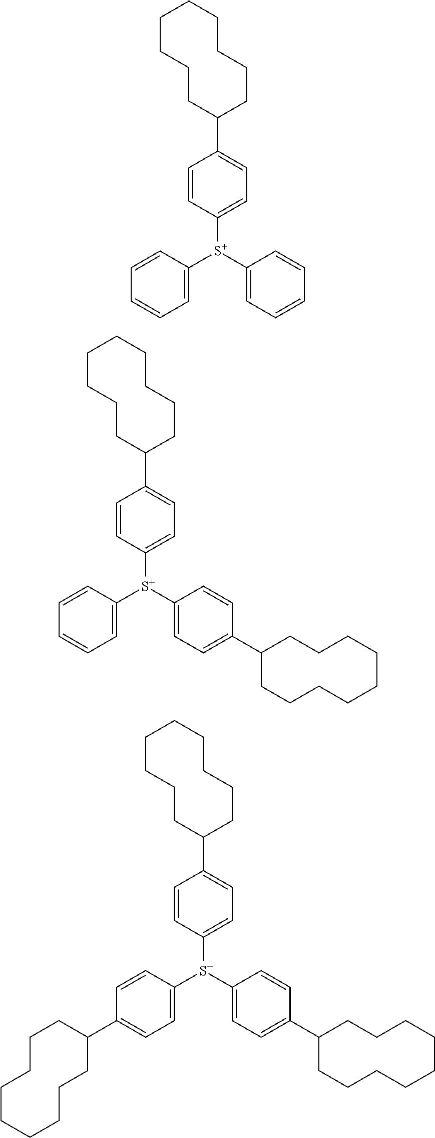 [SMILES: c1ccc([S+](c2ccccc2)c2ccc(C3CCCCCCCCC3)cc2)cc1 ; c1ccc([S+](c2ccc(C3CCCCCCCCC3)cc2)c2ccc(C3CCCCCCCCC3)cc2)cc1 ; c1cc([S+](c2ccc(C3CCCCCCCCC3)cc2)c2ccc(C3CCCCCCCCC3)cc2)ccc1C1CCCCCCCCC1]

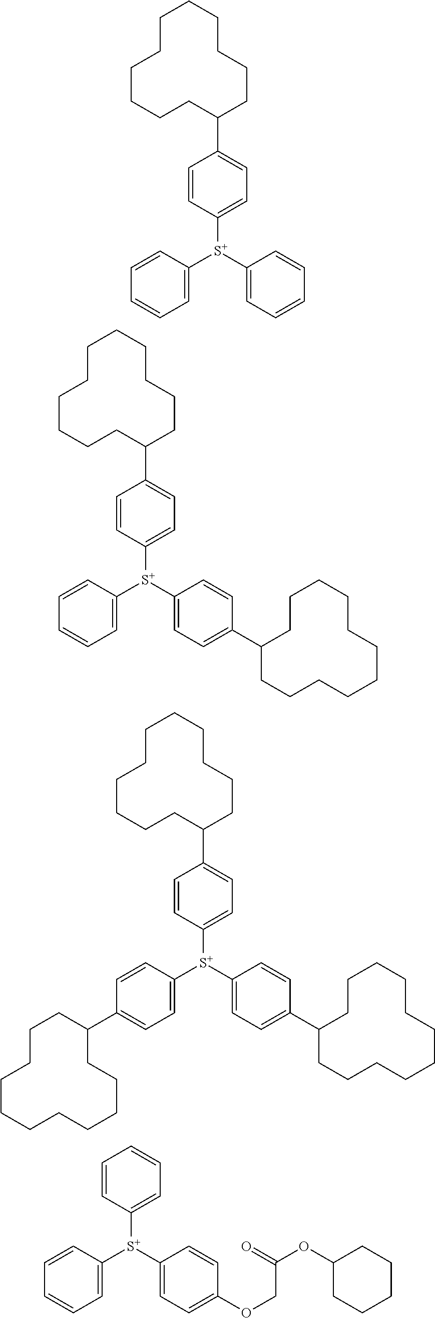 [SMILES: c1ccc([S+](c2ccccc2)c2ccc(C3CCCCCCCCCCC3)cc2)cc1 ; c1ccc([S+](c2ccc(C3CCCCCCCCCCC3)cc2)c2ccc(C3CCCCCCCCCCC3)cc2)cc1 ; c1cc([S+](c2ccc(C3CCCCCCCCCCC3)cc2)c2ccc(C3CCCCCCCCCCC3)cc2)ccc1C1CCCCCCCCCCC1 ; O=C(COc1ccc([S+](c2ccccc2)c2ccccc2)cc1)OC1CCCCC1]

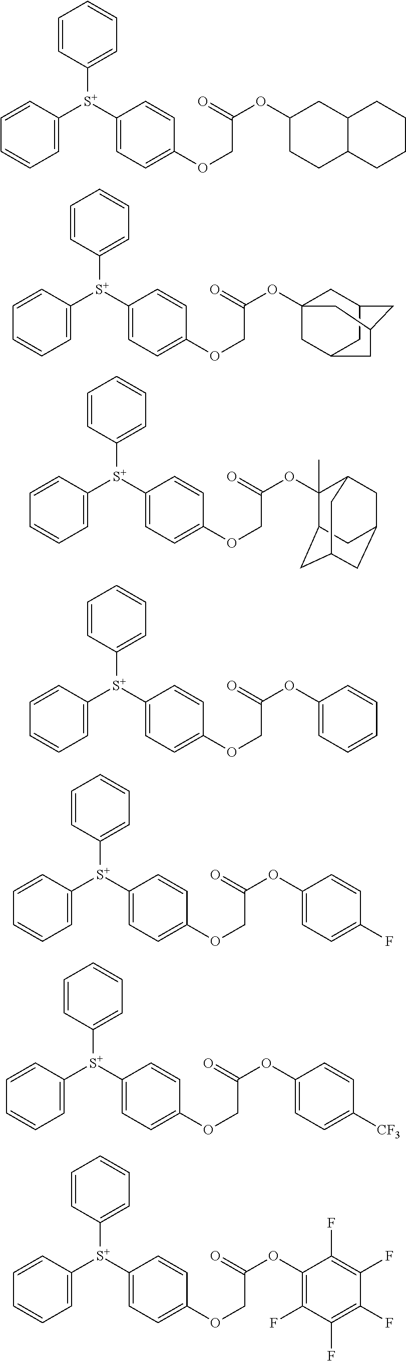

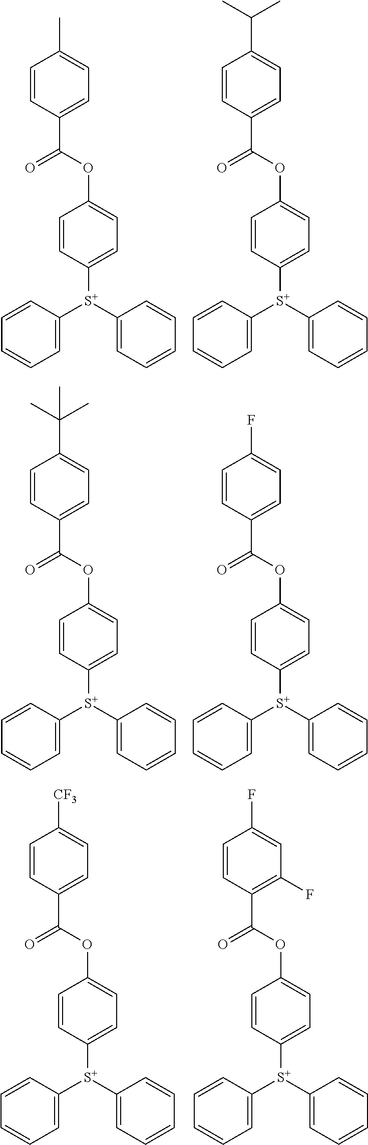 [SMILES: Cc1ccc(C(=O)Oc2ccc([S+](c3ccccc3)c3ccccc3)cc2)cc1 ; CC(C)c1ccc(C(=O)Oc2ccc([S+](c3ccccc3)c3ccccc3)cc2)cc1 ; CC(C)(C)c1ccc(C(=O)Oc2ccc([S+](c3ccccc3)c3ccccc3)cc2)cc1 ; O=C(Oc1ccc([S+](c2ccccc2)c2ccccc2)cc1)c1ccc(F)cc1 ; O=C(Oc1ccc([S+](c2ccccc2)c2ccccc2)cc1)c1ccc(C(F)(F)F)cc1 ; O=C(Oc1ccc([S+](c2ccccc2)c2ccccc2)cc1)c1ccc(F)cc1F]

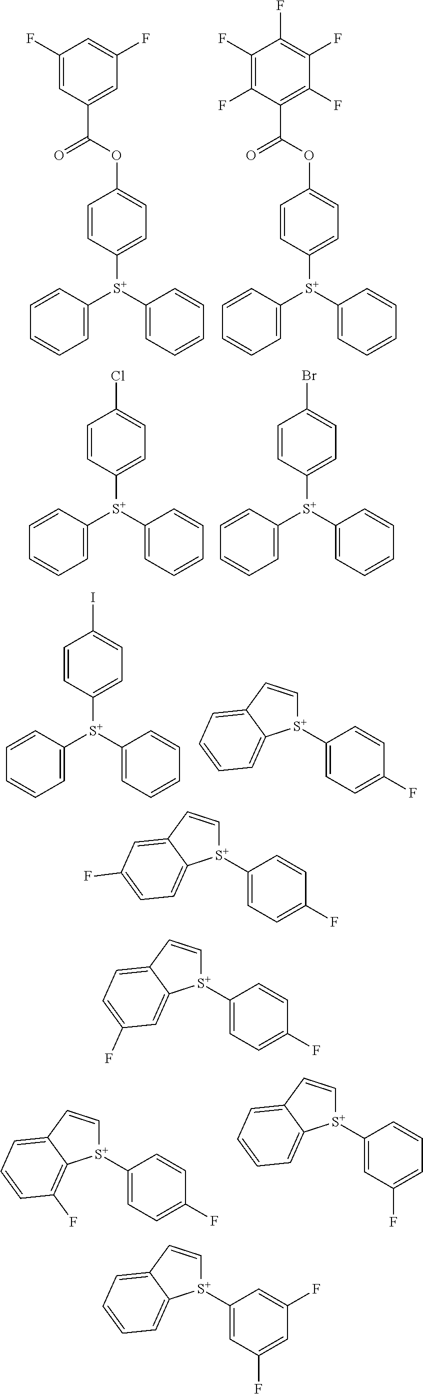

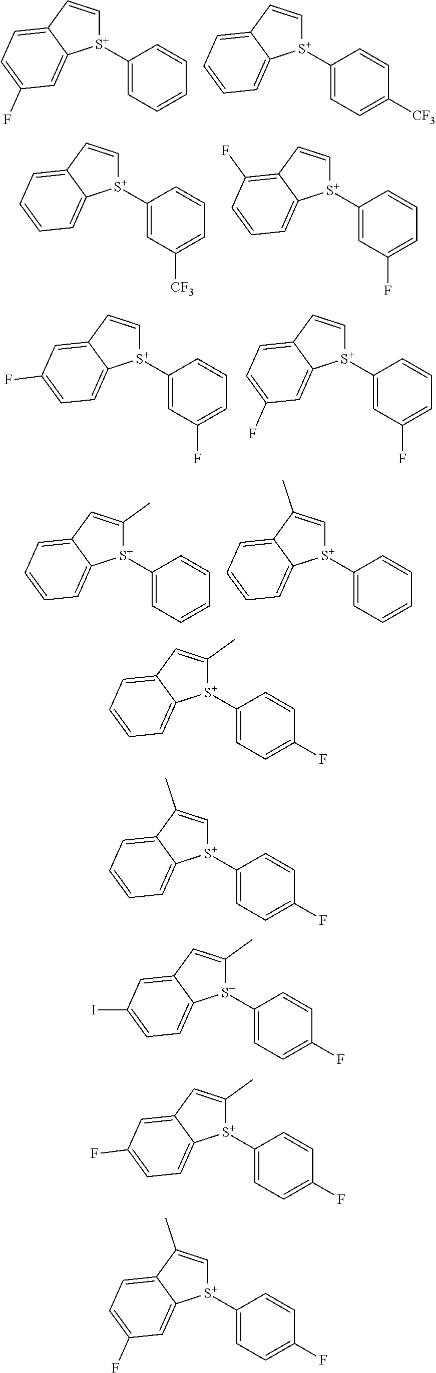

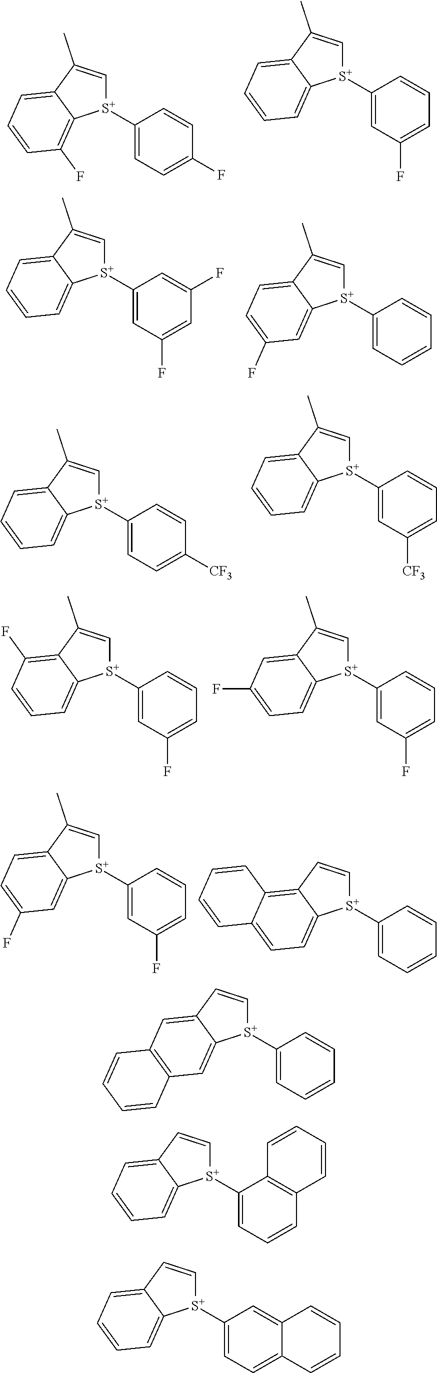

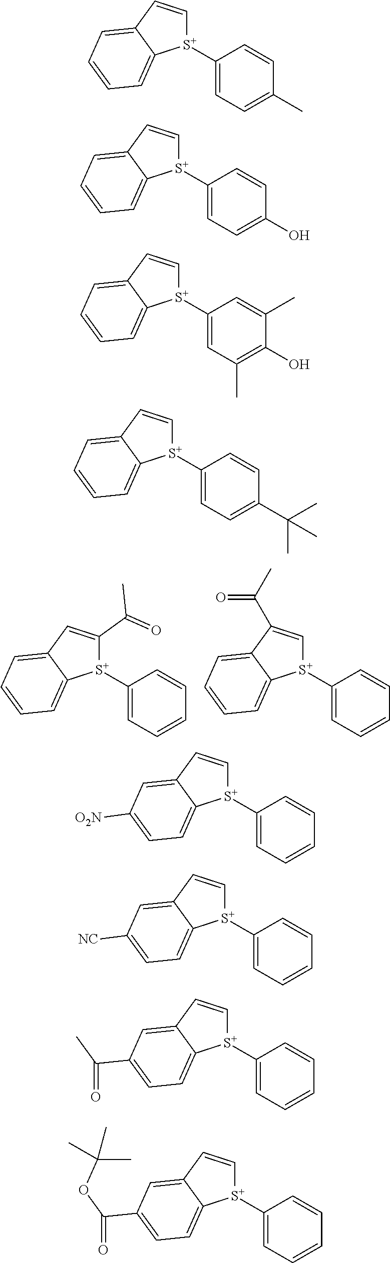

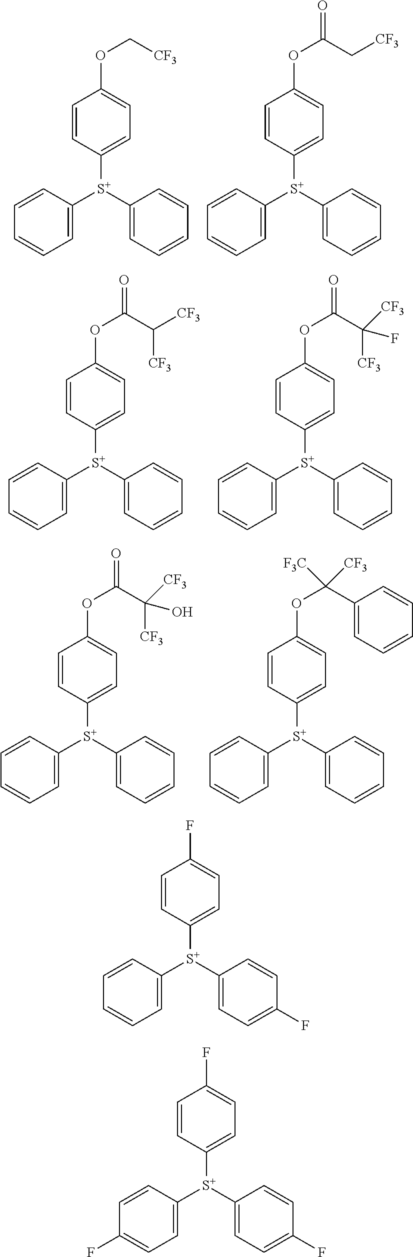

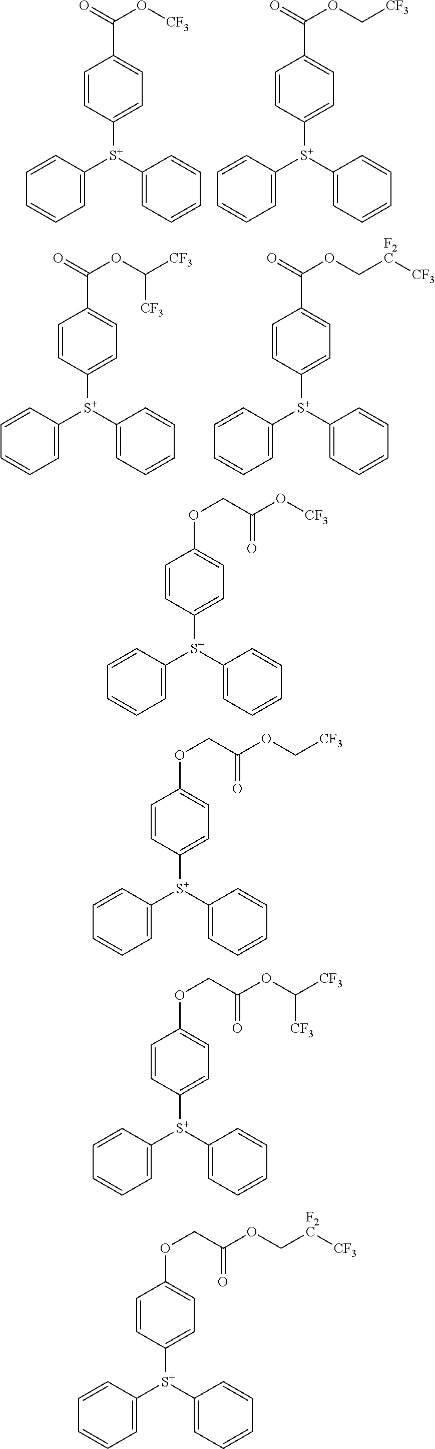

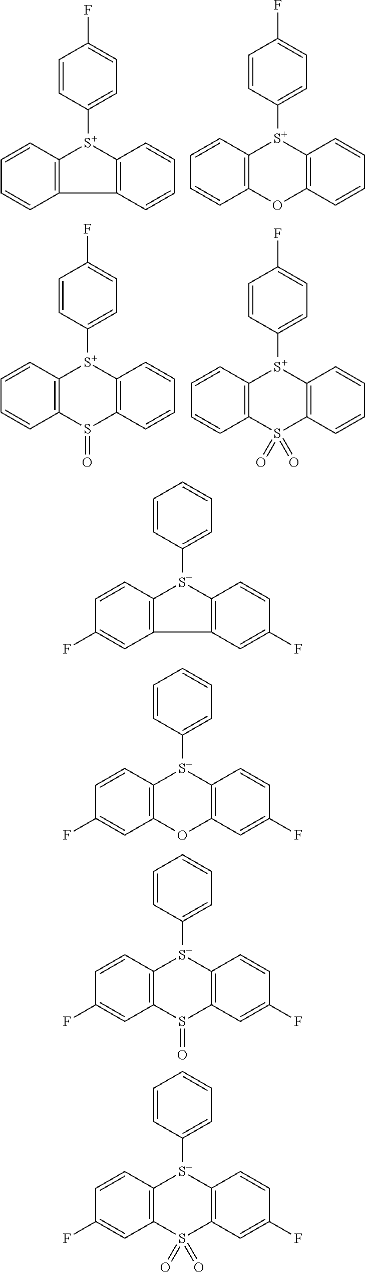

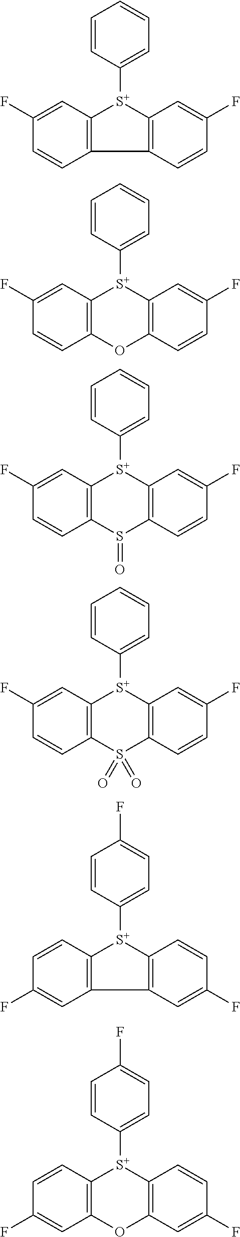 [SMILES: Fc1ccc2c3ccc(F)cc3[s+](-c3ccccc3)c2c1 ; Fc1ccc2c(c1)[S+](c1ccccc1)c1cc(F)ccc1O2 ; O=S1c2ccc(F)cc2[S+](c2ccccc2)c2cc(F)ccc21 ; O=S1(=O)c2ccc(F)cc2[S+](c2ccccc2)c2cc(F)ccc21 ; Fc1ccc(-[s+]2c3ccc(F)cc3c3cc(F)ccc32)cc1 ; Fc1ccc([S+]2c3ccc(F)cc3Oc3cc(F)ccc32)cc1]

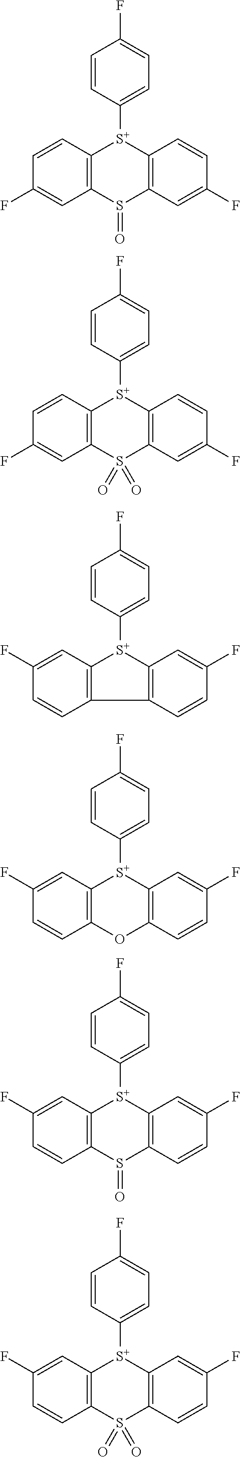 [SMILES: O=S1c2cc(F)ccc2[S+](c2ccc(F)cc2)c2ccc(F)cc21 ; O=S1(=O)c2cc(F)ccc2[S+](c2ccc(F)cc2)c2ccc(F)cc21 ; Fc1ccc(-[s+]2c3cc(F)ccc3c3ccc(F)cc32)cc1 ; Fc1ccc([S+]2c3cc(F)ccc3Oc3ccc(F)cc32)cc1 ; O=S1c2ccc(F)cc2[S+](c2ccc(F)cc2)c2cc(F)ccc21 ; O=S1(=O)c2ccc(F)cc2[S+](c2ccc(F)cc2)c2cc(F)ccc21]

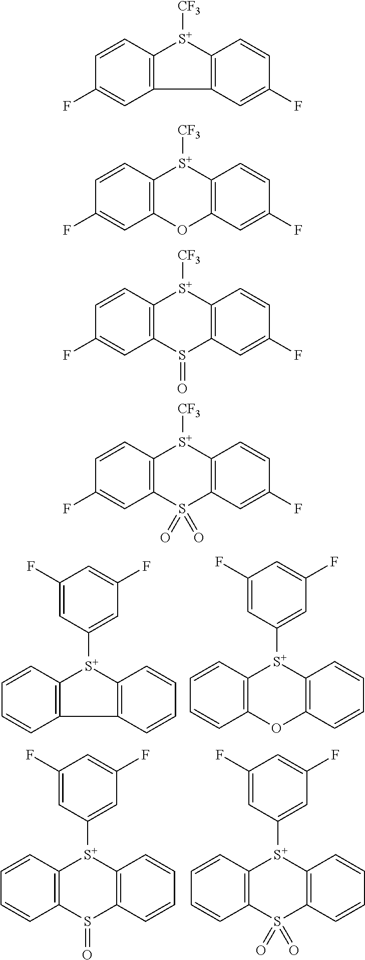

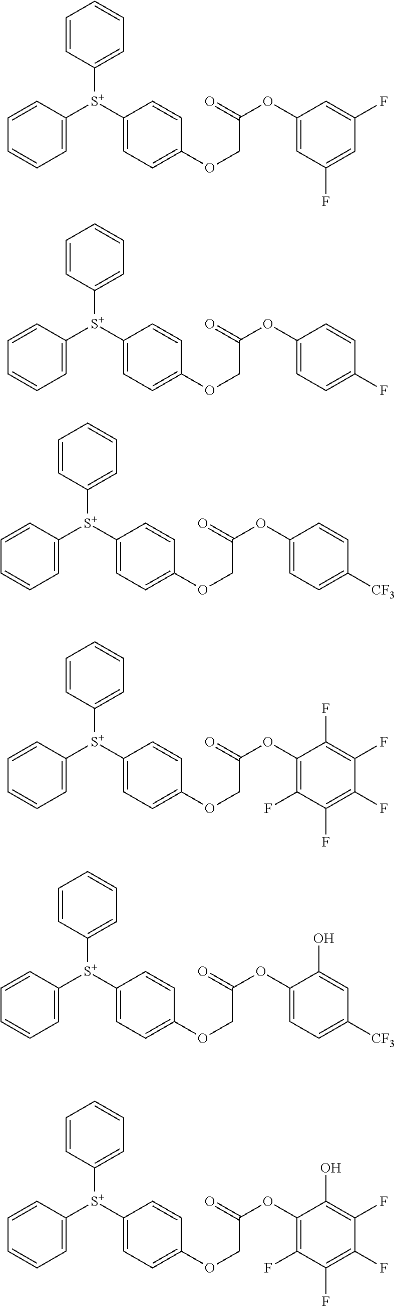 [SMILES: O=C(COc1ccc([S+](c2ccccc2)c2ccccc2)cc1)Oc1cc(F)cc(F)c1 ; O=C(COc1ccc([S+](c2ccccc2)c2ccccc2)cc1)Oc1ccc(F)cc1 ; O=C(COc1ccc([S+](c2ccccc2)c2ccccc2)cc1)Oc1ccc(C(F)(F)F)cc1 ; O=C(COc1ccc([S+](c2ccccc2)c2ccccc2)cc1)Oc1c(F)c(F)c(F)c(F)c1F ; O=C(COc1ccc([S+](c2ccccc2)c2ccccc2)cc1)Oc1ccc(C(F)(F)F)cc1O ; O=C(COc1ccc([S+](c2ccccc2)c2ccccc2)cc1)Oc1c(O)c(F)c(F)c(F)c1F]

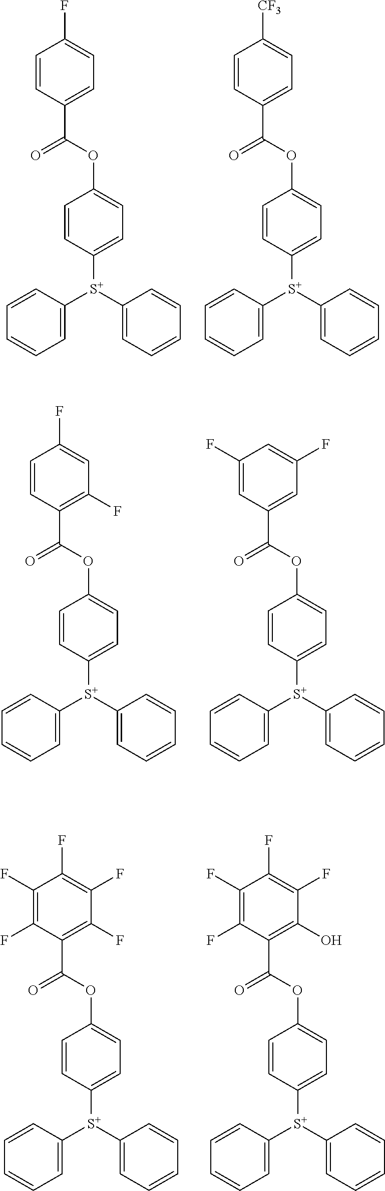 [SMILES: O=C(Oc1ccc([S+](c2ccccc2)c2ccccc2)cc1)c1ccc(F)cc1 ; O=C(Oc1ccc([S+](c2ccccc2)c2ccccc2)cc1)c1ccc(C(F)(F)F)cc1 ; O=C(Oc1ccc([S+](c2ccccc2)c2ccccc2)cc1)c1ccc(F)cc1F ; O=C(Oc1ccc([S+](c2ccccc2)c2ccccc2)cc1)c1cc(F)cc(F)c1 ; O=C(Oc1ccc([S+](c2ccccc2)c2ccccc2)cc1)c1c(F)c(F)c(F)c(F)c1F ; O=C(Oc1ccc([S+](c2ccccc2)c2ccccc2)cc1)c1c(O)c(F)c(F)c(F)c1F]

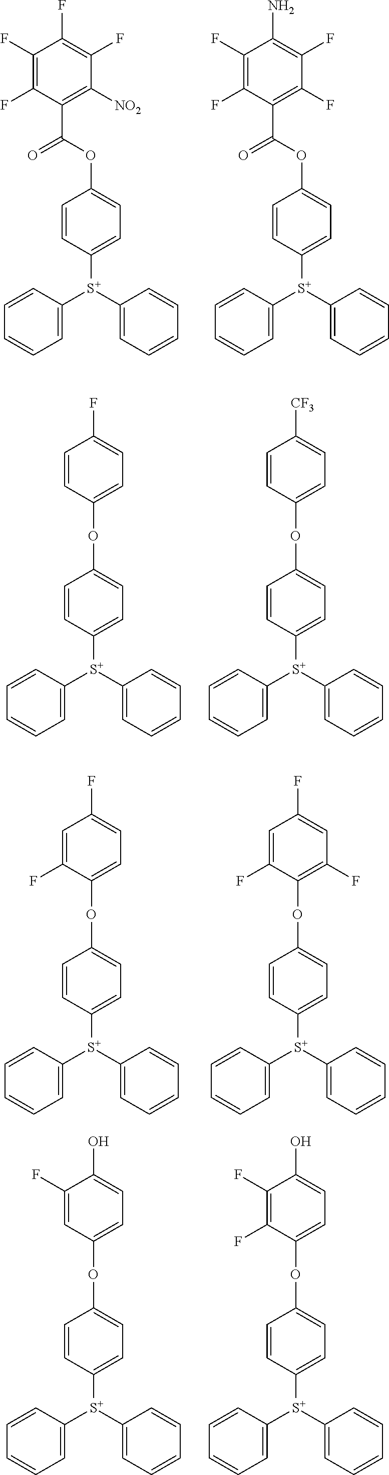

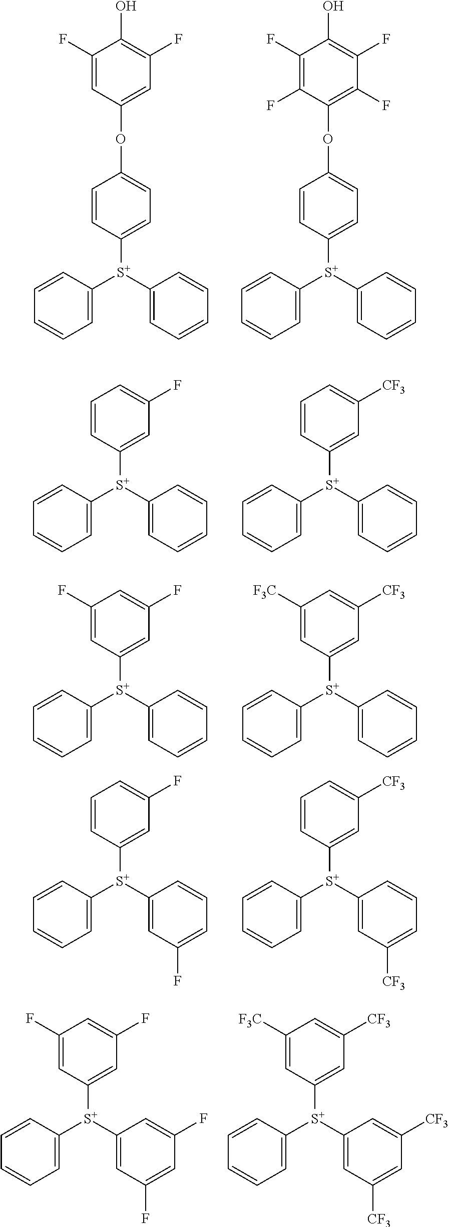

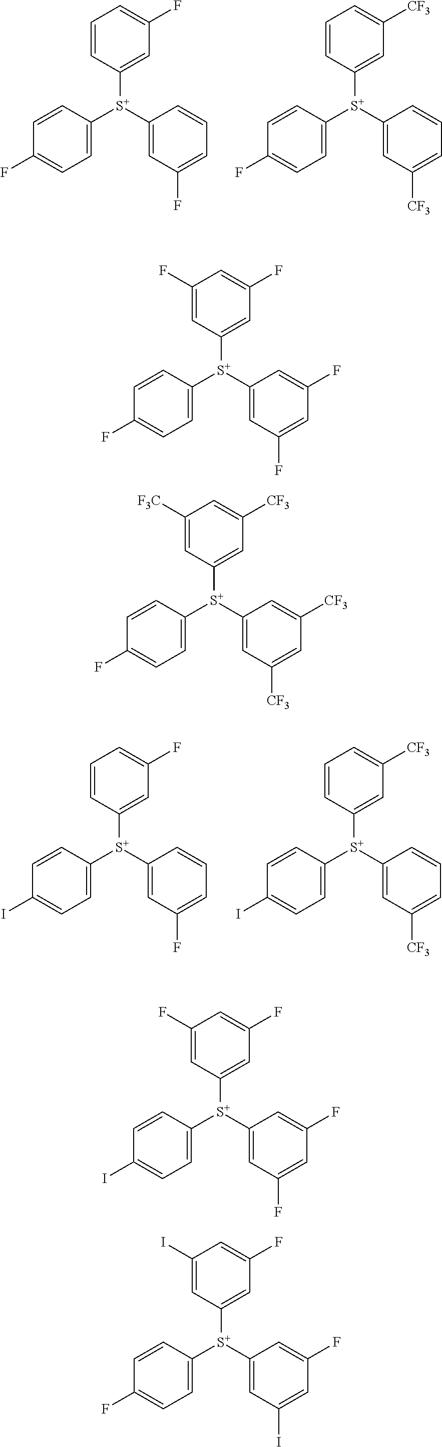

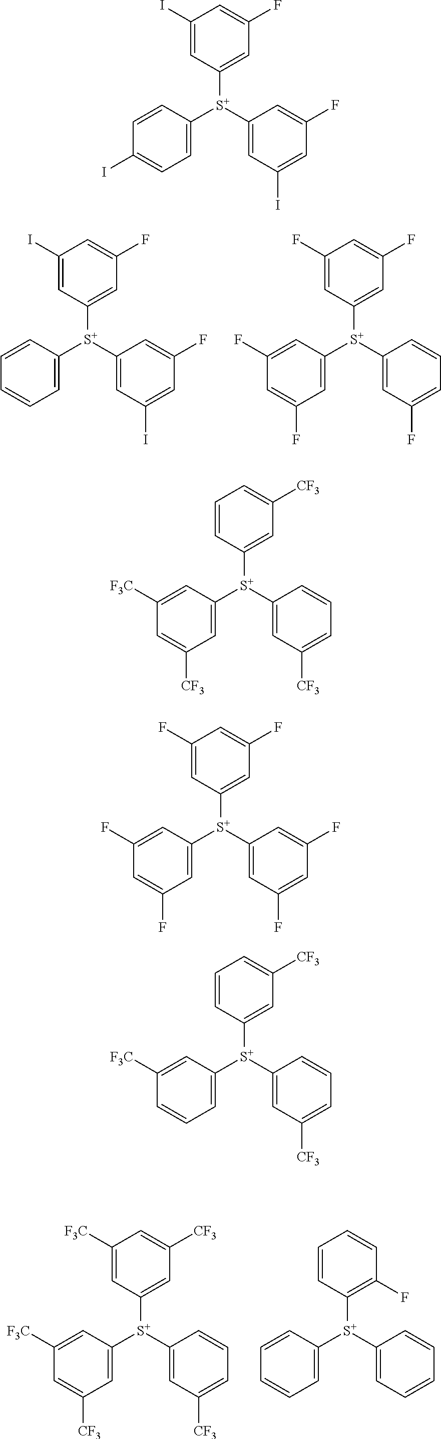

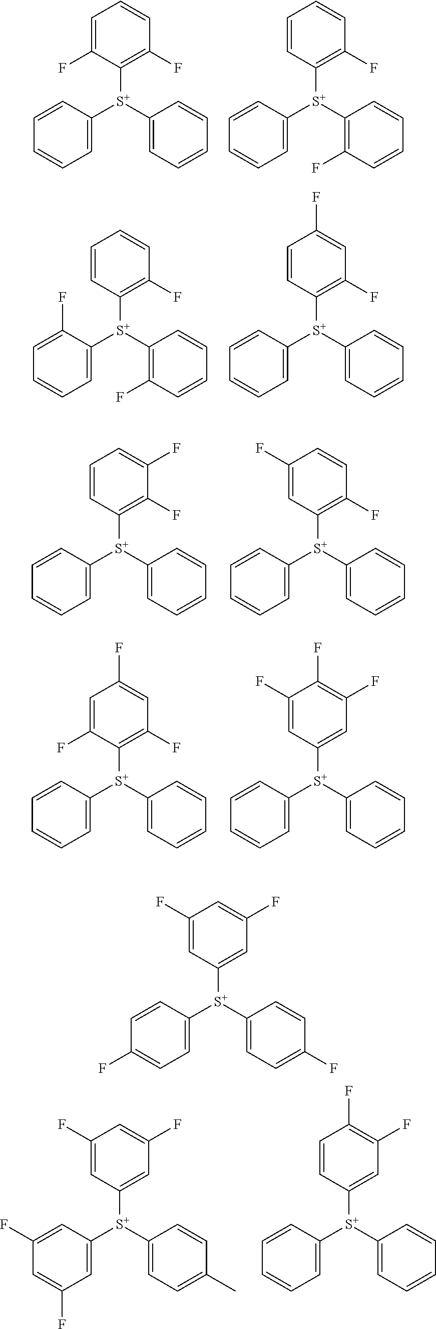

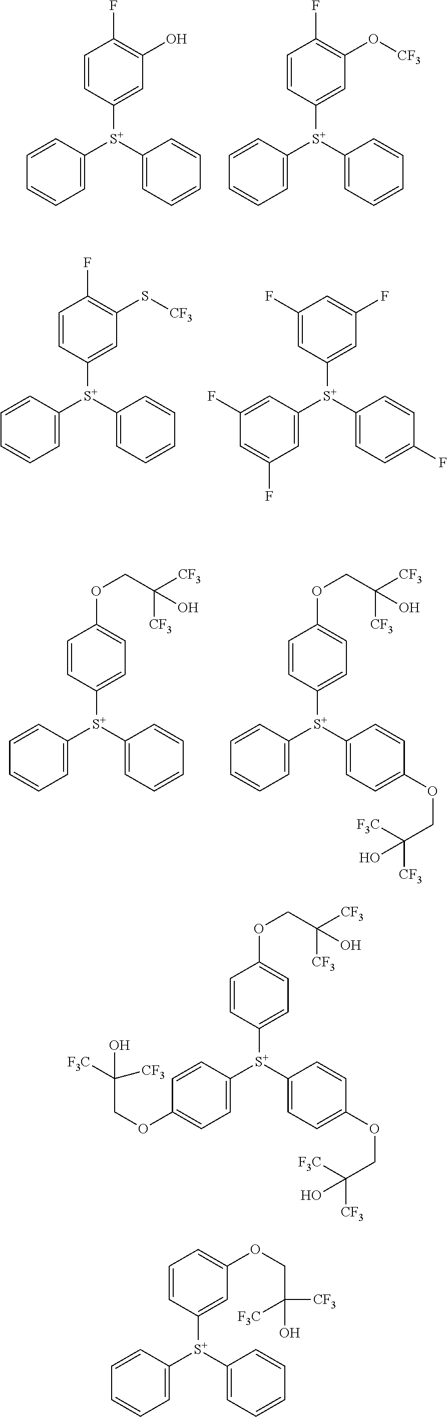

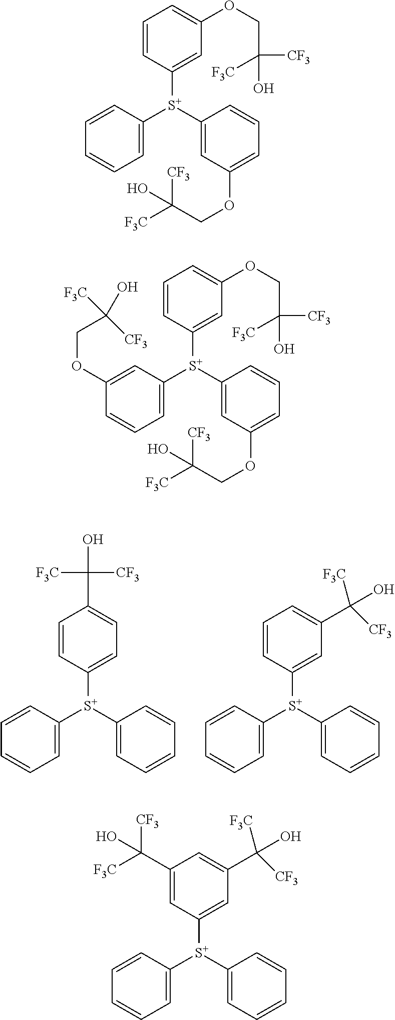 [SMILES: OC(COc1cccc([S+](c2ccccc2)c2cccc(OCC(O)(C(F)(F)F)C(F)(F)F)c2)c1)(C(F)(F)F)C(F)(F)F ; OC(COc1cccc([S+](c2cccc(OCC(O)(C(F)(F)F)C(F)(F)F)c2)c2cccc(OCC(O)(C(F)(F)F)C(F)(F)F)c2)c1)(C(F)(F)F)C(F)(F)F ; OC(c1ccc([S+](c2ccccc2)c2ccccc2)cc1)(C(F)(F)F)C(F)(F)F ; OC(c1cccc([S+](c2ccccc2)c2ccccc2)c1)(C(F)(F)F)C(F)(F)F ; OC(c1cc([S+](c2ccccc2)c2ccccc2)cc(C(O)(C(F)(F)F)C(F)(F)F)c1)(C(F)(F)F)C(F)(F)F]

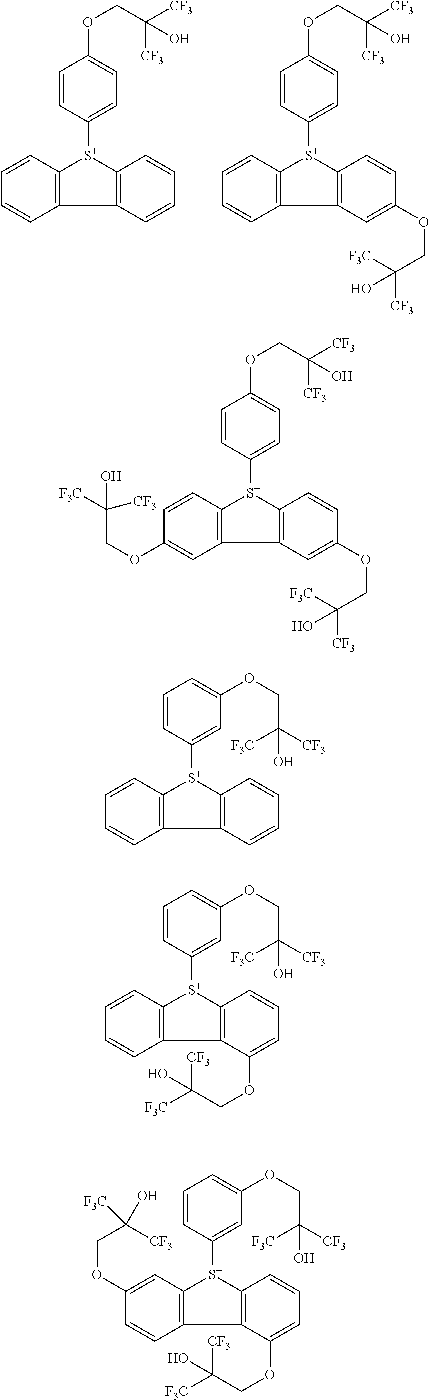

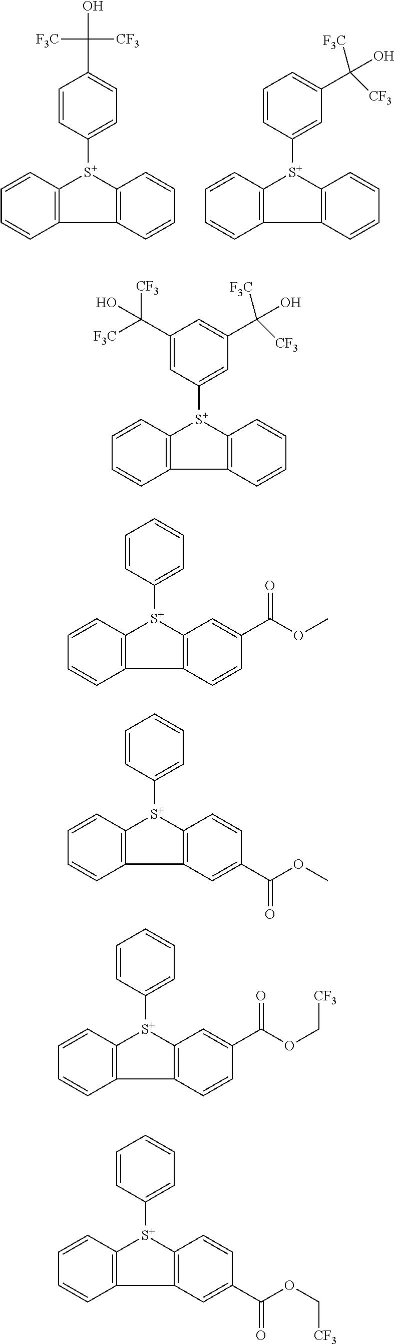

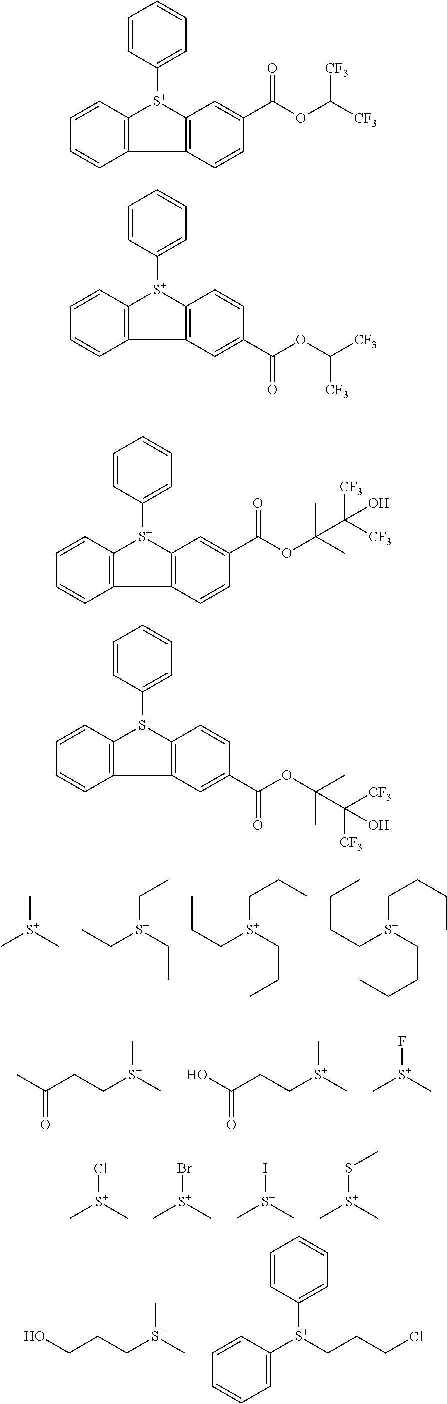

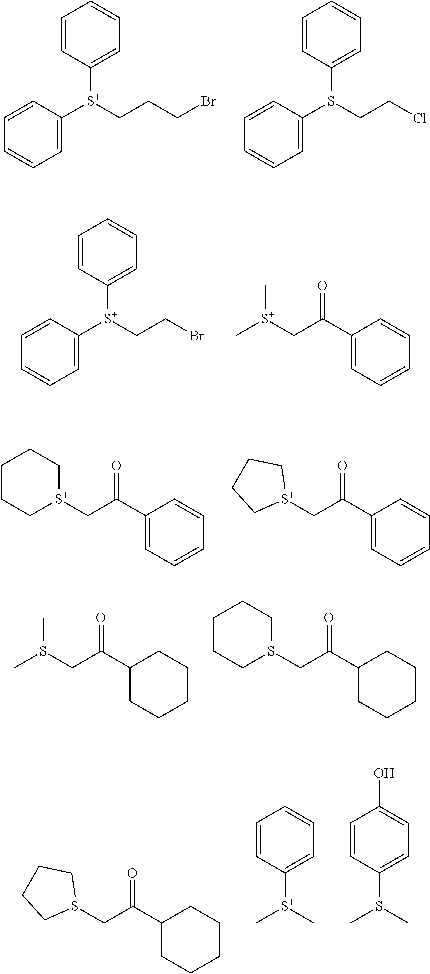

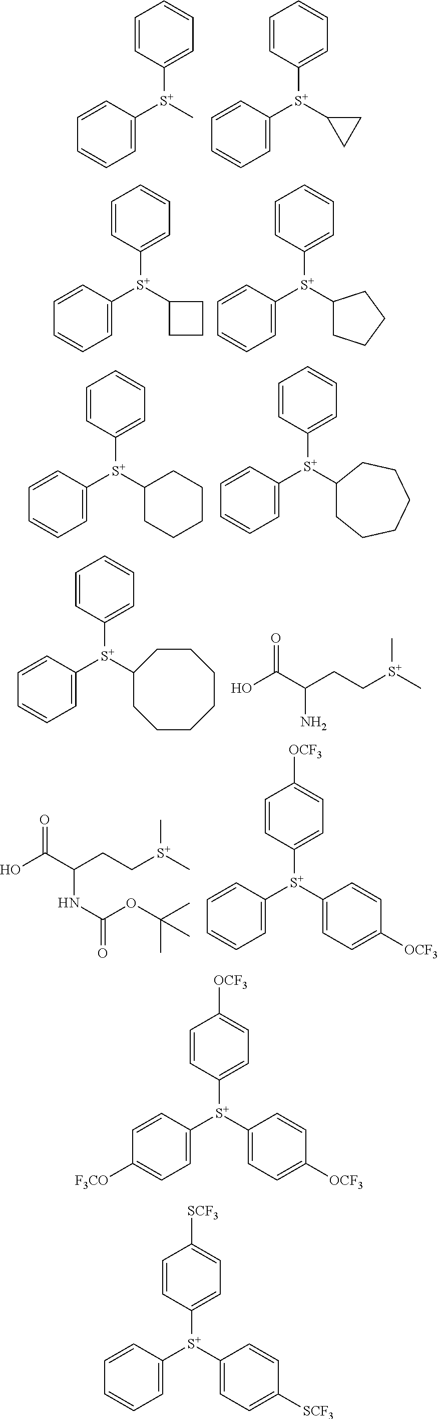

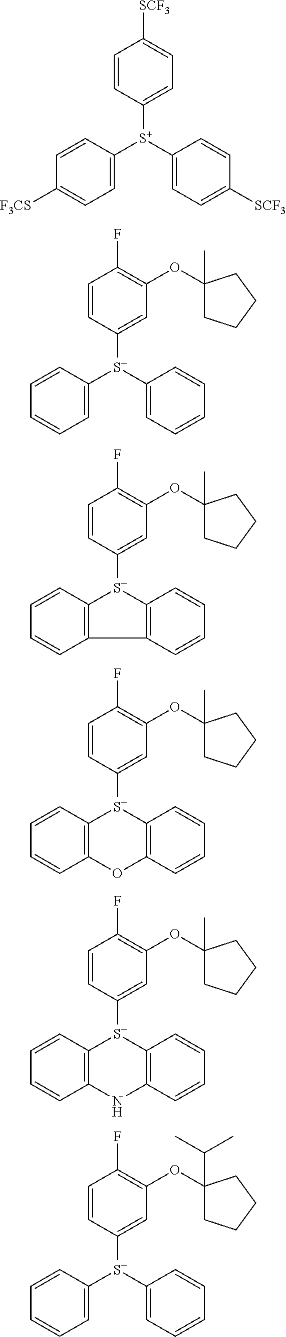

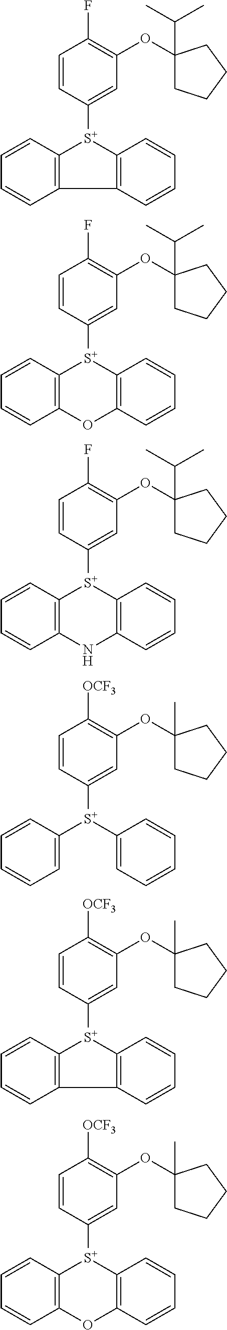 [SMILES: CC(C)C1(Oc2cc(-[s+]3c4ccccc4c4ccccc43)ccc2F)CCCC1 ; CC(C)C1(Oc2cc([S+]3c4ccccc4Oc4ccccc43)ccc2F)CCCC1 ; CC(C)C1(Oc2cc([S+]3c4ccccc4Nc4ccccc43)ccc2F)CCCC1 ; CC1(Oc2cc([S+](c3ccccc3)c3ccccc3)ccc2OC(F)(F)F)CCCC1 ; CC1(Oc2cc(-[s+]3c4ccccc4c4ccccc43)ccc2OC(F)(F)F)CCCC1 ; CC1(Oc2cc([S+]3c4ccccc4Oc4ccccc43)ccc2OC(F)(F)F)CCCC1]

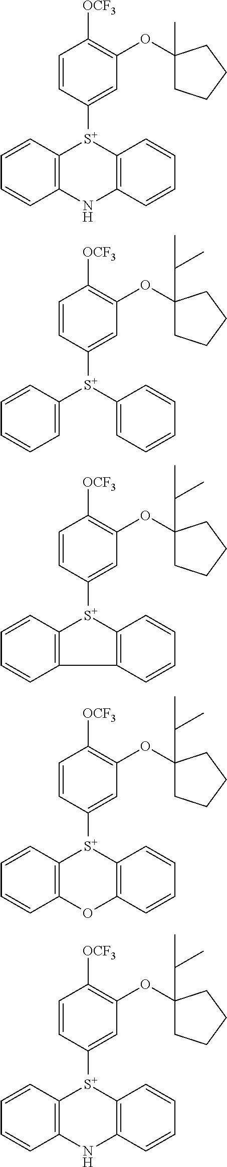 [SMILES: CC1(Oc2cc([S+]3c4ccccc4Nc4ccccc43)ccc2OC(F)(F)F)CCCC1 ; CC(C)C1(Oc2cc([S+](c3ccccc3)c3ccccc3)ccc2OC(F)(F)F)CCCC1 ; CC(C)C1(Oc2cc(-[s+]3c4ccccc4c4ccccc43)ccc2OC(F)(F)F)CCCC1 ; CC(C)C1(Oc2cc([S+]3c4ccccc4Oc4ccccc43)ccc2OC(F)(F)F)CCCC1 ; CC(C)C1(Oc2cc([S+]3c4ccccc4Nc4ccccc43)ccc2OC(F)(F)F)CCCC1]

Specific examples of the iodonium cation represented by the formula (5-2) include the following, but are not limited thereto.

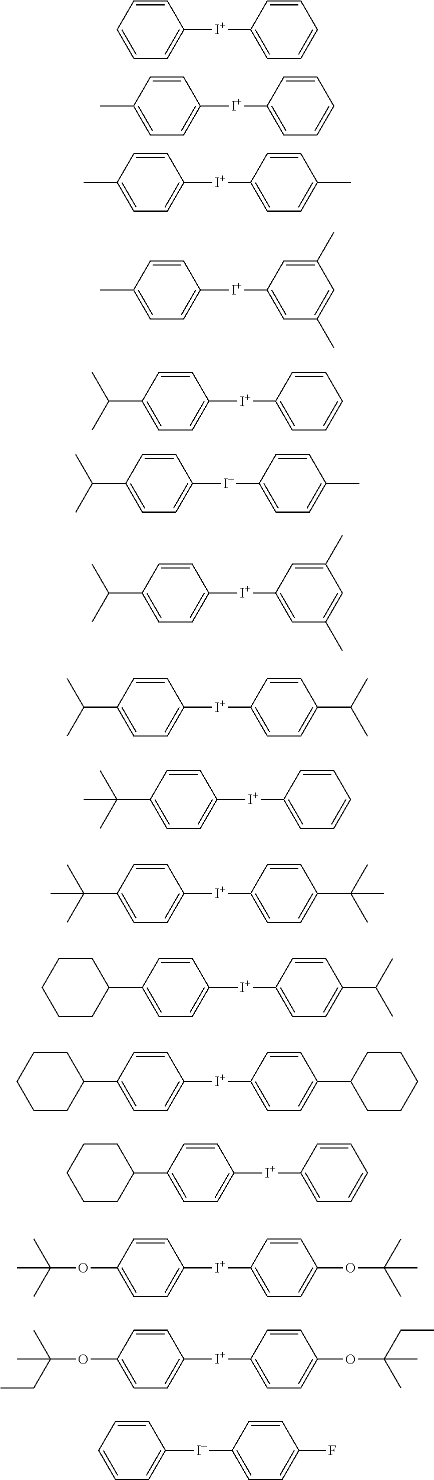

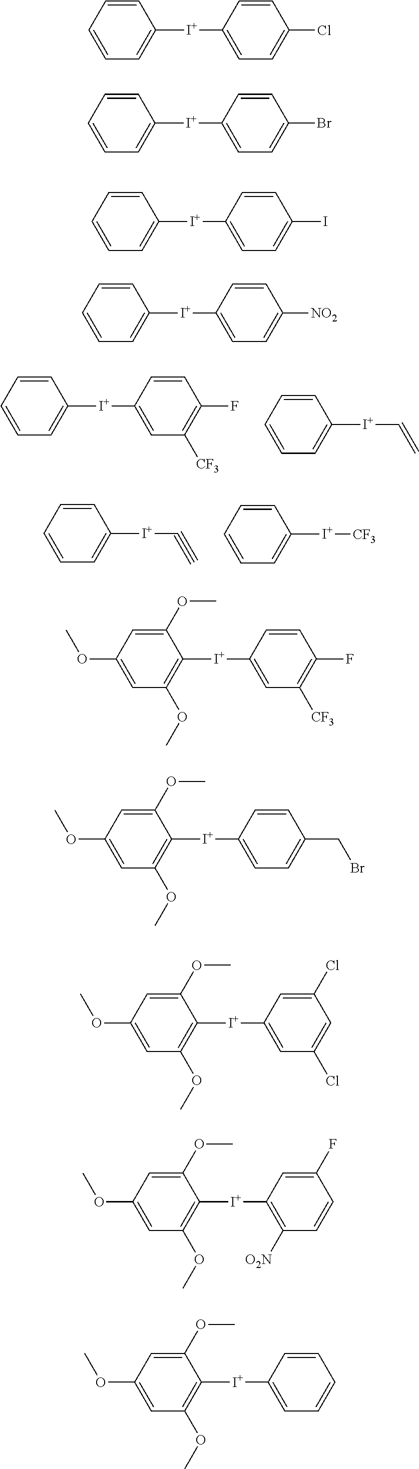

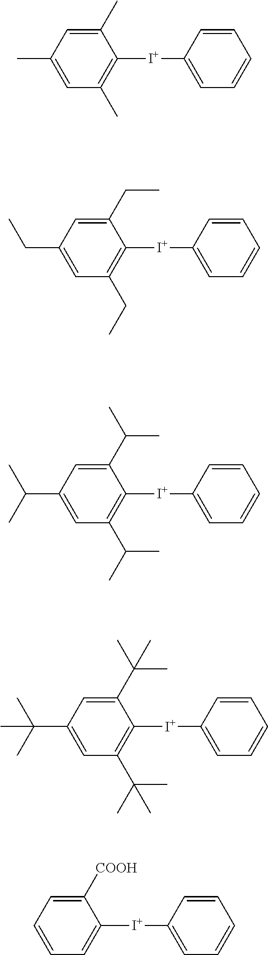 [SMILES: Cc1cc(C)c([I+]c2ccccc2)c(C)c1 ; CCc1cc(CC)c([I+]c2ccccc2)c(CC)c1 ; CC(C)c1cc(C(C)C)c([I+]c2ccccc2)c(C(C)C)c1 ; CC(C)(C)c1cc(C(C)(C)C)c([I+]c2ccccc2)c(C(C)(C)C)c1 ; O=C(O)c1ccccc1[I+]c1ccccc1]

The onium salt compound contains, as an anion, a halide ion, a nitrate ion, a hydrogen sulfate ion, a hydrogen carbonate ion, a tetraphenylborate ion, or an anion represented by any of the following formulae (5-3) to (5-9).

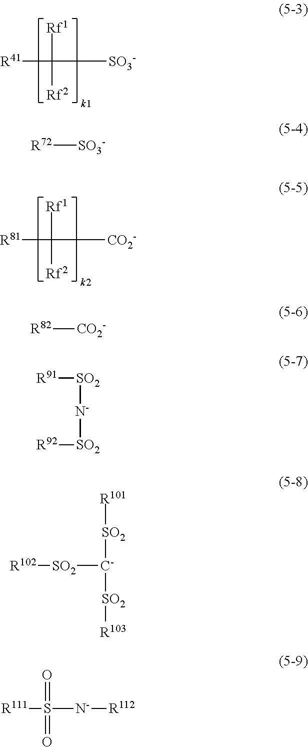

In the formulae (5-3) and (5-5), “k1” and “k2” each independently represent 1, 2, 3, or 4. Rf¹ and Rf² each independently represent a hydrogen atom, a fluorine atom, or a fluorine-containing alkyl group having 1 to 6 carbon atoms, provided that not all of the Rf¹ and Rf² are hydrogen atoms at the same time.

In the formula (5-3), R⁷¹ represents a hydrogen atom, a halogen atom, a hydroxy group, or a hydrocarbyl group having 1 to 50 carbon atoms and optionally containing a heteroatom.

In the formula (5-4), R⁷² represents a hydrogen atom, a halogen atom, a hydroxy group, or a hydrocarbyl group having 1 to 50 carbon atoms and optionally containing a heteroatom. However, groups in which a hydrogen atom on the carbon atom in the α position and the β position of the sulfo group is substituted with a fluorine atom or a fluoroalkyl group are excluded.

In the formula (5-5), R⁸¹ represents a hydrogen atom, a halogen atom, a hydroxy group, or a hydrocarbyl group having 1 to 50 carbon atoms and optionally containing a heteroatom.

In the formula (5-6), R⁸² represents a hydrogen atom, a halogen atom, a hydroxy group, or a hydrocarbyl group having 1 to 50 carbon atoms and optionally containing a heteroatom. However, groups in which a hydrogen atom on the carbon atom in the α position and the β position of the carboxy group is substituted with a fluorine atom or a fluoroalkyl group are excluded.

In the formula (5-7), R⁹¹ and R⁹² each independently represent a hydrocarbyl group having 1 to 50 carbon atoms and optionally containing a heteroatom.

In the formula (5-8), R¹⁰¹ to R¹⁰³ each independently represent a hydrocarbyl group having 1 to 50 carbon atoms and optionally containing a heteroatom.

In the formula (5-9), Rill represents a fluorine atom or a fluorinated hydrocarbyl group having 1 to 10 carbon atoms, and the fluorinated hydrocarbyl group may contain a hydroxy group, an ether bond, or an ester bond. R¹¹² represents a hydrogen atom or a hydrocarbyl group having 1 to 20 carbon atoms, and the hydrocarbyl group may contain a hydroxy group, an ether bond, or an ester bond. Furthermore, R¹¹¹ and R¹¹² may be bonded to each other to form a ring together with the atoms bonded thereto.

As the anions of the onium salt compounds, a halide ion, a nitrate ion, or an anion represented by any of the formulae (5-3) to (5-9) is preferable, and a halide ion, a nitrate ion, or an anion represented by the formula (5-4), (5-6), or (5-8) is more preferable.

The hydrocarbyl group represented by R⁷¹, R⁷², R⁸¹, R⁸², R⁹¹, R⁹², R¹⁰¹, R¹⁰², and R¹⁰³ having 1 to 50 carbon atoms may be saturated or unsaturated, and may be linear, branched, or cyclic. Specific examples thereof include: alkyl groups having 1 to 50 carbon atoms, such as a methyl group, an ethyl group, a propyl group, an isopropyl group, an n-butyl group, a sec-butyl group, a tert-butyl group, a tert-pentyl group, an n-pentyl group, an n-hexyl group, an n-octyl group, a 2-ethylhexyl group, an n-nonyl group, and an n-decyl group; cyclic saturated hydrocarbyl groups having 3 to 50 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, an adamantyl group, and an adamantylmethyl group; alkenyl groups having 2 to 30 carbon atoms, such as a vinyl group, a 1-propenyl group, a 2-propenyl group, a butenyl group, and a hexenyl group; cyclic unsaturated hydrocarbyl groups having 3 to 30 carbon atoms, such as a cyclohexenyl group; aryl groups having 6 to 50 carbon atoms, such as a phenyl group, a naphthyl group, and an anthracenyl group; and groups which are combinations of these groups. Furthermore, part or all of the hydrogen atoms of the hydrocarbyl group may be substituted with a group containing a heteroatom, such as an oxygen atom, a sulfur atom, a nitrogen atom, or a halogen atom, and part of the —CH₂— constituting the hydrocarbyl group may be substituted with a group containing a heteroatom such as an oxygen atom, a sulfur atom, or a nitrogen atom. The resulting hydrocarbyl group may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc.

The fluorinated hydrocarbyl group represented by Rill having 1 to 10 carbon atoms is a group in which part or all of the hydrogen atoms of a hydrocarbyl group having 1 to 10 carbon atoms are substituted with a fluorine atom. The hydrocarbyl group having 1 to 10 carbon atoms may be saturated or unsaturated, and may be linear, branched, or cyclic. Specific examples thereof include groups having 1 to 10 carbon atoms out of the groups given as examples of the hydrocarbyl group represented by R⁷¹, R⁷², R⁸¹, R⁸², R⁹¹, R⁹², R¹⁰¹, R¹⁰², and R¹⁰³ having 1 to 50 carbon atoms.

The hydrocarbyl group represented by R¹¹² having 1 to 20 carbon atoms may be saturated or unsaturated, and may be linear, branched, or cyclic. Specific examples thereof include groups having 1 to 20 carbon atoms out of the groups given as examples of the hydrocarbyl group represented by R⁷¹, R⁷², R⁸¹, R⁸², R⁹¹, R⁹², R¹⁰¹, R¹⁰², and R¹⁰³ having 1 to 50 carbon atoms.

The anion represented by any of the formulae (5-3) to (5-9) may contain a polymerizable functional group in its structure, and may have a hydrocarbyl group having 2 to 50 carbon atoms and optionally containing a heteroatom. Specific examples thereof include the following, but are not limited thereto.

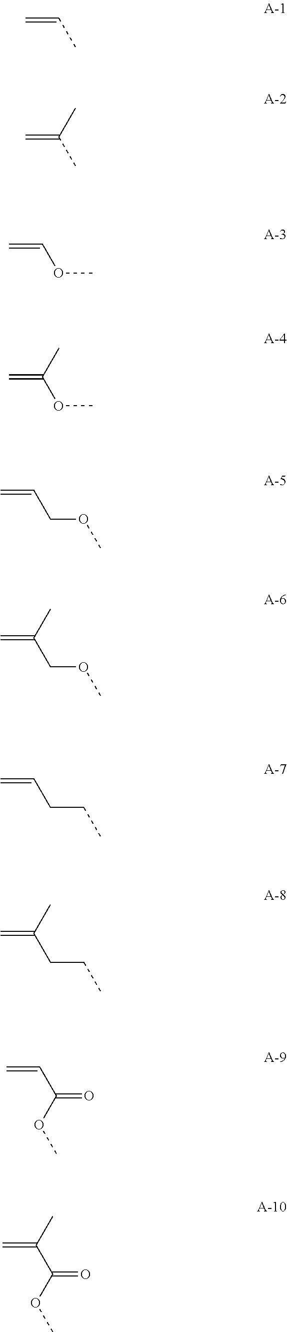

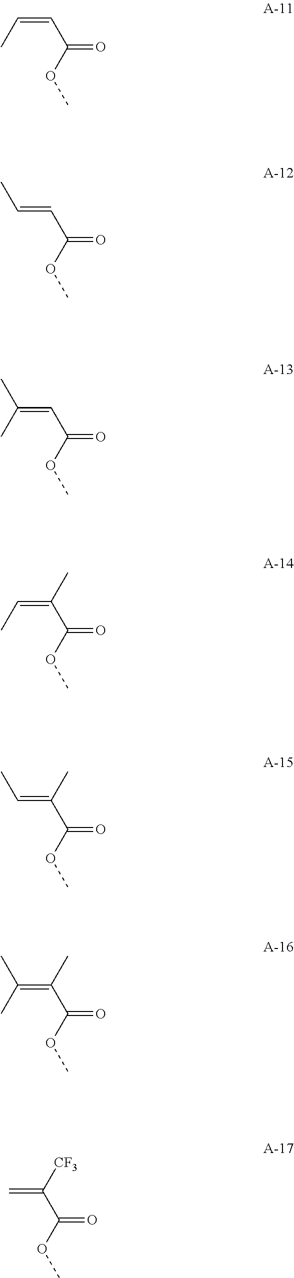

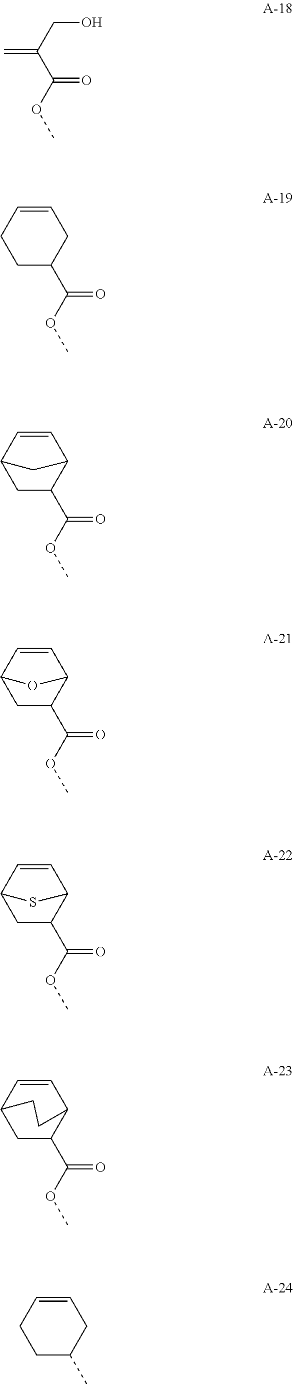

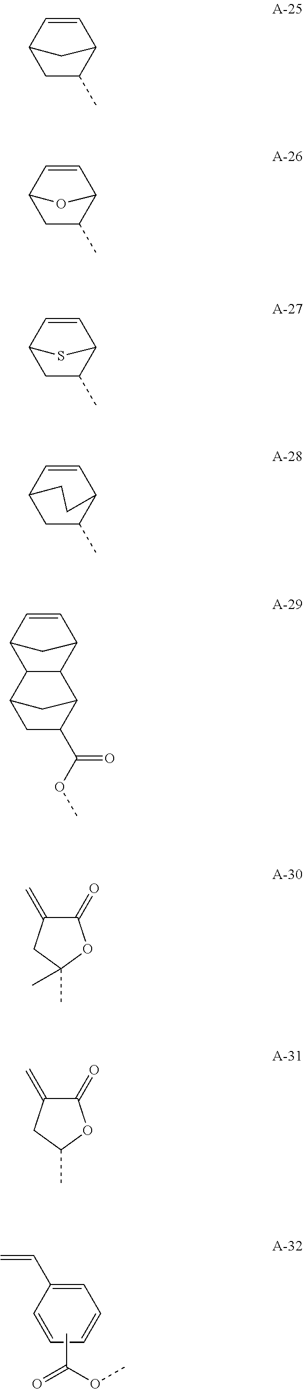

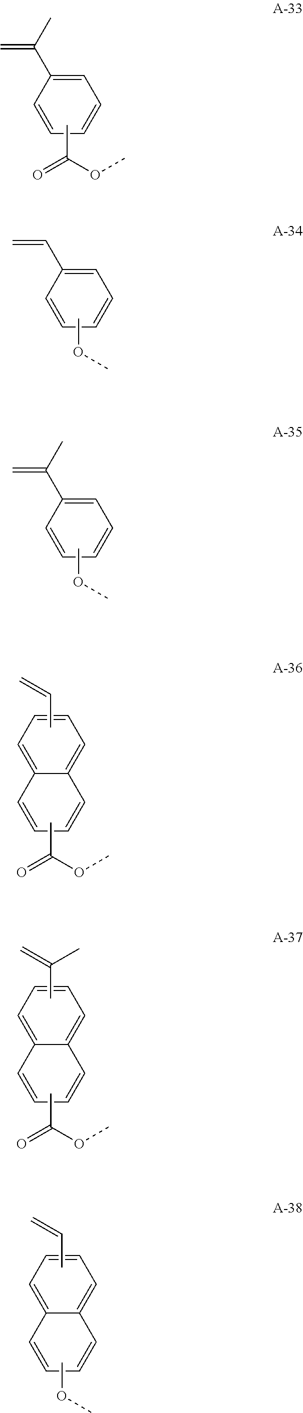

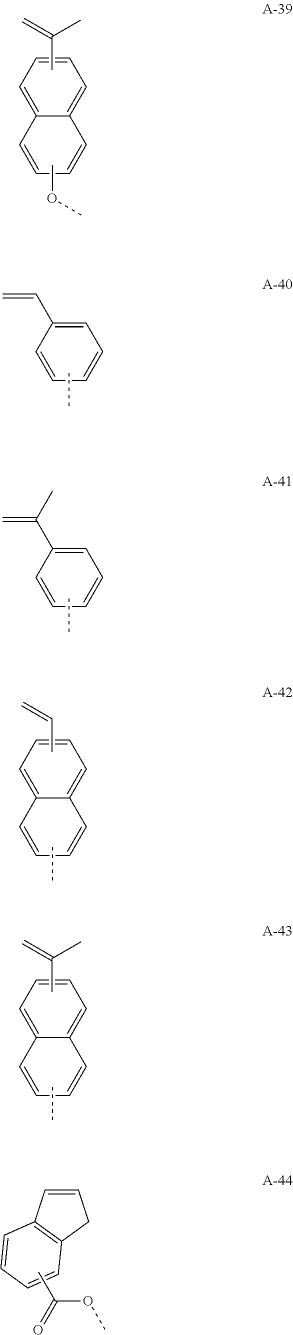

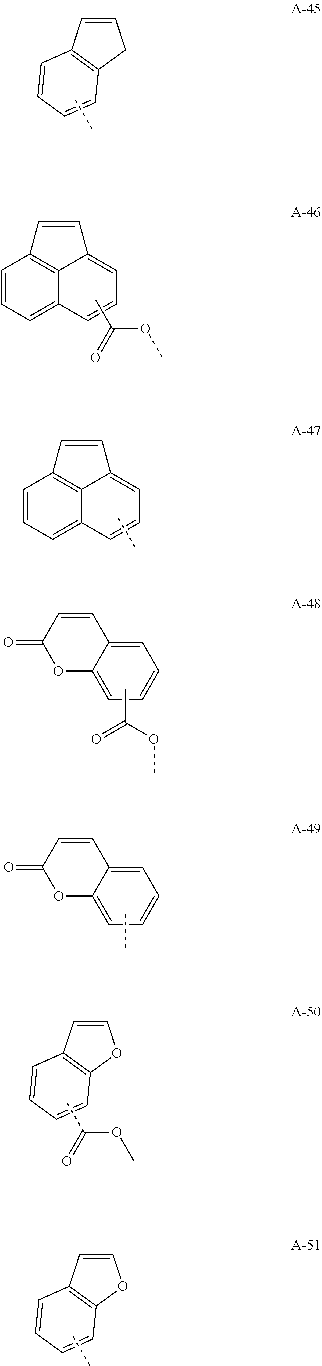

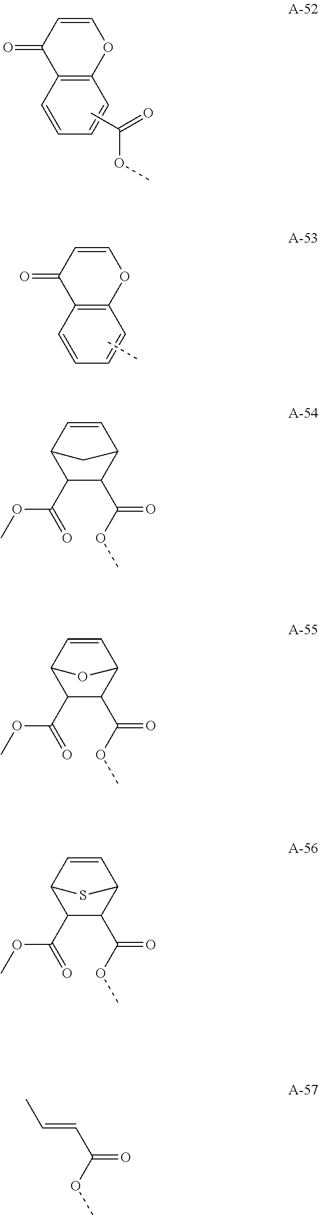

Specific examples of the anion represented by the formula (5-3) include the following, but are not limited thereto. Note that, in the following formulae, Ac represents an acetyl group and Rf is as defined above.

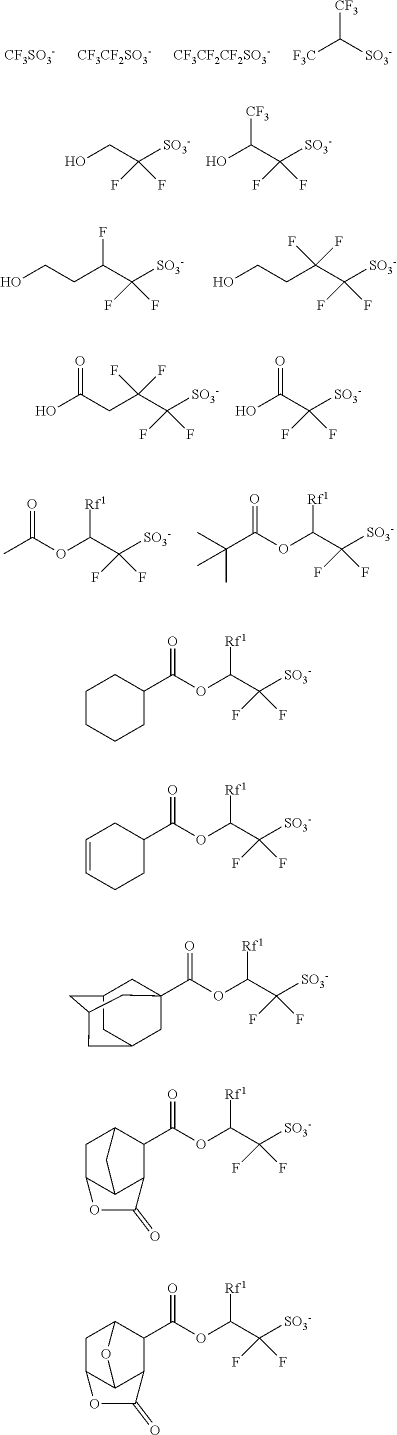

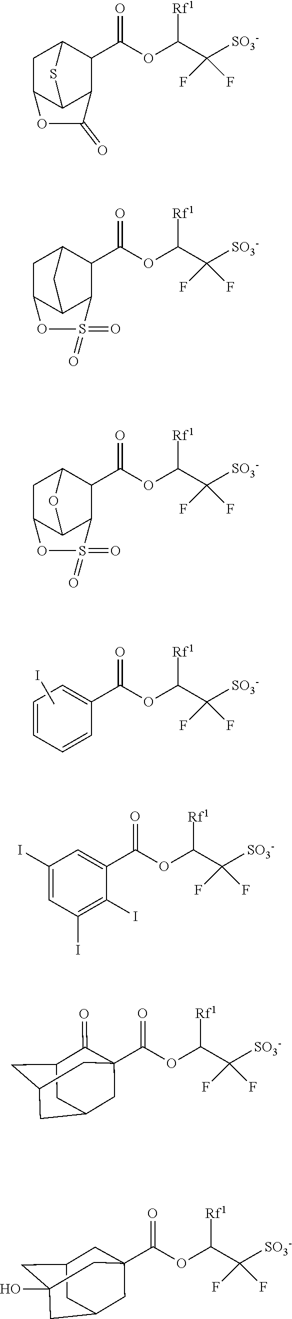

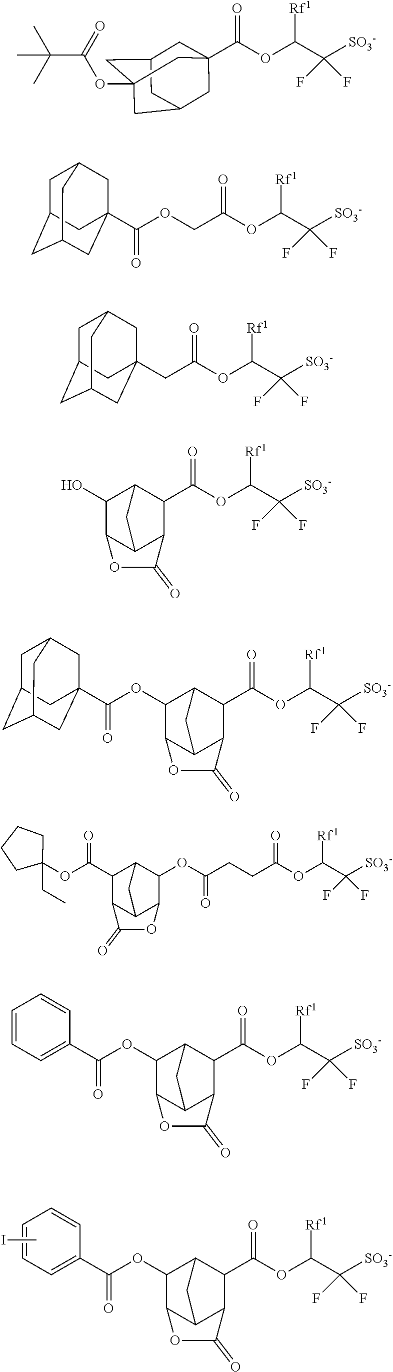

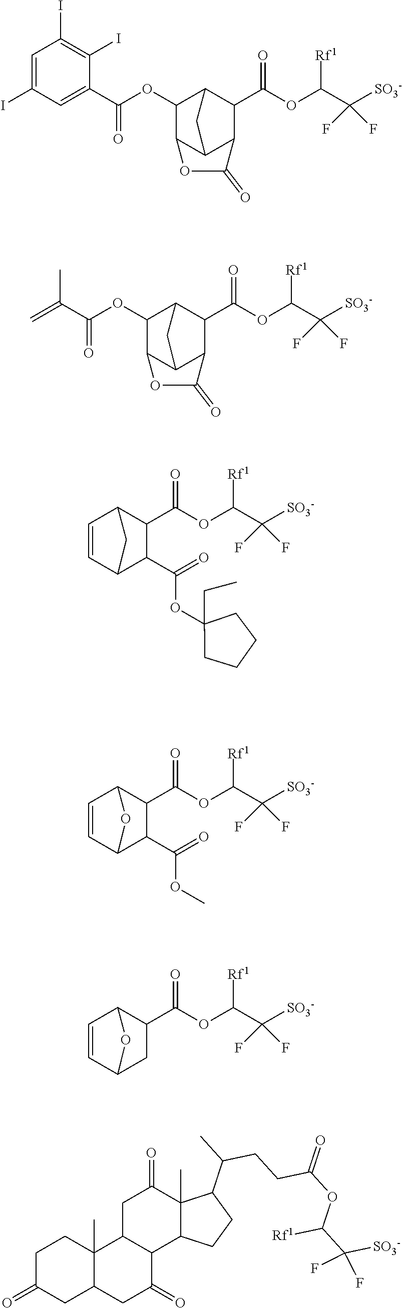

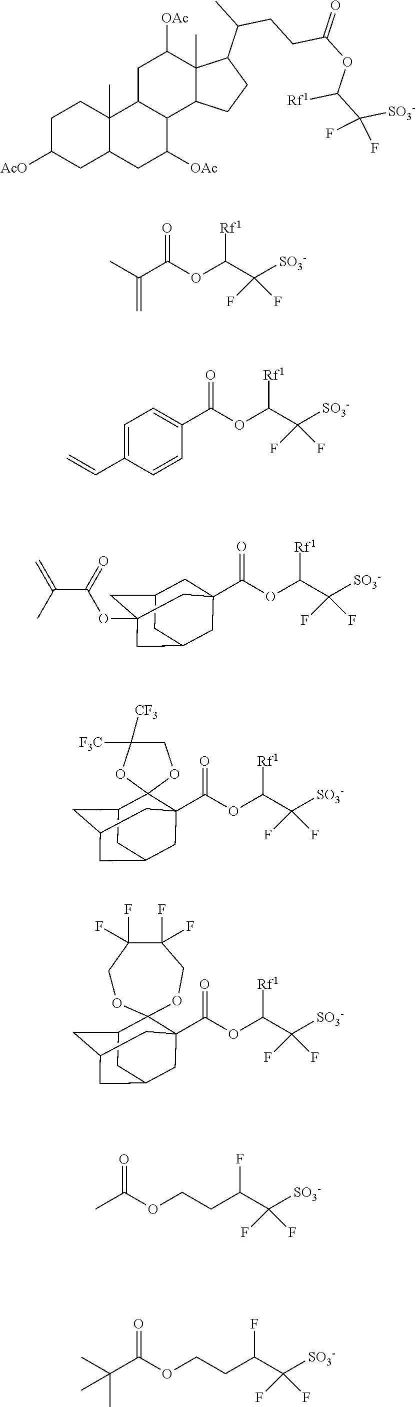

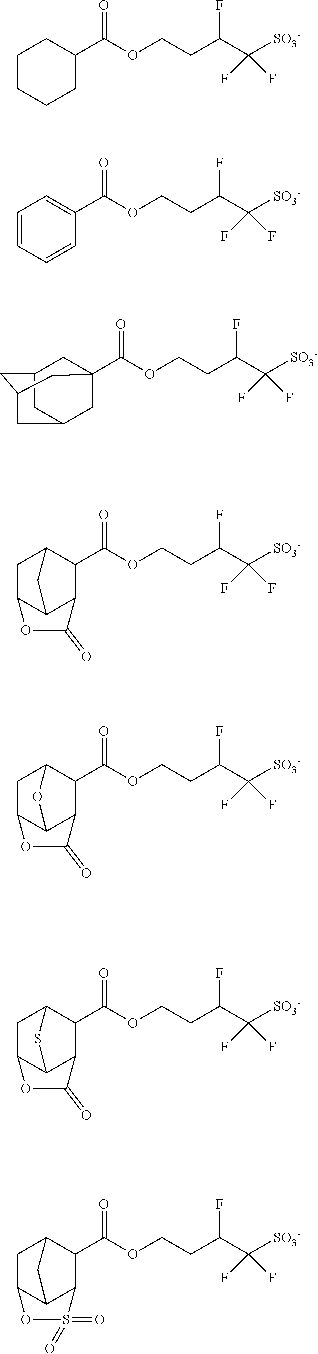

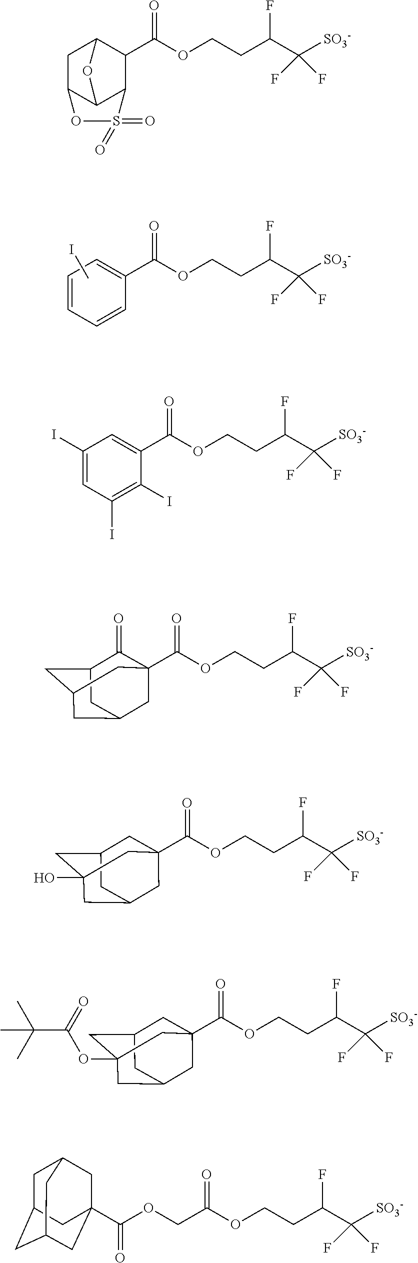

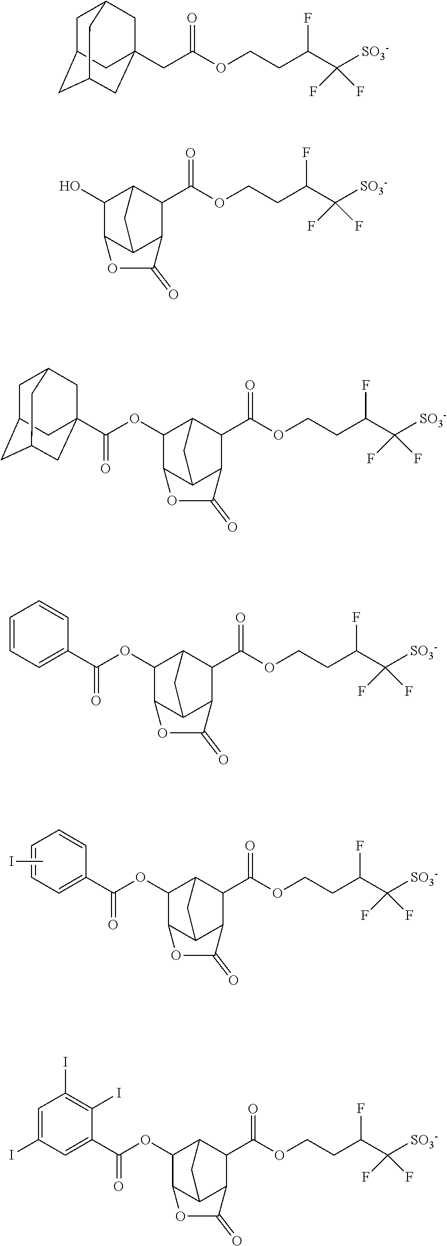

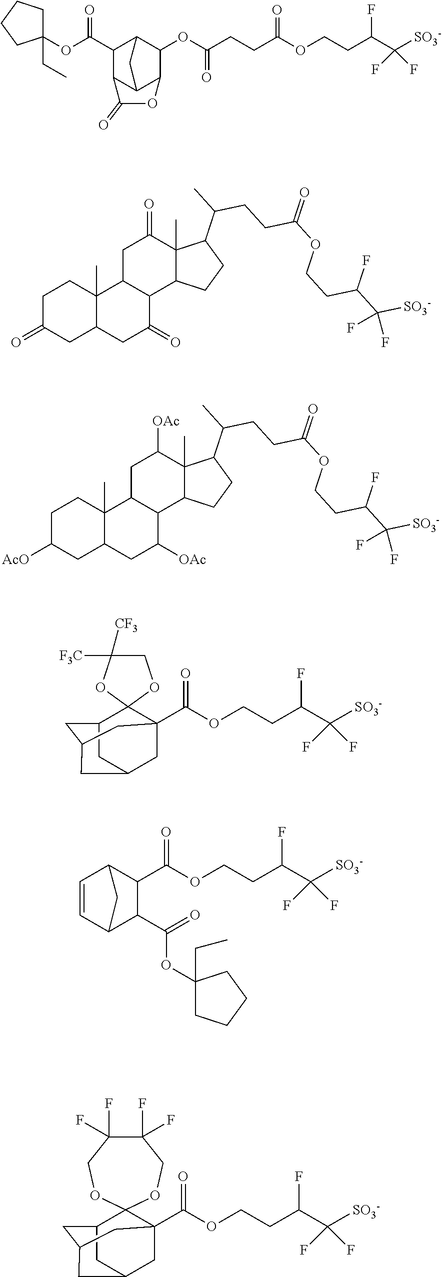

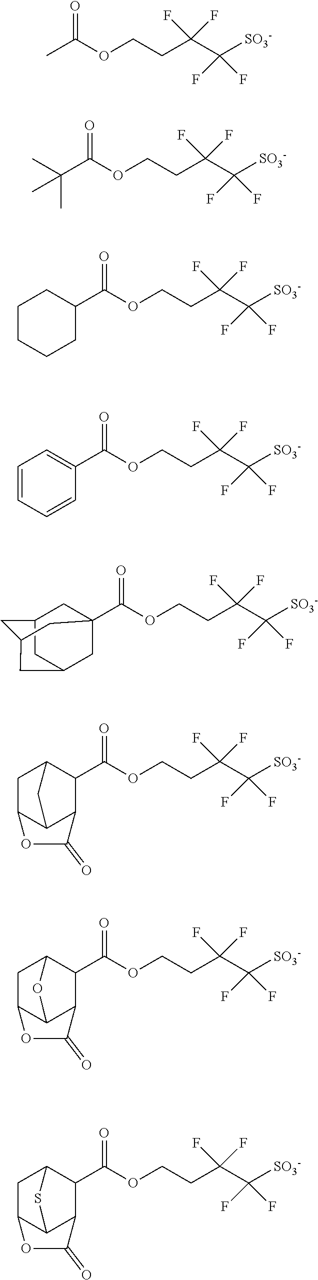

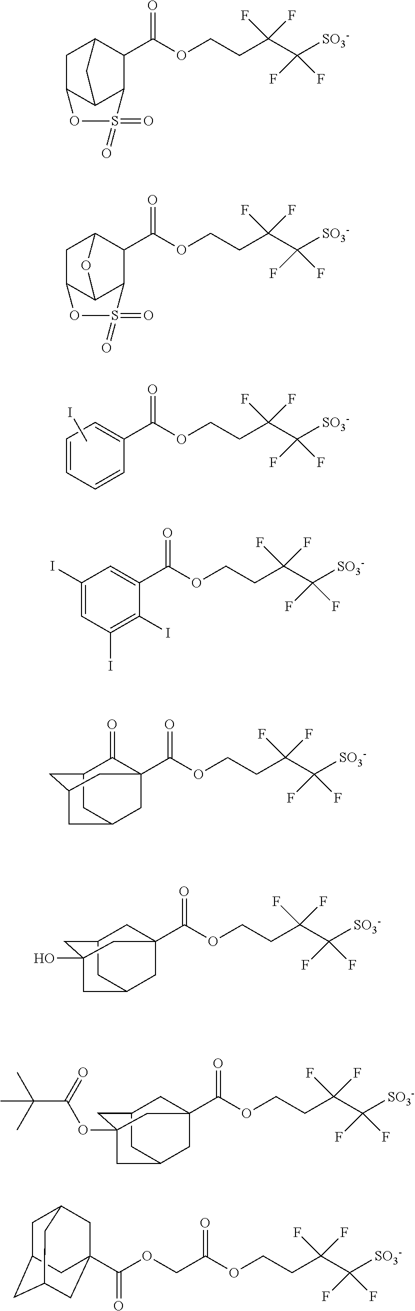

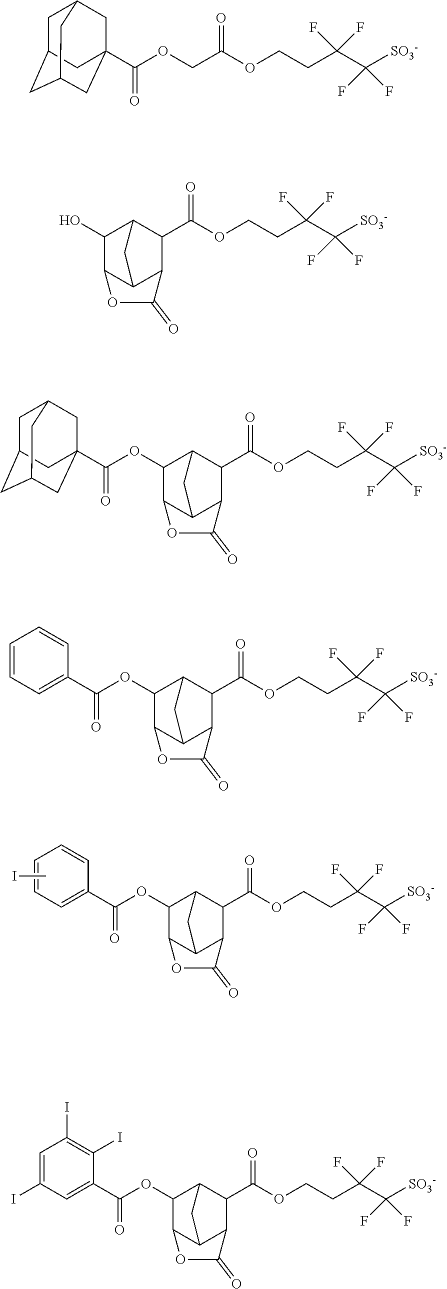

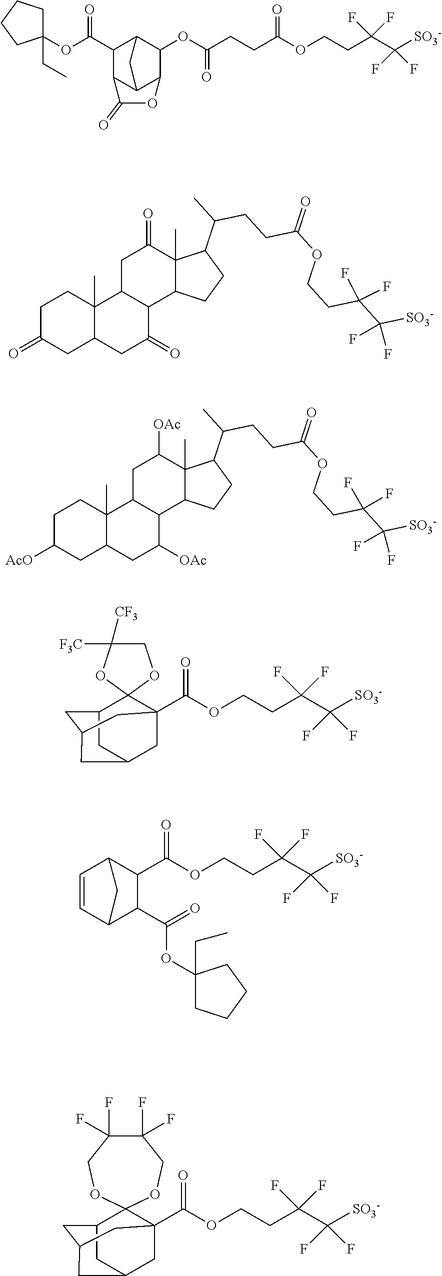

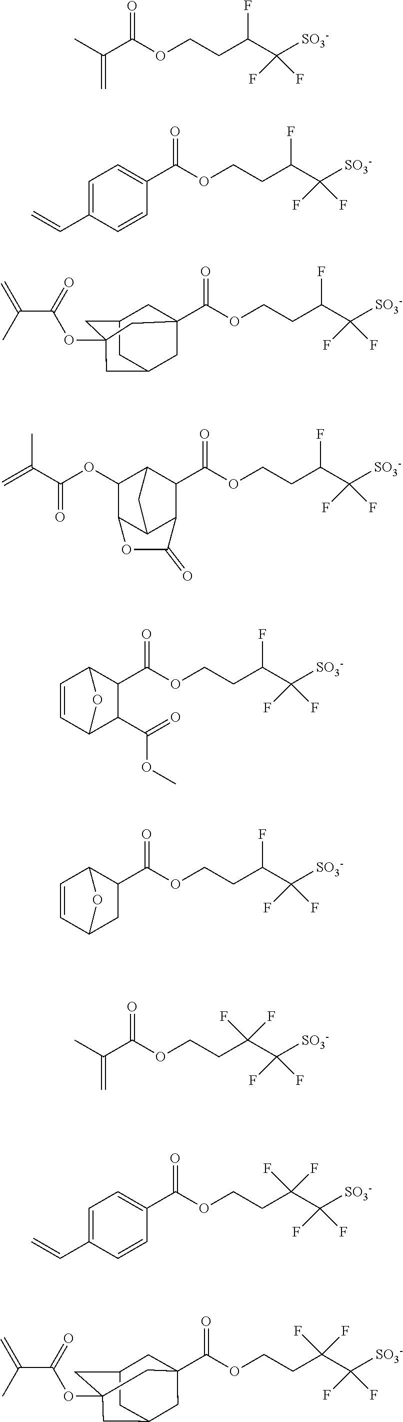

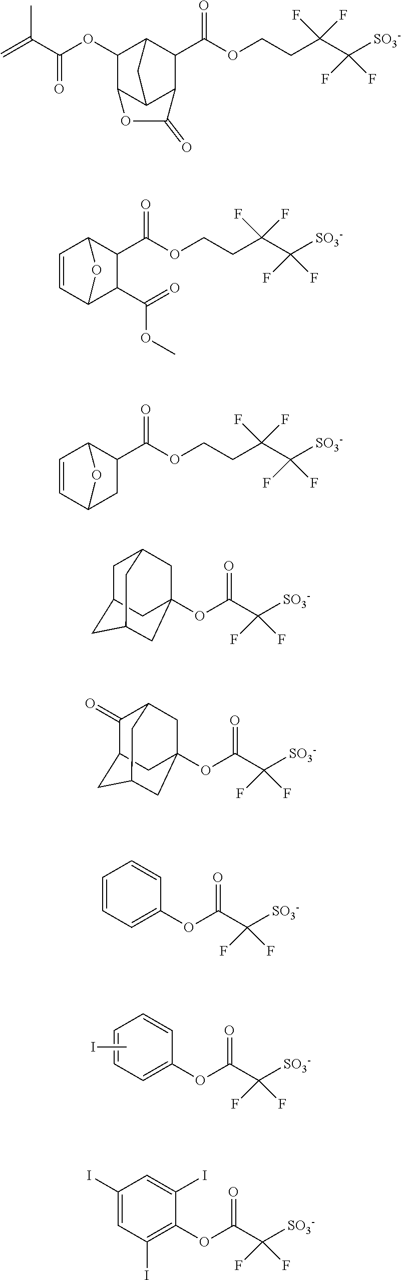

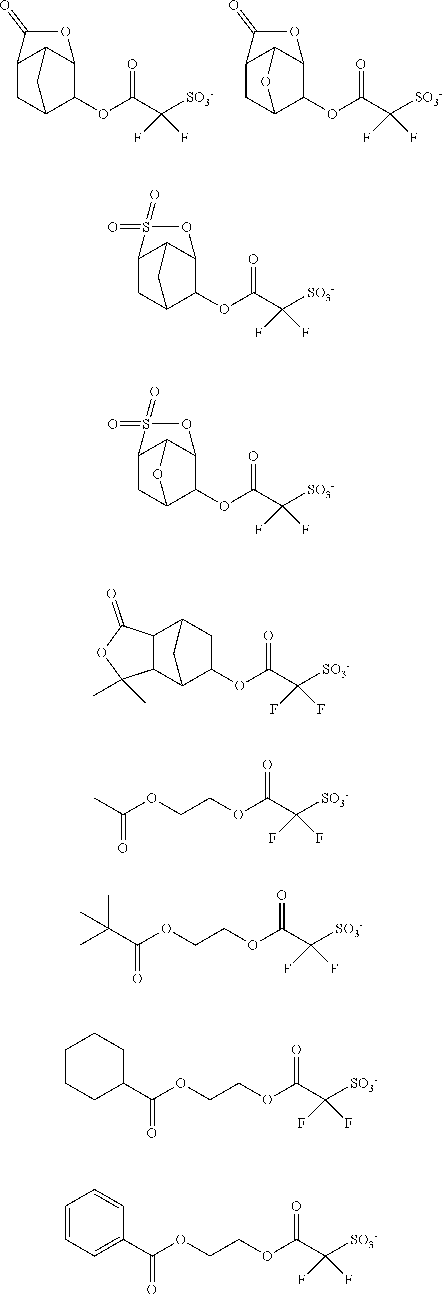

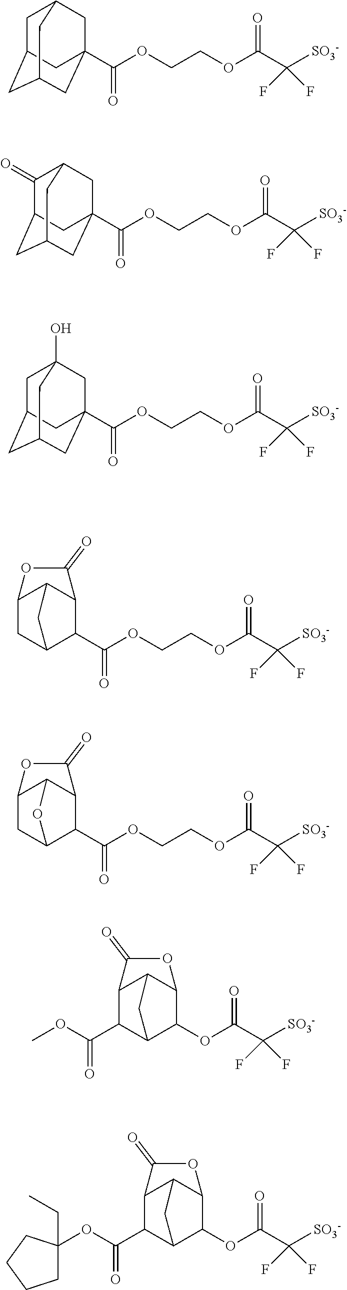

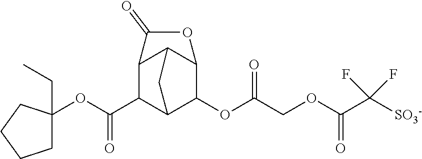

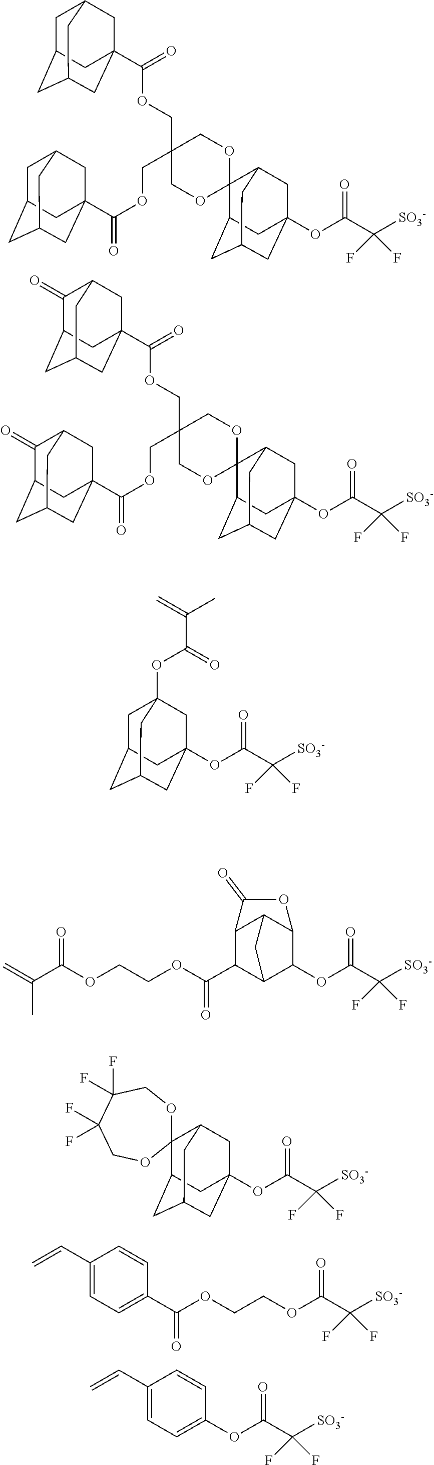

Specific examples of the anion represented by the formula (5-4) include the following, but are not limited thereto.

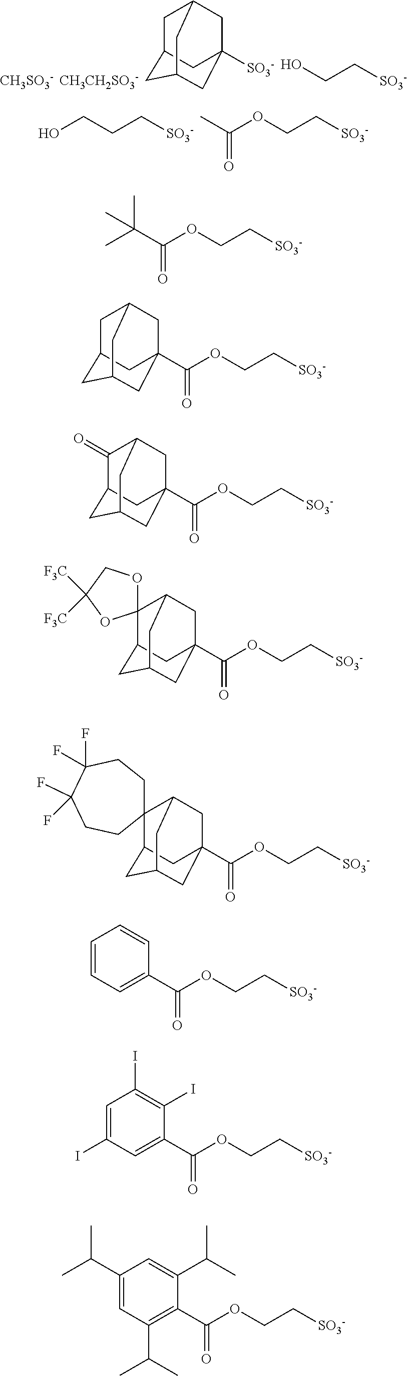

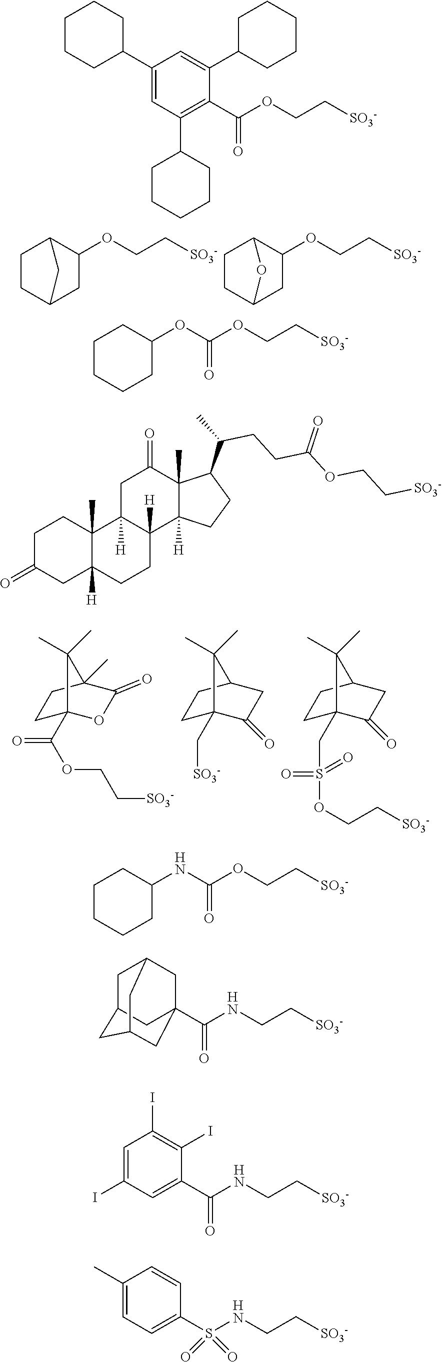

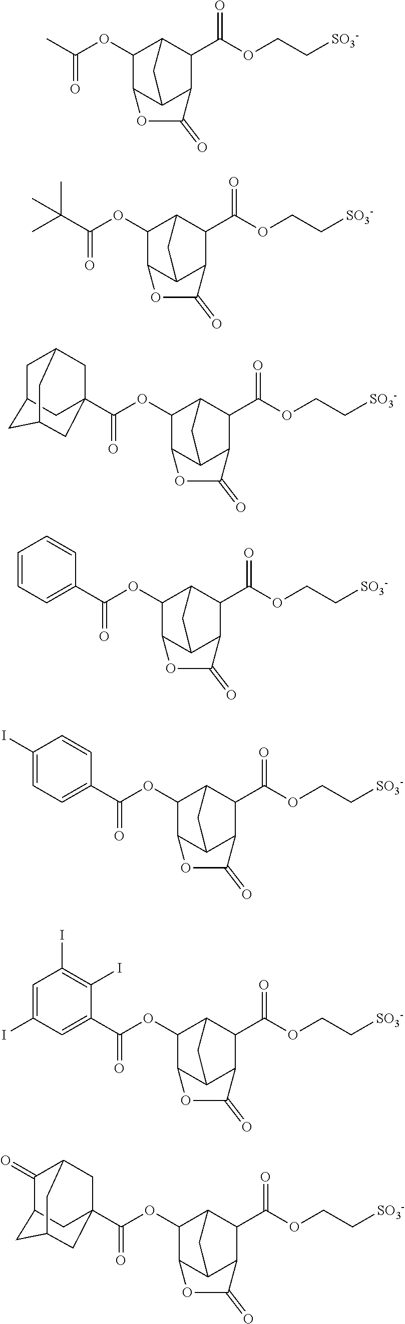

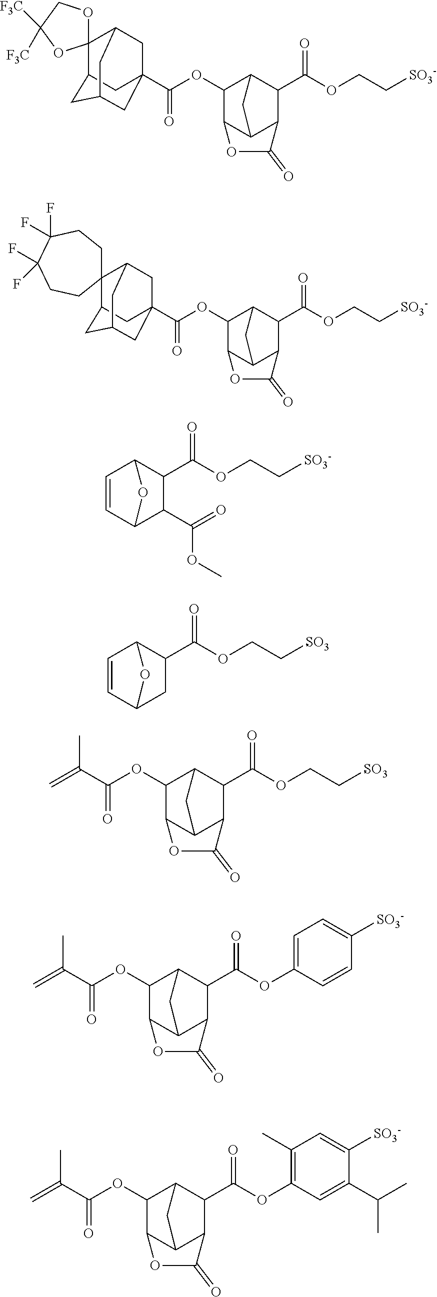

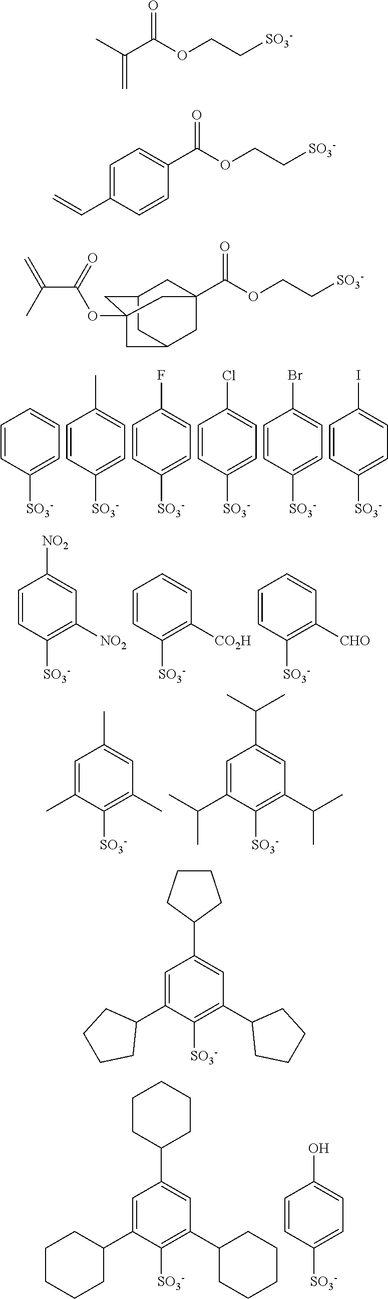

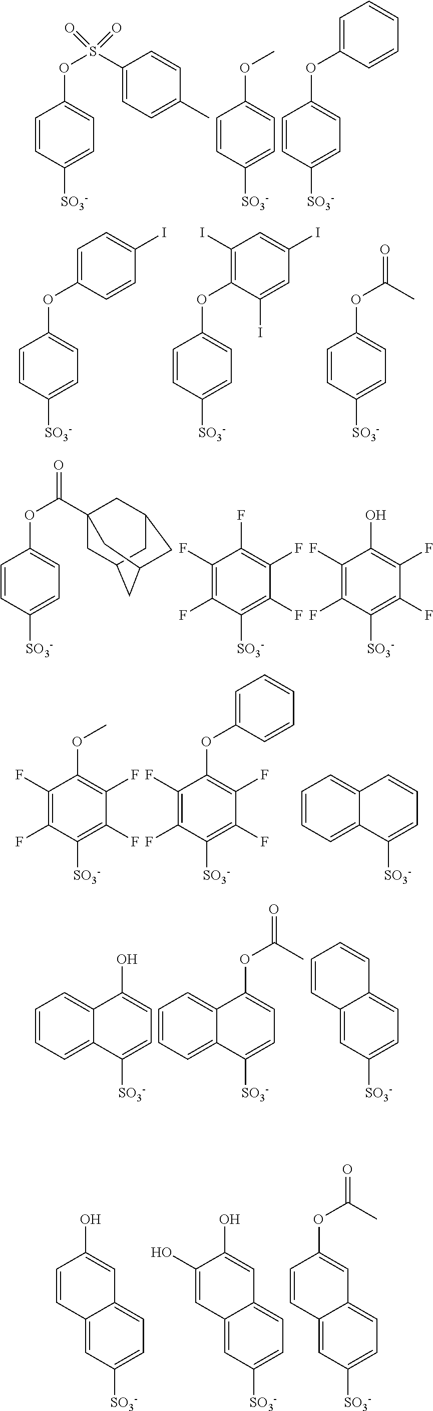

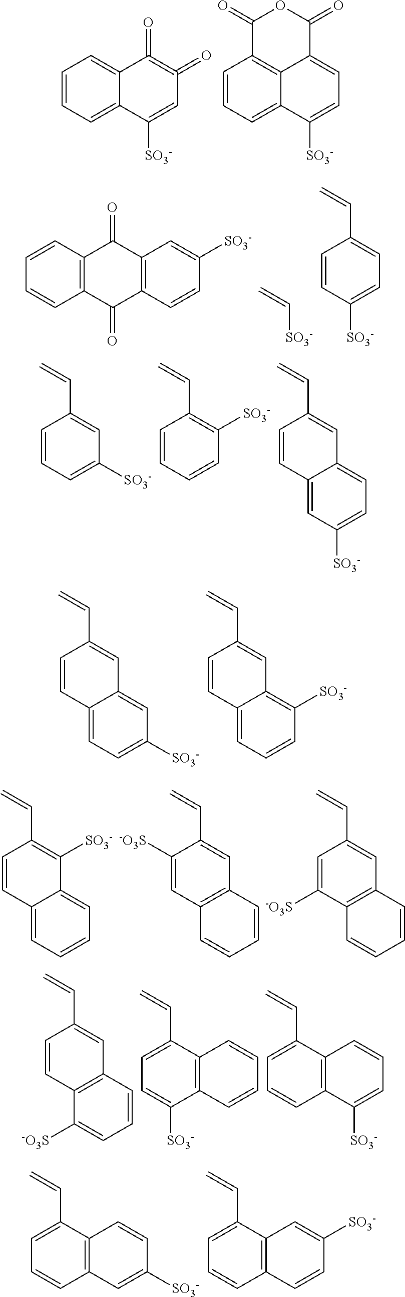

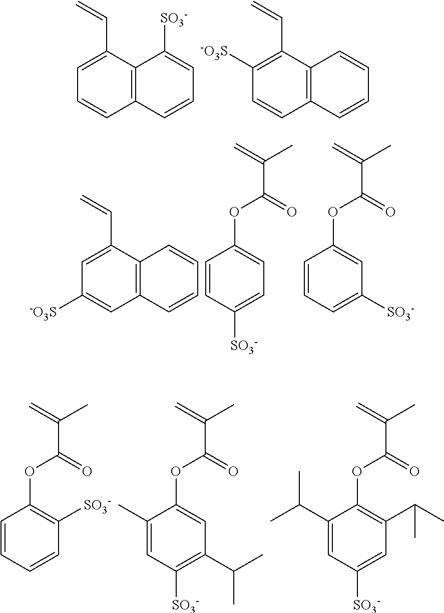

Specific examples of the anion represented by the formula (5-5) include the following, but are not limited thereto.

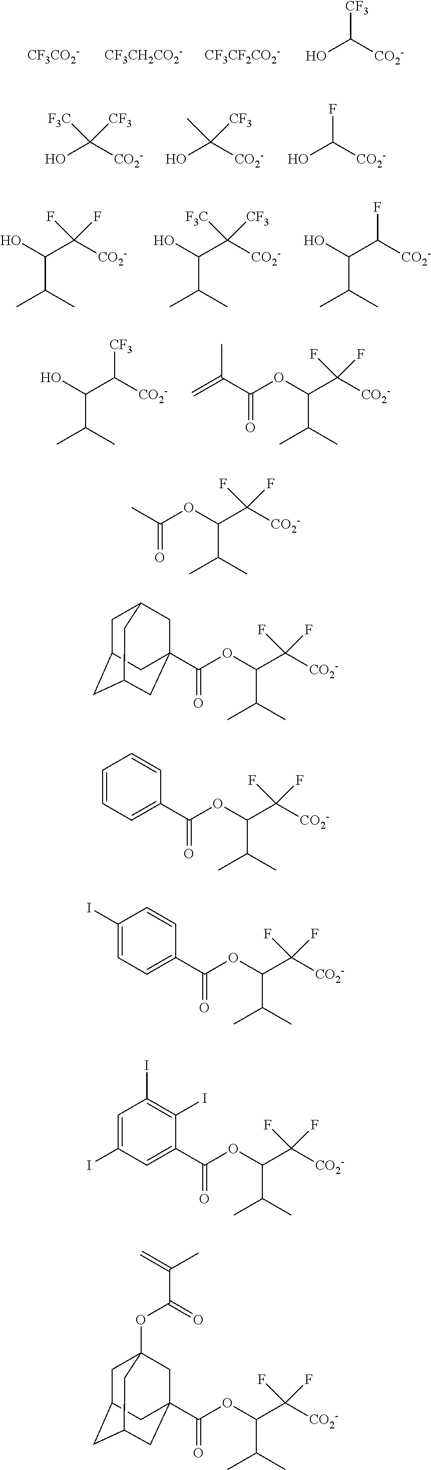

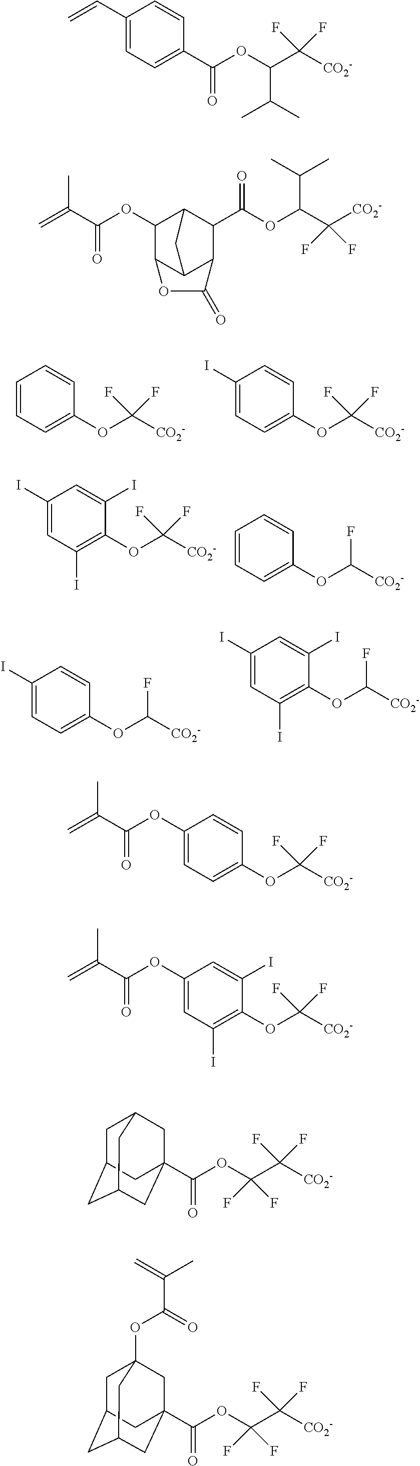

Specific examples of the anion represented by the formula (5-6) include the following, but are not limited thereto.

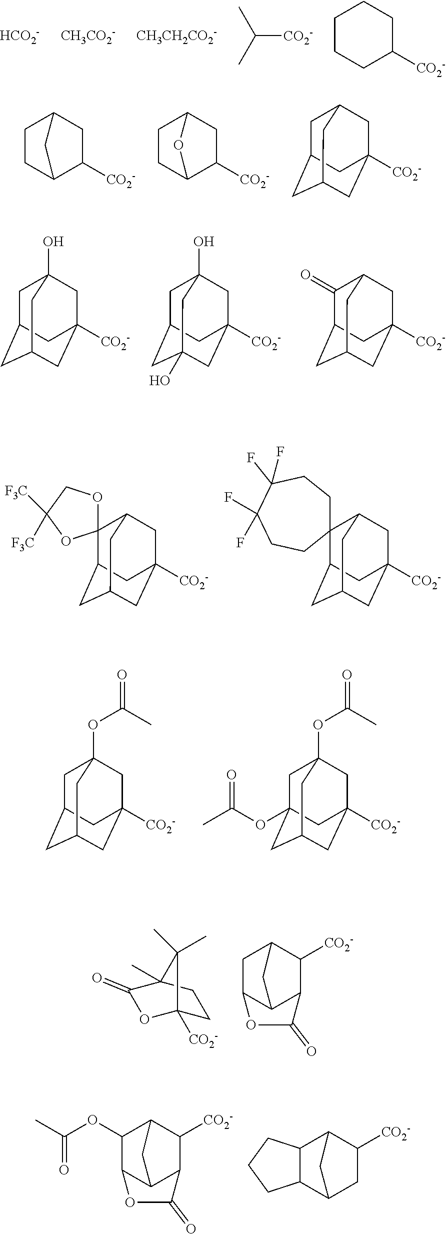

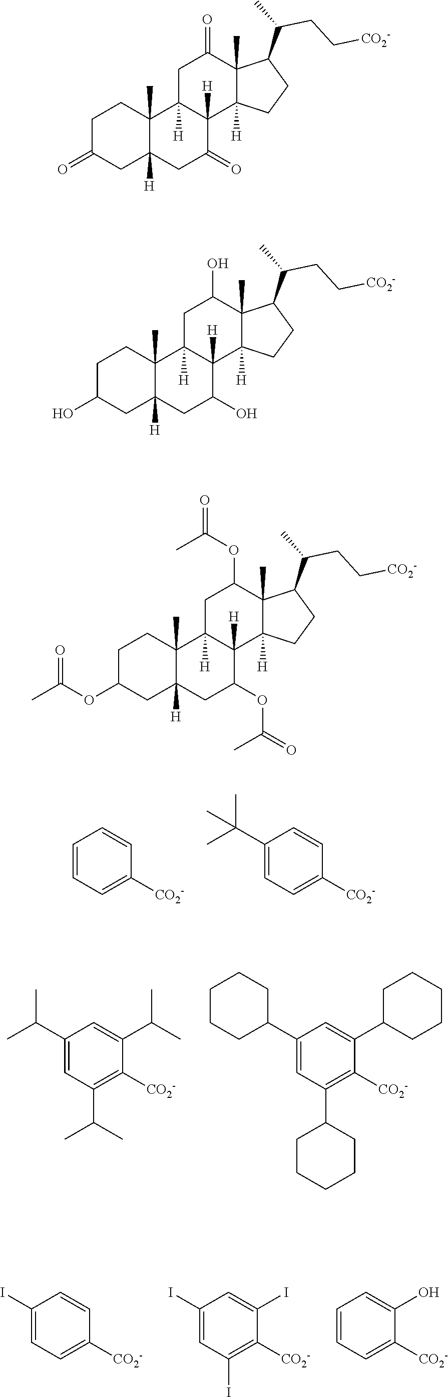

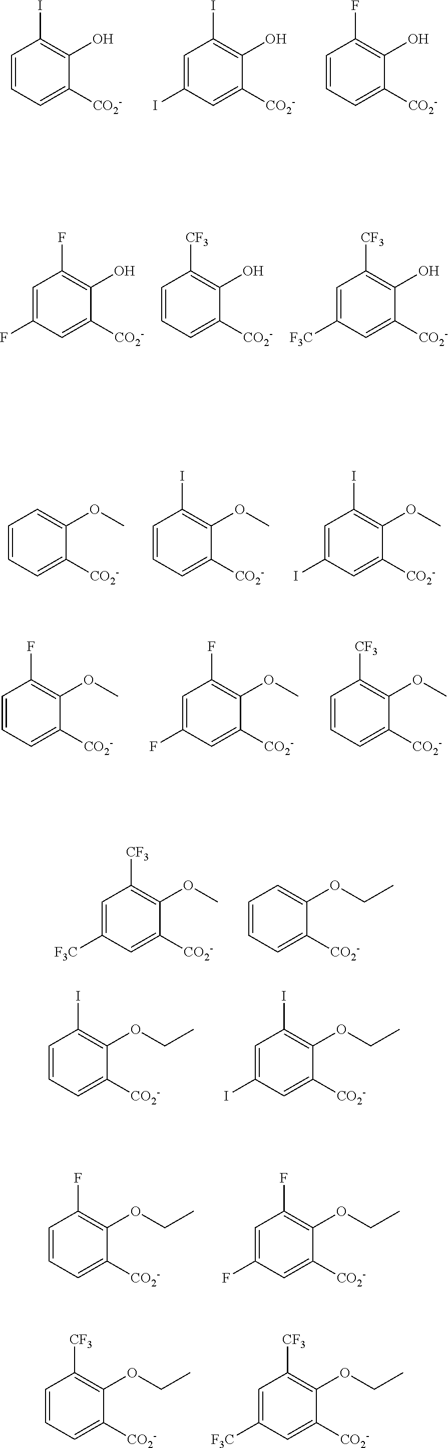

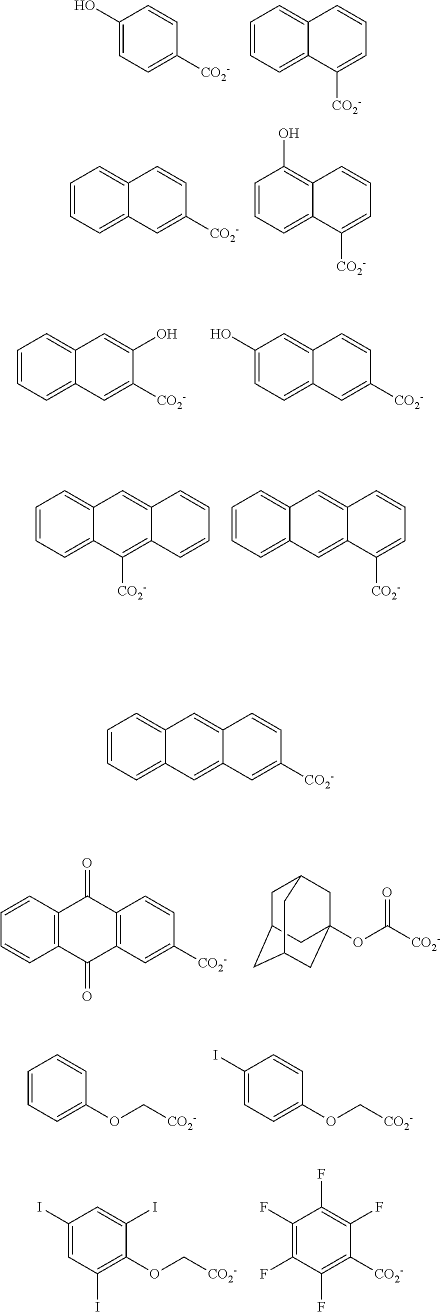

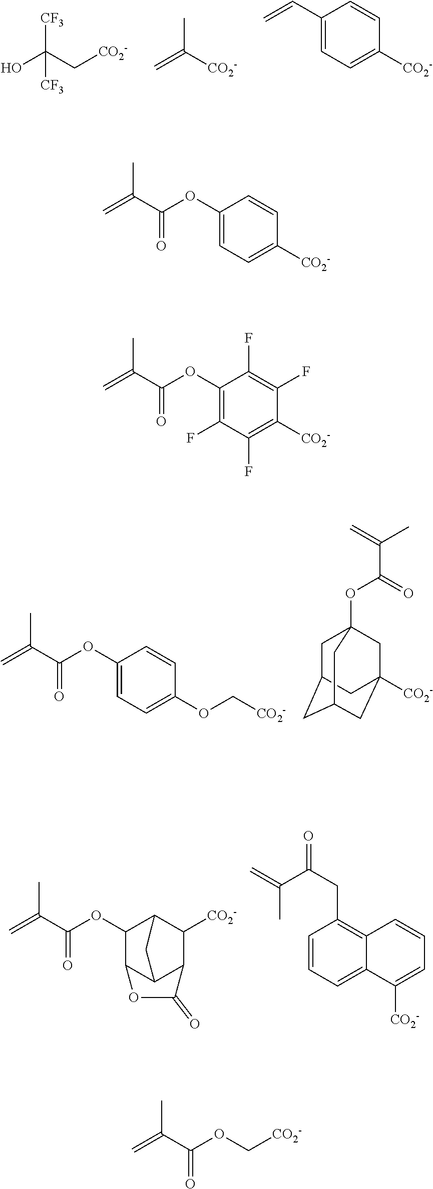

Specific examples of the anion represented by the formula (5-7) include the following, but are not limited thereto.

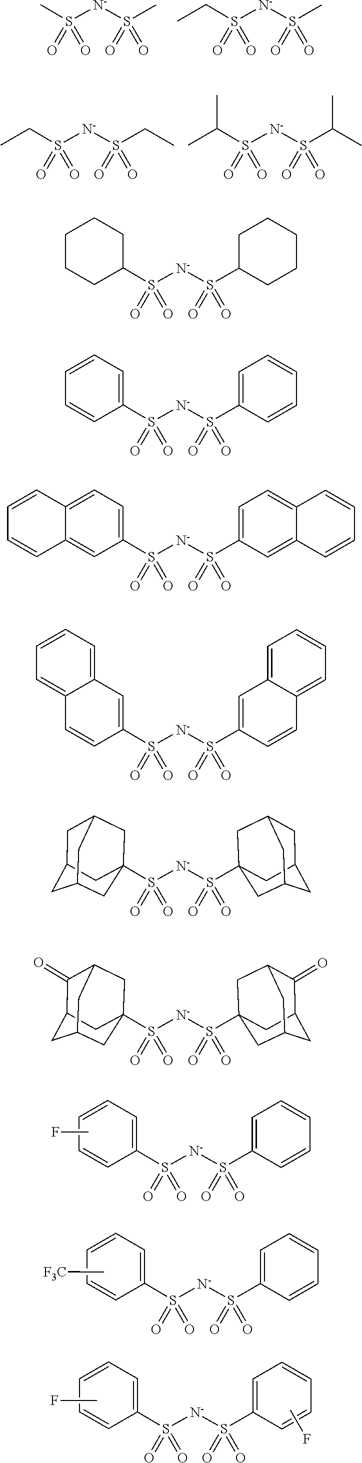

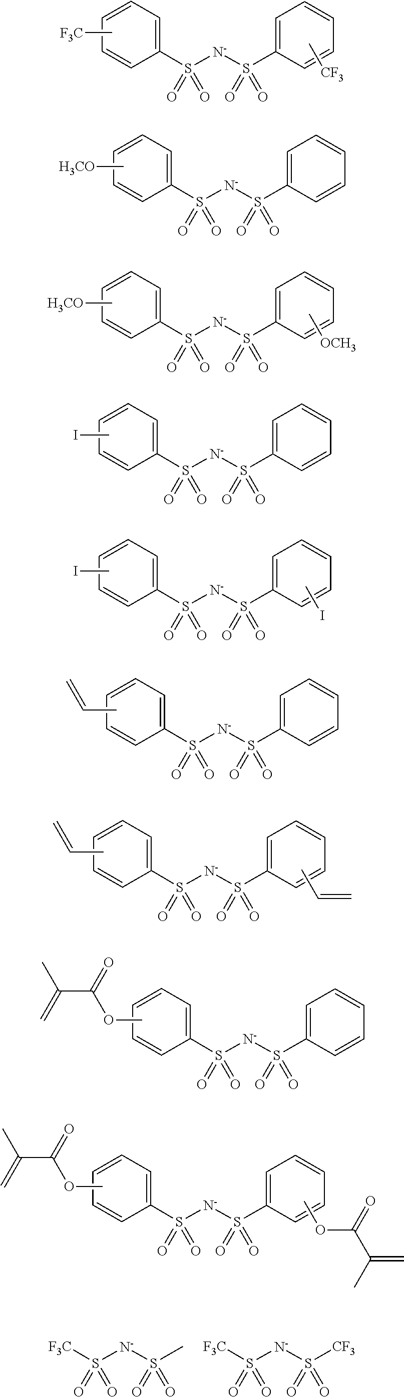

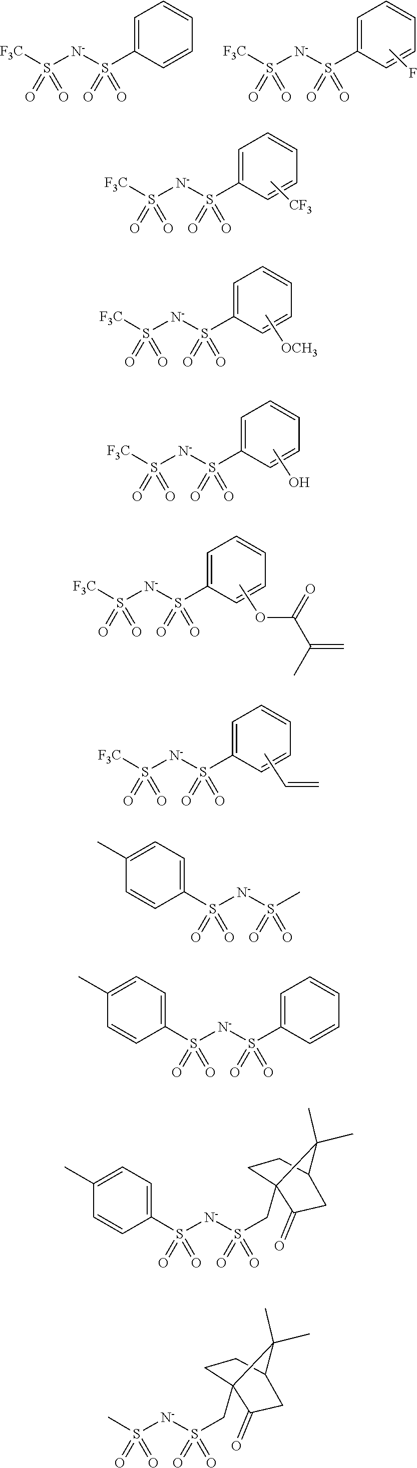

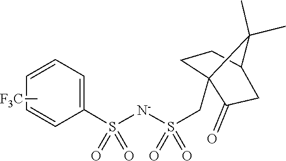

Specific examples of the anion represented by the formula (5-8) include the following, but are not limited thereto.

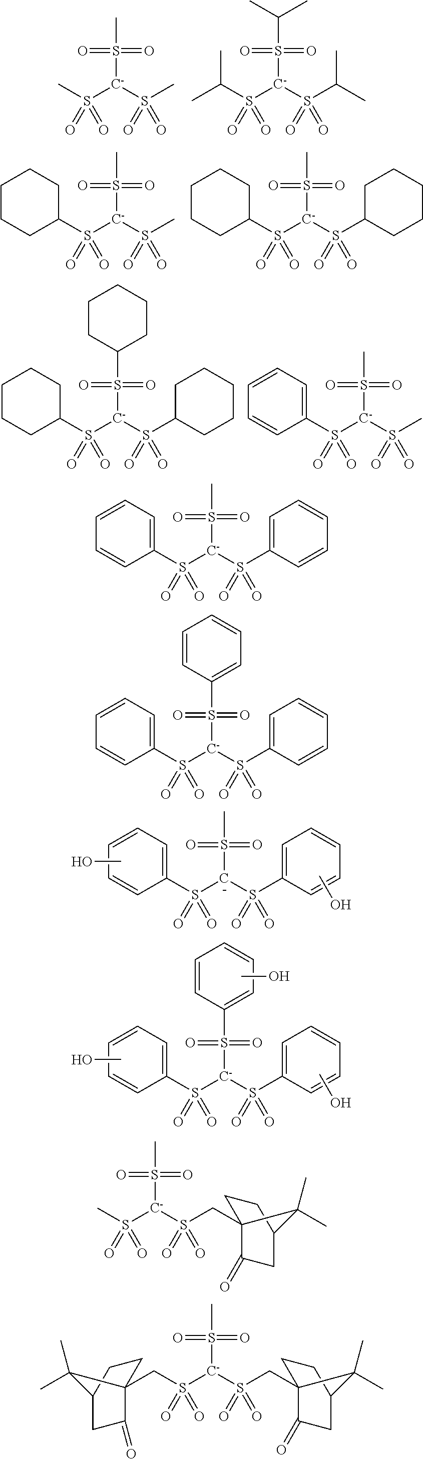

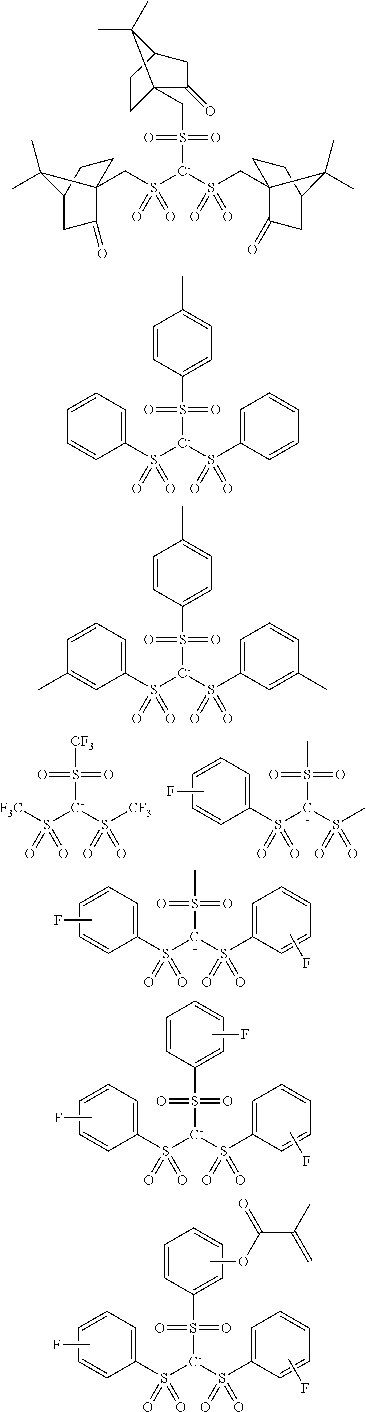

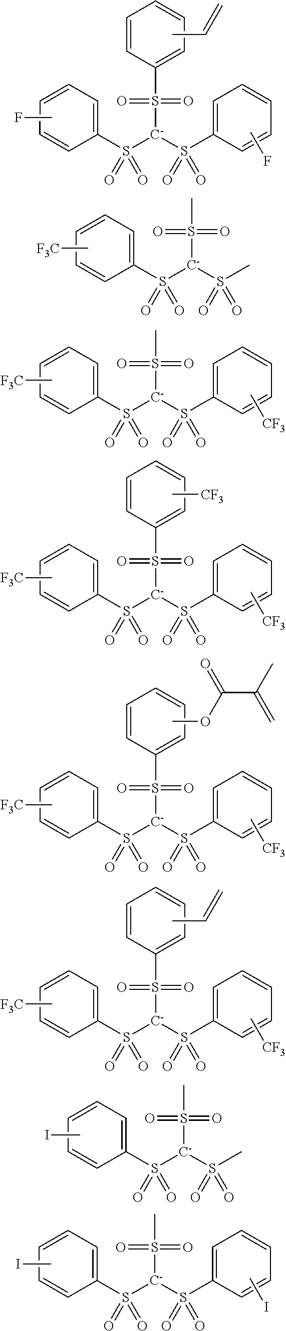

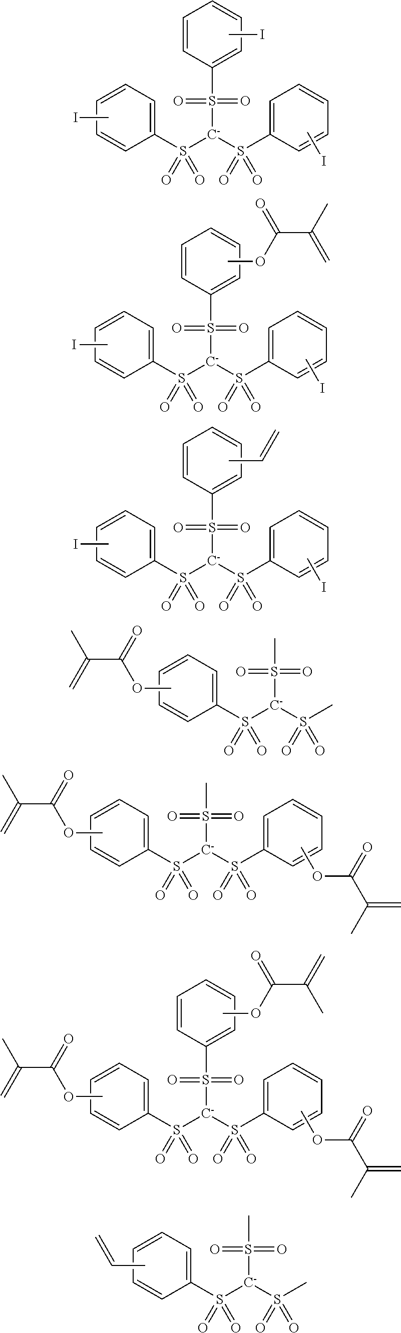

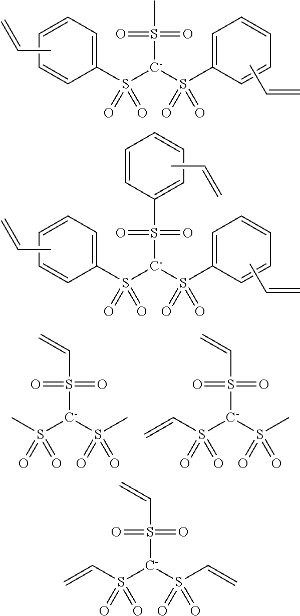

Specific examples of the anion represented by the formula (5-9) include the following, but are not limited thereto.

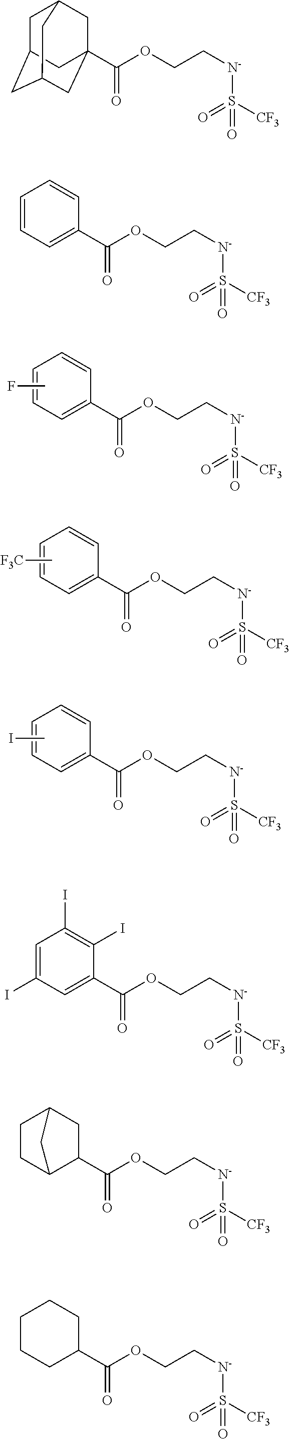

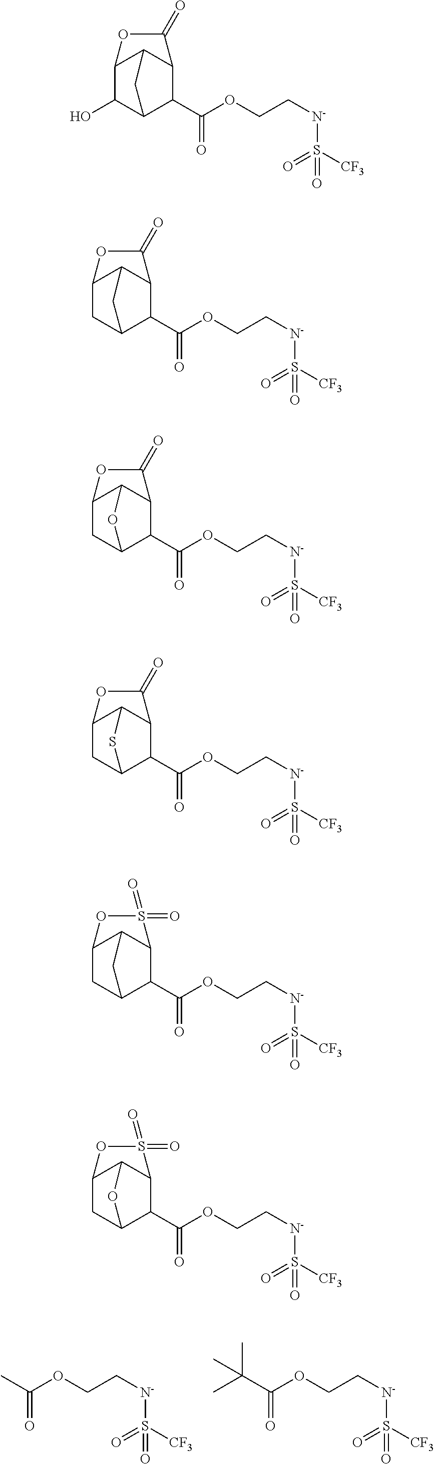

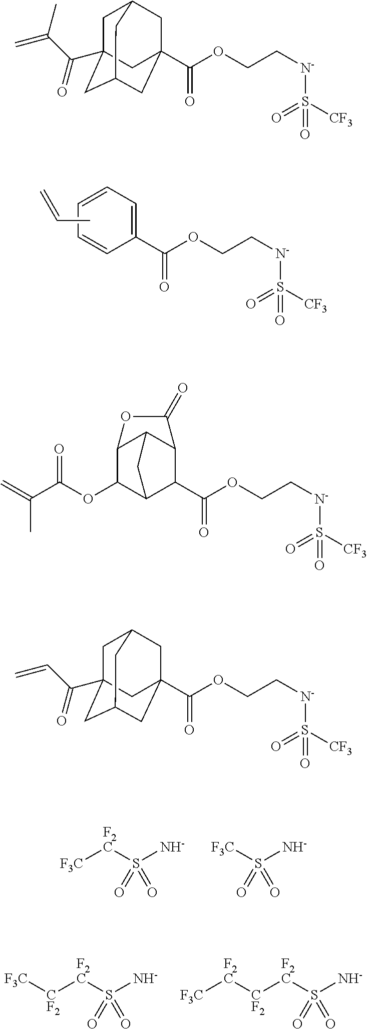

Specific examples of the onium salts include any combination of the above-described anions and cations.

One kind of the onium salts may be used, or two or more kinds thereof may be used in combination. When two or more onium salts are used in combination, it is preferable to use photo-acid generators that generate acids having different acidities. The acid generated in exposed portions of the resist is quenched by a photo-acid generator that generates an acid having a low acidity and is prevented from diffusing to unexposed portions, and thus, it is possible to suppress diffusion and form a high-resolution pattern.

In the inventive resist composition, the content ratio of the hypervalent iodine compound to the photo-acid generator is preferably “hypervalent iodine compound”: “photo-acid generator”=1:1000 to 1000:1, more preferably 1:500 to 500:1 in molar ratio.

When a substituent that has a high molecular weight and is bulky has been introduced to the onium salt, the onium salt has a high excluded volume and can highly suppress the diffusion of the generated acid, and therefore, is suitable when forming a fine pattern.

When the onium salt has an element, such as a fluorine atom or an iodine atom, that has a high effect of absorbing EUV light, the generated amount of secondary electrons increases and the decomposition of cations is promoted, and therefore, the onium salt is suitable for fine patterning with high sensitivity.

### [Laminate]

The present invention provides a laminate including: a substrate; and a resist film, which is a film body formed of the above-described resist composition, on the substrate. In such a laminate, including a resist film obtained from the non-chemically amplified resist composition of the present invention, the resist film, which is a film body of the above-described resist composition, has extremely high sensitivity, also exhibits excellent limiting resolution, is extremely effective for precise fine processing, and in addition, is applicable to either positive or negative patterning. Therefore, the laminate has a wide ranges of uses, and is extremely highly useful in resist process technology.

In this case, a resist underlayer film can be further provided as necessary between the substrate and the resist film.

Furthermore, in the inventive laminate, the resist film preferably contains a product made by a ligand exchange reaction of the hypervalent iodine compound and the carboxy-group-containing compound. That is, the laminate is obtained by forming a substrate and a resist film obtained from the inventive resist composition on the substrate, and the resist film is preferably one formed by ligand exchange between the hypervalent iodine compound and the carboxy-group-containing compound.

As described above, by removing by-product low-molecular-weight carboxylic acid produced during film formation and in the subsequent baking process, the ligand exchange reaction between the hypervalent iodine compound and the carboxy-group-containing compound progresses, and a resist film containing a ligand exchange reaction product is formed (that is, a film body is produced). By the ligand exchange being completed, a polymer in which the carboxy-group-containing compound is crosslinked with the hypervalent iodine compound is obtained. It is preferable to form the resist film on completing the ligand exchange reaction in this manner.

### [Patterning Process]

When the inventive resist composition is used for manufacturing various integrated circuits, a known lithography technique can be applied. Examples of patterning processes include a method including the steps of: forming a resist film by using the above-described resist composition on a substrate or on a resist underlayer film of a substrate on which the resist underlayer film has been laminated; exposing the resist film by using a high-energy beam; and developing the exposed resist film by using a developer. Hereinafter, the resist underlayer film is also simply referred to as an “underlayer film”.

Firstly, the inventive resist composition is applied onto a substrate for manufacturing an integrated circuit, on an underlayer film of a substrate (Si, SiO₂, SiN, SiON, TiN, WSi, BPSG, SOG, organic antireflective film, etc.) on which the underlayer film has been laminated, on a substrate for manufacturing a mask circuit, or on an underlayer film of a substrate (Cr, Cro, CrON, MoSi₂, SiO₂, etc.) on which the underlayer film has been laminated, by an appropriate coating process, such as spin coating, roll coating, flow coating, dip coating, spray coating, or doctor coating, so that the thickness of the coating film is 0.01 to 2 μm. The resultant is prebaked on a hot plate preferably at 60 to 200° C. for 10 seconds to 30 minutes, more preferably 80 to 180° C. for 30 seconds to 20 minutes. Thus, a resist film is formed. Note that an underlayer film means a film formed between the substrate and the resist film in a multilayer resist process. The underlayer film is not particularly limited, and a conventionally known film can be used.

Subsequently, the resist film is exposed by using a high-energy beam. Examples of the high-energy beam include ultraviolet ray (g-line (436 nm), h-line (405 nm), i-line (365 nm), etc.), deep ultraviolet ray, EB, EUV, X-ray, soft X-ray, excimer laser beam (KrF excimer laser beam, ArF excimer laser beam, etc.), γ-ray, and synchrotron radiation. As the high-energy beam, it is preferable to use an i-line, a KrF excimer laser beam, an ArF excimer laser beam, an electron beam, or an extreme ultraviolet ray. When ultraviolet ray, deep ultraviolet ray, EUV, X-ray, soft X-ray, excimer laser beam, Y-ray, synchrotron radiation, or the like is employed as the high-energy beam, the irradiation is performed directly or while using a mask for forming a target pattern at an exposure dose of preferably about 1 to 300 mJ/cm², more preferably about 10 to 200 mJ/cm². When an EB is employed as the high-energy beam, the writing is performed directly or while using a mask for forming a target pattern at an exposure dose of preferably about 0.1 to 8000 μC/cm², more preferably about 0.5 to 5000 μC/cm². Note that the inventive resist composition is particularly suitable for fine patterning with an EB or EUV, among the high-energy beams.

After the exposure, PEB is performed as necessary. In this event, the PEB is preferably performed after the exposure on a hot plate or in an oven under the conditions of 30 to 200° C. for 10 seconds to 30 minutes, more preferably 60 to 120° C. for 30 seconds to 20 minutes.

After the exposure or after the PEB, development is performed by using a developer to perform patterning. Examples of the developer used in this event include: aqueous alkaline solutions, such as an aqueous solution of tetramethylammonium hydroxide and an aqueous solution of tetrabutylammonium hydroxide; and organic solvents, such as 2-octanone, 2-nonanone, 2-heptanone, 3-heptanone, 4-heptanone, 2-hexanone, 3-hexanone, diisobutyl ketone, 5-methyl-2-hexanone, methylcyclohexanone, acetophenone, methylacetophenone, isopropyl alcohol, isoamyl alcohol, n-butanol, tert-butyl alcohol, tert-pentyl alcohol, n-pentanol, cyclohexanol, formic acid, acetic acid, propionic acid, propyl acetate, butyl acetate, isobutyl acetate, pentyl acetate, butenyl acetate, isopentyl acetate, cyclohexyl acetate, 4-tert-butylcyclohexyl acetate, octyl acetate, isobornyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, phenylmethyl acetate, phenylethyl acetate, benzyl formate, phenylethyl formate, methyl 3-phenylpropionate, benzyl propionate, 2-phenylethyl acetate, 1-propanol, 3-methoxybutanol, 3-methyl-3-methoxybutanol, 1-methoxy-2-propanol, 1-ethoxy-2-propanol, 3-methyl-1-butanol, diacetone alcohol, 4-methyl-2-pentanol, 3-methylcyclohexanol, 3,5,5-trimethylhexyl alcohol, 2,6-dimethyl-4-heptanol, toluene, anisole, and ε-caprolactone. One kind of these developers may be used, or two or more kinds thereof may be used in mixture.

After the development, rinsing is performed as necessary. The rinsing liquid is preferably a solvent that is miscible with the developer but does not dissolve the resist film. As such a solvent, it is preferable to use an alcohol having 3 to 10 carbon atoms, an ether compound having 8 to 12 carbon atoms, an alkane, alkene, alkyne, and aromatic solvent, each having 6 to 12 carbon atoms.

The rinsing can reduce resist pattern collapse and defect formation. Meanwhile, the rinsing is not necessarily essential, and the amount of the solvent used can be reduced by not performing the rinsing.

In the inventive resist composition, a difference occurs in the solubility between exposed portions and unexposed portions by virtue of exposure as described above, and a positive or negative pattern can be formed. Therefore, it is possible to use a developer that dissolves exposed portions and does not dissolve unexposed portions, or a developer that dissolves unexposed portions and does not dissolve exposed portions. Thus, the inventive patterning process makes it possible to form a positive or negative pattern by appropriately selecting a developer, and therefore, is widely applicable to various kinds of fine patterning.

### EXAMPLES

Hereinafter, the present invention will be specifically described with reference to Synthesis Examples, Examples, and Comparative Example. However, the present invention is not limited to the following Examples.

### [1] Synthesis of Carboxy-Group-Containing Polymer

The monomers used for the synthesis of carboxy-group-containing polymers are as follows.

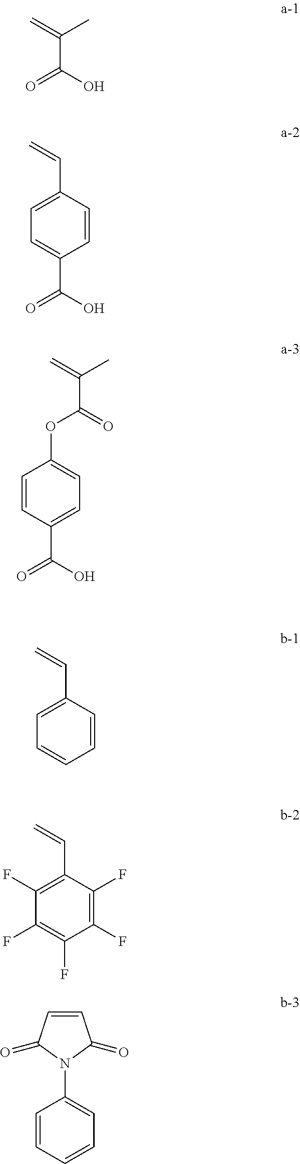

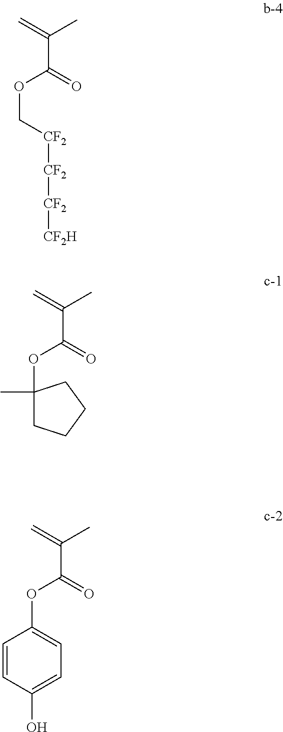

### [Synthesis Example 1-1] Production of Polymer P-1

Under a nitrogen atmosphere, the monomer a-1 (56 g) and the monomer b-1 (36 g) were dissolved in 100 g of MEK, and 20 minutes of degassing under reduced pressure and nitrogen substitution were repeated three times to prepare a solution A. Separately, 2.90 g of dimethyl 2,2′-azobisisobutyrate (I-1) was dissolved in 10.0 g of MEK, and 20 minutes of degassing under reduced pressure and nitrogen substitution were repeated three times to prepare a solution B. Furthermore, 8.79 g of 2-cyano-2-propyl benzodithioate was dissolved in 20.0 g of MEK, and 20 minutes of degassing under reduced pressure and nitrogen substitution were repeated three times to prepare a solution C. Then, the reaction vessel of the solution C was heated so as to achieve a temperature of 80° C. inside the reaction vessel. The solution A and the solution B were each independently added dropwise thereto over 2 hours by using a syringe pump. After the dropwise addition, the polymerization liquid was stirred for 6 hours while being maintained at 80° C., and cooled to room temperature (the above process will be referred to as step RM-1).

Subsequently, 8.60 g of dimethyl 2,2′-azobisisobutyrate and 15.0 g of thioglycolic acid were dissolved in 33.3 g of MEK, and 20 minutes of degassing under reduced pressure and nitrogen substitution were repeated three times to prepare a solution D. The solution D was added dropwise to the reaction solution of the step RM-1 over 5 minutes by using a syringe pump. After the dropwise addition, the reaction vessel was heated again so as to achieve a temperature of 80° C. inside, and the mixture was stirred for 2 hours while being maintained at 80° C. and cooled to room temperature.

Subsequently, the obtained polymerization liquid was added dropwise to 4000 g of vigorously stirred hexane, and the precipitated polymer was filtered. The obtained polymer was washed twice with hexane (1200 g), and then dried in vacuo at 50° C. for 20 hours to obtain a white powder polymer P-1 (90 g, 98% yield). The polymer P-1 had Mw of 8000 and Mw/Mn of 1.11. Note that the Mw is a standard polystyrene-converted measurement value obtained by GPC using THE as an eluent. The details are as follows (the same, hereinafter).
Apparatus: HLC-8320GPC
Column:

$$TSK guardcolumn + TSKgel G 4000 HXL + TSKgel G 2000 HXL + TSKgel superH 5000$$

Constant temperature of pump and column: 40° C.
Eluent: THF
Detector: RI (refractive index) detector
Injection volume: 100 μl

### [Synthesis Examples 1-2 to 1-12] Synthesis of Polymers P-2 to P-12

The polymers shown in Table 1 below were synthesized in the same manner as in Synthesis Example 1-1 except that the kinds and blending ratios of the monomers were changed.

### [Synthesis Example 1-13] Synthesis of Polymer P-13

Under a nitrogen atmosphere, the monomer a-1 (56 g), the monomer b-1 (36 g), 5.4 g of V-601 (manufactured by FUJIFILM Wako Pure Chemical Corporation), and 180 g of MEK were added into a flask to prepare a monomer-polymerization initiator solution. Into another flask with a nitrogen atmosphere, 55 g of MEK was added and heated to 80° C. with stirring, and then the monomer-polymerization initiator solution was added dropwise over 4 hours. After the dropwise addition, the polymerization liquid was further stirred for 2 hours with maintaining the temperature at 80° C., and then cooled to room temperature. The obtained polymerization liquid was added dropwise to 4000 g of vigorously stirred hexane, and the precipitated polymer was filtered. The obtained polymer was washed twice with hexane (1200 g), and then dried in vacuo at 50° C. for 20 hours to obtain a white powder polymer P-13 (90 g, 98% yield). The polymer P-13 had Mw of 8000 and Mw/Mn of 1.42. Note that the Mw is a polystyrene-converted measurement value obtained by GPC using THE as an eluent.

### [Synthesis Examples 1-14 and 1-15] Synthesis of Polymers P-14 and P-15

The polymers shown in Table 1 below were synthesized in the same manner as in Synthesis Example 1-13 except that the kinds and blending ratios of the monomers were changed.

TABLE 1

| | | Introduction | | Introduction | | |
|---|---|---|---|---|---|---|
| Base | Unit | rate | Unit | rate | | |
| polymer | 1 | (mol %) | 2 | (mol %) | Mw | Mw/Mn |
| P-1 | a-1 | 65 | b-1 | 35 | 8000 | 1.11 |
| P-2 | a-1 | 50 | b-2 | 50 | 8400 | 1.13 |
| P-3 | a-1 | 60 | b-3 | 40 | 8100 | 1.11 |
| P-4 | a-1 | 60 | b-4 | 40 | 8100 | 1.10 |
| P-5 | a-2 | 65 | b-1 | 35 | 8000 | 1.11 |
| P-6 | a-2 | 50 | b-2 | 50 | 8600 | 1.15 |
| P-7 | a-2 | 60 | b-3 | 40 | 7900 | 1.10 |
| P-8 | a-2 | 65 | b-4 | 35 | 8200 | 1.11 |
| P-9 | a-3 | 65 | b-1 | 35 | 8700 | 1.12 |
| P-10 | a-3 | 50 | b-2 | 50 | 9000 | 1.11 |
| P-11 | a-3 | 60 | b-3 | 40 | 7500 | 1.10 |
| P-12 | a-3 | 65 | b-4 | 35 | 8600 | 1.12 |
| P-13 | a-1 | 65 | b-1 | 35 | 8000 | 1.42 |
| P-14 | a-2 | 65 | b-1 | 35 | 8000 | 1.44 |
| P-15 | c-1 | 60 | c-2 | 40 | 8500 | 1.45 |

As shown in Table 1, narrowly dispersed polymers, having low dispersity (Mw/Mn), were obtained by living radical polymerization using a RAFT agent.

### [2] Preparation of Resist Composition

### Examples 2-1 to 2-20 and Comparative Examples 2-1 to 2-4

A hypervalent iodine compound and a carboxy-group-containing compound were dissolved in a solvent containing 0.01 mass % of a surfactant (PF-636, manufactured by OMNOVA Solutions Inc.) in the constitution shown below in Table 2, and the obtained solution was filtered with a 0.2-μm Teflon (registered trademark) filter to prepare a resist composition (R-01 to R-20, CR-01, and CR-02). Meanwhile, a polymer, a photo-acid generator, and a sensitivity modifier were dissolved in a solvent containing 0.01 mass % of a surfactant (PF-636, manufactured by OMNOVA Solutions Inc.) in the constitution shown below in Table 3, and the obtained solution was filtered with a 0.2-μm Teflon (registered trademark) filter to prepare a resist composition (CR-03 and CR-04).

TABLE 2

| | | | Other | | | | | |
|---|---|---|---|---|---|---|---|---|
| | | Hypervalent | hypervalent | Carboxylic | | | | |
| | | iodine | iodine | acid | | | | |
| | | compound | compound | Compound | Solvent 1 | | Solvent 2 | |
| | | (parts | (parts | (parts | (parts | | (parts | |
| | Resist | by mass) | by mass) | by mass) | by mass) | | by mass) | |
| Example 1-1 | R-01 | I-1 (11) | | P-1 (9) | PGMEA | (800) | AcOH | (200) |
| Example 1-2 | R-02 | I-2 (9) | | P-1 (9) | PGMEA | (800) | AcOH | (200) |
| Example 1-3 | R-03 | I-3 (15) | | P-1 (9) | PGMEA | (800) | AcOH | (200) |
| Example 1-4 | R-04 | I-4 (11) | | P-1 (9) | PGMEA | (800) | AcOH | (200) |
| Example 1-5 | R-05 | I-5 (5) | I-2 (4) | P-1 (9) | PGMEA | (800) | AcOH | (200) |
| Example 1-6 | R-06 | I-6 (14) | | P-1 (9) | PGMEA | (800) | AcOH | (200) |
| Example 1-7 | R-07 | I-7 (11) | | P-1 (9) | PGMEA | (800) | AcOH | (200) |
| Example 1-8 | R-08 | I-8 (9) | | P-1 (9) | PGMEA | (800) | AcOH | (200) |
| Example 1-9 | R-09 | I-9 (14) | | P-1 (9) | PGMEA | (800) | AcOH | (200) |
| Example 1-10 | R-10 | I-1 (11) | | P-2 (17) | PGMEA | (800) | AcOH | (200) |
| Example 1-11 | R-11 | I-1 (11) | | P-3 (12) | PGMEA | (800) | AcOH | (200) |
| Example 1-12 | R-12 | I-1 (11) | | P-4 (17) | PGMEA | (800) | AcOH | (200) |
| Example 1-13 | R-13 | I-1 (11) | | P-5 (12) | PGMEA | (800) | AcOH | (200) |
| Example 1-14 | R-14 | I-1 (11) | | P-6 (21) | PGMEA | (800) | AcOH | (200) |
| Example 1-15 | R-15 | I-1 (11) | | P-7 (16) | PGMEA | (800) | AcOH | (200) |
| Example 1-16 | R-16 | I-1 (11) | | P-8 (19) | PGMEA | (800) | AcOH | (200) |
| Example 1-17 | R-17 | I-1 (11) | | P-9 (21) | PGMEA | (800) | AcOH | (200) |
| Example 1-18 | R-18 | I-1 (11) | | P-10 (29) | PGMEA | (800) | AcOH | (200) |
| Example 1-19 | R-19 | I-1 (11) | | P-11 (25) | PGMEA | (800) | AcOH | (200) |
| Example 1-20 | R-20 | I-1 (11) | | P-12 (27) | PGMEA | (800) | AcOH | (200) |
| Comparative | CR-01 | I-1 (11) | | P-13 (9) | PGMEA | (800) | AcOH | (200) |
| Example 1-1 | | | | | | | | |
| Comparative | CR-02 | I-1 (11) | | P-14 (12) | PGMEA | (800) | AcOH | (200) |
| Example 1-2 | | | | | | | | |

TABLE 3

| | | | Photo-acid | Sensitivity | | |
|---|---|---|---|---|---|---|
| | | Polymer | generator | modifier | Solvent 1 | Solvent 2 |
| | Resist | (parts | (parts | (parts | (parts | (parts |
| | composition | by mass) | by mass) | by mass) | by mass) | by mass) |
| Comparative | CR-03 | P-15 (80) | PAG-1 (19) | Q-1 (6) | PGMEA | GBL (210) |
| Example 1-3 | | | | | (1890) | |
| Comparative | CR-04 | P-15 (80) | PAG-1 (19) | I-1 (5) | PGMEA | GBL (210) |
| Example 1-4 | | | | | (1890) | |

In Tables 2 and 3, hypervalent iodine compounds I-1 to I-9, photo-acid generator PAG-1, sensitivity modifier Q-1, and solvents are as follows.

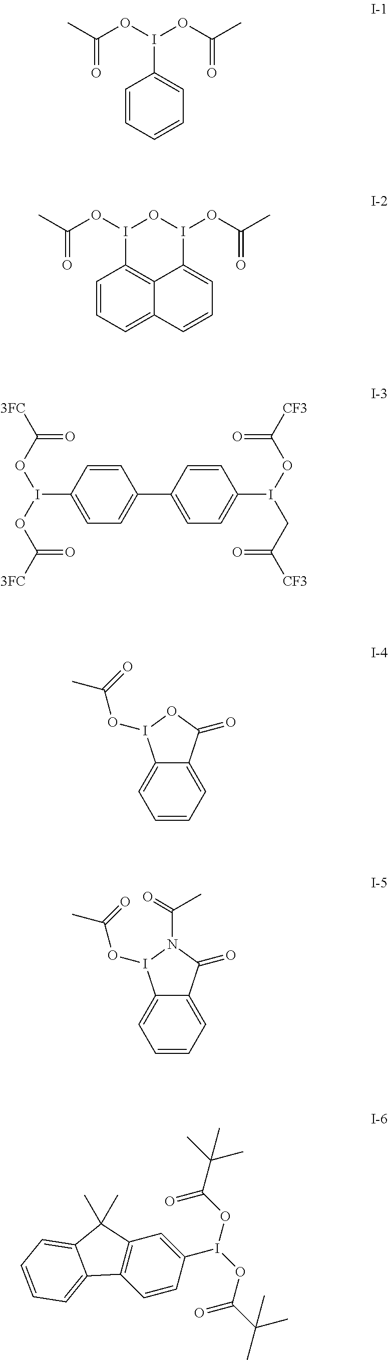

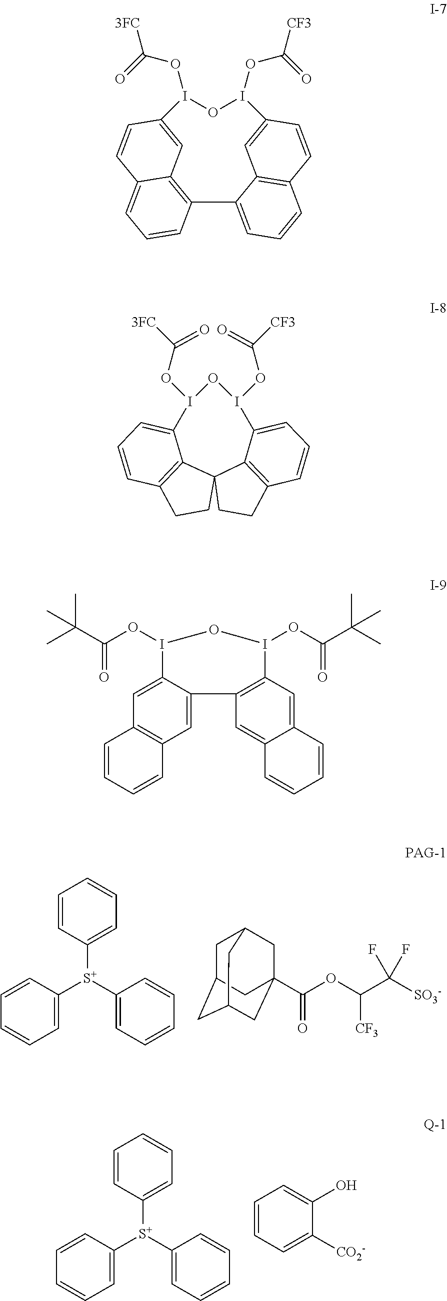

### Solvents:

PGMEA (propylene glycol monomethyl ether acetate)
AcOH (acetic acid)
GBL (γ-butyrolactone)

### [3] EUV Lithography Evaluation (Line-and-Space Pattern)

### Examples 3-1 to 3-20 and Comparative Examples 3-1 to 3-4

Each of the resist compositions (R-01 to R-20 and CR-01 to CR-04) was applied by spin-coating on a Si substrate on which a silicon-containing spin-on hard mask SHB-A940, manufactured by Shin-Etsu Chemical Co., Ltd. (silicon content of 43 mass %), was formed with 20 nm in film thickness, and subjected to prebake (PAB) by using a hot plate at the temperature shown in Table 4 for 60 seconds to form a resist film having a film thickness of 40 nm. The resist film was exposed using an EUV scanner NXE3400 (NA 0.33, σ0.9, 90° dipole illumination), manufactured by ASML Holding N.V., to form a 36-nm 1:1 line-and-space (LS) pattern. Then, PEB was performed on a hot plate at the temperature shown in Table 4 for 60 seconds, and then development was performed with the developer shown in Table 4 for 30 seconds to form an LS pattern having a space width of 18 nm and a pitch of 36 nm.

Regarding the obtained resist pattern, the following evaluations were carried out. The results are shown in Table 4.

### [Sensitivity Evaluation]

The LS pattern was observed using a length-measurement SEM (CG-6300), manufactured by Hitachi High-Technologies Corporation, and an optimum exposure dose Eₒₚ (mJ/cm²) to yield the LS pattern with 18 nm in space width and 36 nm in pitch was determined to specify this value as sensitivity.

### [LWR Evaluation]

In the LS pattern obtained by irradiation at the optimum exposure dose, sizes in 10 positions in the longitudinal direction of the space width were measured with a length-measurement SEM (CG-6300), manufactured by Hitachi High-Technologies Corporation. From the results, a tripled value (30) of a standard variation (o) was determined as LWR. A smaller LWR value can yield a pattern with smaller roughness and a more uniform space width.

### [Limiting Resolution Evaluation]

A pattern was formed while gradually increasing the exposure dose from the optimum exposure dose at which the LS pattern can be formed, and in this event, the limit of the line width (nm) at which resolution is possible was determined using a length-measurement SEM (CG-6300), manufactured by Hitachi High-Technologies Corporation, to specify this value as limiting resolution (nm). A smaller value indicates that it is possible to form a finer pattern with better limiting resolution.

TABLE 4

| | | | | | | | Limiting |
|---|---|---|---|---|---|---|---|
| | Resist | PAB/PEB | | Pattern | Eₒₚ | LWR | resolution |
| | composition | (° C.) | Developer | type | (mJ/cm²) | (nm) | (nm) |
| Evaluation | R-01 | 110/90 | nBA | Positive | 35 | 3.0 | 13 |
| Example 3-1 | | | | | | | |
| Evaluation | R-02 | 110/90 | nBA | Positive | 38 | 3.2 | 13 |
| Example 3-2 | | | | | | | |
| Evaluation | R-03 | 110/90 | nBA | Positive | 37 | 3.2 | 13 |
| Example 3-3 | | | | | | | |
| Evaluation | R-04 | 110/90 | nBA | Positive | 37 | 3.1 | 13 |
| Example 3-4 | | | | | | | |
| Evaluation | R-05 | 110/90 | nBA | Positive | 38 | 3.0 | 13 |
| Example 3-5 | | | | | | | |
| Evaluation | R-06 | 110/90 | nBA | Positive | 38 | 3.0 | 13 |
| Example 3-6 | | | | | | | |
| Evaluation | R-07 | 110/90 | nBA | Positive | 39 | 3.1 | 13 |
| Example 3-7 | | | | | | | |
| Evaluation | R-08 | 110/90 | nBA | Positive | 35 | 3.3 | 14 |
| Example 3-8 | | | | | | | |
| Evaluation | R-09 | 110/90 | nBA | Positive | 37 | 3.4 | 14 |
| Example 3-9 | | | | | | | |
| Evaluation | R-10 | 110/90 | nBA | Positive | 37 | 3.3 | 14 |
| Example 3-10 | | | | | | | |
| Evaluation | R-11 | 110/90 | nBA | Positive | 39 | 3.4 | 14 |
| Example 3-11 | | | | | | | |
| Evaluation | R-12 | 110/90 | nBA | Positive | 35 | 3.3 | 14 |
| Example 3-12 | | | | | | | |
| Evaluation | R-13 | 110/90 | TMAH | Negative | 38 | 3.4 | 13 |
| Example 3-13 | | | | | | | |
| Evaluation | R-14 | 110/90 | TMAH | Negative | 38 | 3.2 | 13 |
| Example 3-14 | | | | | | | |
| Evaluation | R-15 | 110/90 | TMAH | Negative | 39 | 3.4 | 14 |
| Example 3-15 | | | | | | | |
| Evaluation | R-16 | 110/90 | TMAH | Negative | 35 | 3.4 | 14 |
| Example 3-16 | | | | | | | |
| Evaluation | R-17 | 110/90 | TMAH | Negative | 38 | 3.4 | 14 |
| Example 3-17 | | | | | | | |
| Evaluation | R-18 | 110/90 | TMAH | Negative | 38 | 3.4 | 14 |
| Example 3-18 | | | | | | | |
| Evaluation | R-19 | 110/90 | TMAH | Negative | 35 | 3.1 | 13 |
| Example 3-19 | | | | | | | |
| Evaluation | R-20 | 110/90 | TMAH | Negative | 39 | 3.4 | 14 |
| Example 3-20 | | | | | | | |
| Comparative | CR-01 | 110/90 | nBA | Positive | 40 | 3.5 | 15 |
| Evaluation | | | | | | | |
| Example 3-1 | | | | | | | |
| Comparative | CR-02 | 110/90 | TMAH | Negative | 40 | 4.2 | 15 |
| Evaluation | | | | | | | |
| Example 3-2 | | | | | | | |
| Comparative | CR-03 | 105/90 | TMAH | Positive | 85 | 4.4 | 18 |
| Evaluation | | | | | | | |
| Example 3-3 | | | | | | | |
| Comparative | CR-04 | 105/90 | TMAH | Positive | 85 | 5.0 | 18 |
| Evaluation | | | | | | | |
| Example 3-4 | | | | | | | |

### Developers:

nBA (butyl acetate)
TMAH (2.38 mass aqueous solution of tetramethylammonium hydroxide)

From the results shown in Table 4, it was found that it was possible to form both positive and negative patterns depending on the developer used. In addition, comparing the inventive resist compositions with the resist compositions of Comparative Examples 3-1 and 3-2, it was found that excellent sensitivity, resolution, and LWR were achieved in Examples 3-1 to 3-20, and it was found that, even compared with the compositions of Comparative Examples 3-3 and 3-4, which were chemically amplified resist compositions using acid catalysis, excellent sensitivity, resolution, and LWR were achieved. Thus, it was found that the inventive resist composition was excellent in sensitivity, resolution, and LWR in LS pattern formation by EUV exposure.

### [4] EUV Lithography Evaluation (Contact Hole Pattern)

### Examples 4-1 to 4-20 and Comparative Examples 4-1 to 4-4

Each of the resist compositions (R-01 to R-20 and CR-01 to CR-04) was applied by spin-coating on a Si substrate on which a silicon-containing spin-on hard mask SHB-A940, manufactured by Shin-Etsu Chemical Co., Ltd. (silicon content of 43 mass %), was formed with 20 nm in film thickness. Then, PAB was performed at the temperature shown in Table 5 for 60 seconds using a hot plate to produce a resist film with 50 nm in film thickness. Subsequently, the resist film was exposed using an EUV scanner NXE3400 (NA 0.33, σ0.9/0.6, quadrupole illumination, 64 nm in pitch on wafer size, hole pattern mask with +20% bias), manufactured by ASML Holding N.V. Then, PEB was performed at the temperature shown in Table 5 for 60 seconds on a hot plate. Thereafter, development was performed with the developer shown in Table 5 for 30 seconds to obtain a hole pattern with 32 nm in size.

Regarding the obtained resist pattern, the following evaluations were carried out. The results are shown in Table 5.

### [Sensitivity Evaluation]

The contact hole pattern was observed using a length-measurement SEM (CG-6300), manufactured by Hitachi High-Technologies Corporation, and an optimum exposure dose Eₒₚ (mJ/cm²) to yield the hole pattern with a size of 22 nm was determined to specify this value as sensitivity.

### [CDU Evaluation]

Sizes of 50 hole patterns obtained by irradiation at the optimum exposure dose were measured, and a tripled value (30) of a standard variation (o) calculated from the results was determined as CDU. A smaller CDU value can yield a pattern having a more uniform hole diameter.

### [Limiting Resolution Evaluation]

A hole pattern was formed while gradually decreasing the exposure dose from the optimum exposure dose at which the hole pattern can be formed, and in this event, the limit of the hole diameter (nm) at which resolution is possible was determined using a length-measurement SEM (CG-6300), manufactured by Hitachi High-Technologies Corporation, to specify this value as limiting resolution (nm). A smaller value indicates that it is possible to form a pattern having a finer hole diameter with better limiting resolution.

TABLE 5

| | | | | | | | Limiting |
|---|---|---|---|---|---|---|---|
| | Resist | PAB/PEB | | Pattern | Eₒₚ | CDU | resolution |
| | composition | (° C.) | Developer | type | (mJ/cm²) | (nm) | (nm) |
| Evaluation | R-01 | 110/90 | nBA | Positive | 30 | 2.7 | 25 |
| Example 4-1 | | | | | | | |
| Evaluation | R-02 | 110/90 | nBA | Positive | 33 | 2.1 | 24 |
| Example 4-2 | | | | | | | |
| Evaluation | R-03 | 110/90 | nBA | Positive | 34 | 2.1 | 24 |
| Example 4-3 | | | | | | | |
| Evaluation | R-04 | 110/90 | nBA | Positive | 32 | 2.3 | 25 |
| Example 4-4 | | | | | | | |
| Evaluation | R-05 | 110/90 | nBA | Positive | 32 | 2.1 | 24 |
| Example 4-5 | | | | | | | |
| Evaluation | R-06 | 110/90 | nBA | Positive | 32 | 2.2 | 25 |
| Example 4-6 | | | | | | | |
| Evaluation | R-07 | 110/90 | nBA | Positive | 33 | 2.3 | 25 |
| Example 4-7 | | | | | | | |
| Evaluation | R-08 | 110/90 | nBA | Positive | 32 | 2.4 | 26 |
| Example 4-8 | | | | | | | |
| Evaluation | R-09 | 110/90 | nBA | Positive | 34 | 2.5 | 26 |
| Example 4-9 | | | | | | | |
| Evaluation | R-10 | 110/90 | nBA | Positive | 34 | 2.4 | 26 |
| Example 4-10 | | | | | | | |
| Evaluation | R-11 | 110/90 | nBA | Positive | 33 | 2.9 | 28 |
| Example 4-11 | | | | | | | |
| Evaluation | R-12 | 110/90 | nBA | Positive | 30 | 2.4 | 26 |
| Example 4-12 | | | | | | | |
| Evaluation | R-13 | 110/90 | TMAH | Negative | 37 | 2.4 | 26 |
| Example 4-13 | | | | | | | |
| Evaluation | R-14 | 110/90 | TMAH | Negative | 37 | 2.2 | 26 |
| Example 4-14 | | | | | | | |
| Evaluation | R-15 | 110/90 | TMAH | Negative | 37 | 2.4 | 29 |
| Example 4-15 | | | | | | | |
| Evaluation | R-16 | 110/90 | TMAH | Negative | 35 | 2.9 | 29 |
| Example 4-16 | | | | | | | |
| Evaluation | R-17 | 110/90 | TMAH | Negative | 38 | 2.5 | 27 |
| Example 4-17 | | | | | | | |
| Evaluation | R-18 | 110/90 | TMAH | Negative | 38 | 2.5 | 25 |
| Example 4-18 | | | | | | | |
| Evaluation | R-19 | 110/90 | TMAH | Negative | 32 | 2.1 | 24 |
| Example 4-19 | | | | | | | |
| Evaluation | R-20 | 110/90 | TMAH | Negative | 37 | 2.7 | 24 |
| Example 4-20 | | | | | | | |
| Comparative | CR-01 | 110/90 | nBA | Positive | 35 | 3.8 | 30 |
| Evaluation | | | | | | | |
| Example 4-1 | | | | | | | |
| Comparative | CR-02 | 110/90 | TMAH | Negative | 40 | 3.7 | 30 |
| Evaluation | | | | | | | |
| Example 4-2 | | | | | | | |
| Comparative | CR-03 | 105/90 | TMAH | Positive | 50 | 4.2 | 32 |
| Evaluation | | | | | | | |
| Example 4-3 | | | | | | | |
| Comparative | CR-04 | 105/90 | TMAH | Positive | 50 | 4.2 | 32 |
| Evaluation | | | | | | | |
| Example 4-4 | | | | | | | |

From the results shown in Table 5, it was found that it was possible to form both positive and negative patterns depending on the developer used. In addition, comparing the inventive resist compositions with the resist compositions of Comparative Examples 4-1 and 4-2, it was found that excellent sensitivity, resolution, and CDU were achieved in Examples 4-1 to 4-20, and it was found that, even compared with the compositions of Comparative Examples 4-3 and 4-4, which were chemically amplified resist compositions using acid catalysis, excellent sensitivity, resolution, and CDU were achieved. Thus, it was found that the inventive resist composition was excellent in sensitivity, resolution, and CDU in CH pattern formation by EUV exposure.

The present description includes the following embodiments.

[1]: A resist composition comprising a hypervalent iodine compound, a carboxy-group-containing polymer, and a solvent,
wherein the carboxy-group-containing polymer includes a repeating unit of a carboxylic acid derivative, represented by the following formula (1), and the polymer has a dispersity Mw/Mn of 1.30 or less, where Mw is a weight-average molecular weight and Mn is a number-average molecular weight measured by gel permeation chromatography,

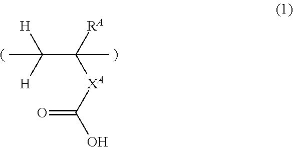

wherein R^{A} represents a hydrogen atom, a halogen atom, a methyl group, or a trifluoromethyl group; X^{A} represents a single bond, a phenylene group, a naphthylene group, or *—C(═O)—O—X^{A1}—; X^{A1} represents a saturated hydrocarbylene group having 1 to 10 carbon atoms, a phenylene group, or a naphthylene group, the saturated hydrocarbylene group optionally containing a hydroxy group, an ether bond, an ester bond, or a lactone ring; and “*” represents an attachment point to the carbon atom of the polymer main chain.

[2]: The resist composition according to [1], wherein the hypervalent iodine compound is at least one compound selected from the group consisting of hypervalent iodine compounds represented by the following formulae (2) to (11),

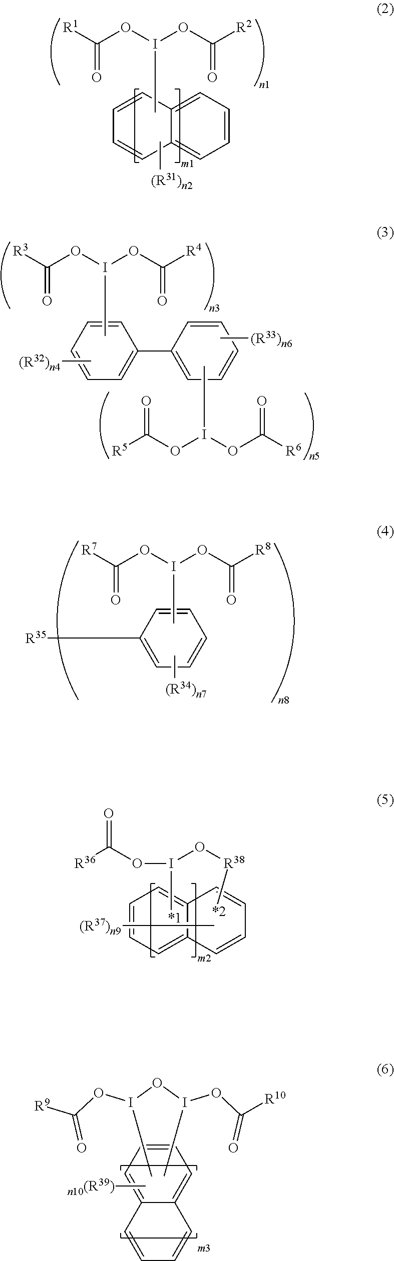

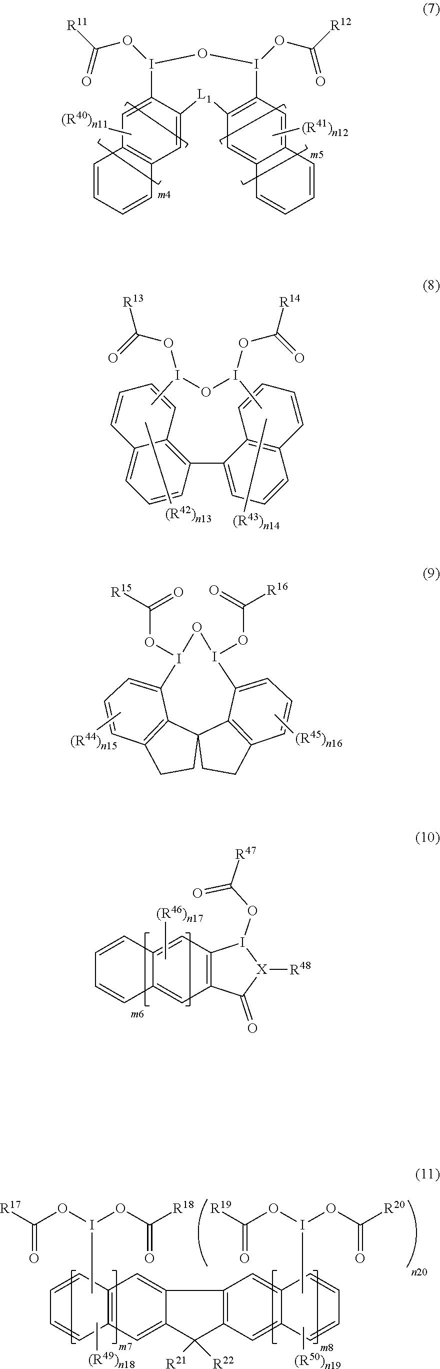

wherein “m1” represents 0, 1, or 2, when “m1” is 0, “n1” representing 1, 2, or 3, “n2” representing 0, 1, 2, 3, 4, or 5, and 1≤n1+n2≤6 being satisfied, when “m1” is 1, “n1” representing 1, 2, or 3, “n2” representing 0, 1, 2, 3, 4, 5, 6, or 7, and 1<n1+n2≤8 being satisfied, and when “m1” is 2, “n1” representing 1, 2, or 3, “n2” representing 0, 1, 2, 3, 4, 5, 6, 7, 8, or 9, and 1≤n1+n2≤10 being satisfied; “n3” represents 1 or 2, “n4” represents 0, 1, 2, 3, or 4, and 1<n3+n4≤5 is satisfied; “n5” represents 1 or 2, “n6” represents 0, 1, 2, 3, or 4, and 1<n5+n6≤5 is satisfied; “n7” represents 0, 1, 2, 3, or 4; “n8” represents 1, 2, 3, or 4; “m2” represents 0, 1, or 2, when “m2” is 0, “n9” representing 0, 1, 2, 3, or 4, when “m2” is 1, “n” representing 0, 1, 2, 3, 4, 5, or 6, and when “m2” is 2, “n9” representing 0, 1, 2, 3, 4, 5, 6, 7, or 8; “m3” represents 0, 1, or 2, when “m3” is 0, “n10” representing 0, 1, 2, 3, or 4, when “m3” is 1, “n10” representing 0, 1, 2, 3, 4, 5, or 6, and when “m3” is 2, “n10” representing 0, 1, 2, 3, 4, 5, 6, 7, or 8; “m4” represents 0 or 1, when “m4” is 0, “n11” representing 0, 1, 2, 3, or 4 and when “m4” is 1, “n11” representing 0, 1, 2, 3, 4, 5, or 6; “m5” represents 0 or 1, when “m5” is 0, “n12” representing 0, 1, 2, 3, or 4 and when “m5” is 1, “n12” representing 0, 1, 2, 3, 4, 5, or 6; “n13” and “n14” each represent 0, 1, 2, 3, 4, 5, or 6; “n15” and “n16” each represent 0, 1, 2, or 3; “m6” represents 0, 1, or 2, when “m6” is 0, “n17” representing 0, 1, 2, 3, or 4, when “m6” is 1, “n17” representing 0, 1, 2, 3, 4, 5, or 6, and when “m6” is 2, “n17” representing 0, 1, 2, 3, 4, 5, 6, 7, or 8; “m7” represents 0, 1, or 2, when “m7” is 0, “n18” representing 0, 1, 2, or 3, when “m7” is 1, “n18” representing 0, 1, 2, 3, 4, or 5, and when “m7” is 2, “n18” representing 0, 1, 2, 3, 4, 5, 6, or 7; “m8” represents 0, 1, or 2, when “m8” represents 0, “n19” representing 0, 1, 2, or 3 and “n20” representing 0 or 1, when “m8” is 1, “n19” representing 0, 1, 2, 3, 4, or 5 and “n20” representing 0 or 1, and when “m8” is 2, “n19” representing 0, 1, 2, 3, 4, 5, 6, or 7 and “n20” representing 0 or 1; R¹ to R-2 each independently represent a halogen atom or a hydrocarbyl group having 1 to 10 carbon atoms and optionally containing a heteroatom, R¹ and R², R³ and R⁴, R⁵ and R⁶, R⁷ and R⁸, R⁹ and R¹⁰, R¹¹ and R¹², R¹³ and R¹⁴, R¹⁵ and R¹⁶, R¹⁷ and R¹⁸, or R¹⁹ and R²⁰ may be bonded to each other to form a ring together with the carbonyloxy groups bonded thereto and any atoms between the carbonyloxy groups, and R²¹ and R²² may be bonded to each other to form a ring together with the carbon atoms bonded thereto and any atoms between the carbon atoms; R³¹ to R³⁴, R³⁷, R³⁹ to R⁴⁶, R⁴⁹, and R⁵⁰ each independently represent a halogen atom or a hydrocarbyl group having 1 to 40 carbon atoms and optionally containing a heteroatom, when “n2” is 2 or more, the R³¹s are identical to or different from each other and the R³¹s may be bonded to each other to form a ring together with the carbon atoms of the aromatic ring bonded thereto, when “n4” is 2 or more, the R³'s are identical to or different from each other and the R³²s may be bonded to each other to form a ring together with the carbon atoms of the aromatic ring bonded thereto, when “n6” is 2 or more, the R³³s are identical to or different from each other and the R³³s may be bonded to each other to form a ring together with the carbon atoms of the aromatic ring bonded thereto, when “n7” is 2 or more, the R³⁴s are identical to or different from each other and the R³⁴s may be bonded to each other to form a ring together with the carbon atoms of the aromatic ring bonded thereto, when “n9” is 2 or more, the R³⁷s are identical to or different from each other and the R³⁷s may be bonded to each other to form a ring together with when “n10” is 2 or more, the R³⁹s are identical to or different from each other and the R³'s may be bonded to each other to form a ring together with the carbon atoms of the aromatic ring bonded thereto, when “n11” is 2 or more, the R⁴⁰s are identical to or different from each other and the R⁴⁰s may be bonded to each other to form a ring together with the carbon atoms of the aromatic ring bonded thereto, when “n12” is 2 or more, the R⁴¹s are identical to or different from each other and the R⁴¹s may be bonded to each other to form a ring together with the carbon atoms of the aromatic ring bonded thereto, when “n13” is 2 or more, the R⁴ªs are identical to or different from each other and the R⁴ªs may be bonded to each other to form a ring together with the carbon atoms of the aromatic ring bonded thereto, when “n14” is 2 or more, the R⁴³s are identical to or different from each other and the R⁴³s may be bonded to each other to form a ring together with the carbon atoms of the aromatic ring bonded thereto, when “n15” is 2 or more, the R⁴⁴s are identical to or different from each other and the R⁴⁴s may be bonded to each other to form a ring together with the carbon atoms of the aromatic ring bonded thereto, when “n16” is 2 or more, the R⁴⁵s are identical to or different from each other and the R⁴⁵s may be bonded to each other to form a ring together with the carbon atoms of the aromatic ring bonded thereto, when “n17” is 2 or more, the R⁴⁶s are identical to or different from each other and the R⁴⁶s may be bonded to each other to form a ring together with the carbon atoms of the aromatic ring bonded thereto, when “n18” is 2 or more, the R⁴⁹s are identical to or different from each other and the R⁴⁹s may be bonded to each other to form a ring together with and when “n19” is 2 or more, the R⁵⁰s are identical to or different from each other and the R⁵⁰s may be bonded to each other to form a ring together with the carbon atoms of the aromatic ring bonded thereto; R³⁵ represents an n8-valent hydrocarbon group having 1 to 40 carbon atoms or an n8-valent heterocyclic group having 2 to 40 carbon atoms, when “n8” is 2, the R³⁵ may be an ether bond, a carbonyl group, an azo group, a thioether bond, a carbonate bond, a carbamate bond, a sulfinyl group, a sulfonyl group, or a thioketone bond, wherein part or all of hydrogen atoms of the n8-valent hydrocarbon group or the n8-valent heterocyclic group may be substituted with a group containing a heteroatom, and part of —CH₂— of the n8-valent hydrocarbon group may be substituted with a group containing a heteroatom, and R³⁴ and R³⁵ may be bonded to each other to form a ring together with the carbon atoms bonded thereto and any atoms between the carbon atoms; R³⁶ represents a halogen atom or a hydrocarbyl group having 1 to 10 carbon atoms and optionally containing a heteroatom; R³⁸ represents a carbonyl group or a hydrocarbylene group having 1 to 10 carbon atoms and optionally containing a heteroatom; “*1” and “*2” each represent an attachment point to a carbon atom of the aromatic ring in the formula, provided that “*1” and “*2” are boned to adjacent carbon atoms of the aromatic ring; L₁ represents absence of a bond, a single bond, —O—, —S—, —NH—, or —CH₂—; R⁴⁷ represents a halogen atom or a hydrocarbyl group having 1 to 10 carbon atoms and optionally containing a heteroatom; and X represents nitrogen or sulfur, when X is nitrogen, X may have R⁴⁸, and R⁴⁸ represents a hydrogen atom, a halogen atom, or a hydrocarbyl group having 1 to 20 carbon atoms and optionally containing a heteroatom.

[3]: A laminate comprising: a substrate; and a resist film, which is a film body formed of the resist composition according to [1] or [2], on the substrate.

[4]: The laminate according to [3], further comprising a resist underlayer film between the substrate and the resist film.

[5]: The laminate according to [3] or [4], wherein the resist film contains a product made by a ligand exchange reaction of the hypervalent iodine compound and the carboxy-group-containing polymer.

[6]: A patterning process comprising the steps of: forming a resist film by using the resist composition according to [1] or [2] on a substrate or on a resist underlayer film of a substrate on which the resist underlayer film has been laminated;
exposing the resist film by using a high-energy beam; and
developing the exposed resist film by using a developer.

[7]: The patterning process according to [6], wherein the high-energy beam used is an i-line, a KrF excimer laser beam, an ArF excimer laser beam, an electron beam, or an extreme ultraviolet ray.

[8]: A method for manufacturing the resist composition according to [1] or [2], comprising the step of
synthesizing the carboxy-group-containing polymer by living radical polymerization using a radical initiator and a reversible addition-fragmentation chain transfer agent represented by the following formula (R-1) or (R-2) and mixing the obtained carboxy-group-containing polymer with the hypervalent iodine compound and the solvent,

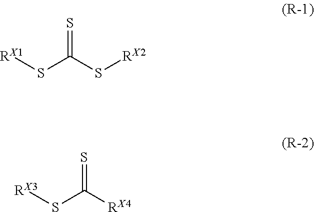

wherein R^{X1} and R^{X3} each independently represent a saturated hydrocarbylthio group having 3 to 20 carbon atoms, an aralkylthio group having 7 to 20 carbon atoms, a heterocyclyl group having 5 to 20 carbon atoms, —N(Z^{A})(Z^{B}), —COOZ^{A}, —OCOZ^{A}, —CON(Z^{A})(Z^{B}), —P(═O)(OZ^{A})₂, or —O—P(═O)(Z^{A})(Z^{B}); Z^{A} and Z^{B} each independently represent a saturated hydrocarbyl group having 1 to 20 carbon atoms, an aryl group having 6 to 20 carbon atoms, or an aralkyl group having 7 to 20 carbon atoms, wherein part or all of hydrogen atoms bonded to carbon atoms of Z^{A} and Z^{B} may be substituted with a cyano group or a carboxy group; and R^{X2} and R^{X4} each independently represent a saturated hydrocarbyl group having 2 to 20 carbon atoms and optionally containing a heteroatom, an aralkyl group having 7 to 20 carbon atoms, or an aryl group having 6 to 20 carbon atoms.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A resist composition comprising a hypervalent iodine compound, a carboxy-group-containing polymer, and a solvent,
wherein the carboxy-group-containing polymer includes a repeating unit of a carboxylic acid derivative, represented by the following formula (1), and the polymer has a dispersity Mw/Mn of 1.30 or less, where Mw is a weight-average molecular weight and Mn is a number-average molecular weight measured by gel permeation chromatography, 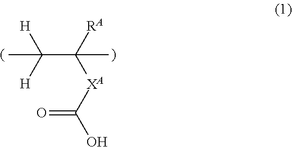
wherein R^{A} represents a hydrogen atom, a halogen atom, a methyl group, or a trifluoromethyl group; X^{A} represents a single bond, a phenylene group, a naphthylene group, or *—C(═O)—O—X^{A1}—; X^{A1} represents a saturated hydrocarbylene group having 1 to 10 carbon atoms, a phenylene group, or a naphthylene group, the saturated hydrocarbylene group optionally containing a hydroxy group, an ether bond, an ester bond, or a lactone ring; and “*” represents an attachment point to the carbon atom of the polymer main chain.

2. The resist composition according to claim 1, wherein the hypervalent iodine compound is at least one compound selected from the group consisting of hypervalent iodine compounds represented by the following formulae (2) to (11), 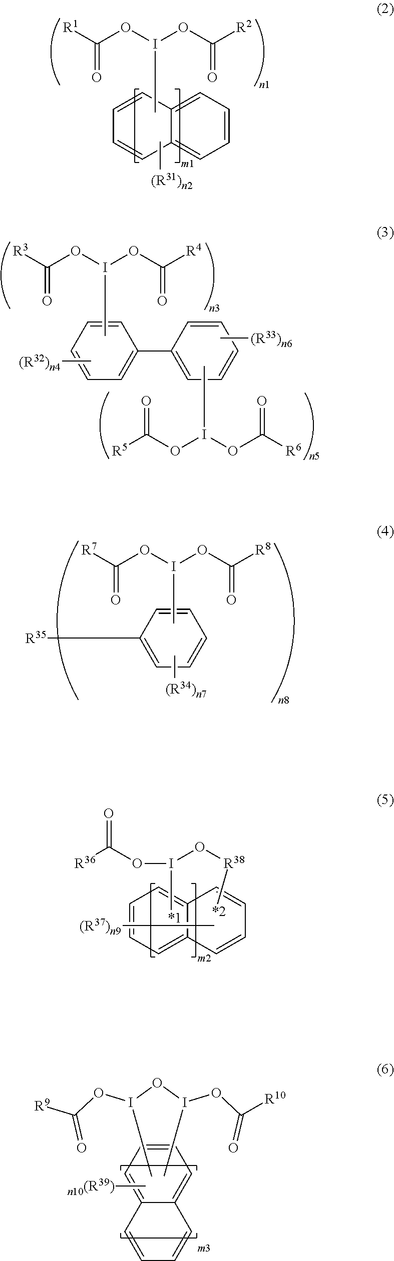 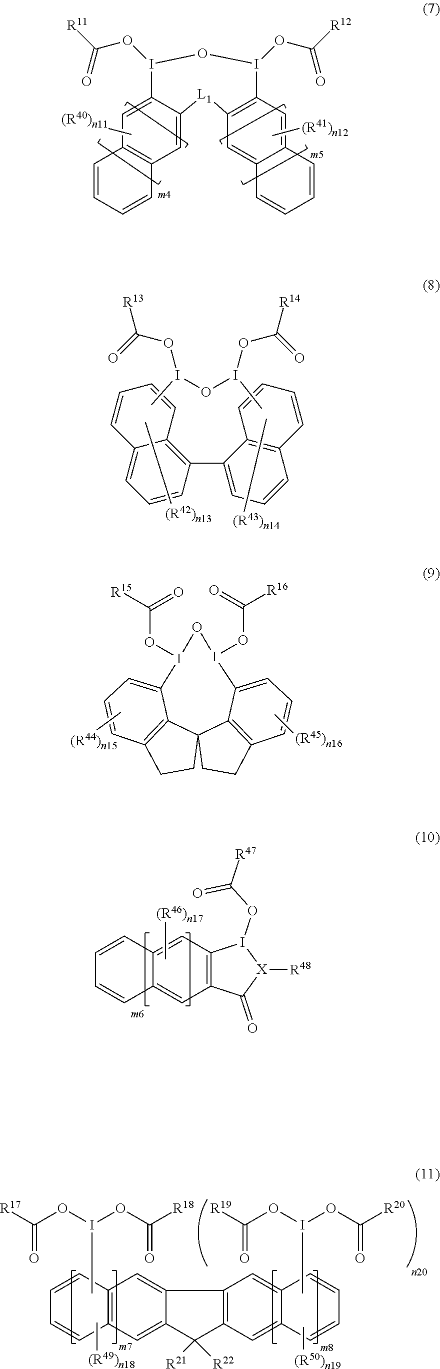
wherein “m1” represents 0, 1, or 2, when “m1” is 0, “n1” representing 1, 2, or 3, “n2” representing 0, 1, 2, 3, 4, or 5, and 1≤n1+n2≤6 being satisfied, when “m1” is 1, “n1” representing 1, 2, or 3, “n2” representing 0, 1, 2, 3, 4, 5, 6, or 7, and 1≤n1+n2≤8 being satisfied, and when “m1” is 2, “n1” representing 1, 2, or 3, “n2” representing 0, 1, 2, 3, 4, 5, 6, 7, 8, or 9, and 1≤n1+n2≤10 being satisfied; “n3” represents 1 or 2, “n4” represents 0, 1, 2, 3, or 4, and 1<n3+n4≤5 is satisfied; “n5” represents 1 or 2, “n6” represents 0, 1, 2, 3, or 4, and 1<n5+n6≤5 is satisfied; “n7” represents 0, 1, 2, 3, or 4; “n8” represents 1, 2, 3, or 4; “m2” represents 0, 1, or 2, when “m2” is 0, “n9” representing 0, 1, 2, 3, or 4, when “m2” is 1, “n” representing 0, 1, 2, 3, 4, 5, or 6, and when “m2” is 2, “n9” representing 0, 1, 2, 3, 4, 5, 6, 7, or 8; “m3” represents 0, 1, or 2, when “m3” is 0, “n10” representing 0, 1, 2, 3, or 4, when “m3” is 1, “n10” representing 0, 1, 2, 3, 4, 5, or 6, and when “m3” is 2, “n10” representing 0, 1, 2, 3, 4, 5, 6, 7, or 8; “m4” represents 0 or 1, when “m4” is 0, “n11” representing 0, 1, 2, 3, or 4 and when “m4” is 1, “n11” representing 0, 1, 2, 3, 4, 5, or 6; “m5” represents 0 or 1, when “m5” is 0, “n12” representing 0, 1, 2, 3, or 4 and when “m5” is 1, “n12” representing 0, 1, 2, 3, 4, 5, or 6; “n13” and “n14” each represent 0, 1, 2, 3, 4, 5, or 6; “n15” and “n16” each represent 0, 1, 2, or 3; “m6” represents 0, 1, or 2, when “m6” is 0, “n17” representing 0, 1, 2, 3, or 4, when “m6” is 1, “n17” representing 0, 1, 2, 3, 4, 5, or 6, and when “m6” is 2, “n17” representing 0, 1, 2, 3, 4, 5, 6, 7, or 8; “m7” represents 0, 1, or 2, when “m7” is 0, “n18” representing 0, 1, 2, or 3, when “m7” is 1, “n18” representing 0, 1, 2, 3, 4, or 5, and when “m7” is 2, “n18” representing 0, 1, 2, 3, 4, 5, 6, or 7; “m8” represents 0, 1, or 2, when “m8” represents 0, “n19” representing 0, 1, 2, or 3 and “n20” representing 0 or 1, when “m8” is 1, “n19” representing 0, 1, 2, 3, 4, or 5 and “n20” representing 0 or 1, and when “m8” is 2, “n19” representing 0, 1, 2, 3, 4, 5, 6, or 7 and “n20” representing 0 or 1; R¹ to R²² each independently represent a halogen atom or a hydrocarbyl group having 1 to 10 carbon atoms and optionally containing a heteroatom, R¹ and R², R³ and R⁴, R⁵ and R⁶, R⁷ and R⁸, R⁹ and R¹⁰, R¹¹ and R¹², R¹³ and R¹⁴, R¹⁵ and R¹⁶, R¹⁷ and R¹⁸, or R¹⁹ and R²⁰ may be bonded to each other to form a ring together with the carbonyloxy groups bonded thereto and any atoms between the carbonyloxy groups, and R²¹ and R²² may be bonded to each other to form a ring together with the carbon atoms bonded thereto and any atoms between the carbon atoms; R³¹ to R³⁴, R³⁷, R³⁹ to R⁴⁶, R⁴⁹, and R⁵⁰ each independently represent a halogen atom or a hydrocarbyl group having 1 to 40 carbon atoms and optionally containing a heteroatom, when “n2” is 2 or more, the R³¹s are identical to or different from each other and the R³¹s may be bonded to each other to form a ring together with the carbon atoms of the aromatic ring bonded thereto, when “n4” is 2 or more, the R³'s are identical to or different from each other and the R³²s may be bonded to each other to form a ring together with the carbon atoms of the aromatic ring bonded thereto, when “n6” is 2 or more, the R³³s are identical to or different from each other and the R³³s may be bonded to each other to form a ring together with the carbon atoms of the aromatic ring bonded thereto, when “n7” is 2 or more, the R³⁴s are identical to or different from each other and the R³⁴s may be bonded to each other to form a ring together with the carbon atoms of the aromatic ring bonded thereto, when “n9” is 2 or more, the R³⁷s are identical to or different from each other and the R³⁷s may be bonded to each other to form a ring together with when “n10” is 2 or more, the R³⁹s are identical to or different from each other and the R³⁹s may be bonded to each other to form a ring together with the carbon atoms of the aromatic ring bonded thereto, when “n11” is 2 or more, the R⁴⁰s are identical to or different from each other and the R⁴⁰s may be bonded to each other to form a ring together with the carbon atoms of the aromatic ring bonded thereto, when “n12” is 2 or more, the R⁴¹s are identical to or different from each other and the R⁴¹s may be bonded to each other to form a ring together with the carbon atoms of the aromatic ring bonded thereto, when “n13” is 2 or more, the R⁴²s are identical to or different from each other and the R⁴²s may be bonded to each other to form a ring together with the carbon atoms of the aromatic ring bonded thereto, when “n14” is 2 or more, the R⁴³s are identical to or different from each other and the R⁴³s may be bonded to each other to form a ring together with the carbon atoms of the aromatic ring bonded thereto, when “n15” is 2 or more, the R⁴⁴s are identical to or different from each other and the R⁴⁴s may be bonded to each other to form a ring together with the carbon atoms of the aromatic ring bonded thereto, when “n16” is 2 or more, the R⁴⁵s are identical to or different from each other and the R⁴⁵s may be bonded to each other to form a ring together with the carbon atoms of the aromatic ring bonded thereto, when “n17” is 2 or more, the R⁴⁶s are identical to or different from each other and the R⁴⁶s may be bonded to each other to form a ring together with the carbon atoms of the aromatic ring bonded thereto, when “n18” is 2 or more, the R⁴⁹s are identical to or different from each other and the R⁴⁹s may be bonded to each other to form a ring together with and when “n19” is 2 or more, the R⁵⁰s are identical to or different from each other and the R⁵⁰s may be bonded to each other to form a ring together with the carbon atoms of the aromatic ring bonded thereto; R³⁵ represents an n8-valent hydrocarbon group having 1 to 40 carbon atoms or an n8-valent heterocyclic group having 2 to 40 carbon atoms, when “n8” is 2, the R³⁵ may be an ether bond, a carbonyl group, an azo group, a thioether bond, a carbonate bond, a carbamate bond, a sulfinyl group, a sulfonyl group, or a thioketone bond, wherein part or all of hydrogen atoms of the n8-valent hydrocarbon group or the n8-valent heterocyclic group may be substituted with a group containing a heteroatom, and part of —CH₂— of the n8-valent hydrocarbon group may be substituted with a group containing a heteroatom, and R³⁴ and R³⁵ may be bonded to each other to form a ring together with the carbon atoms bonded thereto and any atoms between the carbon atoms; R³⁶ represents a halogen atom or a hydrocarbyl group having 1 to 10 carbon atoms and optionally containing a heteroatom; R³⁸ represents a carbonyl group or a hydrocarbylene group having 1 to 10 carbon atoms and optionally containing a heteroatom; “*1” and “*2” each represent an attachment point to a carbon atom of the aromatic ring in the formula, provided that “*1” and “*2” are boned to adjacent carbon atoms of the aromatic ring; L₁ represents absence of a bond, a single bond, —O—, —S—, —NH—, or —CH₂—; R⁴⁷ represents a halogen atom or a hydrocarbyl group having 1 to 10 carbon atoms and optionally containing a heteroatom; and X represents nitrogen or sulfur, when X is nitrogen, X may have R⁴⁸, and R⁴⁸ represents a hydrogen atom, a halogen atom, or a hydrocarbyl group having 1 to 20 carbon atoms and optionally containing a heteroatom.

3. A laminate comprising: a substrate; and a resist film, which is a film body formed of the resist composition according to claim 1, on the substrate.

4. A laminate comprising: a substrate; and a resist film, which is a film body formed of the resist composition according to claim 2, on the substrate.

5. The laminate according to claim 3, further comprising a resist underlayer film between the substrate and the resist film.

6. The laminate according to claim 4, further comprising a resist underlayer film between the substrate and the resist film.

7. The laminate according to claim 3, wherein the resist film contains a product made by a ligand exchange reaction of the hypervalent iodine compound and the carboxy-group-containing polymer.

8. The laminate according to claim 4, wherein the resist film contains a product made by a ligand exchange reaction of the hypervalent iodine compound and the carboxy-group-containing polymer.

9. A patterning process comprising the steps of:
forming a resist film by using the resist composition according to claim 1 on a substrate or on a resist underlayer film of a substrate on which the resist underlayer film has been laminated;
exposing the resist film by using a high-energy beam; and
developing the exposed resist film by using a developer.

10. A patterning process comprising the steps of:
forming a resist film by using the resist composition according to claim 2 on a substrate or on a resist underlayer film of a substrate on which the resist underlayer film has been laminated;
exposing the resist film by using a high-energy beam; and
developing the exposed resist film by using a developer.

11. The patterning process according to claim 9, wherein the high-energy beam used is an i-line, a KrF excimer laser beam, an ArF excimer laser beam, an electron beam, or an extreme ultraviolet ray.

12. The patterning process according to claim 10, wherein the high-energy beam used is an i-line, a KrF excimer laser beam, an ArF excimer laser beam, an electron beam, or an extreme ultraviolet ray.

13. A method for manufacturing the resist composition according to claim 1, comprising the step of
synthesizing the carboxy-group-containing polymer by living radical polymerization using a radical initiator and a reversible addition-fragmentation chain transfer agent represented by the following formula (R-1) or (R-2) and mixing the obtained carboxy-group-containing polymer with the hypervalent iodine compound and the solvent, 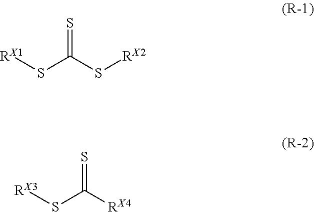
wherein R^{X1} and R^{X3} each independently represent a saturated hydrocarbylthio group having 3 to 20 carbon atoms, an aralkylthio group having 7 to 20 carbon atoms, a heterocyclyl group having 5 to 20 carbon atoms, —N(Z^{A})(Z^{B}), —COOZ^{A}, —OCOZ^{A}, —CON(Z^{A})(Z^{B}), —P(═O)(OZ^{A})₂, or —O—P(═O)(Z^{A})(Z^{B}); Z^{A} and Z^{B} each independently represent a saturated hydrocarbyl group having 1 to 20 carbon atoms, an aryl group having 6 to 20 carbon atoms, or an aralkyl group having 7 to 20 carbon atoms, wherein part or all of hydrogen atoms bonded to carbon atoms of Z^{A} and Z^{B} may be substituted with a cyano group or a carboxy group; and R^{X2} and R^{X4} each independently represent a saturated hydrocarbyl group having 2 to 20 carbon atoms and optionally containing a heteroatom, an aralkyl group having 7 to 20 carbon atoms, or an aryl group having 6 to 20 carbon atoms.
